(19) United States
(12) Patent Application Publication
(10) Pub. No.: US 2019/0233455 A1
(43) Pub. Date: Aug. 1, 2019

(54) Tetradentate ring metal platinum complex with 4-aryl-3, 5-disubstituted pyrazole and preparation method and application

(71) Applicants: AAC Microtech (Changzhou) Co., Ltd., Changzhou (CN); Zhejiang University of Technology, Hangzhou (CN)

(72) Inventor: Guijie Li, Shenzhen (CN)

(21) Appl. No.: 16/240,863

(22) Filed: Jan. 7, 2019

(30) Foreign Application Priority Data
Jan. 30, 2018 (CN) 201810089082.X

(51) Int. Cl. C07F 15/00; H01L 51/00; H01L 51/50

(52) U.S. Cl. CPC C07F 15/0086; H01L 51/5016; H01L 51/0087

(57) ABSTRACT

The present invention relates to the field of blue light phosphorescent tetradentate ring metal platinum complex luminescent material, publishes a blue light phosphorescent tetradentate ring metal platinum complex based on 4-aryl-3, 5-disubstituted pyrazole, its preparation method and application. The complex can be a delayed fluorescent and/or phosphorescent emitter with characteristics such as high thermal decomposition temperature, high quantum effect, being equipped with blue luminescence and narrow emission spectrum. Therefore, it has great application prospect in the field of blue light, especially dark blue phosphorescent material.

### FIELD OF THE PRESENT DISCLOSURE

The invention relates to the field of blue light phosphorescent tetradentate ring metal platinum complex luminescent material, in particular to a blue light phosphorescent tetradentate ring metal platinum complex based on 4-aryl-3, 5-disubstituted pyrazole.

### DESCRIPTION OF RELATED ART

Compounds capable of absorbing and/or emitting light can ideally be used in a wide variety of optical and electroluminescent devices, including, for example, optical absorption devices such as solar sensitive devices and photosensitive devices, organic light-emitting diodes (OLEDs), optical emission devices, or devices capable of both carrying out optical absorption and light emission and used as markers for biological applications. Many studies have been devoted to the discovery and optimization of organic and organometallic materials for use in optical and electroluminescent devices. Usually, research in this field aims to achieve many objectives, including the improvement of absorption and emission efficiency, and the improvement of processing capacity.

Although significant progress has been made in the research of chemical and electro-optic materials, such as the commercialization of red-green phosphorescent organometallic materials and its application in OLEDs, lighting equipment and phosphor materials in advanced displays. However, the materials available now still have many disadvantages, including poor machining property, inefficient emission or absorption, and less desirable stability.

In addition, good blue light luminescent materials are very rare, and a huge challenge is the poor stability of blue light devices, and the choice of host materials has an important impact on the stability and efficiency of devices. Compared with red and green phosphor materials, the lowest triplet state of blue light phosphorescent materials has a higher energy level, which means that the triplet state energy level of host materials in blue light devices needs to be still higher. Therefore, the limitation of host materials in blue-light devices is another important problem for its development.

In general, changes in the chemical structure affect the electronic structure of the compound, which in turn affects the optical properties of the compound (for example, emission and absorption spectra), so, the compound can be regulated or adjusted to specific emission or absorption energy. In some ways, the optical properties of the compound disclosed by the invention can be regulated by changing the structure of the ligand surrounding the metal center. For example, the compound with ligand with electron-donating group or electron-attracting group usually shows different optical properties, including different emission and absorption spectra.

Because phosphorescent polydentate platinum metal complexes can simultaneously utilize electrically excited singlet state and triplet state excitons to obtain an internal quantum efficiency of 100%, these complexes can therefore be used as alternative luminescent materials for OLEDs. Usually, the ligand of polydentate platinum metal complex includes luminescent groups and auxiliary groups. If conjugated groups, such as aromatic ring substituent groups or heteroatom, are introduced into the luminescent part, the energy levels of the HOMO and the LOMO of its luminescent material is be changed. At the same time, the energy level gap between the HOMO orbit and the LOMO orbit can be further adjusted to regulate the spectral properties of the phosphorescent polydentate platinum metal complex, for example, to make it wider or narrower, or to make it move red or blue.

### BRIEF DESCRIPTION OF THE DRAWINGS

Many aspects of the exemplary embodiments can be better understood with reference to the following drawings. The components in the drawing are not necessarily drawn to scale, the emphasis instead being placed upon clearly illustrating the principles of the present disclosure.

FIG. 1 shows the emission spectrum spectrogram of the compound Pt1 dichloromethane solution at room temperature;

FIG. 2 shows the emission spectrum spectrogram of the compound Pt2 dichloromethane solution at room temperature;

FIG. 3 shows the emission spectrum spectrogram of the compound Pt925 dichloromethane solution at room temperature;

FIG. 4 shows the emission spectrum spectrogram of the compound Pt926 dichloromethane solution at room temperature;

FIG. 5 shows the original spectrum of the thermogravimetric analysis curve of compound Pt1;

FIG. 6 shows the original spectrum of the thermogravimetric analysis curve of compound Pt2;

FIG. 7 shows the original spectrum of the thermogravimetric analysis curve of compound Pt925;

FIG. 8 shows the original spectrum of the thermogravimetric analysis curve of compound Pt926;

FIG. 9 shows the emission spectrum spectrogram of the compound Pt929 dichloromethane solution at room temperature;

### DETAILED DESCRIPTION OF THE EXEMPLARY EMBODIMENTS

The present disclosure is hereinafter described in detail with reference to several exemplary embodiments. To make the technical problems to be solved, technical solutions and beneficial effects of the present disclosure more apparent, the present disclosure is described in further detail together with the figure and the embodiments. It should be understood the specific embodiments described hereby is only to explain the disclosure, not intended to limit the disclosure.

The disclosure may be more easily understood by referring to the following specific modes of implementation and the embodiments contained therein. Before disclosing and describing the compounds, devices, and/or methods of the present invention, It should be understood that they are not limited to specific synthetic methods (otherwise they would be pointed out separately), or specific reagents (otherwise they would be pointed out separately), because of course this can change. It should also be understood that the terms used in the present invention are only used to describe specific aspects, and not to make limitations. Although any method and material similar or equivalent to those described in the present invention can be used in the practice or experiment, exemplary methods and materials are described below.

The singular forms of the terms used in the description and the appended claims, “a”, “an” and “the” contain plural indicators. Otherwise, it would be clearly stated separately in the context. As a result, a mixture of two or more components is included when referring to “component”.

The term “optional” or “optionally” used in the present invention means that the events or circumstances described subsequently may or may not occur, and the description includes the circumstances in which the described events or circumstances occur and the circumstances in which they do not occur.

The invention discloses the components that can be used to prepare the compounds described in the present invention and the compound to be used in the method disclosed in the present invention itself. These and other substances are disclosed in the present invention, and it should be understood that when combinations, subsets, interactions, groups, etc., of these substances are disclosed and the specific references of each various individual and total combinations and substitutions of these compounds cannot be specifically disclosed, each is specifically anticipated and described in the present invention. For example, if a specific compound and many modifications that can be made to many molecules that contain the compound are disclosed and discussed, the various kinds and each combination and substitution of the compound are specifically expected, and the modification may be carried out, otherwise it would be specified to the contrary. Therefore, if first class molecules, A, B and C, first class molecules, D, E and F, and combinatorial molecule A-D, are disclosed, then even if not each one is separately recorded, consideration is given to the disclosure of each single and total expected meaning combinations, A-E, A-F, B-D, B-E, B-F, C-D, C-E and C-F. Similarly, any subset or combination of these is also disclosed. Therefore, for example, consideration should be given to the disclosing of combination A-E, B-F and C-E. These concepts apply to all aspects of the present invention, including, but not limited to, the steps of the method for the preparation and use of the compounds. Therefore, if there are various additional steps that can be carried out, it should be understood, each of these additional steps can be performed with a specific embodiment or the combination of embodiments of the method.

The connecting atoms used in the present invention can connect two groups, such as N and C group. The connecting atoms can optionally (if the valence bond permits) have other attached chemical parts. For example, on one hand, Oxygen does not have any other chemical groups attached, because once it is bonded to two atoms (such as N or C), valence bond has already been satisfied. On the contrary, when C is the connecting atom, two other chemical parts may be attached to the C atom. The appropriate chemical components include, but are not limited to, H, oxhydryl, alkyl, alkoxy, ═O, halogen, nitryl, amine, amide, thiol group, aryl, heteroaryl, cycloalkyl alkyl and heterocyclyl.

The term “cyclic structure” or similar terms used in the present invention refers to any cycliv chemical structure, which includes but is not limited to, aryl, heteroaryl, cycloalkyl, cycloalkenyl, heterocyclyl, carbene and N-heterocyclic carbene.

The term “substituted” used in the present invention is expected to contain all allowable substituent groups of an organic compound. In wide terms, the permitted substituent groups include the non-cyclic and cyclic, branched and unbranched, C-cyclic and heterocyclic, and aromatic and non-aromatic substituent groups of the organic compounds. The illustrative substituent groups include, for example, those described below. For the appropriate organic compounds, the permitted substituent groups may be one or more, the same or different. For the purposes of the present invention, heteroatoms (e.g. nitrogen) can have hydrogen substituent groups and/or any allowable substituent groups of the organic compounds of the invention, which satisfies the valence bond of the heteroatoms. This disclosure does not purport to impose any restriction in any way with the substituent groups permitted by the organic compound. In the same way, the term “substitution” or “with substitution” contains an implicit condition that the substitution conforms to the allowed valence bond of the substituted atom and the substituent group, and that the substitution leads to stable compounds (for example, compounds that do not spontaneously transform (e.g. by recomposition, cyclization, elimination, etc.). It is also anticipated that, in some respects, unless it is clearly stated to the contrary, otherwise, the single substituent group can be further optionally substituted (that is, it is further substituted or not substituted).

When defining various terms, “R¹”, “R²”, “R³” and “R⁴” are used as general symbols in the present invention to denote specific substituent groups. These symbols may be any substituent group, not limited to those disclosed in the present invention. And when they are limited to certain substituent groups in one certain case, they may in other cases be limited to some other substituent groups.

The term “alkyl” used in the present invention is a saturated, branched or unbranched, alkyl with 1 to 24 carbon atoms, such as methyl, ethyl, n-propyl, isopropyl, normal-butyl, isobutyl, sec.-butyl, tert.-butyl, n-amyl, isoamyl, sec.-amyl, neo-amyl, hexyl, heptyl, semi group, nonyl, decyl, dodecylalkyl, myristylalkyl, cetylalkyl, eicosylalkyl, tetracosylmyristylalkyl and so on. The alkyl may also be substituted or unsubstituted. For example, the alkyl may replace one or more groups, including, but not limited to the optionally substituted alkyl, cycloalkyl, alkoxy, azyl, ether, halogen, oxhydryl, nitryl, organosilyl, Sulfo-OXO or thiol group, as described in the present invention. The “lower alkyl” group is an alkyl containing 1 to 6 (for example, 1 to 4) carbon atoms.

Throughout the description, “alkyl” is commonly used to refer to both unsubstituted alkyl and substituted alkyl; however, substituted alkyl is also specifically referred to in the present invention by identifying specific substituent groups of alkyl. For example, the term “halogenated alkyl” or “haloalkylalkyl” specifically refers to alkyl that has one or more substituent halogens (e.g. fluorine, chlorine, bromine, bromine, or iodine). The term “alkoxy” specifically means alkyl that has one or more substituent alkoxy, as described below. The term “alkyl azyl” specifically means alkyl with one or more substituent azyls, as described below. When “alkyl” is used in one case and a specific term such as “alkyl alcohol” is used in another case, it does not imply that the term “alkyl” does not simultaneously refer to specific terms such as “alkyl alcohol”.

This practice is also used in other groups described in the present invention. That is, when terms such as “cycloalkyl” refer to both unsubstituted and substituted cycloalkyl, the substituted portion may be specifically determined separately in the present invention; for example, the specifically substituted cycloalkyl can be called, for example, “alkyl cycloalkyl”. Similarly, the substituted alkoxy can be specifically referred to as, for example, “halogenated alkoxy”, and specifically substituted alkenyl may be called, for example, “enol”. The practice of using general terms such as “cycloalkyl” and specific terms such as “alkyl cycloalkyl” is not intended to imply that the general term does not simultaneously contain the specific term.

The term “cycloalkyl” used in the present invention is a non-aromatic, C based cycle consisting of at least three atoms. Examples of cycloalkyl include, but not limited to, cyclopropyl, cyclobutyl, cyclopentyl, cyclohexyl, cyclononyl, etc. The term “heterocyclic alkyl” is a class of cycloalkyl as defined above, and is included in the meaning of the term “cycloalkyl”, in which at least one cyclic C atom is substituted by a heteroatom such as but not limited to nitrogen, oxygen, sulfur, or phosphorus. The cycloalkyl and heterocyclic alkyl may be substituted or unsubstituted. The cycloalkyl and heterocyclic alkyl may have one or more substituted groups, including, but not limited to, alkyl, cycloalkyl, alkoxy, azyl, ether, halogen, oxhydryl, nitryl, organosilylalkyl, sulfo-OXO or thiol group, as described in the present invention.

The terms “alkoxy” and “alkoxy groups” used in the present invention refer to alkyl or cycloalkyl bonded by ether linking group; that is, “alkoxy” can be defined as —OR¹, where R¹ is an alkyl or cycloalkyl as defined above. “Alkoxy” also contains the polymer of the alkoxyl just described; that is, alkoxy may be polyether such as —OR¹—OR² or —OR¹—(OR²)ₐ—OR³, where “a” is an integer from 1 to 200, while R¹, R² and R³ are independently alkyl, cycloalkyl, or their combination.

The term “alkyl” used in the present invention refers to alkyl of 2 to 24 carbon atoms, the structural formula of which contains at least one carbon-carbon double bond. Asymmetrical structures, such as (R¹R²)C═C(R³R⁴), are intended to contain E and Z isomers. It may be presumed from this, that there in the structural formula of the present invention, exists asymmetric alkene, or it may be explicitly expressed by the bond symbol C═C. The alkenyl may have one or more substituted groups, including, but not limited to, alkyl, cycloalkyl, alkoxy, alkenyl, cycloalkenyl, alkynyl, cycloalkynyl, aryl, heteroaryl, aldehyde, azyl, carboxylic acid, ester, ether, halogen, oxhydryl, ketone, triazotriazo, nitryl, organosilyl, Sulfo-OXO or thiol group.

The term “cycloalkenyl” used in the present invention is a non-aromatic, carbon-based cycle consisting of at least three C atoms and containing at least one C—C double bond, namely, C═C. Examples of cycloalkenyl include but are not limited to, cyclopropenylalkenyl, cyclobutenylalkenyl, cyclopentenylalkenyl, cyclopentadienylalkenyl, cyclohexenylalkenyl, cyclohexadienylalkenyl, norbornenyl, etc. The term “heterocycloalkenyl” is a class of cycloalkenyl as defined above and is included in the meaning of the term “cycloalkenyl”, in which at least one carbon atom of the cycle uses heteroatom such as, but not limited to, nitrogen, oxygen, sulfur or phosphor. Cycloalkenyl and heterocycloalkenyl may be substituted or unsubstituted. The cycloalkenyl and heterocycloalkenyl have one or more substituted groups, including but not limited to, alkyl, cycloalkyl, alkoxy, alkenyl, cycloalkenyl, alkynyl, cycloalkynyl, aryl, heteroaryl, aldehyde, azyl, carboxylic acid, ester, ether, halogen, oxhydryl, ketone, triazo, nitryl, organosilyl, Sulfo-OXO or thiol group.

The term “alkynyl” used in the present invention is an alkynyl with 2 to 24 carbon atoms, having a structural formula containing at least one carbon-carbon triple bond. The alkynyl may have one or more unsubstituted or substituted groups, the groups include, but are not limited to, alkyl, cycloalkyl, alkoxy, alkenyl, cycloalkenyla, alkynyl, cycloalkynyl, aryl, heteroaryl, aldehyde, azyl, carboxylic acid, ester, ether, halogen, oxhydryl, ketone, triazo, nitryl, organosilyl, sulfo-oxo or thiol group, as described in the present invention.

The term “cycloalkynyl” used in the present invention is a non-aromatic carbon-based cycle, which contains at least seven carbon atoms and at least one C—C triple bond. The examples of cycloalkynyl include, but not limited to, heptynylalkynyl, cyclooctynyl, cyclononynyl, etc. The term “heterocycloalkynyl” is a type of cycloalkenyl as defined above and is included within the meaning of the term “cycloalkynyl”, in which at least one of the carbon atoms of the cycle is replaced by heteroatomatom, the described heteroatom includes, for example, but is not limited to nitrogen, oxygen, sulfur, or phosphorus. The cycloalkynyl and heterocyclic alkynyl may be substituted or unsubstituted. The cycloalkynyl and heterocyclic alkynyl may have one or more substituted groups, the groups include, but not limited to, alkyl, cycloalkyl, alkoxy, alkenyl, cycloalkenyl, alkynyl, cycloalkynyl, aryl, heteroaryl, aldehyde, azyl, carboxylic acid, ester, ether, halogen, oxhydryl, ketone, triazo, nitryl, organosilyl, sulfo-OXO, thiol group, as described in the present invention,

The term “aryl” used in the present invention is a group containing any carbon-based aromatic group, the carbon-based aromatic group includes, but is not limited to, benzene, naphthaline, benzene groups, biphenyl, phenoxy benzene, etc. The term “aryl” also includes “heteroaryl”, which is defined as a group containing an aromatic group, the aromatic group has at least one innercyclic heteratom introducing aromatic groups. Examples of heteroatomatom include, but are not limited to, nitrogen, oxygen, sulfur, and phosphorus. Similarly, the term “non-hetero-aryl” (which is also included in the term “aryl”) defines a group containing an aromatic group. The described aromatic group contains no heteroatom heteroatomatom. The aryl may be substituted or unsubstituted. The aryl may have one or more substituted groups, and the group includes but is not limited to the alkyl, cycloalkyl, alkoxy, alkenyl, cycloalkenyl, alkynyl, cycloalkynyl, aryl, heteroaryl, aldehyde group, azyl, carboxylic acid group, ester group, ether group, halogen, oxhydryl, ketone group, triazo, nitryl, organosilylalkyl, Sulfo-OXO group or sulfydryl, as described in the present invention. The term “biaryl” is aryl of a particular type and is contained in the definition of “aryl”. Biaryl refers to two aryls that are bound together by a fused cyclic structure, as in the case of a naphthalene, or two aryls connected by one or more C—C bonds, as in biphenyl.

The term “amine” or “azyl” used in the present invention is expressed by the passing type —NR¹R², in which R¹ and R² may be independently selected from hydrogen, alkyl, cycloalkyl, alkenyl, cycloalkynyl, alkynyl, cycloalkynyl, aryl or heteroaryl.

The term “alkyl azyl” used in the present invention is expressed by the passing type —NH(-alkyl), in which alkyl is as described in the present invention. Representative examples include, but are not limited to, methyl azyl, ethyl azyl, propyl azyl, isopropyl azyl, butyl azyl, isobutyl azyl, (sec.-butyl) azyl, (tert.-butyl) azyl, pentyl azyl, isoamyl azyl, (tert-pentyl) azyl, hexyl azyl, etc.

The term “dialkyl azyl” used in the present invention is expressed by the passing type —N(-alkyl)₂, in which alkyl is as described in the present invention. Representative examples include, but are not limited to, dimethyl azyl, diethyl azyl, dipropyl azyl, diisopropyl azyl, dibutyl azyl, diisobutyl azyl, di(sec.-butyl) azyl, di(tert.-butyl) azyl, diamyl azyl, diisoamyl azyl, di(tert-amyl) azyl, dihexyl azyl, N-ethyl-N-methyl azyl, N-methyl-N-propyl azyl, N-ethyl-N propyl azyl, etc.

The term “ether” used in the present invention is expressed by the passing type R¹OR², in which R¹ and R² can independently be alkyl, cycloalkyl, alkenyl, cycloalkenyl, alkynyl, cycloalkynyl, aryl, or heteroaryl, as described in the present invention. The term “polyether” used in the present invention is expressed by the passing type —(R¹O—R²O)ₐ—, in which R¹ and R² can independently be alkyl, cycloalkyl, alkenyl, cycloalkenyl, alkynyl, cycloalkynyl, aryl or heteroaryl, as described in the present invention, and “a” is an integer from 1 to 500. Examples of polyether group include polyethylene glycol oxide, polyoxypropylene, and polybutene oxide.

The term “halogen” used in the present invention refers to halogen fluorine, chlorine, bromine, and iodine.

The term “heterocyclic” used in the present invention refers to monocyclic and multicyclic non-aromatic ring systems, and the term “heteraryl” used in the present invention refers to monocyclic and multicyclic aromatic ring systems: at least one of the ring members is not carbon. The term includes nitrogen heterocyclic butyl alkyl, dioxyl group, furan group, imidazolyl, isothiazolyl group, lisoxazole group, morpholinyl, oxazolyl, includes the oxazolyl of 1,2,3-oxadiazolyl, 1,2,5-oxadiazolyl and 1,3,4-oxadiazolyl, piperazine group, piperidyl, pyrazinyl, pyrazolyl, pyridazinyl, pyridyl, pyrimidyl, pyrryl, pyrrolidyl, 4 hydrogen furan group, 4 hydrogen pyranyl, includes the tetrazinyl of 1,2,4,5-tetrazinyl, includes the tetrazolyl of 1,2,3,4-tetrazolyl and 1,2,4,5-tetrazolyl, includes the thiadiazolyl of 1,2,3-thiadiazolyl, 1,2,5-thiadiazolyl and 1,3,4-thiadiazolyl, thiazyl, thienyl, includes the triazinyl of 1,3,5-triazinyl and 1,2,4-triazinyl, includes the triazolyl of 1,2,3-triazolyl and 1,3,4-triazolyl, etc.

The term “oxhydryl” used in the present invention is expressed by the passing type —OH.

The term “ketone” used in the present invention is expressed by the passing type R′C(O)R², in which R¹ and R² can independently be alkyl, cycloalkyl, alkenyl, cycloalkenyl, alkynyl, cycloalkynyl, aryl or heteroaryl, as described in the present invention.

The term “triazo” used in the present invention is expressed by the passing type —N₃.

The term “nitryl” used in the present invention is expressed by the passing type —NO₂.

The term “nitrile” used in the present invention is expressed by the passing type —CN.

The term “organosilyl” used in the present invention is expressed by the passing type —SiR¹R²R³, in which R¹, R² and R³ can independently be hydrogen, or alkyl, cycloalkyl, alkoxy, alkenyl, cycloalkenyl, alkynyl, cycloalkynyl, aryl or heteroaryl, as described in the present invention.

The term “Sulfo-OXO group” used in the present invention is expressed by the passing type —S(O)R¹, —S(O)₂R¹, —OS(O)₂R¹ or —OS(O)₂OR¹, in which R¹ can independently be hydrogen, or alkyl, cycloalkyl, alkenyl, cycloalkenyl, alkynyl, cycloalkynyl, aryl or heteroaryl, as described in the present invention. Throughout the description, “S(O)” is a shorthand form of S═O. The term “sulfonyl” used in the present invention refers to the Sulfo-OXO group expressed by the passing type —S(O)₂R¹, in which, R¹ can be alkyl, cycloalkyl, alkenyl, cycloalkenyl, alkynyl, cycloalkynyl, aryl, or heteroaryl. The term “sulphone” used in the present invention is expressed by the passing type R¹S(O)₂R², in which R¹ and R² can independently be alkyl, cycloalkyl, alkenyl, cycloalkenyl, alkynyl, cycloalkynyl, aryl or heteroaryl, as described in the present invention. The term “sulfoxide” used in the present invention is expressed by the passing type R¹S(O)R², in which R¹ and R² can independently be alkyl, cycloalkyl, alkenyl, cycloalkenyl, alkynyl, cycloalkynyl, aryl or heteroaryl, as described in the present invention.

The term “sulfydryl” used in the present invention is expressed by the passing type —SH.

The “R¹”, “R²”, “R³”, and “Rⁿ” (where n is an integer) used by the present invention may independently have one or more of the groups listed above. For example, if R¹ is a linear chain alkyl, then a hydrogen atom of alkyl may optimally has a substituted oxhydryl, alkoxy, alkyl, halogen, etc. Depending on the selected group, the first group may be combined within the second group, or optionally, the first group may be hung (that is, connected) to the second group. For example, for the phrase “alkyl containing azyl”, azyl may be bound within the backbone of alkyl. Optionally, azyl can be connected to the backbone of alkyl. The properties of the selected group determine whether the first group is embedded in or connected to the second group.

The compounds described in the present invention may contain “optionally substituted” parts. The term “substituted” (whether or not the term “optionally” exists previously) means that one or more hydrogens of the indicated part are substituted by a suitable substituent group. Unless otherwise stated, otherwise, the “optionally substituted” group may have a suitable substituent group at each substitutable position of the group, and when more than one position in any given structure may have more than one substituent group of selected designated groups, the substituent group at each position may be the same or different. The substituent group combination envisaged in the present invention are preferably those selected as stable or chemically viable compounds. In some respects, unless clearly indicated to the contrary, otherwise they also mean, each substituent group may be further optimally substituted (i.e., further substituted or unsubstituted).

The structure of compound may be expressed as follows:

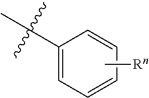

It is understood to be equivalent to the following:

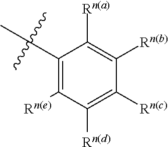

In which n is usually an integer. That is, Rⁿ is understood to represent five separate substituent groups, R^{n(a)}, R^{n(b)}, R^{n(c)}, R^{n(d)}, R^{n(e)}. “Separate substituent group” means that each of the R substituent groups can be independently defined. For example, if R^{n(a)} is halogen in one case, then R^{n(b)} is not necessarily halogen in this case.

The chemical structures and parts disclosed and described in the present invention refer several times to R¹, R², R³, R⁴, R⁵, R⁶, etc. Any explanation in the description of R¹, R², R³, R⁴, R⁵, R⁶, etc., applies respectively to any structure or part that refers to R¹, R², R³, R⁴, R⁵, R⁶, etc., unless otherwise stated.

Optoelectronic devices using organic materials have become increasingly urgent for a variety of reasons. Many of the materials used to manufacture such devices are relatively cheap and therefore organic photoelectric devices have the potential for cost advantages when compared with inorganic devices. In addition, the inherent properties of organic materials, such as their flexibility, make them very suitable for special applications such as manufacturing on flexible substrates. Examples of organic optoelectronic devices include organic light-emitting devices (OLED), organic phototransistors, organic photovoltaic cells and organic photodetectors. For OLED, organic materials may have better performance advantages than conventional materials. For example, the illuminant wavelengths of organic luminescent layers can be easily tuned with appropriate dopants.

Exciton attenuates from single excited state to ground state to produce immediate luminescence, which is fluorescence. If exciton attenuates from triple excited state to ground state to produce luminescence, this is phosphorescence. Due to the strong spin orbital coupling of heavy metal atoms between the singlet state and triplet state excited states, therefore, phosphorescence metal complexes (such as platinum complexes) have shown their potential to utilize both singlet state and triplet state excitons to achieve an internal quantum efficiency of 100%. Phosphorescence metal complexes are good candidates for dopants in the emission layer of organic luminescent devices (OLED), and have received considerable attention in the academic and industrial fields. Many achievements have been made in the past decade, which has led to lucrative commercialization of the technology, for example, OLED has been used for advanced displays of smart phones, televisions and digital cameras.

However, by far, blue electroluminescent devices are still the most challenging area of the technology, and the stability of blue devices is a major problem. It has been proved that the selection of host materials is very important for the stability of blue devices. However, the lowest energy of the triple excited state (Ti) of blue luminescent material is very high, which means that the lowest energy of the triple excited state (Ti) of the host material of blue devices should be higher, which makes the development of the host material of blue devices more difficult.

The metal complexes of the present invention can be customized or tuned to specific applications expected to have specific emission or absorption characteristics. The regulation of the optical properties of metal complexes in this disclosure can be achieved by changing the structure of the ligand surrounding the metal center or changing the structure of the fluorescent luminescence on the ligand. For example, In the emission and absorption spectra, the metal complexes of ligands with electron-donating substituent groups or electron-attracting substituent groups usually exhibit different optical properties. The color of metal complexes can be adjusted by modifying fluorescent luminaires and conjugated groups on ligands.

The emission of the complexes of the present invention can be regulated, for example, by changing the structure of ligands or fluorescent illuminant body, such as from ultraviolet ray to near-infrared. Fluorescent illuminant body is a group of atoms in organic molecules, it can absorb energy to produce singlet excitation state, and single excitons decay rapidly to produce instant luminescence. On the one hand, the complexes of the invention can provide the emission of most visible spectra. In specific examples, the complexes of the present invention can emit light in the range of about 400 nm to about 700 nm. On the other hand, the complexes of the invention have improved stability and efficiency compared with the traditional emission complexes. In addition, the complexes of the invention can be used, for example, in biological applications, as anticancer agents, emitter in organic light-emitting diode (OLED), or luminous label of their combination. On the other hand, the complexes of the present invention may be used in luminescent devices, such as compact fluorescent lamp (CFL), light emitting diode (LED), filament lamp and their combination.

This article discloses compounds or complexes containing platinum. The term compound or complex is interchangeably used in the present invention.

The compound disclosed herein may exhibit desired properties and have emission and/or absorption spectrums that can be adjusted by selecting appropriate ligands. On the other hand, the present invention may exclude any one or more compounds, structures or their parts specifically described herein.

The compound of the present invention may be prepared using a variety of methods, including but not limited to those described in the embodiments provided herein.

The compound disclosed herein may be delayed fluorescence and/or phosphorescent projectiles. On the one hand, the compounds disclosed herein can be delayed fluorescence projectiles. On the one hand, the compounds disclosed herein may be phosphorescent projectiles. On the other hand, the compounds disclosed herein may be delayed fluorescent projectiles and phosphorescent projectiles.

The embodiments of the present invention relate to a tetradentate ring metal platinum complex containing 4-aryl-3, 5-disubstituted pyrazole, the structure of the complex is as shown in formula (I):

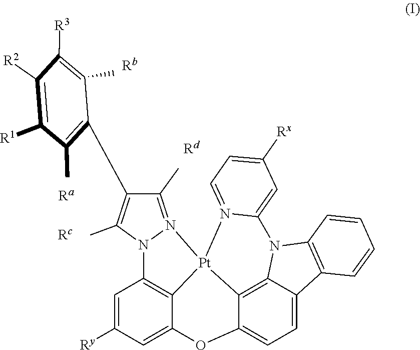

In which,

R^{a}, R^{b}, R^{c} and R^{d} are independently alkyl, alkoxy, cycloalkyl, ether, heterocyclyl, oxhydryl, aryl, heteroaryl, aryloxy, mon- or dialkyl azyl, mon- or diaryl azyl, halogen, sulfydryl, cyanogroup or their combination;

R^{x} is alkyl, alkoxy, cycloalkyl, heterocyclyl, ether, mon- or dialkyl azyl, mon- or diaryl azyl, halogen or their combination;

R^{y} is hydrogen, deuterium, alkyl, alkoxy, cycloalkyl alkyl, heterocyclyl, ether, mon- or dialkyl azyl, mon- or diaryl azyl, halogen or their combination;

R¹, R² and R³ are independently hydrogen, deuterium, alkyl, alkoxy, ether, cycloalkyl, heterocyclyl, oxhydryl, aryl, heteroaryl, aryloxy, mon- or dialkyl azyl, mon- or diaryl azyl, halogen, sulfydryl, cyanogroup, halogen alkyl or their combination;

In some specific embodiments of the present invention, for any structural formula which this patent applies to publish, each structural unit

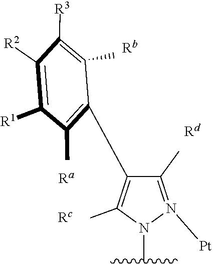

of it may respectively, independently represent the following structure, but is not limited to, the following structure:

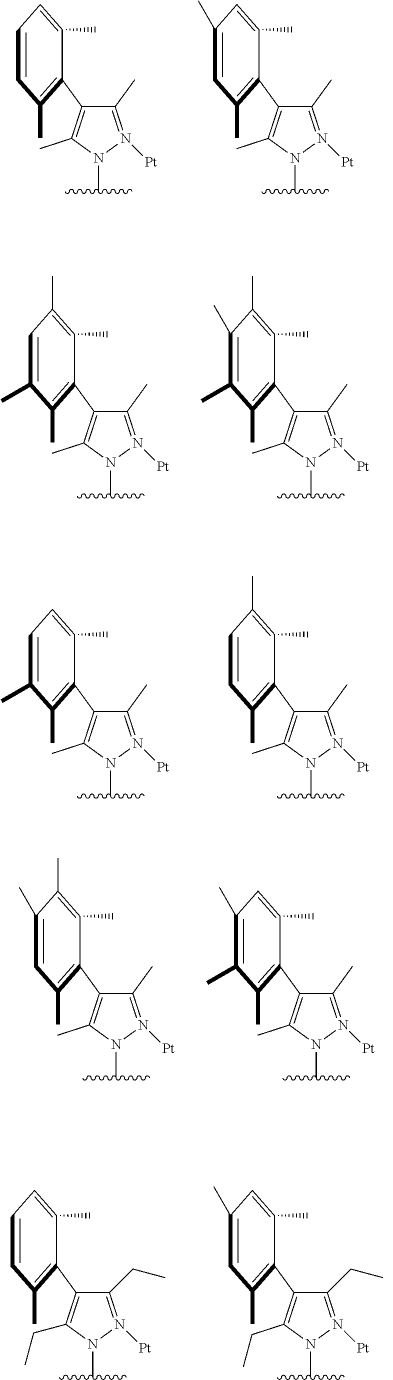

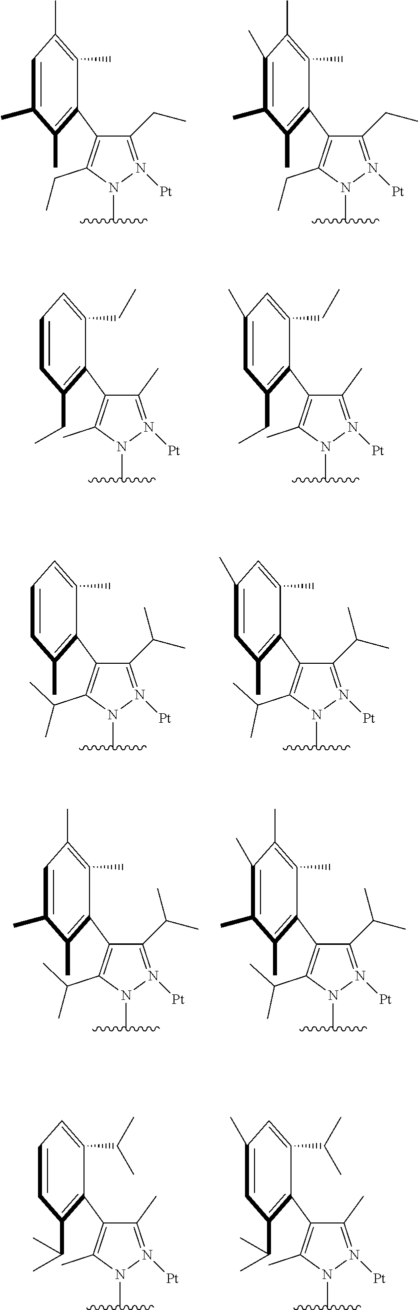

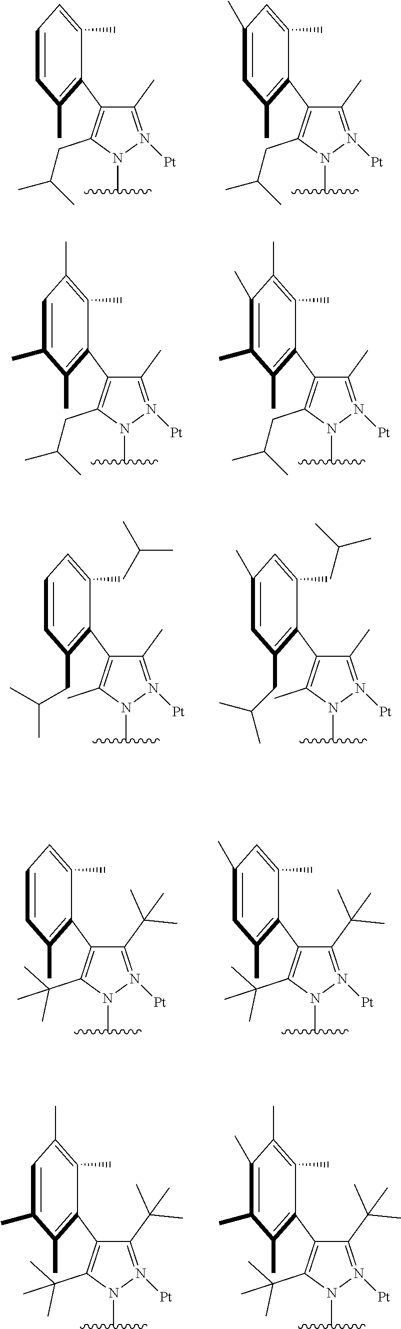

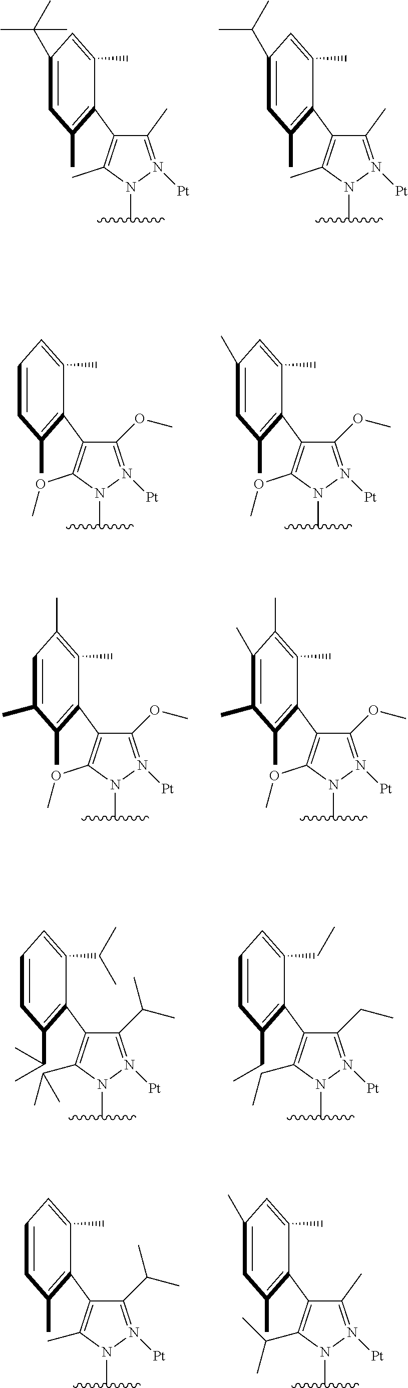

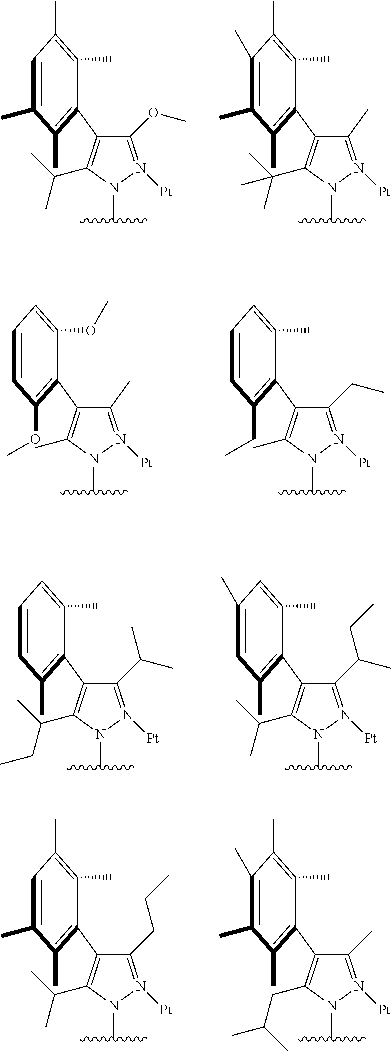

In some specific embodiments of the present invention, the tetradentate ring metal platinum complex containing 4-aryl-3, 5-disubstituted pyrazole has a structure selected from Pt1-Pt940:

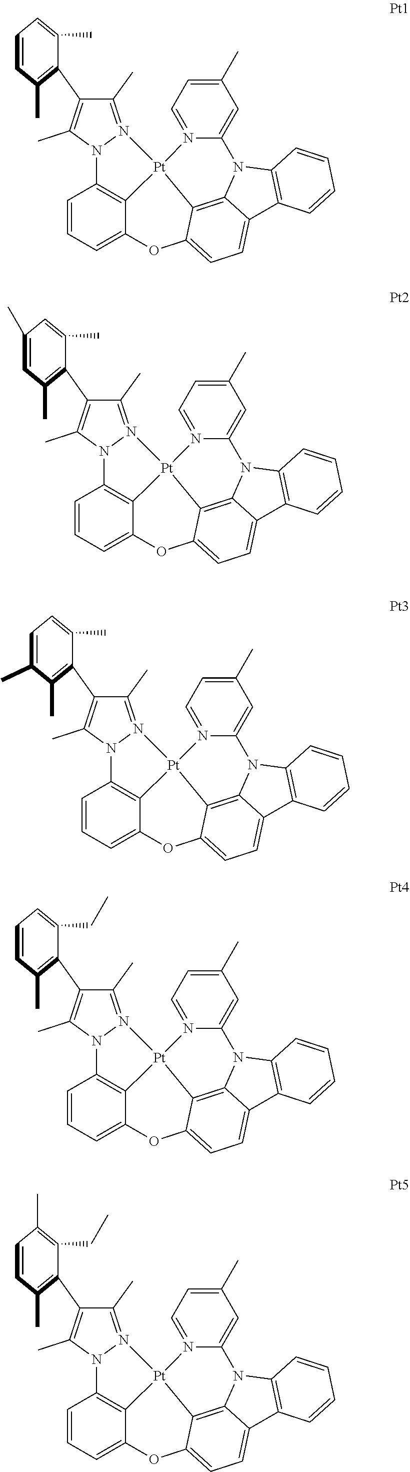

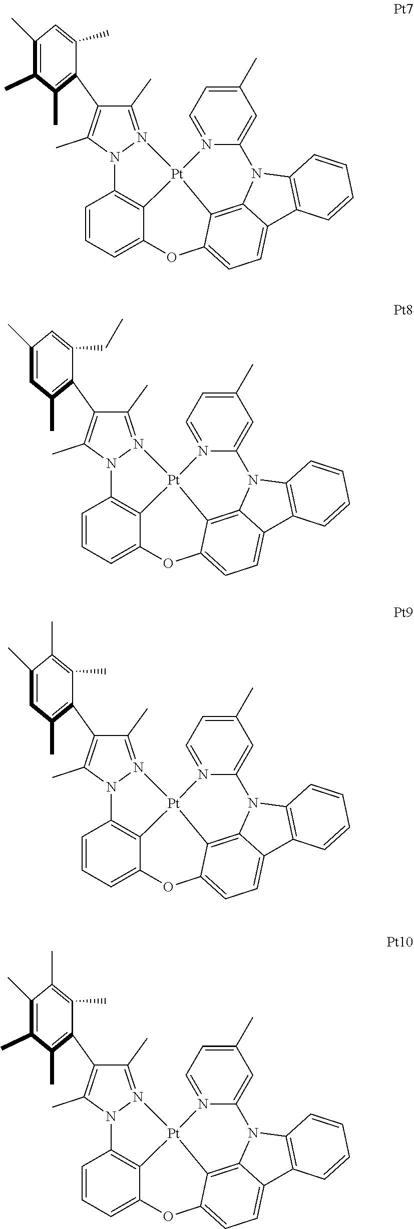

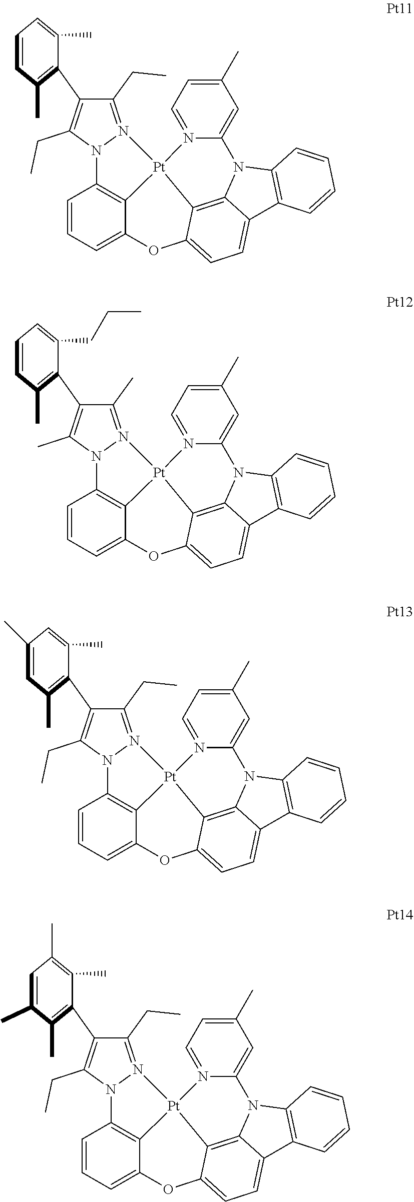

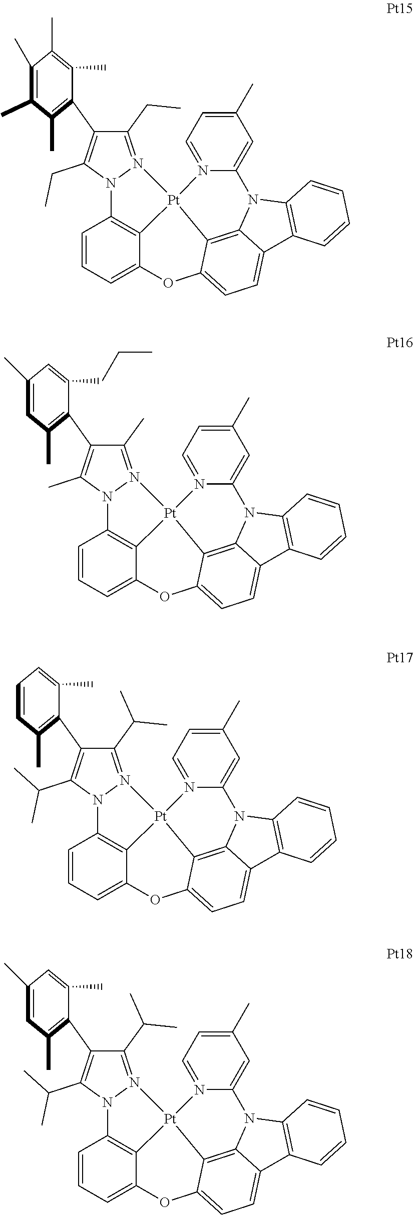

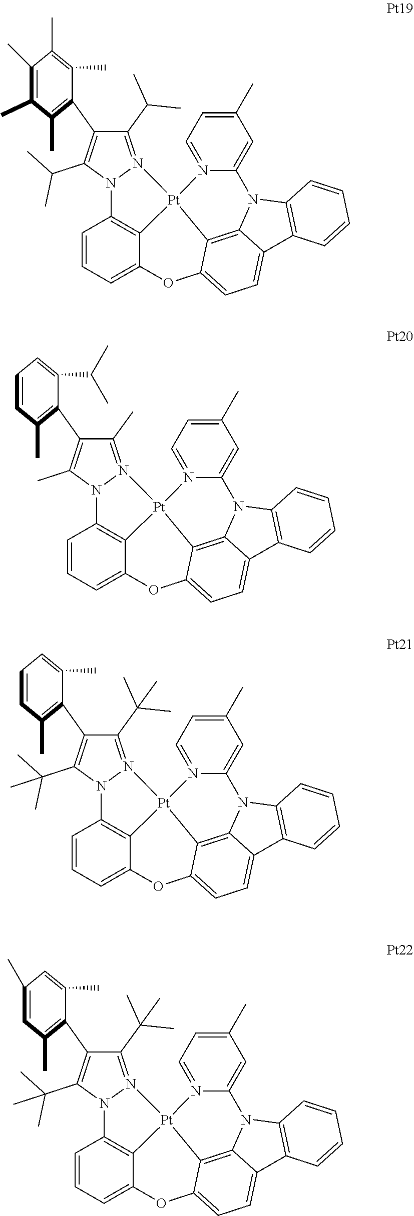

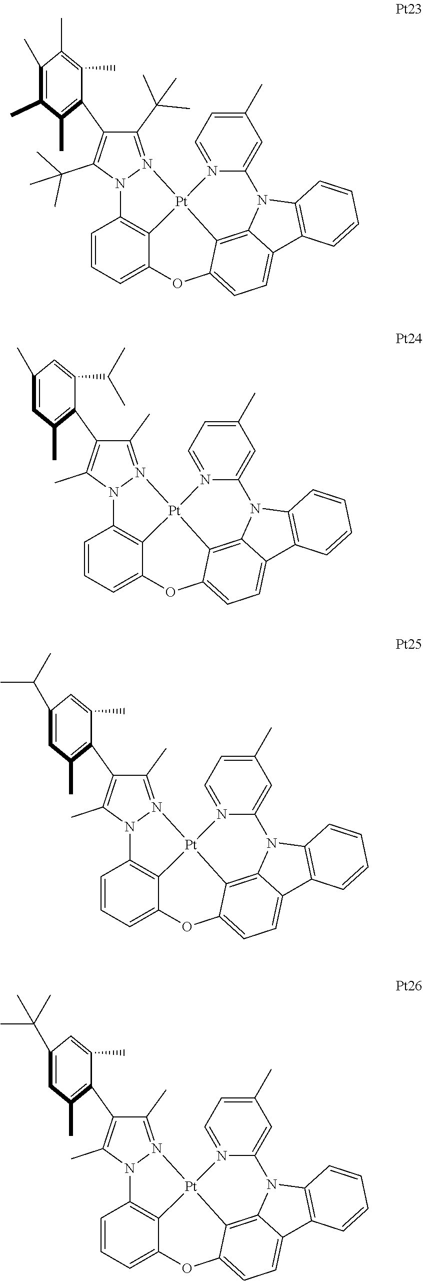

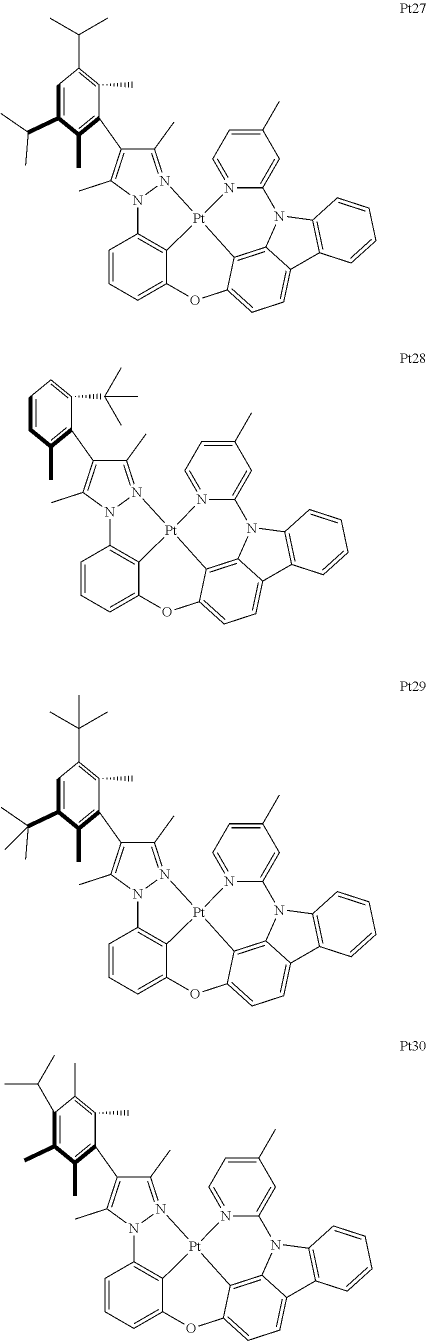

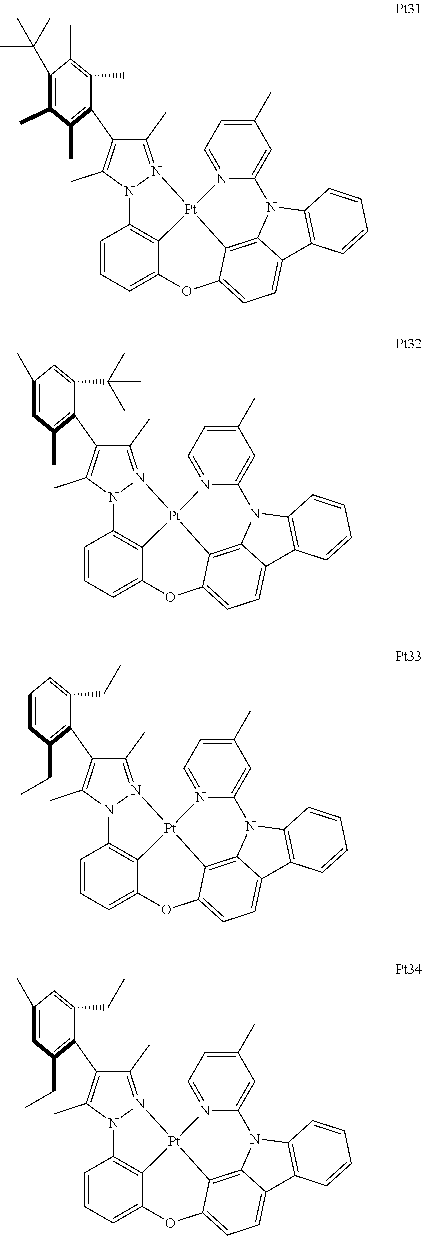

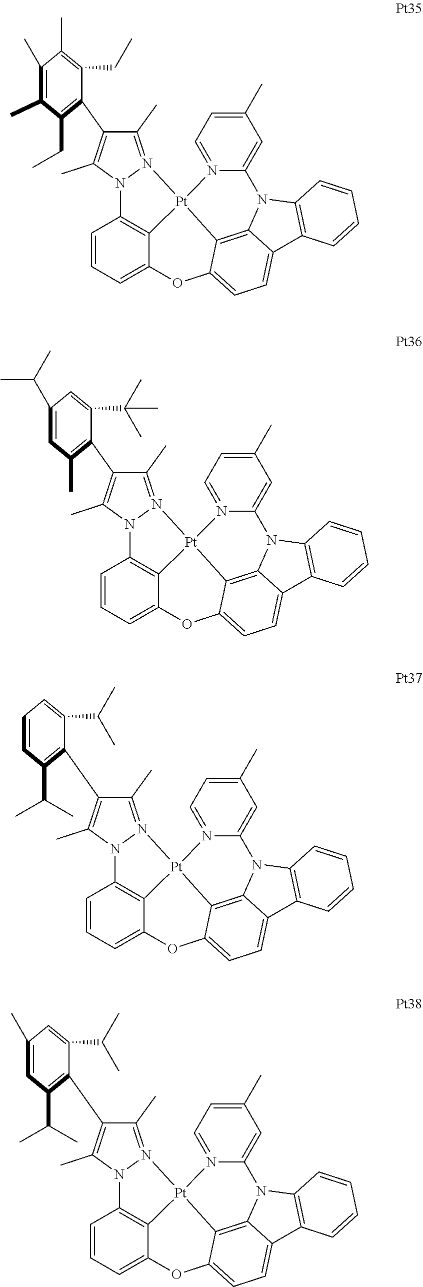

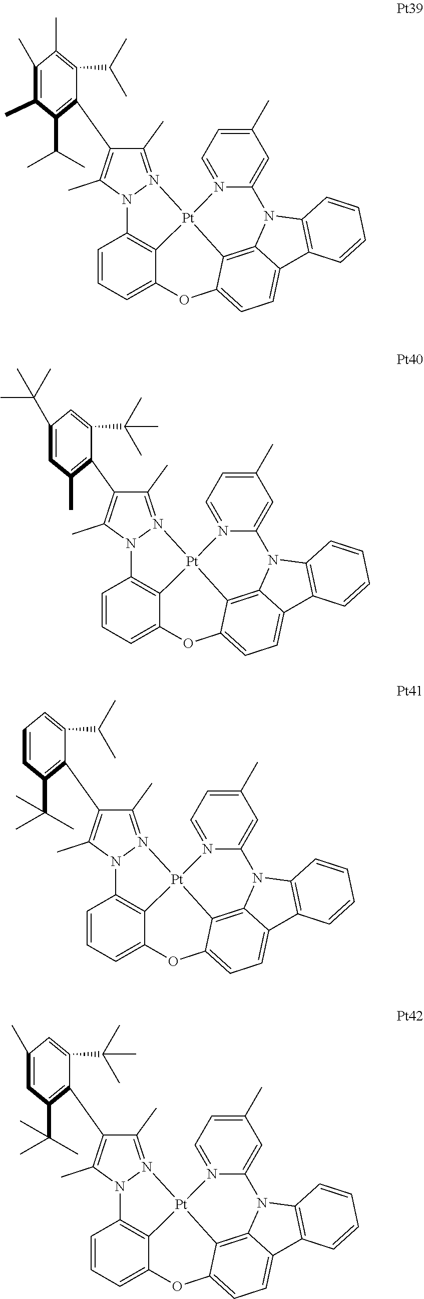

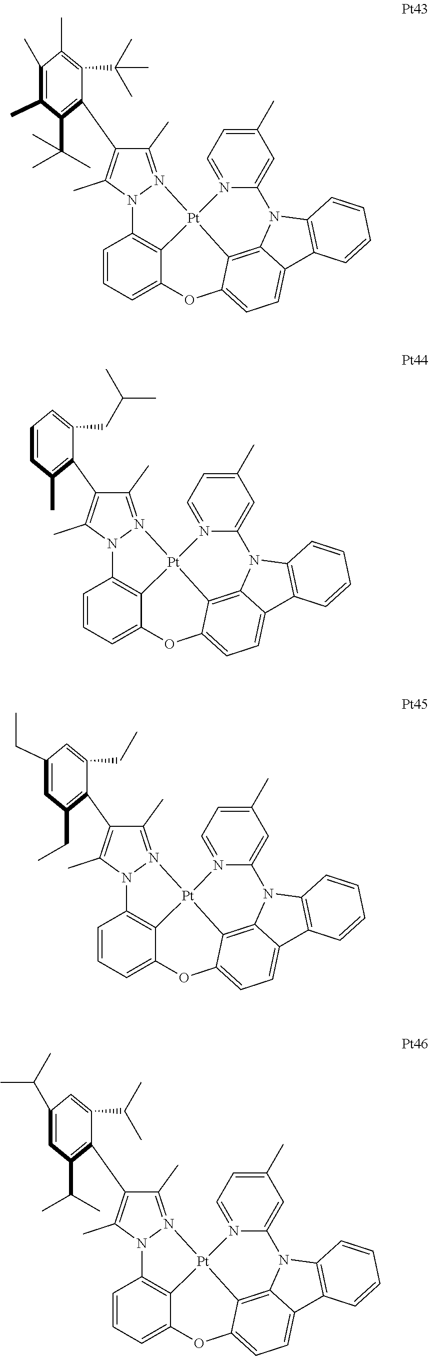

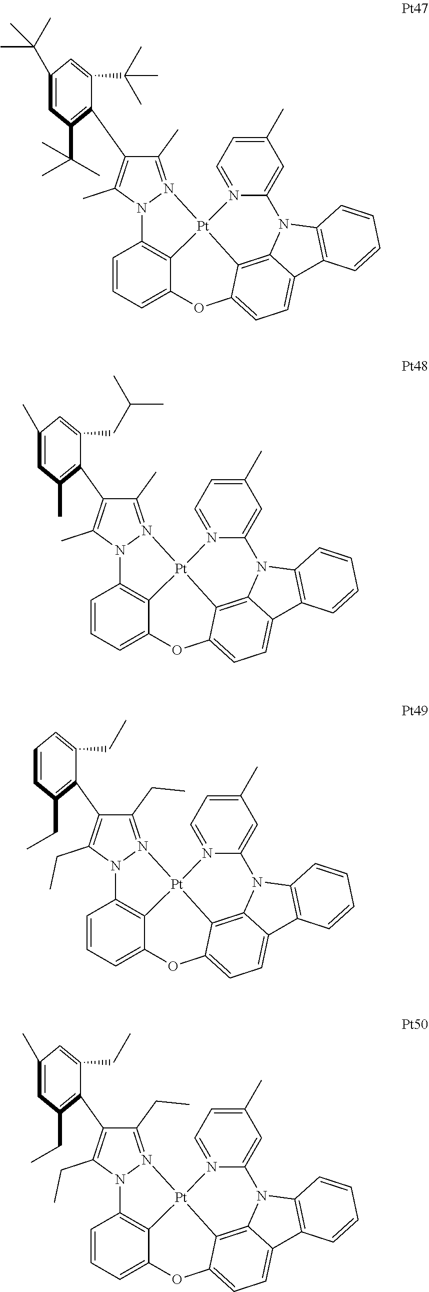

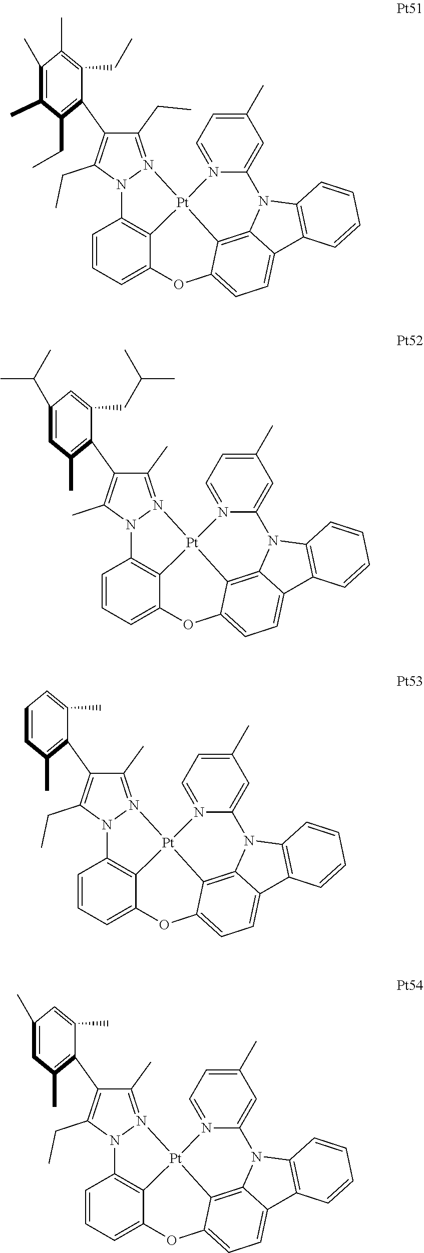

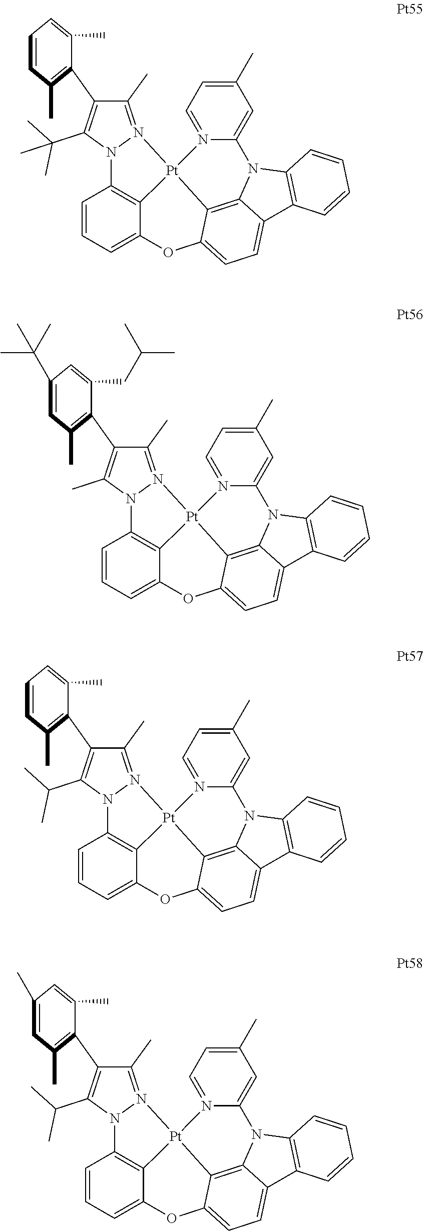

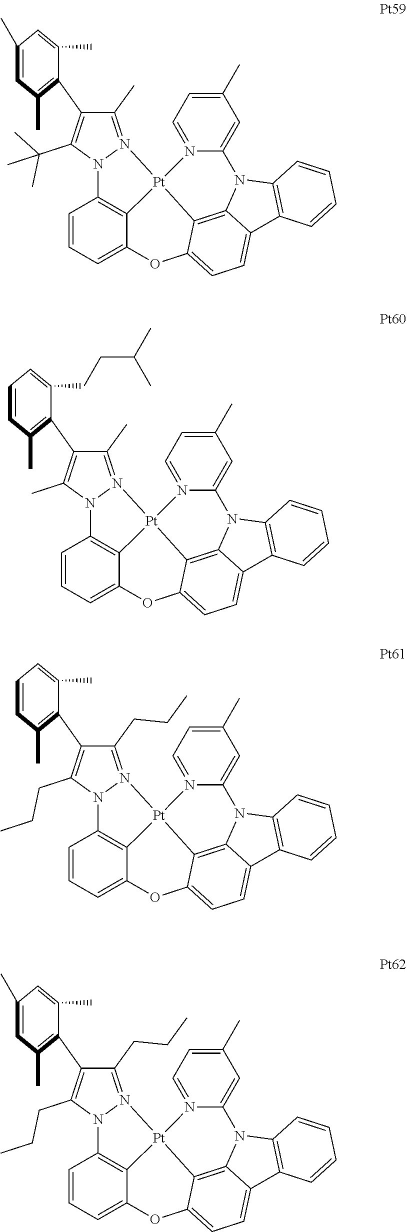

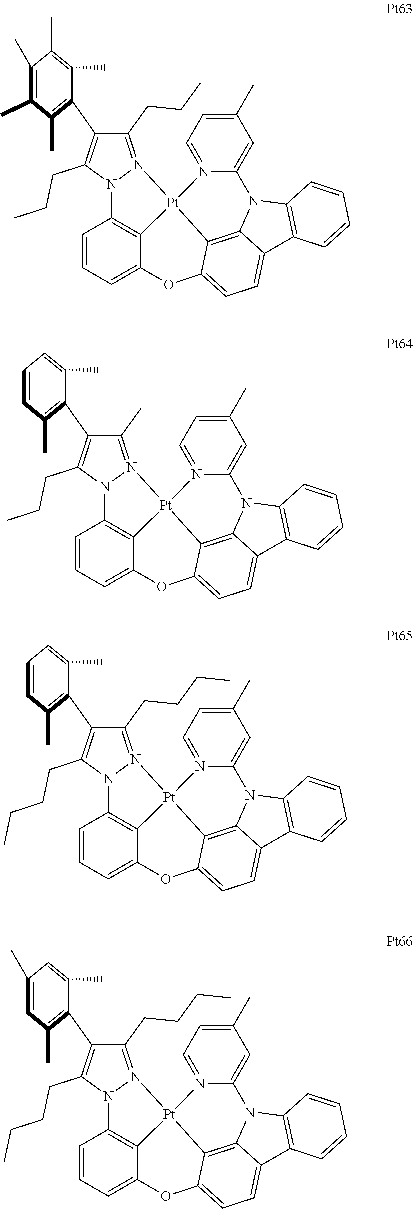

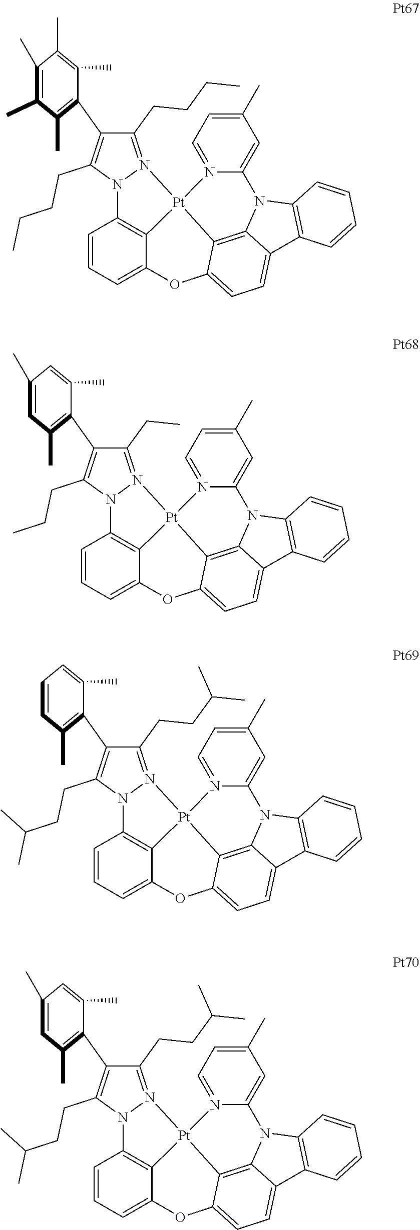

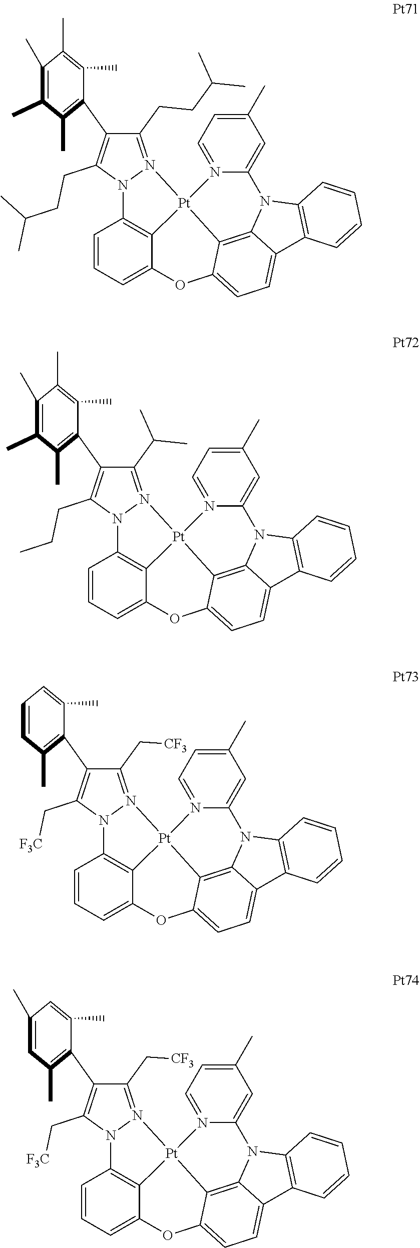

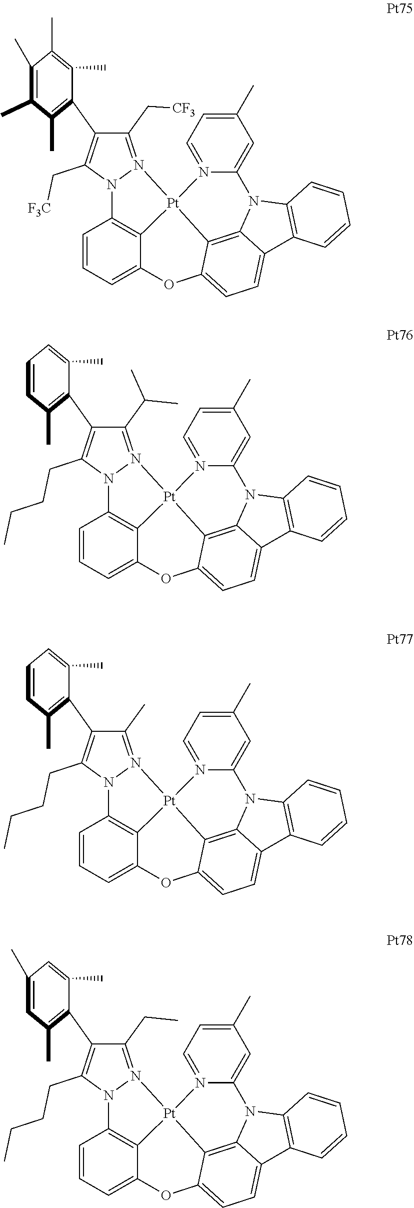

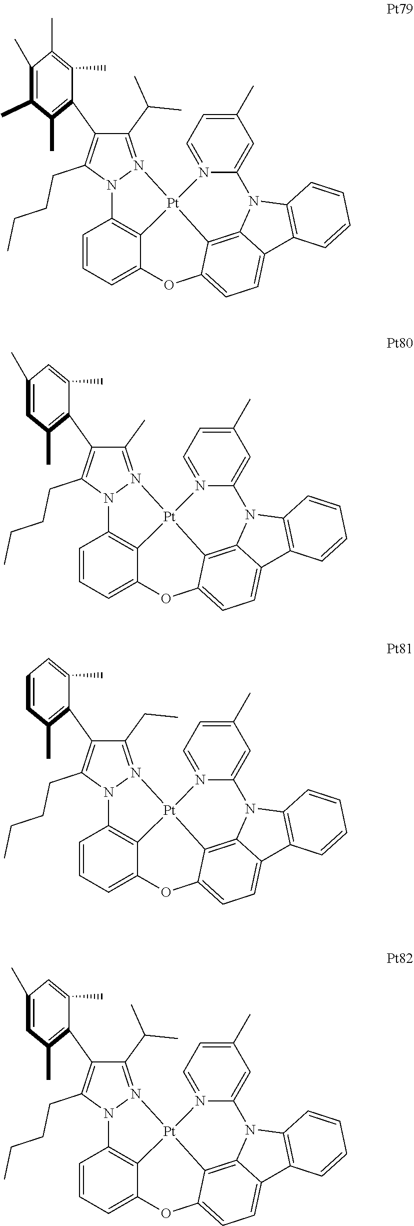

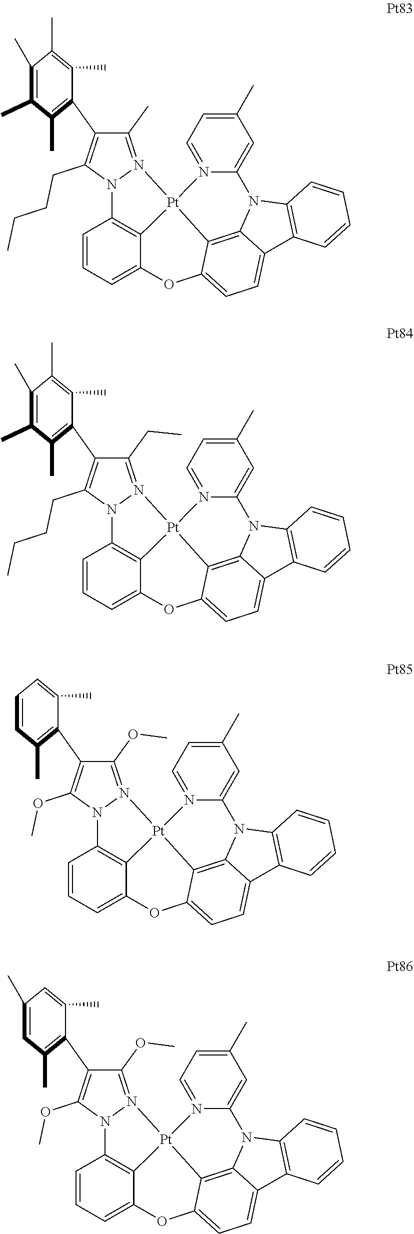

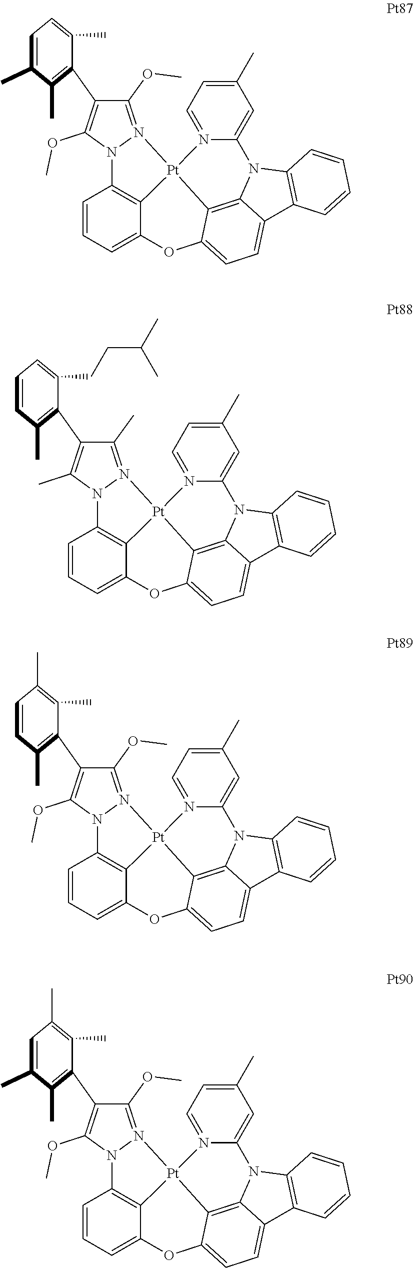

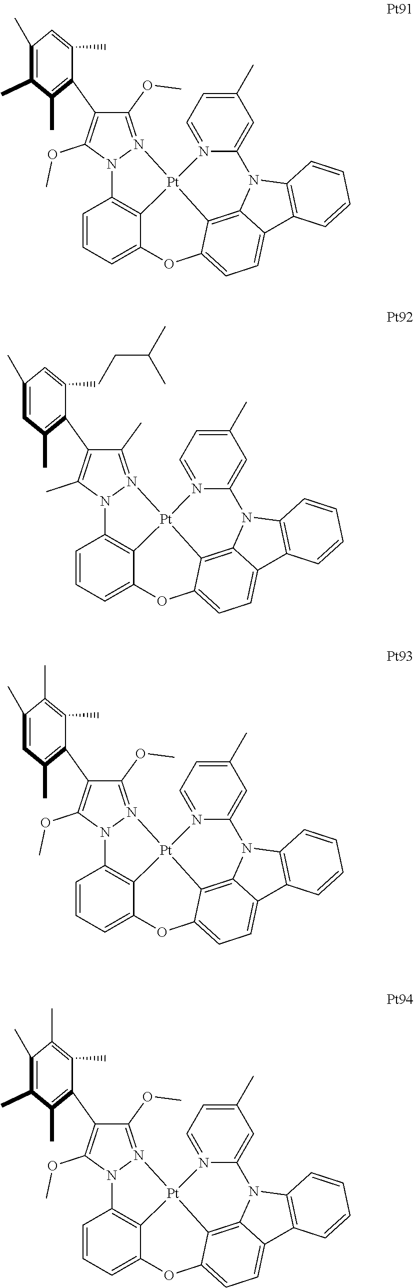

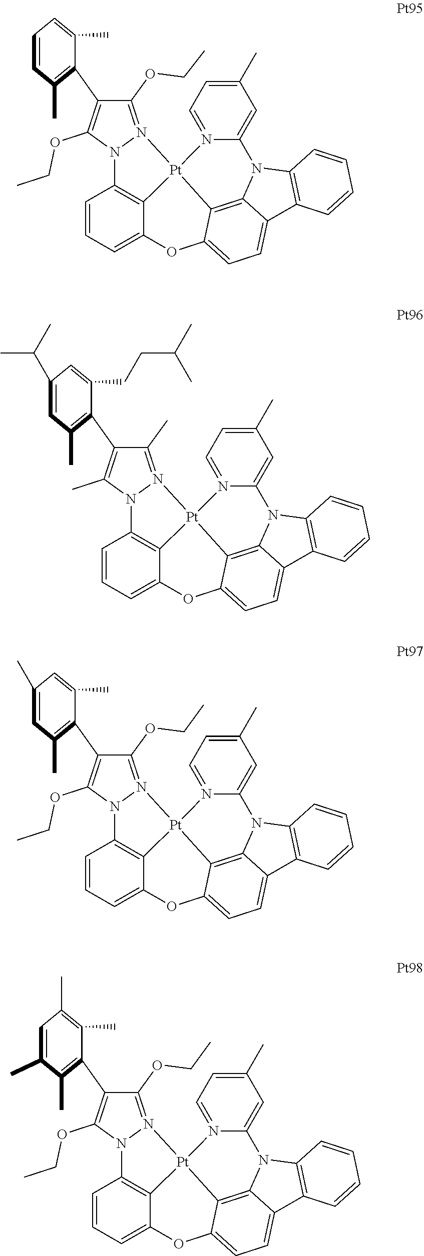

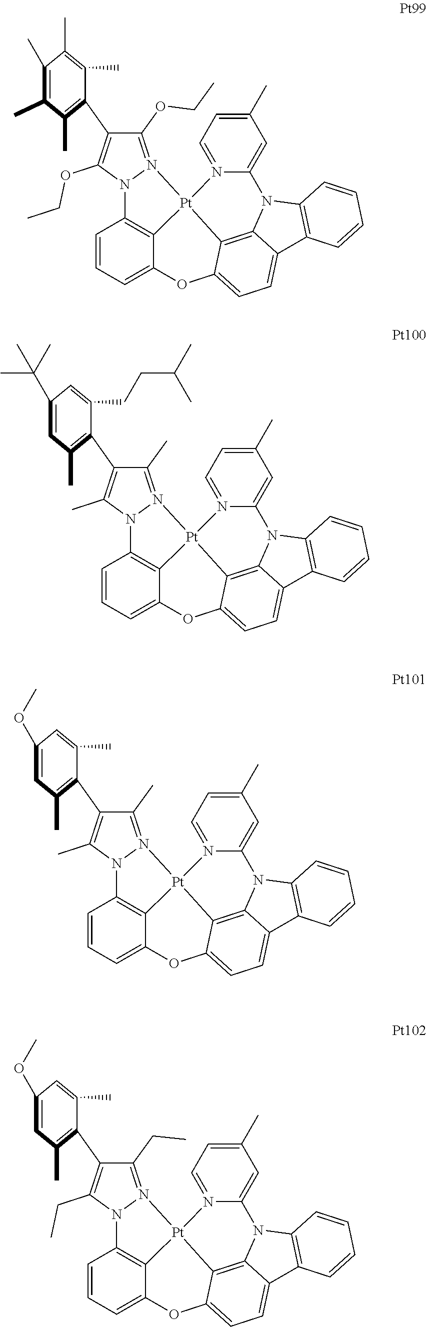

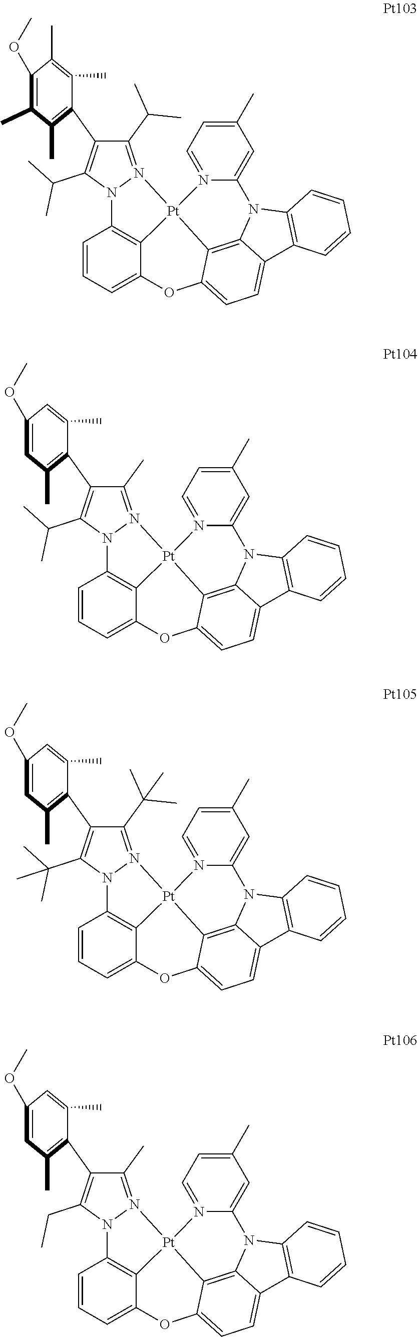

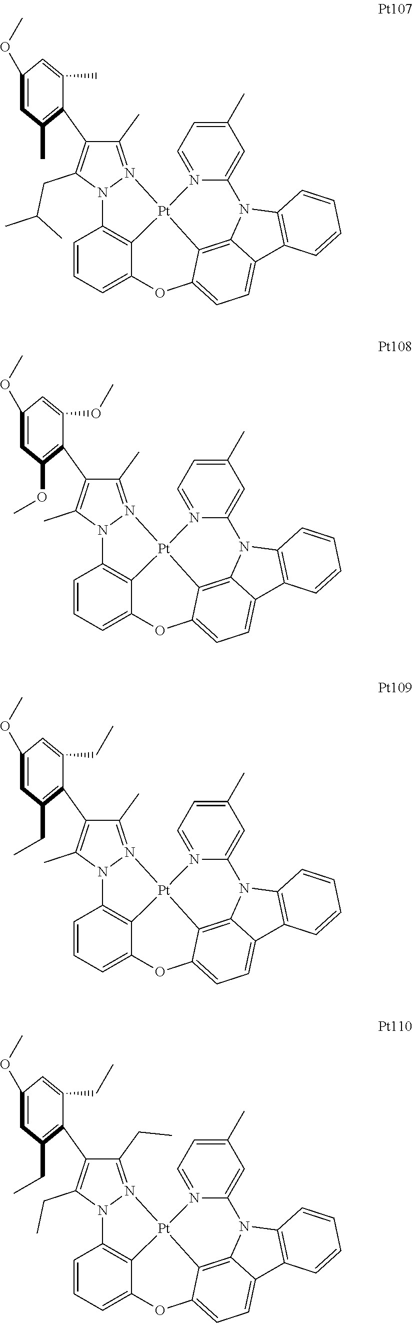

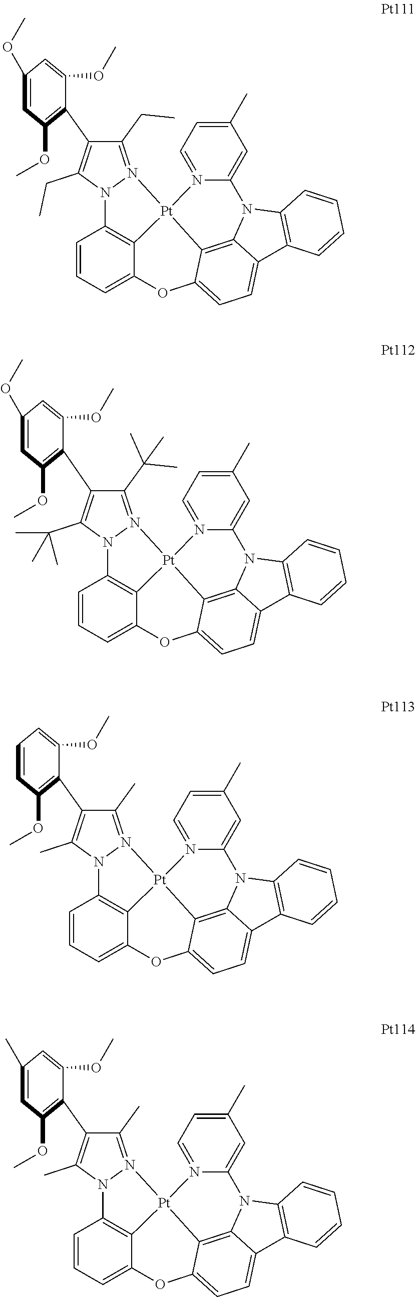

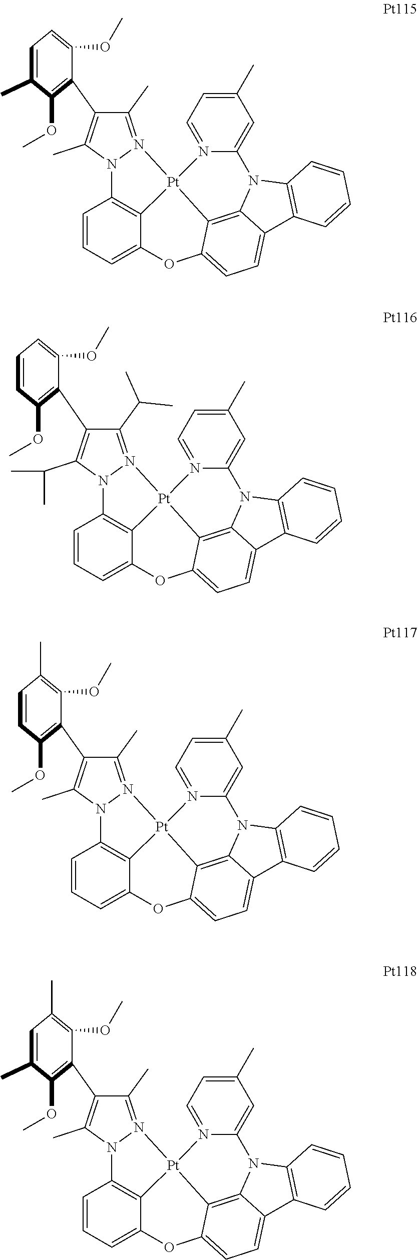

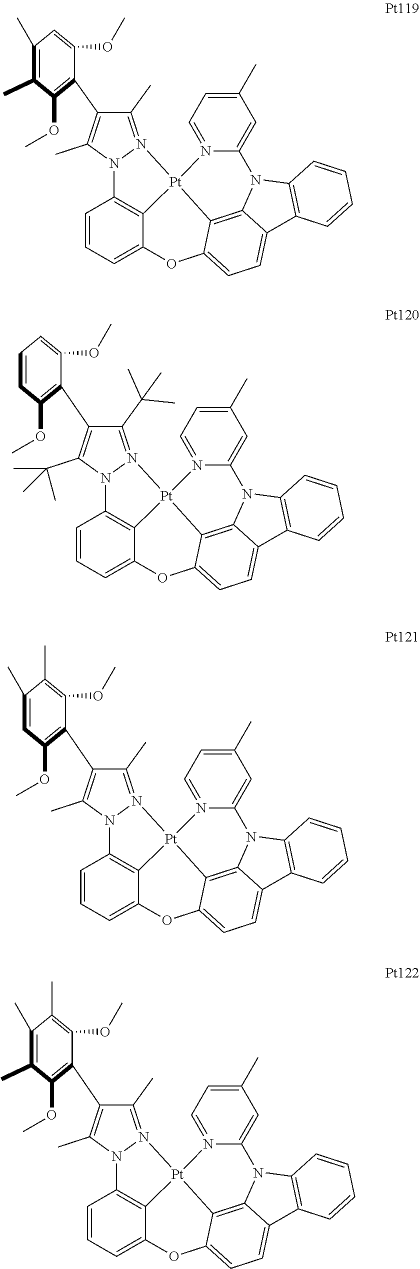

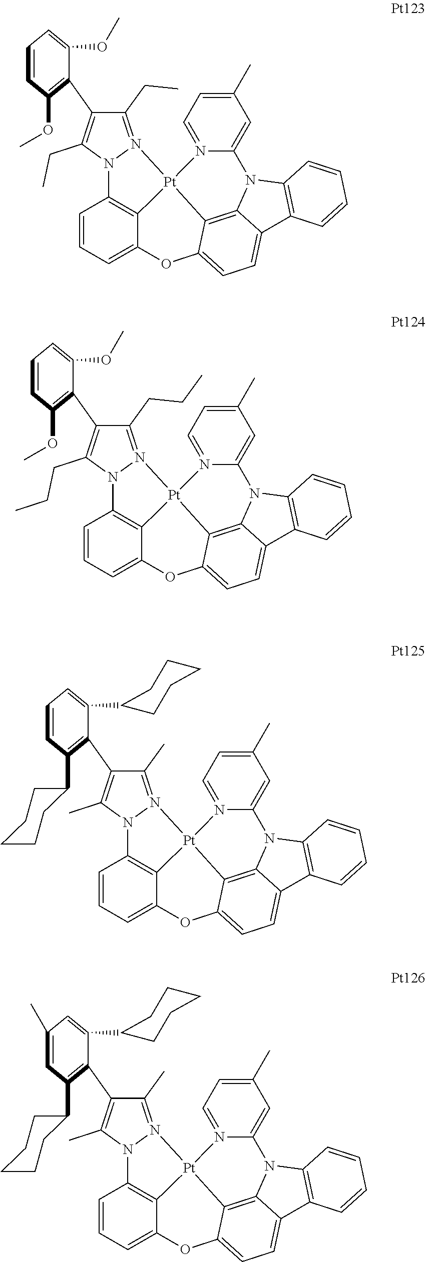

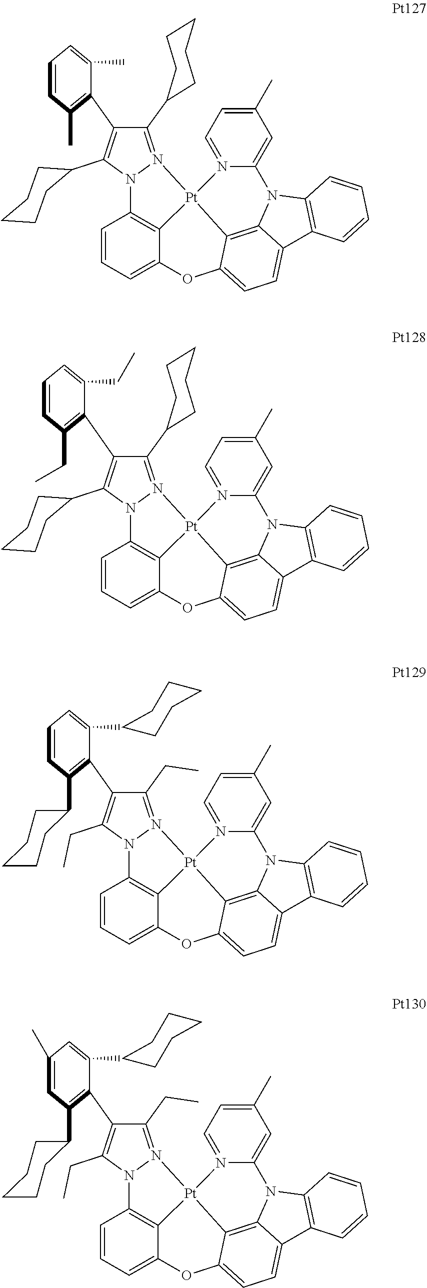

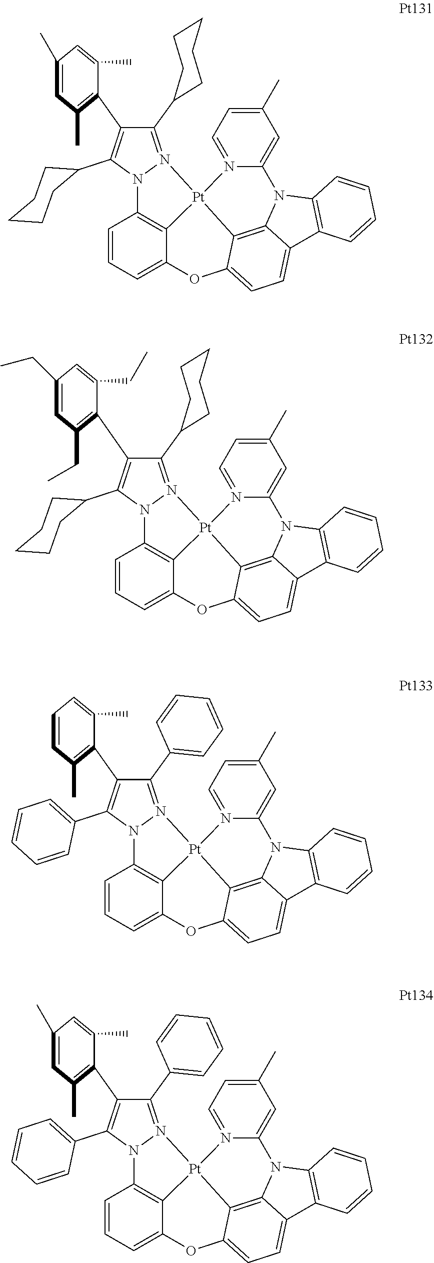

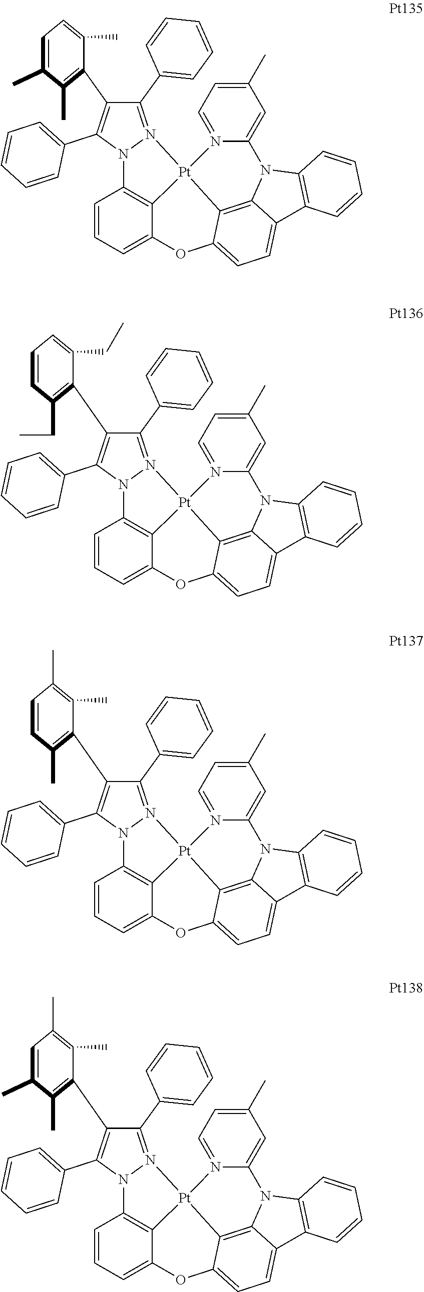

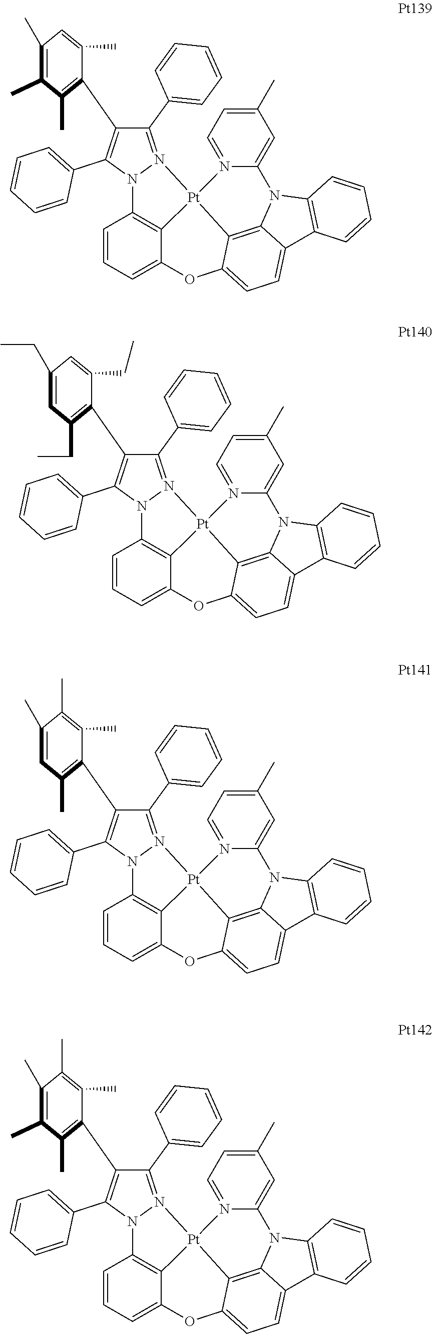

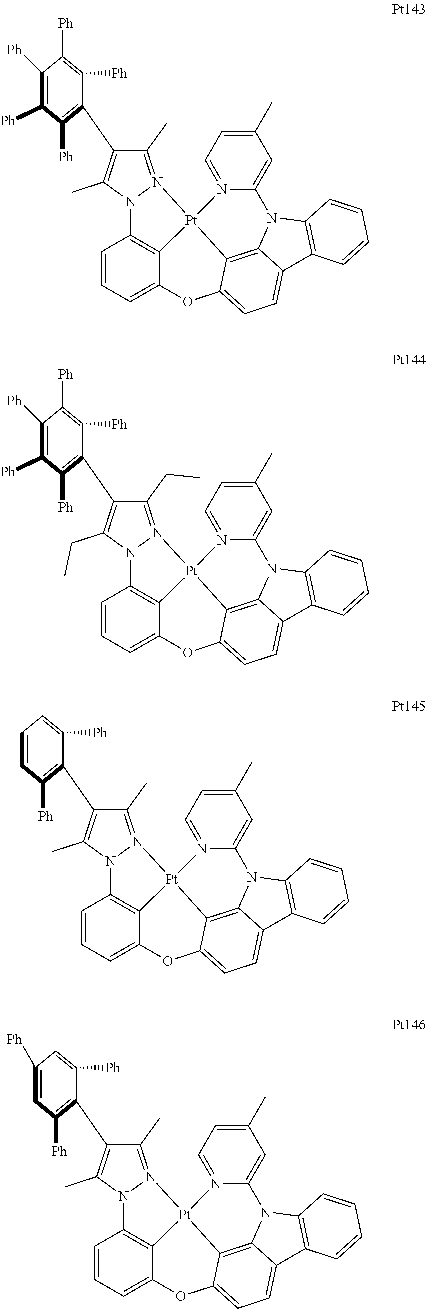

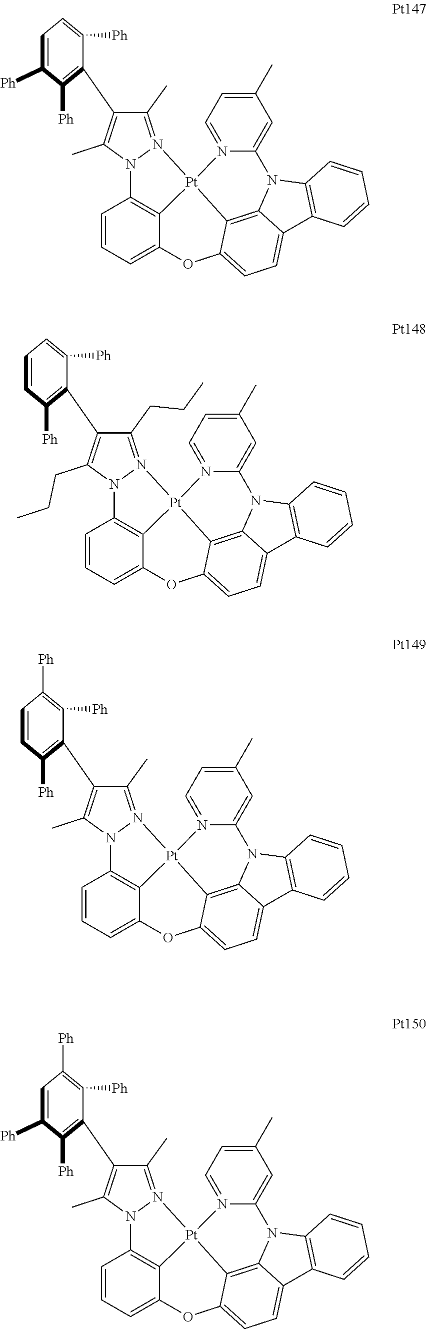

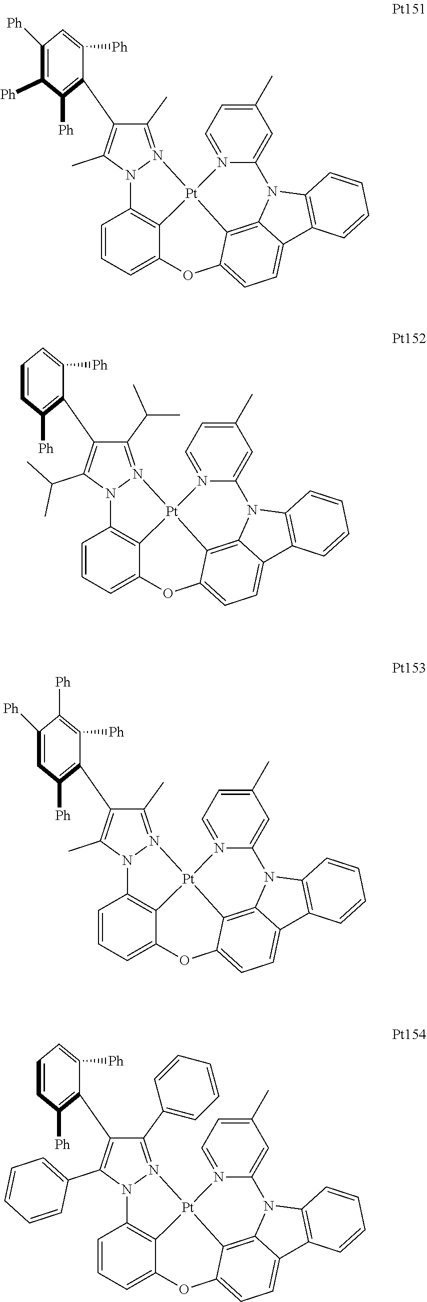

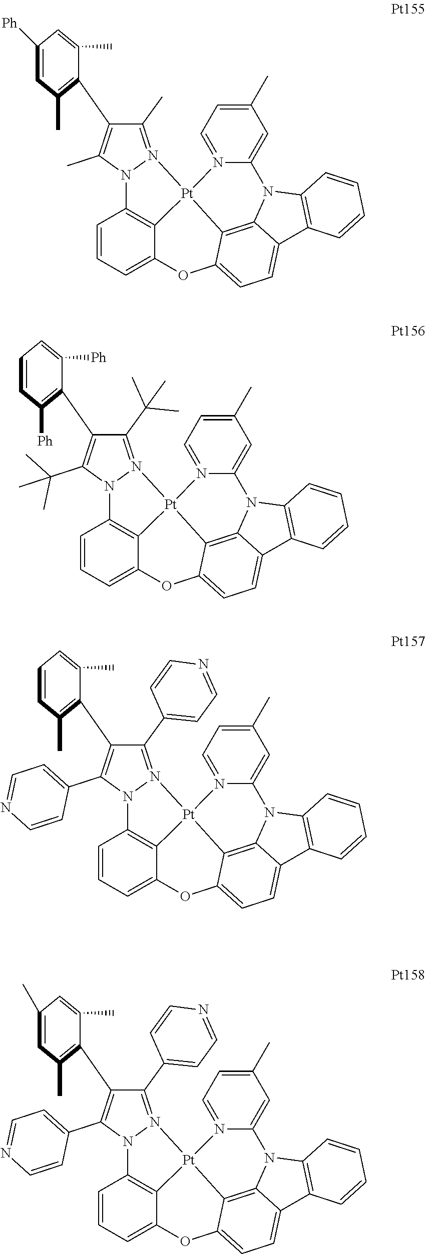

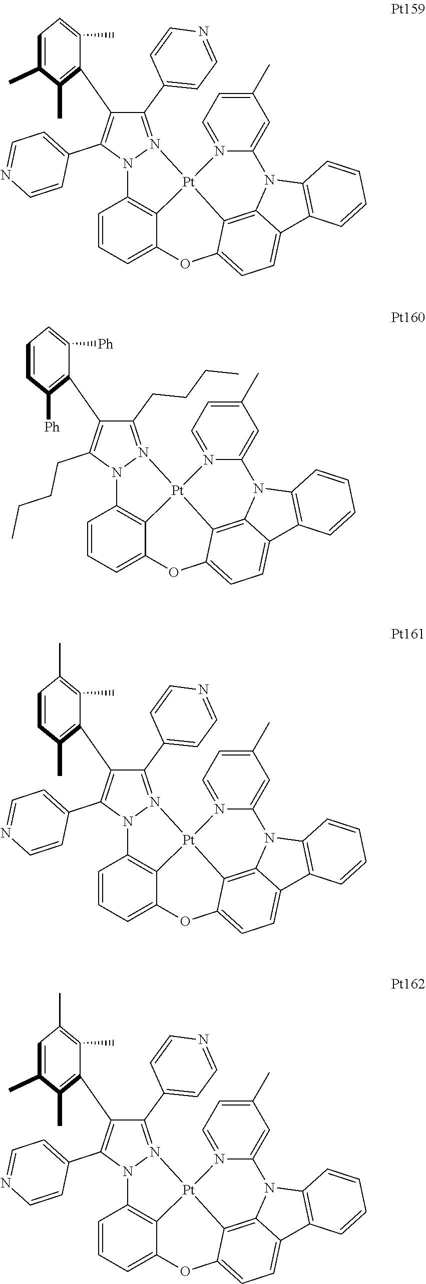

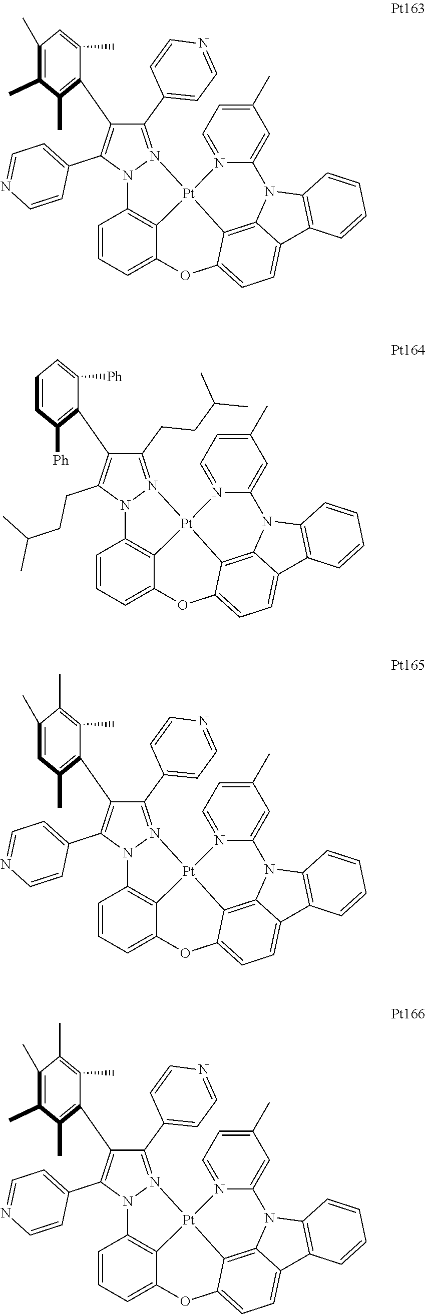

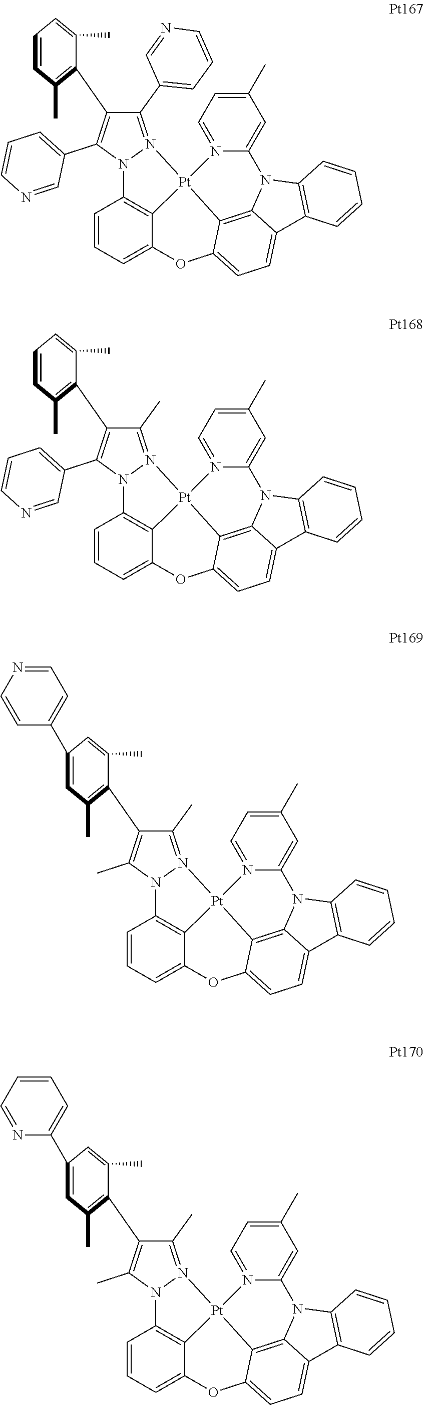

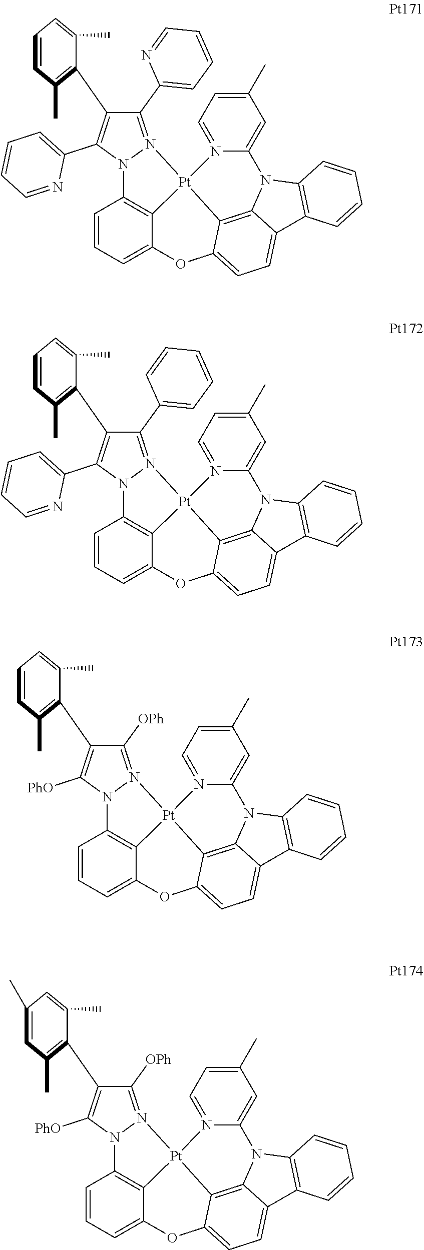

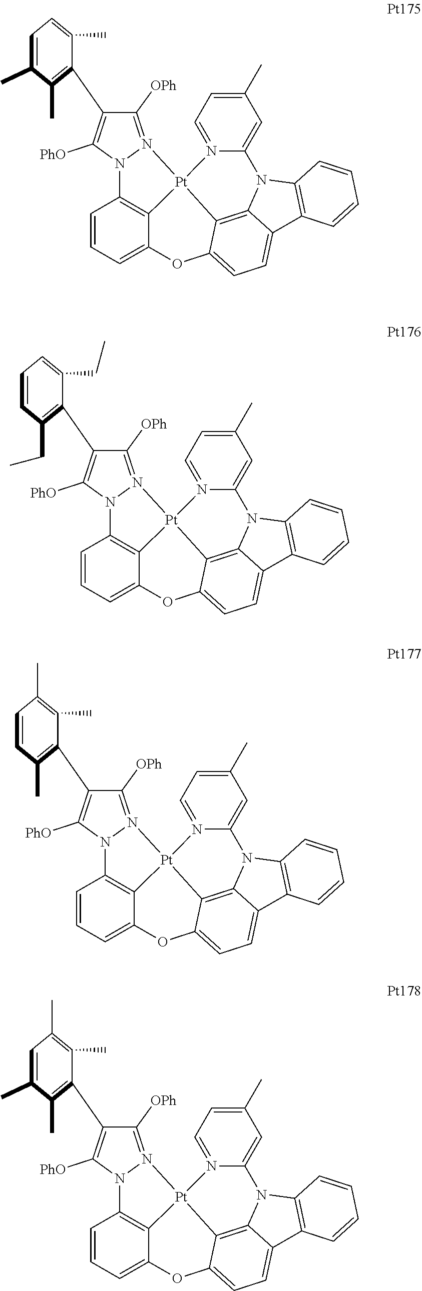

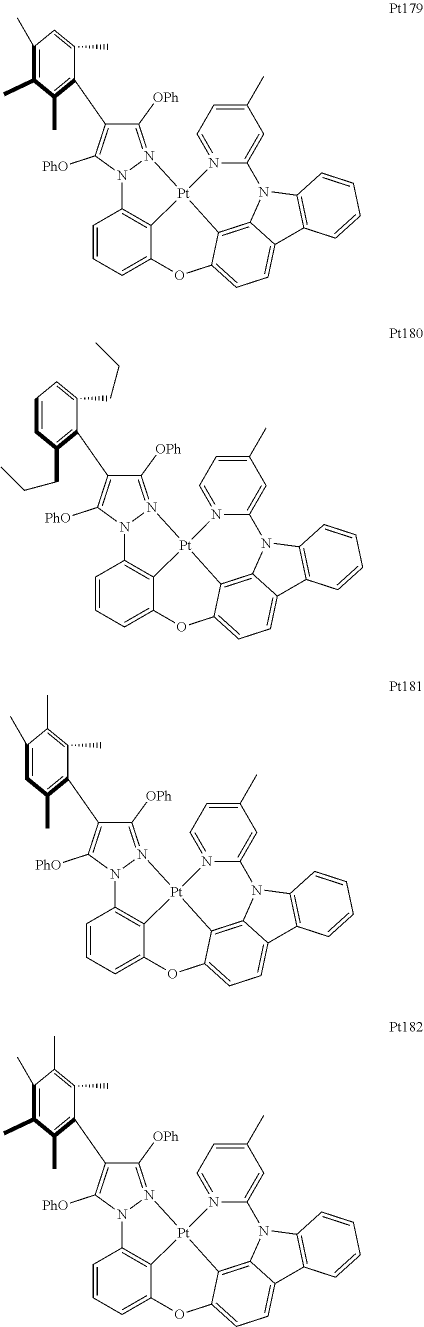

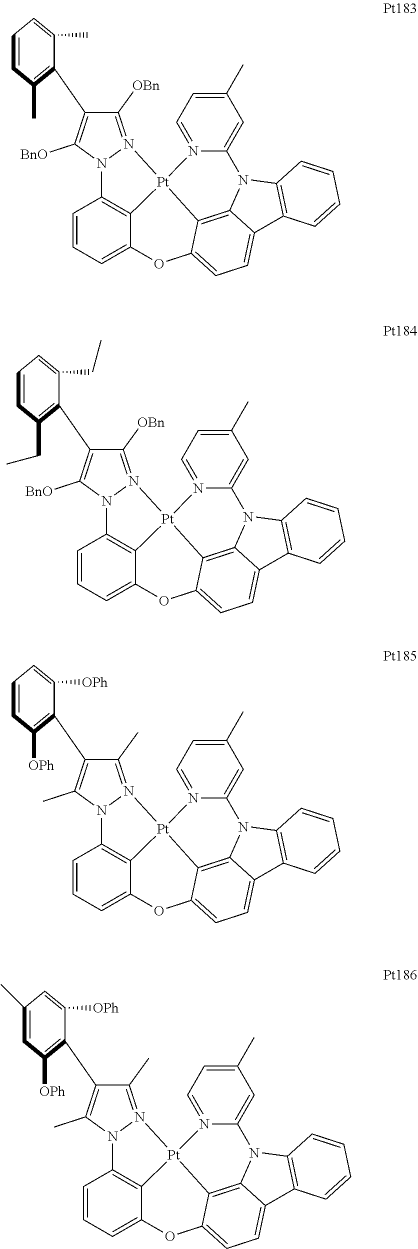

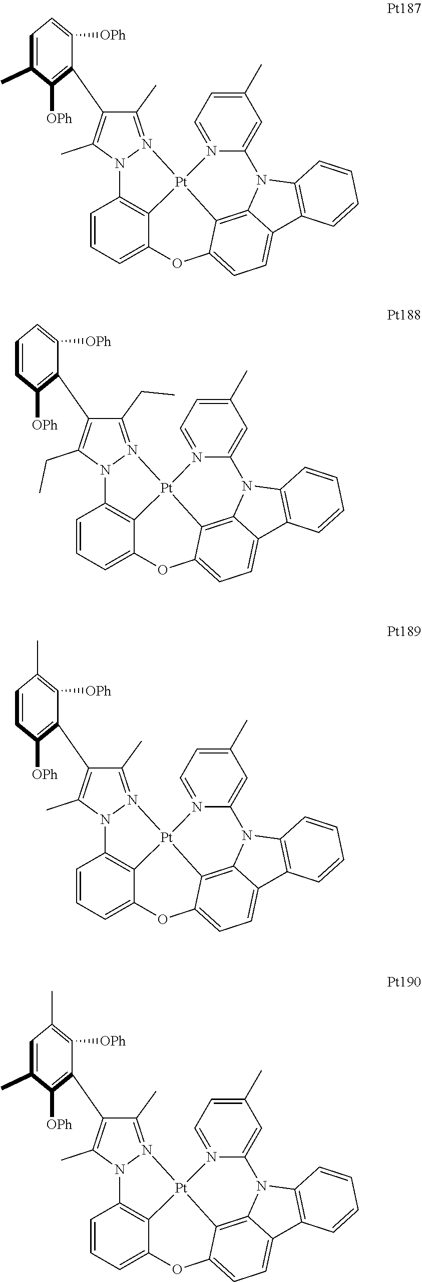

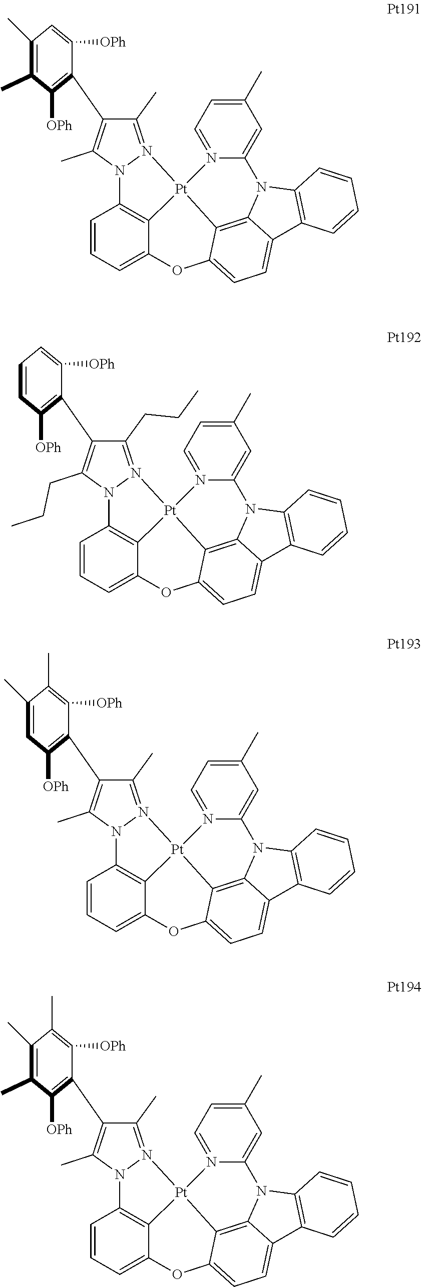

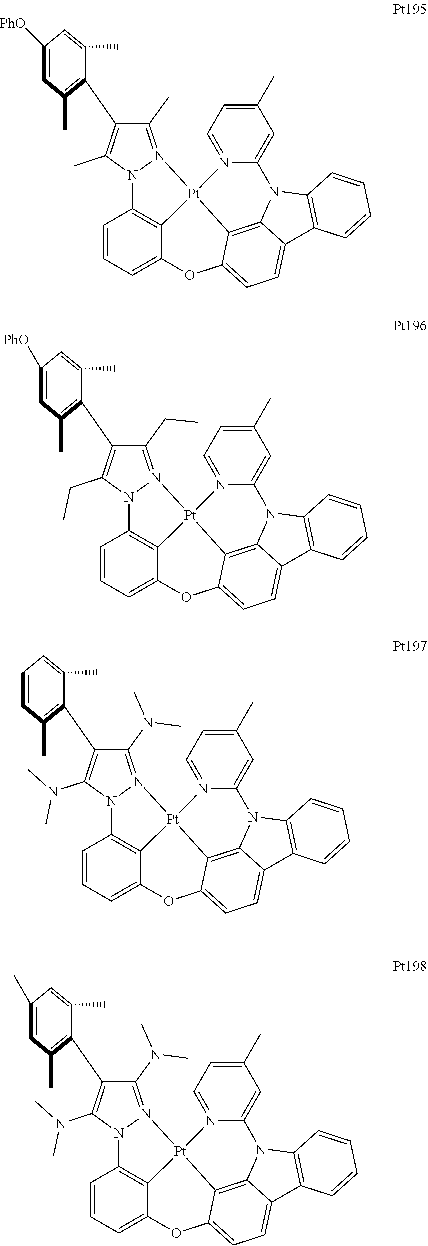

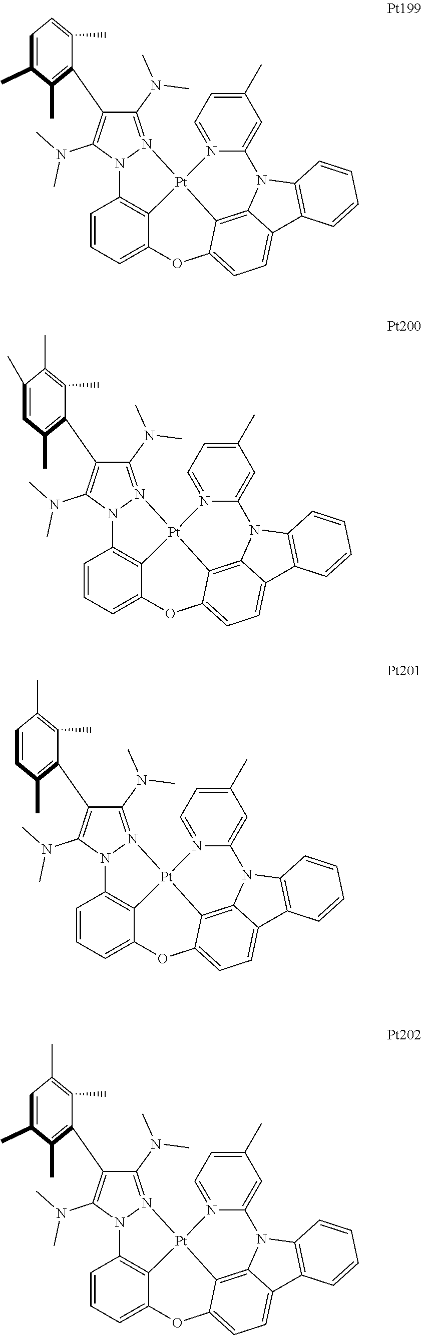

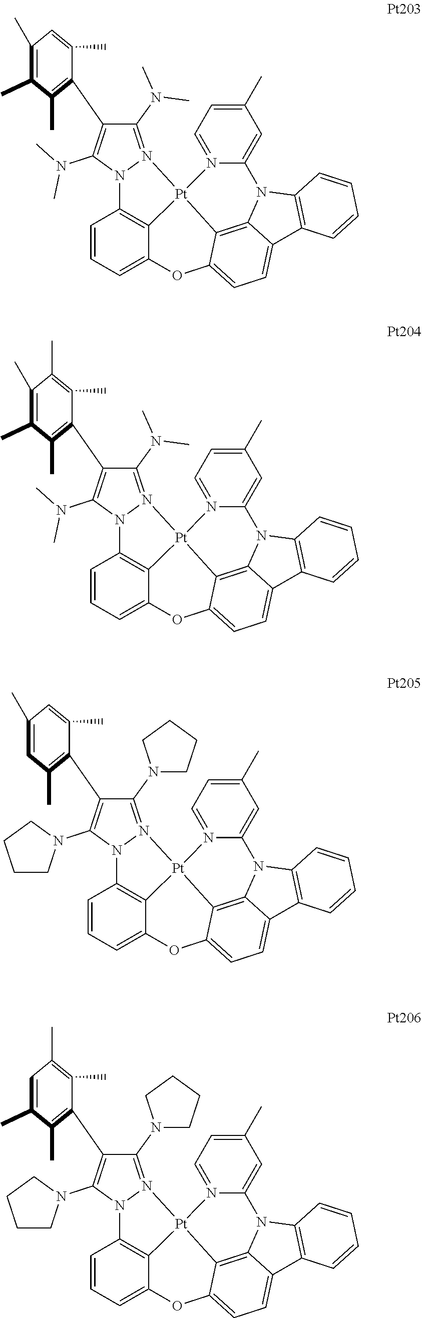

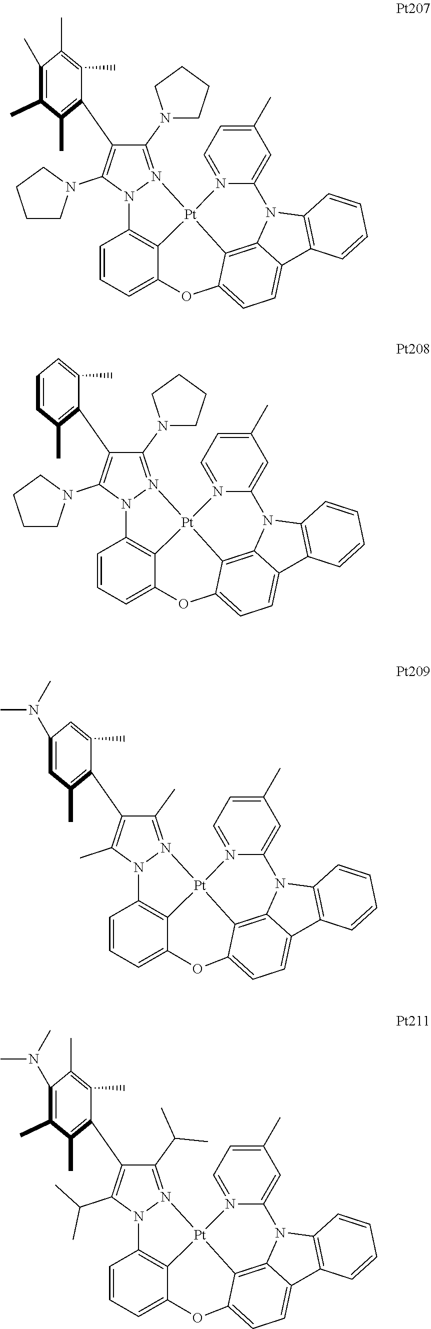

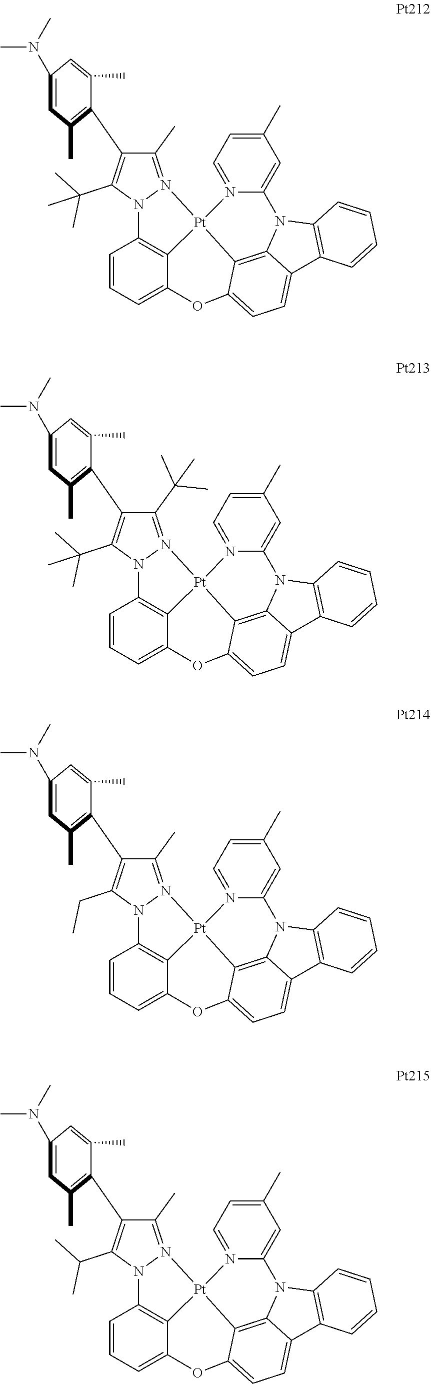

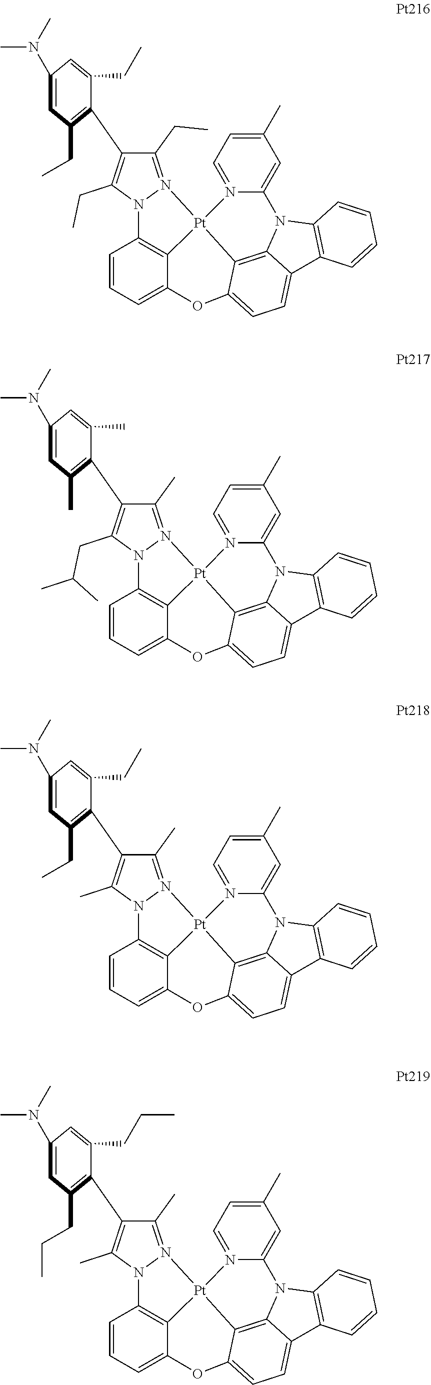

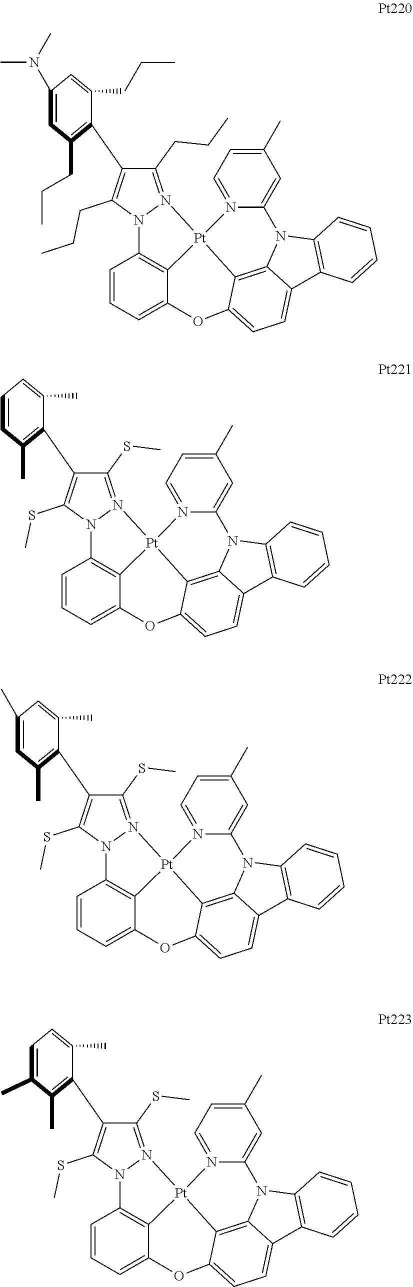

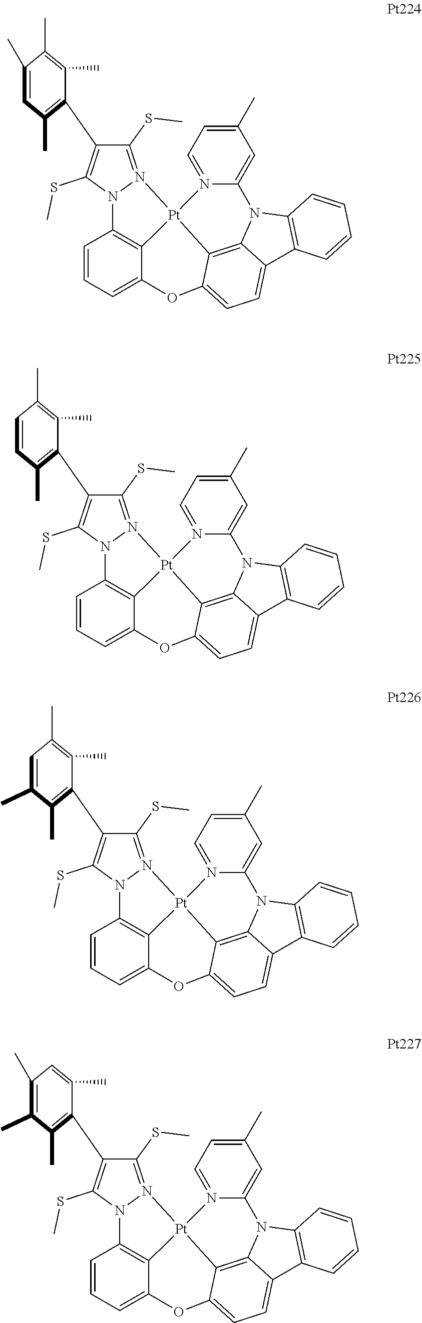

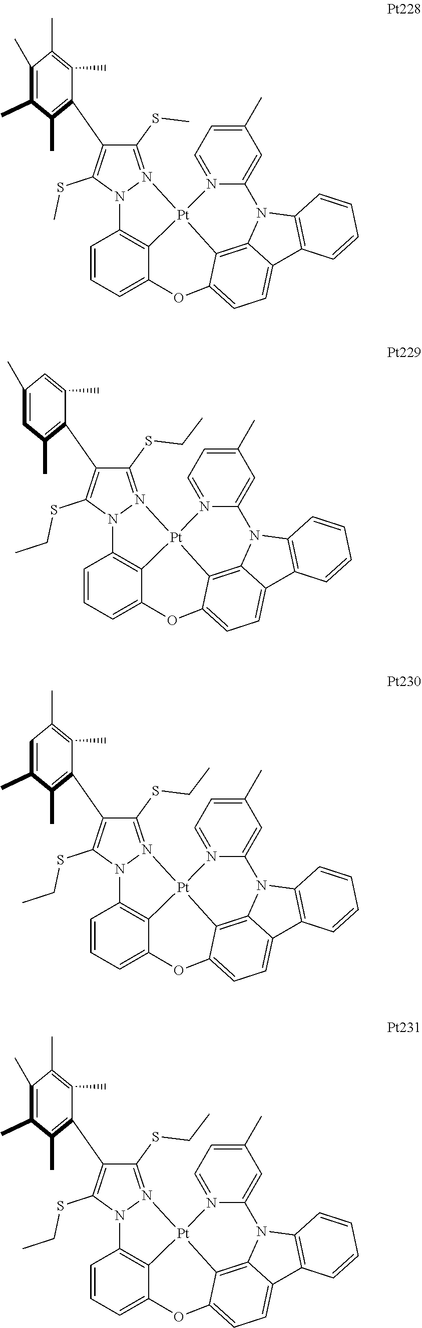

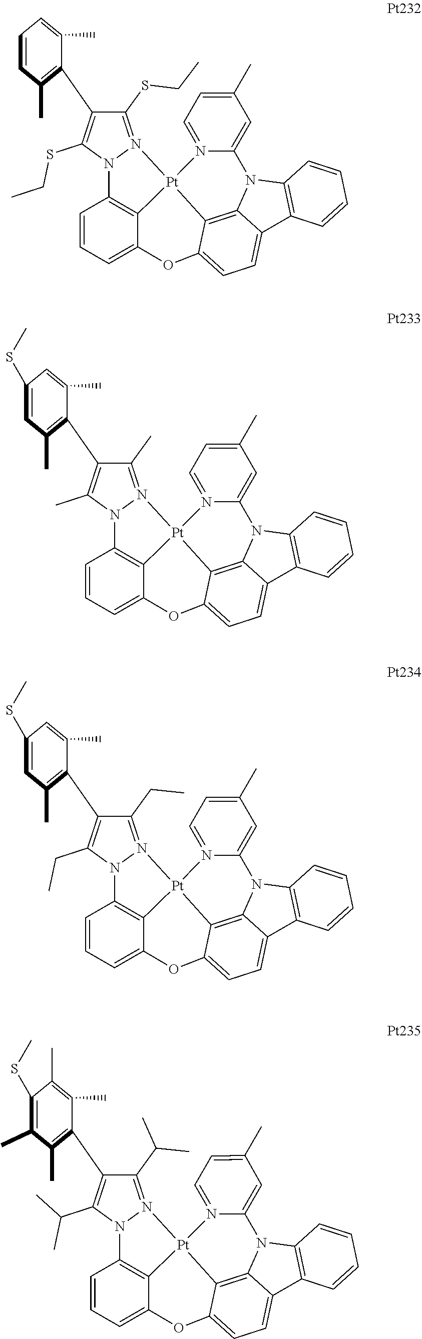

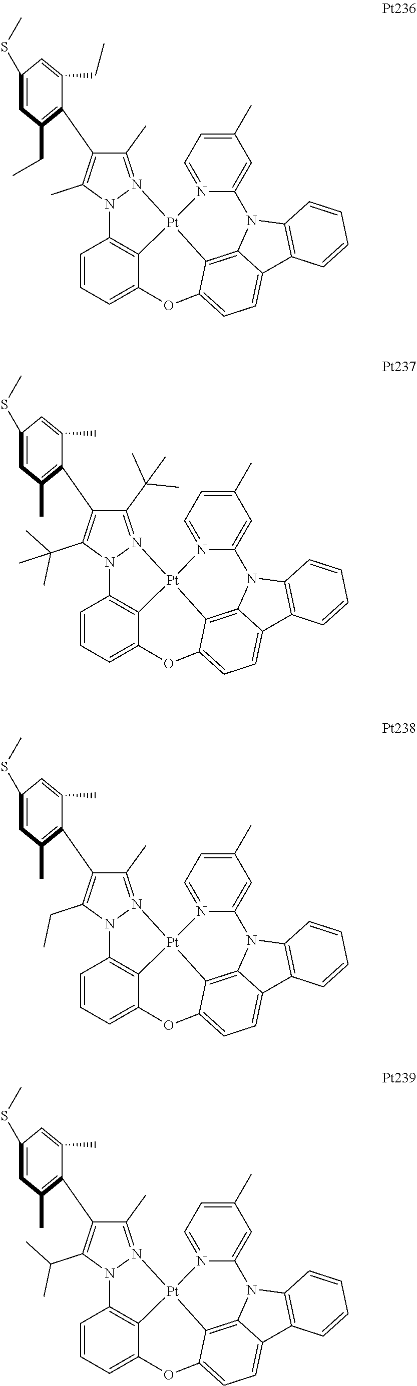

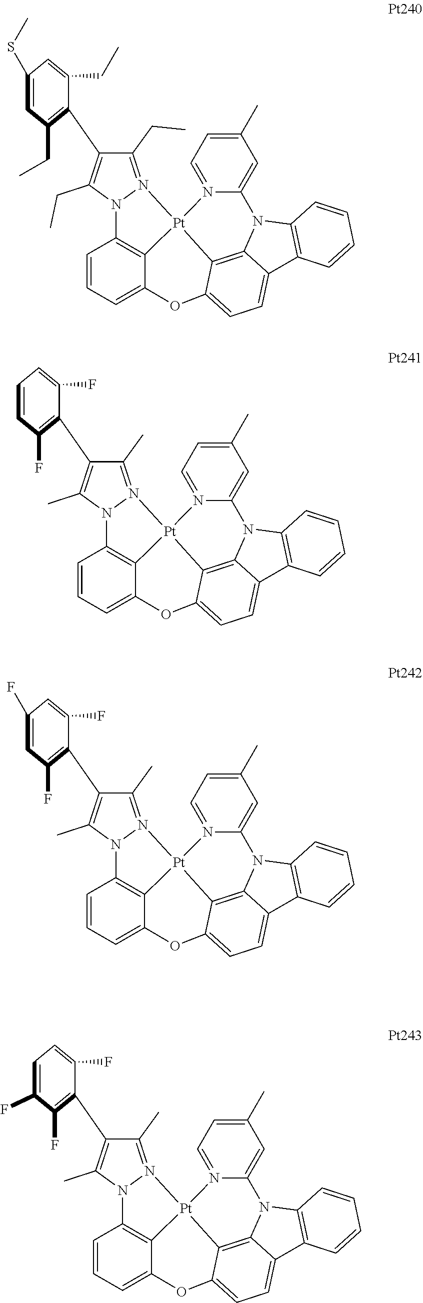

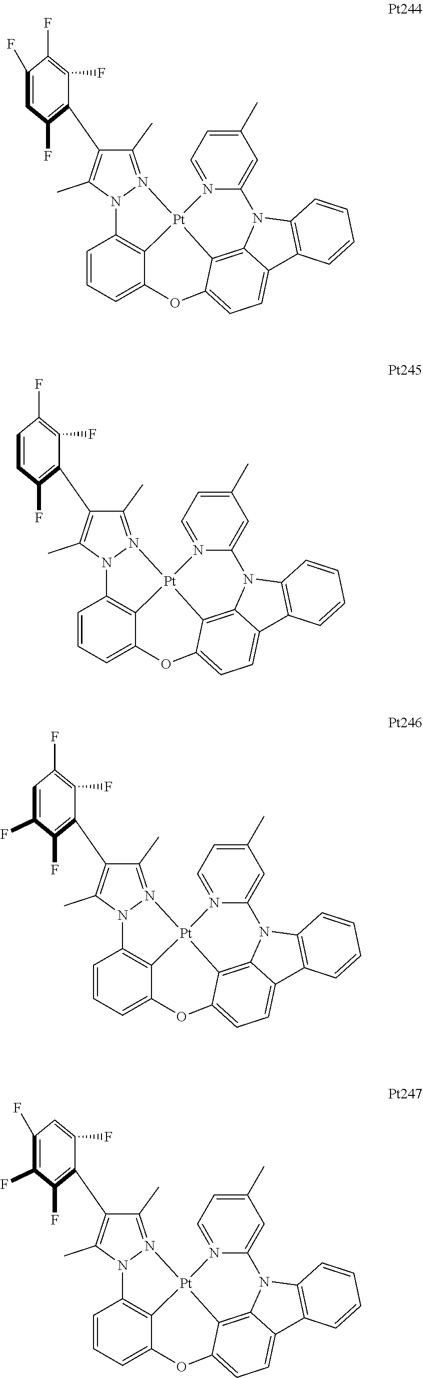

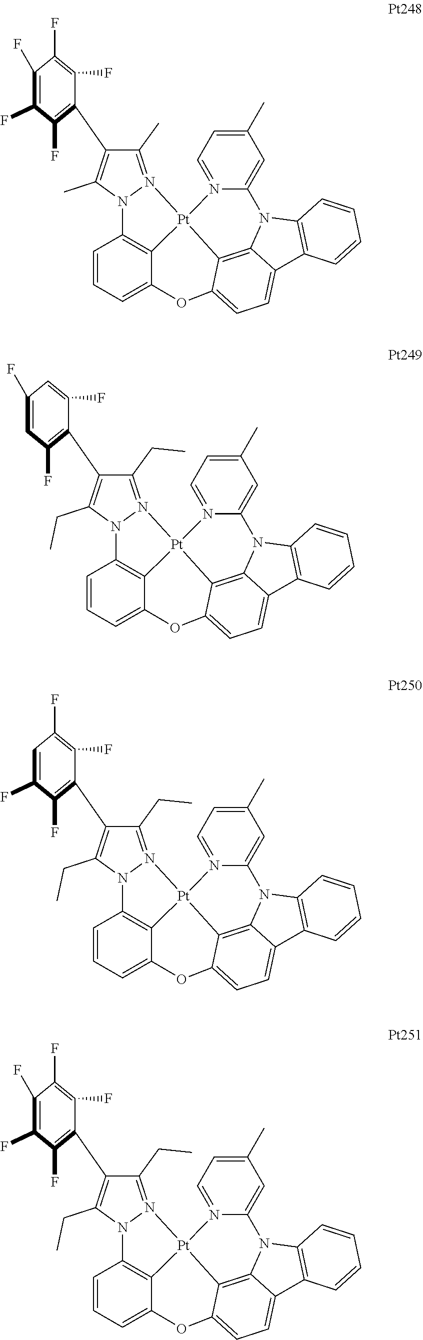

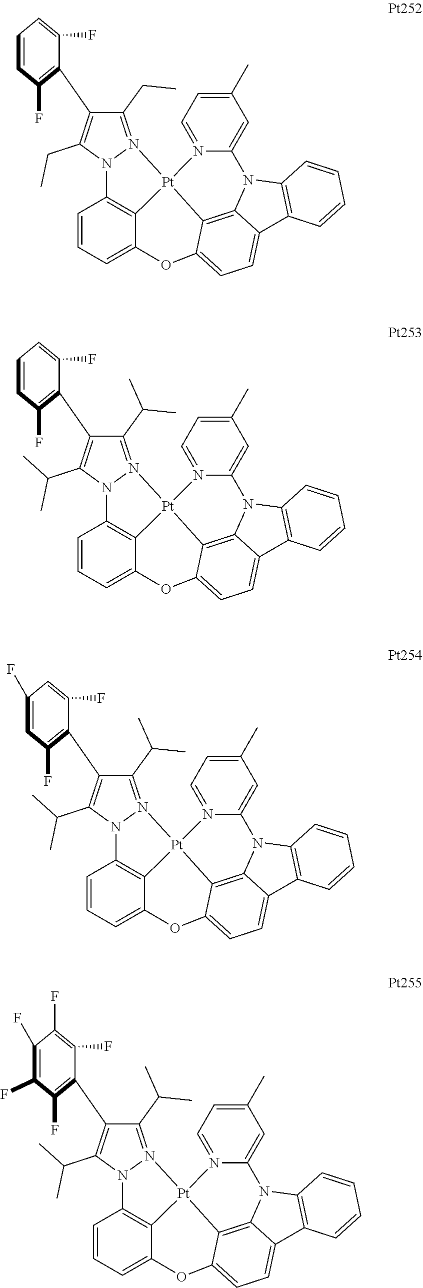

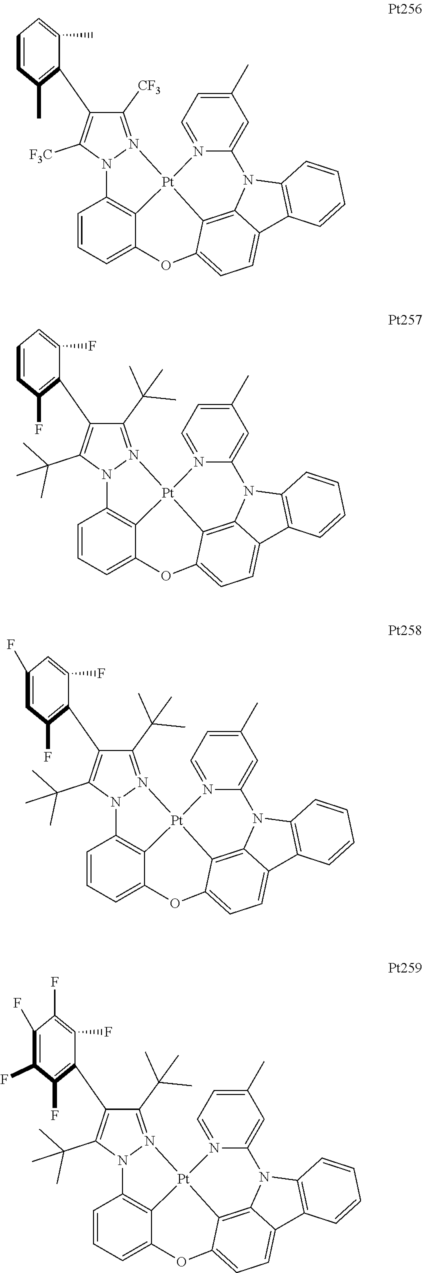

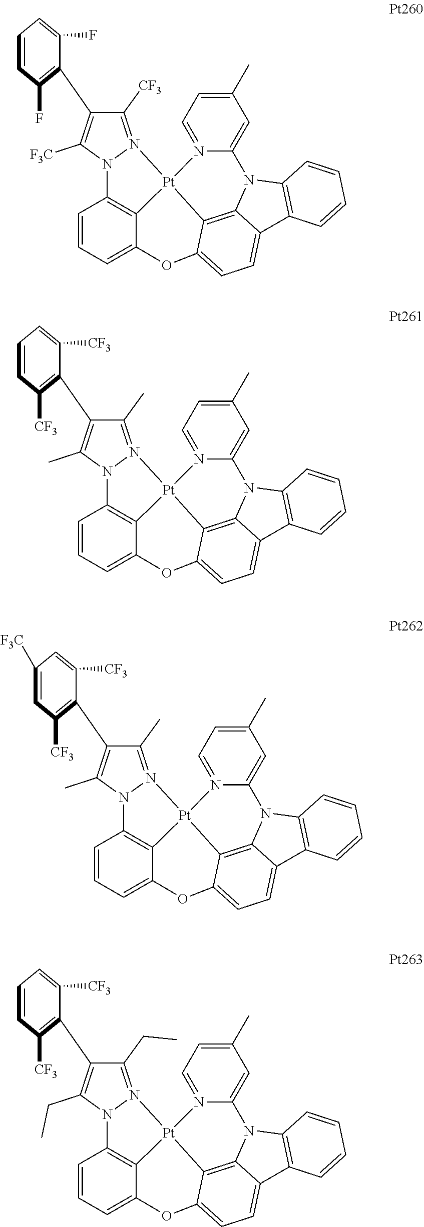

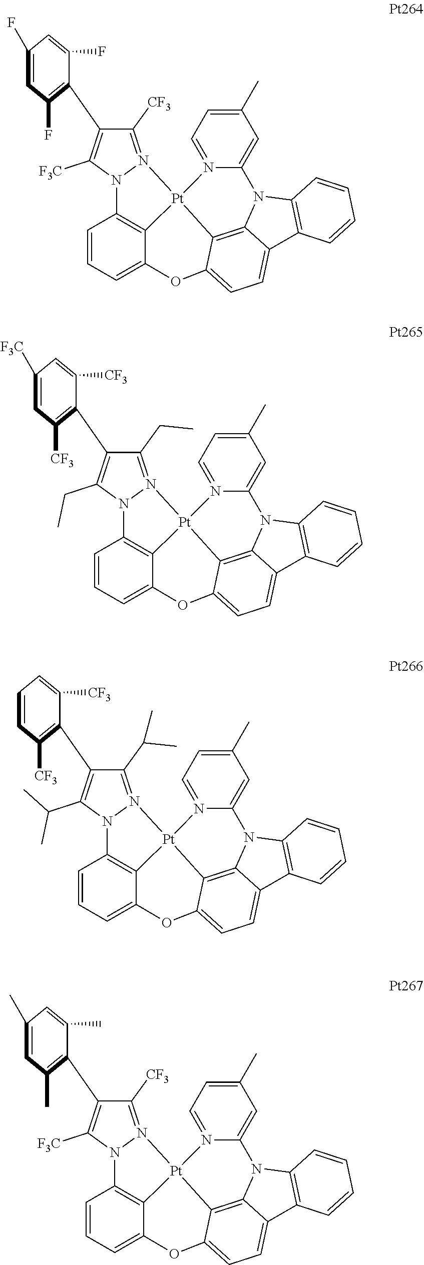

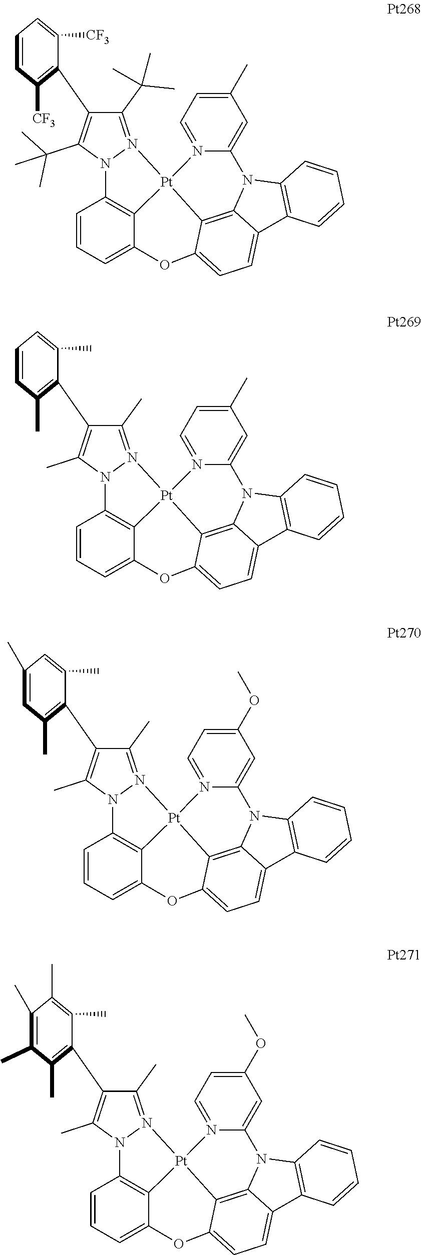

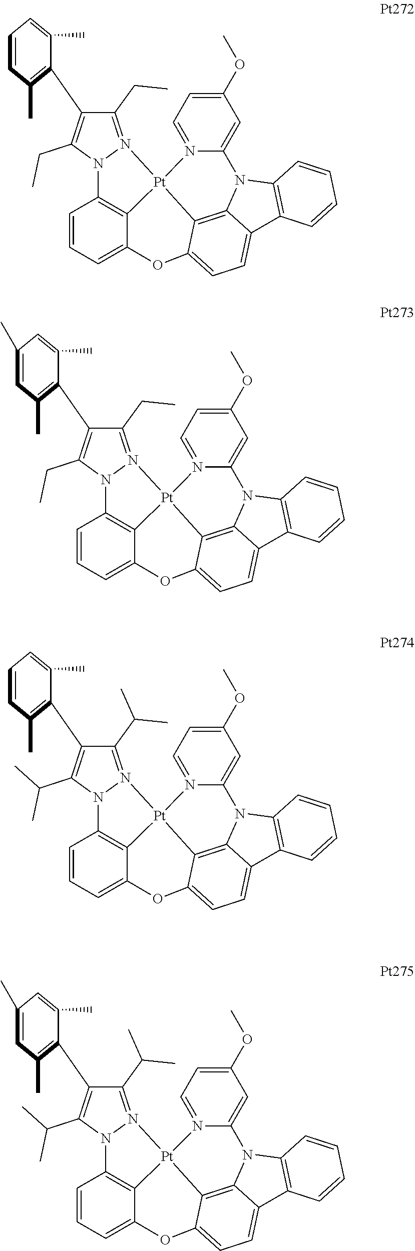

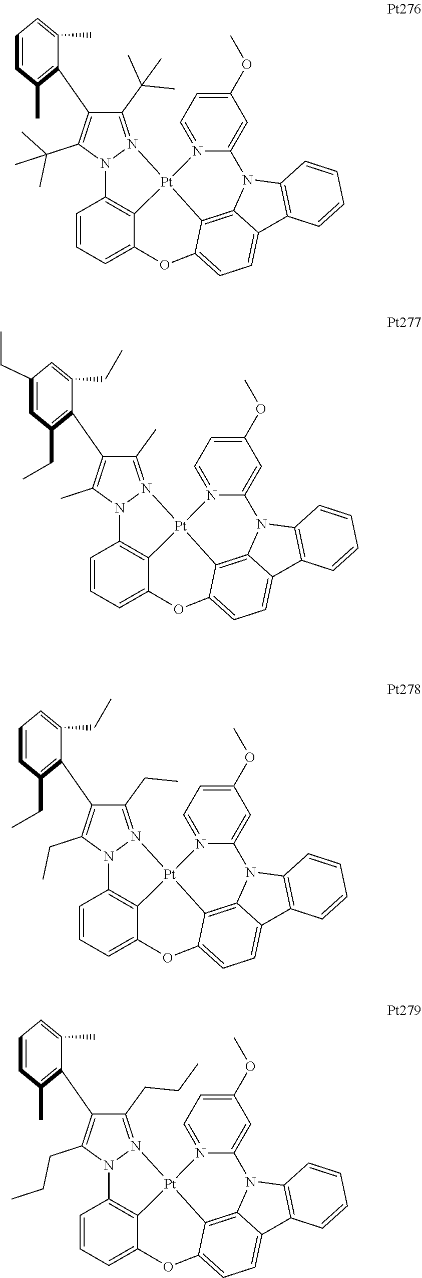

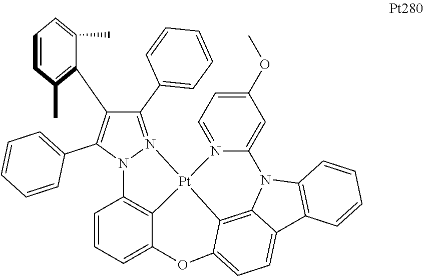

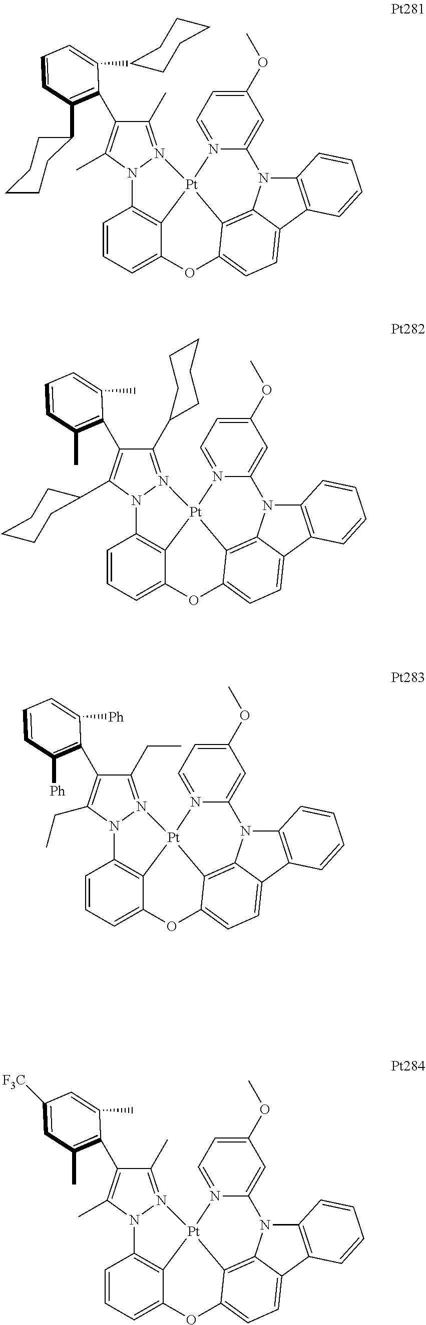

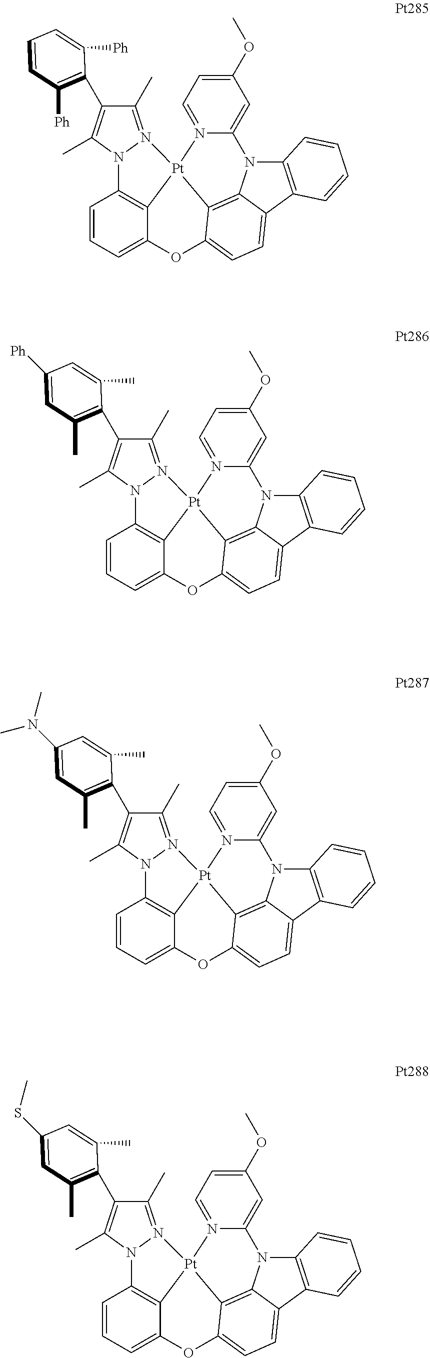

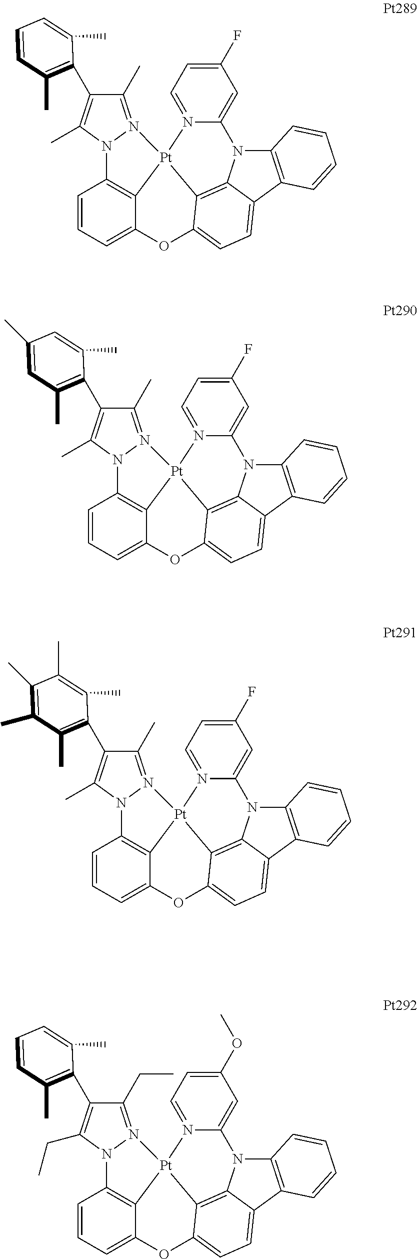

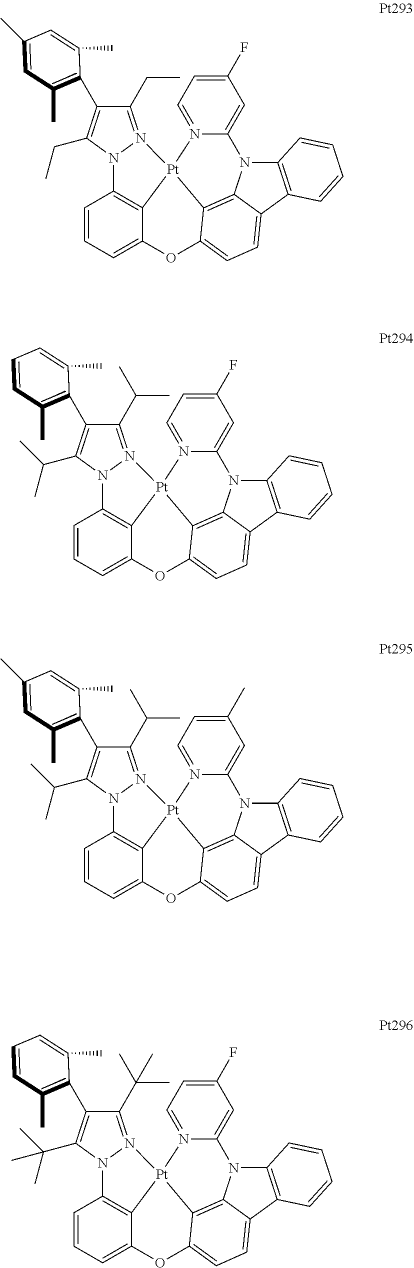

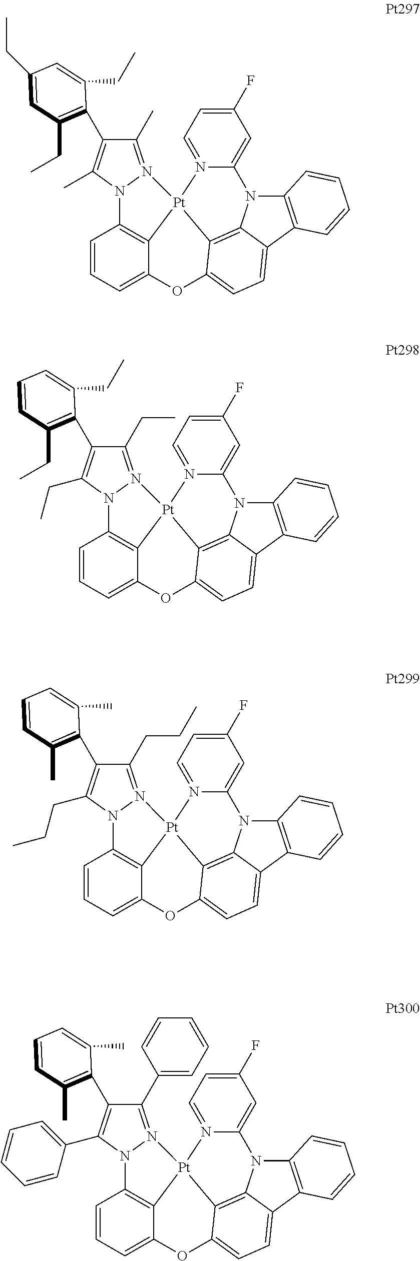

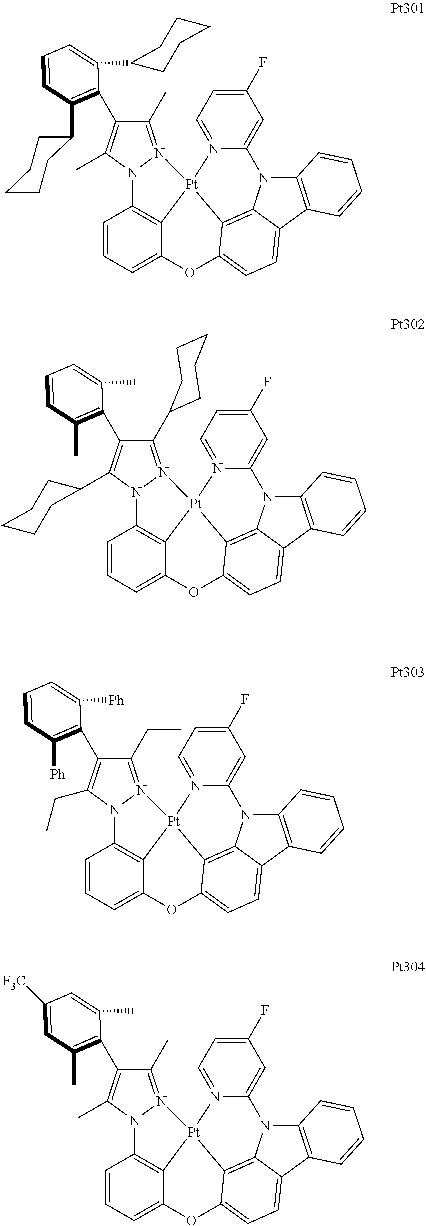

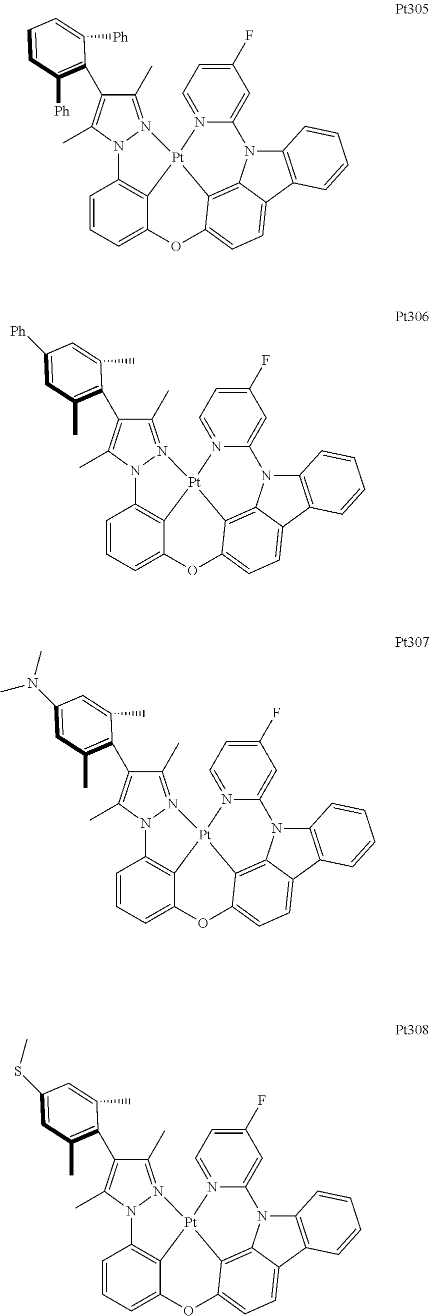

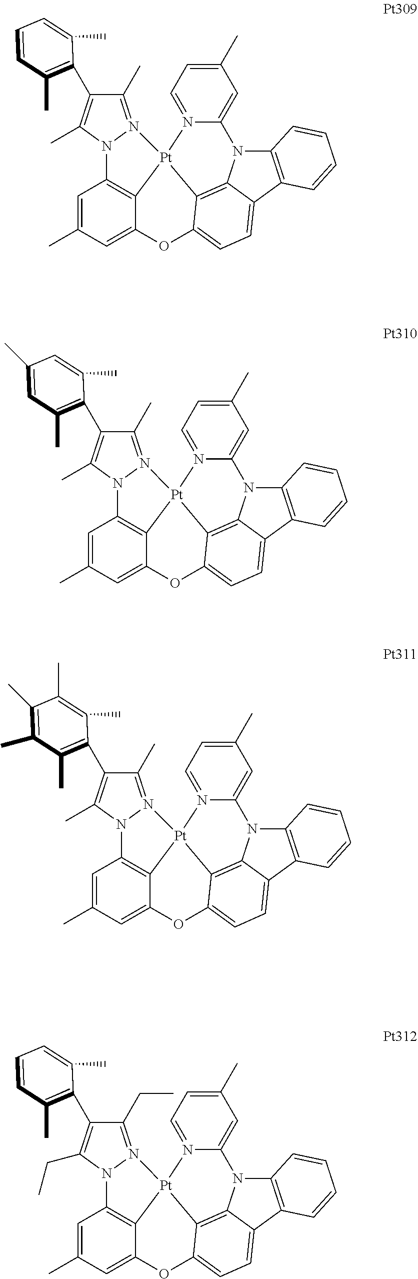

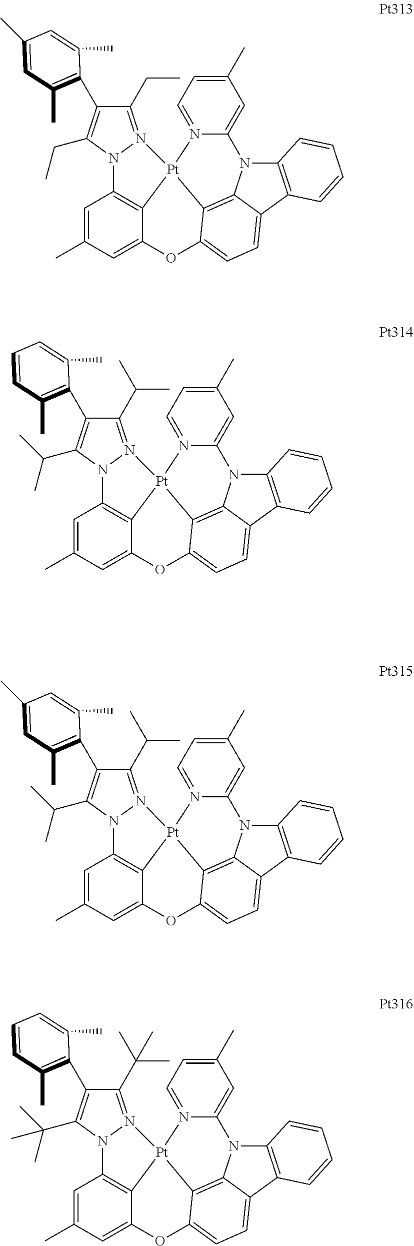

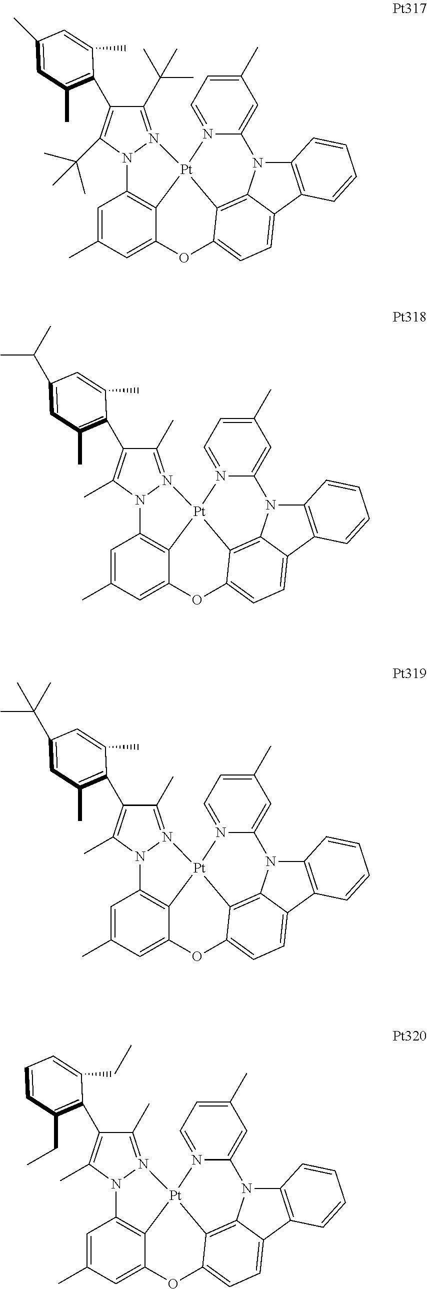

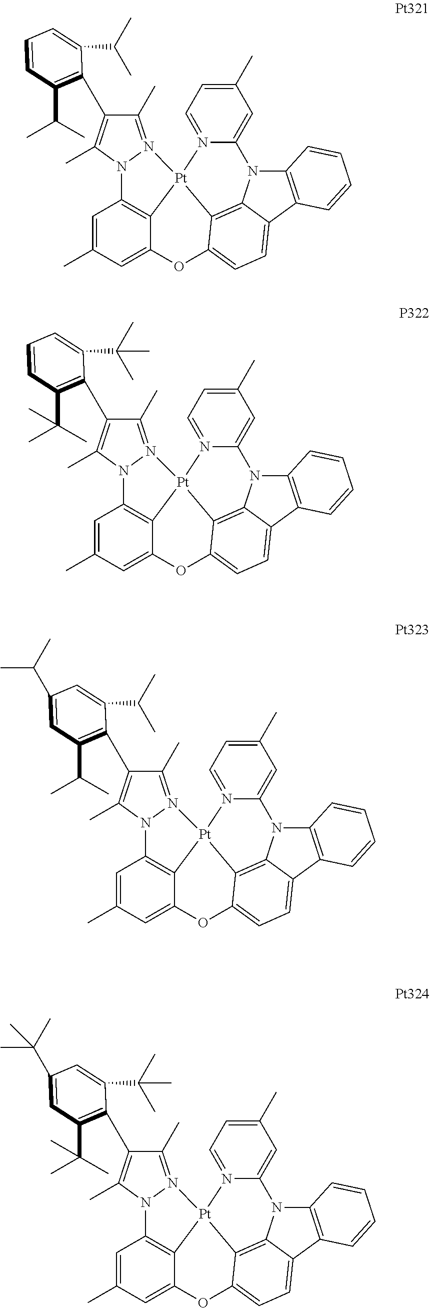

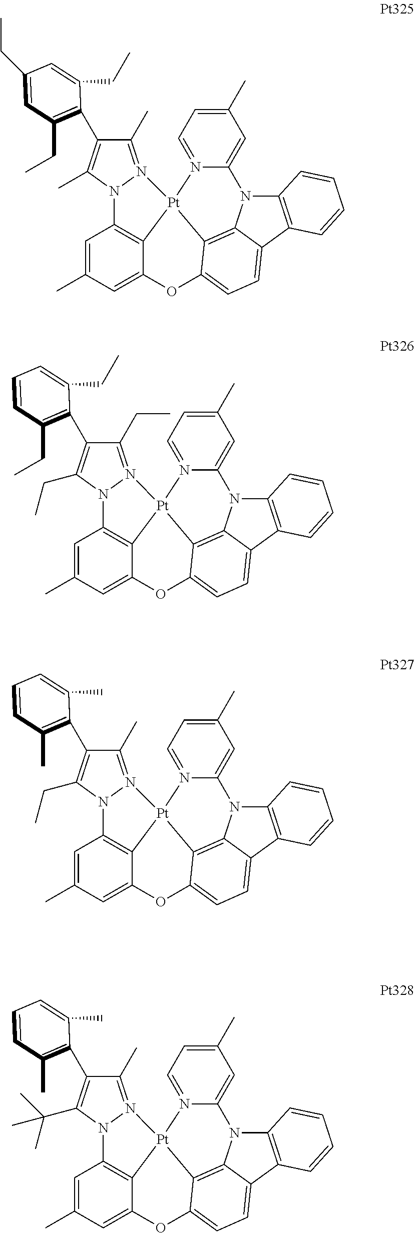

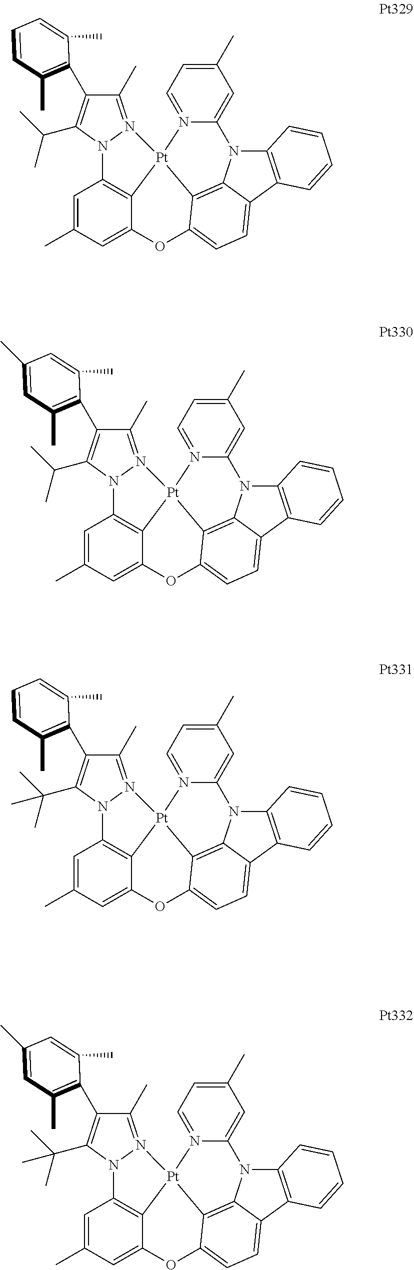

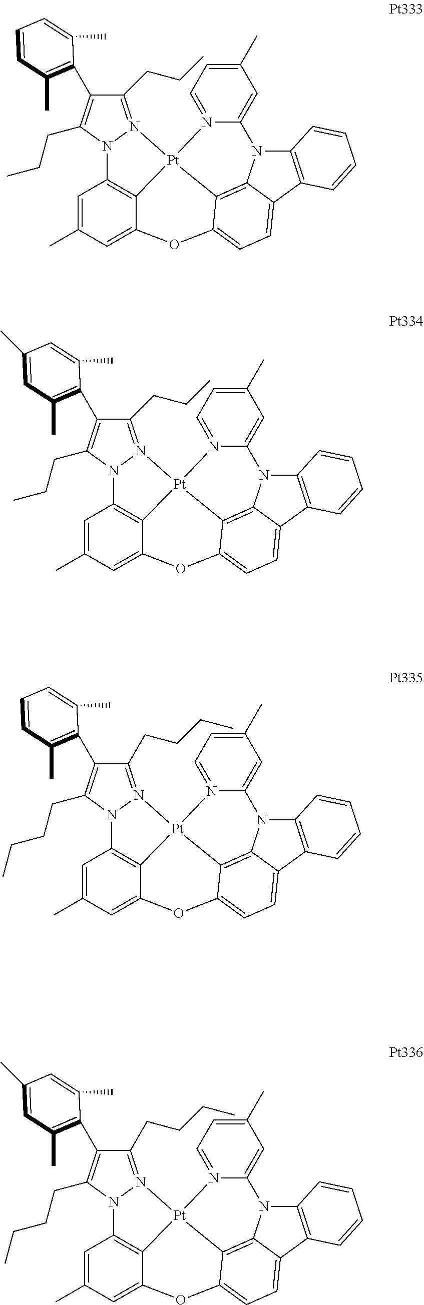

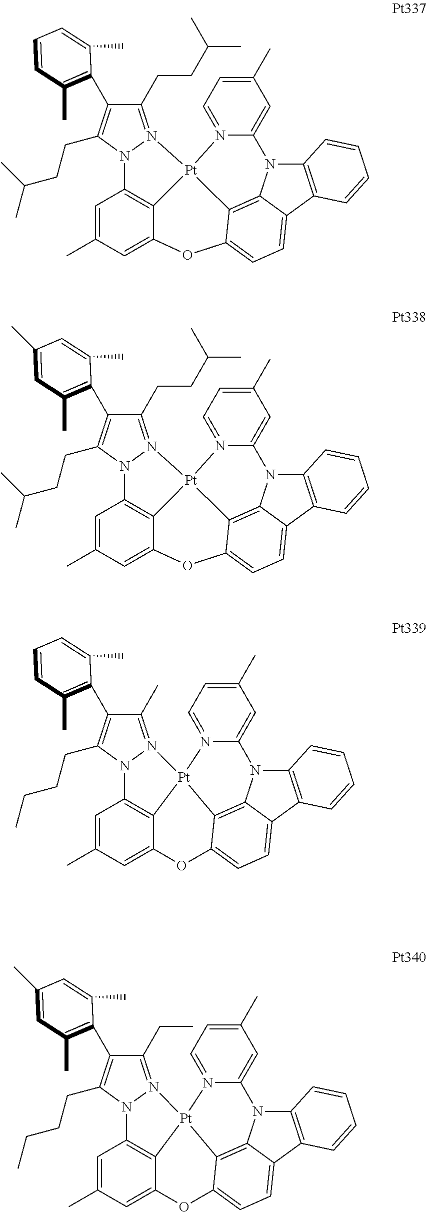

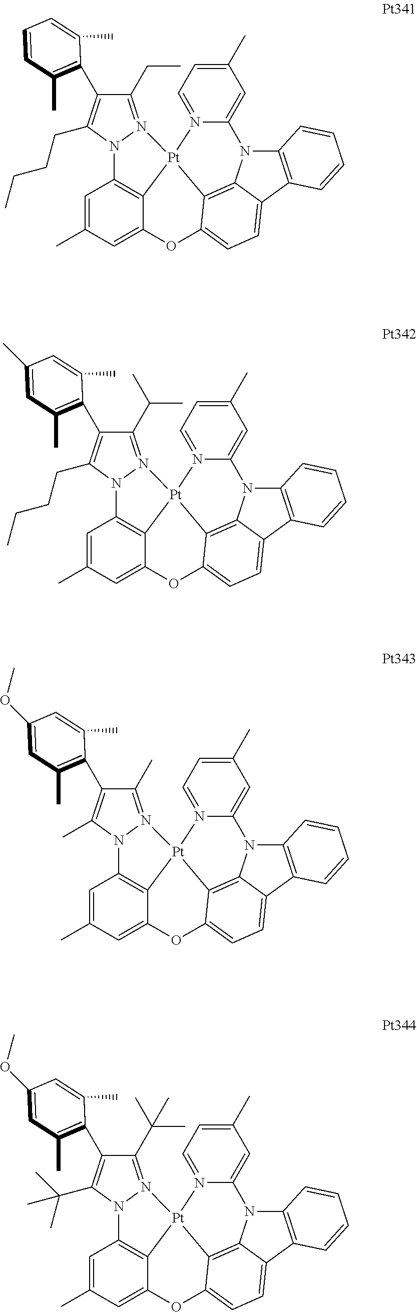

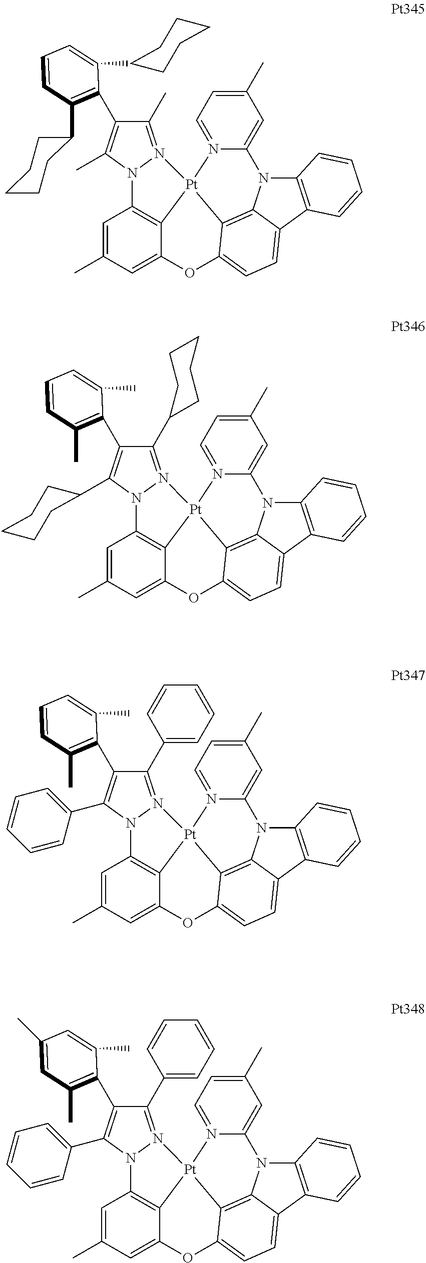

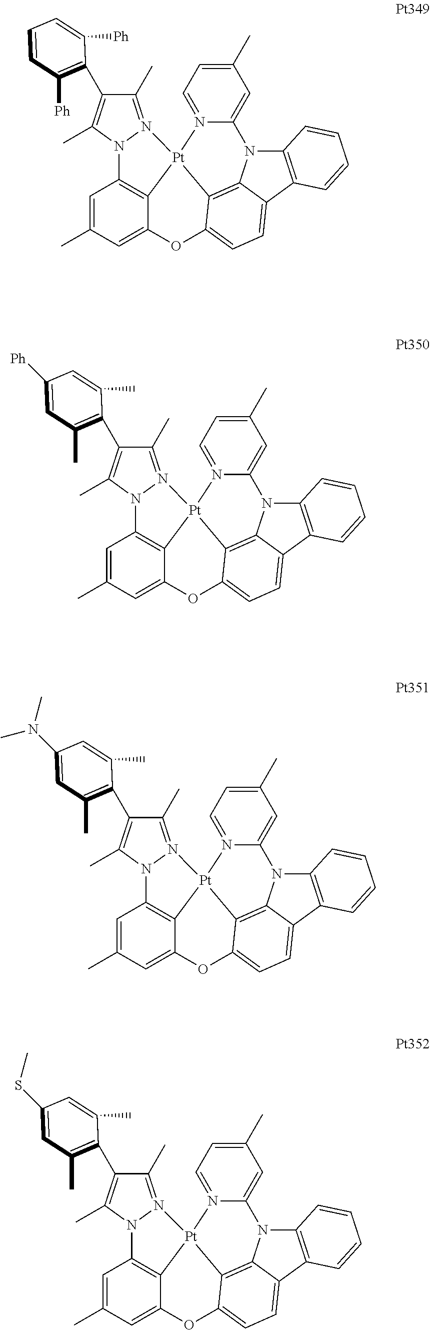

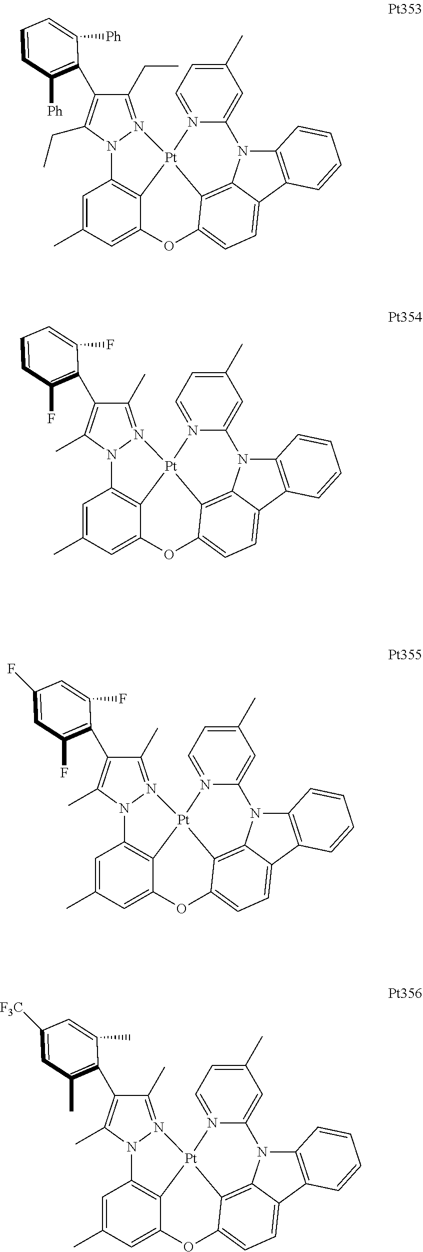

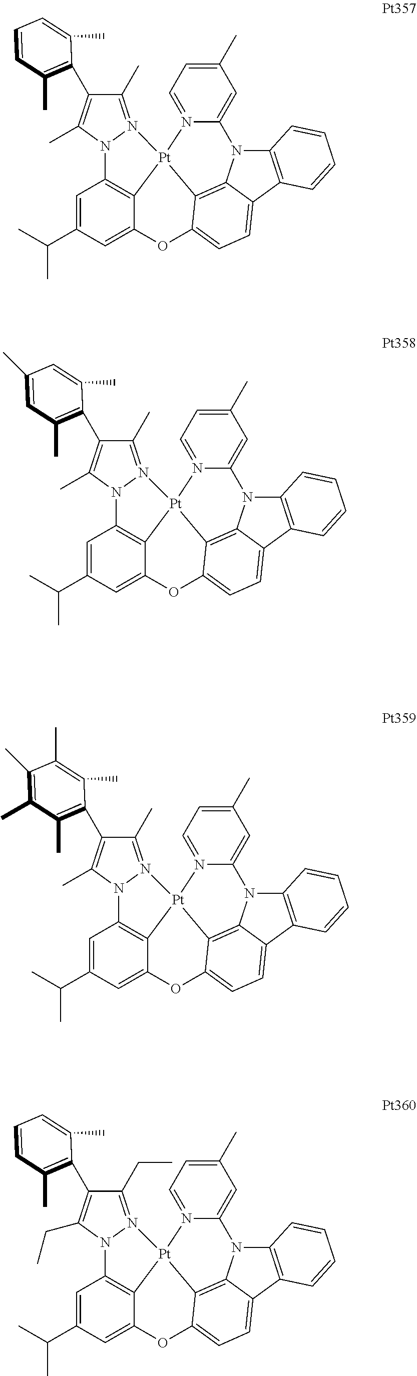

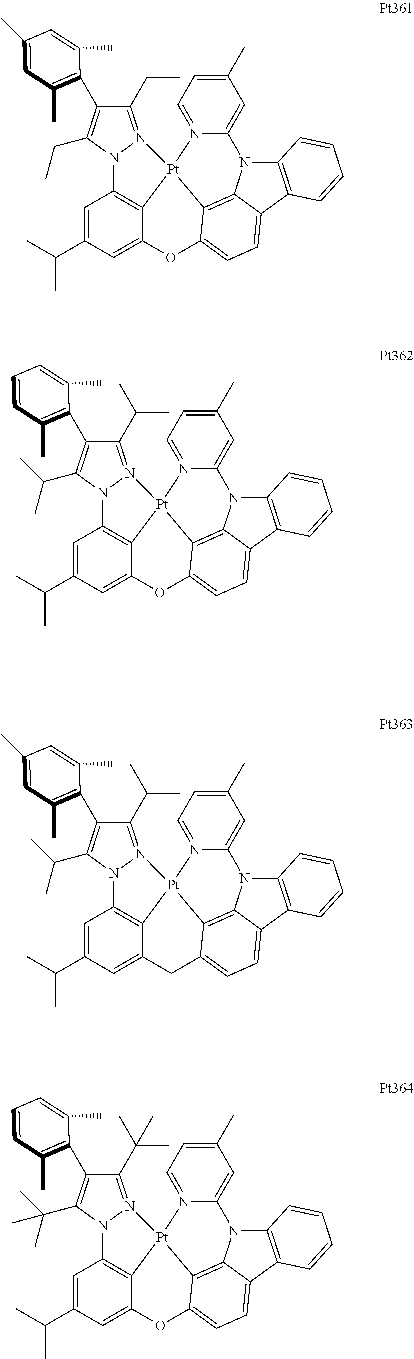

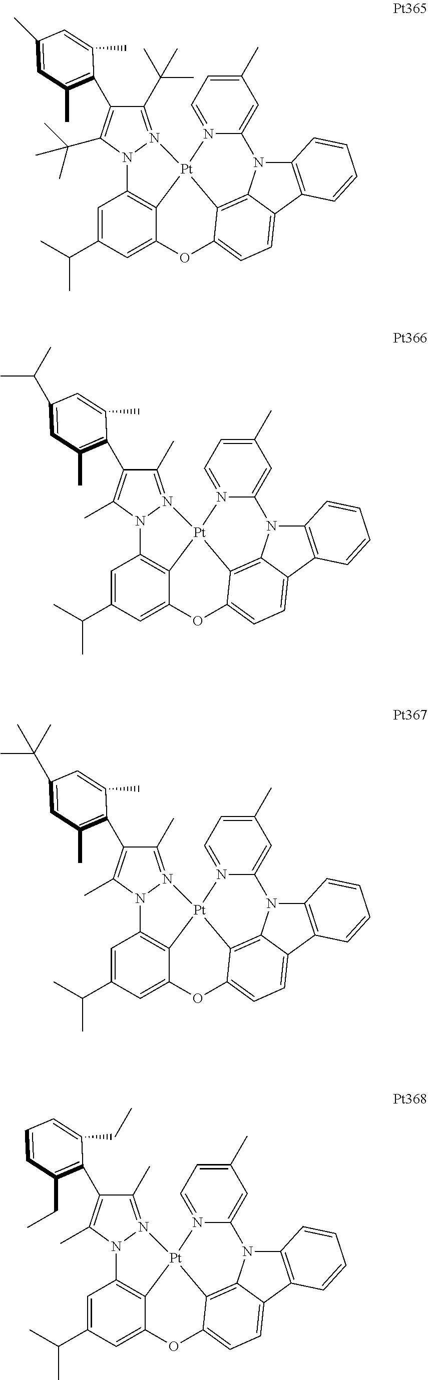

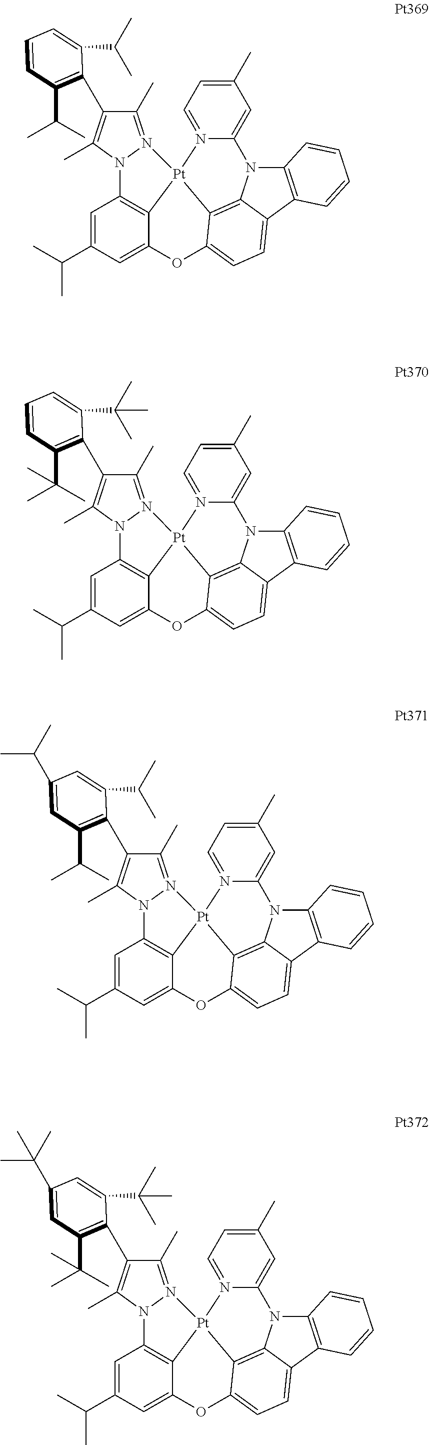

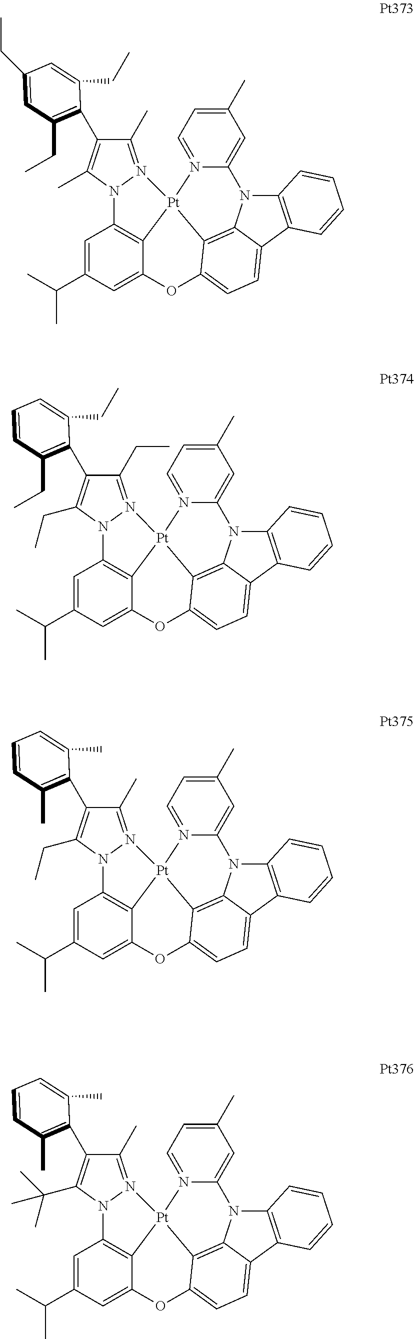

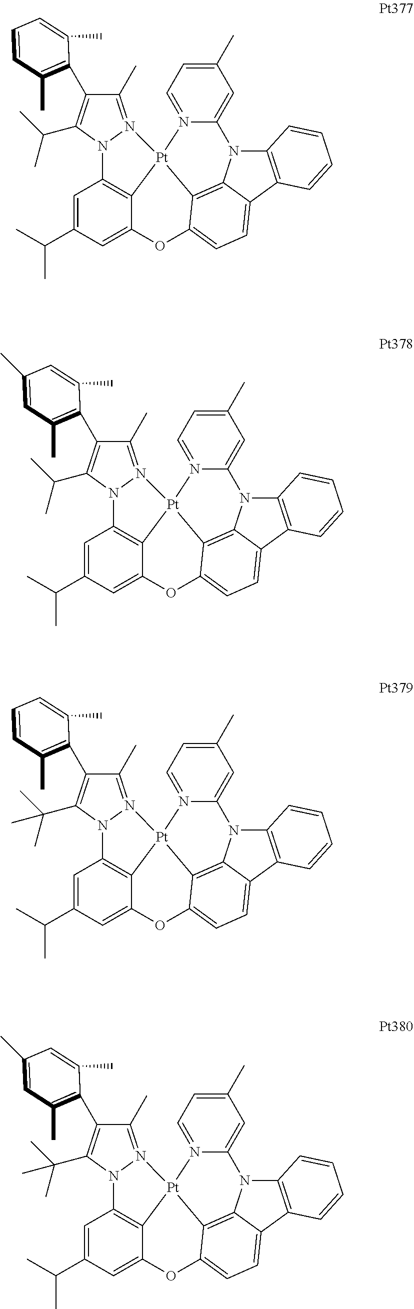

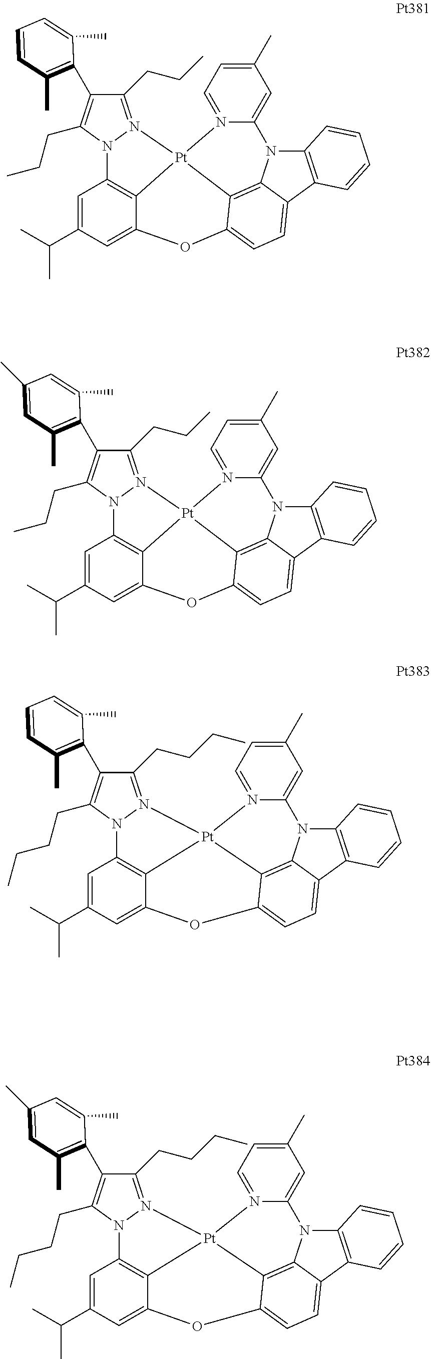

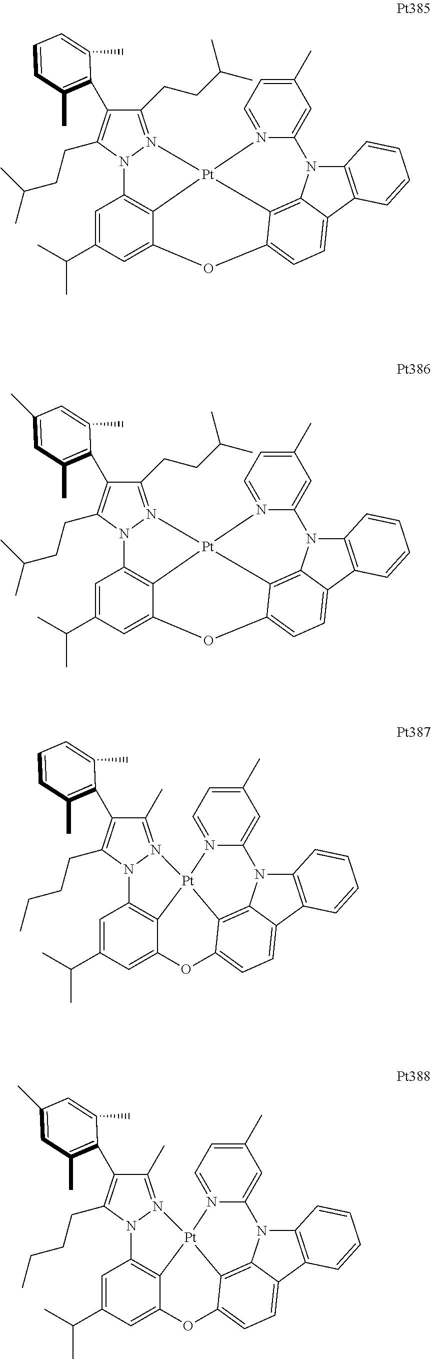

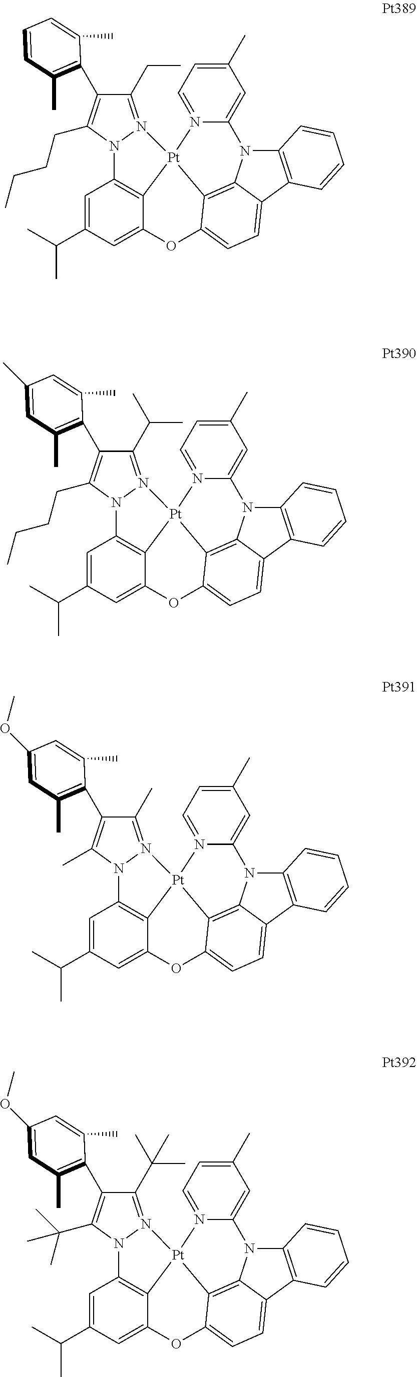

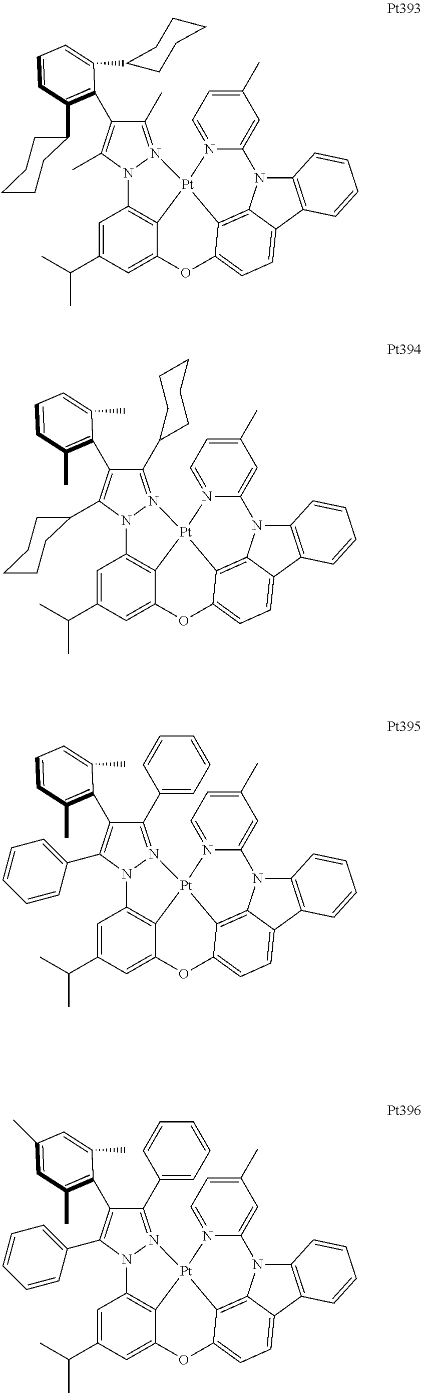

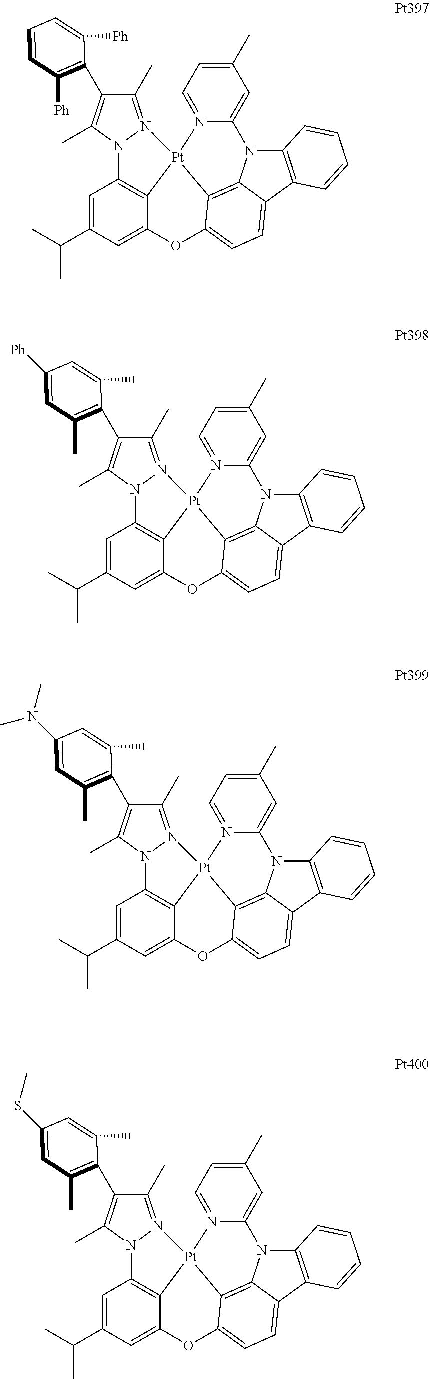

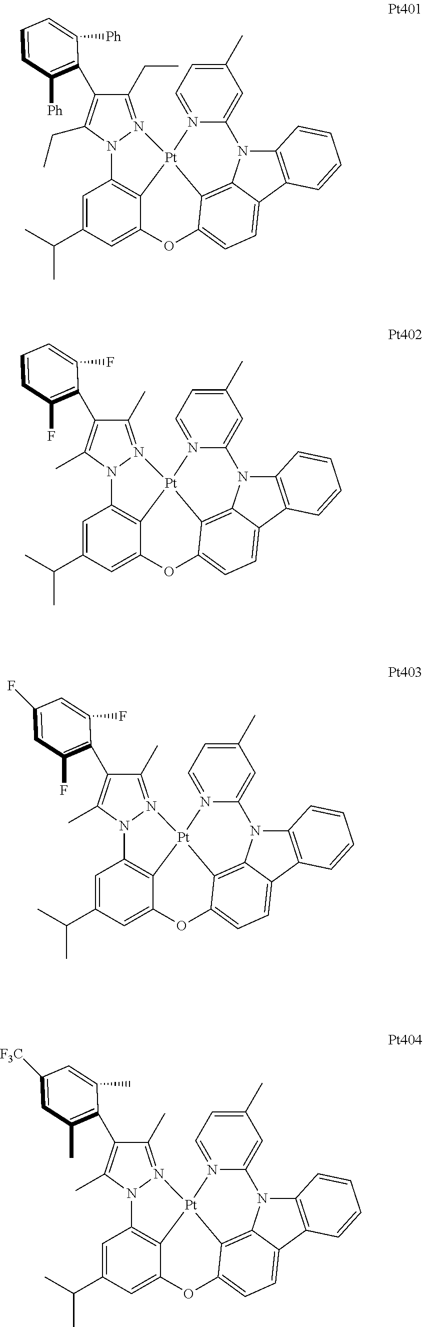

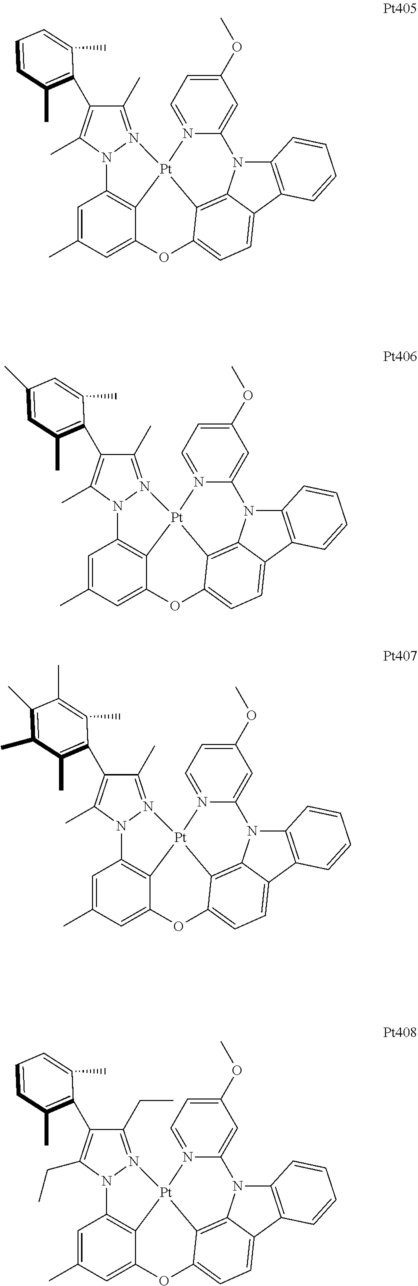

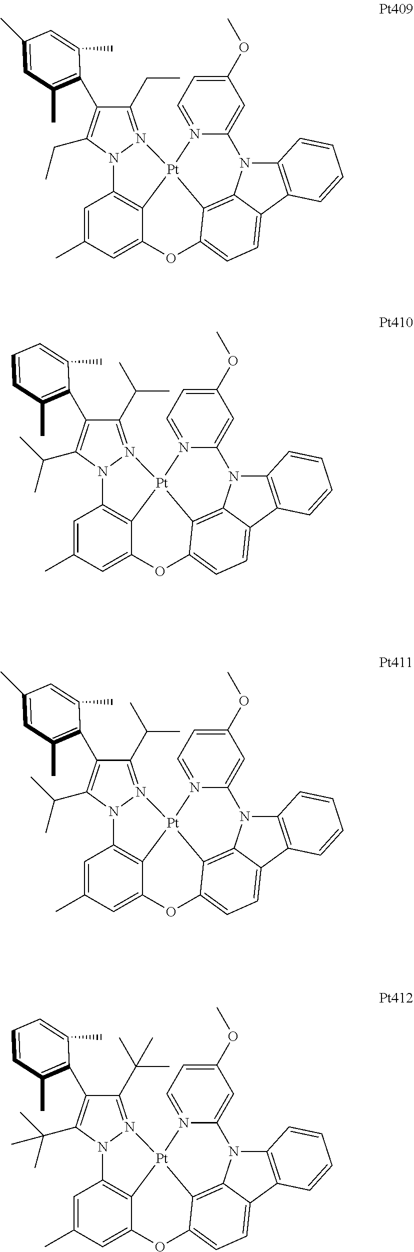

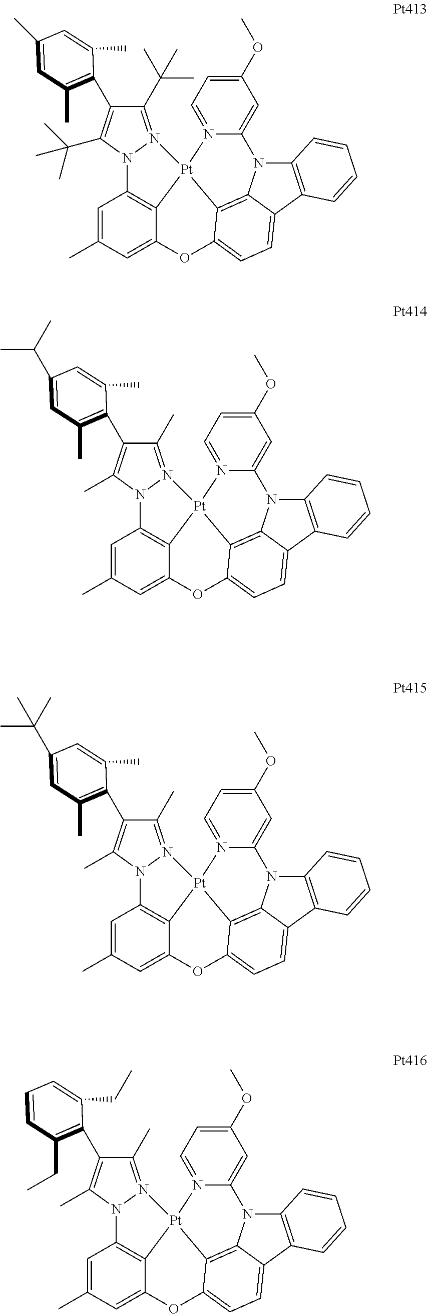

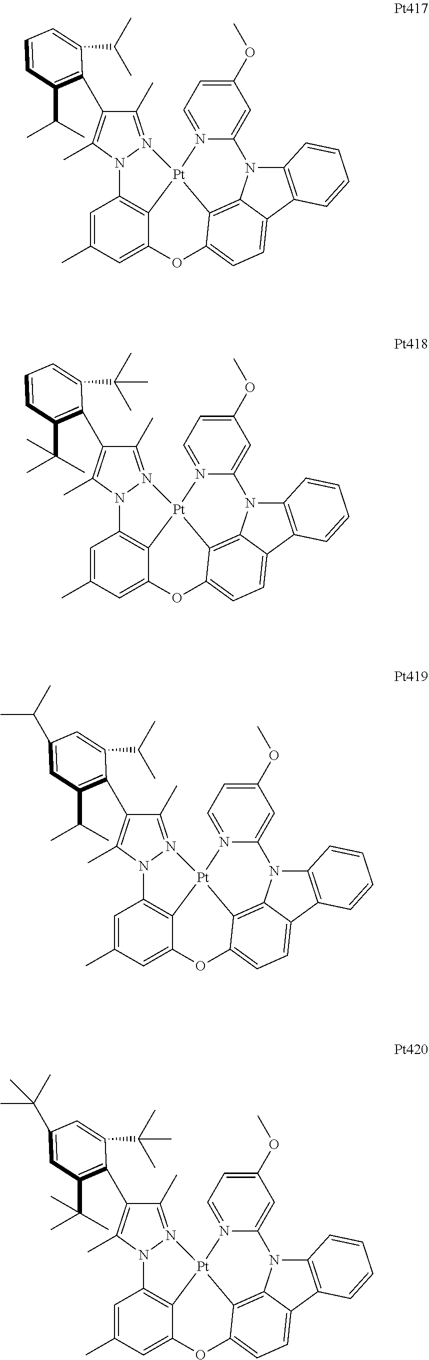

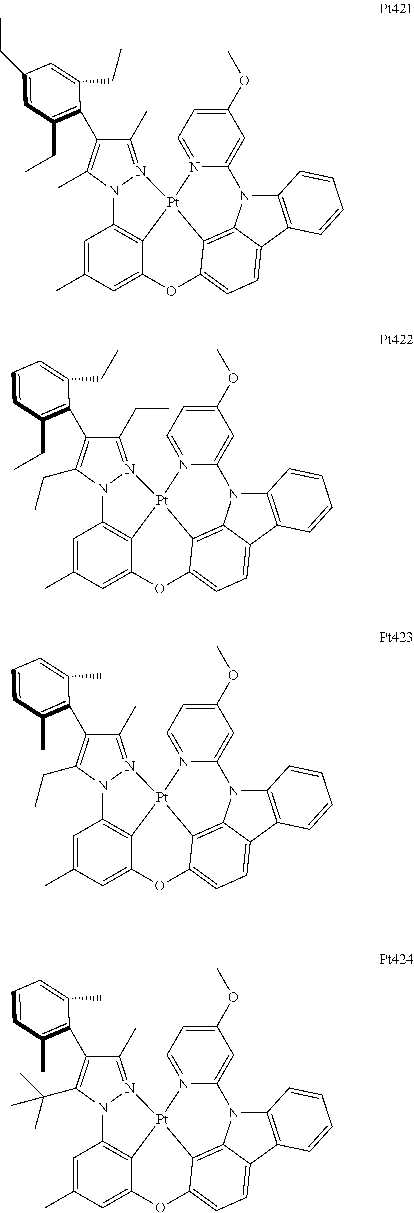

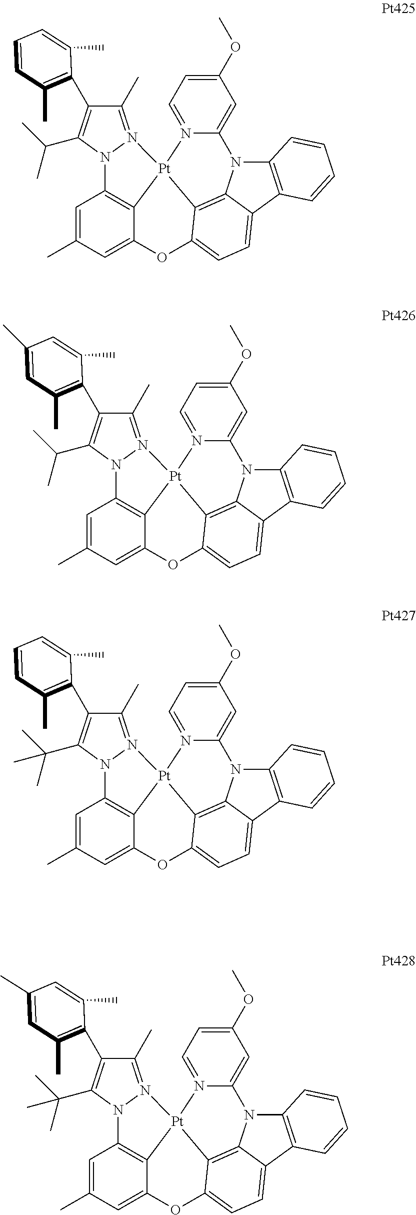

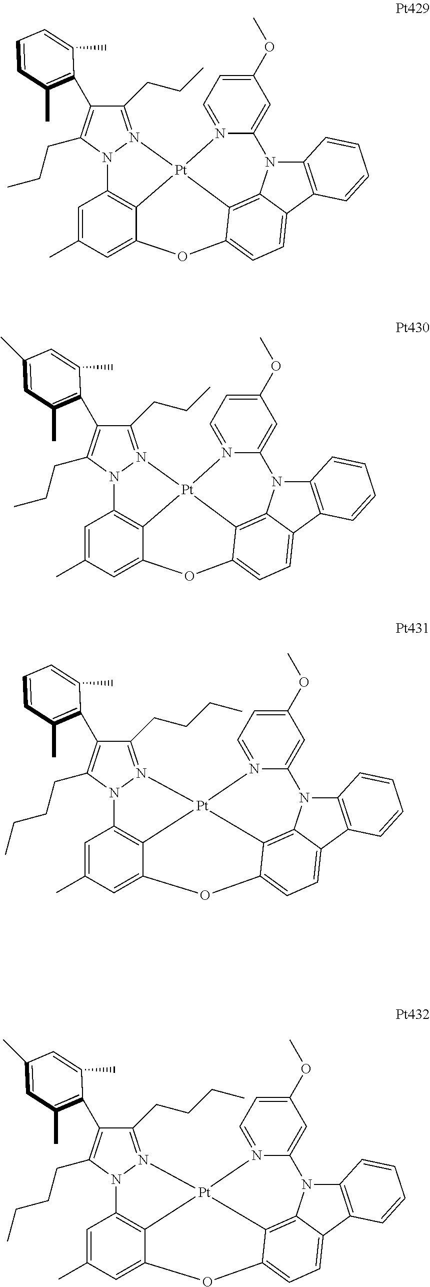

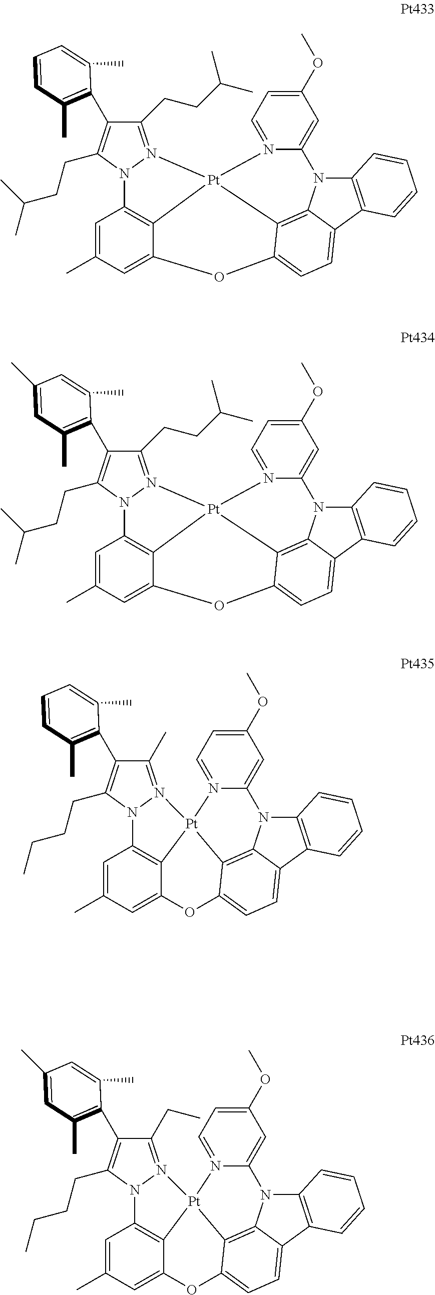

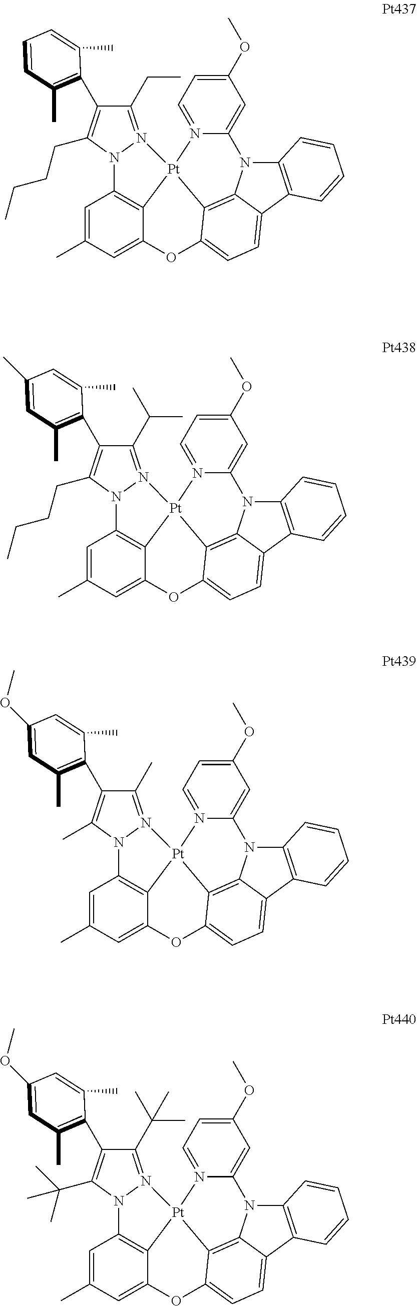

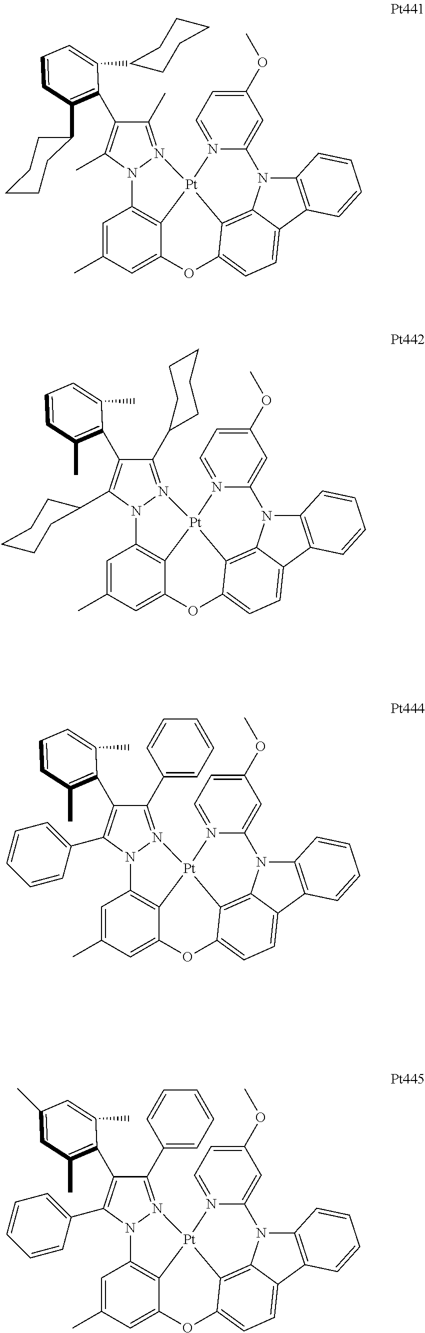

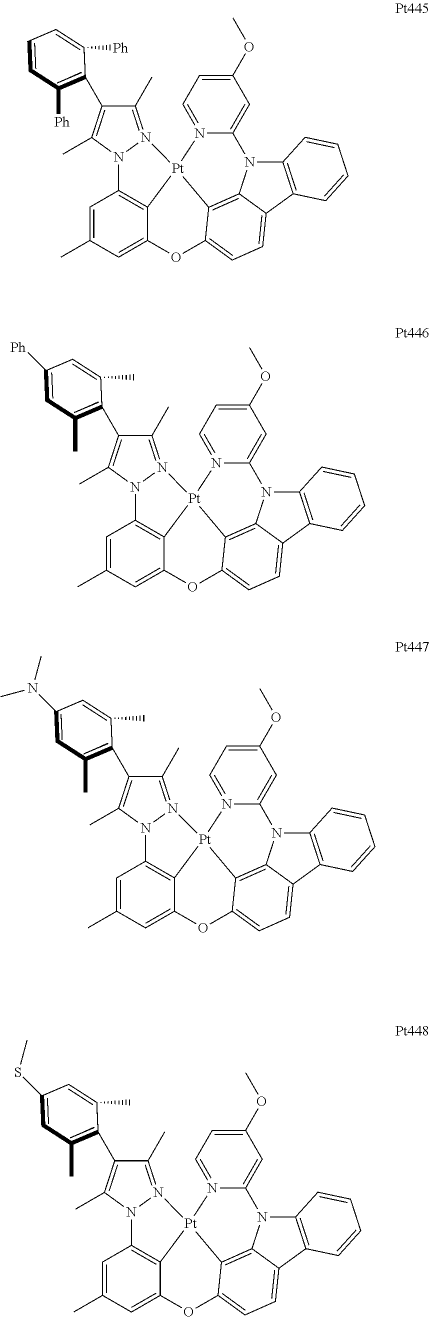

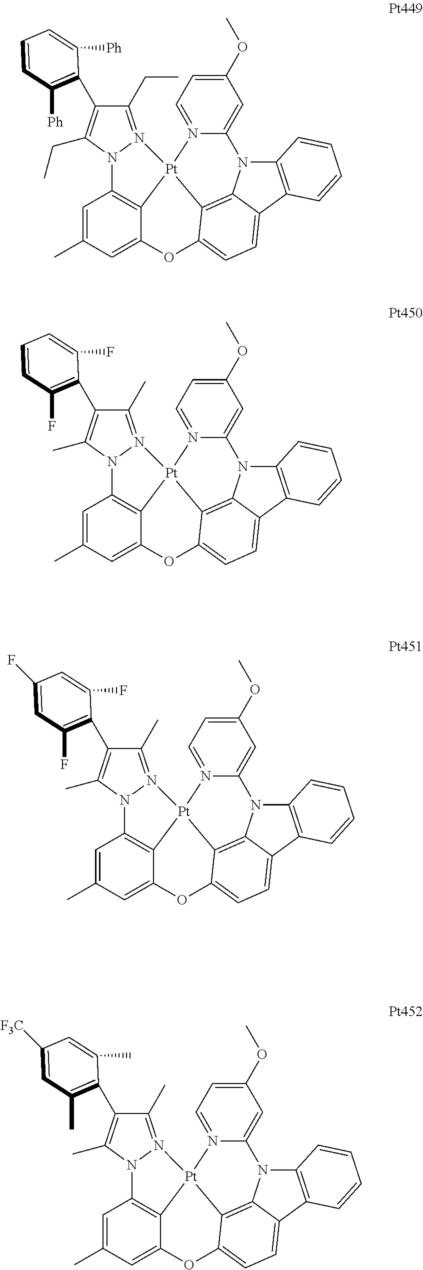

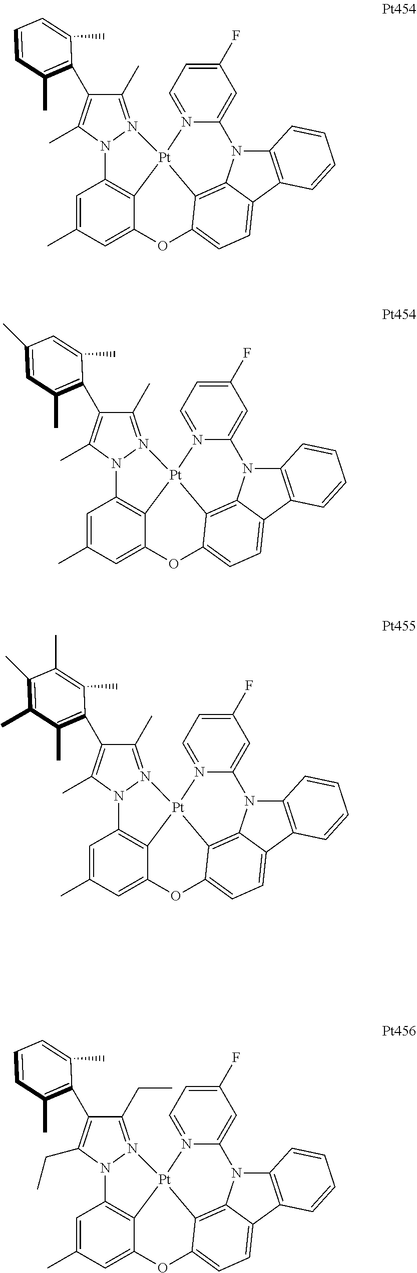

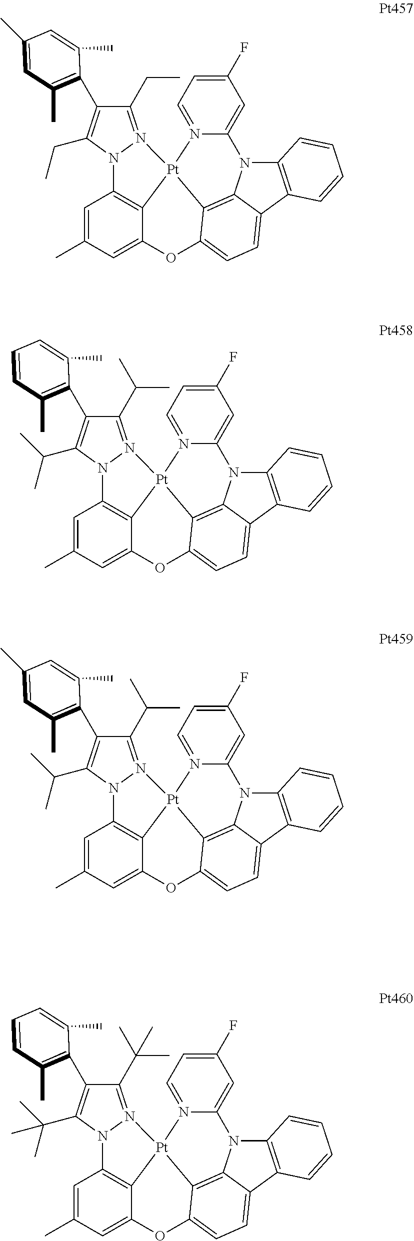

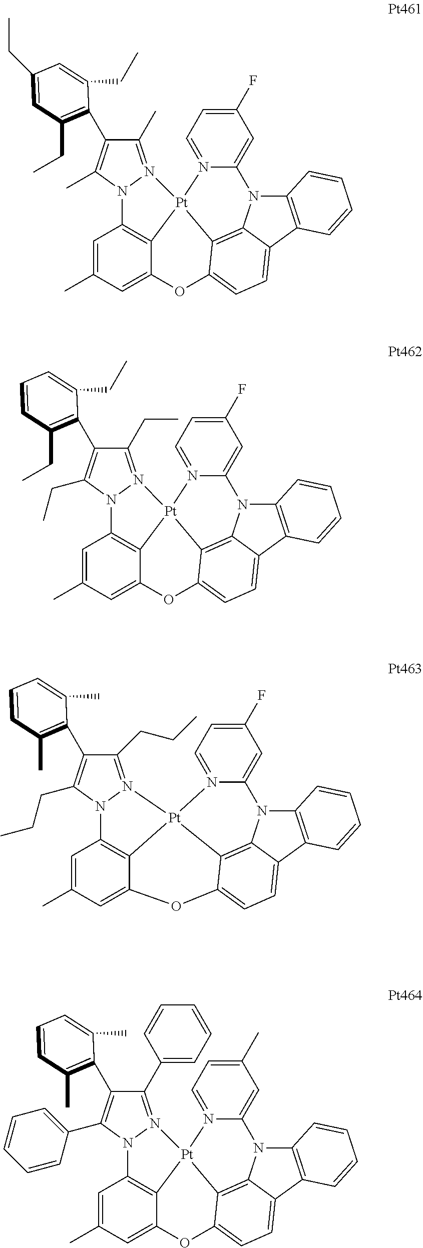

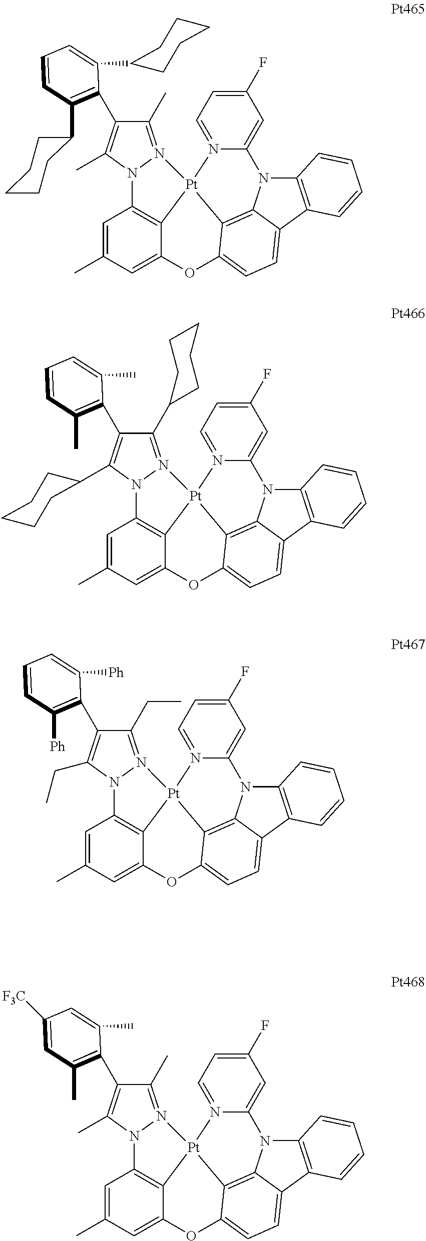

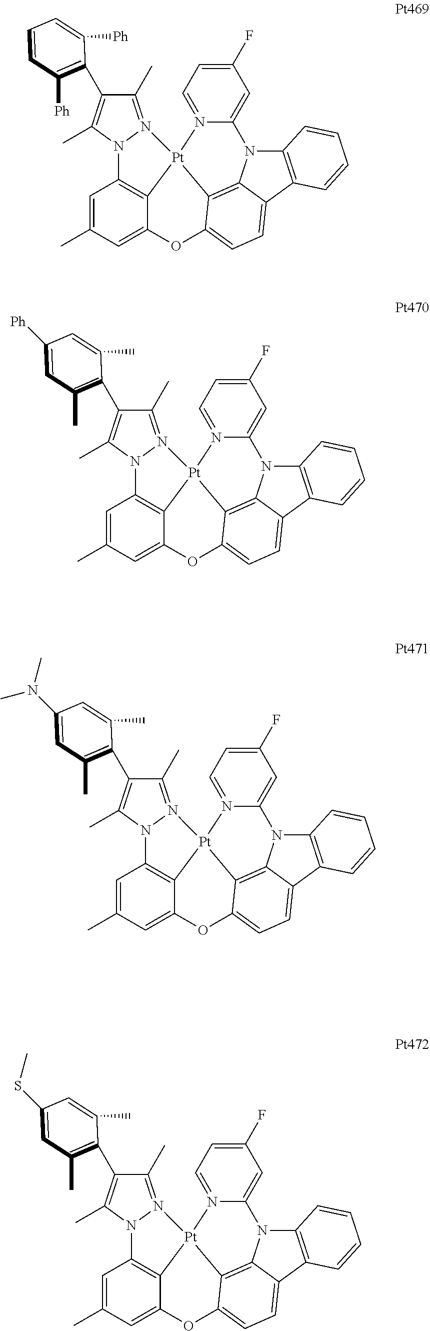

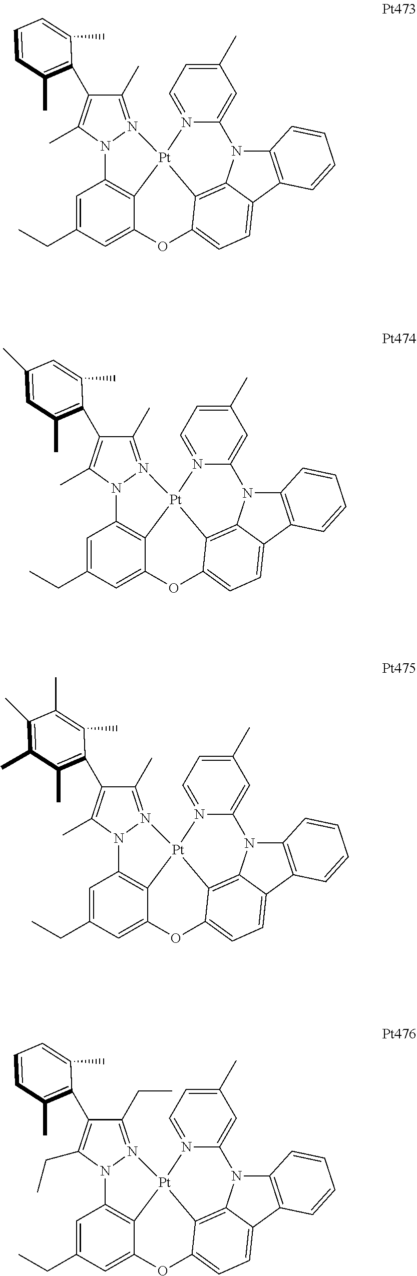

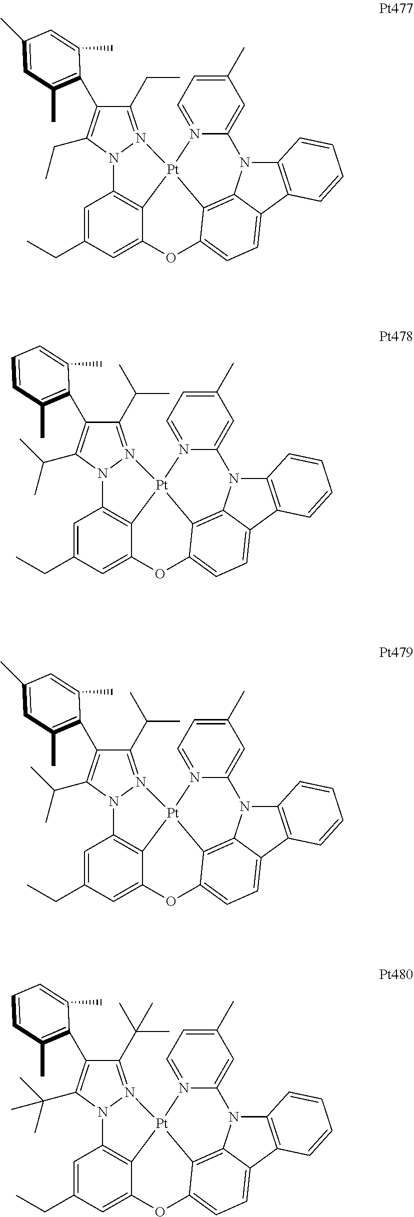

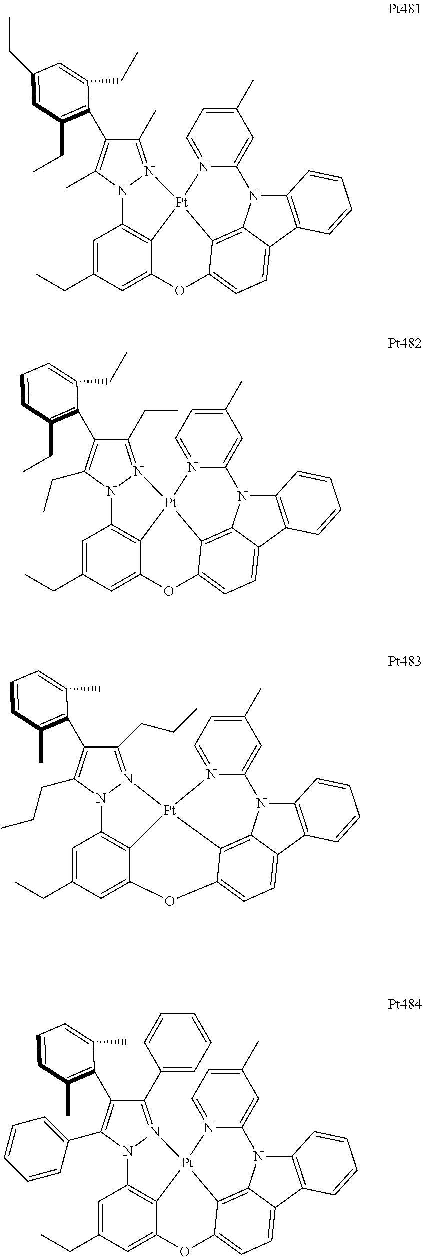

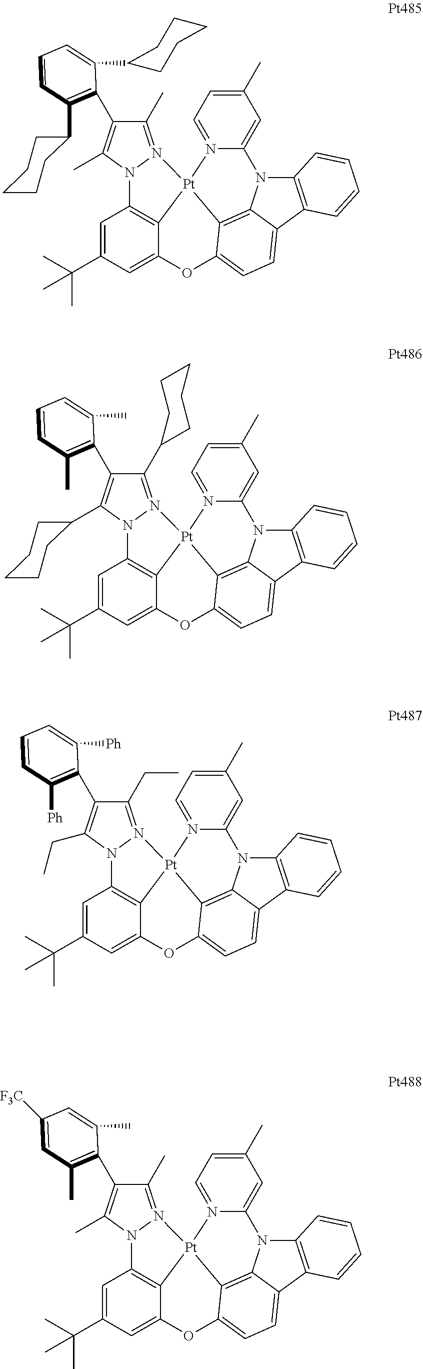

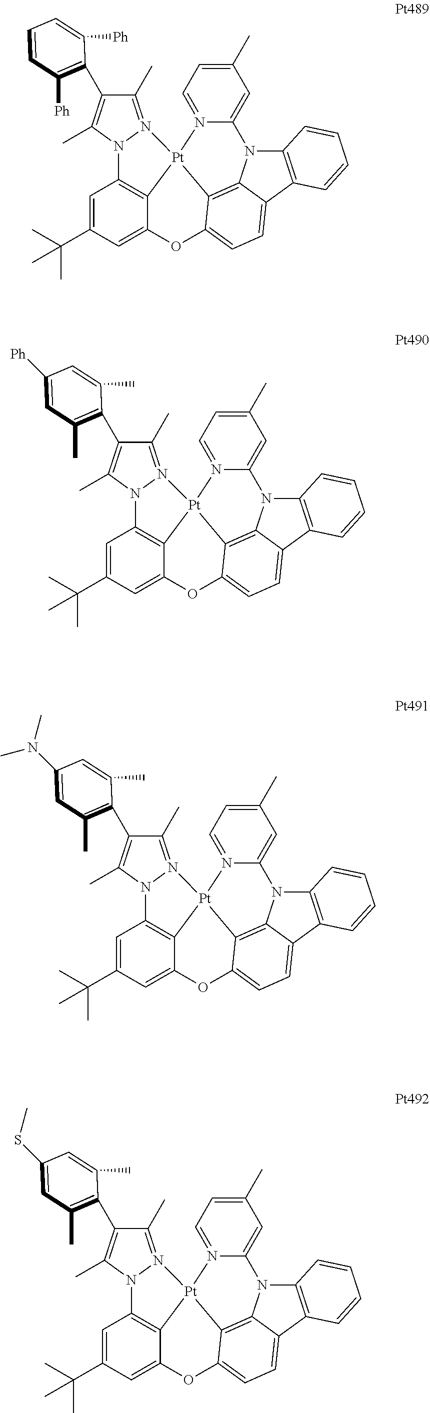

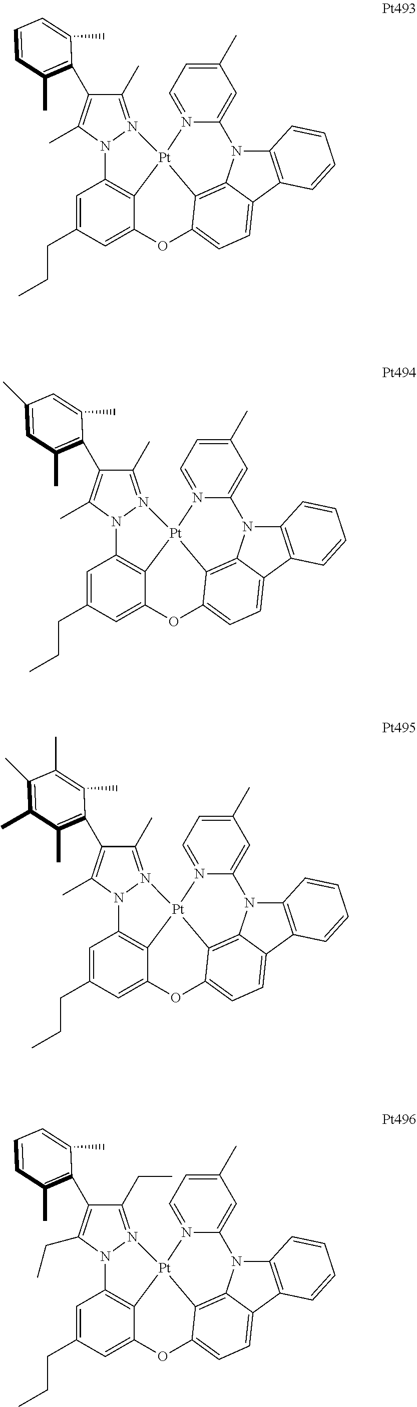

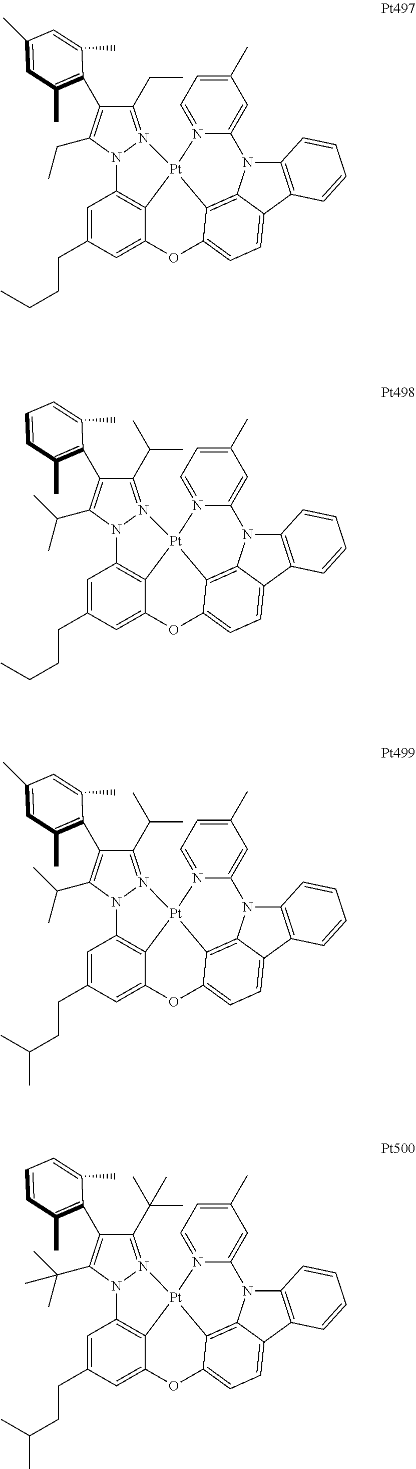

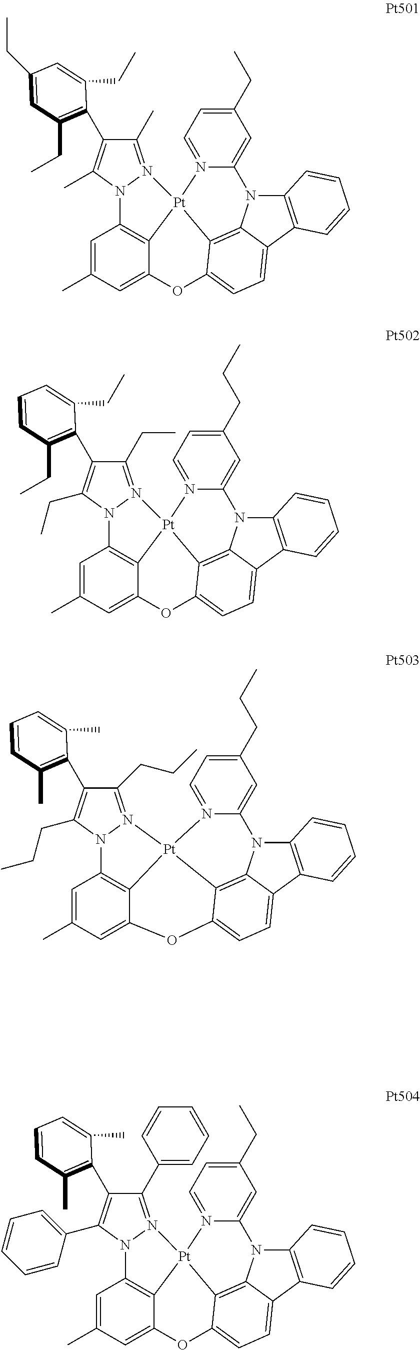

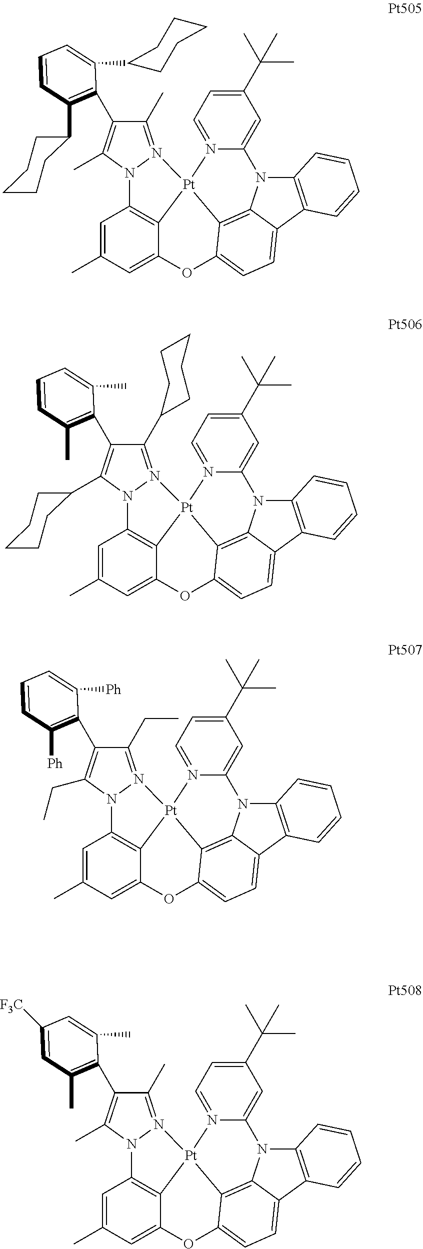

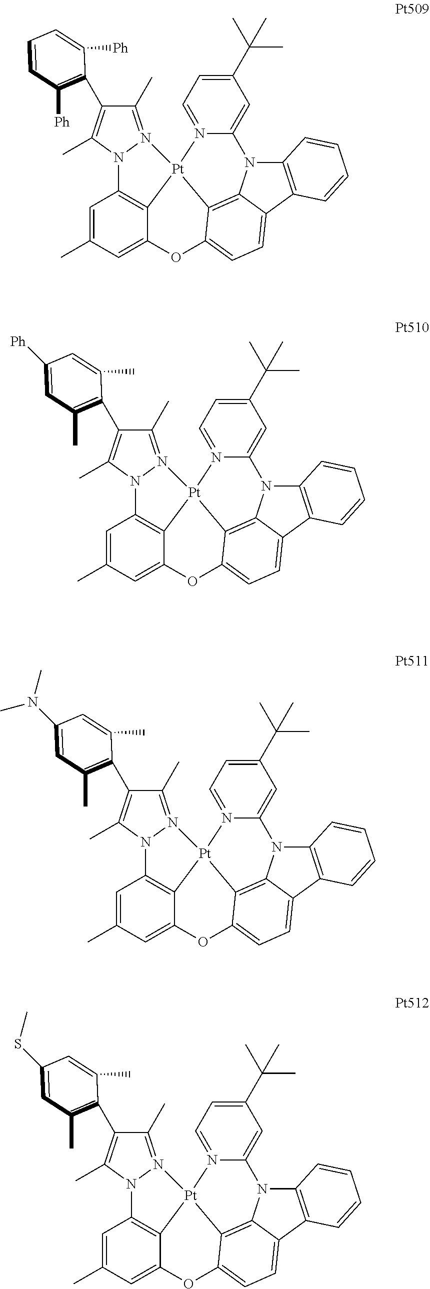

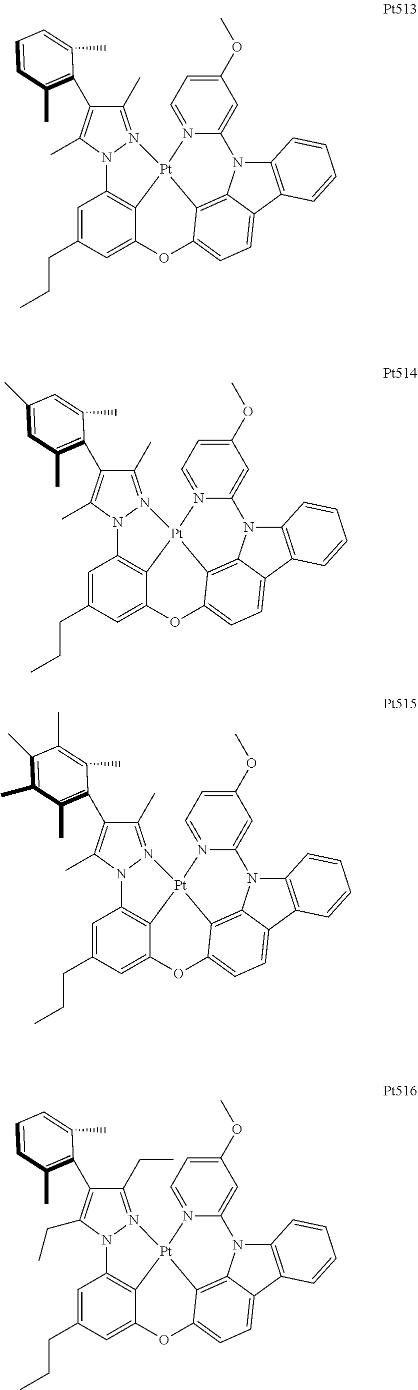

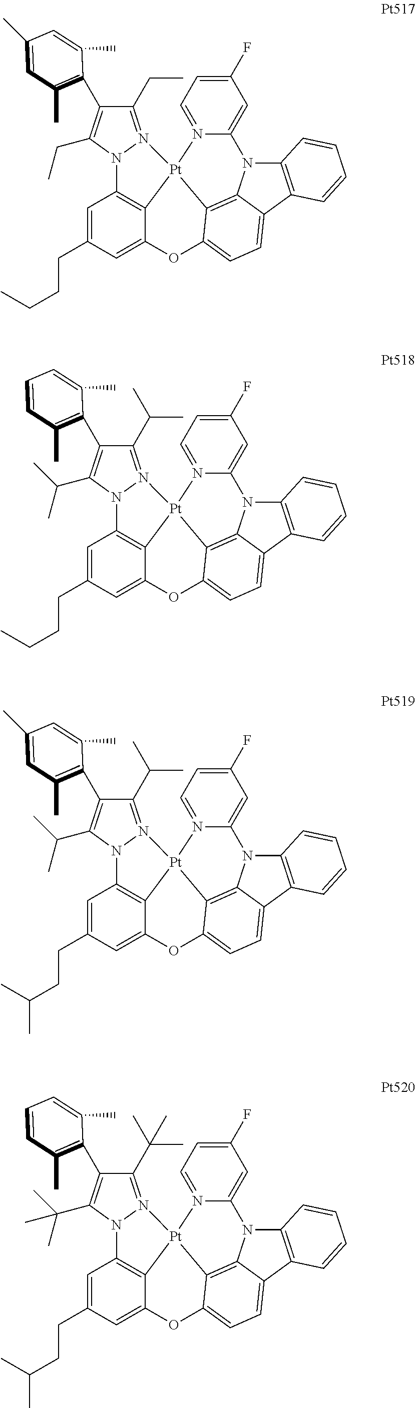

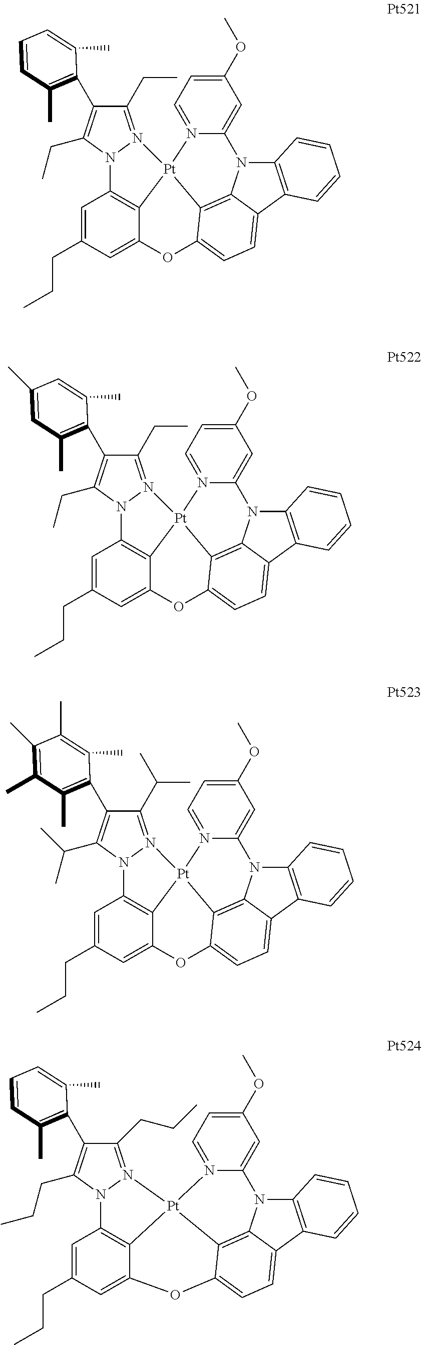

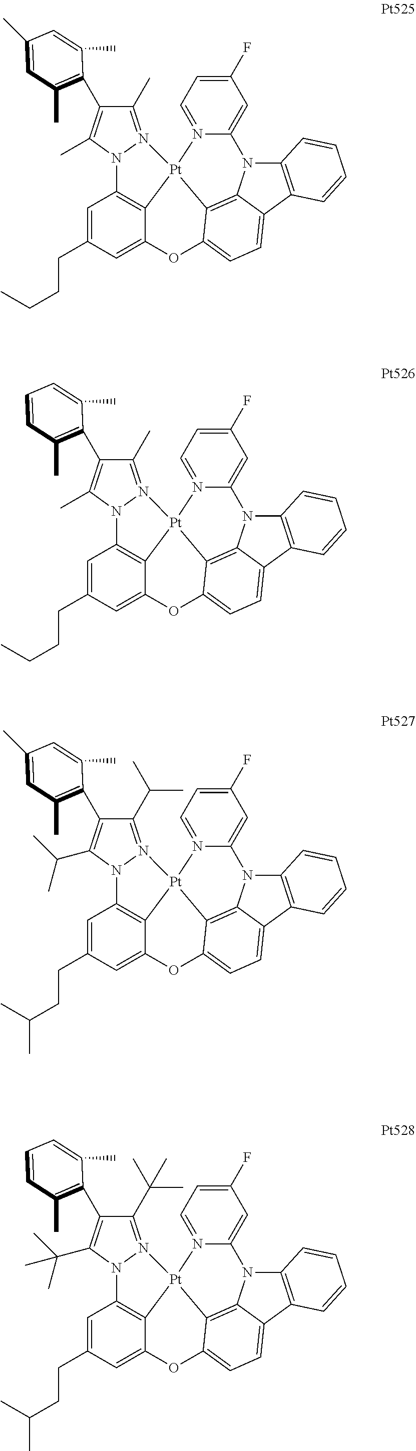

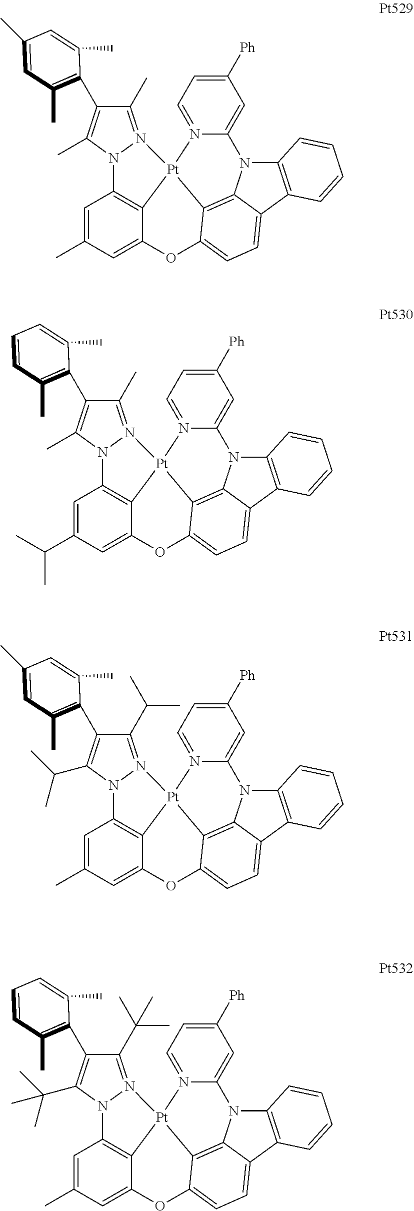

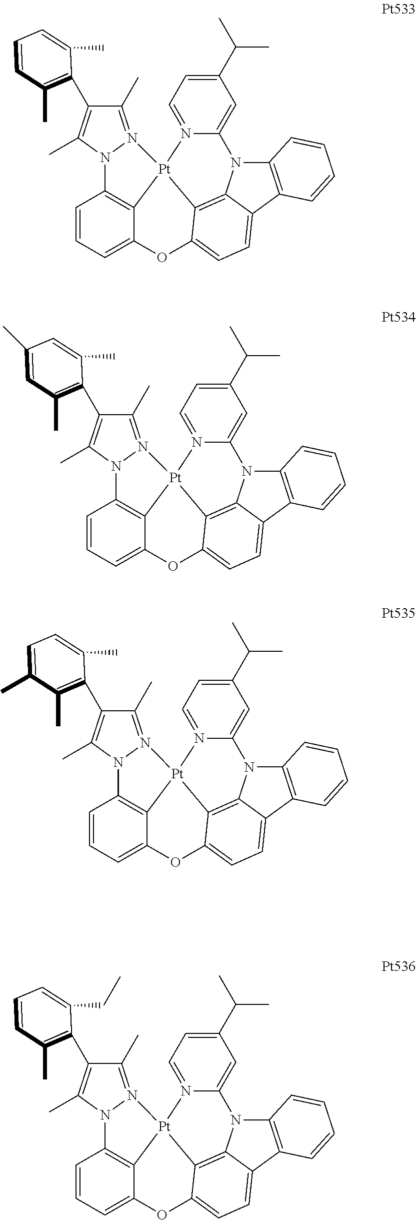

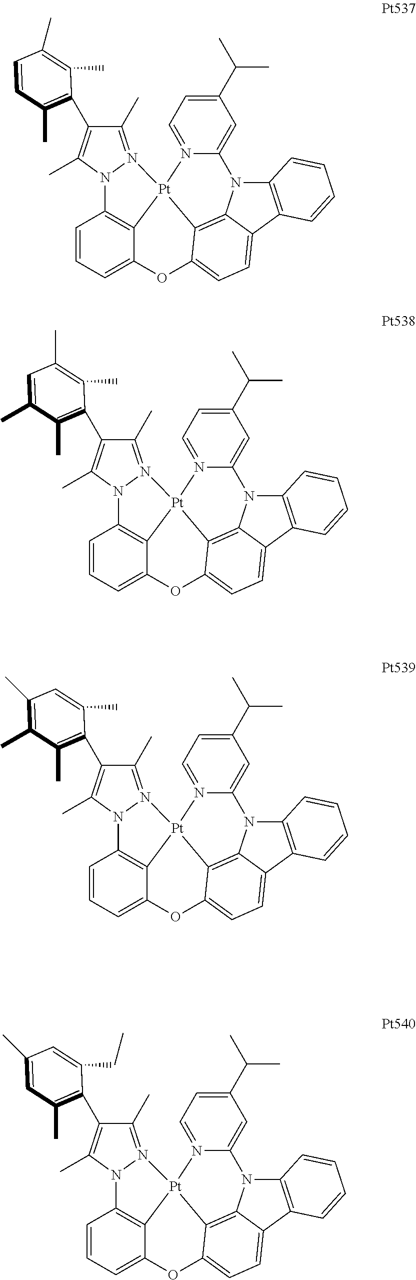

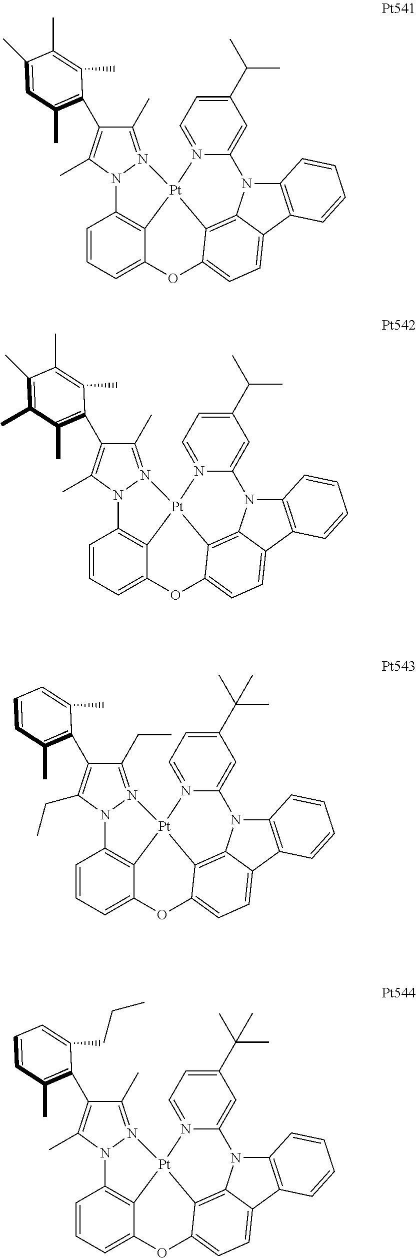

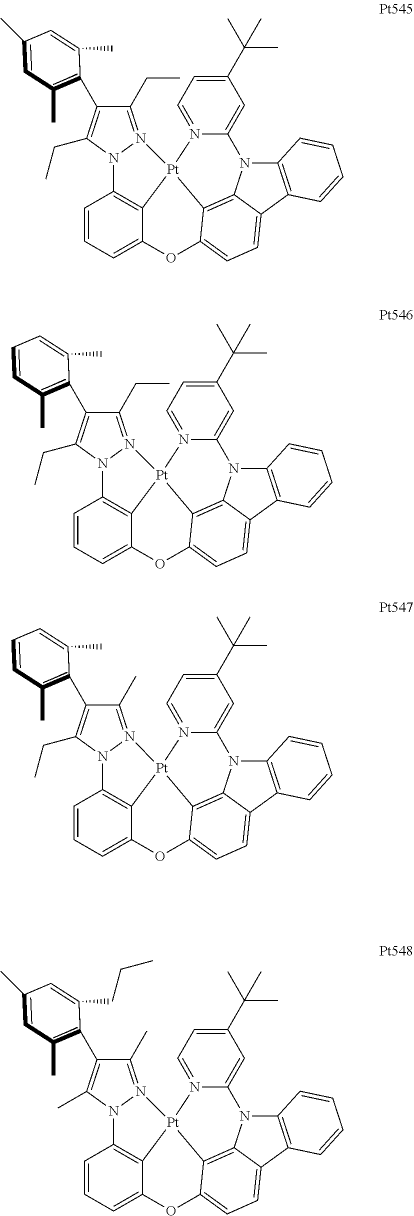

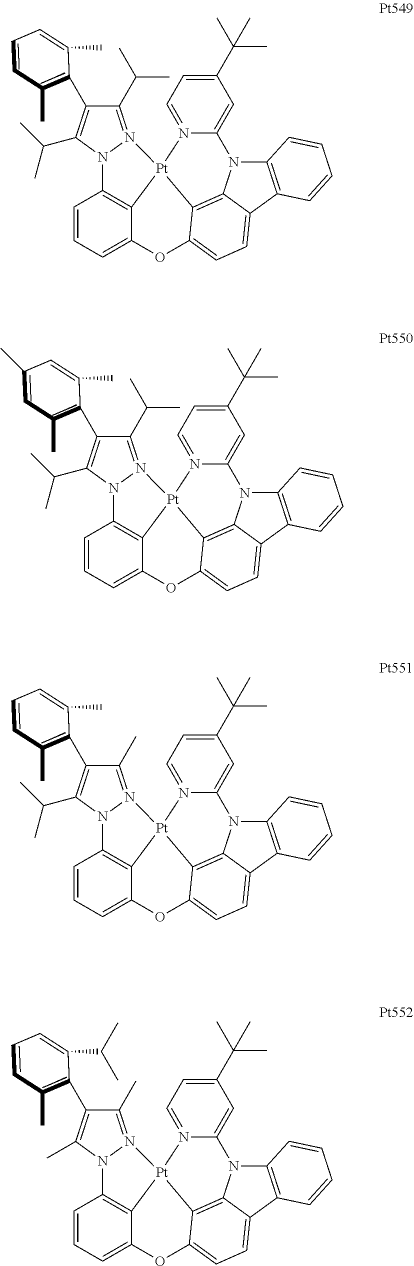

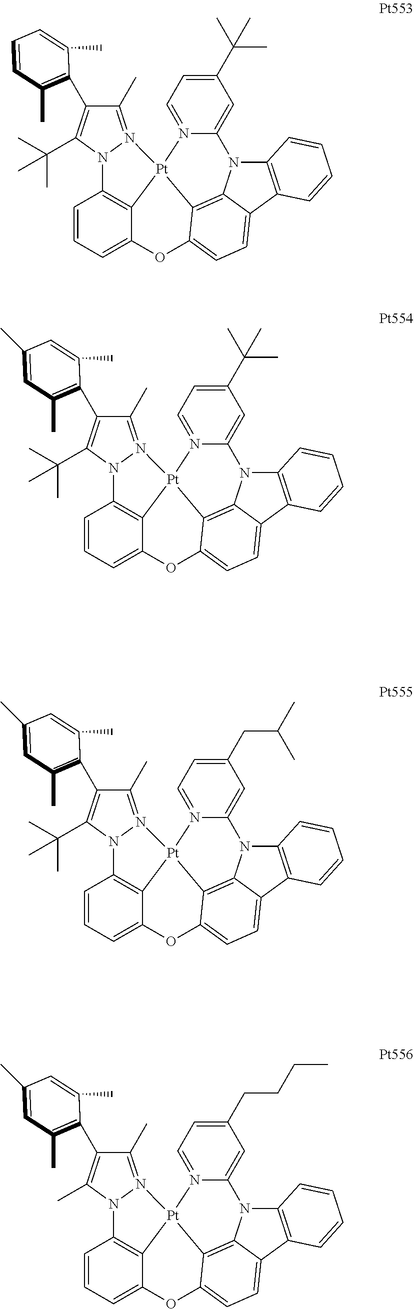

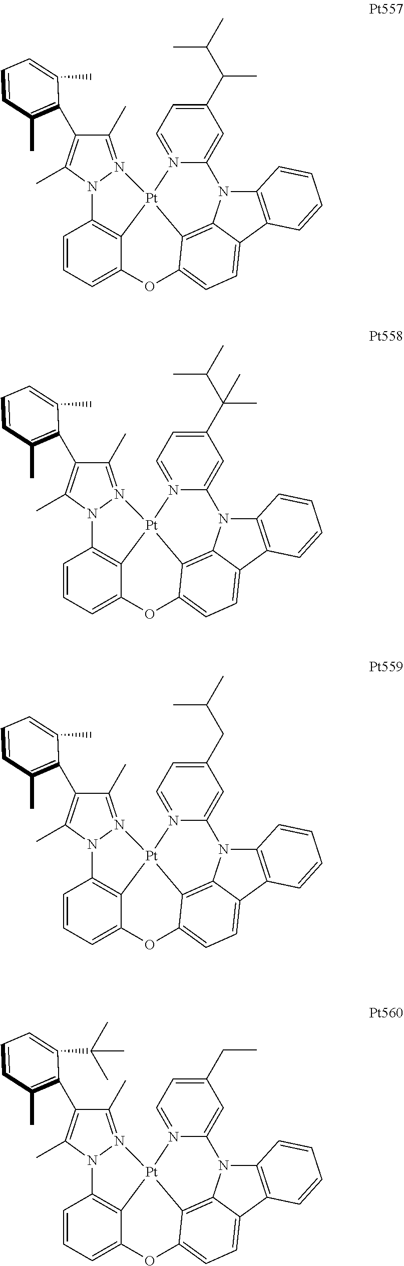

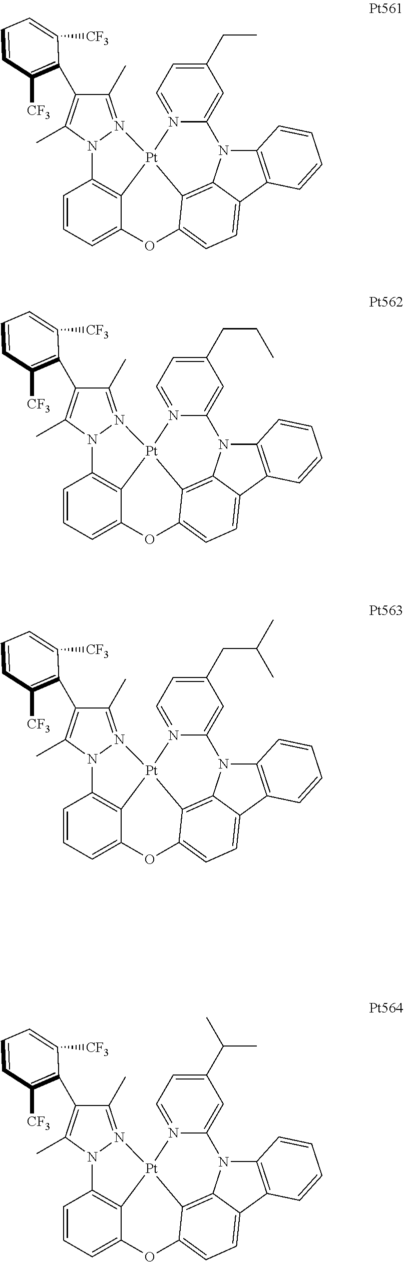

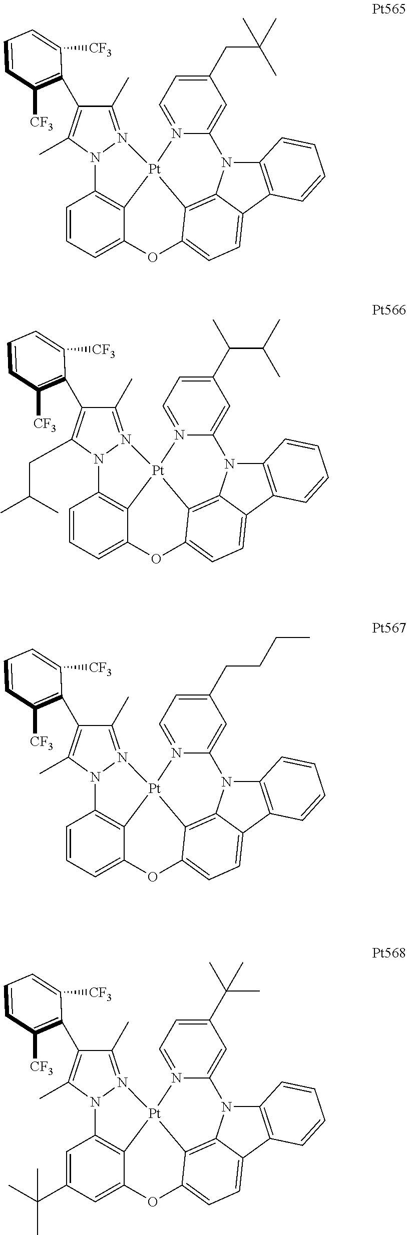

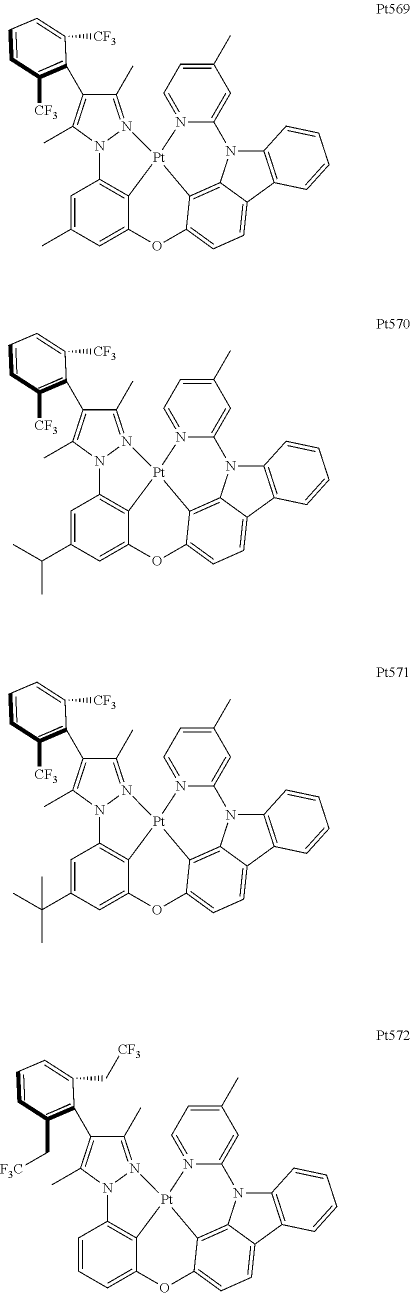

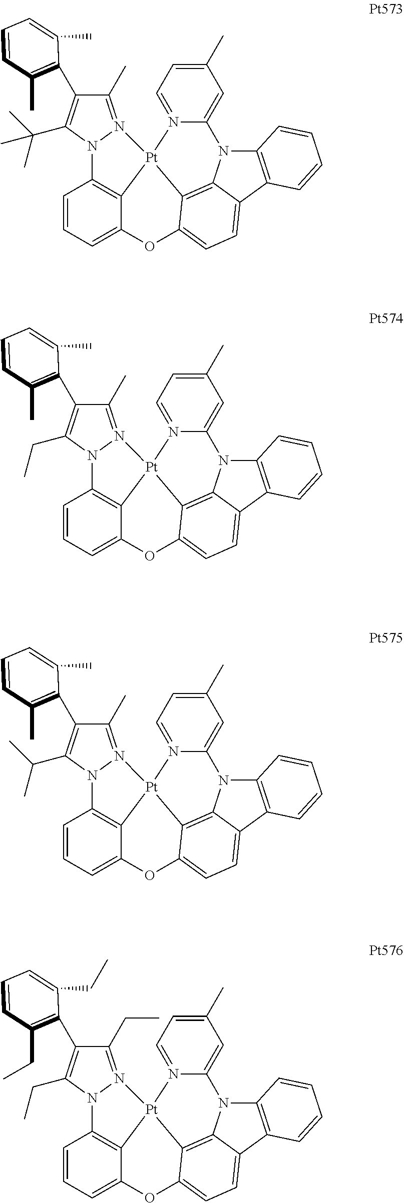

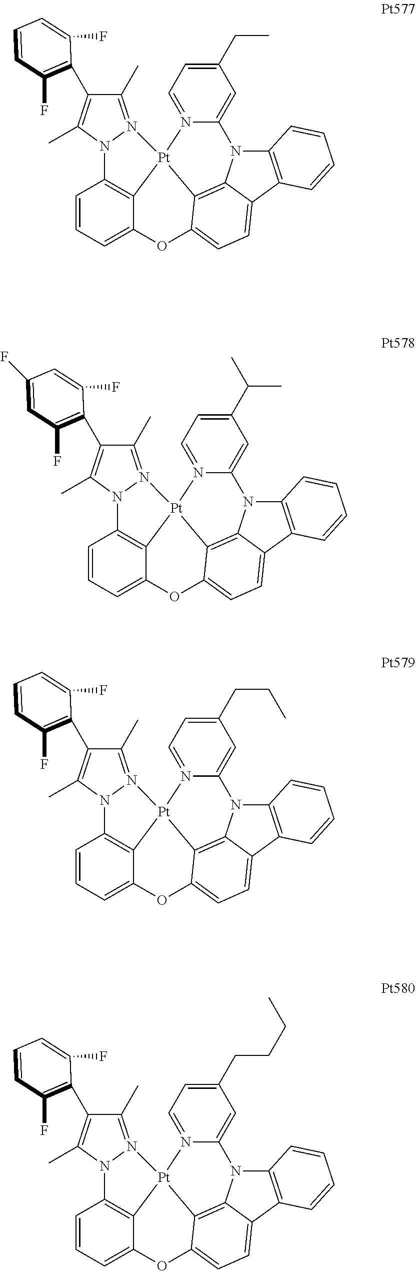

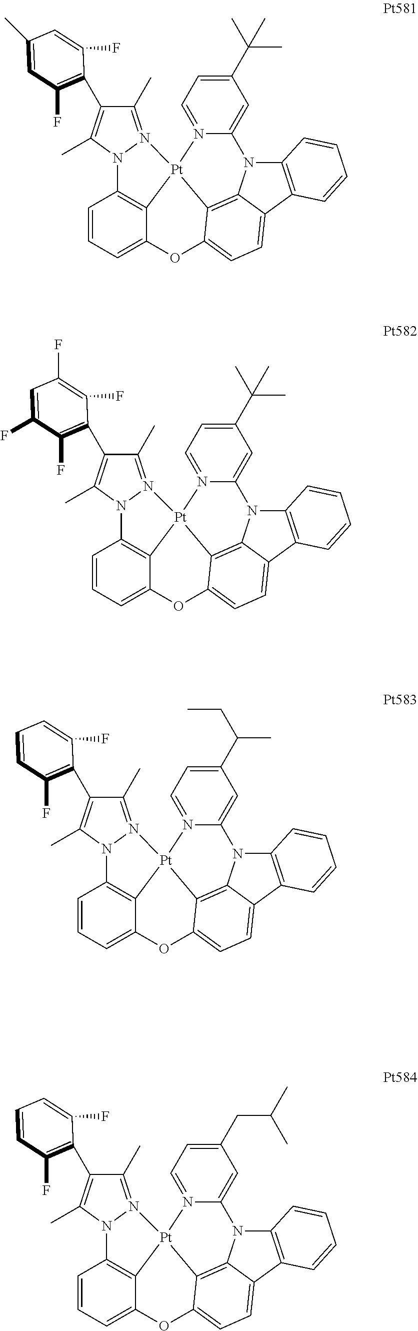

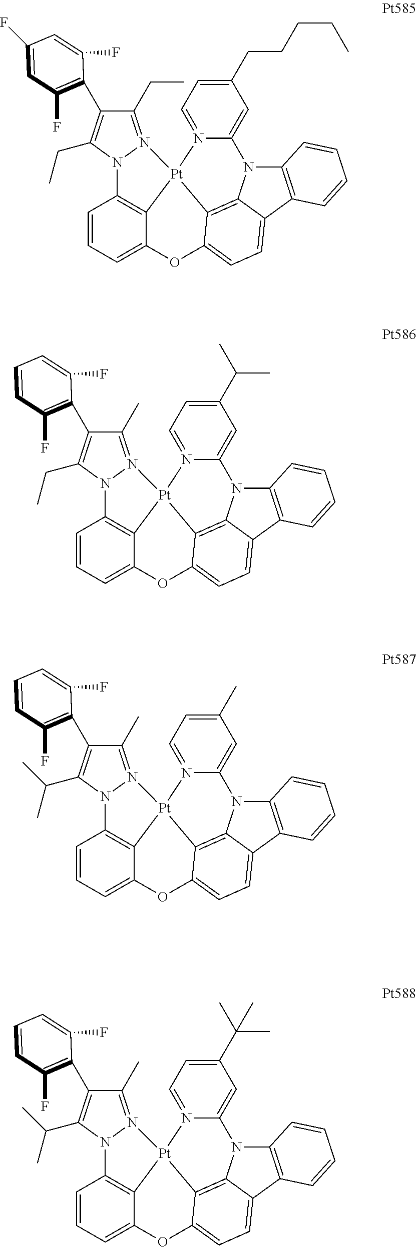

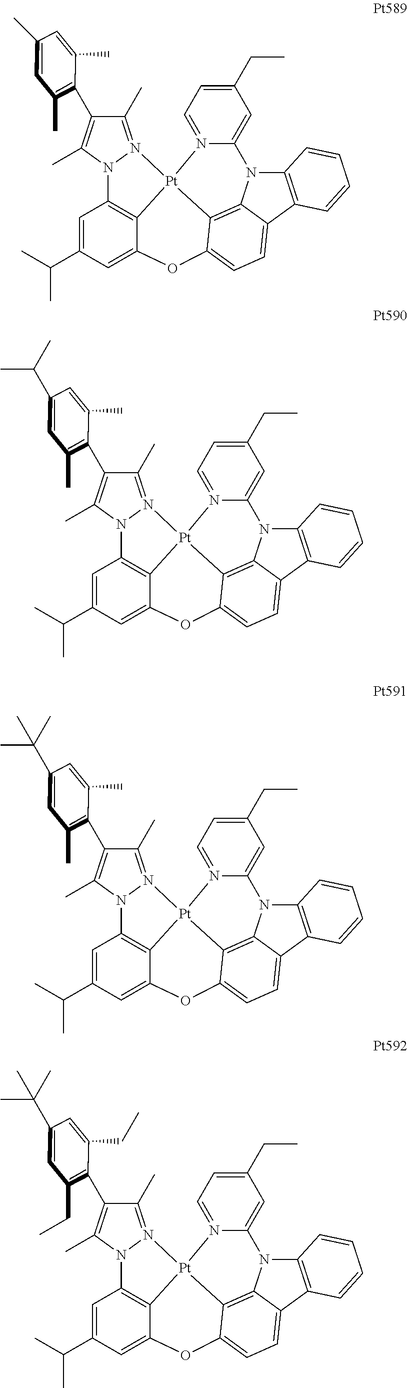

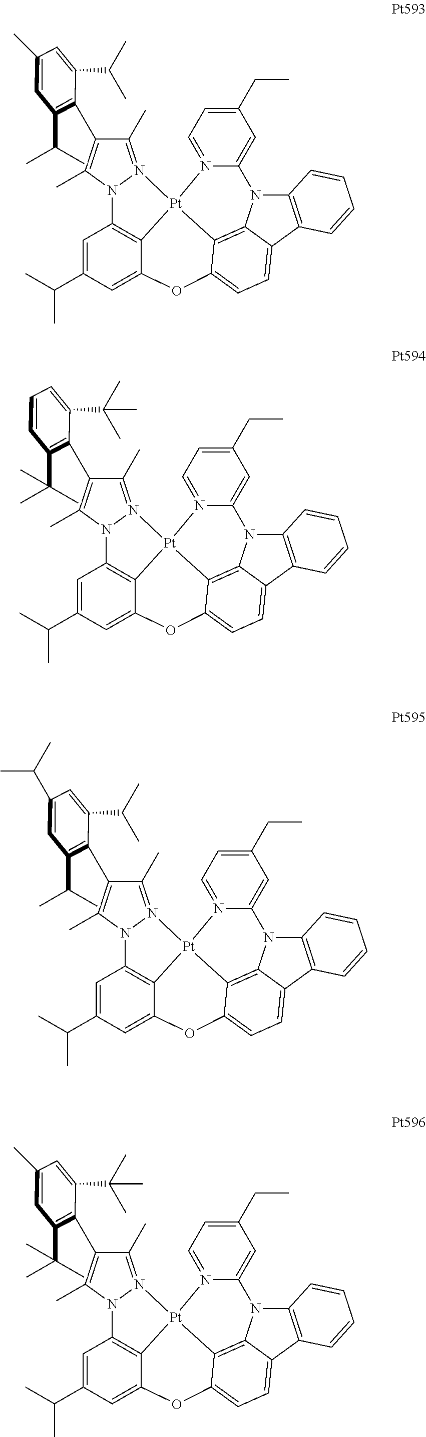

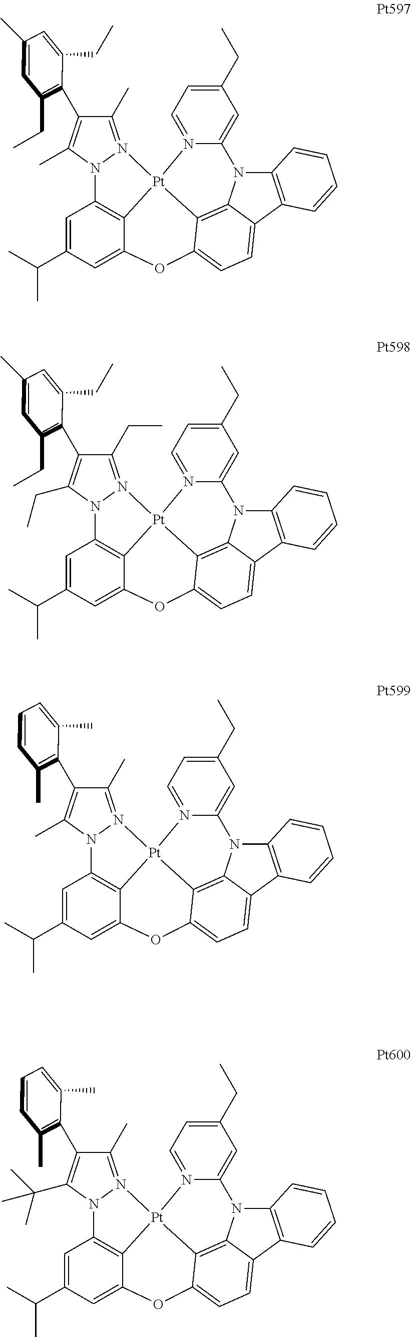

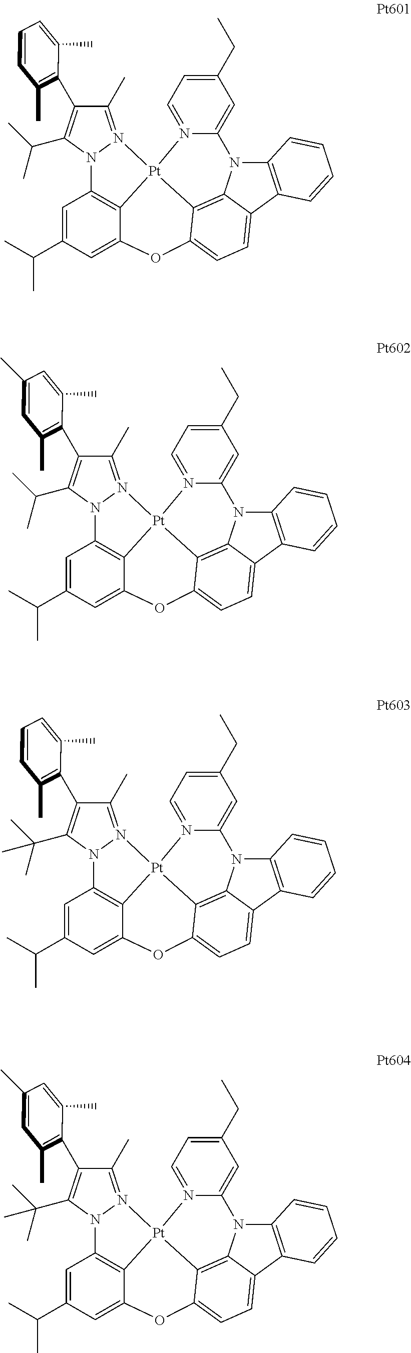

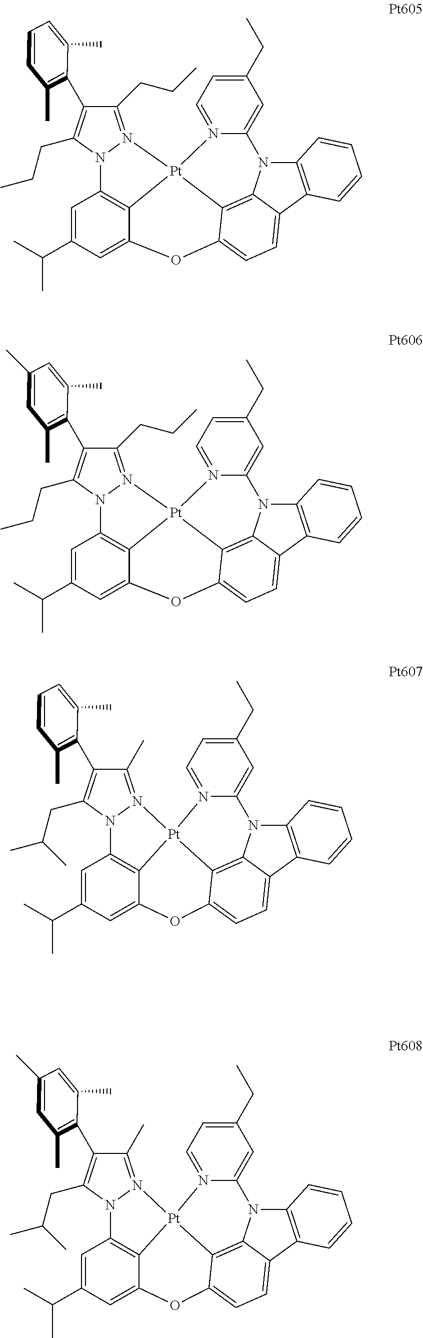

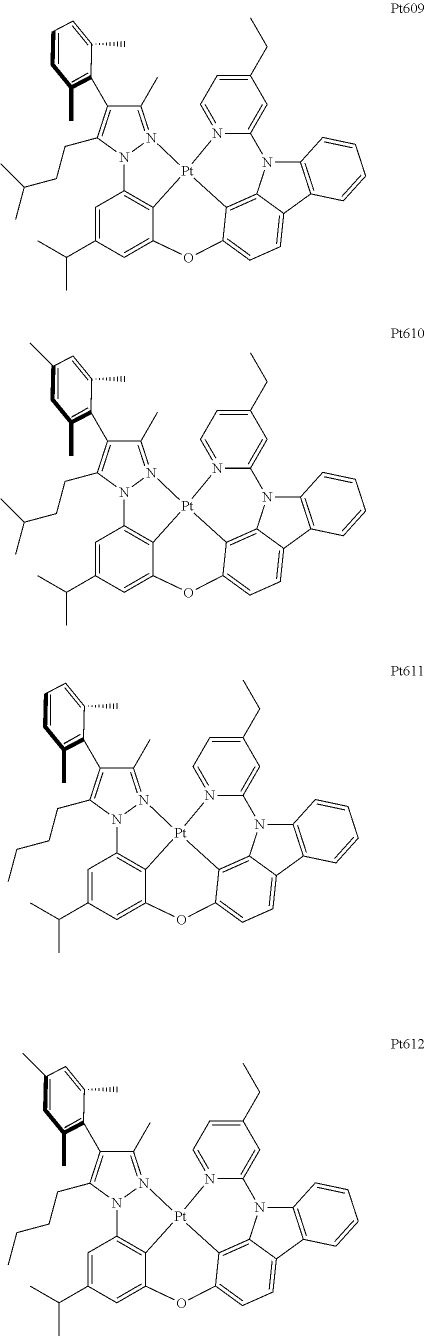

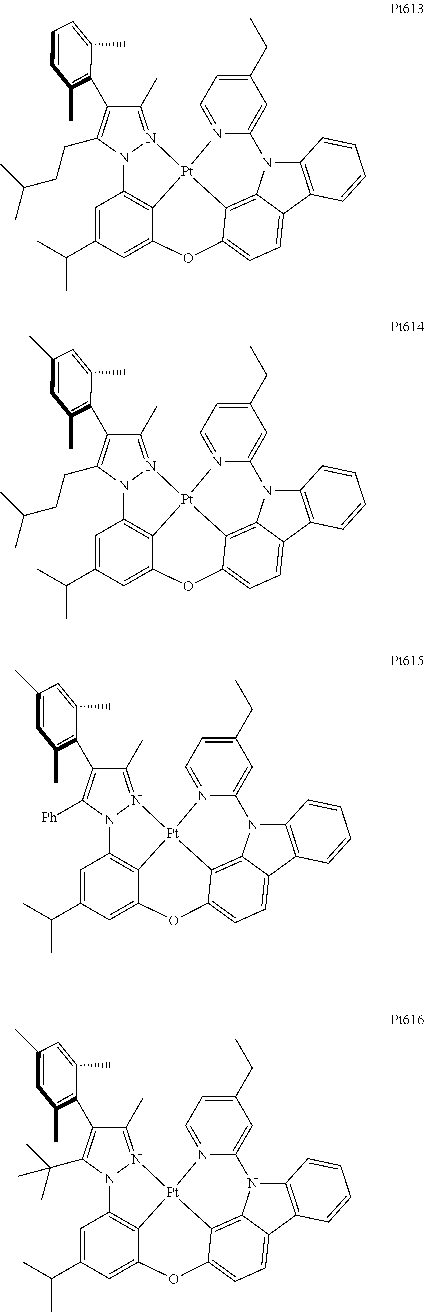

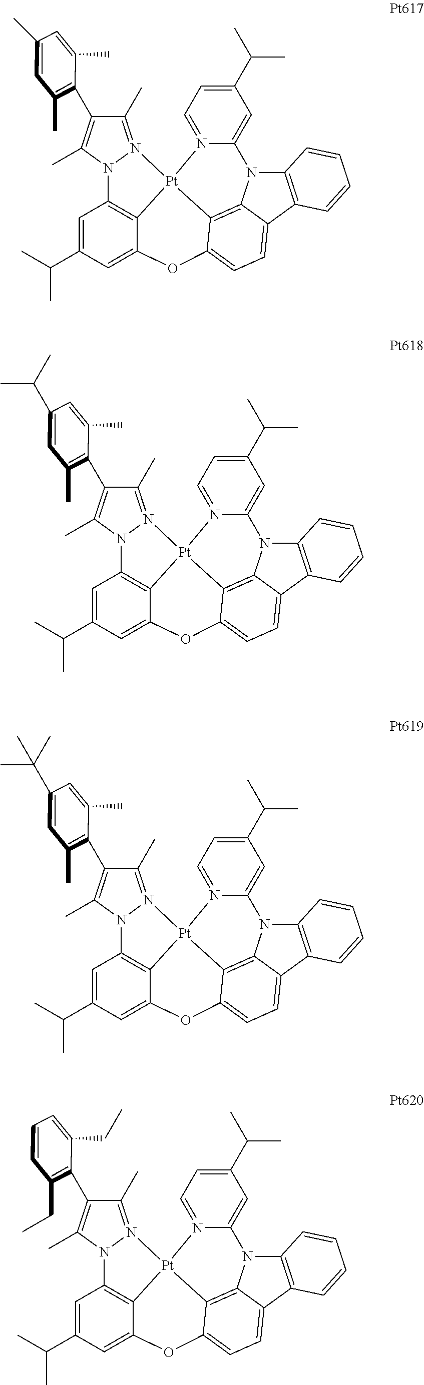

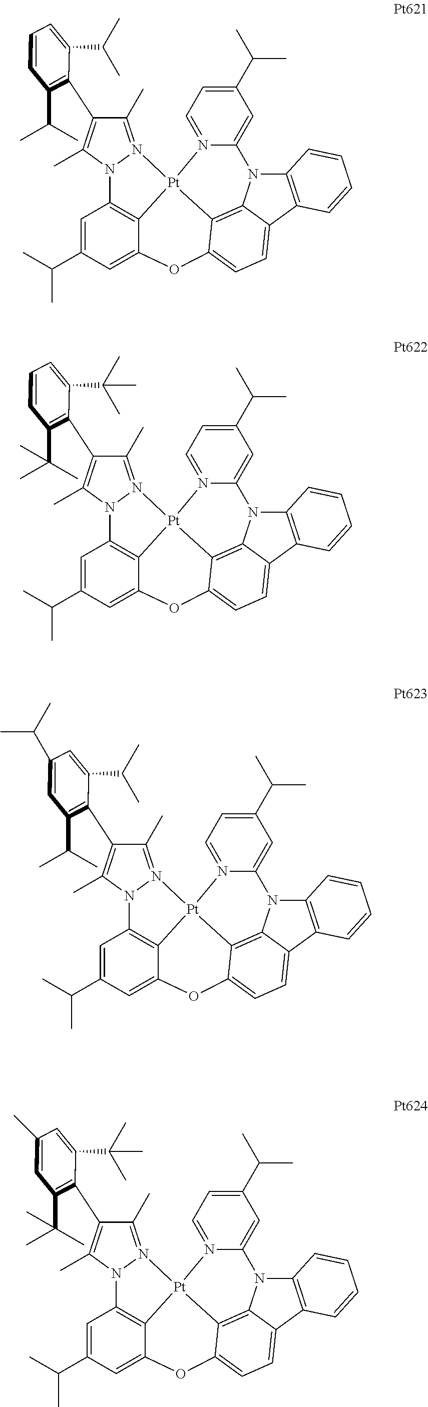

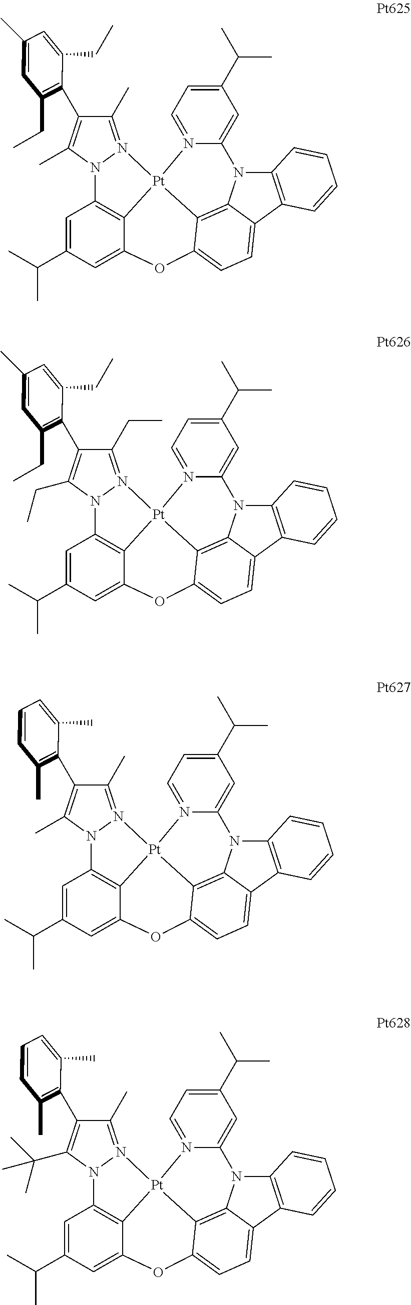

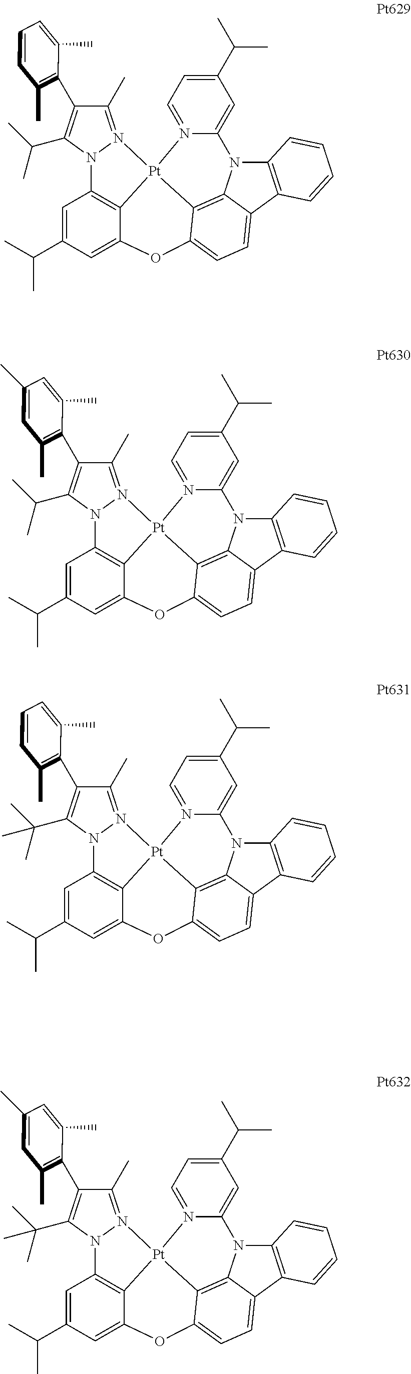

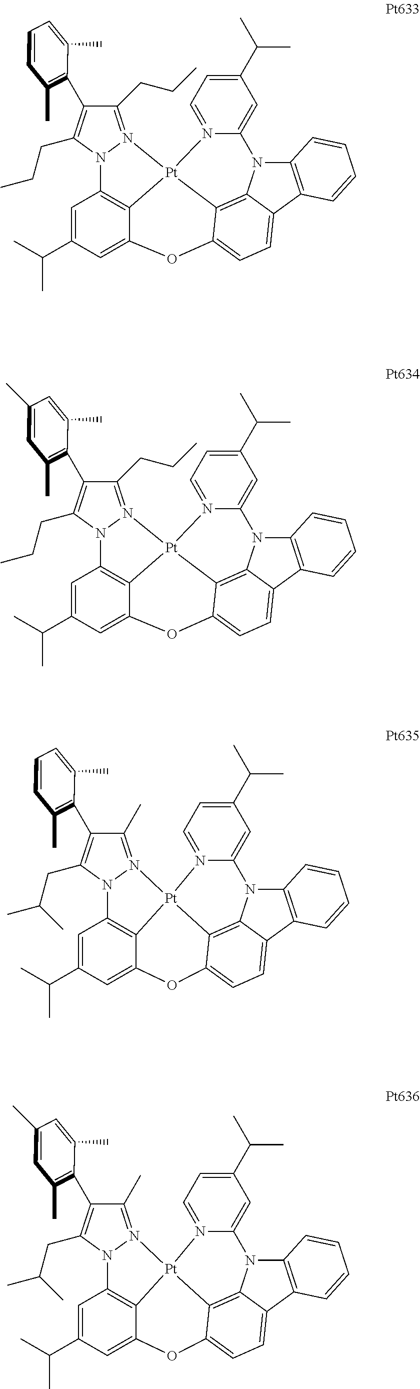

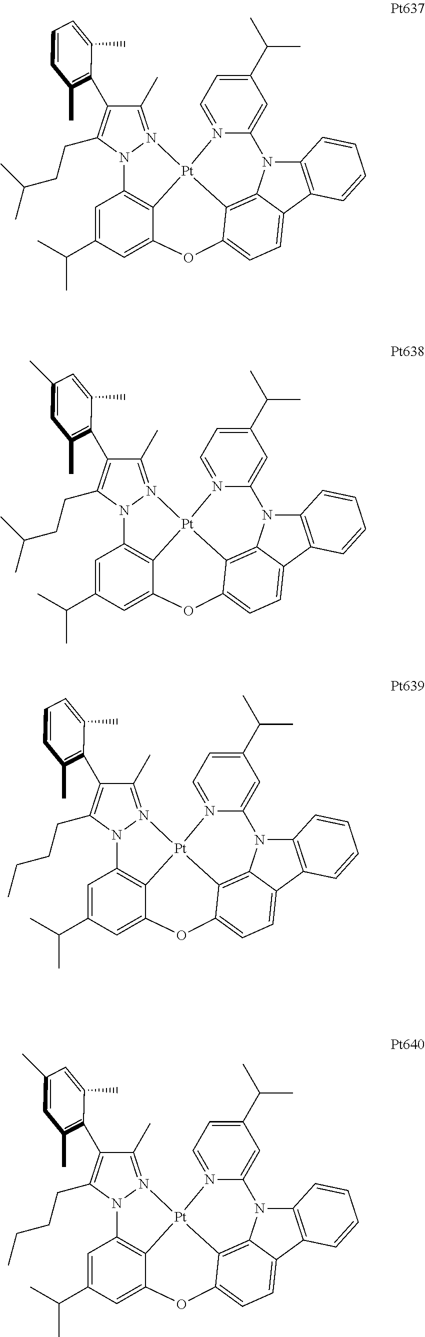

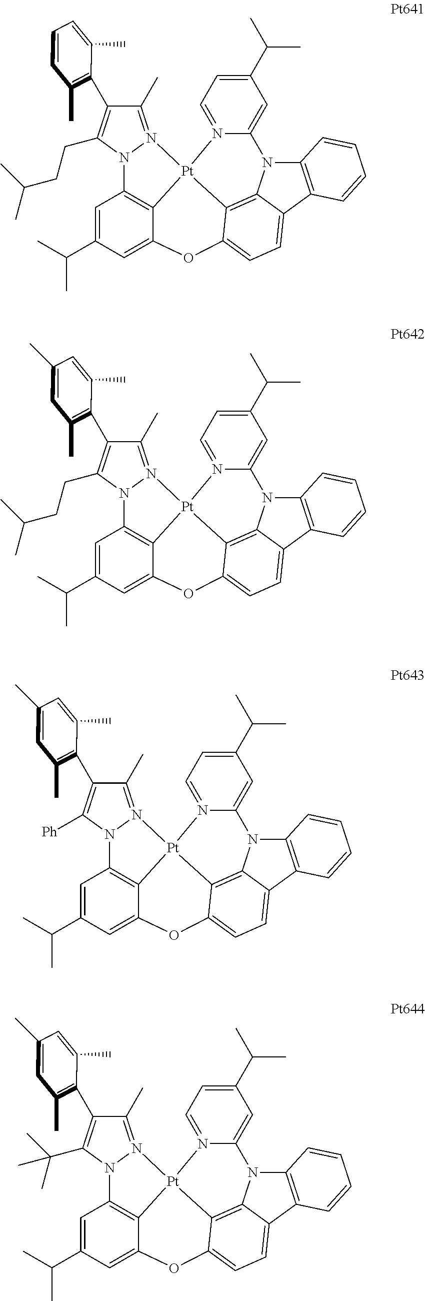

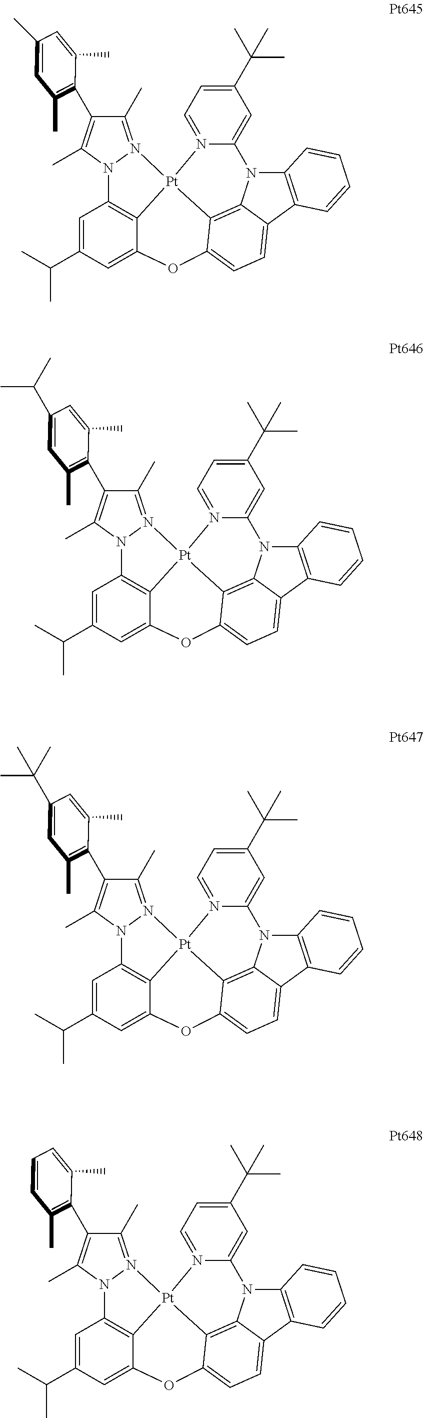

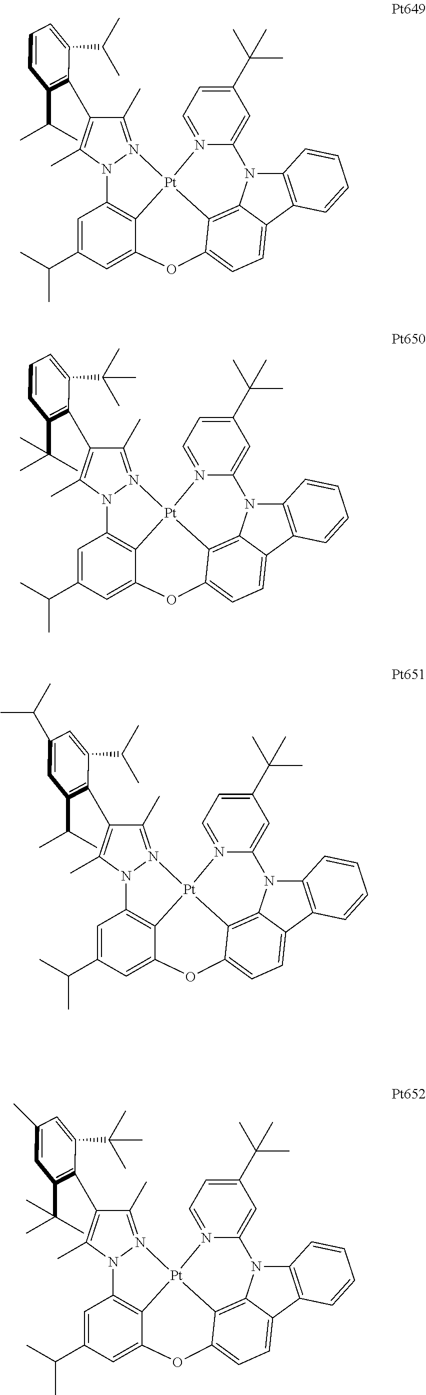

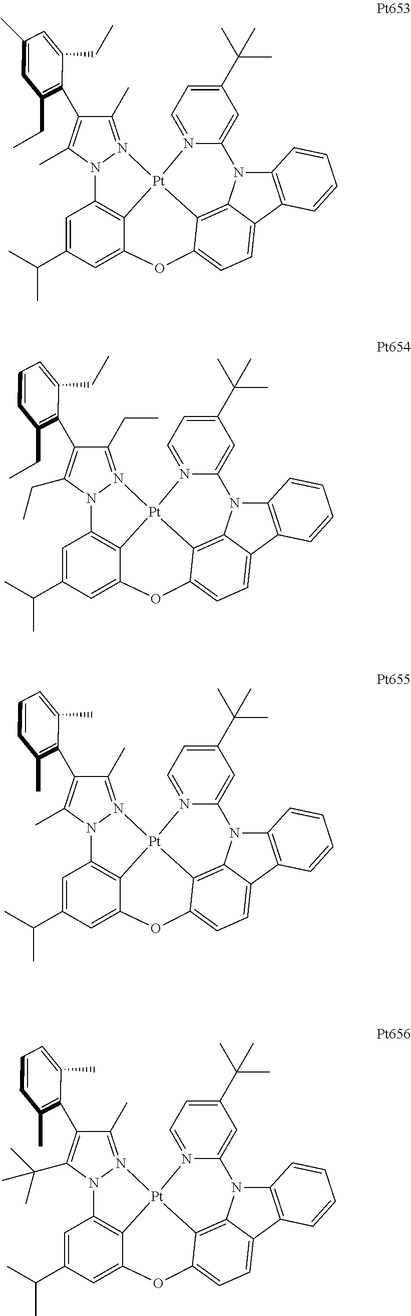

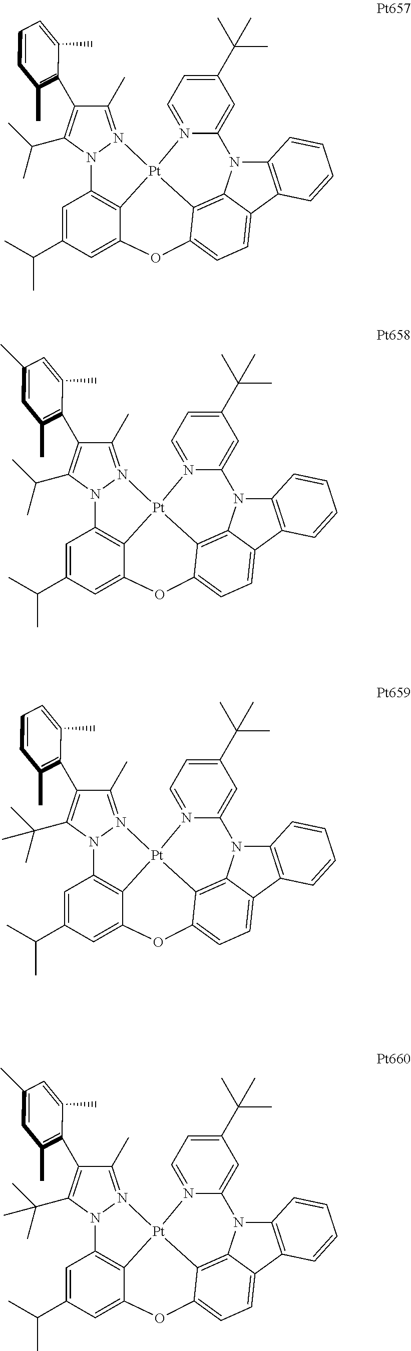

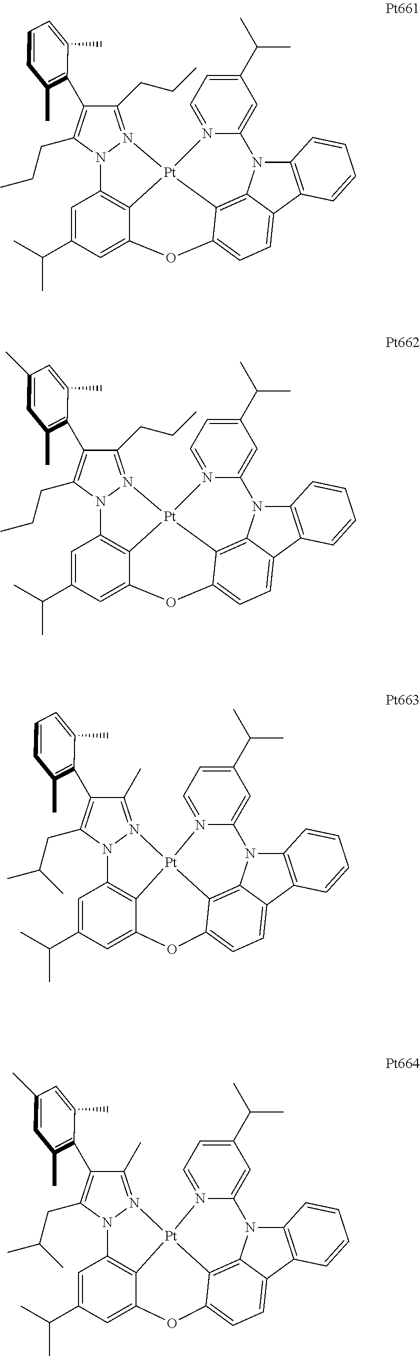

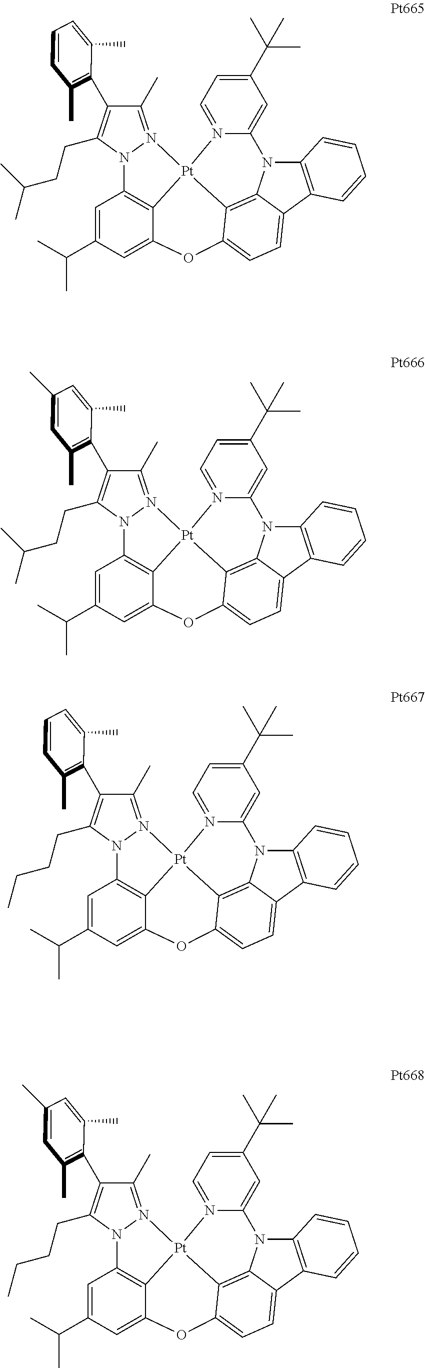

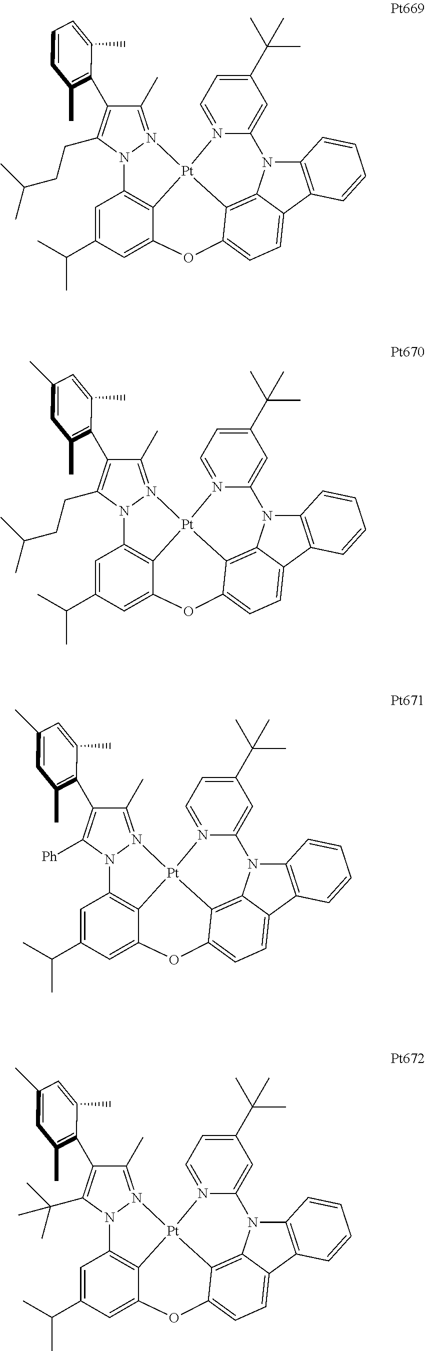

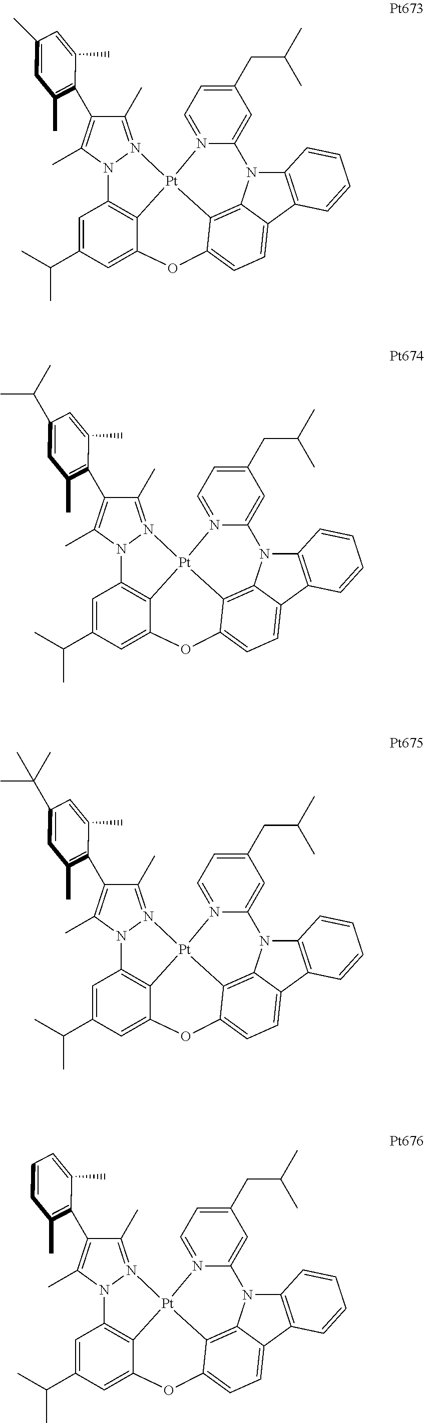

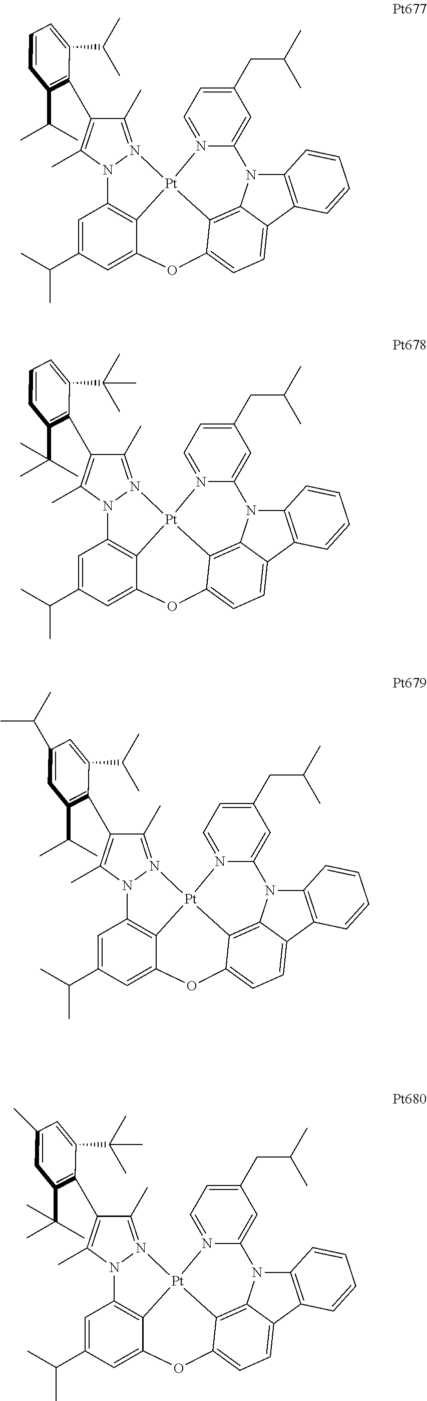

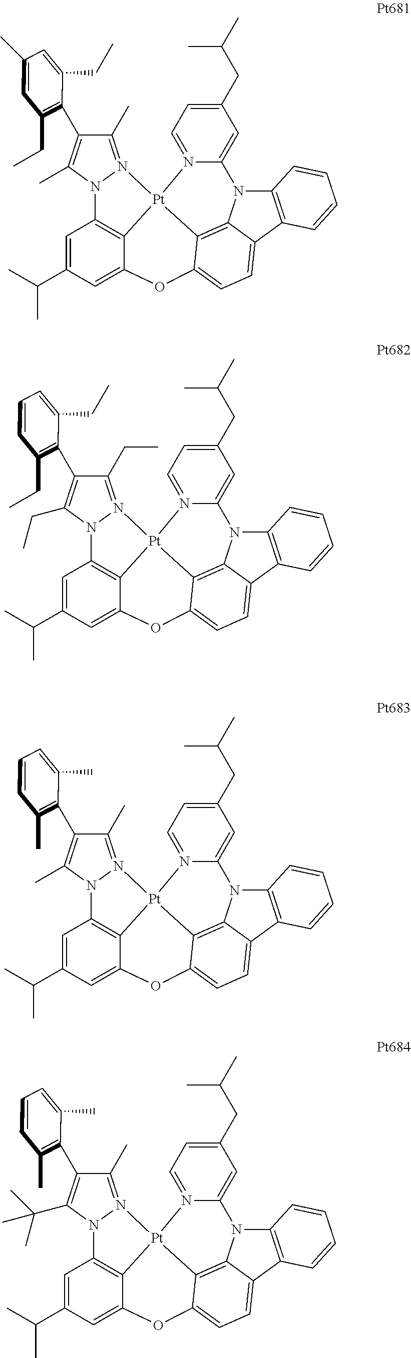

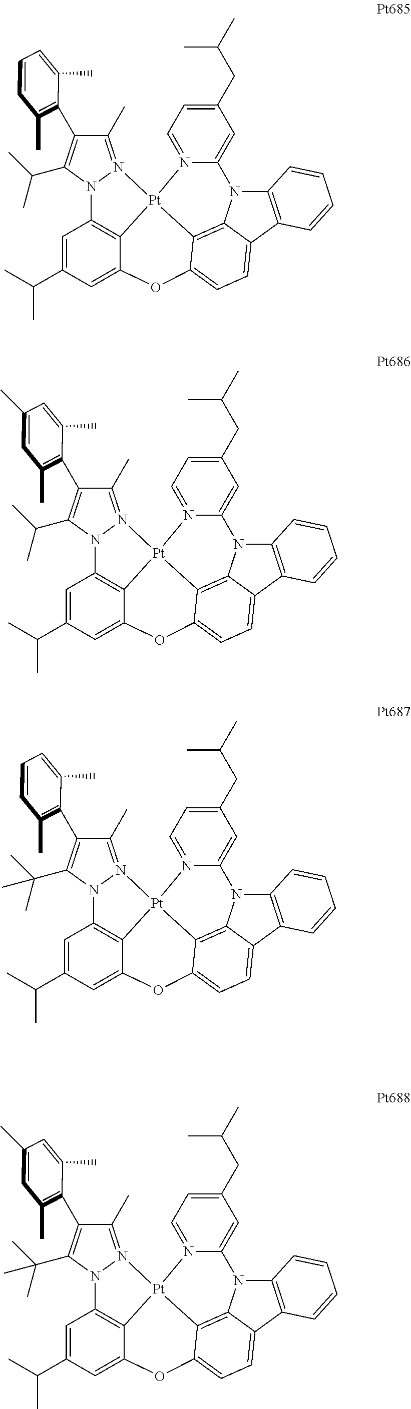

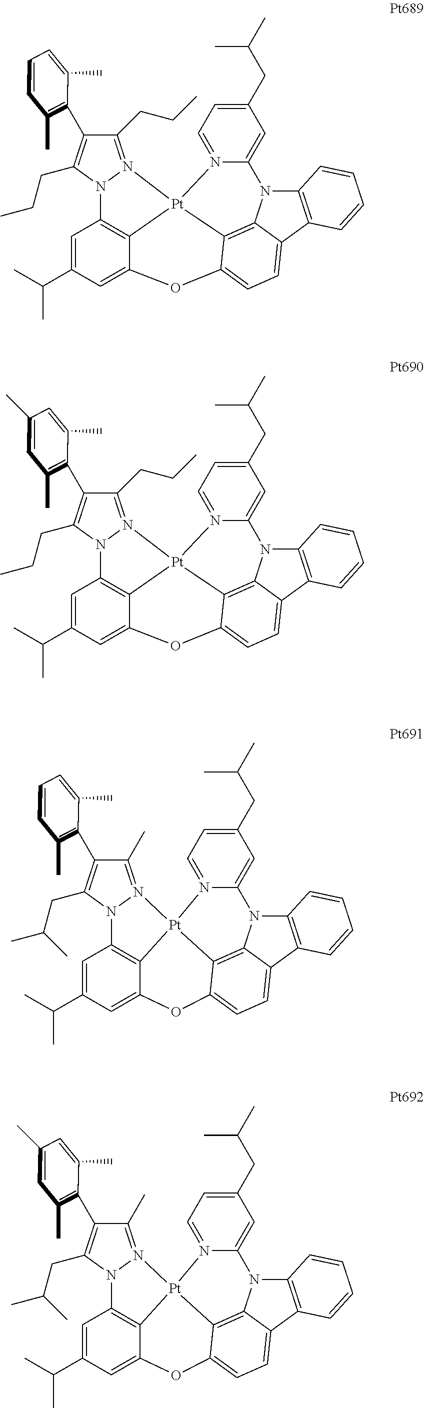

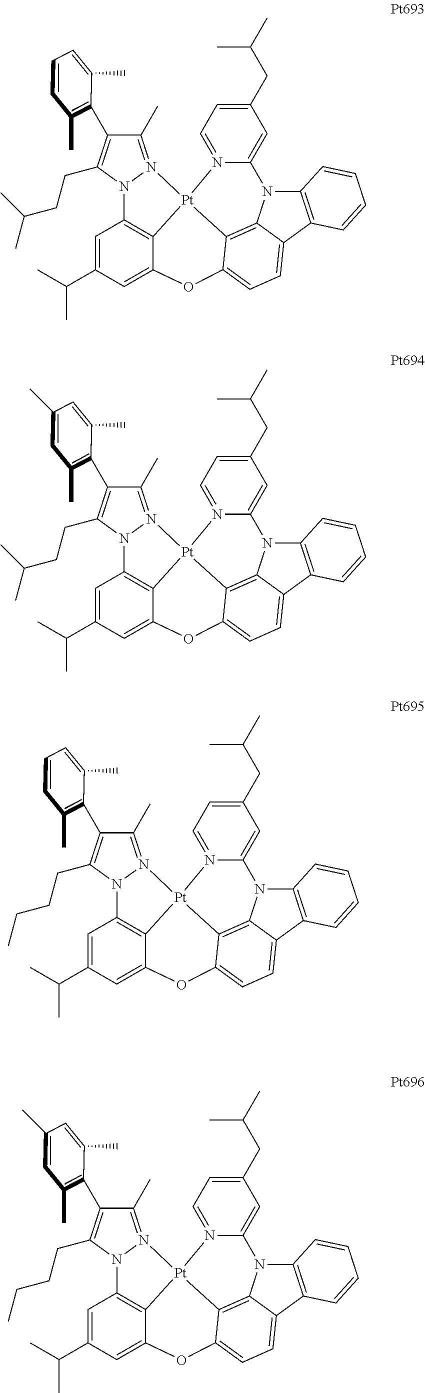

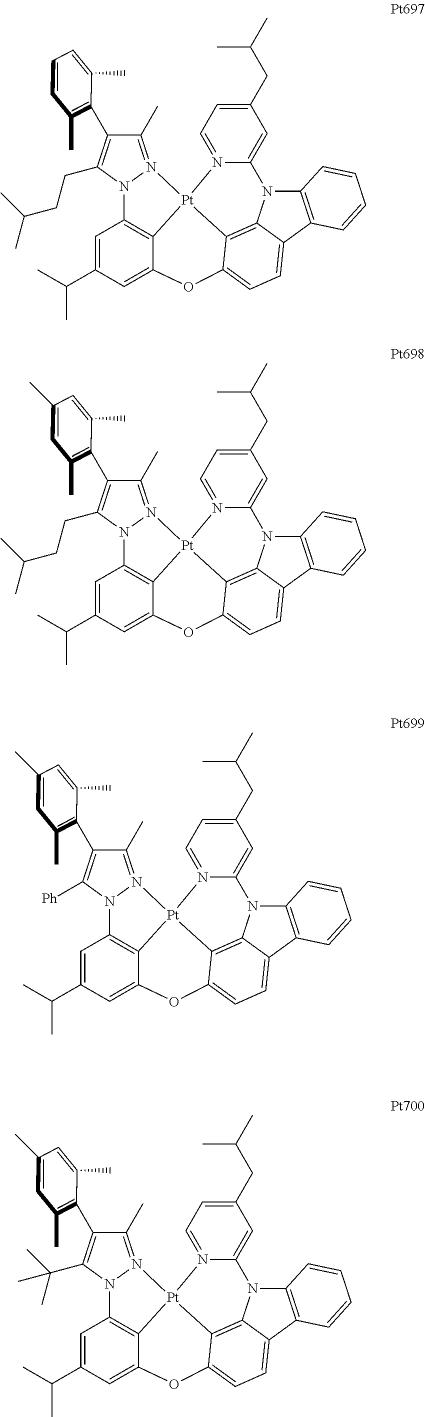

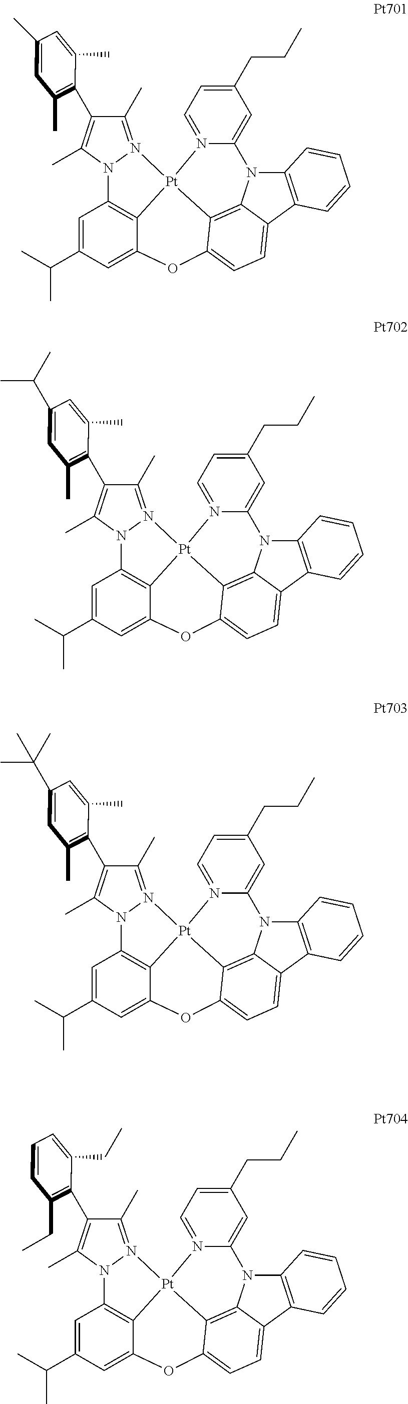

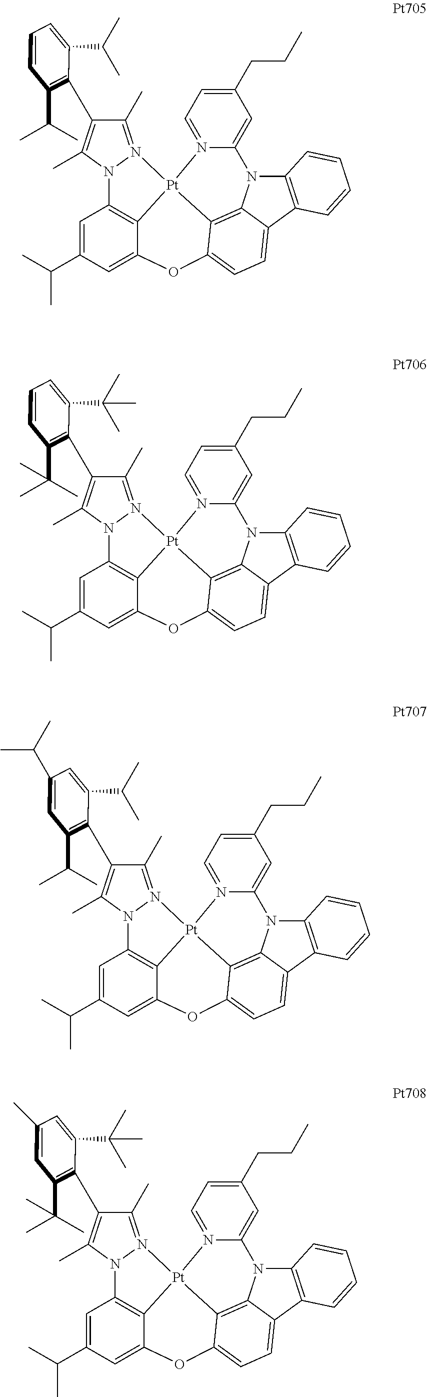

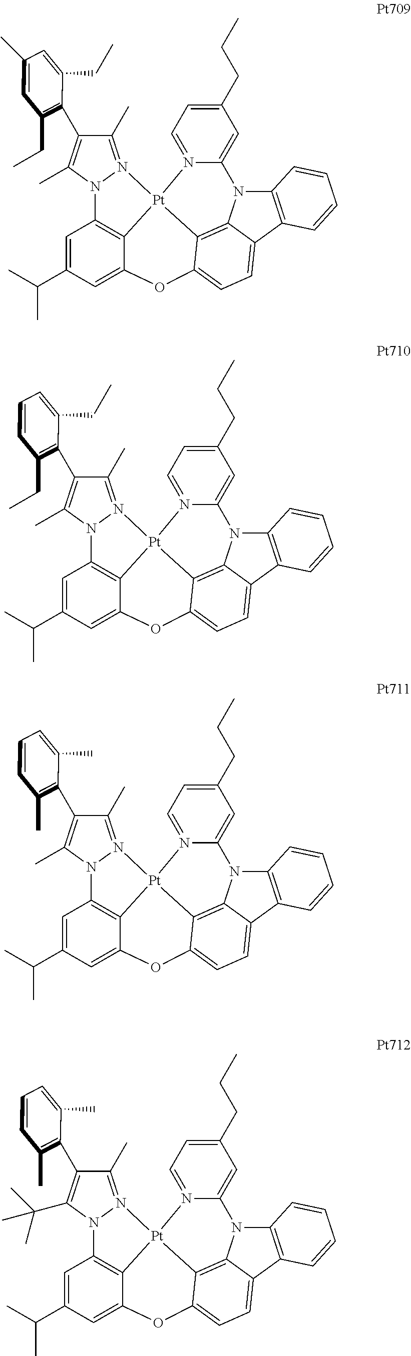

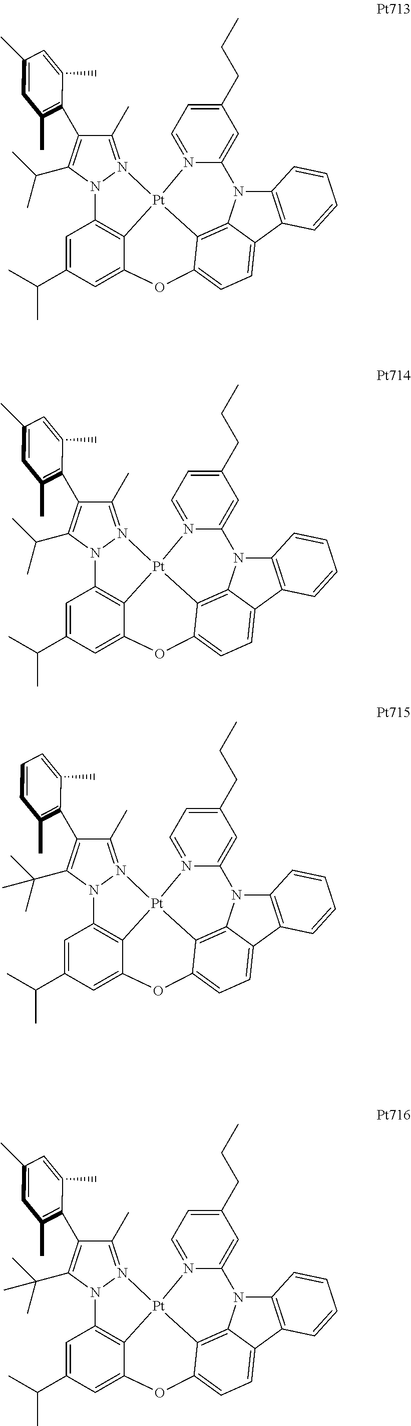

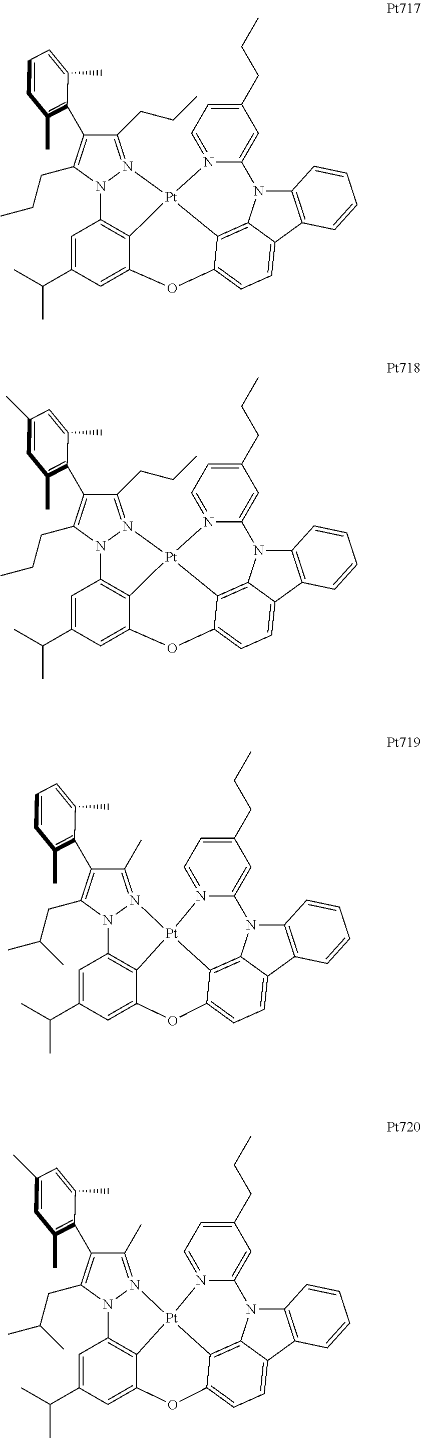

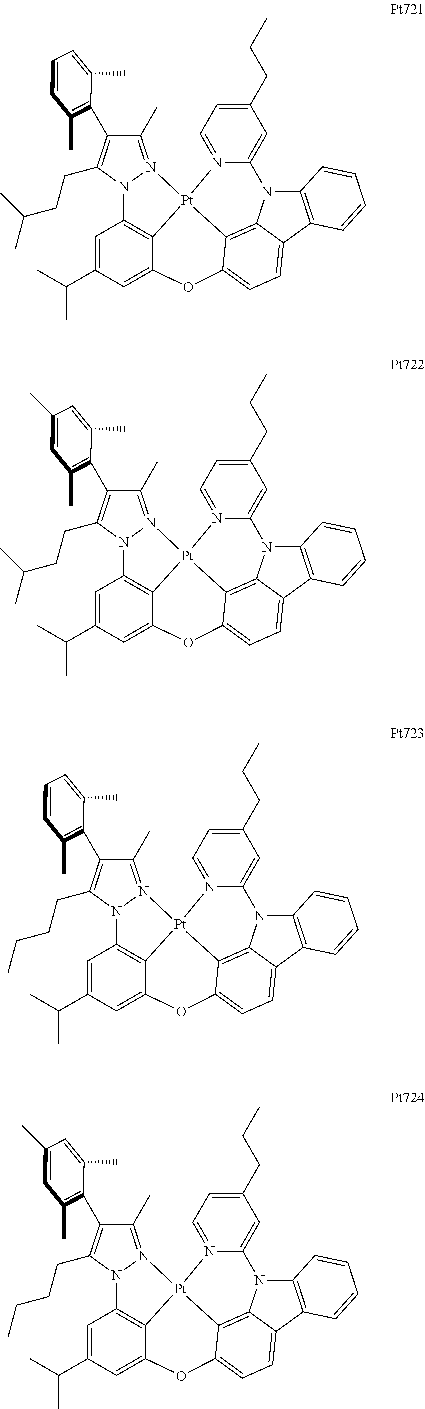

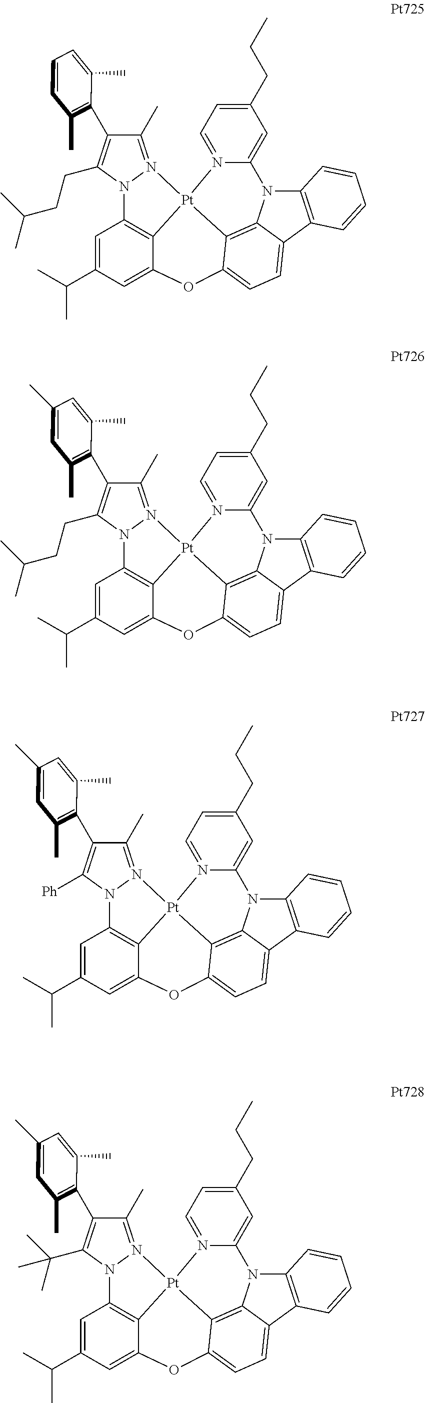

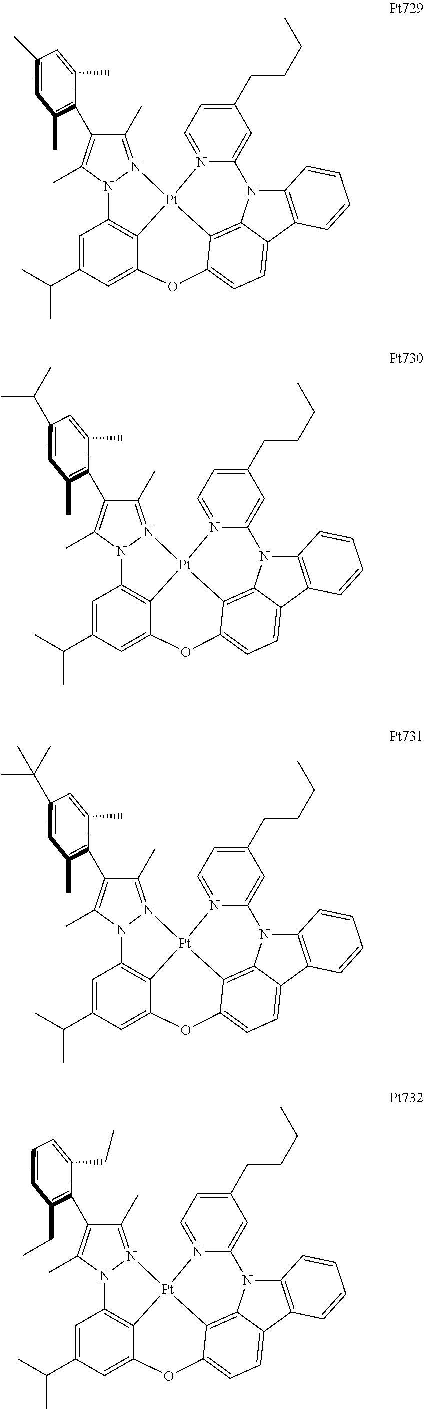

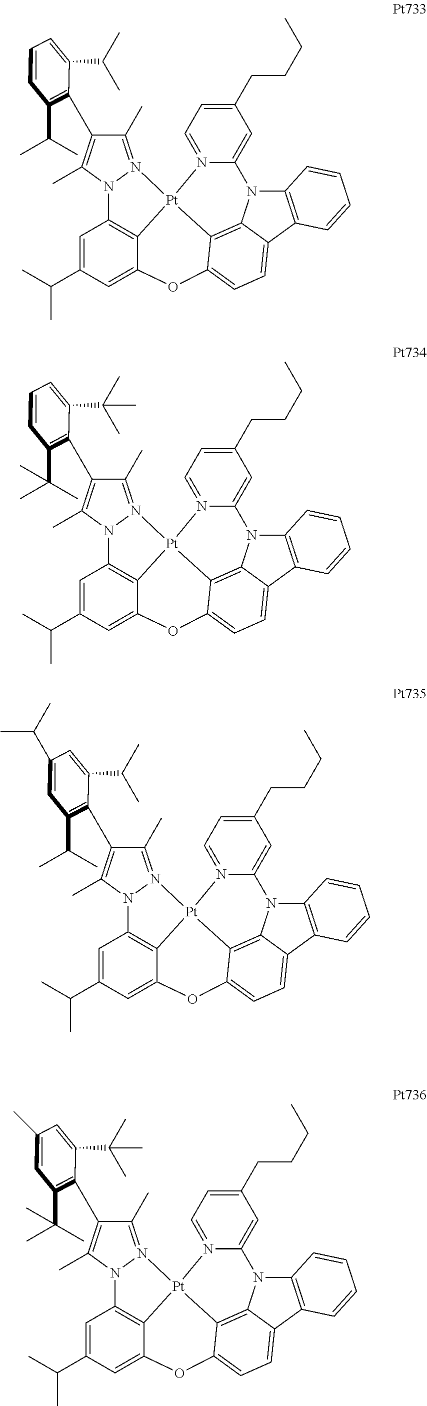

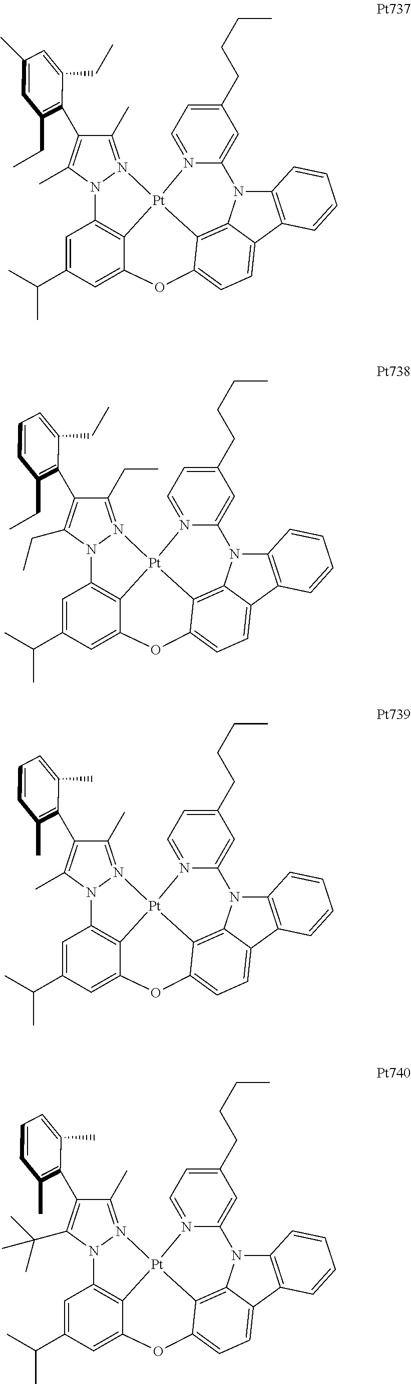

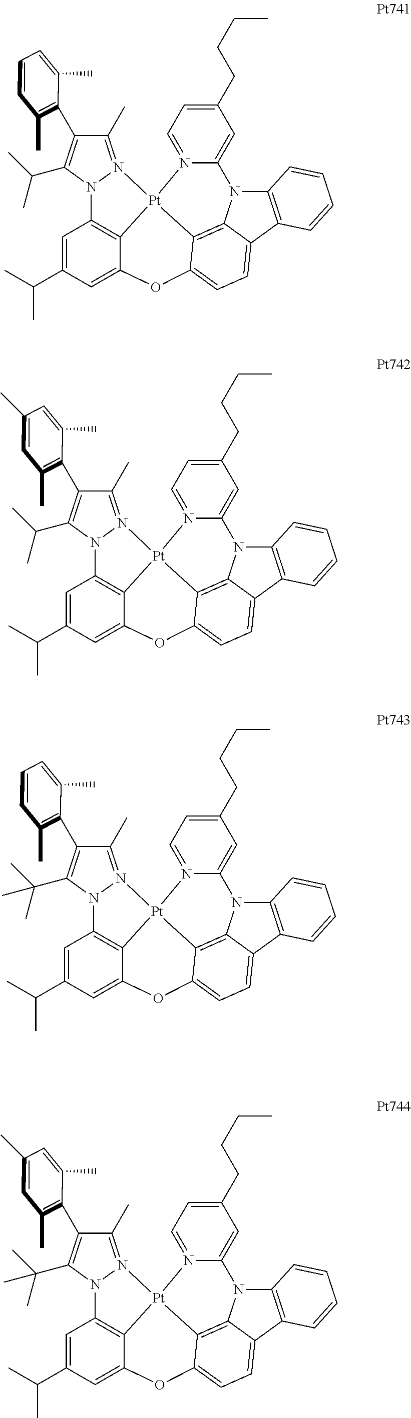

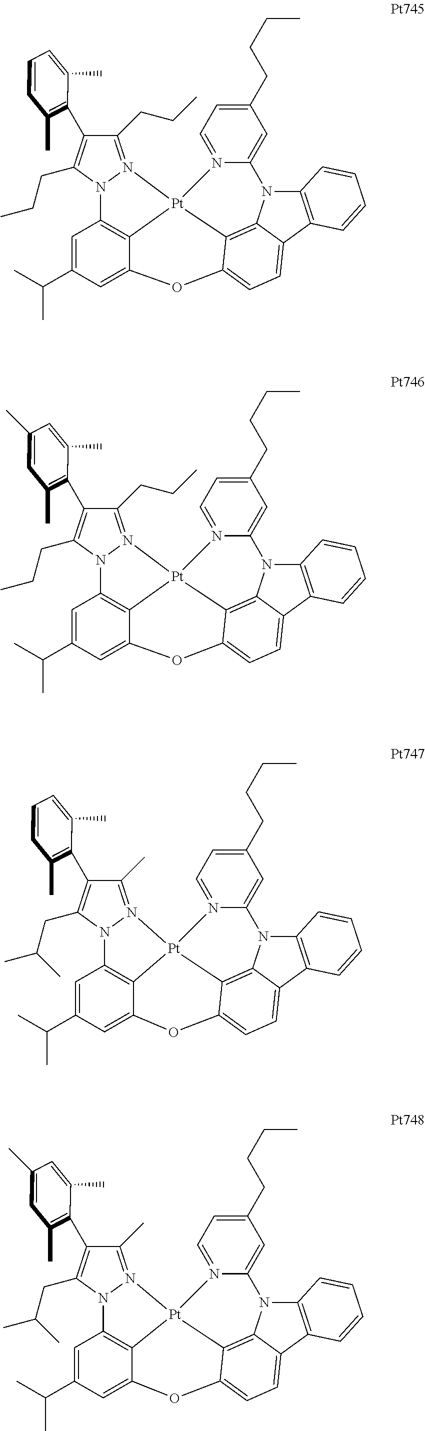

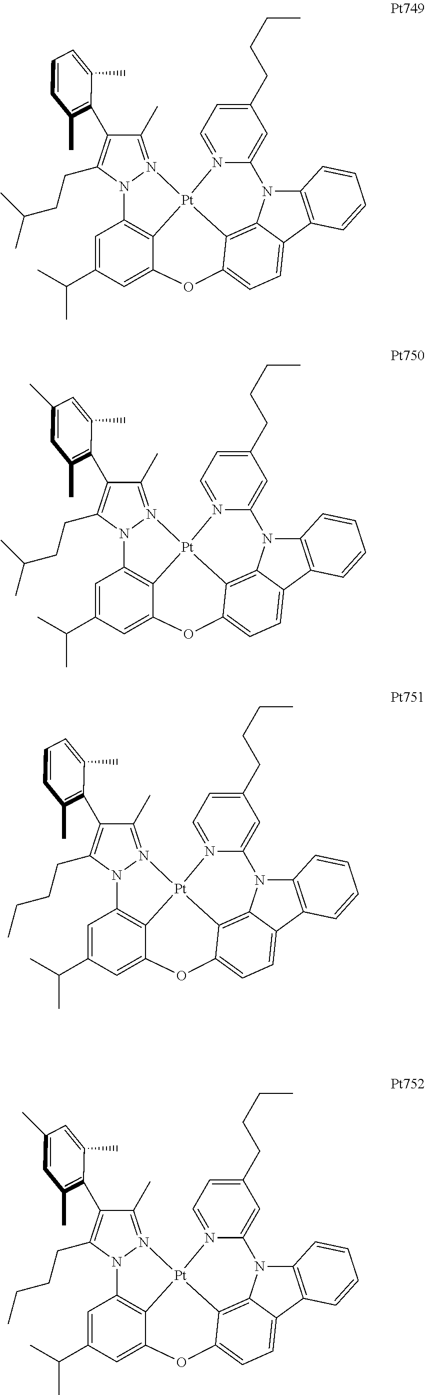

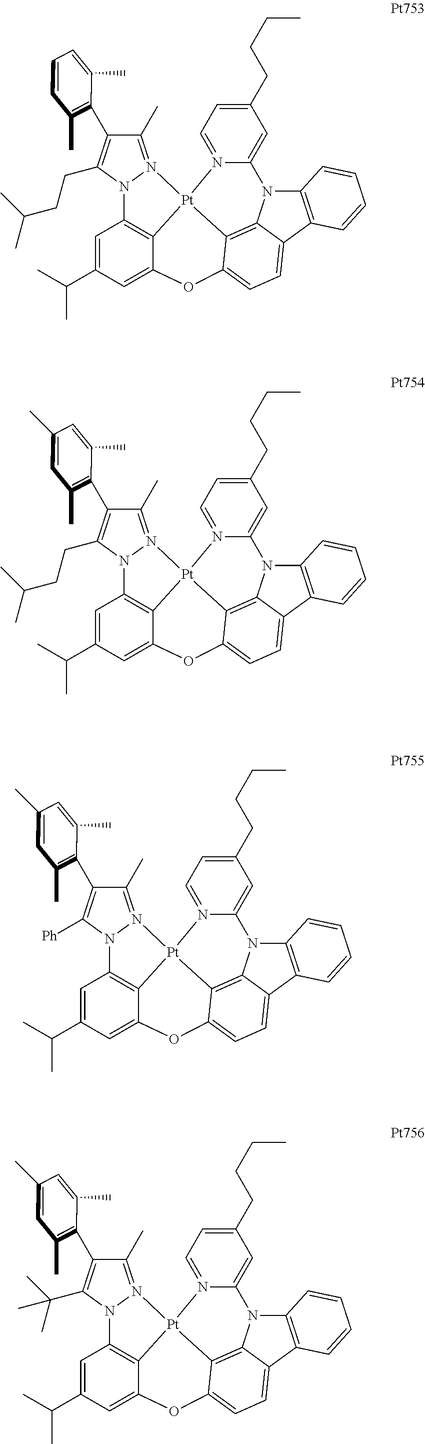

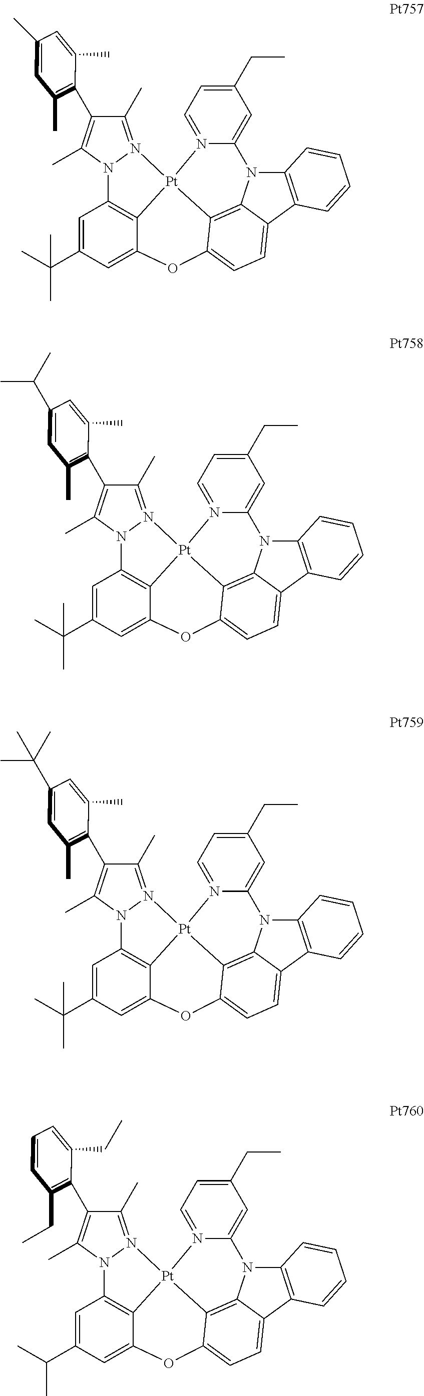

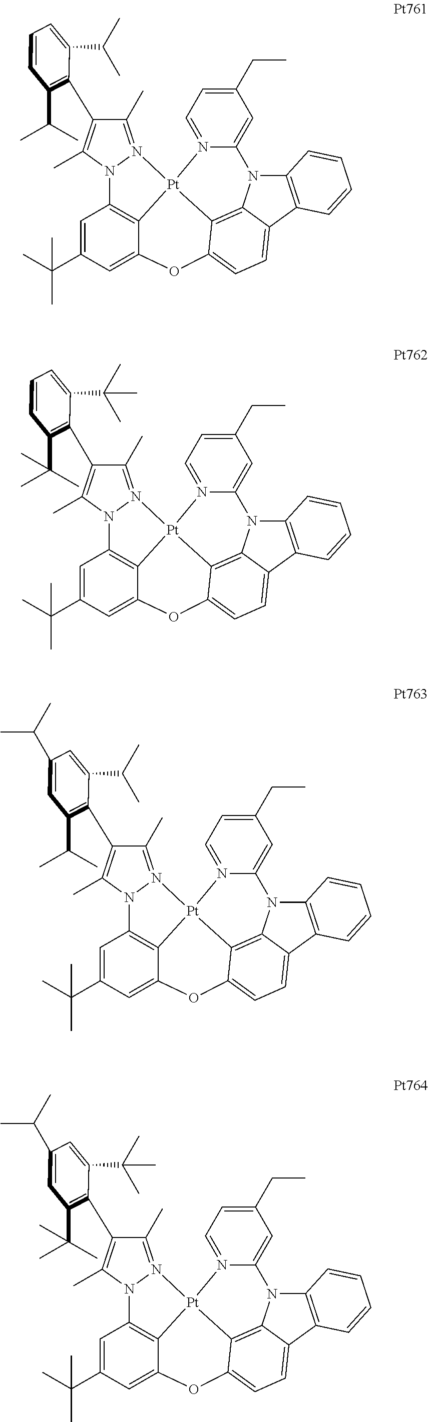

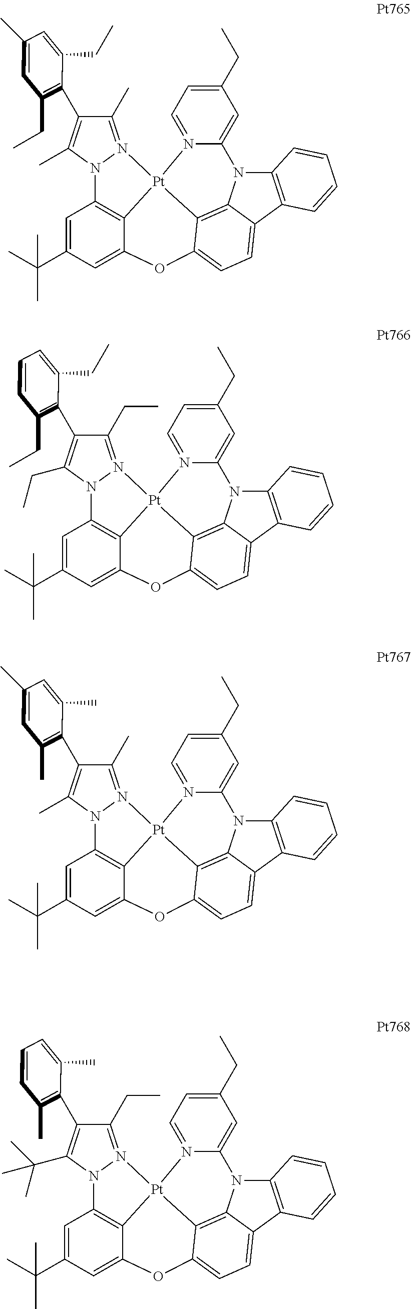

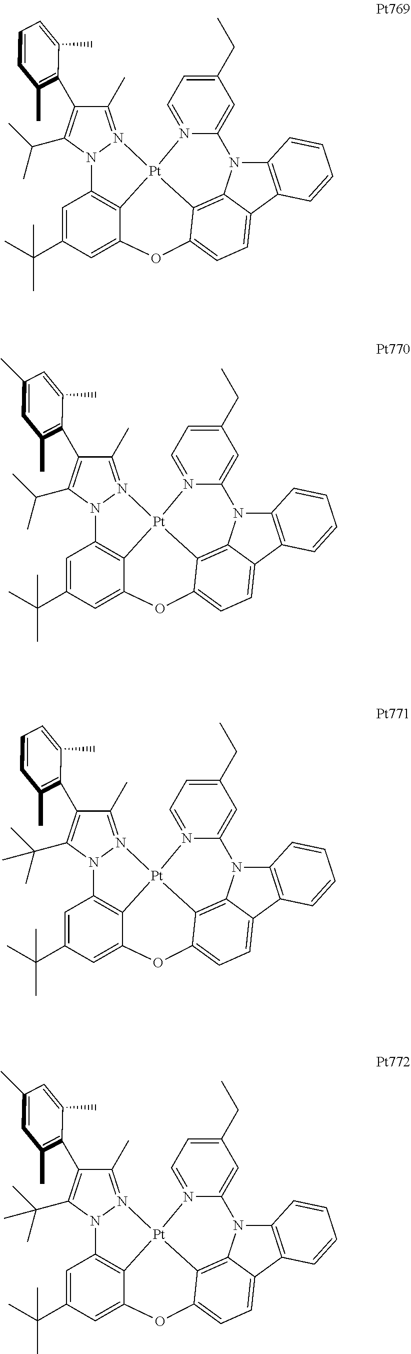

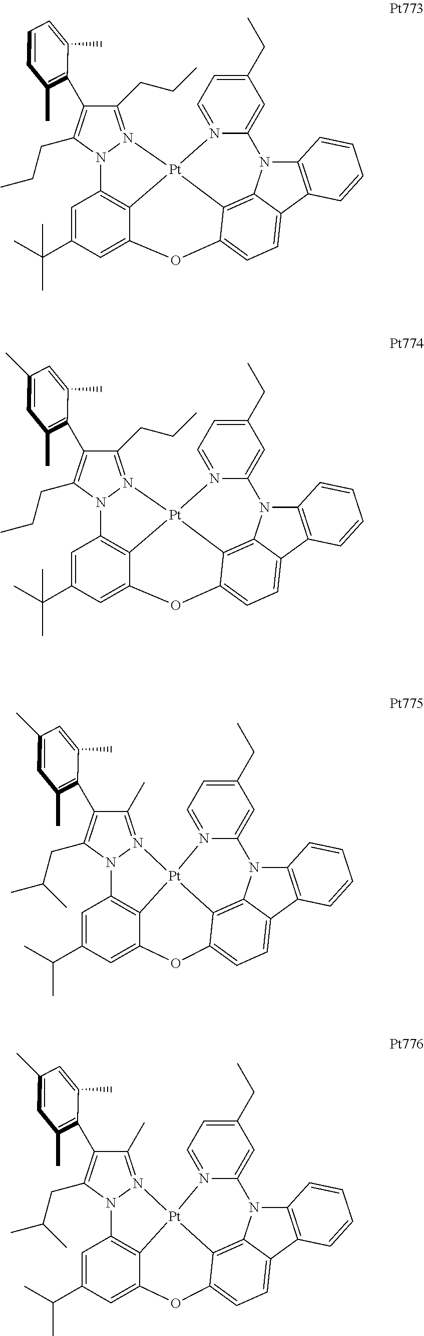

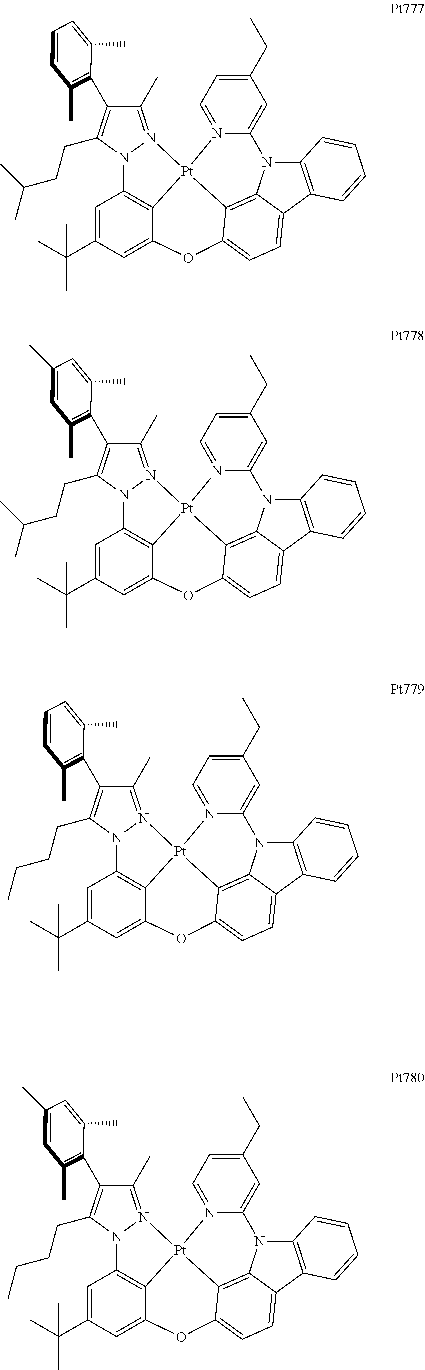

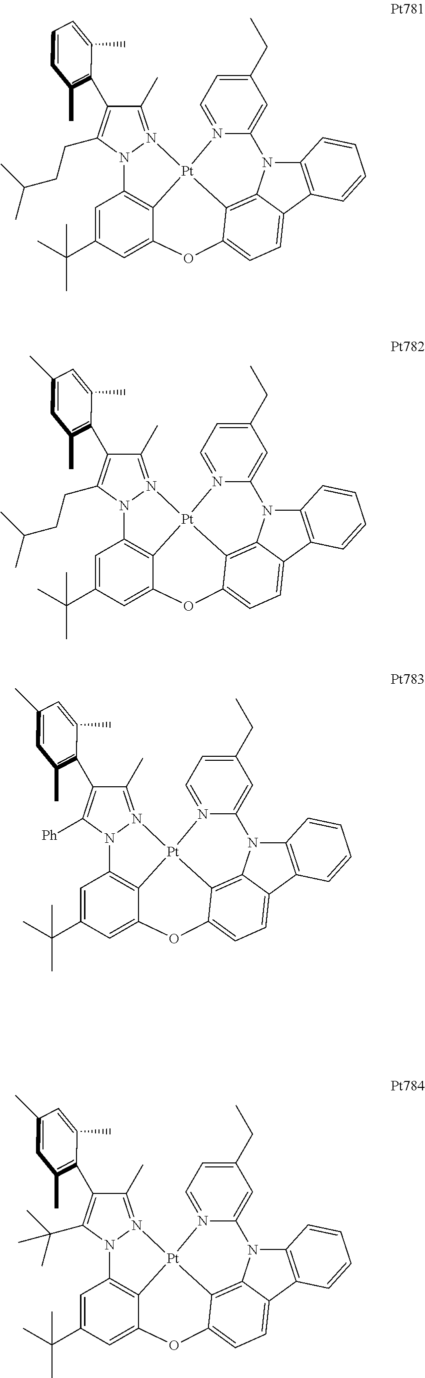

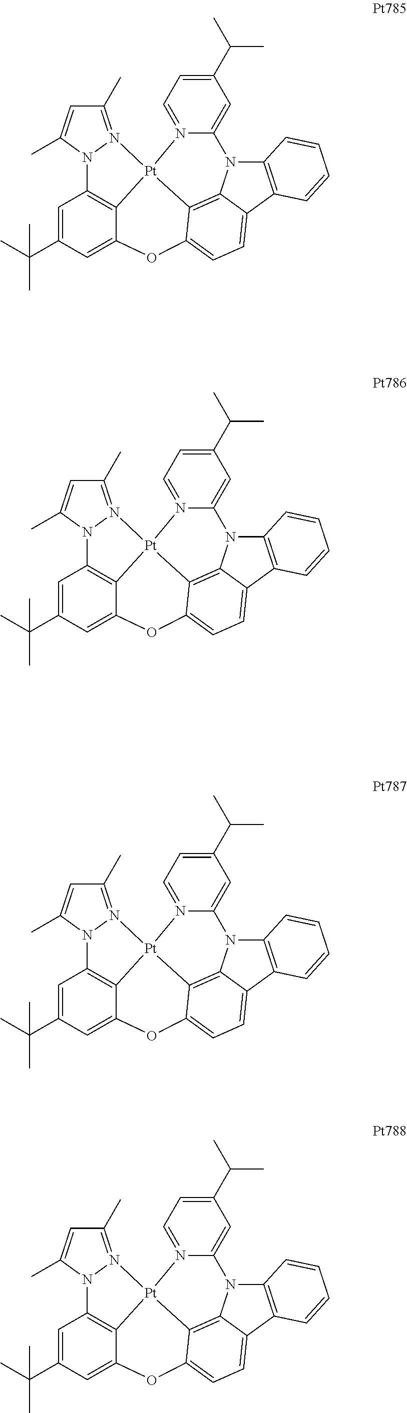

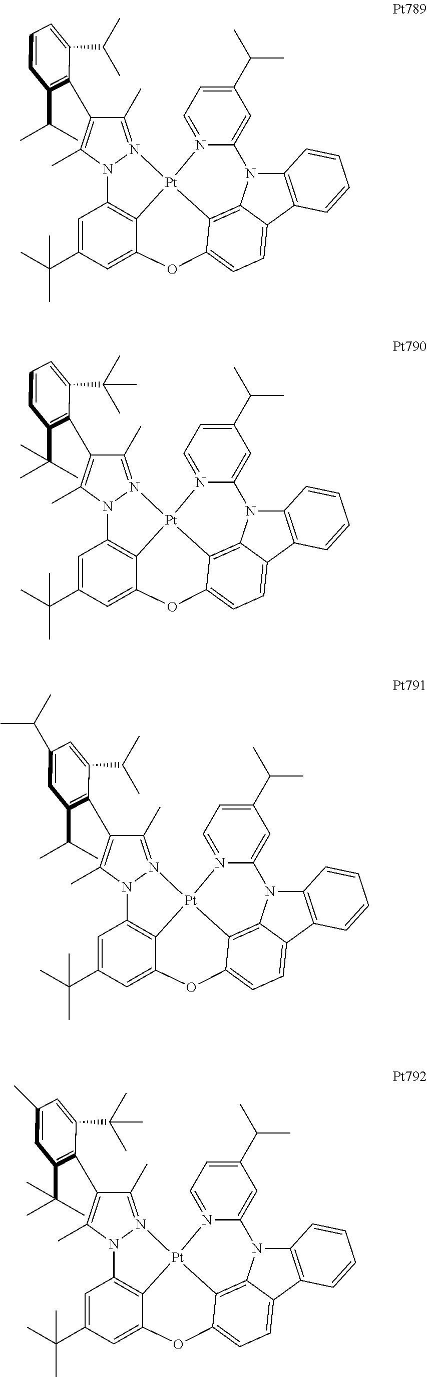

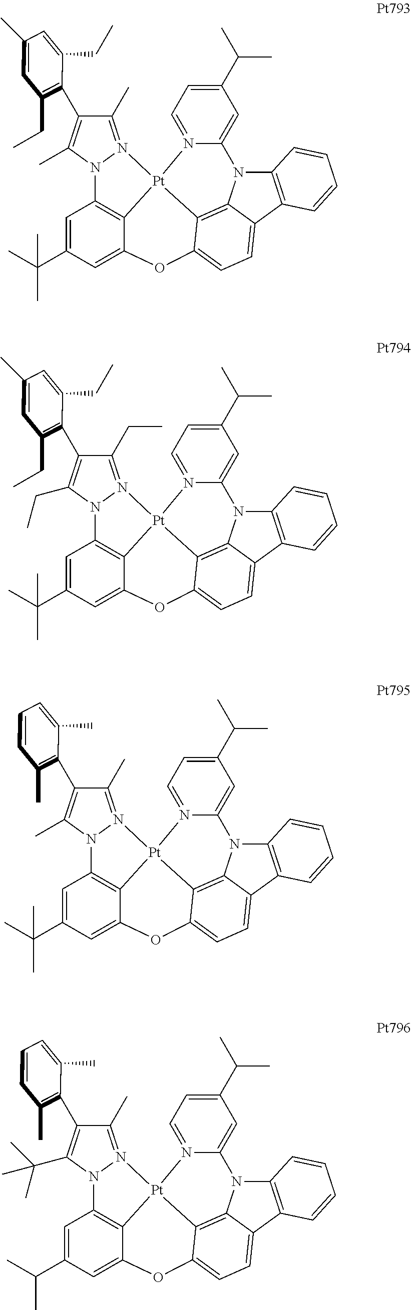

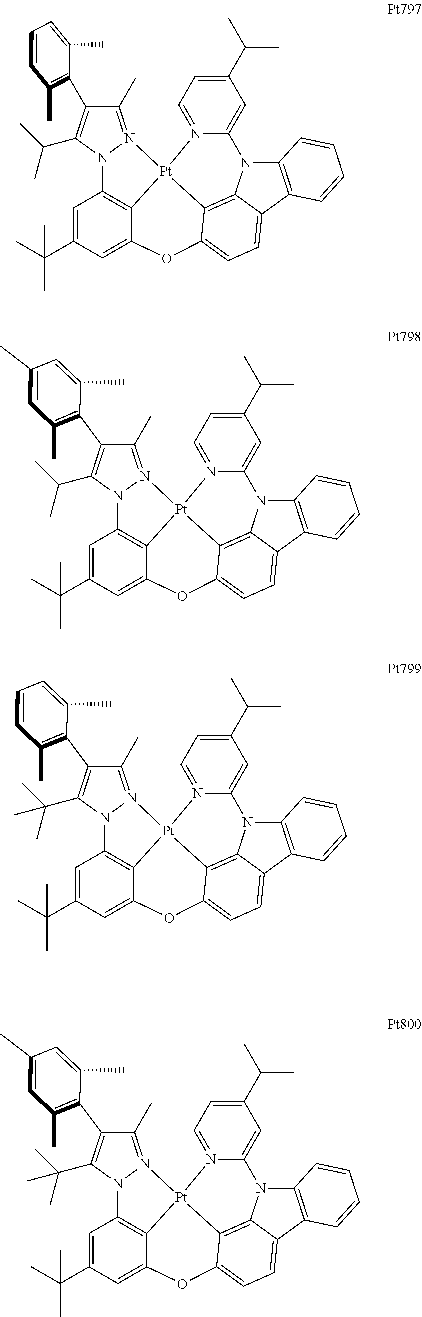

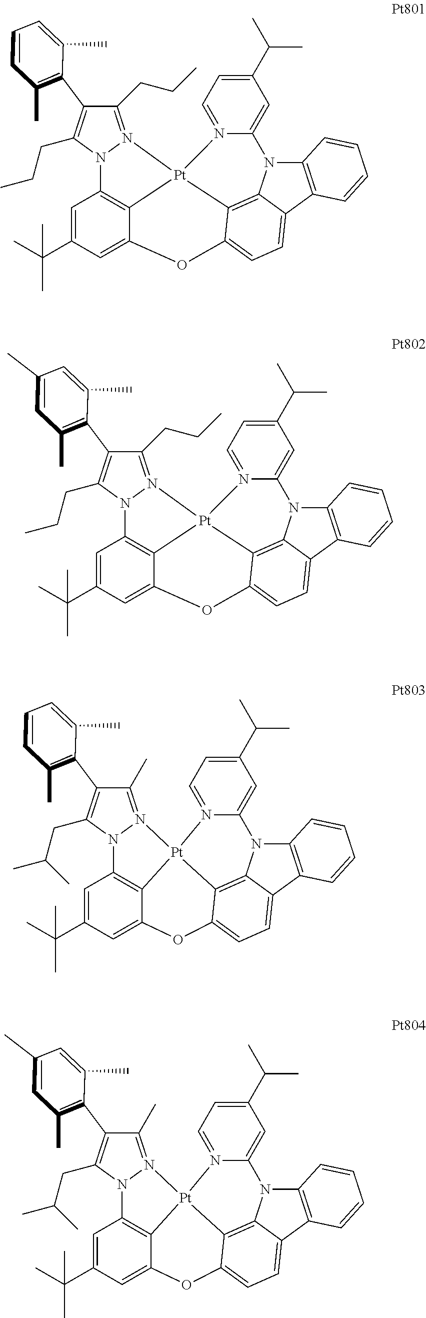

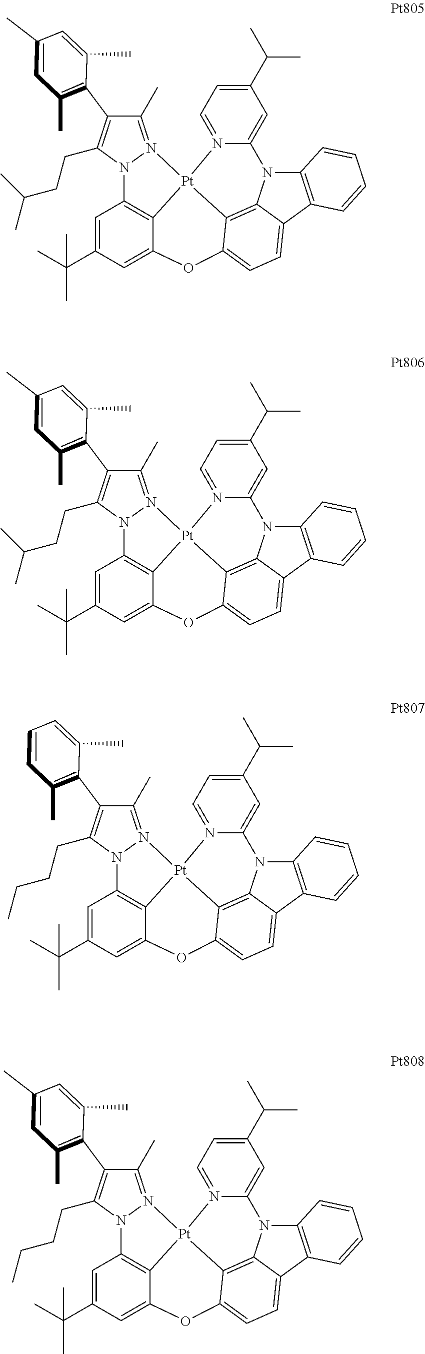

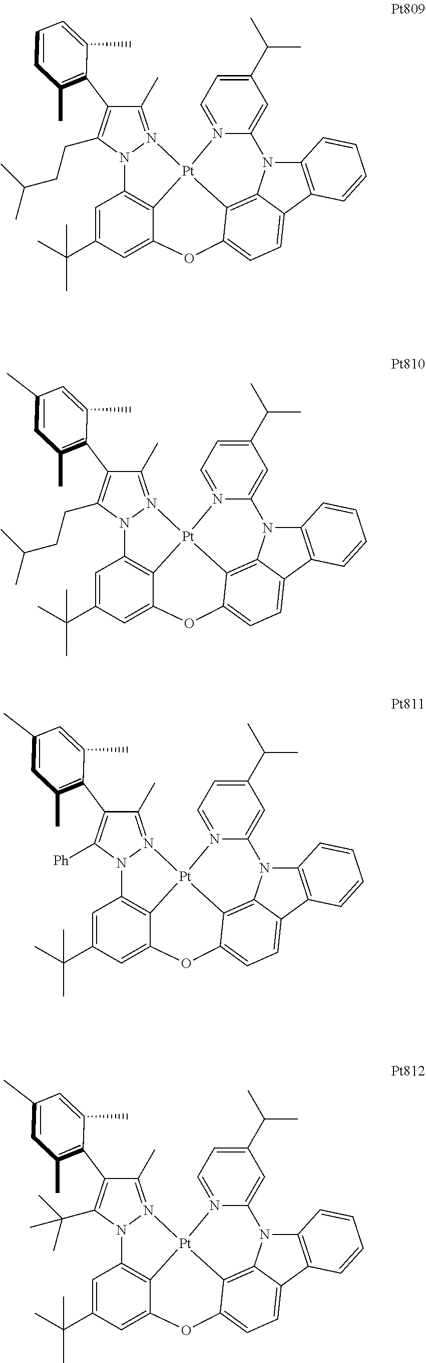

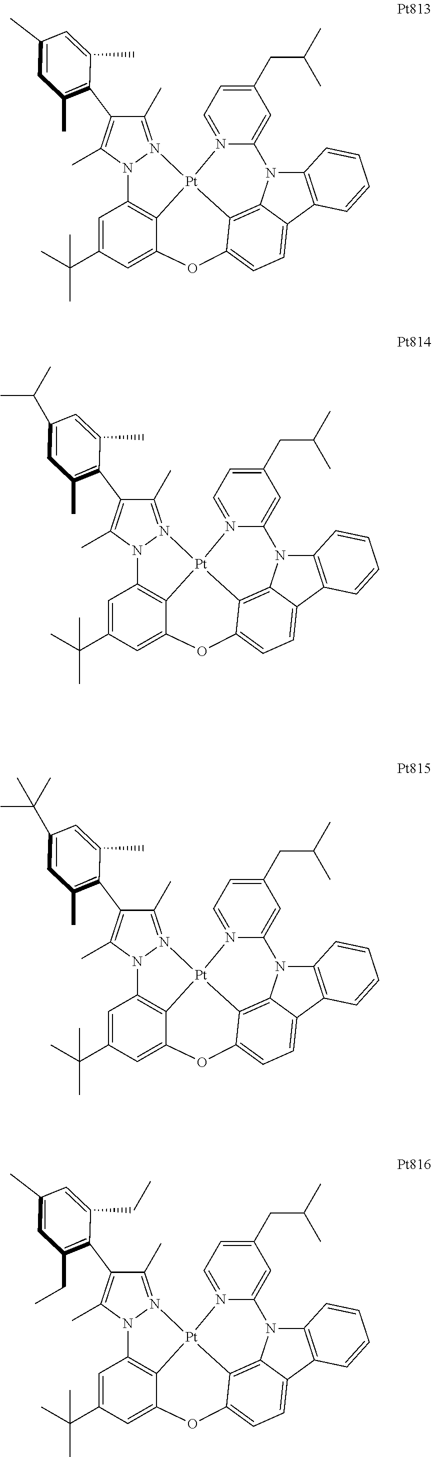

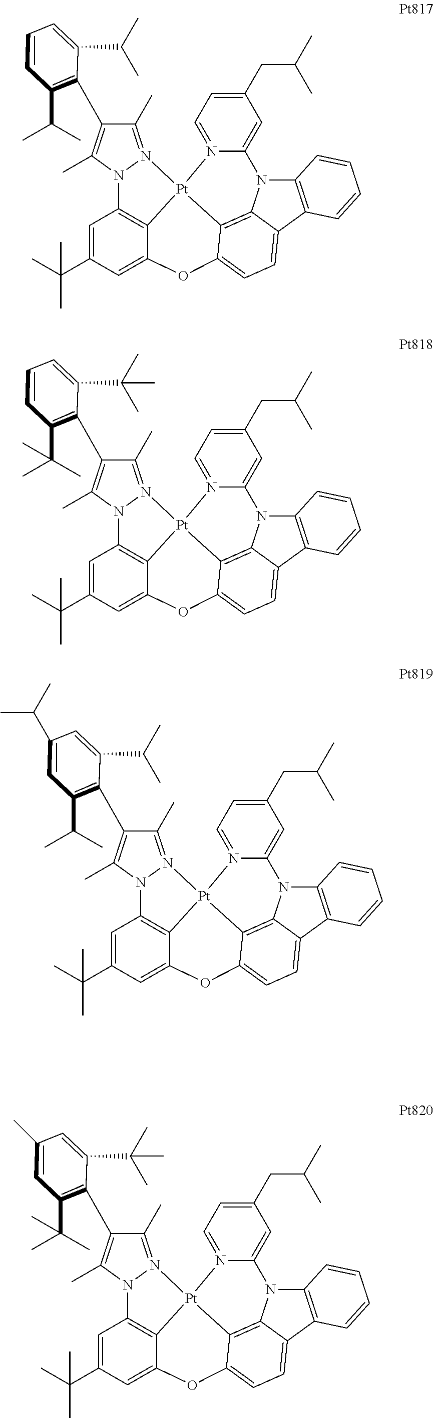

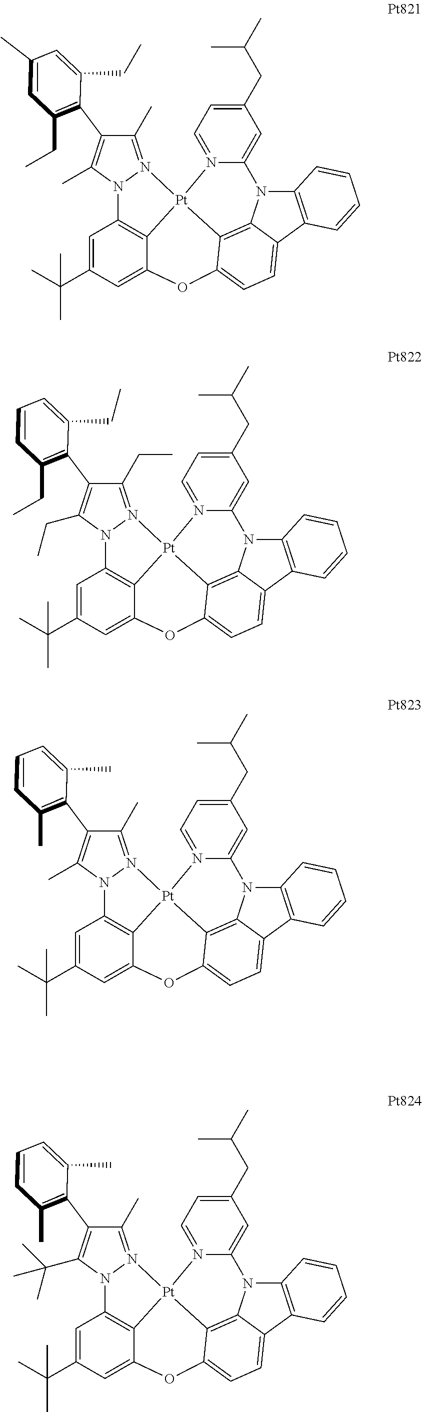

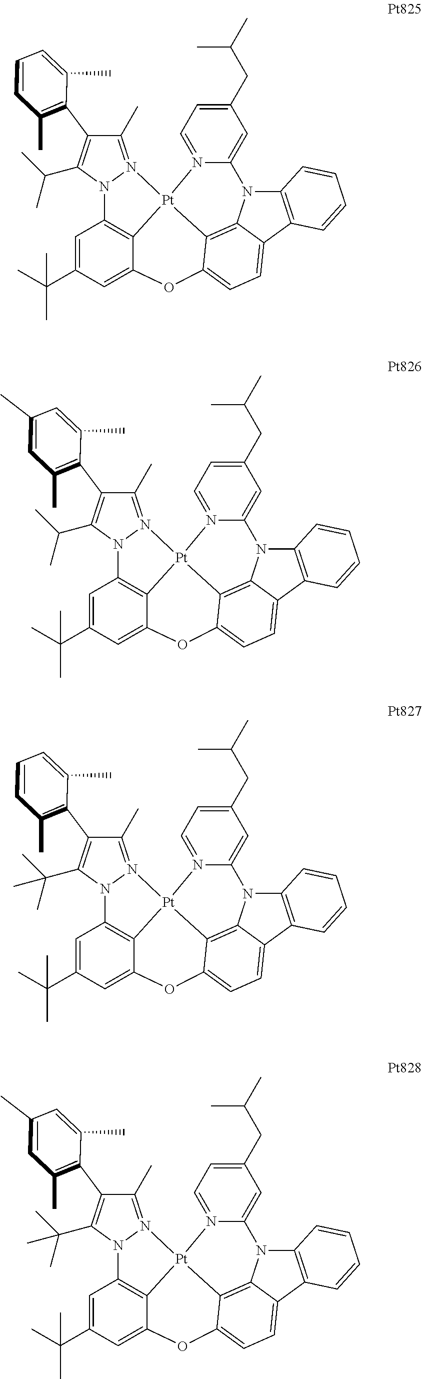

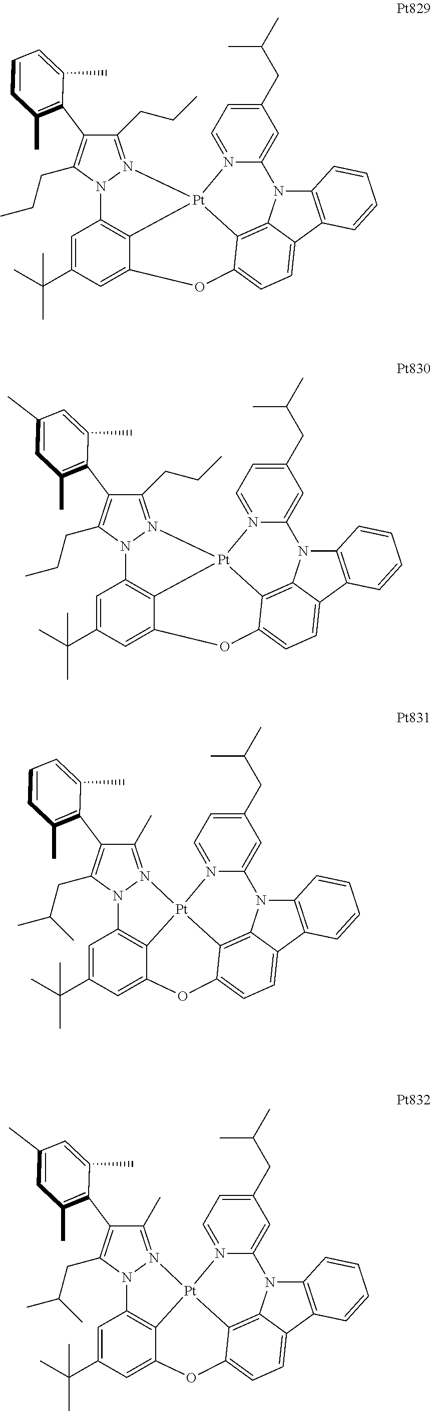

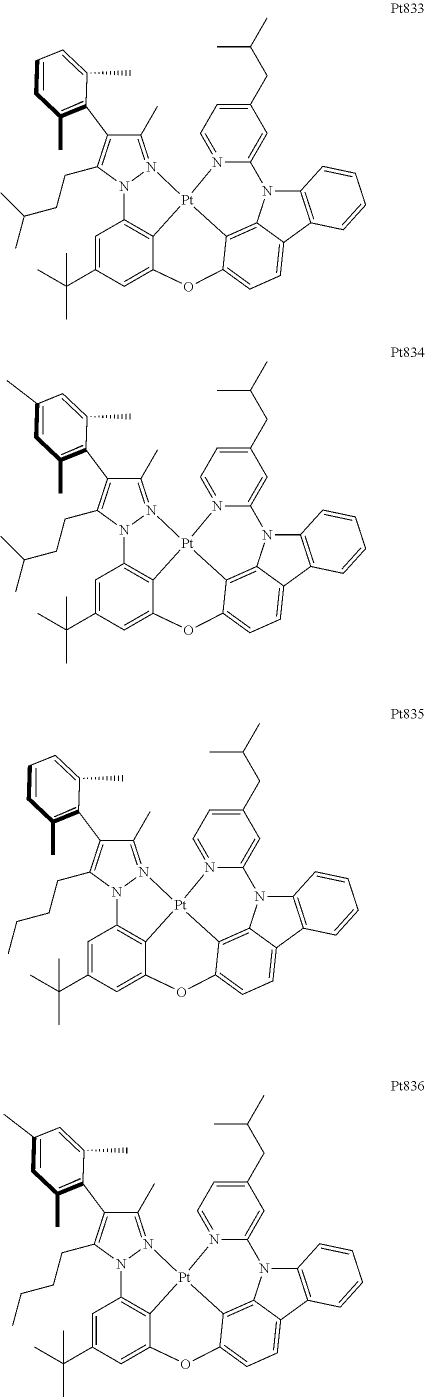

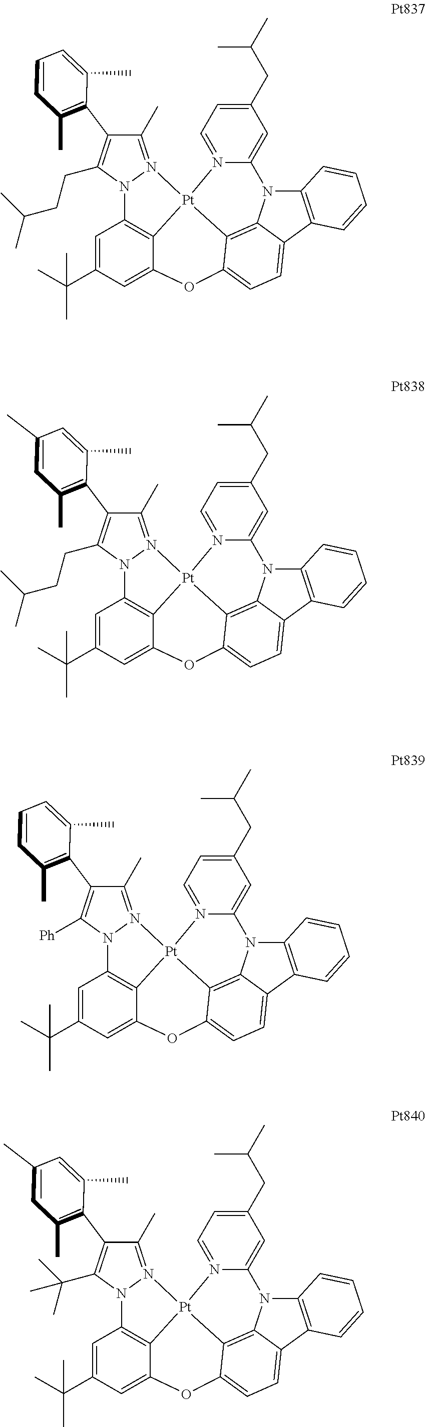

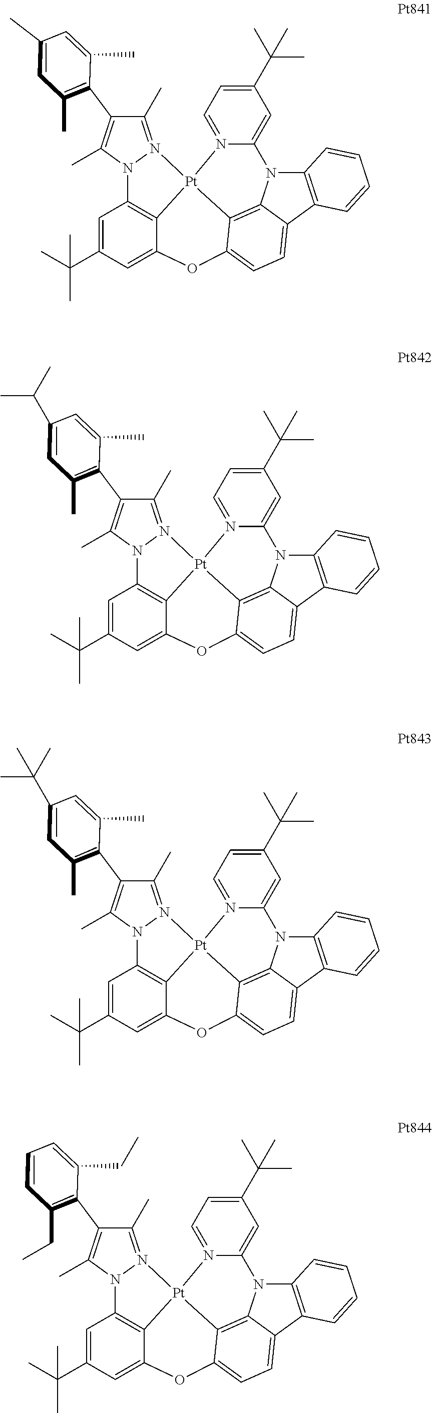

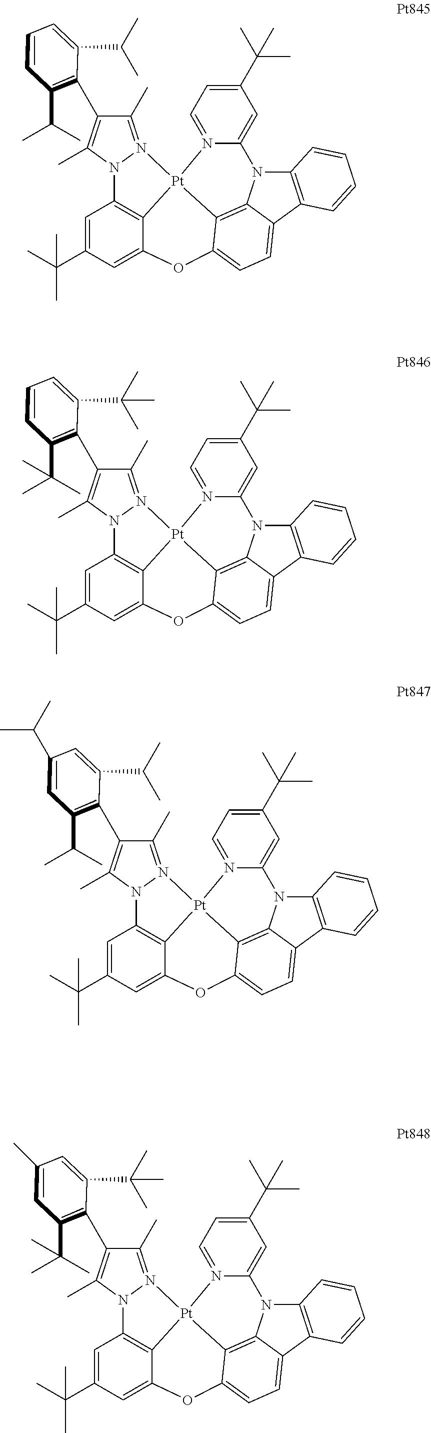

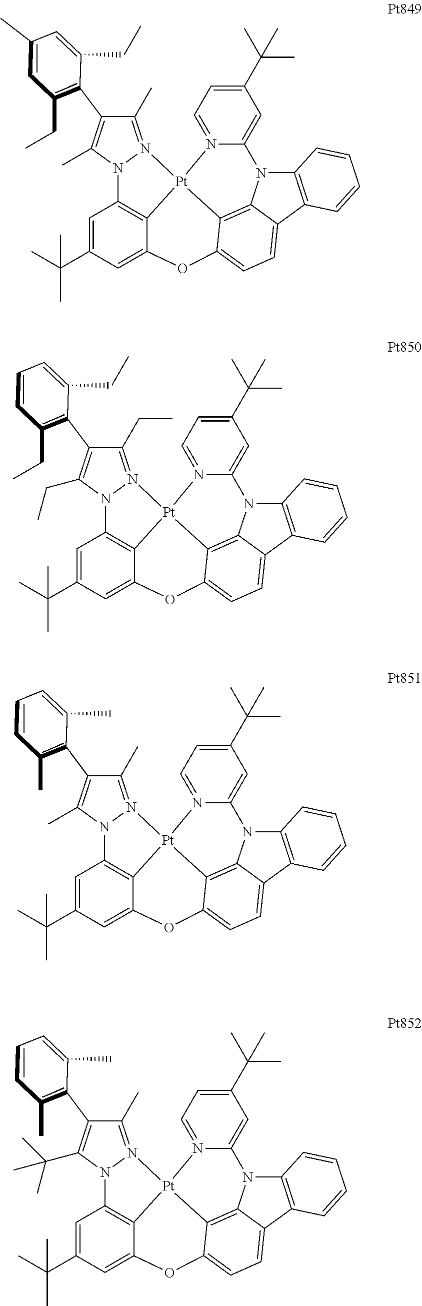

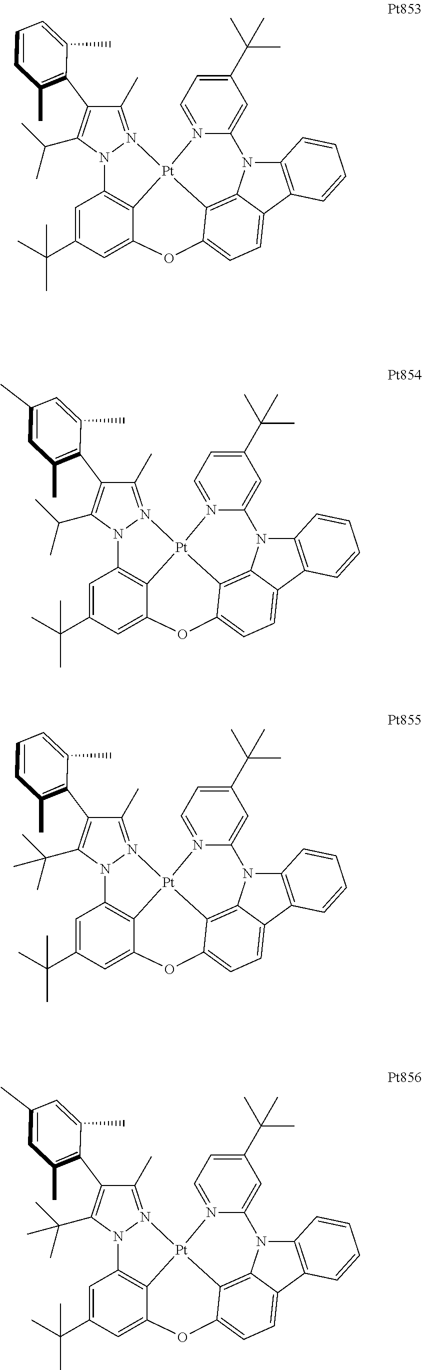

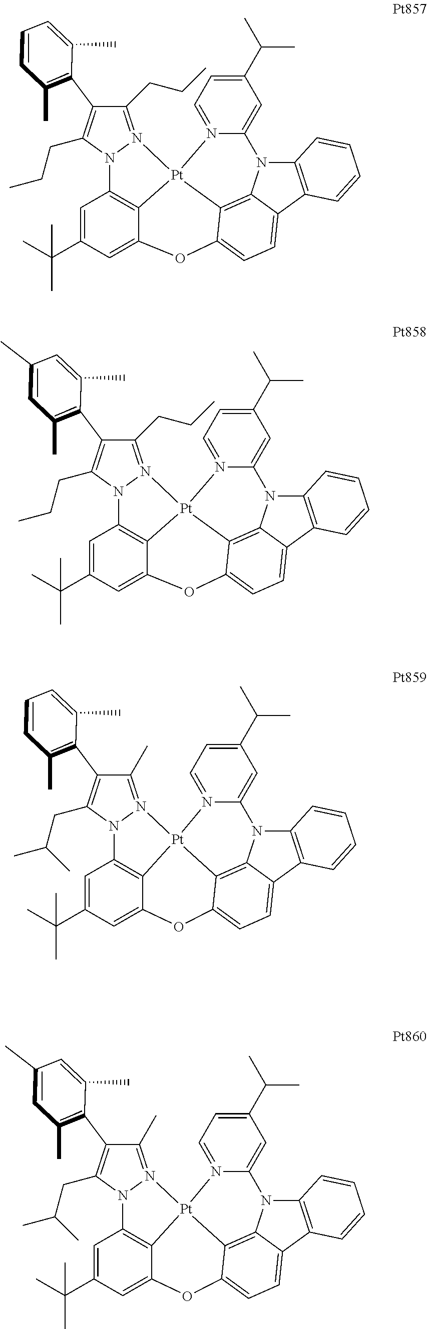

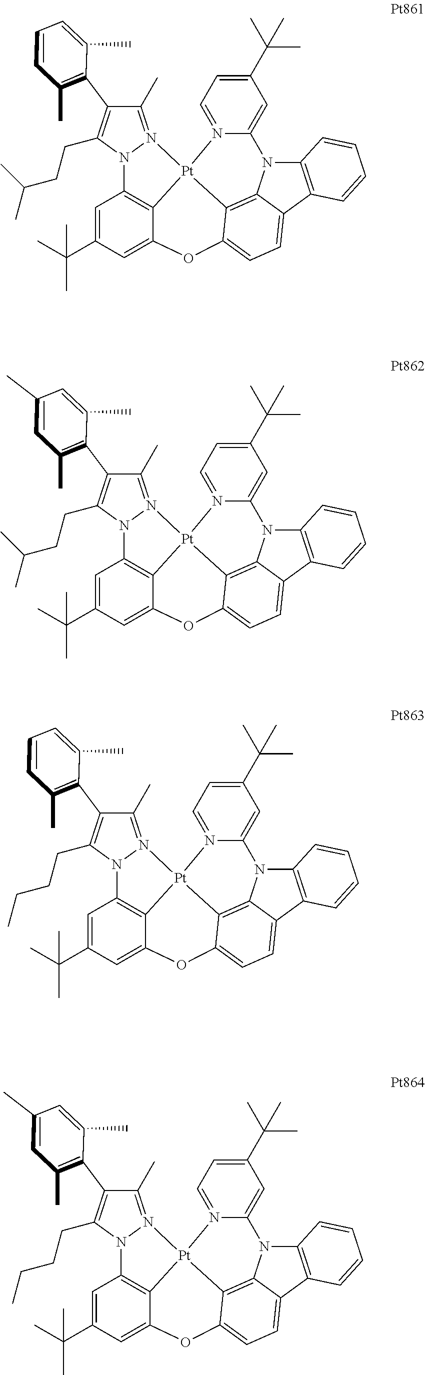

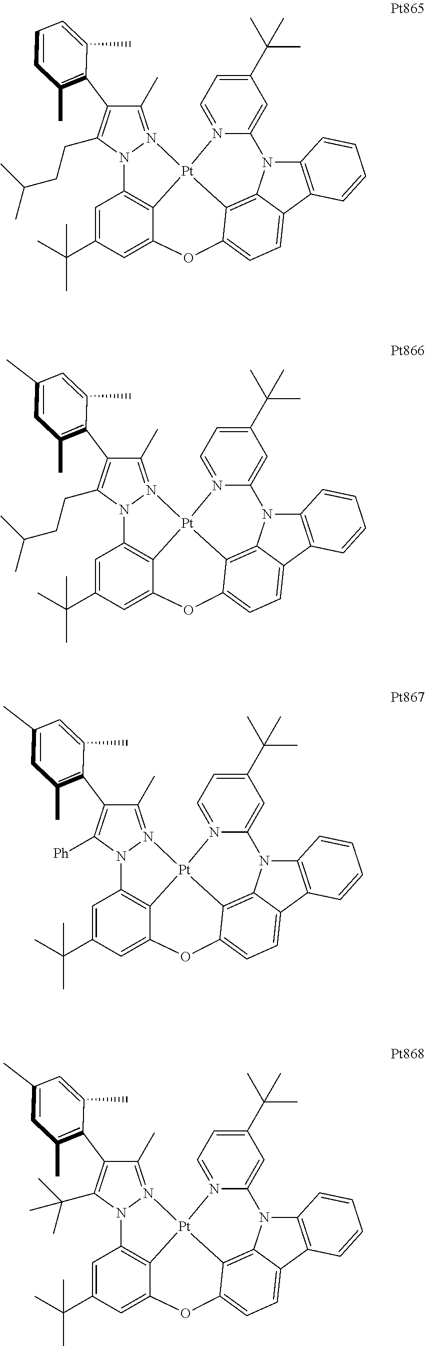

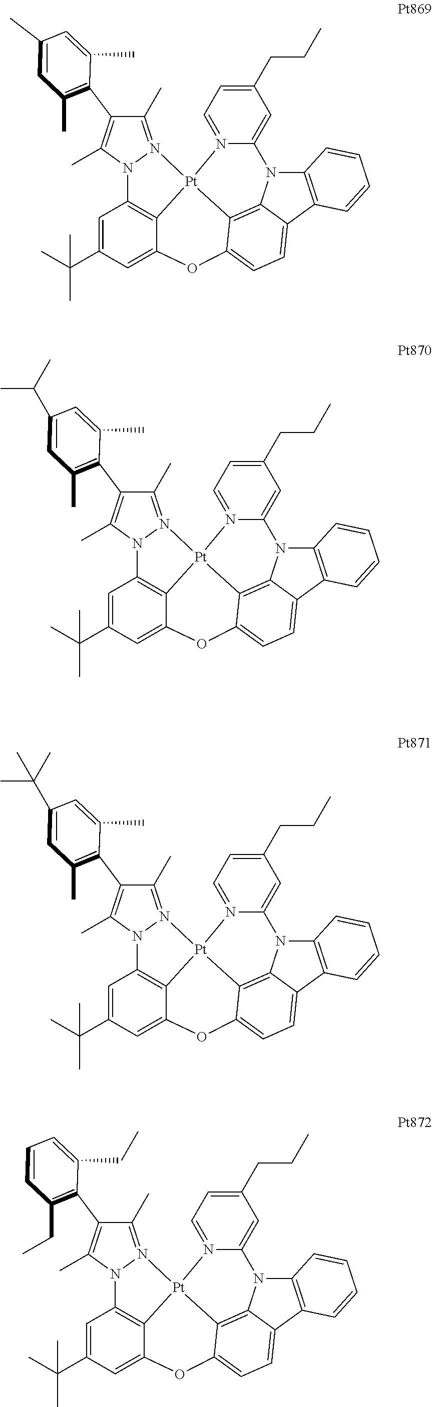

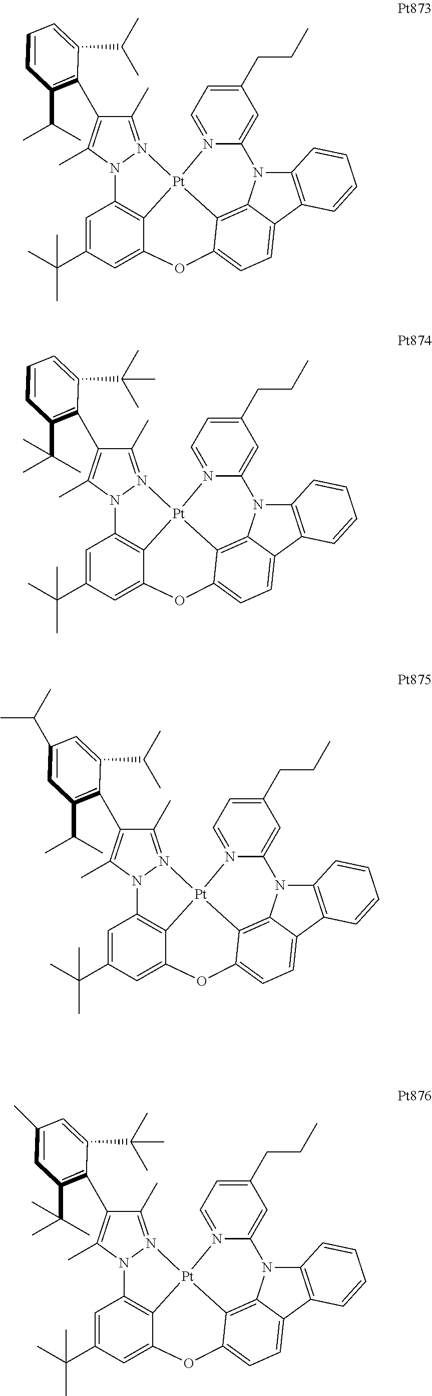

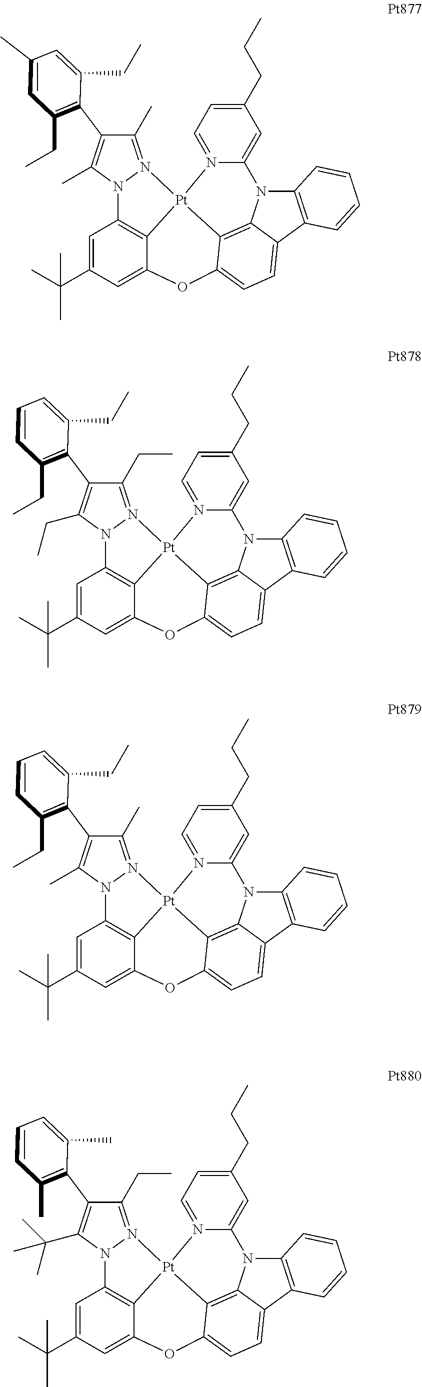

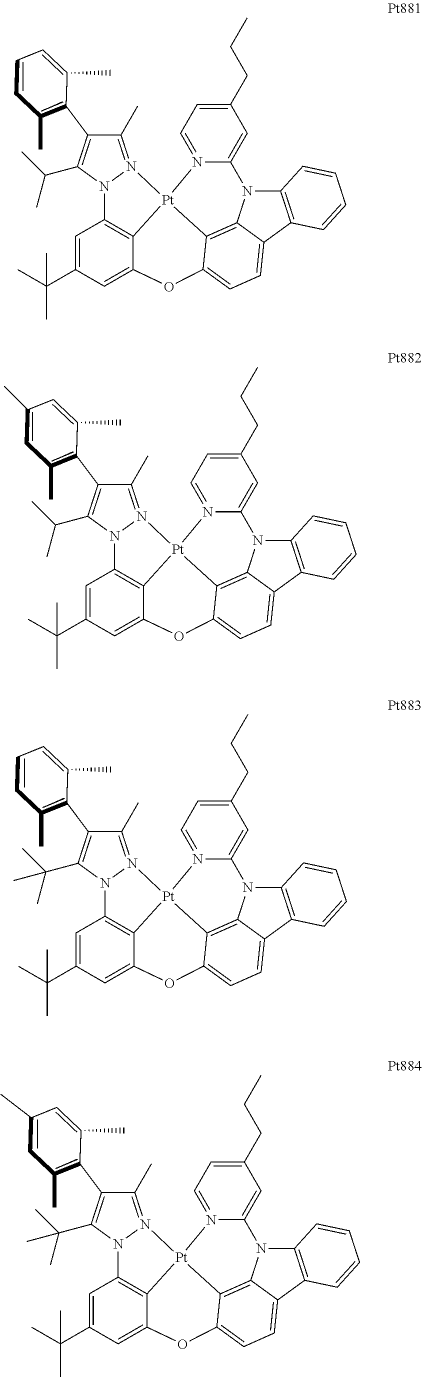

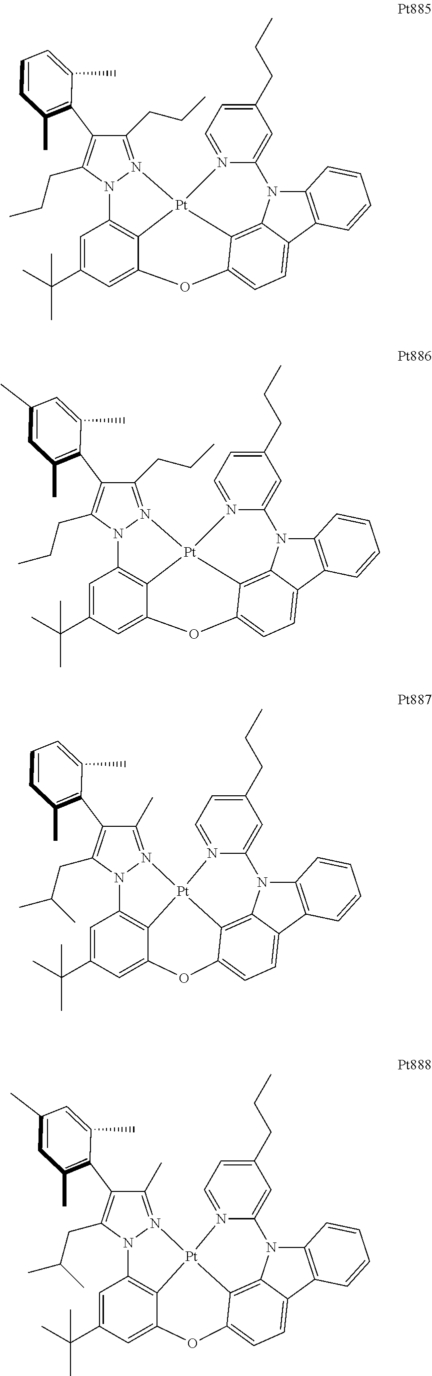

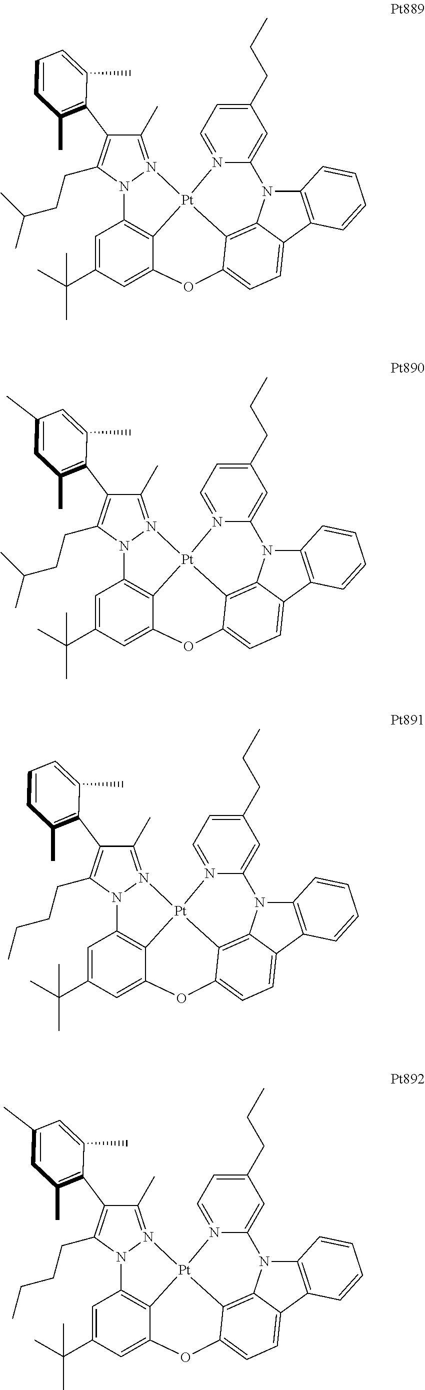

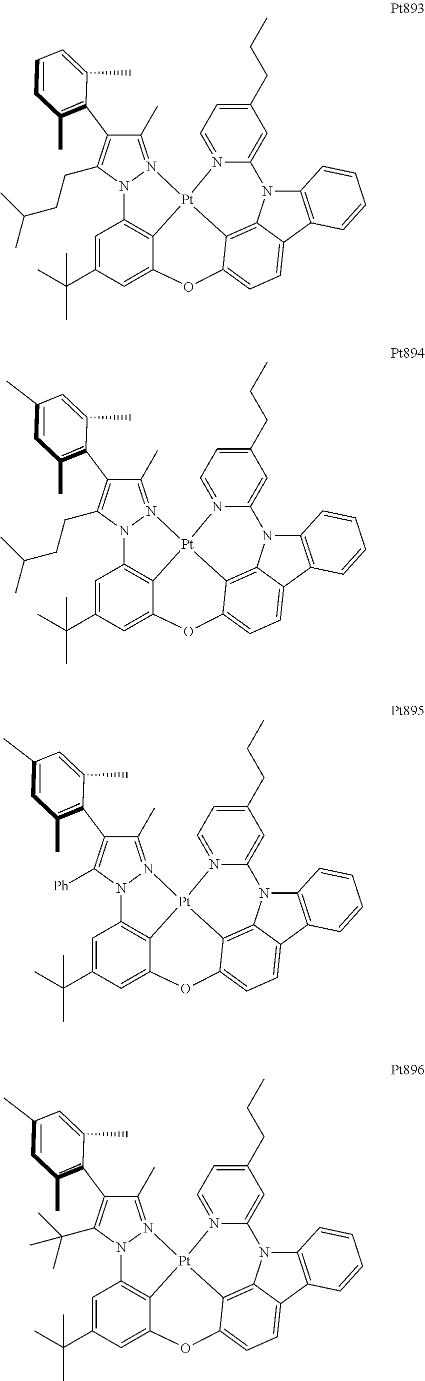

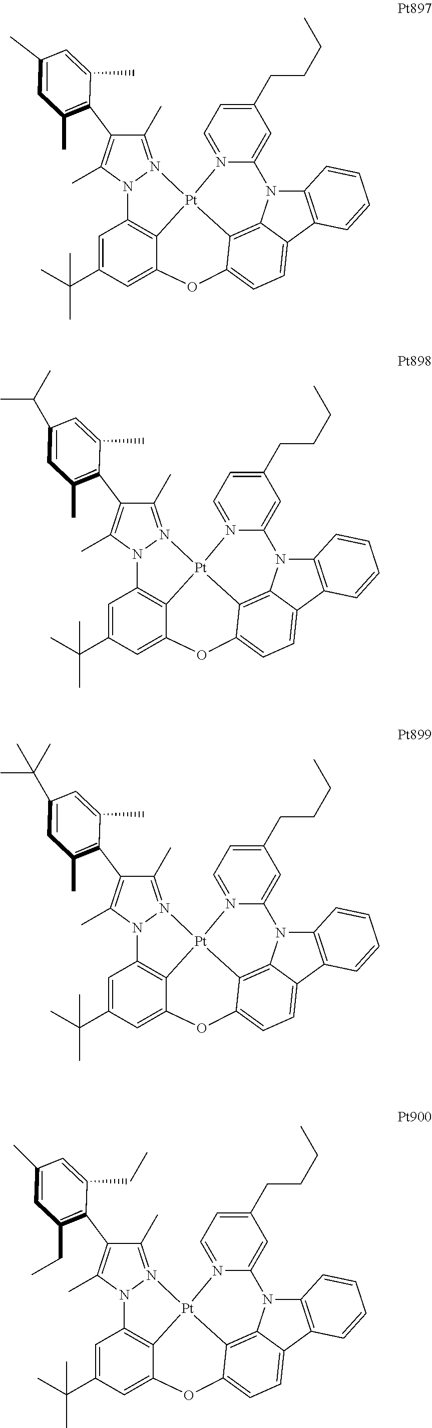

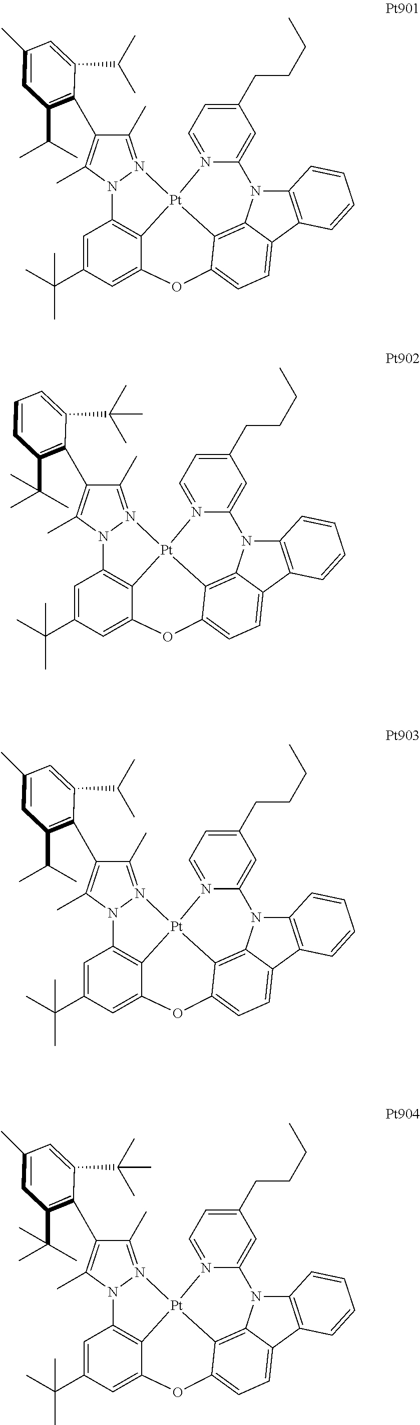

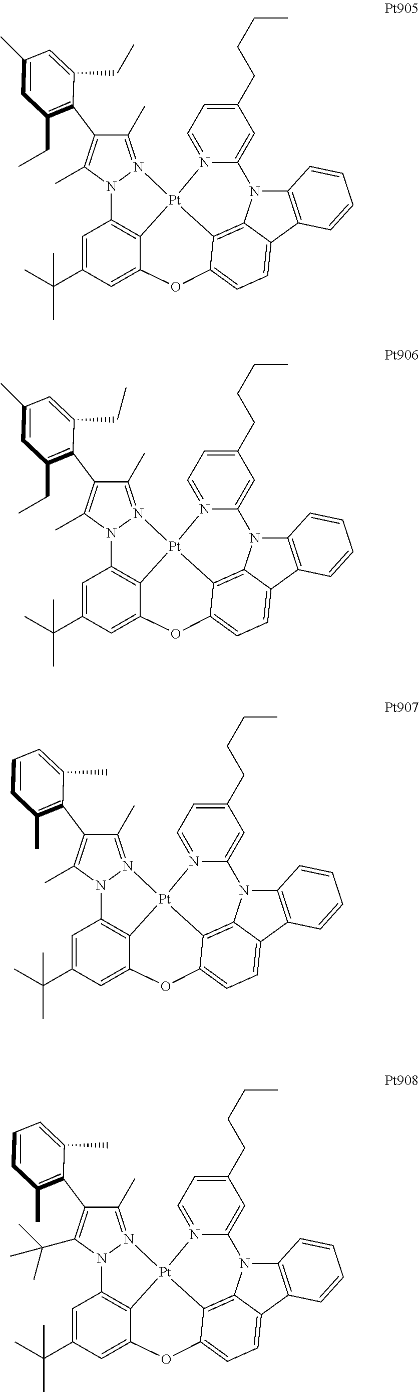

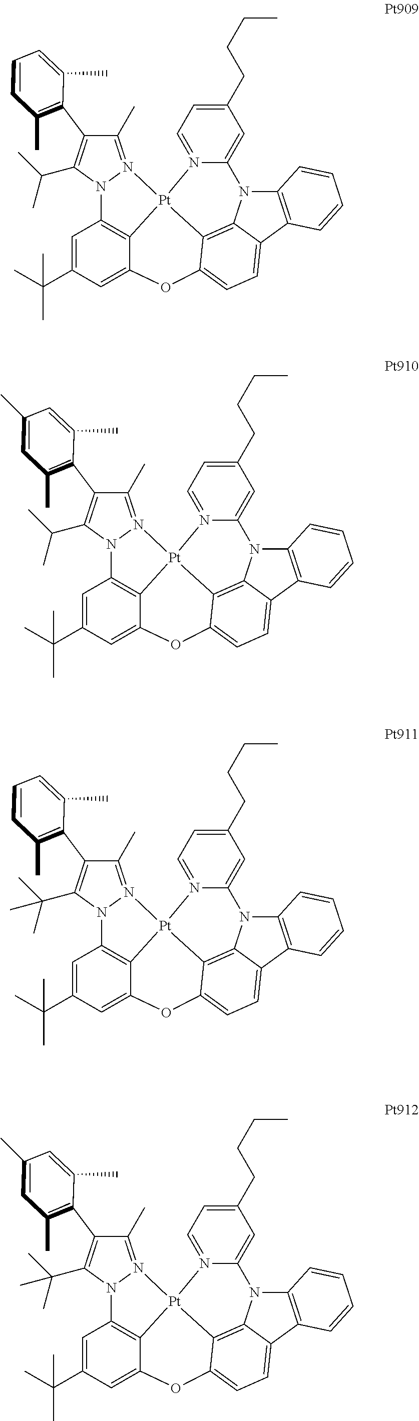

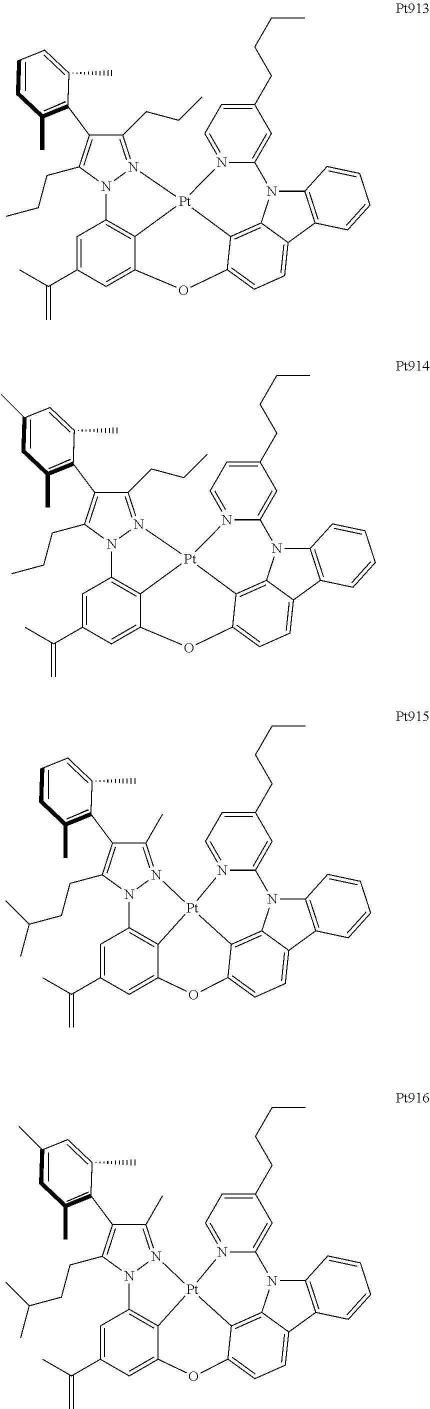

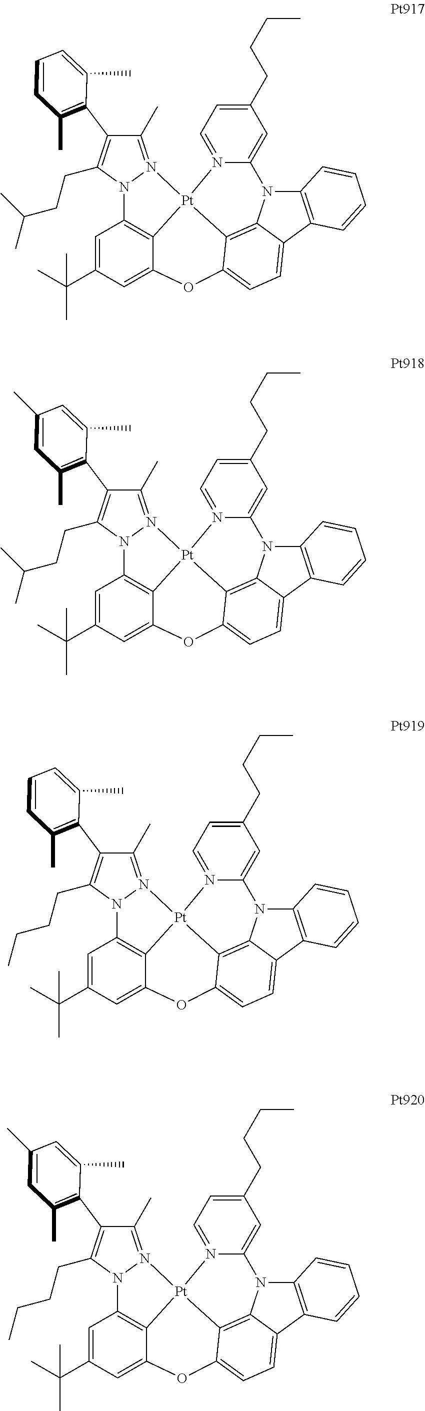

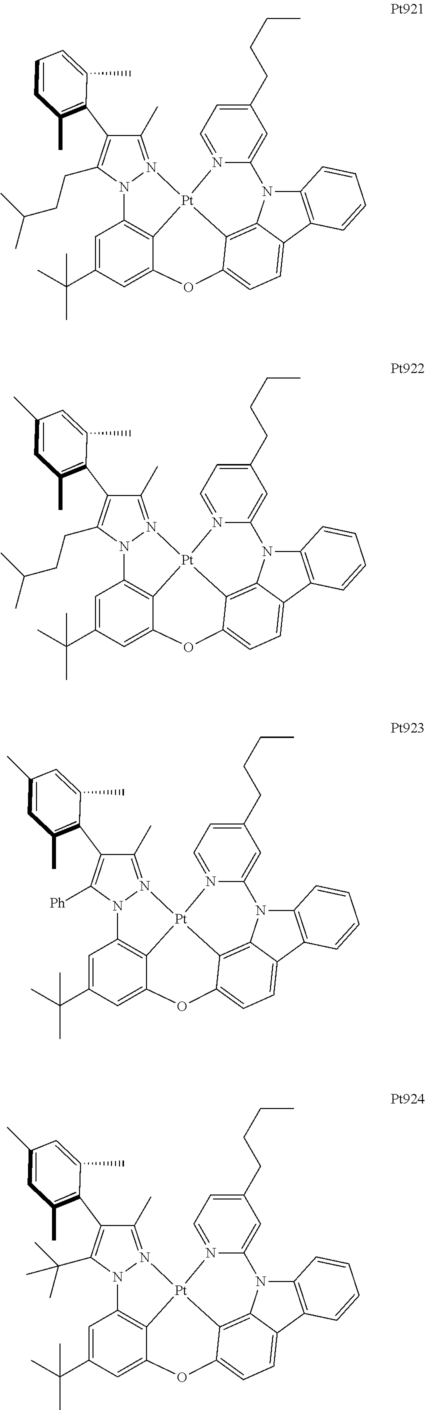

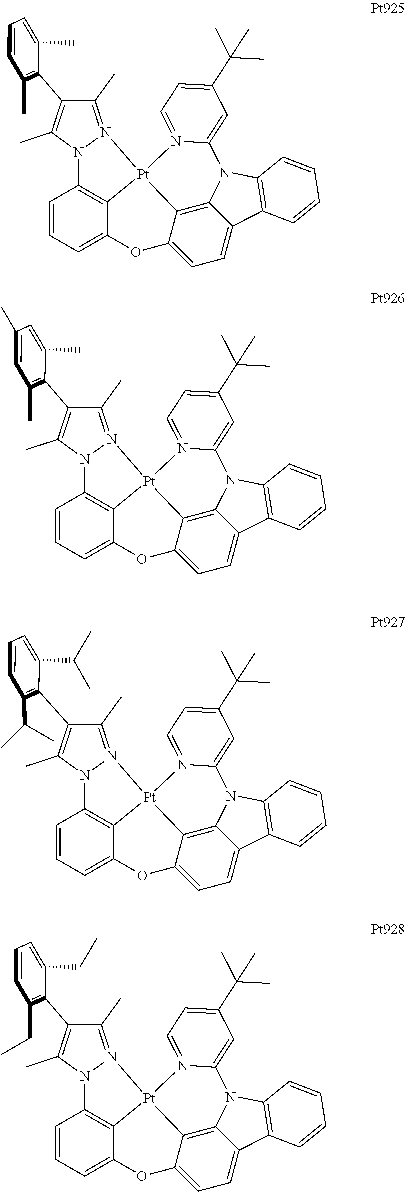

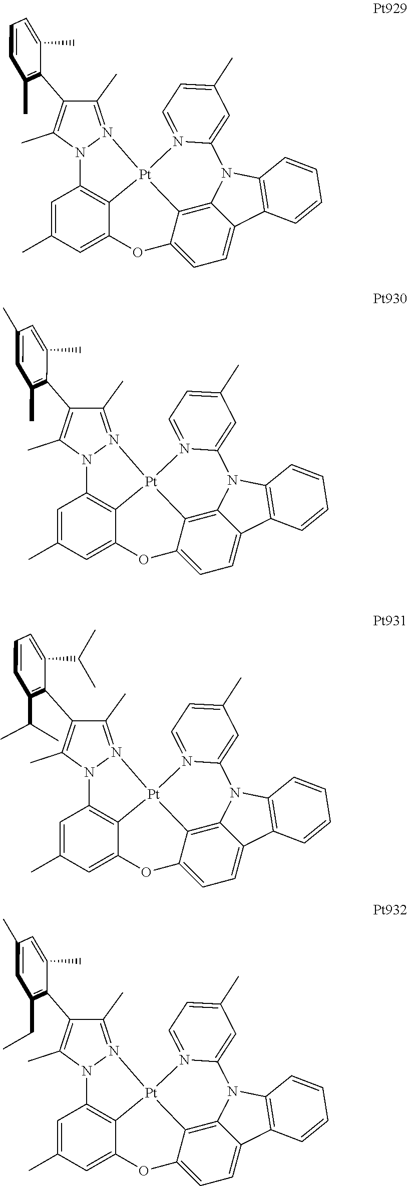

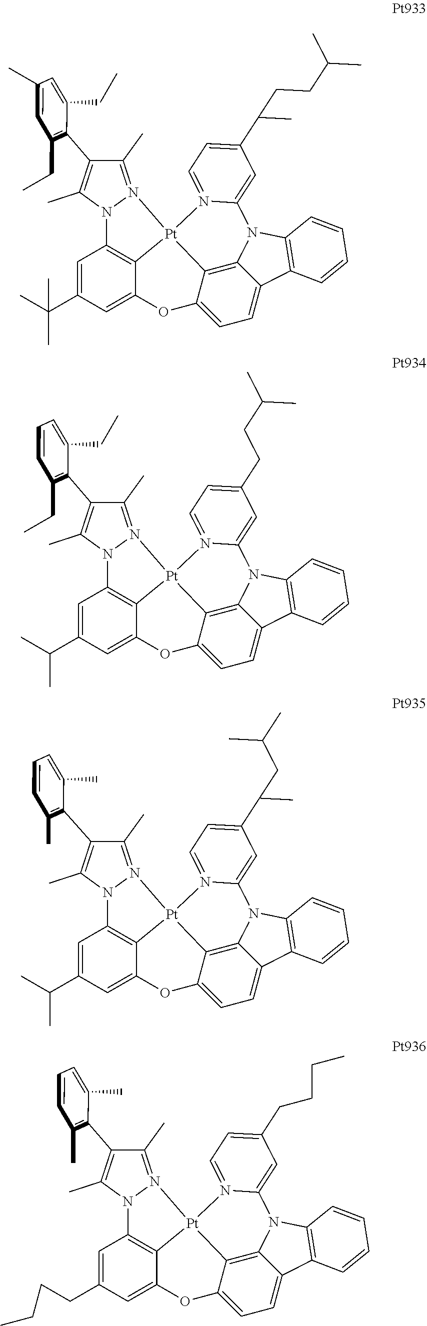

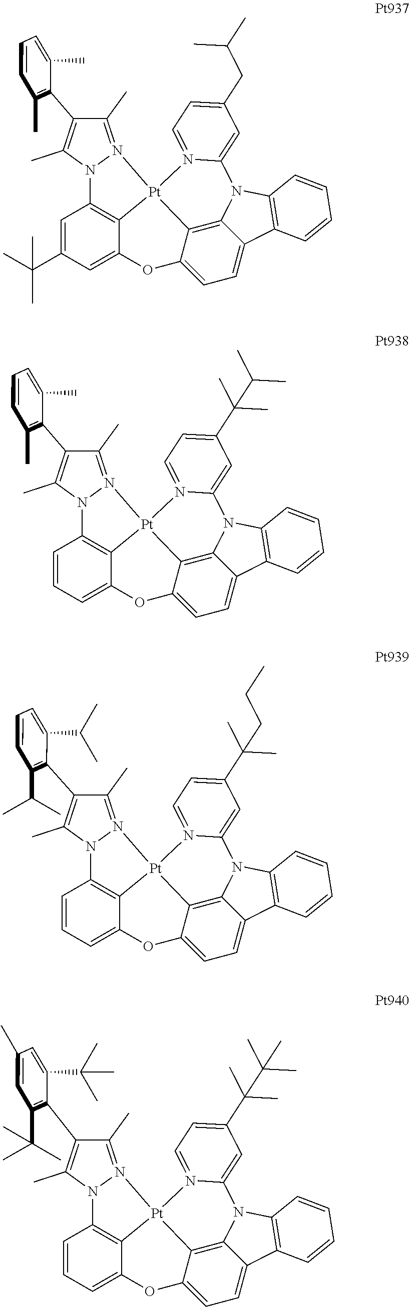

In some specific embodiments of the present invention, the tetradentate ring metal platinum complex containing 4-aryl-3, 5-disubstituted pyrazole is electrically neutral.

In some specific embodiments of the present invention, an optical or electro-optical device is also provided, which contains one or more kinds of the above mentioned tetradentate ring metal platinum complex containing 4-aryl-3, 5-disubstituted pyrazole.

In some specific embodiments of the present invention, the optical or electro-optical device provided includes an optical absorption device (such as a solar device or photosensitive device), organic light-emitting diode (OLED), an optical emitting device or a device capable of being compatible with optical absorption and emission.

In some specific embodiments of the present invention, the optical or electro-optical device provided by the tetradentate ring metal platinum complex containing 4-aryl-3, 5-disubstituted pyrazole in the embodiments of the present invention has an internal quantum efficiency of 100%.

In some embodiments of the present invention, an OLED device is also provided, the luminescent material or host material of the OLED device contains one or more kinds of the above mentioned tetradentate ring metal platinum complex containing 4-aryl-3, 5-disubstituted pyrazole. The complex provided by the embodiment of the invention can be both used as host material of OLED devices, for example, used in full-color display, etc; and be applied to luminescent material of OLED devices, such as a light emitting devices and displays.

Preparation and Performance Evaluation Embodiments

Embodiments are presented below to provide one of ordinary skill in the art with the completely disclosed contents and description of how to manufacture and evaluate compounds, complexes, products, devices and/or methods described in the present invention. And the mentioned embodiments are intended only to be a demonstration of the contents of this disclosure and not to delineate limit range. Although efforts have been made to ensure the accuracy of values (for example, quantities, temperatures, etc.). However, some errors and deviations should be taken into account. Unless otherwise stated, the number of copies is in weight, the temperature is in ° C. or at ambient temperature, and the pressure is at or near atmospheric pressure.

In embodiments, a variety of methods for the preparation of the disclosed compound are described in the present invention. These methods are provided to illustrate the plurality of preparation methods. But the contents of this disclosure are not intended to be limited to any of the methods described in the present invention. Therefore, the technical staff of the field to which the disclosure belongs can easily modify the described method or prepare one or more kinds of the disclosed compounds with different methods. The following aspects are merely exemplary, and are not intended to limit the scope of this disclosure. The temperature, catalyst agent, thickness, reactant composition and other technology conditions may be changed, and for the desired complexes, the technical staff in the field of the content of the disclosure may easily choose the appropriate reactants and conditions.

In CDCl₃ or DMSO-d₆ solution on Varian Liquid State NMR instrument, ¹H mapping is recorded with 400 MHz, ¹³C NMR mapping is recorded with 100 MHz, chemical shift refers to residual protiated solvent. If CDCl₃ is used as solvent, then tetramethylsilane (δ=0.00 ppm) is used as internal standard to record ¹³C NMR mapping. If H₂O (δ=3.33 ppm) is used solvent, then residual H2O (δ=3.33 ppm) is used as internal standard to record ¹H NMR mapping, DMSO-d6 (δ=39.52 ppm) is used as as internal standard to record ¹³C NMR mapping. The following abbreviations (or combinations) are used to explain the multiplicity of ¹H NMR: s=single, d=dual, t=triple, q=quadruple, P=five times, m=multiple, br=wide.

General Synthesis Route

The general synthesis route of the compound disclosed in the invention patent is as follows:

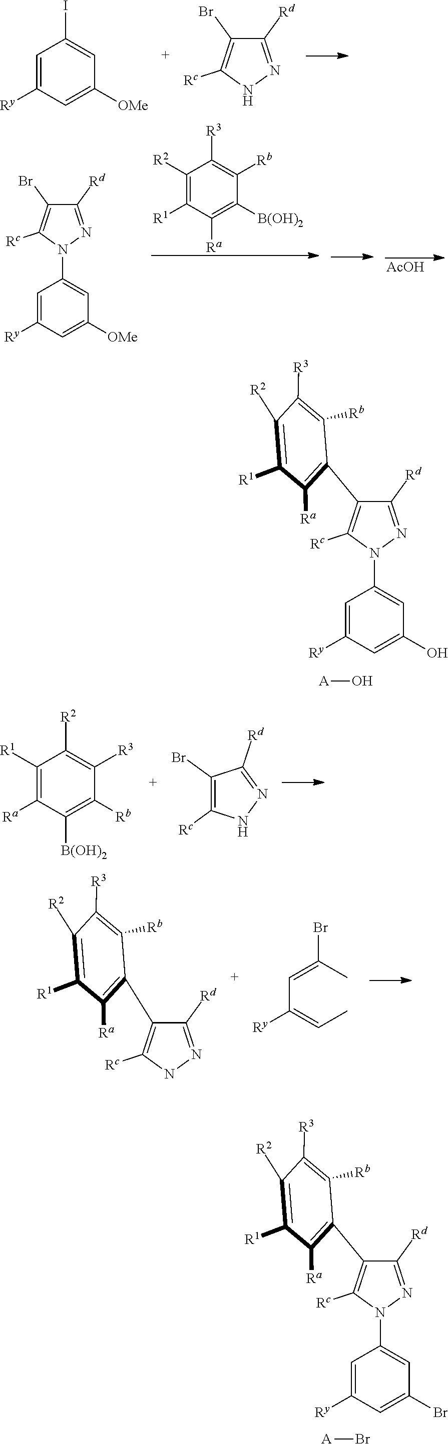

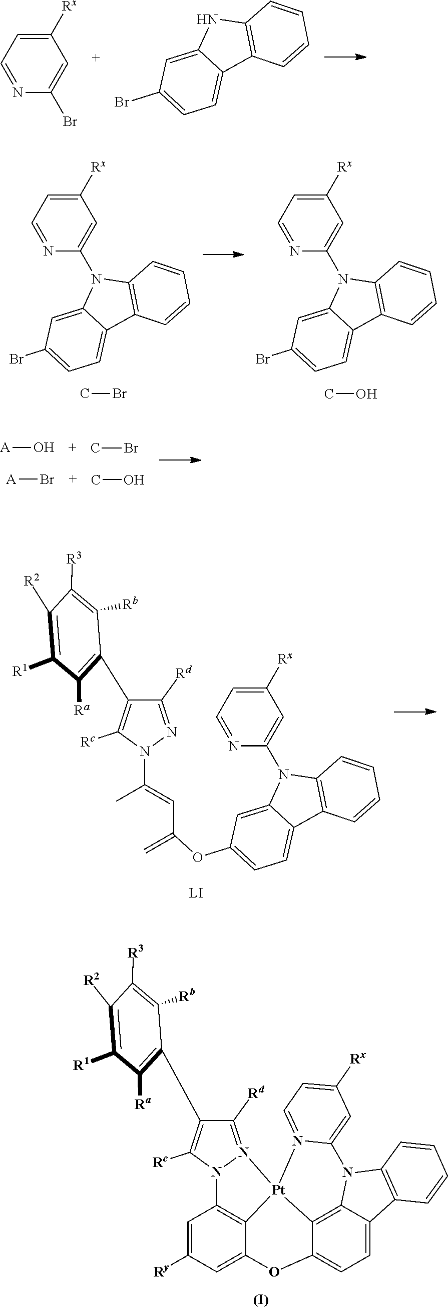

### PREPARATION EMBODIMENTS

### Embodiment 1: Compound Pt1 May be Synthesized in Accordance with the Following Route

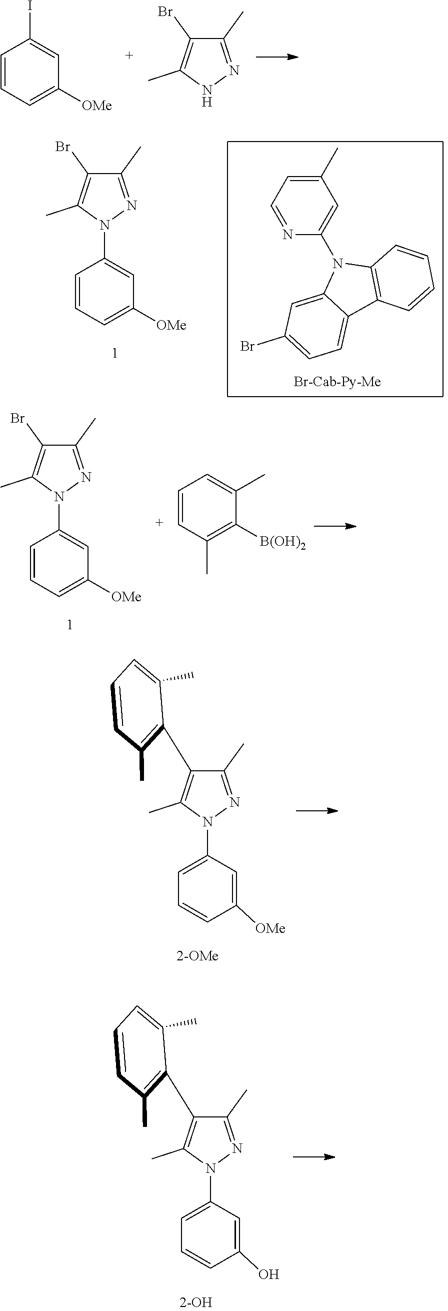

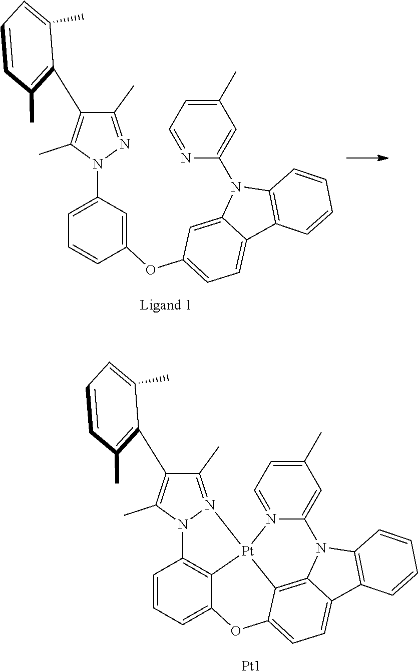

The Synthesis of Intermediate Compound 1:

Add, in turn, 3,5-dimethyl-4-bromopyrazole (5250 mg 30.00 mmol, 1.00 equivalent), iodide copper (572 mg, 3.00 mmol, 0.10 equivalent), L-proline (690 mg, 6.00 mmol, 0.20 equivalent) and potassii (8280 mg, 60.00 mmol, 2.00 equivalent) to a dry three-mouth bottle with reflux condensing tube and magnetic rotor, carry out nitrogen exchange three times, then add between iodoanisole (10,500 mg, 45.00 mmol/L, 1.50 equivalent) and resteamed dimethyl sulfoxide (10 mL). The reaction mixture is agitated at 120° C. for 2 days, which is monitored by TLC thin-layer chromatography until the end of 4-bromopyrazole reaction. The reaction is then quenched by adding water (100 ml), then filter, the insoluble substance is washed by 50 ml of ethyl acetate, the organic phase is then separated from the mother liquor, the anhydrous sodium sulfate is dried and filtered, then reduce pressure and distill to remove the solvent. The crude product is separated and purified by silica gel column chromatography and eluent (petroleum ether/ethyl acetate=20:1-10:1), obtaining 8350 mg of compound 1, a colorless viscous liquid, the yield is 99%.

¹H NMR (500 MHz, DMSO-d₆): δ 2.20 (s, 3H), 2.30 (s, 3H), 3.81 (s, 3H), 7.01 (ddd, J=8.1, 2.4, 0.6 Hz, 1H), 7.05-7.08 (m, 2H), 7.42 (t, J=8.1 Hz, 1H).

The Synthesis of Intermediate 2-OMe:

Add, in turn, 4-bromine-1-(3-anisole)-3,5-dimethyl-1 hydrogen-pyrazol 1 (2100 mg, 7.47 mmol, 1.00 equivalent), 2,6-dimethylphenylo boric acid (2240 mg, 14.94 mmol, 2.00 equivalent), Pd₂(dba)₃ (137 mg, 0.15 mmol, 0.02 equivalent), tripotassium phosphate (4760 mg, 22.41 mol, 3.00 equivalent), S-Phos (245 mg, 0.60 mmol, 0.08 equivalent) to a dry three-mouth flask with magnetic rotor, carry out nitrogen exchange three times, then add methylbenzene (40 mL). After that, bubbling nitrogen for 20 minutes and the reaction mixture is placed at 110° C. and agitated to react for 3 days. Cool down, add 100 mL water, extract with ethyl acetate (50 ml×3), merge organic phase, anhydrous sodium sulfate is then dried and filtered, then reduce pressure and distill to remove the solvent. The crude product is separated and purified by silica gel column chromatography and eluent (petroleum ether/ethyl acetate=20:1-15:1), obtaining 1200 mg of compound 2-OMe, an orange viscous liquid, the yield is 54%.

¹H NMR (500 MHz, DMSO-d₆): δ 1.94 (s, 3H), 2.02 (s, 6H), 2.05 (s, 3H), 3.83 (s, 3H), 6.96 (d, J=8.3 Hz, 1H), 7.14-7.18 (m, 5H), 7.42 (t, J=8.0 Hz, 1H).

The Synthesis of Intermediate 2-OH:

Dissolve 4-(2,6-dimethyl benzene)-1-(3-anisole)-3,5-dimethyl-1 hydrogen-pyrazol 2-OMe (600 mg, 1.95 mmol, 1.00 equivalent) in 25 ml acetic acid, add hydrobromic acid (consistence 48%˜10 mL), then the reaction mixture is placed at 120° C. and agitated to react for 12 hours. Cool down, spin out acetic acid, add a small amount of water, then add sodium carbonate solution, titrate it so that no more bubbles appear, use ethyl acetate to extract the water phase (20 ml×2), and combine the organic phase, the anhydrous sodium sulfate is dried and filtered, then reduce pressure and distill to remove the solvent. The crude product is separated and purified by silica gel column chromatography and eluent (petroleum ether/ethyl acetate=5:1-3:1), obtaining 6511 mg of compound 2-OH, a brown solid, the yield is 99%.

¹H NMR (500 MHz, DMSO-d₆): δ 1.93 (s, 3H), 2.01 (s, 6H), 2.03 (s, 3H), 6.78 (ddd, J=7.8, 2.6, 0.6 Hz, 1H), 6.97-7.00 (m, 2H), 7.14-7.20 (m, 3H), 7.29 (t, J=8.0 Hz, 1H), 9.75 (s, 1H).

The Synthesis of Ligand Ligand 1:

Add, in turn, phenol derivative 2-OH (500 mg, 1.71 mmol, 1.00 equivalent), 2-bromine-9-(4-picoline-2-)-9H-carbazole Br-Cab-Py-Me (691 mg, 2.05 mmol, 1.20 equivalent, synthesis method referring to The Journal of Organic Chemistry, 2017, 82, 1024-1033), iodide copper (65 mg, 0.34 mmol, 0.20 equivalent), 2-picolinic acid (84 mg, 0.68 mmol, 0.40 equivalent), potassium orthophosphate (762 mg, 3.59 mmol, 2.10 equivalent) to a dry three-mouth flask with magnetic rotor, carry out nitrogen exchange three times, then add DMSO (5 mL). The reaction mixture is agitated at 105° C. to react for 24 hours, which is monitored by TLC thin-layer chromatography. Cool down, add acetic ether (40 mL) and water (40 mL) to dilute, separate solution, separate organic phase, anhydrous sodium sulfate is then extracted with acetic ether (20 mL×2), then reduce pressure and distill to remove the solvent. The crude product is separated and purified by silica gel column chromatography and eluent (petroleum ether/ethyl acetate=15:1-10:1), obtaining 800 mg of ligand Ligand 1, an white solid, the yield is 76%.

¹H NMR (500 MHz, DMSO-d₆): δ 1.89 (s, 3H), 1.98 (s, 6H), 2.02 (s, 3H), 2.45 (s, 3H), 7.06-7.08 (m, 1H), 7.12-7.19 (m, 4H), 7.26 (t, J=2.2 Hz, 1H), 7.30 (d, J=5.0 Hz, 1H), 7.33-7.37 (m, 2H), 7.44-7.47 (m, 1H), 7.50-7.53 (m, 2H), 7.61 (s, 1H), 7.77 (d, J=8.3 Hz, 1H), 8.23 (d, J=7.6 Hz, 1H), 8.29 (d, J=8.4 Hz, 1H), 8.53 (d, J=5.0 Hz, 1H).

The Synthesis of Metal Complex Luminescent Material Pt1:

Add, in turn, ligand Ligand 1 (1500 mg, 2.73 mmol, 1.00 equivalent), potassium tetrachloroplatinate (1250 mg, 3.00 mmol, 1.10 equivalent) and tetrabutylammonium bromide (87 mg, 0.27 mmol, 0.10 equivalent) to a dry three-mouth flask with magnetic rotor. Carry out nitrogen exchange three times, then add solvent acetic acid DMSO (140 mL). Bubbling nitrogen for 20 minutes, the reaction mixture is agitated at room temperature for 12 hours and then agitated at 110° C. for 3 days. Cool the reaction mixture down to room temperature, then reduce pressure and distill to remove the solvent. The crude product is separated and purified by silica gel column chromatography and eluent (petroleum ether/dichloromethane=3:1-2:1), obtaining 1300 mg yellow-green solid, the yield is 64%.

¹H NMR (500 MHz, DMSO-d₆): δ 2.09 (s, 6H), 2.16 (s, 3H), 2.40 (s, 3H), 2.46 (s, 3H), 6.98 (d, J=7.4 Hz, 1H), 7.12-7.28 (m, 6H), 7.34 (d, J=7.4 Hz, 1H), 7.40 (t, J=7.2 Hz, 1H), 7.47-7.50 (m, 1H), 7.86 (d, J=8.3 Hz, 1H), 7.99 (s, 1H), 8.13 (dd, J=14.8, 7.9 Hz, 2H), 9.15 (d, J=6.1 Hz, 1H).

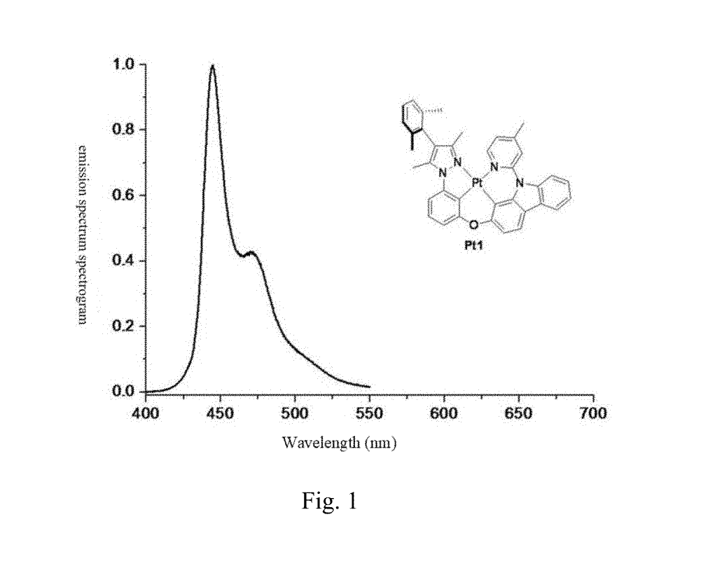

FIG. 1 is an emission spectrum spectrogram of compound Pt1 dichloromethane solution at room temperature, and FIG. 5 is a thermogravimetric analysis (TGA) curve of compound Pt1.

### Embodiment 2: Compound Pt2 May be Synthesized in Accordance with the Following Route

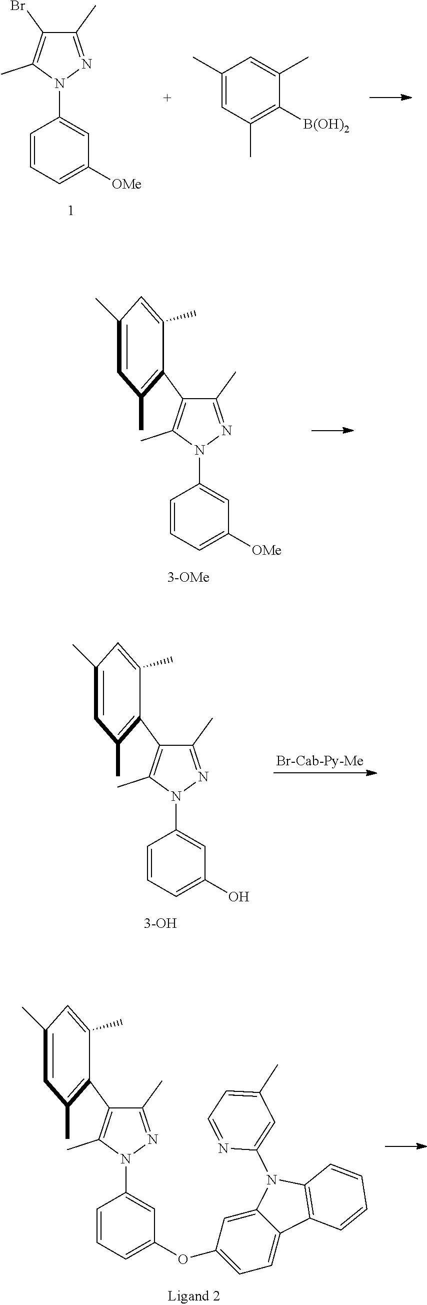

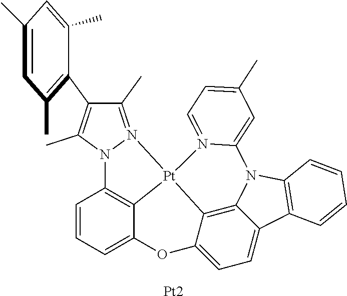

The Synthesis of Intermediate 3-OMe:

Add, in turn, 4-bromine-1-(3-anisole)-3,5-dimethyl-1 hydrogen-pyrazol 1 (4.50 g, 16.01 mmol, 1.00 equivalent), 2,4,6-trimethylphenylo boric acid (5.25 g, 32.02 mmol, 2.00 equivalent), Pd₂(dba)₃ (0.29 g, 0.32 mmol, 0.02 equivalent), tripotassium phosphate (10.20 g, 48.03 mol, 3.00 equivalent), S-Phos (0.53 g, 0.60 mmol, 0.08 equivalent) to a dry three-mouth bottle with magnetic rotor, carry out nitrogen exchange three times, then add methylbenzene (100 mL). After that, bubbling nitrogen for 20 minutes and the reaction mixture is placed at 110° C. and agitated to react for 3 days. Cool down, add water (100 mL), extract with ethyl acetate (50 ml×3), merge organic phase, anhydrous sodium sulfate then dried and filtered, then reduce pressure and distill to remove the solvent. The crude product is separated and purified by silica gel column chromatography and eluent (petroleum ether/ethyl acetate=20:1-15:1), 4.94 g of compound 3-Ome light yellow viscous liquid is obtained, the yield is 97%.

¹H NMR (500 MHz, DMSO-d₆): δ 1.93 (s, 3H), 1.98 (s, 6H), 2.04 (s, 3H), 2.28 (s, 3H), 3.83 (s, 3H), 6.94-6.97 (m, 3H), 7.12-7.15 (m, 2H), 7.41 (t, J=8.1 Hz, 1H).

The Synthesis of Intermediate 3-OH:

Dissolve anisol derivative 3-OMe (600 mg, 1.95 mmol, 1.00 equivalent) in 25 mL acetic acid, add hydrobromic acid (consistence 48%, 10.0 mL), then the reaction mixture is placed at 120° C. and agitated to react for 12 hours. Cool down, spin out acetic acid, add a small amount of water, then add sodium carbonate solution, titrate it so that no more bubbles appear, use ethyl acetate to extract the water phase (20 mL×2), and combine the organic phase, the anhydrous sodium sulfate is dried and filtered, then reduce pressure and distill to remove the solvent. The crude product is separated and purified by silica gel column chromatography and eluent (petroleum ether/ethyl acetate=5:1-3:1), obtaining 511 mg of compound 3-OH, a brown solid, the yield is 90%.

¹H NMR (500 MHz, DMSO-d₆): δ 1.92 (s, 3H), 1.97 (s, 6H), 2.02 (s, 3H), 2.28 (s, 3H), 6.77 (ddd, J=8.2, 2.2, 0.8 Hz, 1H), 6.96-6.99 (m, 4H), 7.28 (t, J=8.0 Hz, 1H), 9.74 (s, 1H).

The Synthesis of Ligand Ligand 2:

Add, in turn, phenol derivative 3-OH (1000 mg, 3.42 mmol, 1.00 equivalent), 2-bromine-9-(4-picoline-2-)-9H-carbazole Br-Cab-Py-Me (1382 mg, 4.10 mmol, 1.20 equivalent, synthesis method referring to The Journal of Organic Chemistry, 2017, 82, 1024-1033), iodide copper (65 mg, 0.34 mmol, 0.10 equivalent), 2-picolinic acid (84 mg, 0.68 mmol, 0.20 equivalent), potassium orthophosphate (1524 mg, 7.18 mmol, 2.10 equivalent) to a dry three-mouth bottle with magnetic rotor, carry out nitrogen exchange three times, then add 8 mL DMSO. The reaction mixture is agitated at 120° C. to react for 3 days, which is monitored by TLC thin-layer chromatography. Cool down, add acetic ether (40 mL) and water (40 mL) to dilute, separate solution, separate organic phase, anhydrous sodium sulfate is then extracted with acetic ether (20 mL×2), then reduce pressure and distill to remove the solvent. The crude product is separated and purified by silica gel column chromatography and eluent (petroleum ether/ethyl acetate=15:1-10:1), obtaining 1663 mg of ligand Ligand 2, an white solid, the yield is 86%.

¹H NMR (500 MHz, DMSO-d₆): δ 1.88 (s, 3H), 1.93 (s, 6H), 2.01 (s, 3H), 2.26 (s, 3H), 2.45 (s, 3H), 6.94 (s, 2H), 7.06 (ddd, J=8.2, 2.3, 0.6 Hz, 1H), 7.11 (dd, J=8.4, 2.1 Hz, 1H), 7.24 (t, J=2.2 Hz, 1H), 7.30 (d, J=4.7 Hz, 1H), 7.33-7.36 (m, 2H), 7.44-7.47 (m, 1H), 7.49-7.52 (m, 2H), 7.61 (s, 1H), 7.77 (d, J=8.3 Hz, 1H), 8.23 (d, J=7.6 Hz, 1H), 8.29 (d, J=8.4 Hz, 1H), 8.53 (d, J=5.0 Hz, 1H).

The Synthesis of Compound Pt2:

Add, in turn, ligand Ligand 2 (1300 mg, 2.31 mmol, 1.00 equivalent), potassium tetrachloroplatinate (1054 mg, 2.54 mmol, 1.10 equivalent) and tetrabutylammonium bromide (74 mg, 0.23 mmol, 0.10 equivalent) to a reaction tube with magnetic rotor. Carry out nitrogen exchange three times, then add solvent acetic acid (160 mL). Bubbling nitrogen for 20 minutes, the reaction mixture is agitated at room temperature for 12 hours and then agitated at 110° C. for 3 days. Cool the reaction mixture down to room temperature, then reduce pressure and distill to remove the solvent. The crude product is separated and purified by silica gel column chromatography and eluent (petroleum ether/dichloromethane=3:1-2:1), obtaining 1210 mg, the yield is 69%. ¹H NMR (500 MHz, DMSO-d₆): δ 2.04 (s, 6H), 2.15 (s, 3H), 2.31 (s, 3H), 2.40 (s, 3H), 2.45 (s, 3H), 6.97 (d, J=7.6 Hz, 1H), 7.03 (s, 2H), 7.17-7.19 (m, 2H), 7.24 (t, J=7.9 Hz, 1H), 7.33 (d, J=7.5 Hz, 1H), 7.40 (t, J=7.2 Hz, 1H), 7.47-7.50 (m, 1H), 7.86 (d, J=8.3 Hz, 1H), 7.98 (s, 1H), 8.12 (d, J=8.2 Hz, 1H), 8.15 (d, J=7.1 Hz, 1H), 9.15 (d, J=6.1 Hz, 1H).

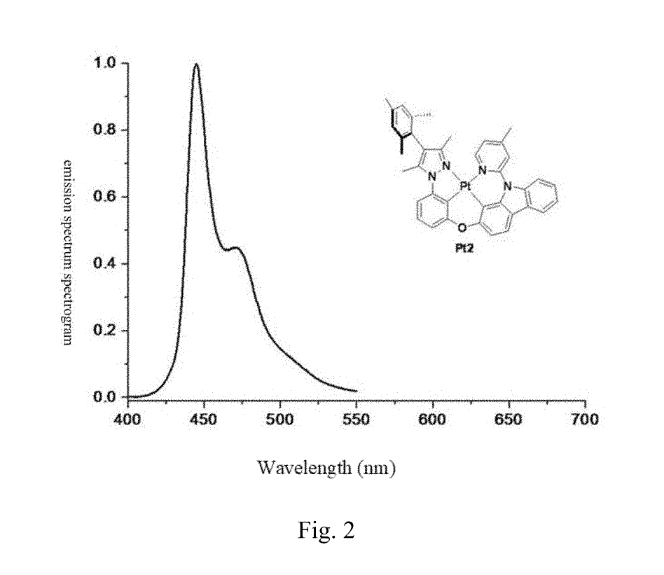

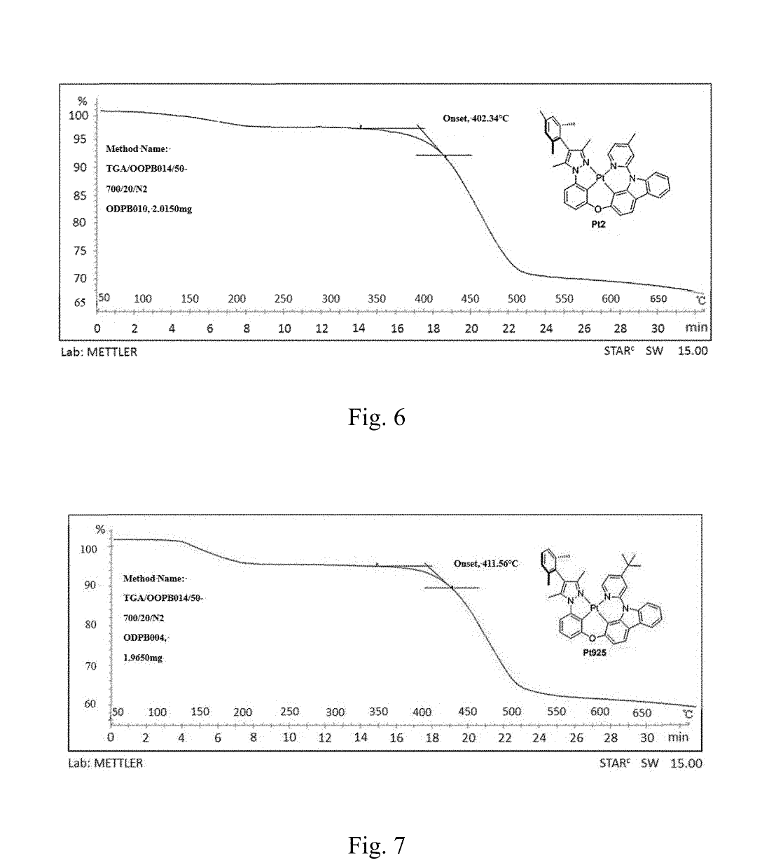

FIG. 2 is an emission spectrum spectrogram of compound Pt2 dichloromethane solution at room temperature, and FIG. 6 is a thermogravimetric analysis (TGA) curve of compound Pt2.

### Embodiment 3: Compound Pt925 May be Synthesized in Accordance with the Following Route

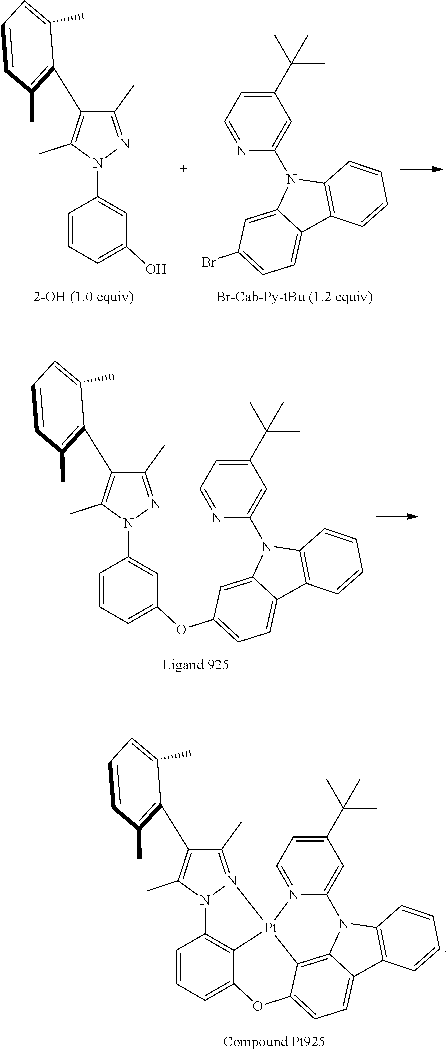

The Synthesis of Ligand Ligand 925:

Add, in turn, 1-(3-oxhydryl phenyl)-3,5-dimethyl-4-(2,6-dimethyl phenyl)-pyrazol 2-OH (877.1 mg, 3.00 mmol, 1.0 equivalent), 2-bromine-9-(2-(4-tert.-butyl pyridyl)) carbazole Br-Cab-Py-tBu (1.37 g, 3.60 mmol, 1.2 equivalent, synthesis method referring to The Journal of Organic Chemistry, 2017, 82, 1024-1033), iodide copper (57.1 mg, 0.30 mmol, 0.1 equivalent), ligand 2-picolinic acid (73.9 mg, 0.60 mmol, 0.2 equivalent), potassium orthophosphate (1.34 g, 6.30 mmol, 2.1 equivalent) to a dry three-mouth tube sealing with magnetic rotor, carry out nitrogen exchange three times, then add solvent dimethyl sulfoxide (8 mL). Then the reaction mixture is agitated at 120° C. for 3 days. Cool it down to room temperature, add large amount of ethyl acetate to dilute, filter and wash with ethyl acetate. The obtained filtrate is washed with water two times, extract water phase two times, merge organic phase, dry with anhydrous sodium sulfate. Filter and reduce pressure and distill to remove the solvent. The obtained crude product is separated and purified by silica gel column chromatography and eluent (petroleum ether/ethyl acetate=10:1), obtaining 1.47 g of target product, an white solid, the yield is 96%.

¹H NMR (400 MHz, DMSO-d₆): δ 1.28 (s, 9H), 1.89 (s, 3H), 1.966 (s, 3H), 1.969 (s, 6H), 7.10-7.18 (m, 5H), 7.29 (t, J=2.0 Hz, 1H), 7.31-7.39 (m, 3H), 7.42-7.46 (m, 2H), 7.52 (t, J=8.0 Hz, 1H), 7.63 (d, J=0.8 Hz, 1H), 7.74 (d, J=8.0 Hz, 1H), 8.22 (d, J=7.6 Hz, 1H), 8.29 (d, J=8.4 Hz, 1H), 8.56 (d, J=5.2 Hz, 1H).

The Synthesis of Compound Pt925:

Add, in turn, ligand Ligand 925 (1.1023 g, 1.87 mmol, 1.00 equivalent), potassium tetrachloroplatinate (0.8519 g, 2.05 mmol, 1.10 equivalent) and tetrabutylammonium bromide (0.0608 g, 0.19 mmol, 0.10 equivalent) to a dry three-mouth flask with magnetic rotor. Carry out nitrogen exchange three times, then add solvent acetic acid (112 mL) under nitrogen protection. Bubbling nitrogen for 20 minutes, ten it is agitated at room temperature for 18 hours then the reaction bottle is placed in 110° C. oil bath. After stirring for 3 days, the thin-layer chromatography monitoring reaction is completed. Cool it down to room temperature, and concentrate, the obtained crude product is separated and purified by quick silica gel column chromatography (eluent: petroleum ether/dichloromethane=5/2), obtaining 1.2578 g compound pt925, a yellowish solid, the yield is 86%.

¹H NMR (500 MHz, DMSO-d₆): δ 1.32 (s, 9H), 2.08 (br s, 6H), 2.17 (s, 3H), 2.46 (s, 3H), 6.98 (d, J=8.0 Hz, 1H), 7.15-7.29 (m, 5H), 7.34 (d, J=7.5 Hz, 1H), 7.37-7.44 (m, 2H), 7.49 (t, J=7.8 Hz, 1H), 7.87 (d, J=8.0 Hz, 1H), 8.06 (d, J=2.0 Hz, 1H), 8.11 (d, J=8.5 Hz, 1H), 8.16 (d, J=7.0 Hz, 1H), 9.17 (d, J=6.0 Hz, 1H).

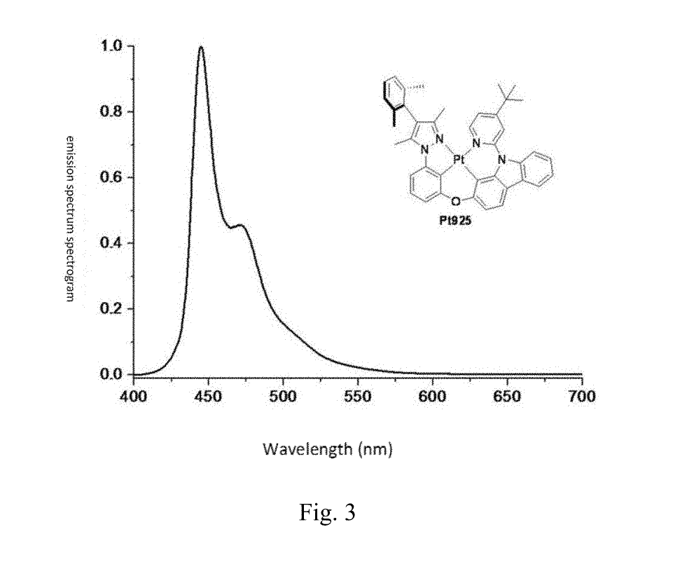

FIG. 3 is an emission spectrum spectrogram of compound Pt925 dichloromethane solution at room temperature, and FIG. 7 is a thermogravimetric analysis (TGA) curve of compound Pt925.

### Embodiment 4: Compound Pt926 May be Synthesized in Accordance with the Following Route

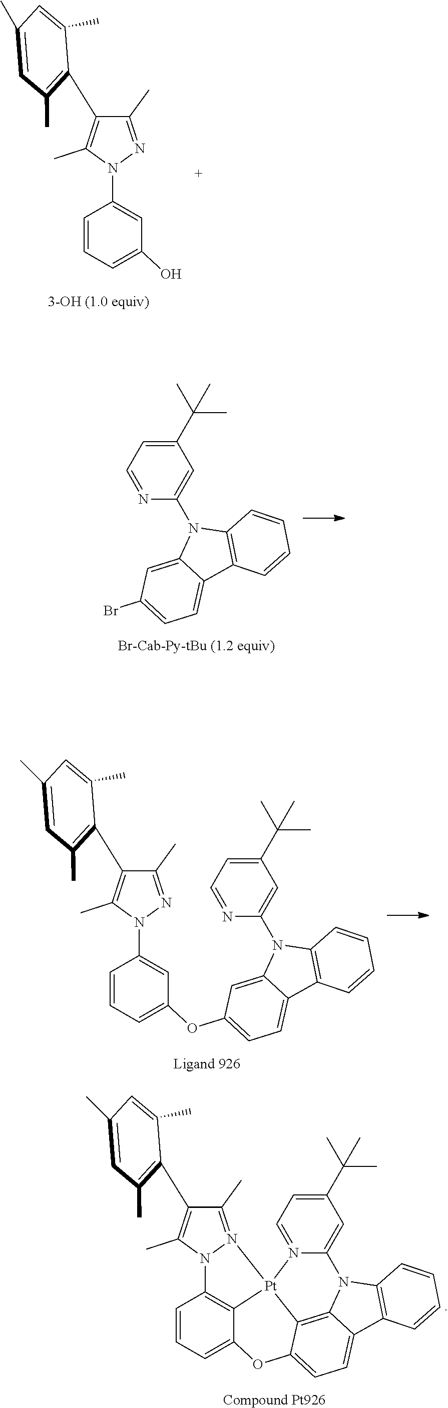

The Synthesis of Ligand Ligand 925:

Add, in turn, 1-(3-oxhydryl phenyl)-2,5-dimethyl-4-(2,4,6-trimethyl phenyl)-pyrazol 3-OH (1.46 g, 5.00 mmol, 1.0 equivalent), 2-bromine-9-(2-(4-tert.-butyl pyridyl)) carbazole Br-Cab-Py-tBu (2.27 g, 6.00 mmol, 1.2 equivalent, synthesis method referring to The Journal of Organic Chemistry, 2017, 82, 1024-1033), iodide copper (95.2 mg, 0.50 mmol, 0.1 equivalent), ligand 2-picolinic acid (123.1 mg, 1.00 mmol, 0.2 equivalent), potassium orthophosphate (2.23 g, 10.50 mmol, 2.1 equivalent) to a dry three-mouth tube sealing with magnetic rotor, carry out nitrogen exchange three times, then add solvent dimethyl sulfoxide (10 mL). Then the reaction mixture is agitated at 120° C. for 3 days. Cool it down to room temperature, add large amount of ethyl acetate to dilute, filter and wash with ethyl acetate. The obtained filtrate is washed with water two times, extract water phase two times, merge organic phase, dry with anhydrous sodium sulfate. Filter and reduce pressure and distill to remove the solvent. The obtained crude product is separated and purified by silica gel column chromatography and eluent (petroleum ether/ethyl acetate=20:1-10:1), obtaining 2.78 g of target product, an white solid, the yield is 92%.

¹H NMR (500 MHz, DMSO-_{d6}): δ 1.27 (s, 9H), 1.87 (s, 3H), 1.92 (s, 6H), 1.95 (s, 3H), 2.25 (s, 3H), 6.93 (s, 2H), 7.10 (dd, J=8.5, 2.0 Hz, 1H), 7.14 (dd, J=8.5, 2.5 Hz, 1H), 7.28 (t, J=2.0 Hz, 1H), 7.33 (t, J=7.5 Hz, 1H), 7.37 (dd, J=8.5, 1.5 Hz, 1H), 7.38 (d, J=2.0 Hz, 1H), 7.42-7.45 (m, 2H), 7.51 (t, J=8.0 Hz, 1H), 7.62 (d, J=1.5 Hz, 1H), 7.74 (d, J=8.0 Hz, 1H), 8.22 (d, J=8.0 Hz, 1H), 8.29 (d, J=8.5 Hz, 1H), 8.56 (d, J=5.0 Hz, 1H).

The Synthesis of Compound Pt926:

Add, in turn, ligand Ligand 926 (1.1709 g, 1.94 mmol, 1.00 equivalent), potassium tetrachloroplatinate (0.8840 g, 2.13 mmol, 1.10 equivalent) and tetrabutylammonium bromide (0.0630 g, 0.19 mmol, 0.10 equivalent) to a dry three-mouth flask with magnetic rotor. Carry out nitrogen exchange three times, then add solvent acetic acid (116 mL) under nitrogen protection. Bubbling nitrogen for 20 minutes, then it is agitated at room temperature for 18 hours then the reaction bottle is placed in 110° C. oil bath. After stirring for 3 days, the thin-layer chromatography monitoring reaction is completed. Cool it down to room temperature, and concentrate, the obtained crude product is separated and purified by quick silica gel column chromatography (eluent: petroleum ether/dichloromethane=5/2), obtaining 1.1125 g compound pt926, a yellowish solid, the yield is 72%.

¹H NMR (500 MHz, DMSO-d₆): δ 1.32 (s, 9H), 2.04 (br s, 6H), 2.16 (s, 3H), 2.30 (s, 3H), 2.45 (s, 3H), 6.97 (d, J=7.5 Hz, 1H), 7.03 (s, 2H), 7.19 (d, J=8.5 Hz, 1H), 7.23 (t, J=8.0 Hz, 1H), 7.33 (d, J=7.5 Hz, 1H), 7.38-7.44 (m, 2H), 7.49 (t, J=7.5 Hz, 1H), 7.87 (d, J=8.5 Hz, 1H), 8.05 (d, J=1.5 Hz, 1H), 8.11 (d, J=8.0 Hz, 1H), 8.16 (d, J=7.0 Hz, 1H), 9.16 (d, J=6.5 Hz, 1H).

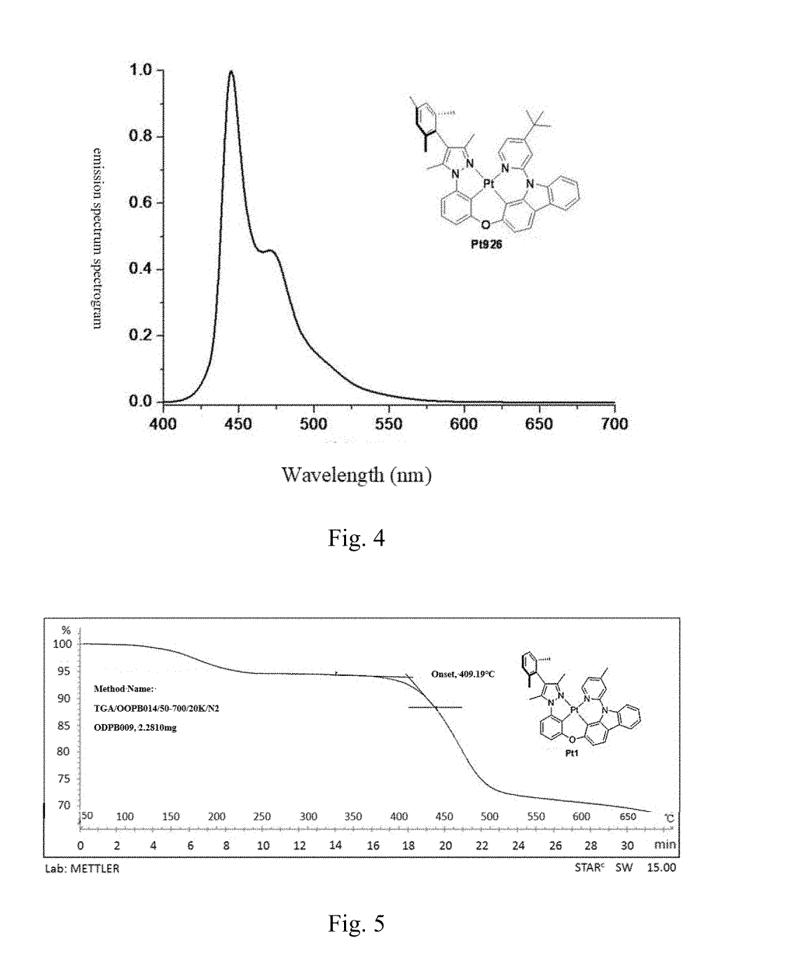

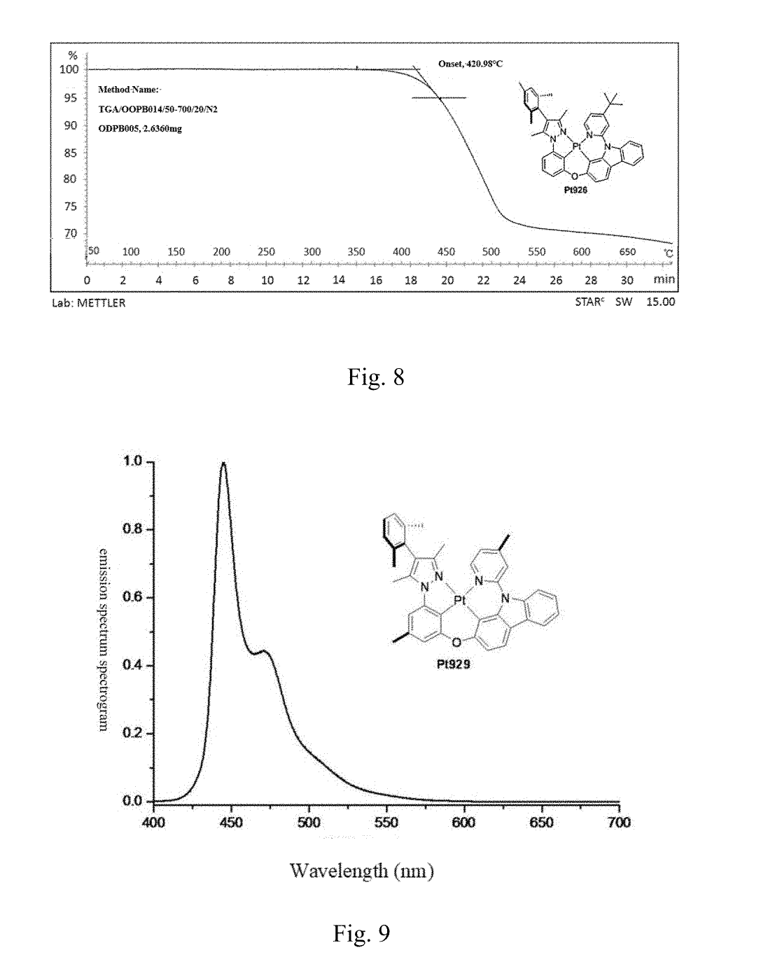

FIG. 4 is an emission spectrum spectrogram of compound Pt926 dichloromethane solution at room temperature, and FIG. 8 is a thermogravimetric analysis (TGA) curve of compound Pt926.

### Embodiment 5: Compound Pt929 May be Synthesized in Accordance with the Following Route

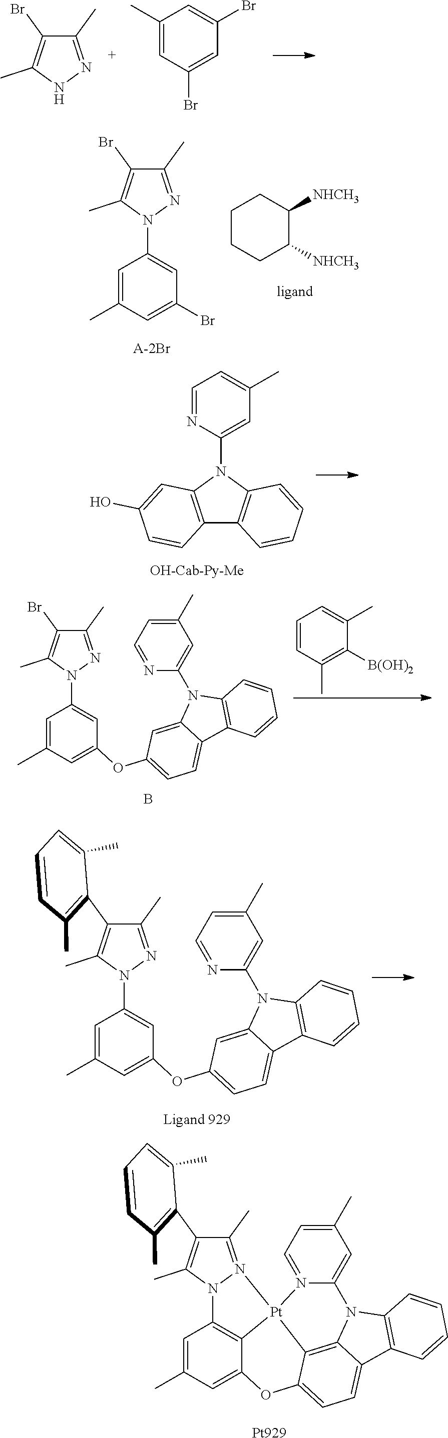

The Synthesis of A-2Br:

Add, in turn, pyrazole derivative (610 mg, 3.48 mmol, 1.00 equivalent), ligand (96 mg, 0.70 mmol, 0.20 equivalent), potassii (963 mg, 6.97 mmol, 2.00 equivalent) and iodide copper (67 mg, 0.35 mmol, 0.10 equivalent) to a dry three-mouth bottle, carry out nitrogen exchange three times, then add 3,5-dibromotoluene (1742 mg, 6.97 mmol, 2.00 equivalent) and resteamed dimethyl sulfoxide (10 mL). The reaction mixture is agitated at 120° C. for 3 days. After the reaction ends, the reaction solution is cooled to room temperature, then add water (50 ml) and acetic ether (30 mL), mix and separate liquid, wash filter residue with a small amount of ethyl acetate, combine the organic layer, after it is dried with anhydrous sodium sulfate, separate by mixing silica gel dry column (mobile phase petroleum ether:ethyl acetate=20:1), obtaining 988 mg of white solid, the yield is 83%.

¹H NMR (500 MHz, DMSO-d₆): δ 2.19 (s, 3H), 2.31 (s, 3H), 2.38 (s, 3H), 7.37 (s, 1H), 7.48 (s, 1H), 7.53 (s, 1H).

The Synthesis of B:

Add, in turn, pyrazole derivative (330 mg, 1 mmol, 1.00 equivalent), carbazole derivative (274 mg, 1 mmol, 1.00 equivalent), iodide copper (19 mg, 0.10 mmol, 0.10 equivalent), 2-picolinic acid (25 mg, 0.2 mmol, 0.20 equivalent) and potassium orthophosphate (445 mg, 2.1 mmol, 2.10 equivalent) to a dry three-mouth tube sealing. Carry out nitrogen exchange three times, then add DMSO (5 mL). Then the reaction mixture is agitated at 105° C. for 3 days. After the reaction ends, add water (40 mL) and wash with acetic ether (40 mL), separate solution, extract water phase with acetic ether (20 mL*2), merge organic phase, dry with anhydrous sodium sulfate, separate by mixing silica gel column (mobile phase petroleum ether:ethyl acetate=15: 1-10:1), obtaining 170 mg of yellow semi solid, the yield is 32.5%.

¹H NMR (500 MHz, CDCl₃): δ 2.25 (s, 3H), 2.27 (s, 3H), 2.36 (s, 3H), 2.49 (s, 3H), 6.83-6.85 (m, 2H), 6.97 (s, 1H), 7.03 (dd, J=8.4, 2.1 Hz, 1H), 7.14 (d, J=5.0 Hz, 1H), 7.31-7.34 (m, 1H), 7.41-7.45 (m, 2H), 7.54 (d, J=2.0 Hz, 1H), 7.77 (d, J=8.3 Hz, 1H), 8.07-8.08 (m, 2H), 8.55 (d, J=5.1 Hz, 1H).

The Synthesis of Ligand Ligand 929:

Add, in turn, carbazole derivative (155 mg, 0.29 mmol, 1.00 equivalent), 2,6-dimethyl phenylo boric acid (57 mg, 0.35 mmol, 1.20 equivalent), Pd₂(dba)₃ (3 mg, 0.01 mmol, 0.02 equivalent), tripotassium phosphate (106 mg, 0.58 mol, 2.00 equivalent), and S-Phos (13 mg, 0.03 mmol, 0.08 equivalent) to a dry three-mouth tube sealing with magnetic rotor, carry out nitrogen exchange three times, then add methylbenzene (10 mL). Then bubbling nitrogen for 20 minutes, then the reaction mixture is agitated at 120° C. for 2 days. After the reaction ends, cool it down, add 40 mL of water, extract with acetic ether (10 mL×3), merge organic phase, dry with anhydrous sodium sulfate. Filter and reduce pressure and distill to remove the solvent. The obtained crude product is separated and purified by silica gel column chromatography and eluent (petroleum ether/ethyl acetate=20:1-15:1), obtaining 140 mg of white solid, the yield is 86%.

¹H NMR (400 MHz, DMSO-d₆): δ 1.88 (s, 3H), 1.97 (s, 6H), 1.99 (s, 3H), 2.37 (s, 3H), 2.44 (s, 3H), 6.90 (s, 1H), 7.03 (t, J=1.8 Hz, 1H), 7.08-7.19 (m, 5H), 7.29-7.35 (m, 2H), 7.42-7.47 (m, 1H), 7.50 (d, J=2.1 Hz, 1H), 7.61 (s, 1H), 7.77 (d, J=8.3 Hz, 1H), 8.22 (d, J=7.5 Hz, 1H), 8.28 (d, J=8.5 Hz, 1H), 8.53 (d, J=5.1 Hz, 1H).

The Synthesis of Compound Pt929:

Add, in turn, ligand Ligand 929 (140 mg, 0.25 mmol, 1.00 equivalent), potassium tetrachloroplatinate (123 mg, 0.27 mmol, 1.10 equivalent) and tetrabutylammonium bromide (10 mg, 0.03 mmol, 0.10 equivalent) to a reaction tube with magnetic rotor. Carry out nitrogen exchange three times, then add solvent acetic acid (10 mL). Bubbling nitrogen for 20 minutes, the reaction mixture is agitated at room temperature for 12, then it is agitated at 110° C. for 3 days. Cool the reaction mixture to room temperature, reduce pressure and distill to remove the solvent, the obtained crude product is separated and purified by silica gel column chromatography (eluent: petroleum ether/dichloromethane=3:1-2:1), obtaining 135 mg green-yellow solid, the yield is 71.5%.

¹H NMR (400 MHz, DMSO-d₆): δ 2.08 (s, 6H), 2.15 (s, 3H), 2.37 (s, 3H), 2.40 (s, 3H), 2.46 (s, 3H), 6.82 (s, 1H), 7.15-7.29 (m, 6H), 7.39 (t, J=7.5 Hz, 1H), 7.46-7.50 (m, 1H), 7.84 (d, J=8.3 Hz, 1H), 7.97 (s, 1H), 8.11 (d, J=8.4 Hz, 1H), 8.14 (d, J=7.5 Hz, 1H), 9.15 (d, J=6.1 Hz, 1H).

FIG. 9 is an emission spectrum spectrogram of compound Pt929 dichloromethane solution at room temperature.

Performance Evaluation Embodiment

Photophysical, electrochemical and thermogravimetric analysis of complexes prepared in the above mentioned embodiments of the present invention are performed as follows:

Photophysical analysis: Phosphorescence emission spectrum and triplet state life tests are both completed at HORIBA FL3-11 spectrograph. Test conditions: In the room temperature emission spectrum, all samples are dichloromethane (chromatographic grade) dilute solution (10⁻⁵-10⁻⁶ M), the preparation of all samples is completed in glove boxes, and nitrogen is introduced for 5 minutes; triplet state life is all measured at the strongest peak of the emission spectrum of the samples.

Electrochemical analysis: Cyclic voltammetry is adopted to test at CH670E electrochemical workstation. 0.1M N,N-dimethyl acetamide solution of ⁿBu₄NPF₆ serves as electrolyte solution; the electrode of metal platinum is positive electrode, the black lead is negative pole, metal silver serves as reference electrode, ferrocene serves as reference interior label and its redox potential is defined as zero.

Thermogravimetric analysis: The thermogravimetric analysis curves are all completed on the TGA2(SF) thermogravimetric analysis. The thermogravimetric analysis's conditions are: the test temperature is 50-700° C.; the heating rate is 20 K/min; the crucible material is aluminum trioxide; and the test is completed in nitrogen atmosphere; the sample quality is generally 2-5 mg.

Table 1. The photophysical, electrochemical and thermogravimetric analysis data of the metal complex luminescent materials.

TABLE 1

| Pt | | | | | | |
|---|---|---|---|---|---|---|
| complex | peak/nm | τ/μs | PLQE | Eₒₓ/eV | E_{red}/eV | T_{d}/° C. |
| Pt1 | 444.6 | 6.4 | 80% | 0.51 | −2.68 | 409 |
| Pt2 | 444.6 | 7.4 | 73% | 0.54 | −2.63 | 402 |
| Pt925 | 444.6 | 5.2 | 70% | 0.53 | −2.68 | 411 |
| Pt926 | 445.0 | 4.8 | 74% | 0.51 | −2.68 | 421 |
| Pt929 | 444.8 | 7.5 | 96% | — | — | 411 |

From the data in Table 1, it can be seen that the platinum complexes provided by the specific embodiments of the present invention are all dark blue phosphorescent luminescent materials, their maximum emission peak is about 445 nm: and the triplet state life of the solution is at the microsecond level (10⁻⁶ second); the quantum efficiency of phosphorescence is above 70%, all of them have strong phosphorescent emission; More importantly, the thermal decomposition temperature is all above 400° C., which is much higher than the thermal evaporation temperature of the material when a device is made (generally not more than 300° C.). Therefore, this kind of phosphorescence material has great application prospect in blue light, especially dark blue light phosphorescent material field, which is of great significance for the development and application of dark blue photoluminescent materials.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A tetradentate ring metal platinum complex containing 4-aryl-3, 5-disubstituted pyrazole, wherein the structure of the complex is shown in Fig. (I): 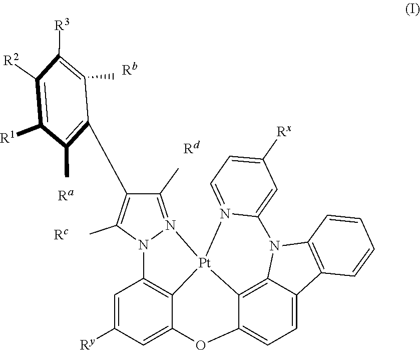
where,
R^{a}, R^{b}, R^{c} and R^{d} are respectively, independently alkyl, alkoxy, cycloalkyl, ether, heterocyclyl, oxhydryl, aryl, heteroaryl, aryloxy, mon- or dialkyl azyl, mon- or diaryl azyl, halogen, sulfydryl, cyanogroup or their combination;
R^{x} is alkyl, alkoxy, cycloalkyl, heterocyclyl, ether, mon- or dialkyl azyl, mon- or diaryl azyl, halogen or their combination;
R^{y} is H, deuterium, alkyl, alkoxy, cycloalkyl, heterocyclyl, ether, mon- or dialkyl azyl, mon- or diaryl azyl, halogen or their combination;
R¹, R² and R³ are respectively, independently H, deuterium, alkyl, alkoxy, ether, cycloalkyl, heterocyclyl, oxhydryl, aryl, heteroaryl, aryloxy, mon- or dialkyl azyl, mon- or diaryl azyl, halogen, sulfydryl, cyanogroup, halogen alkyl or their combination.

2. The tetradentate ring metal platinum complex containing 4-aryl-3, 5-disubstituted pyrazole as described in claim 1, wherein the 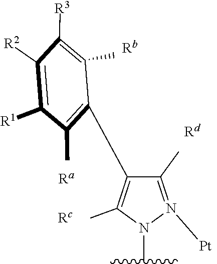
has a structure selected from one of the following:

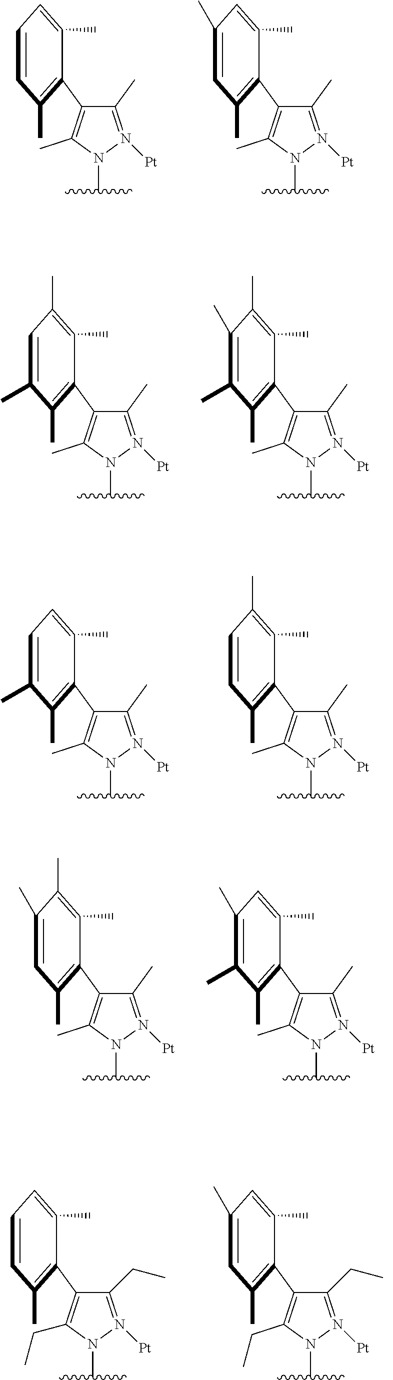

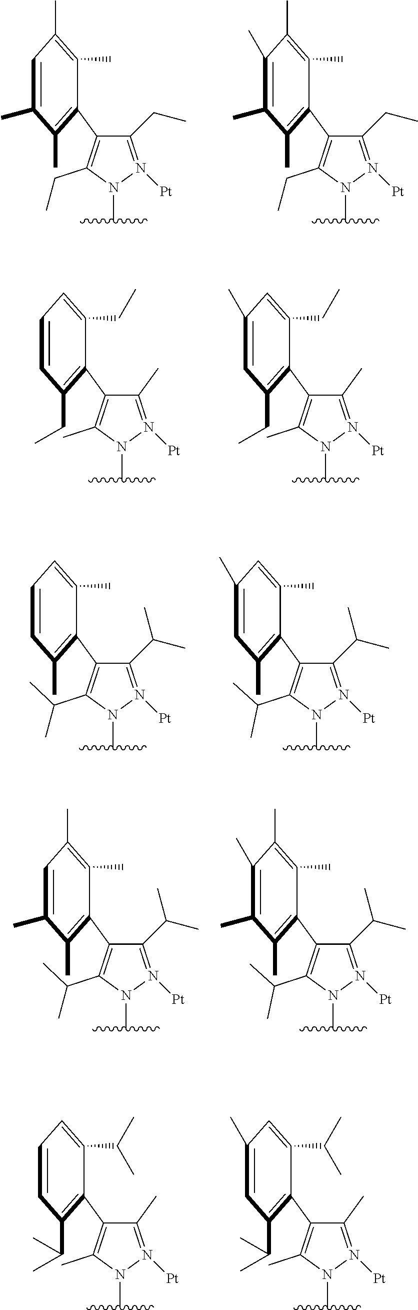

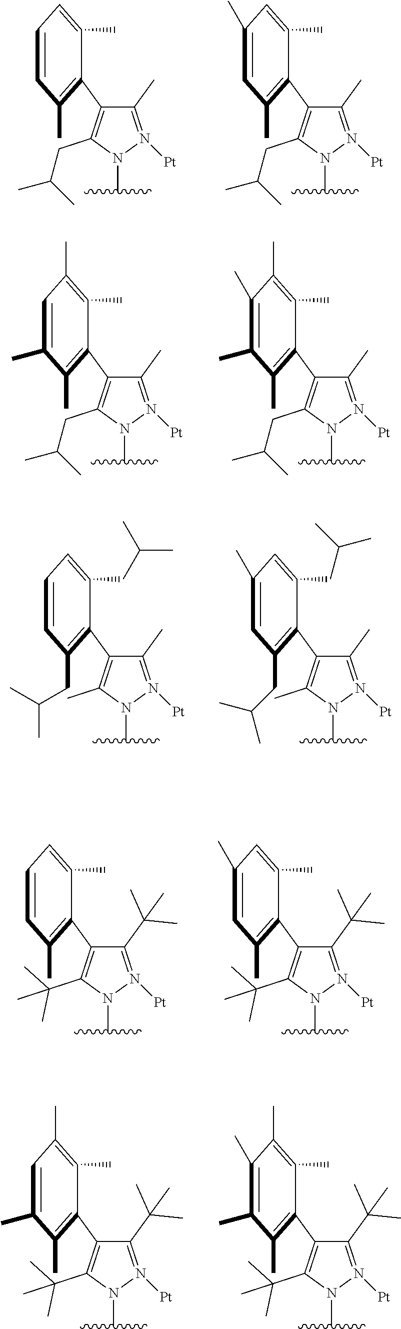

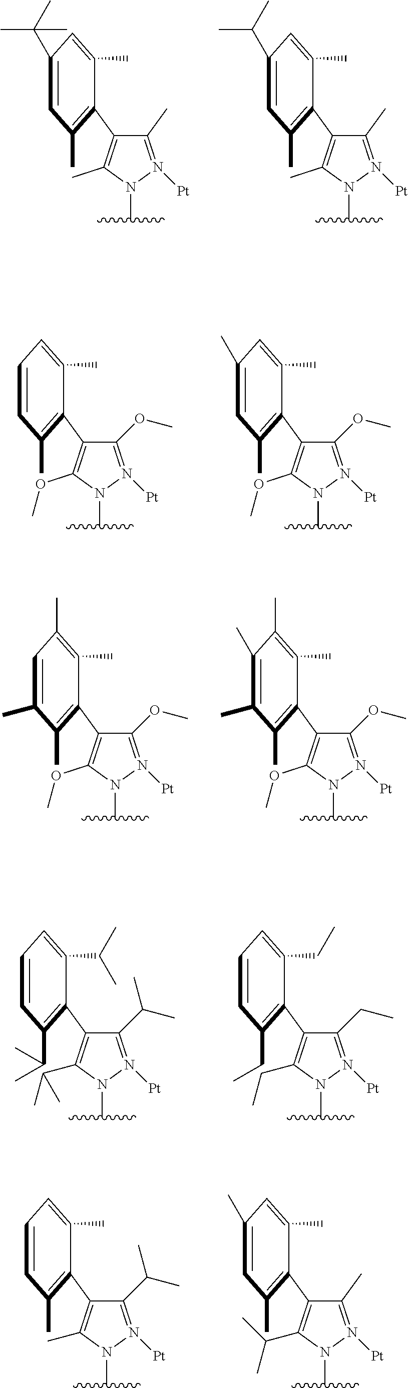

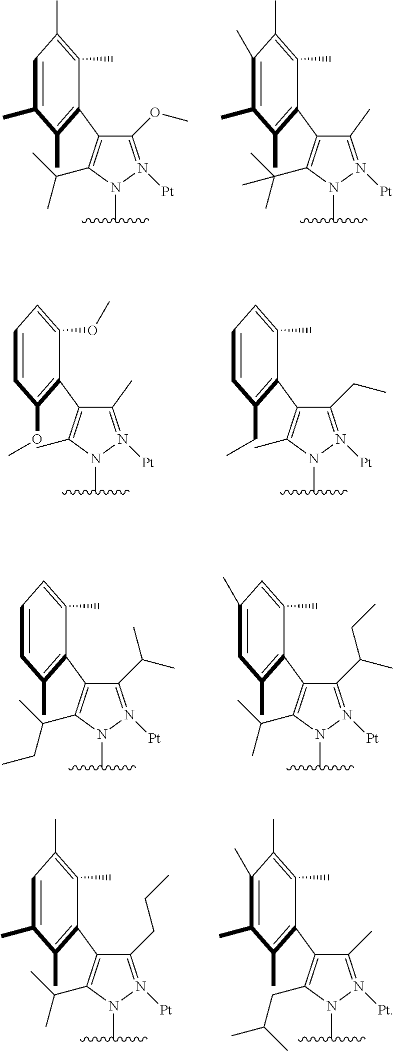

3. The tetradentate ring metal platinum complex containing 4-aryl-3, 5-disubstituted pyrazole as described in claim 1, wherein the complex has a structure selected from Pt1-Pt940:

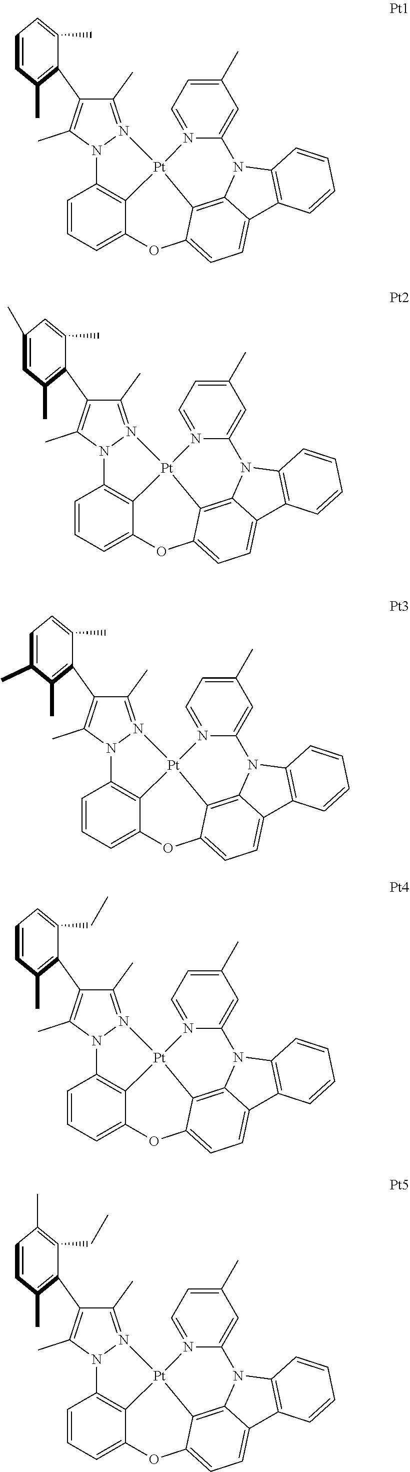

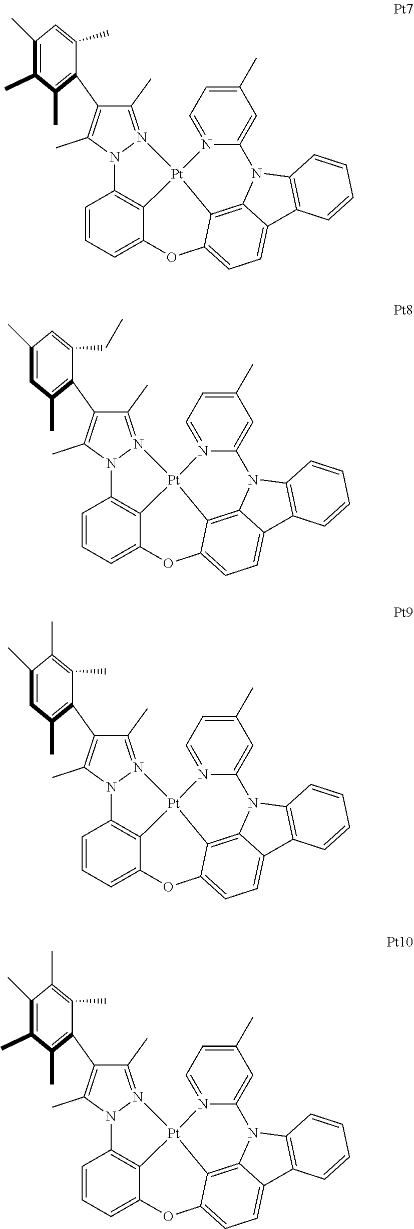

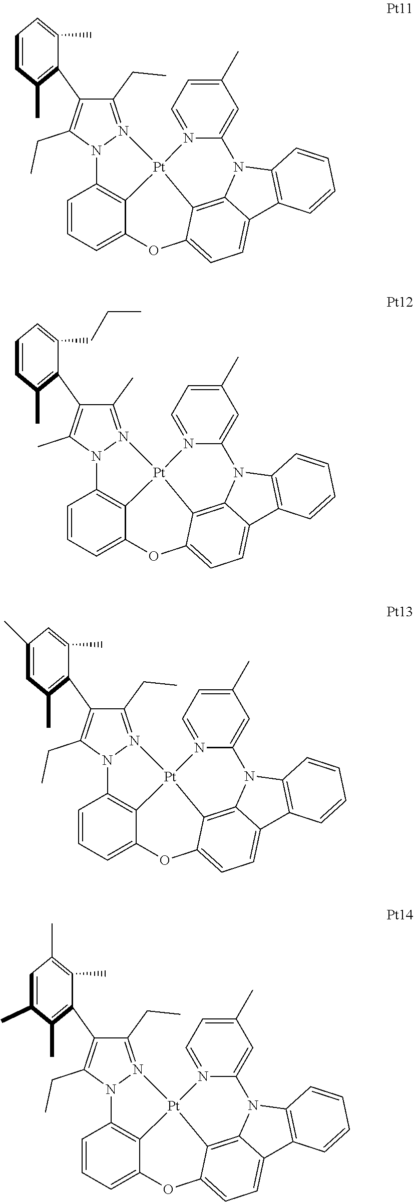

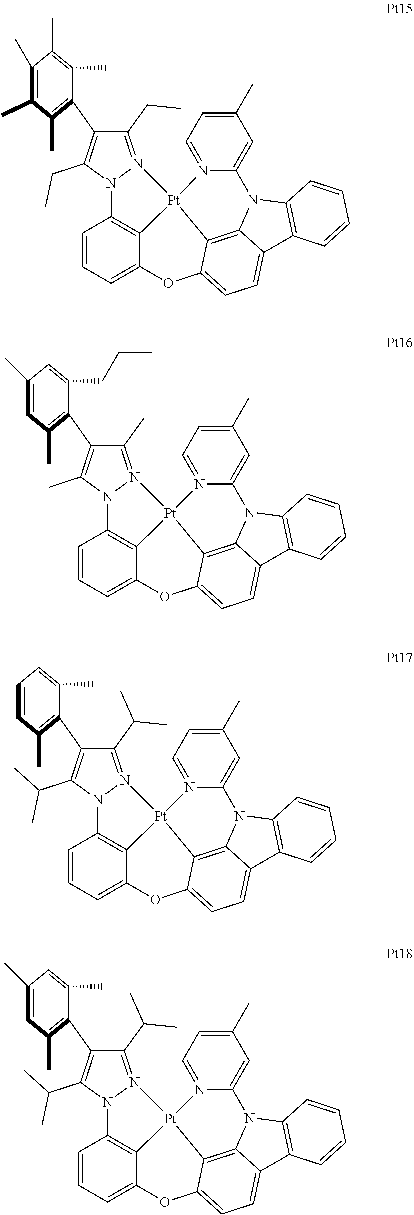

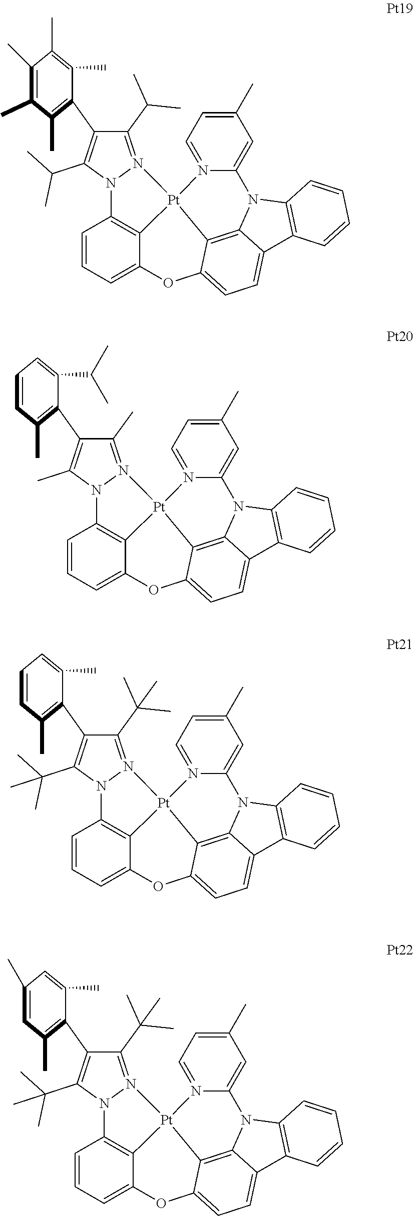

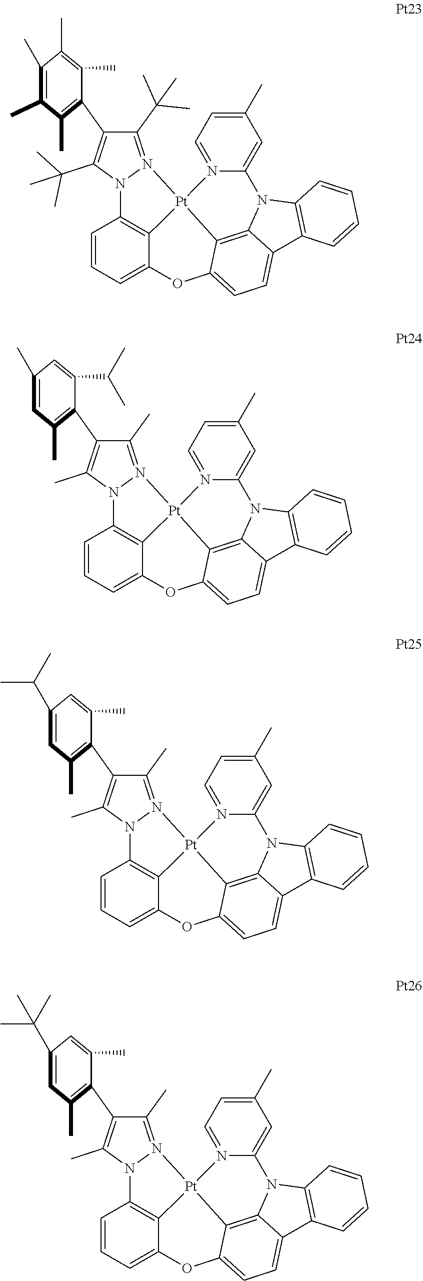

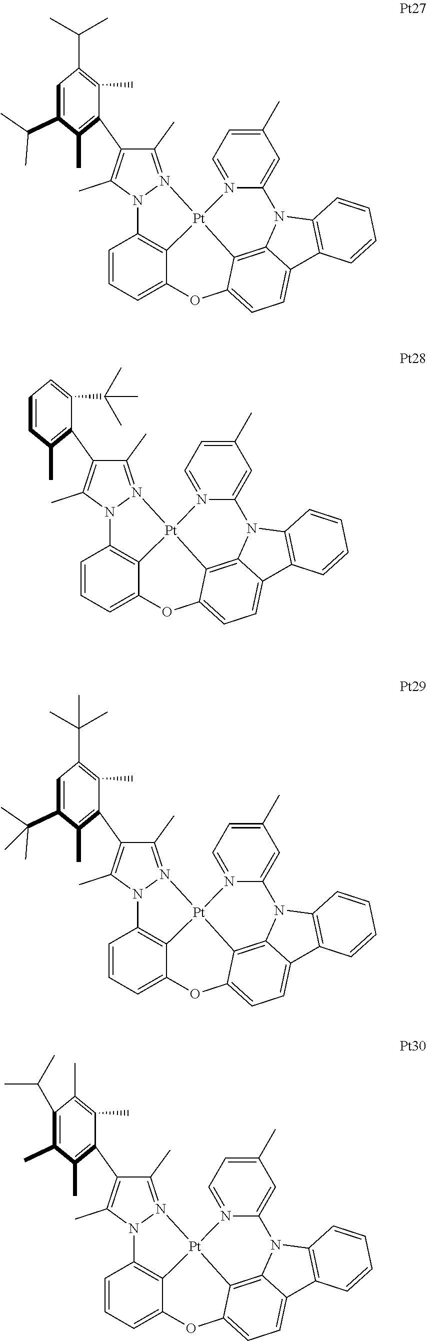

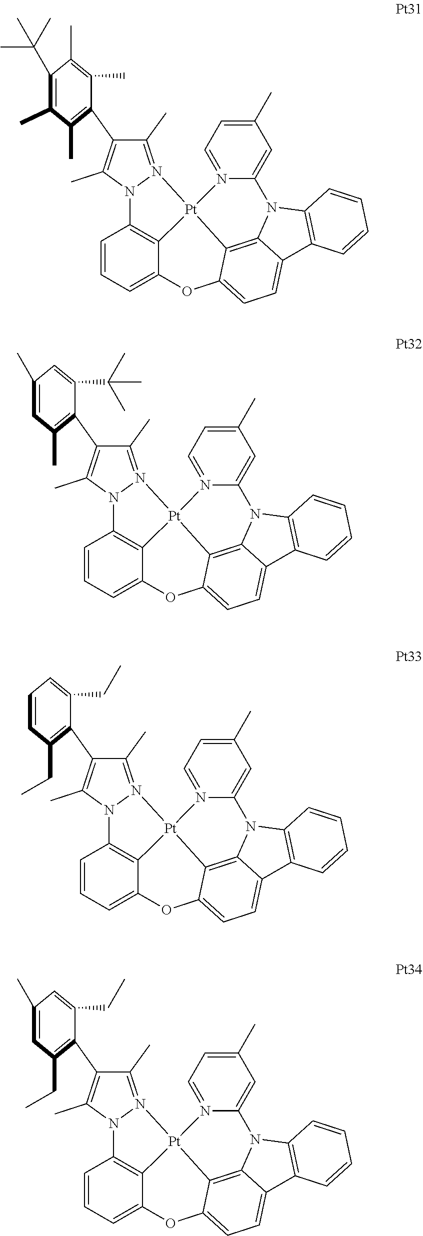

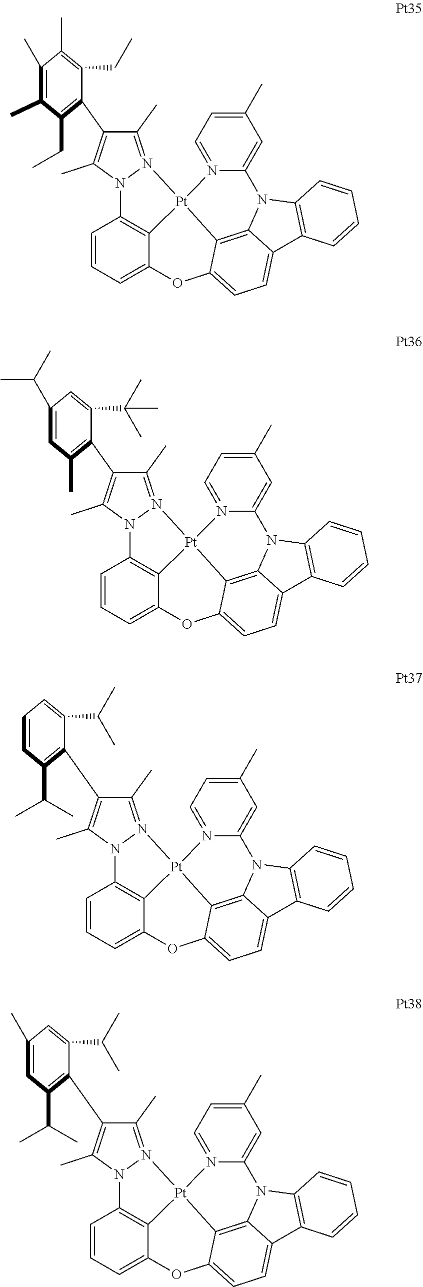

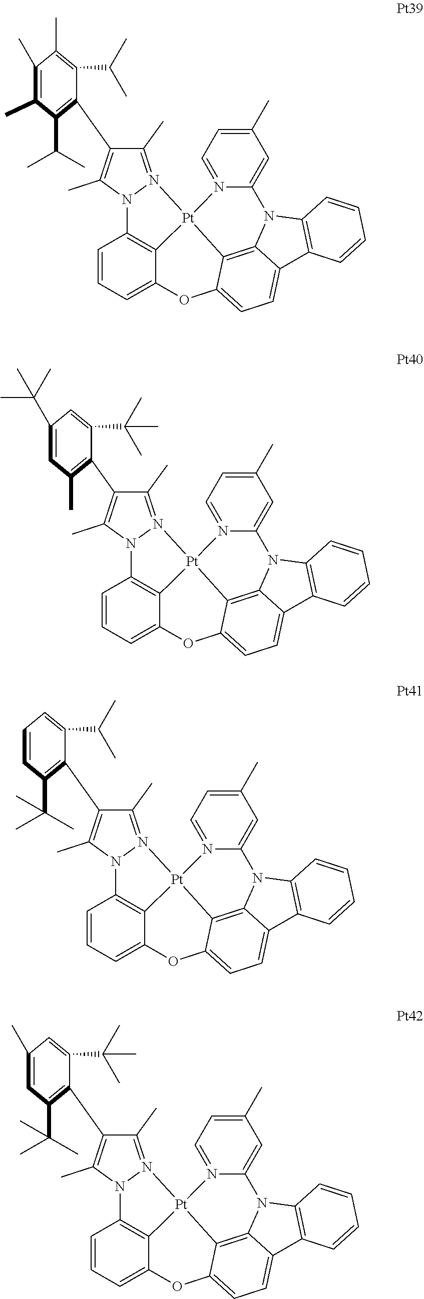

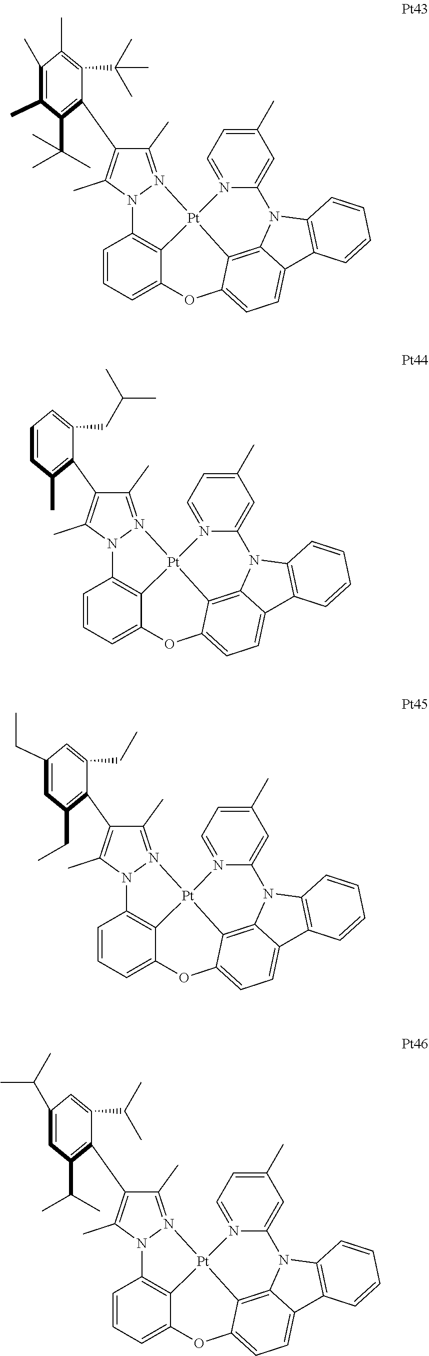

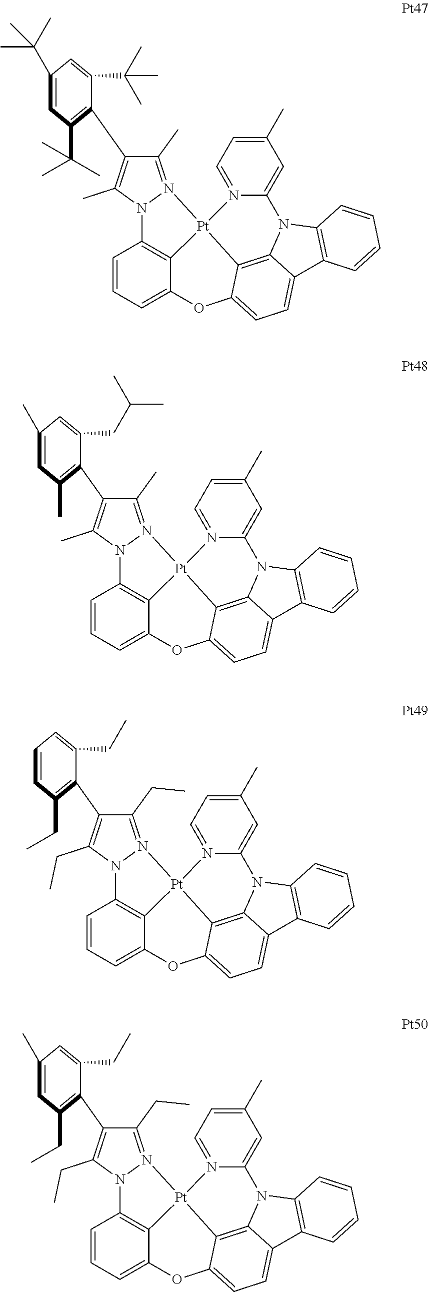

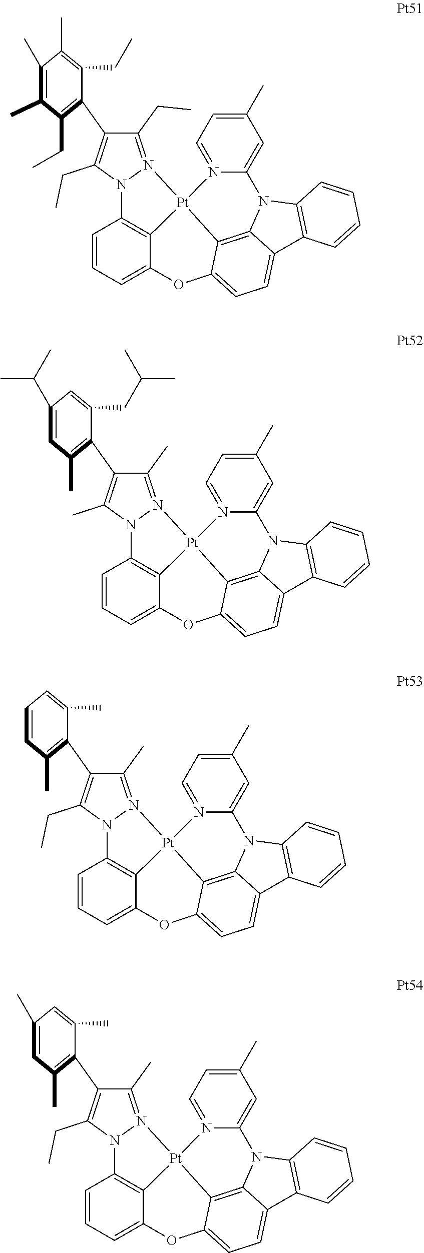

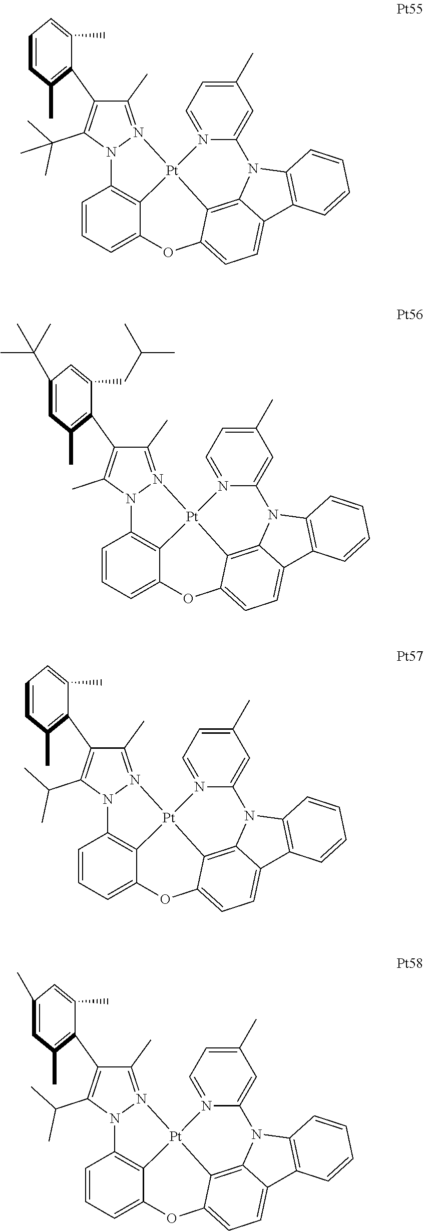

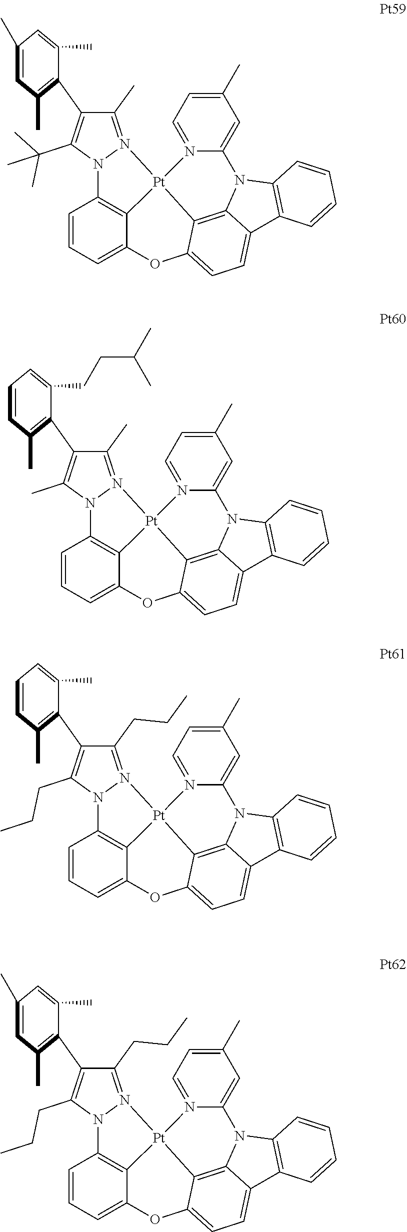

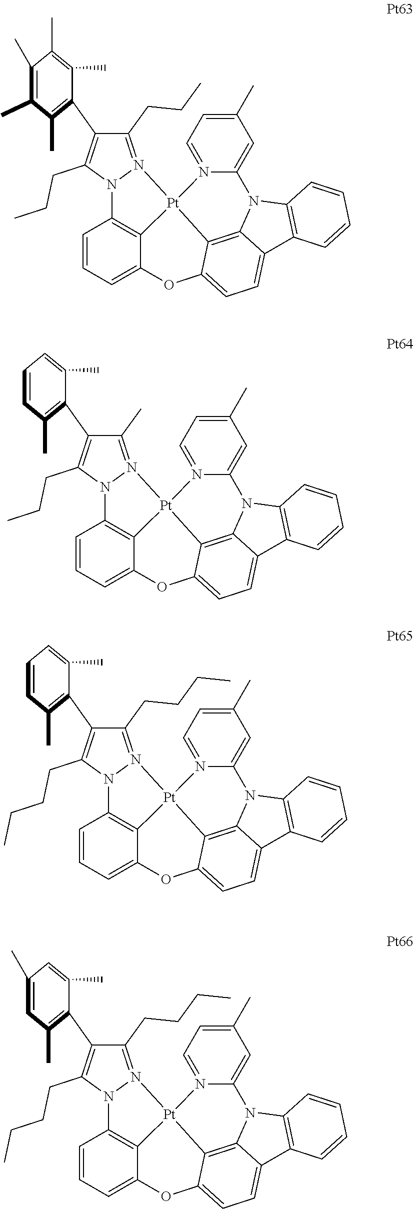

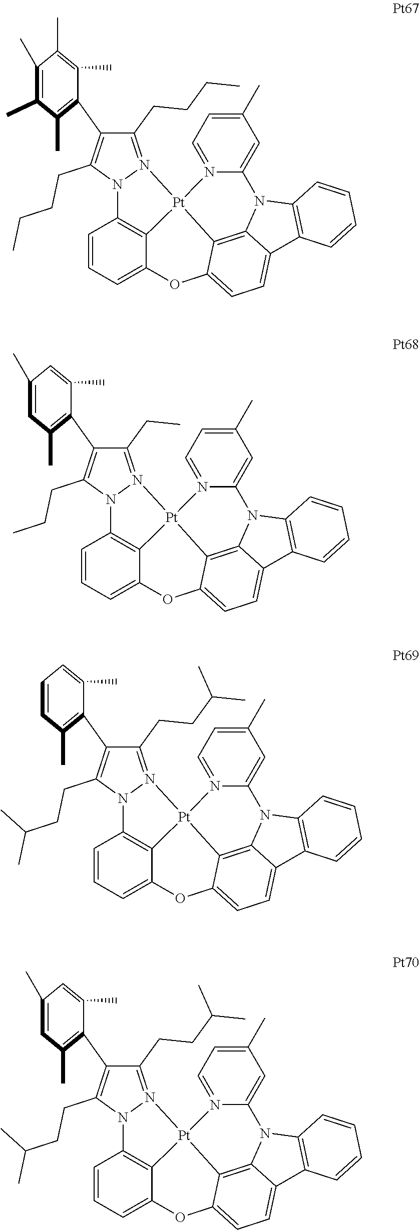

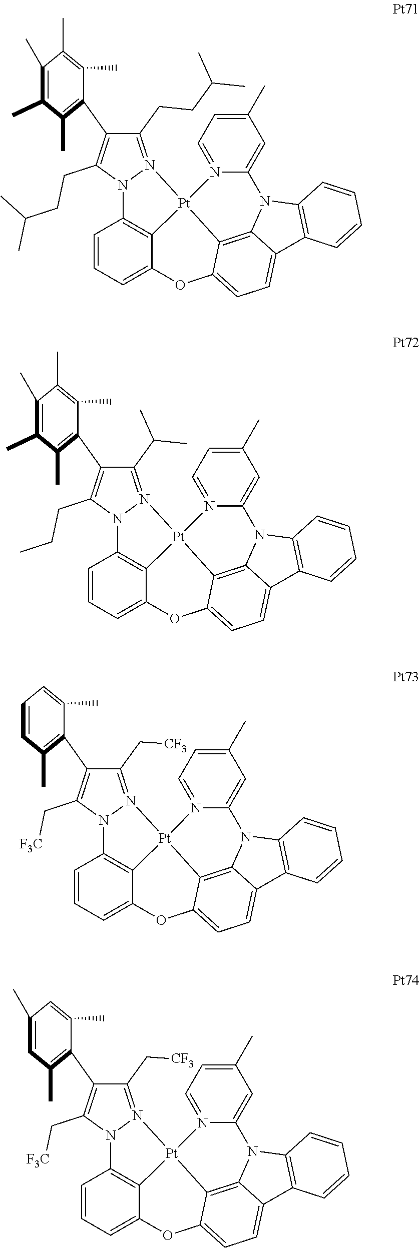

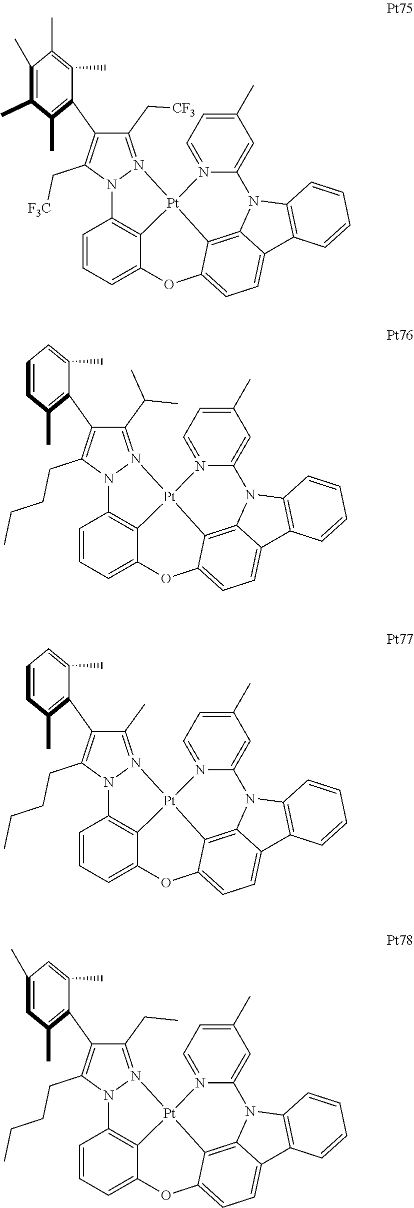

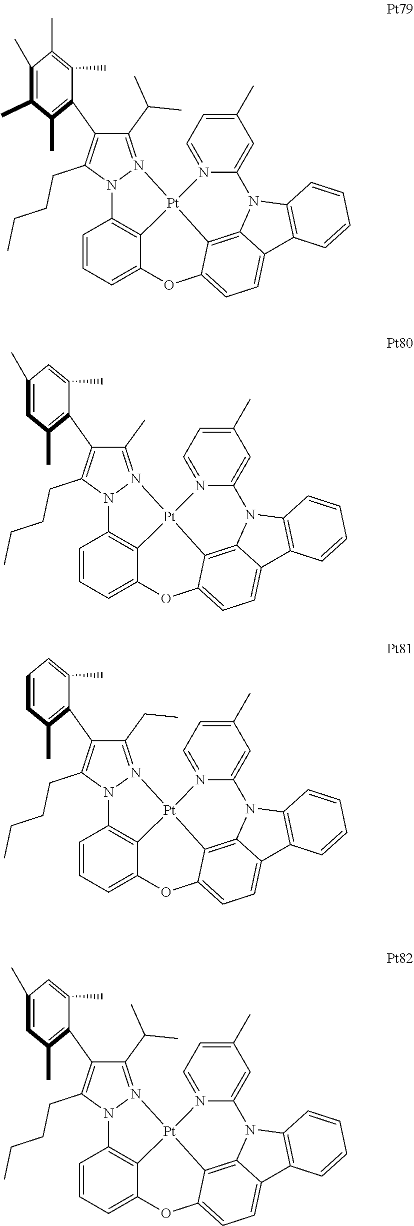

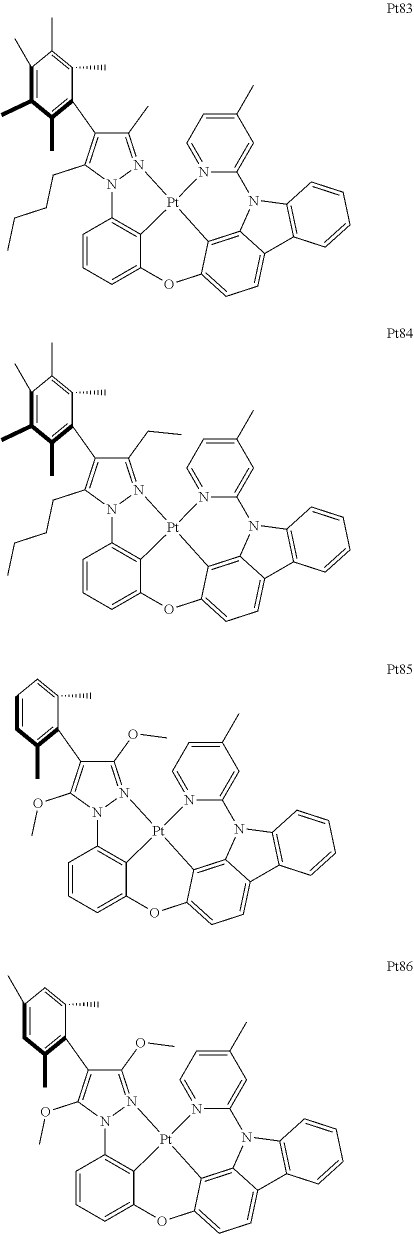

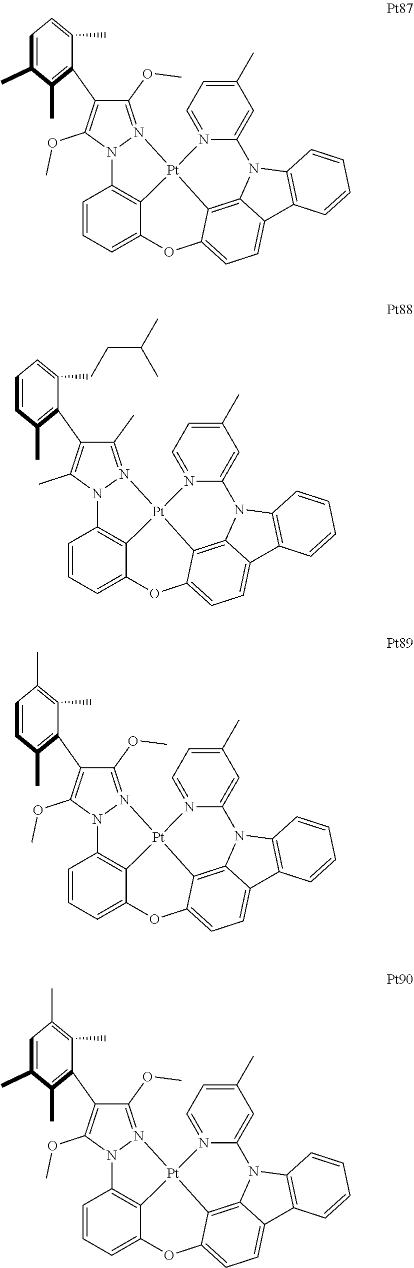

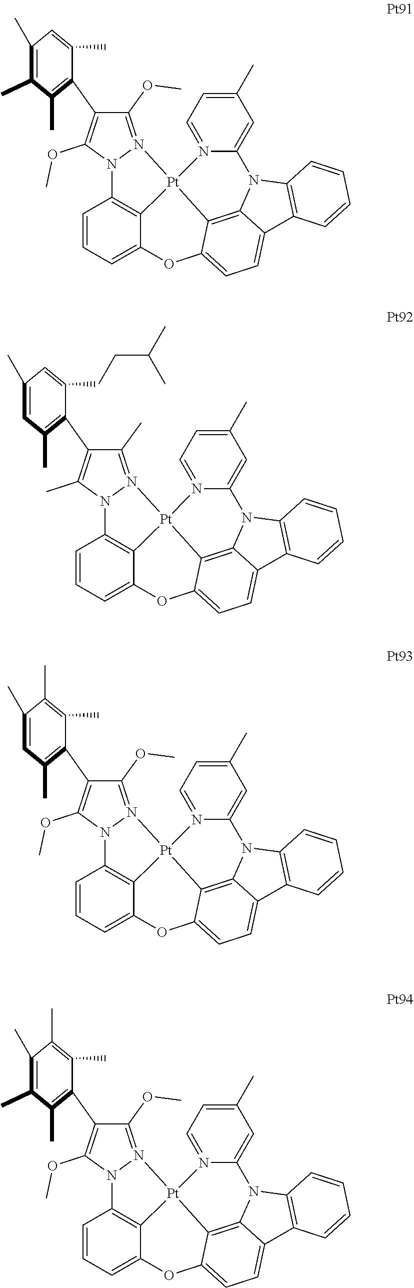

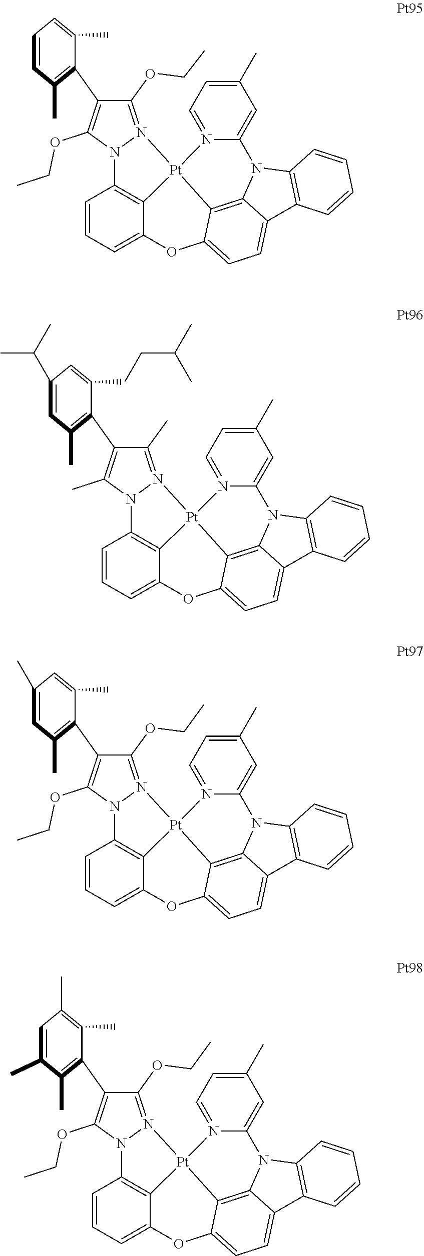

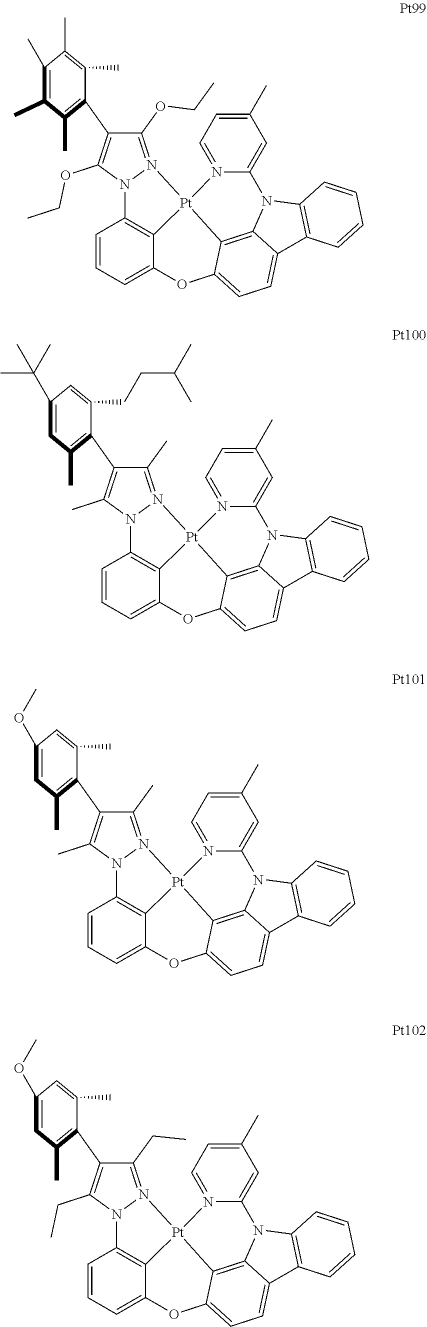

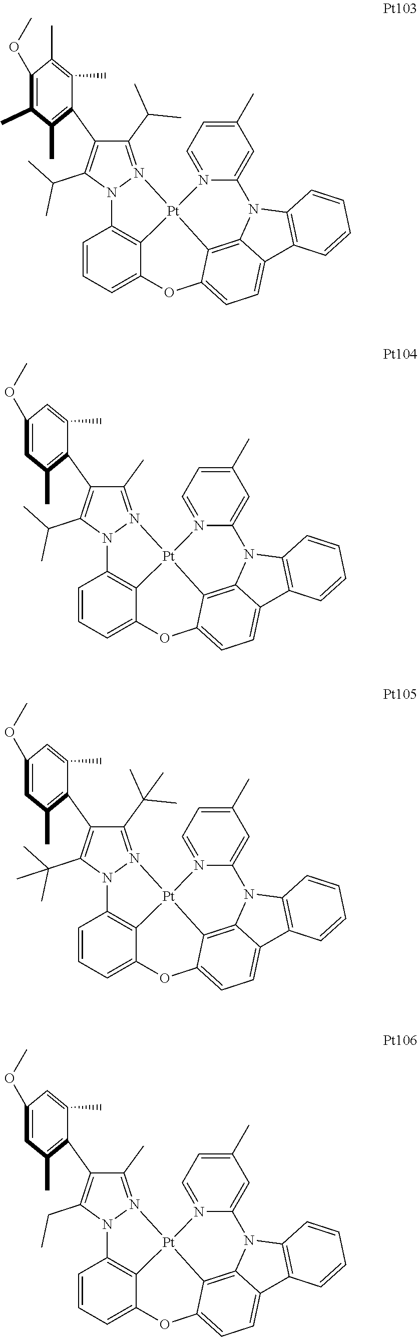

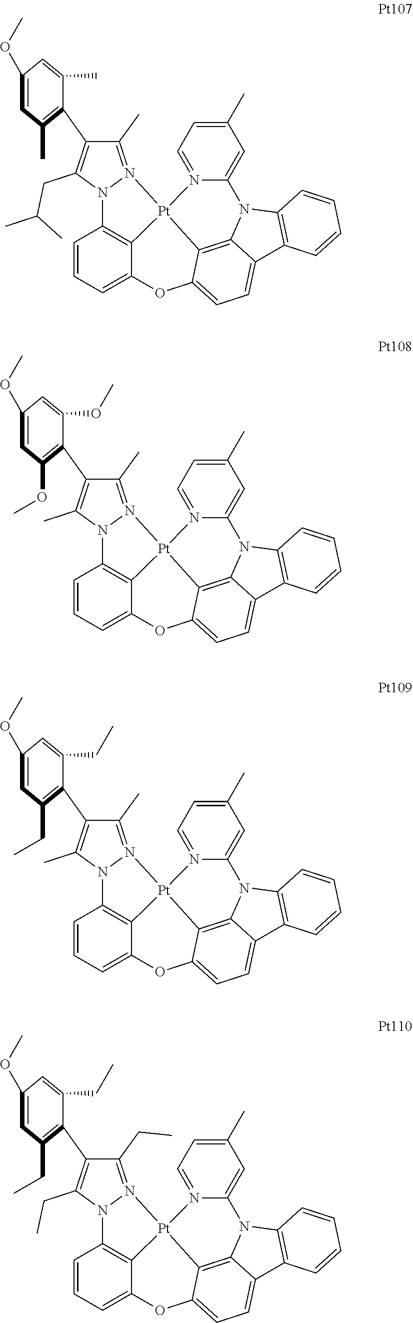

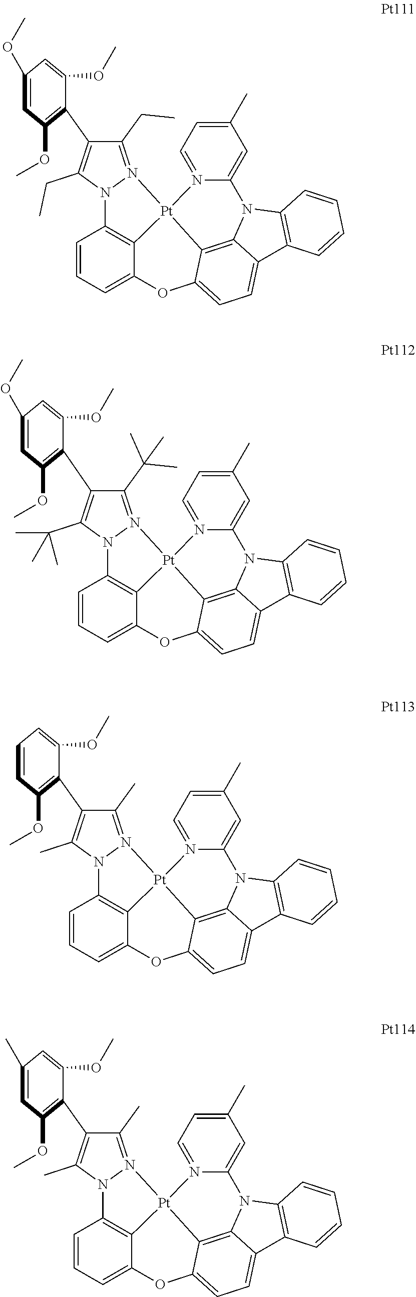

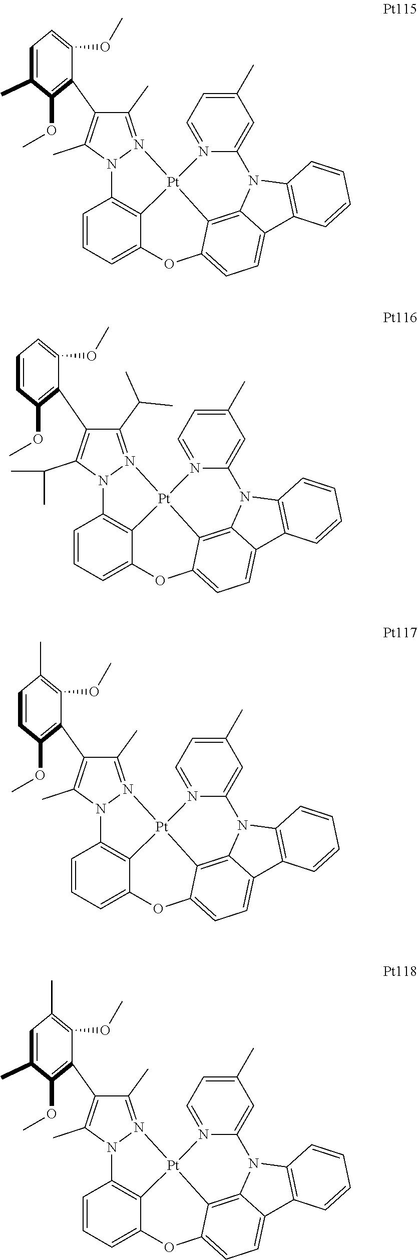

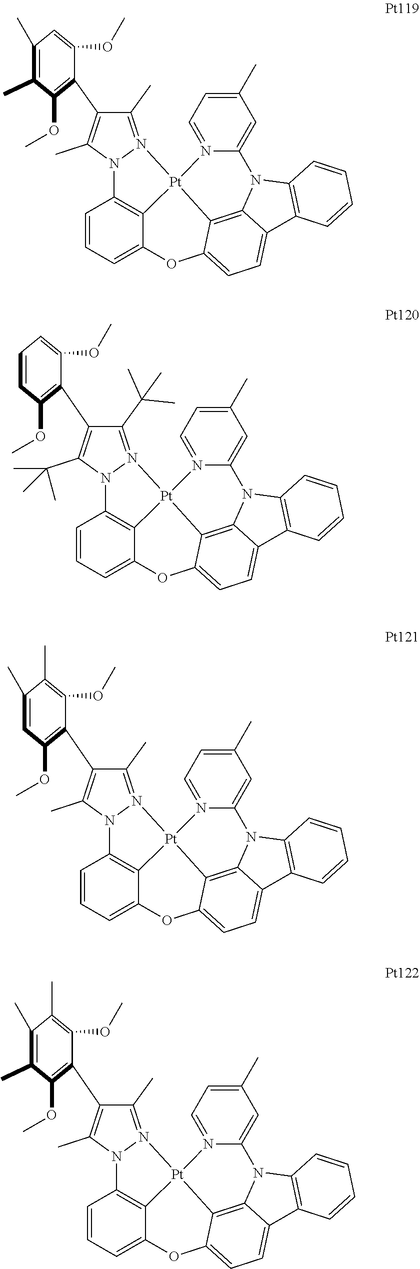

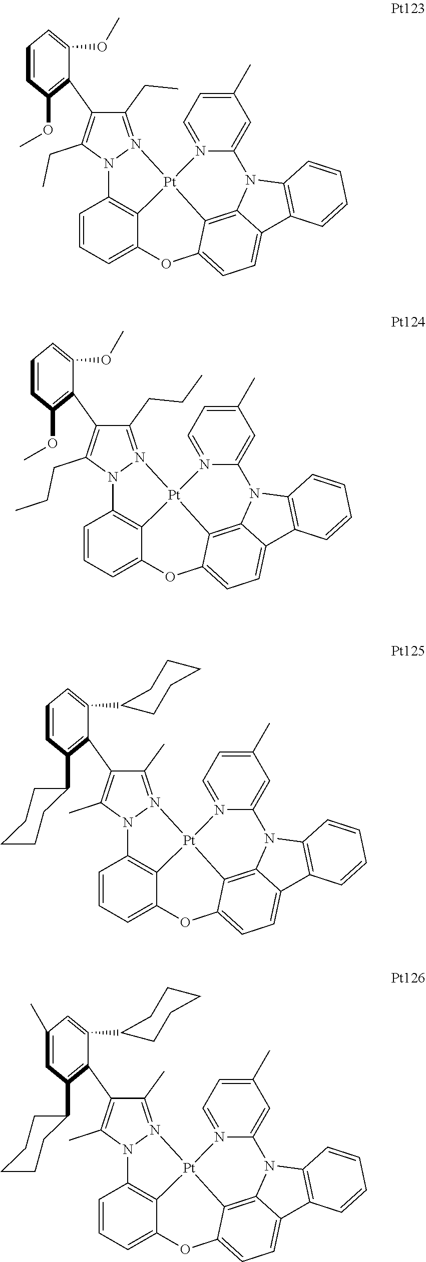

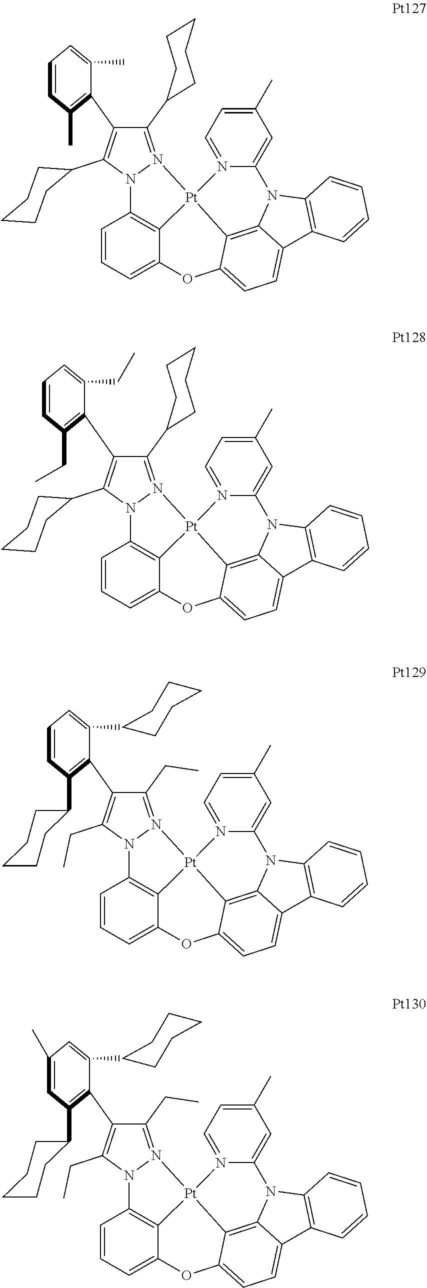

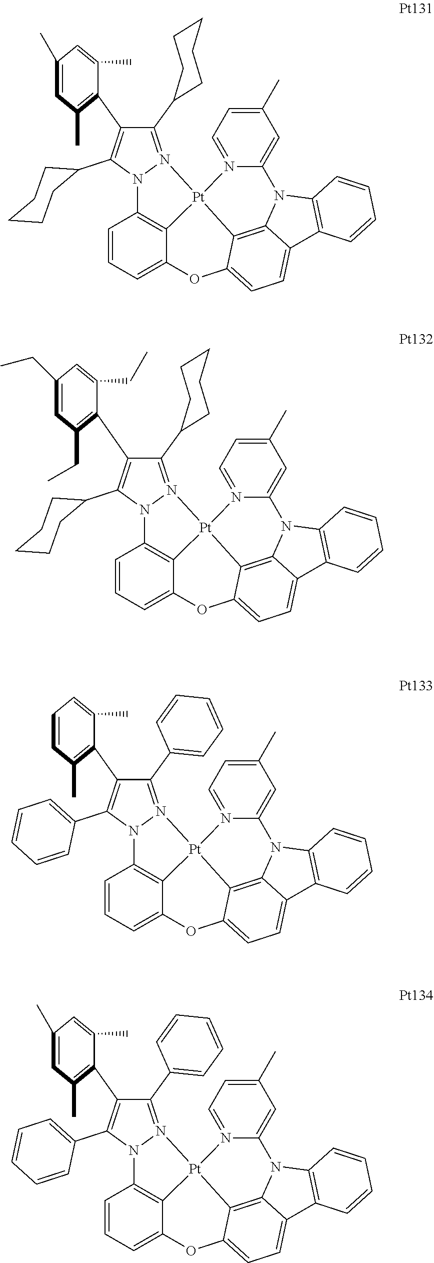

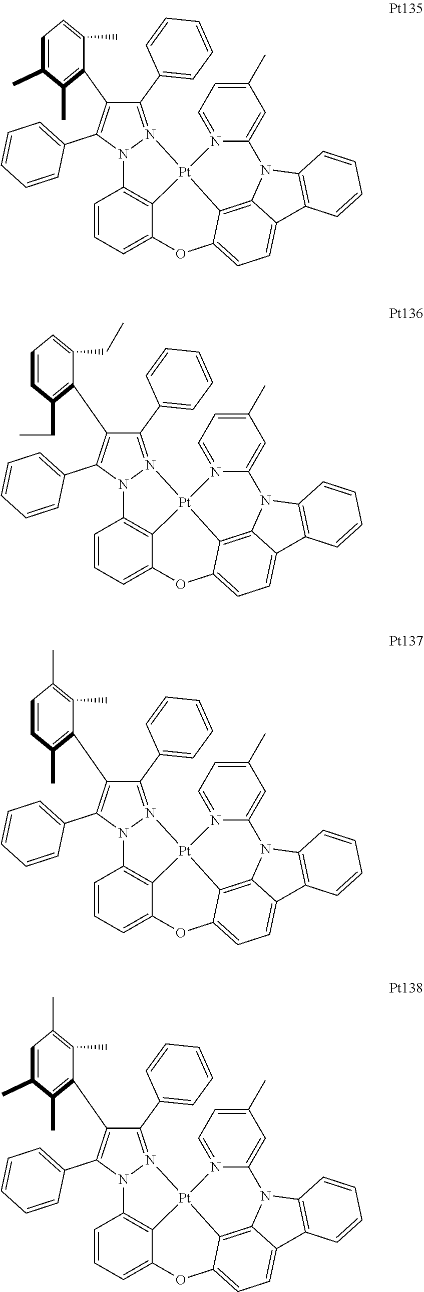

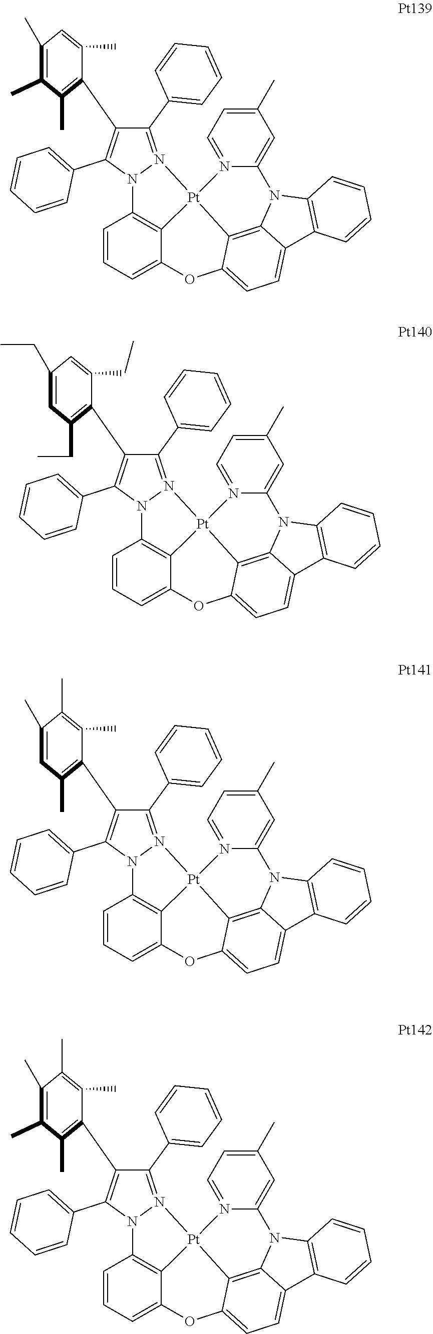

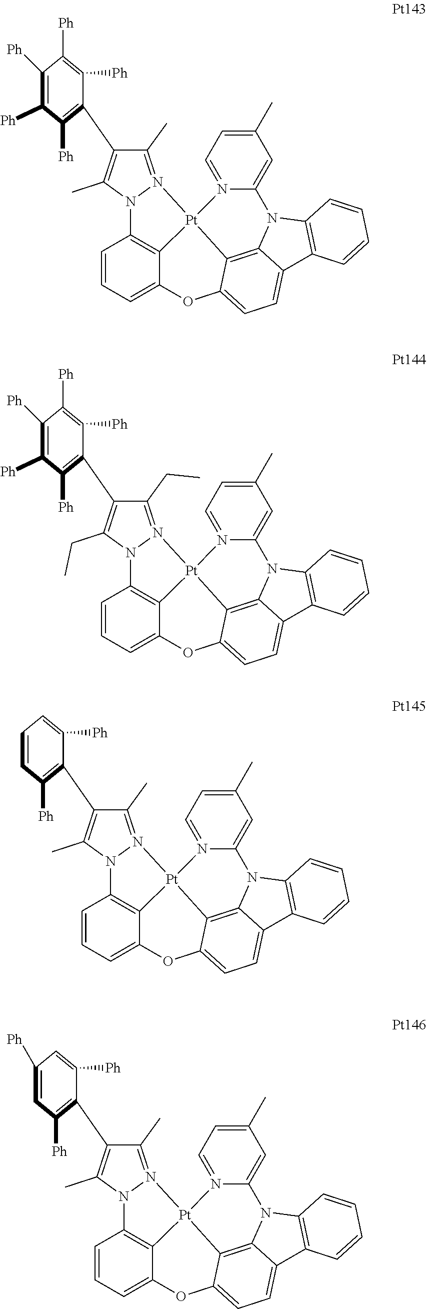

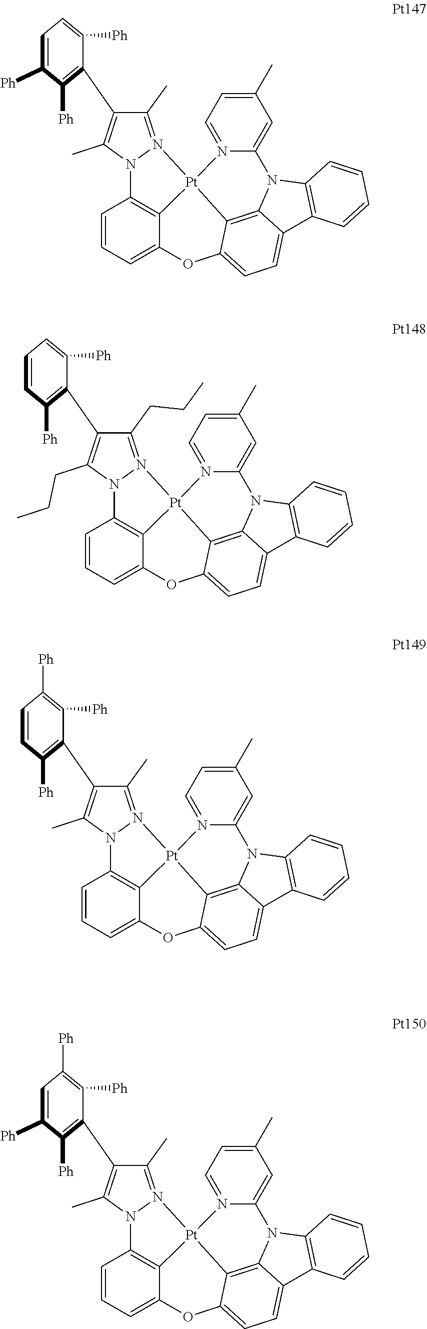

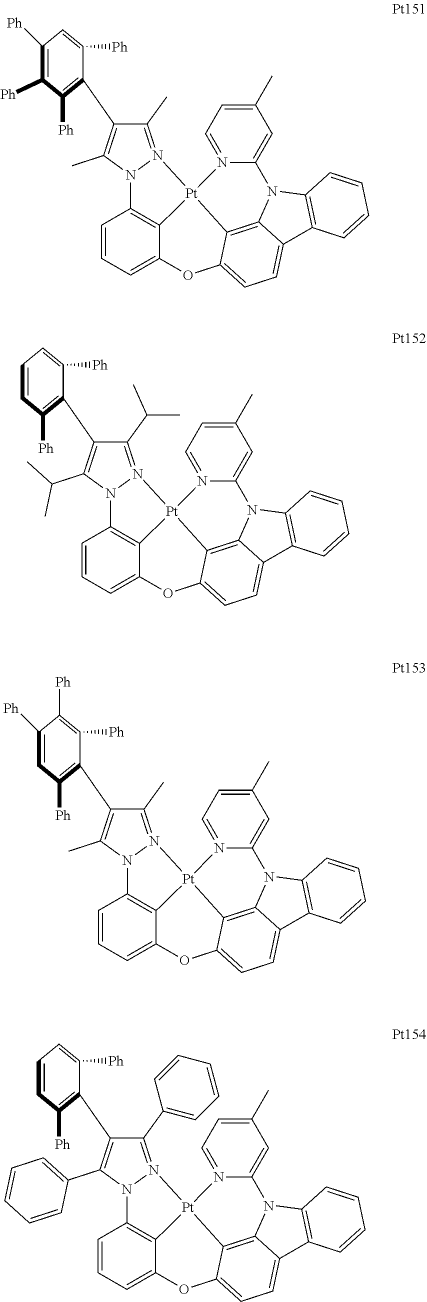

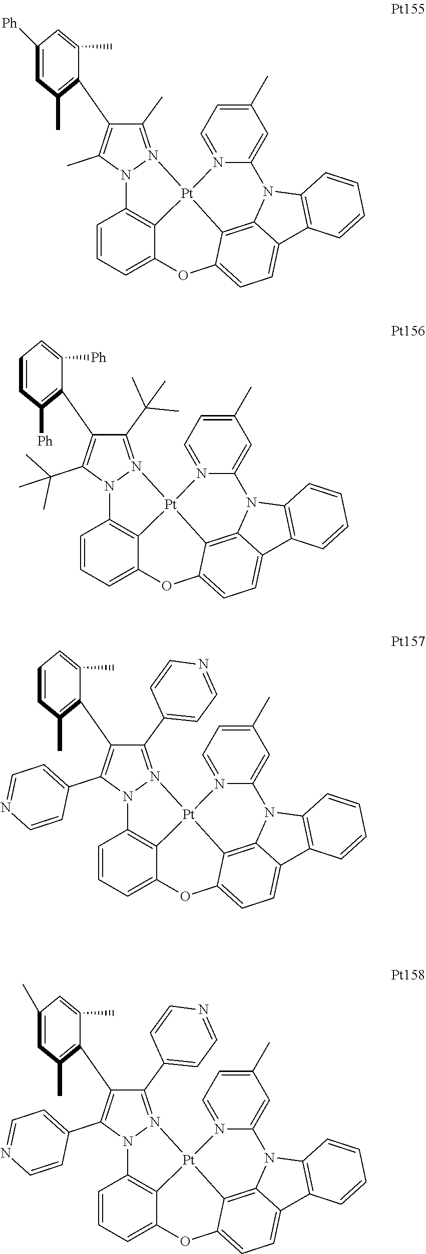

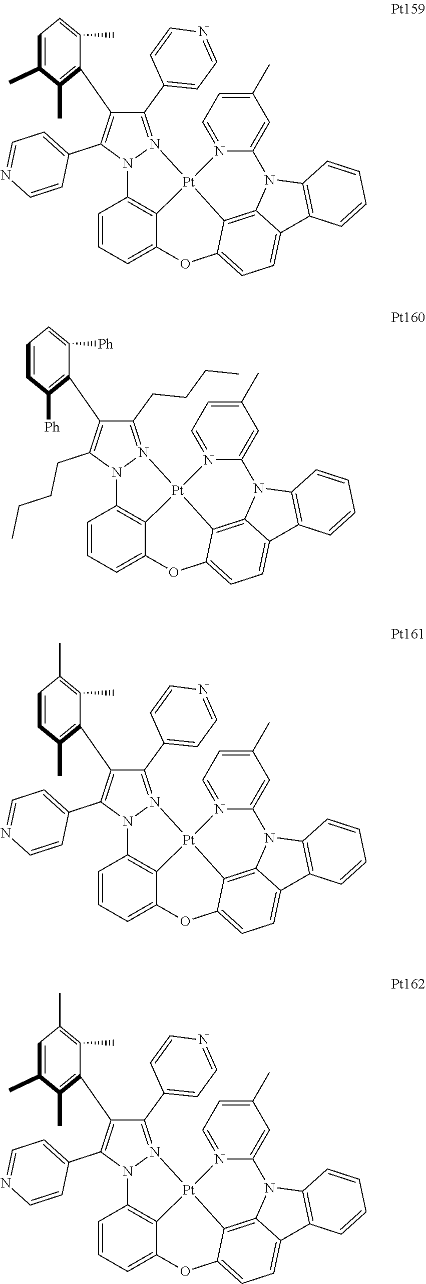

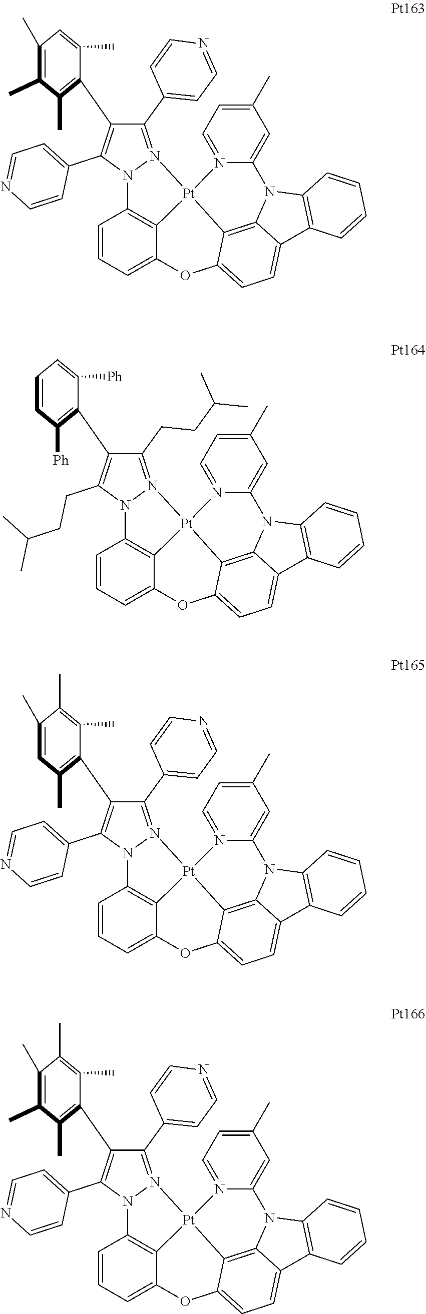

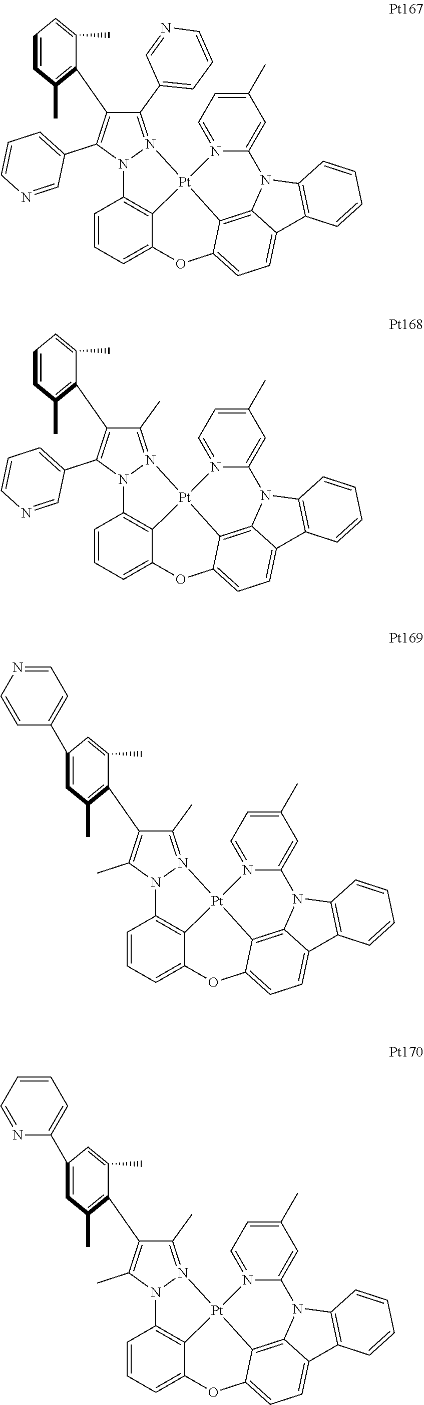

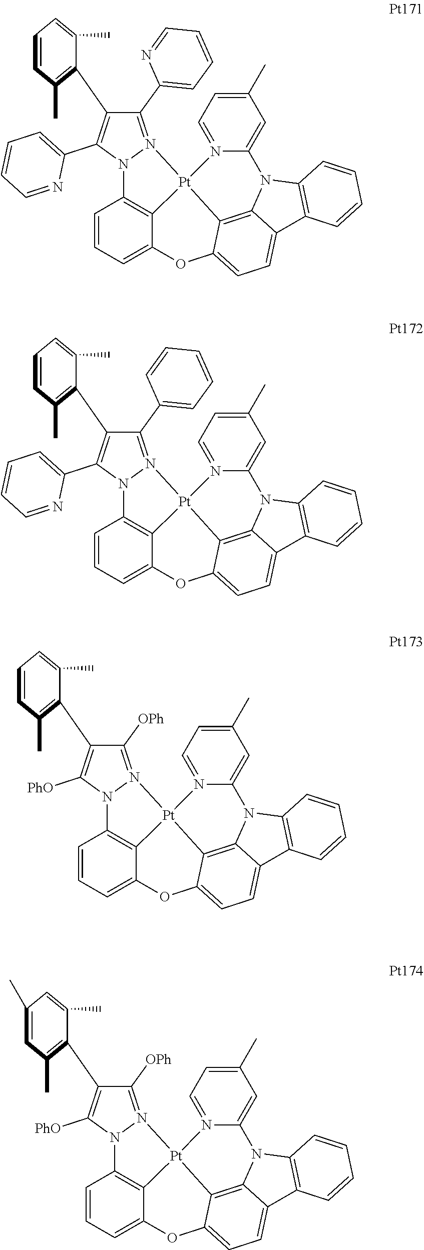

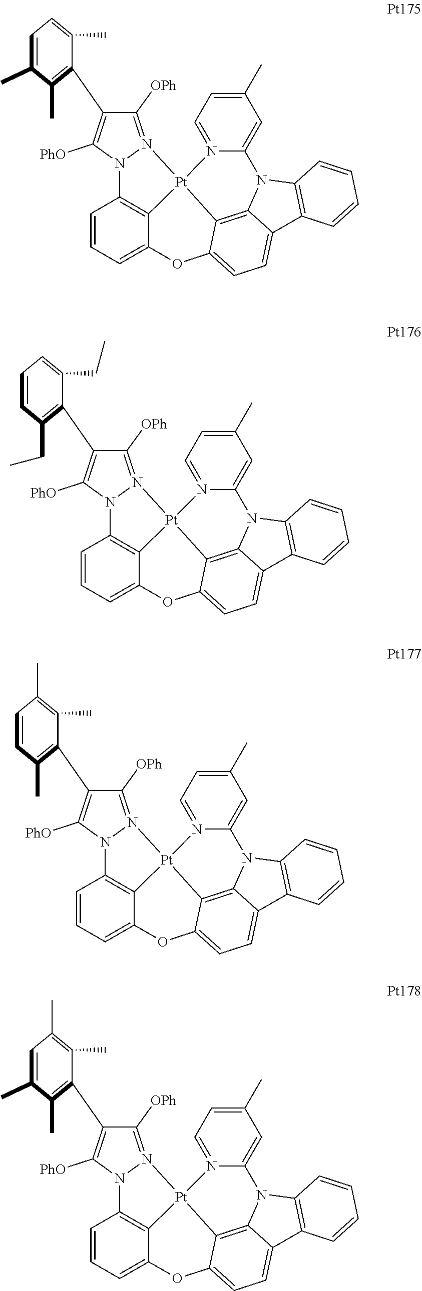

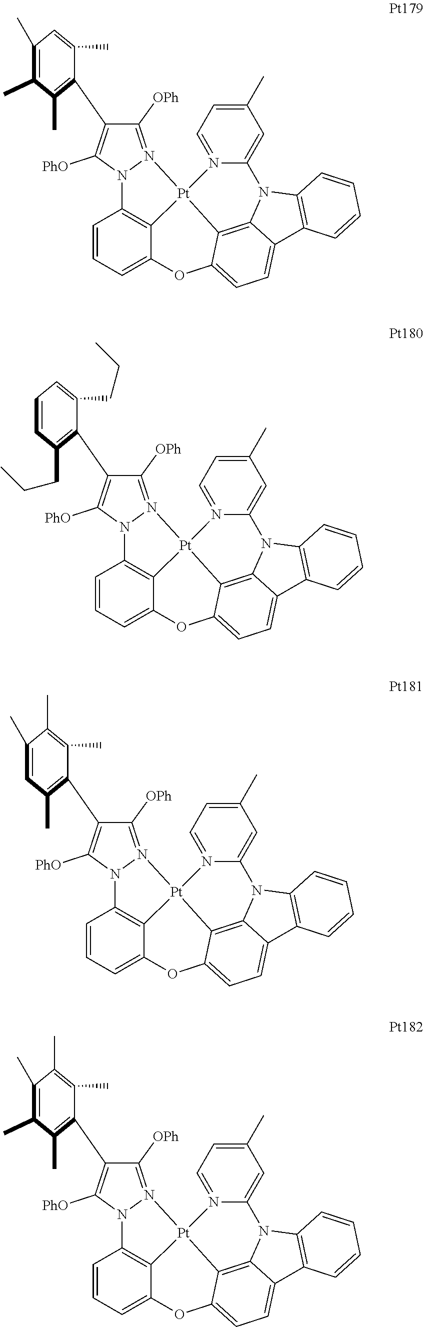

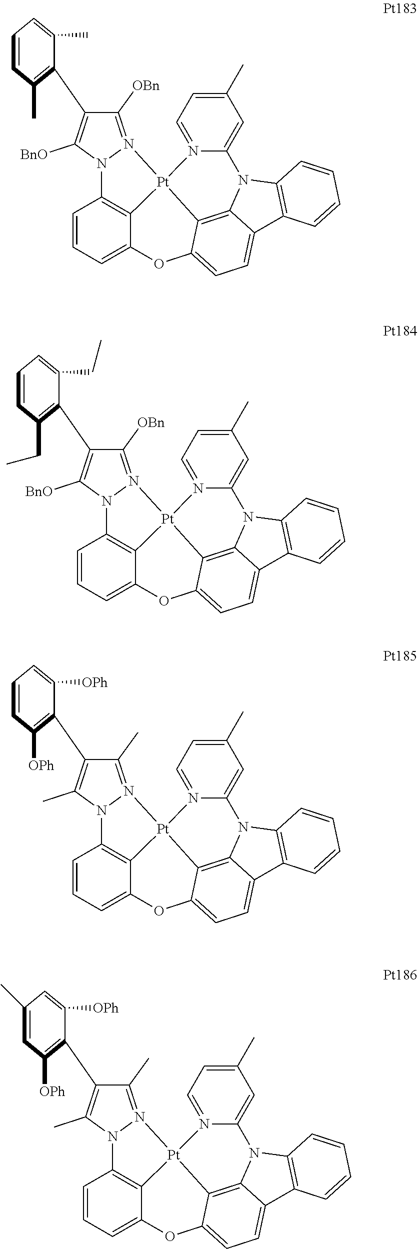

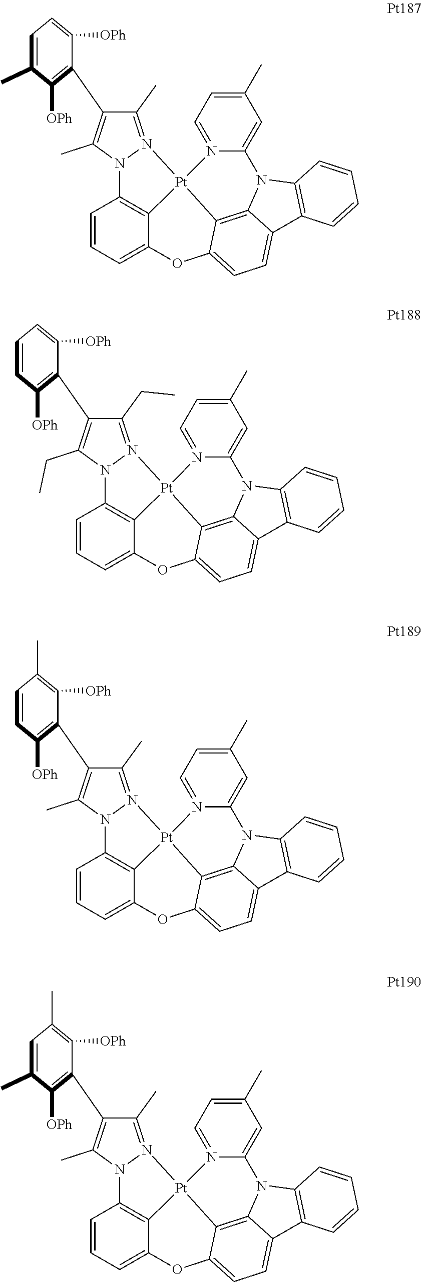

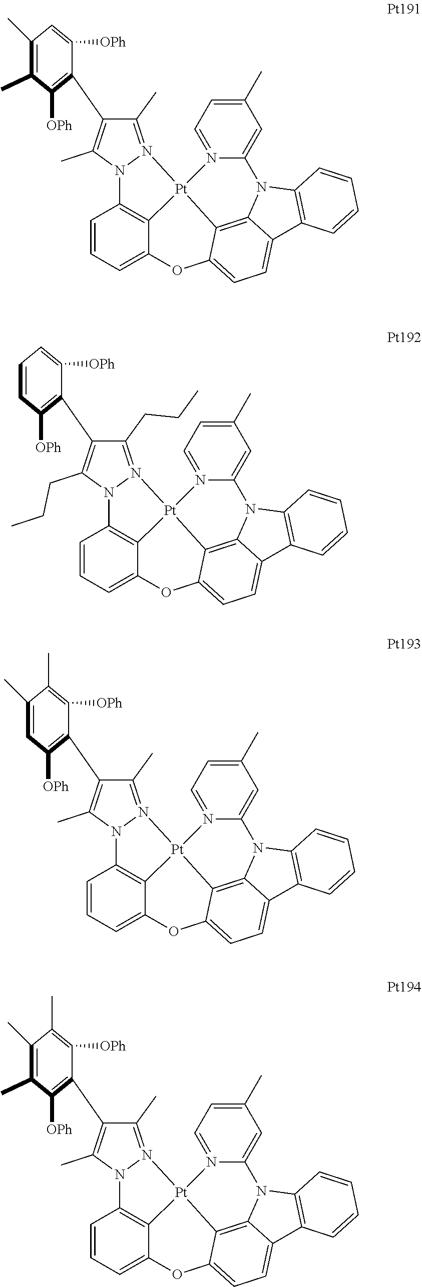

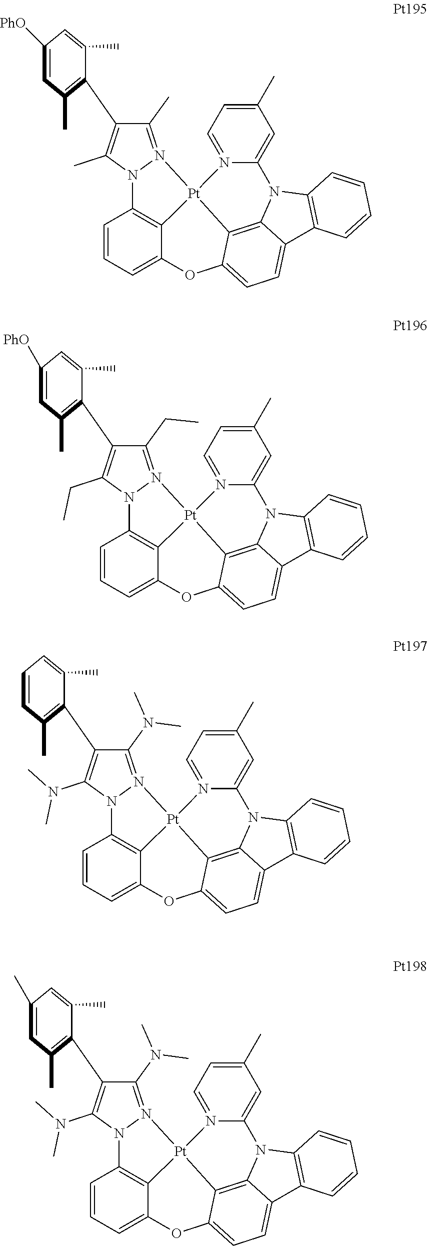

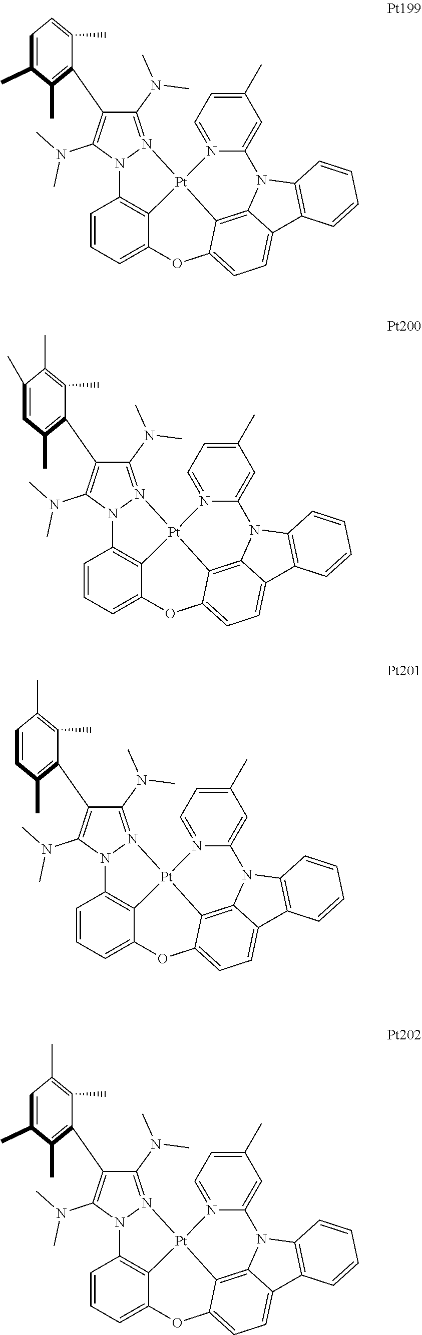

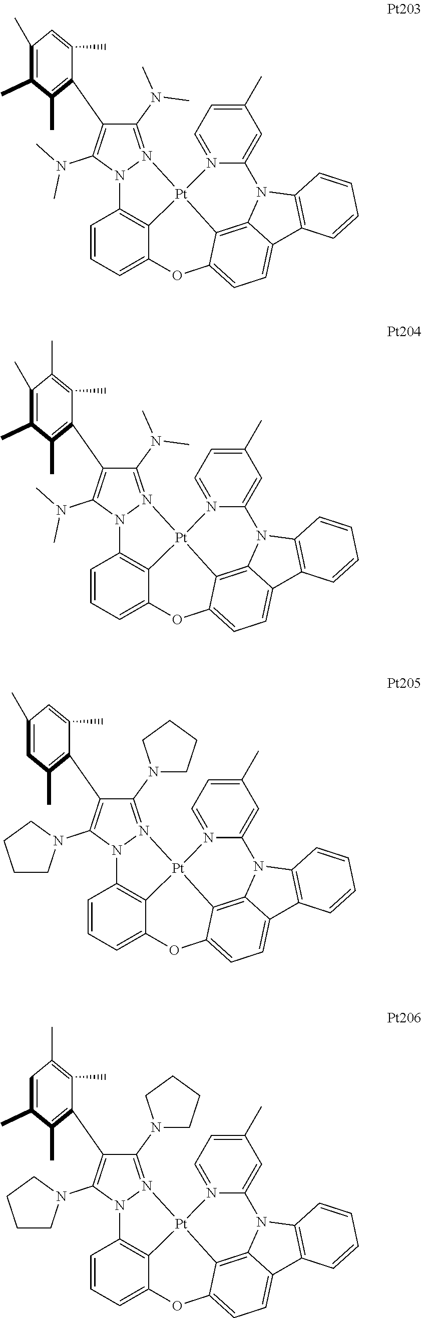

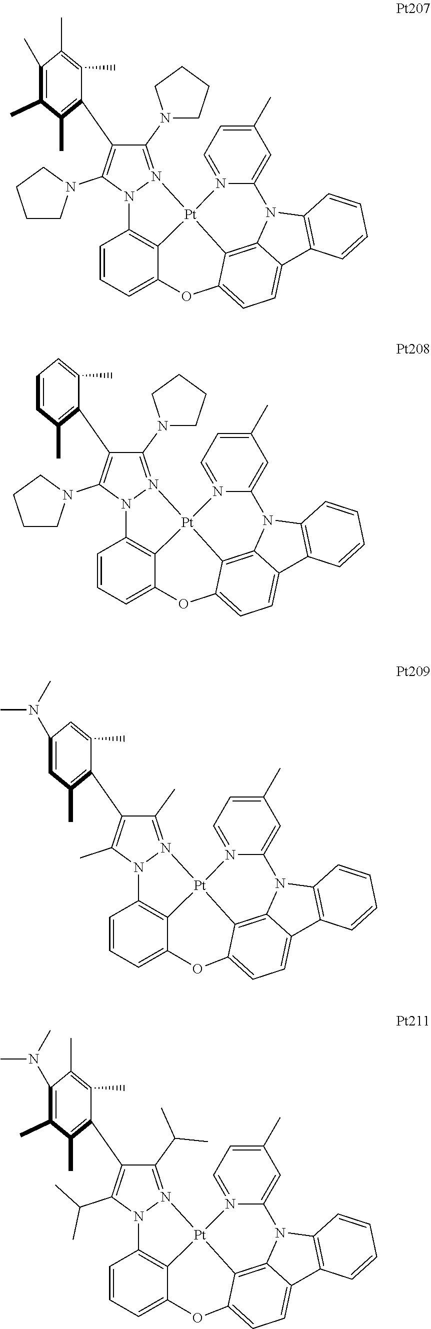

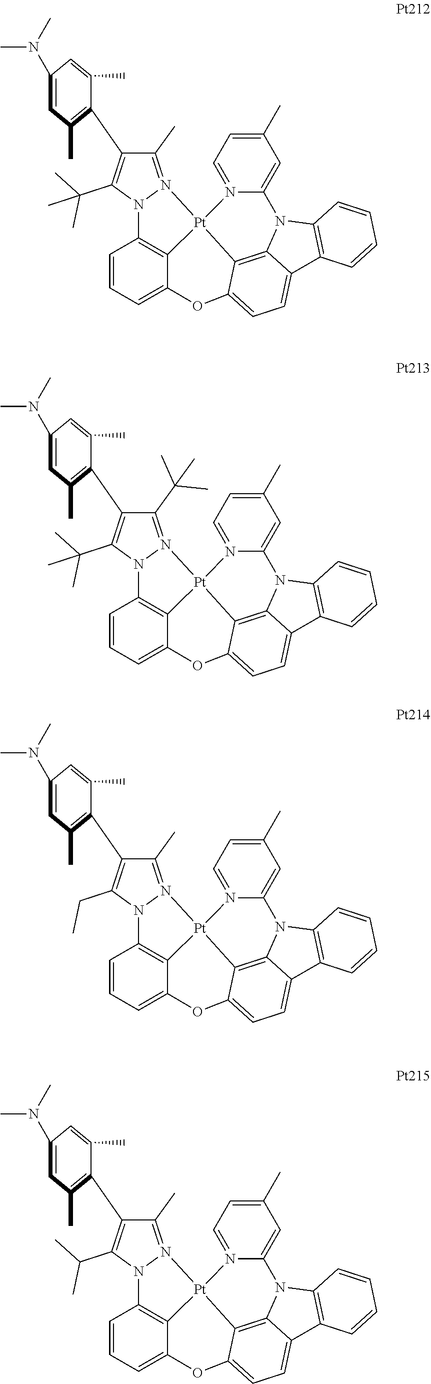

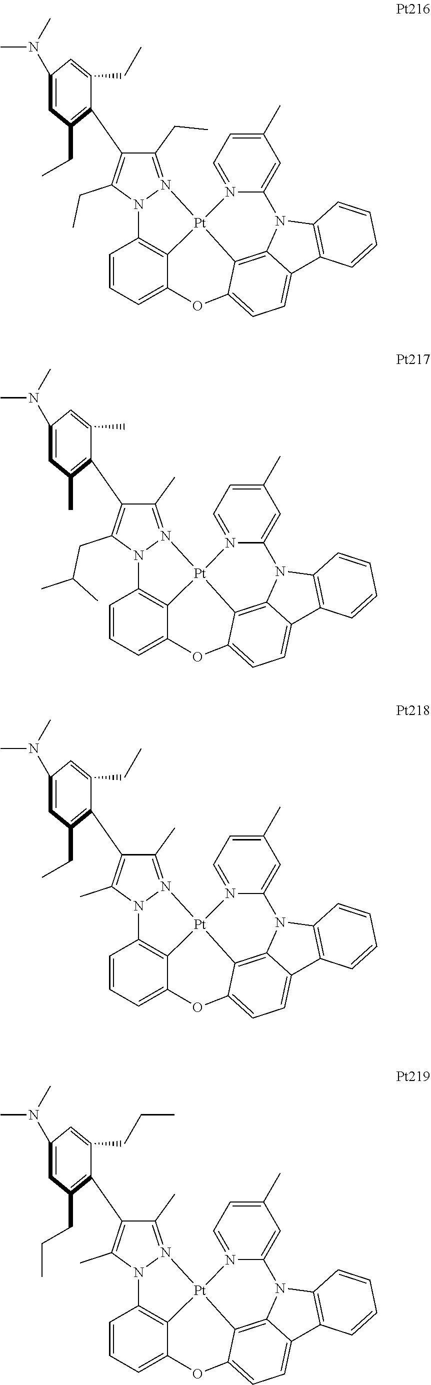

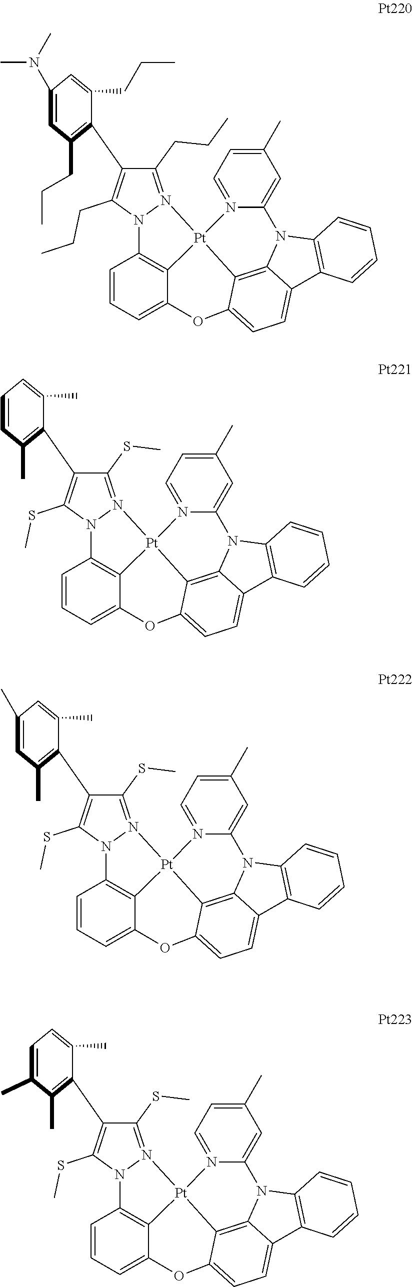

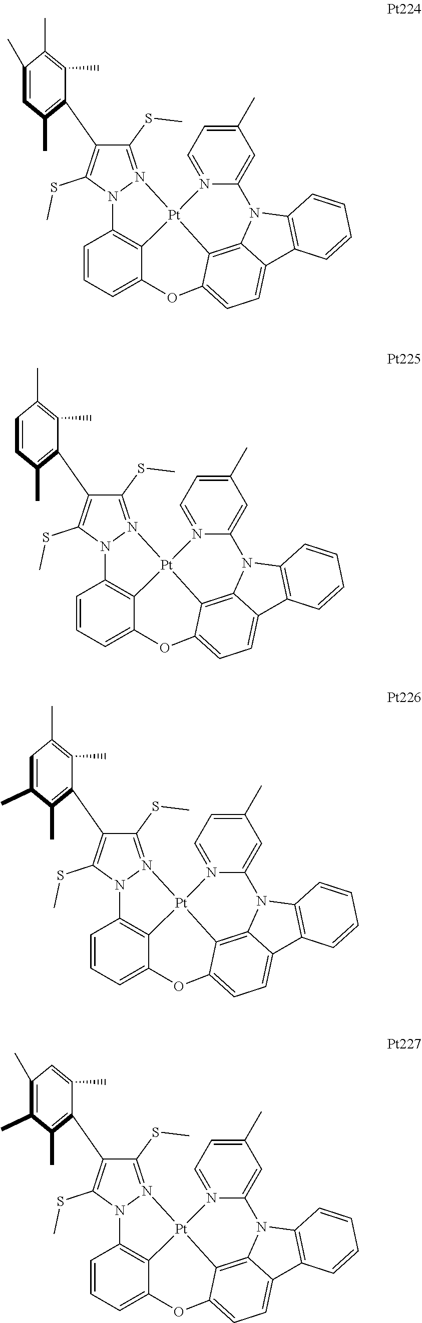

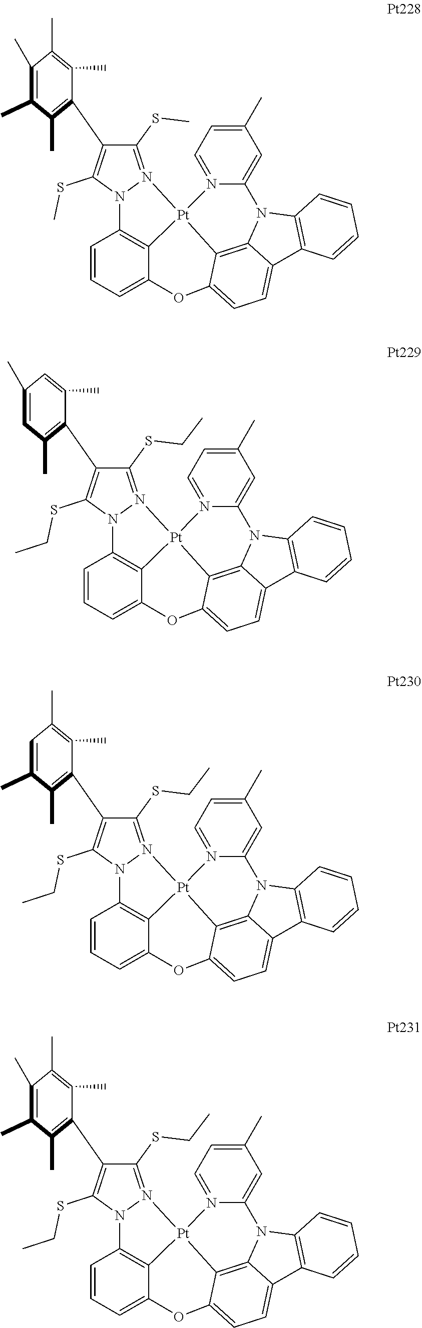

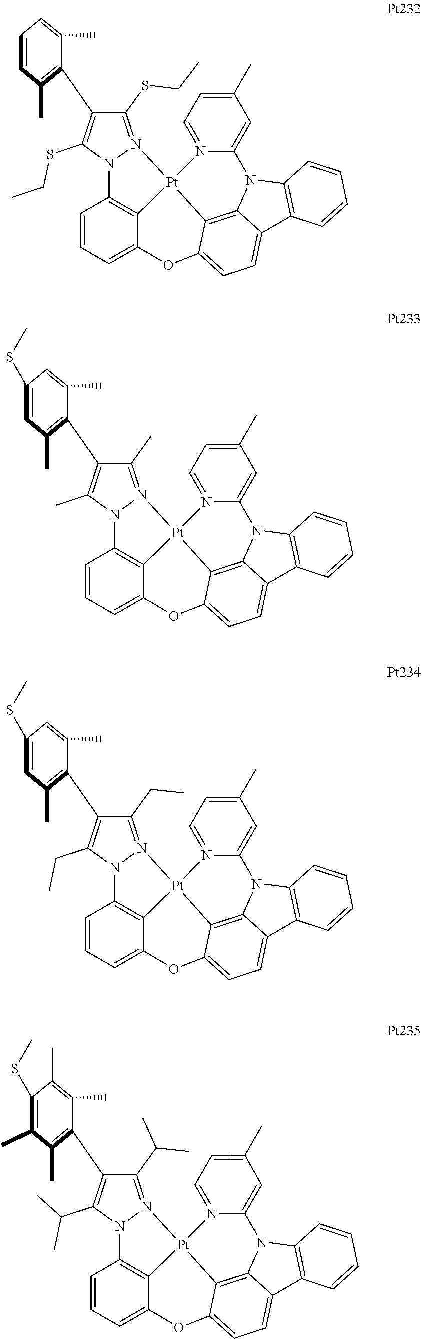

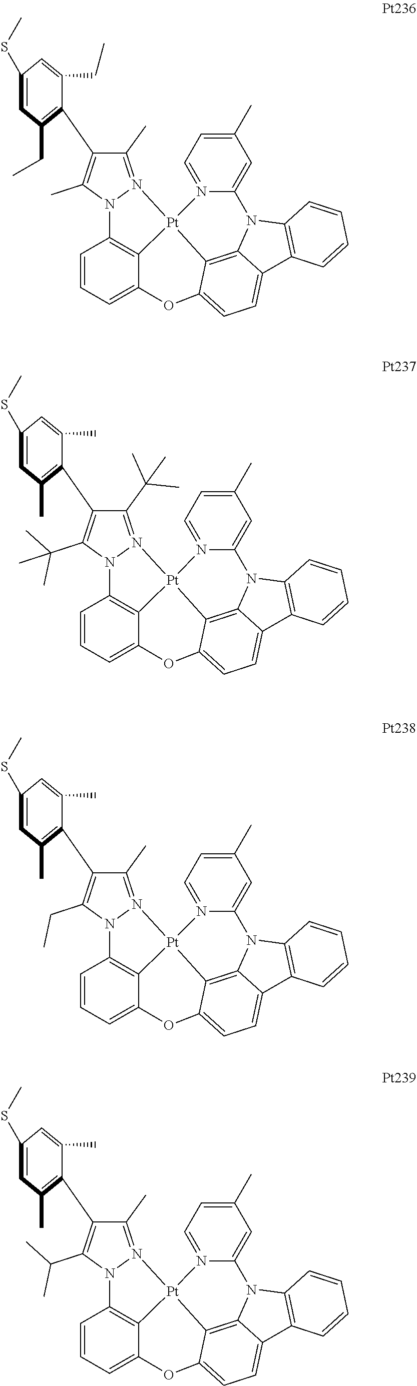

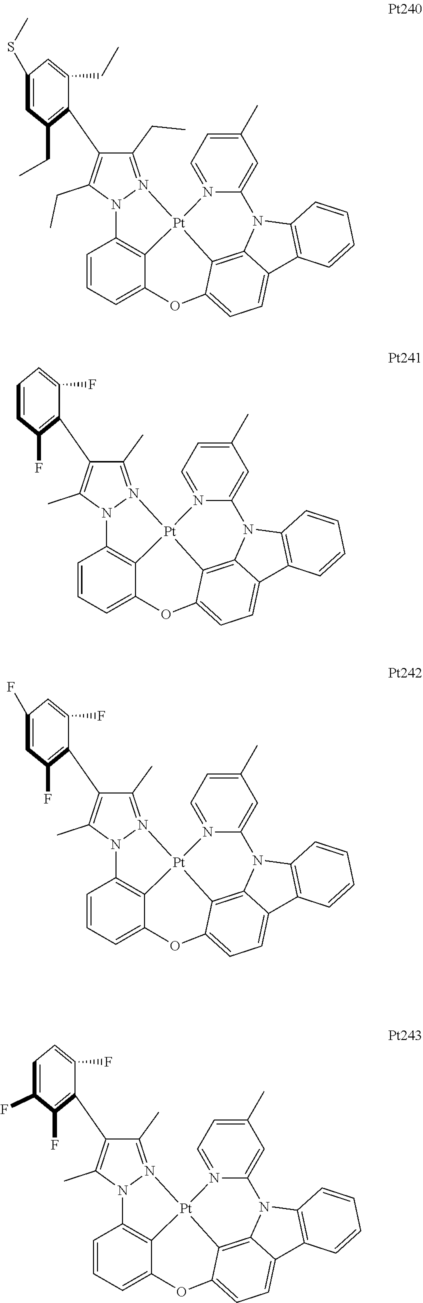

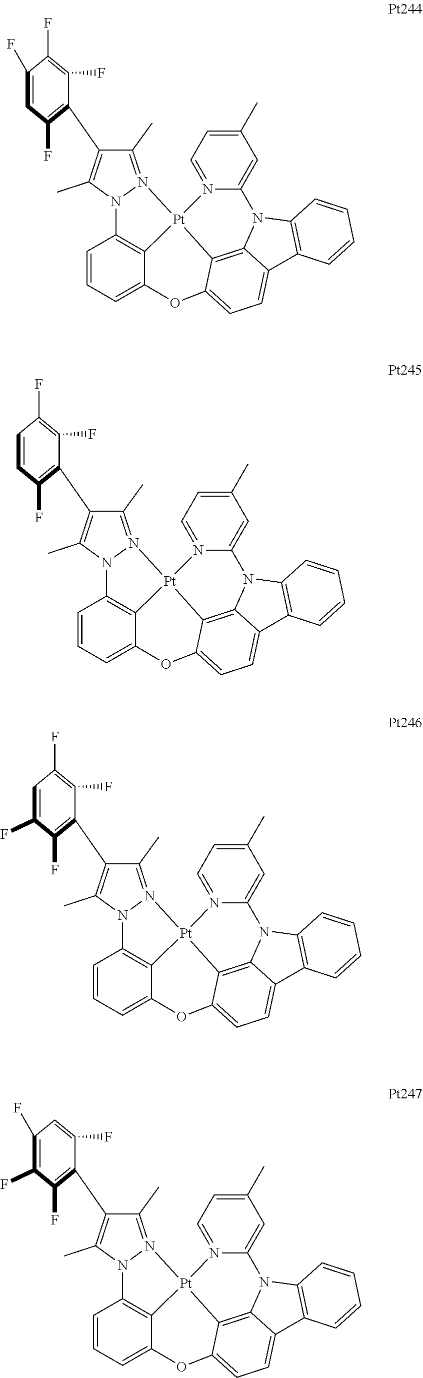

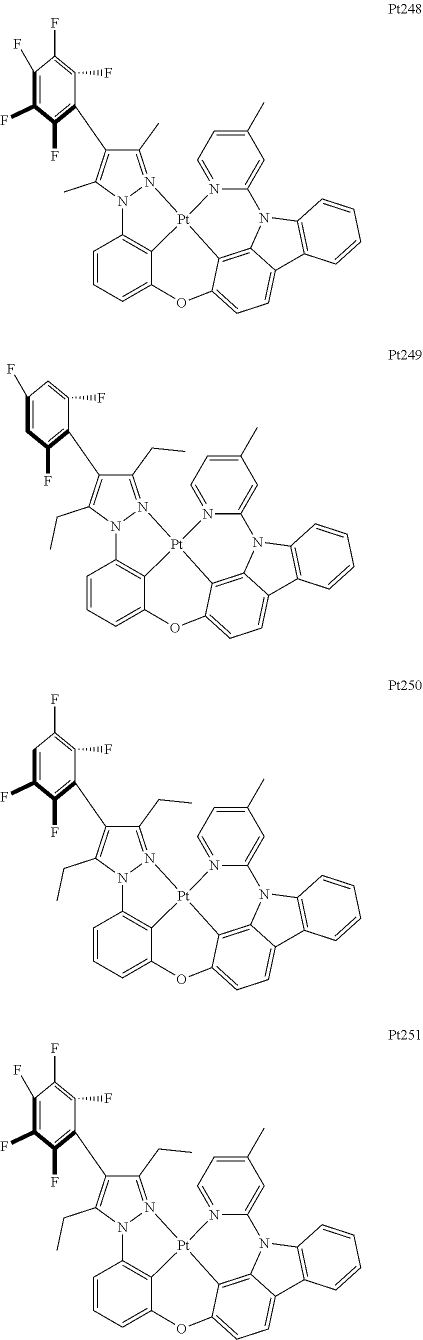

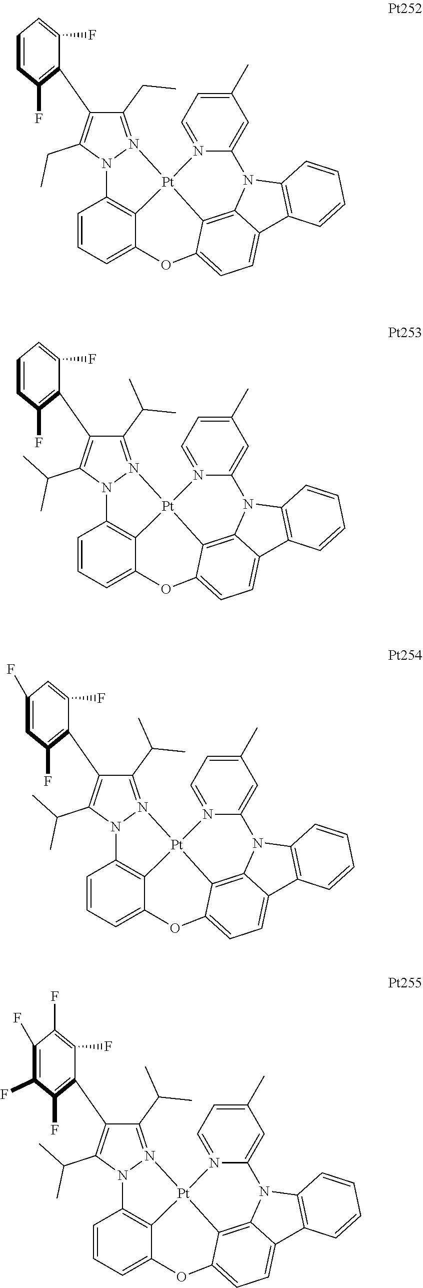

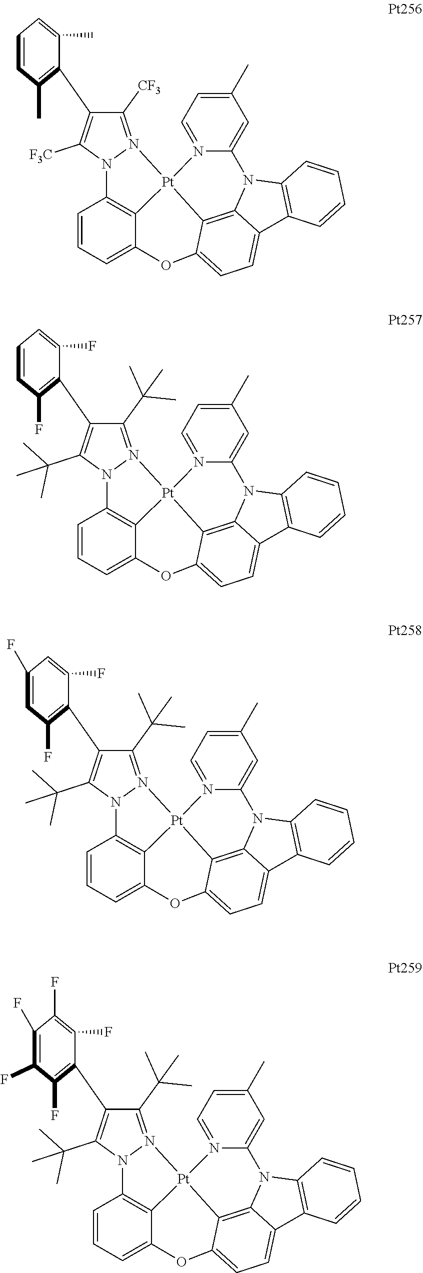

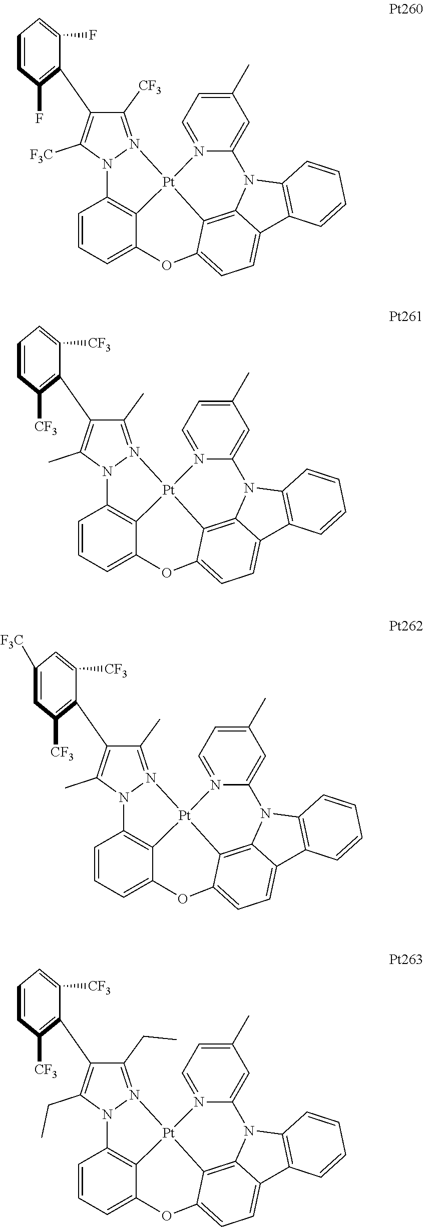

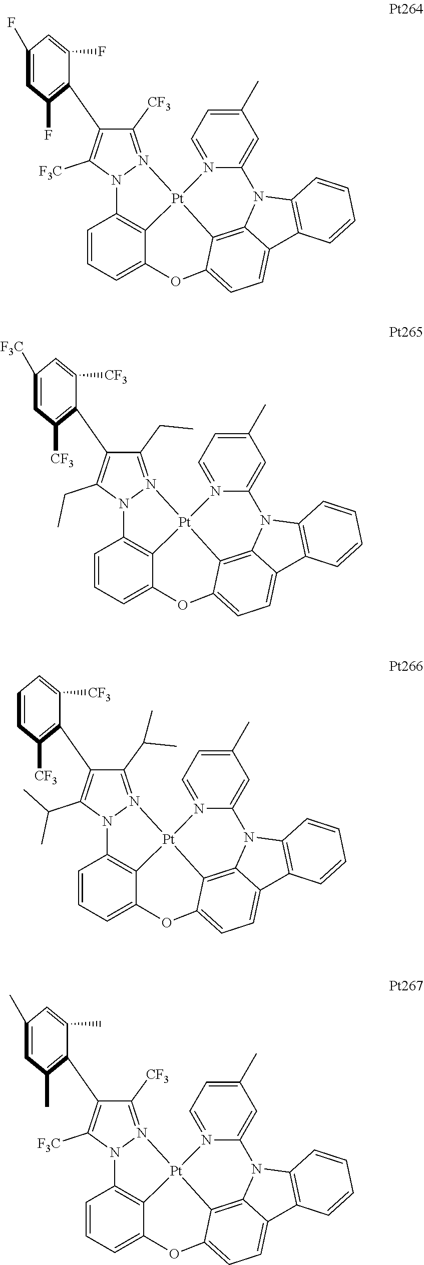

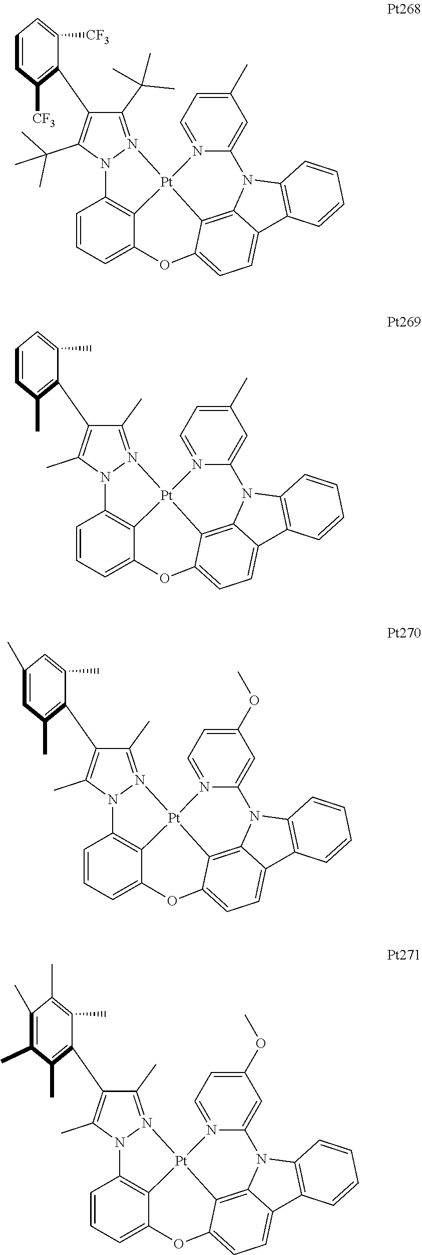

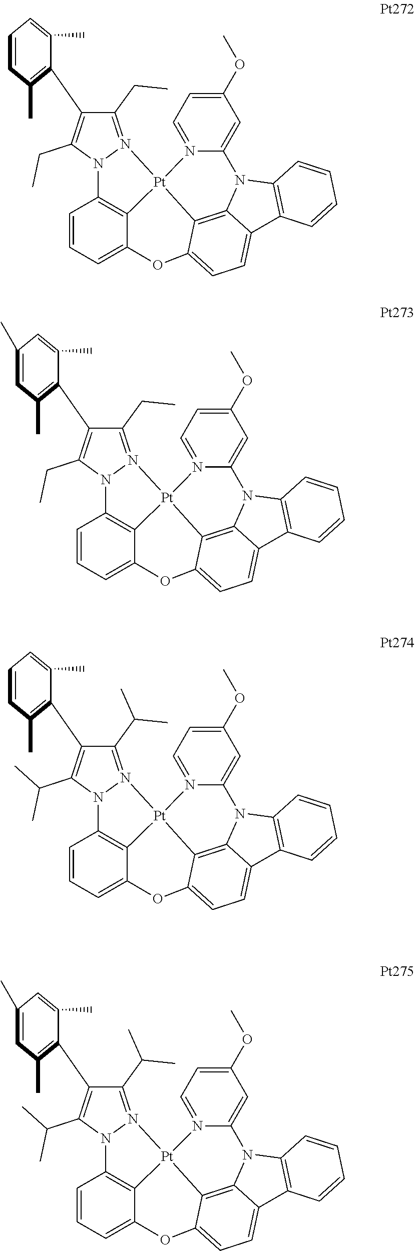

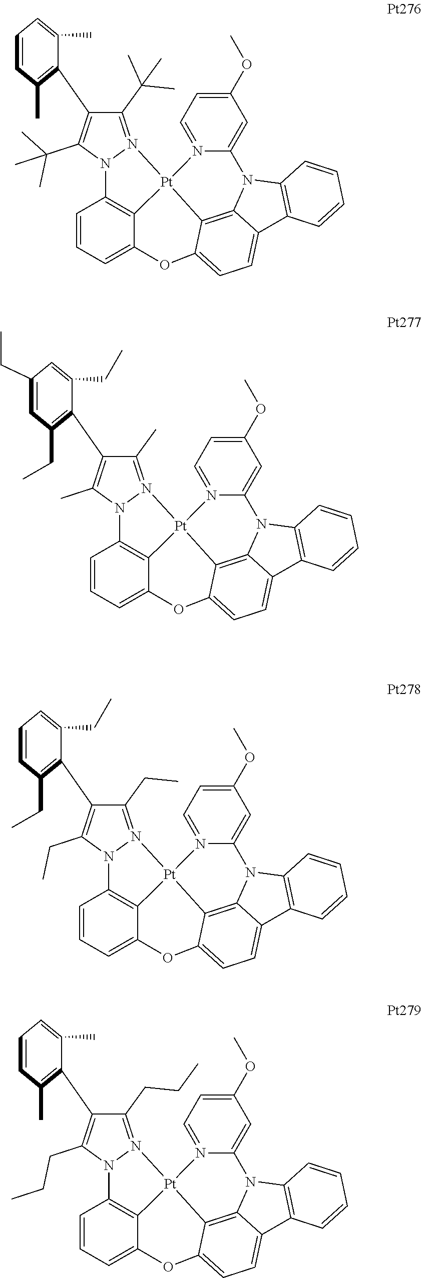

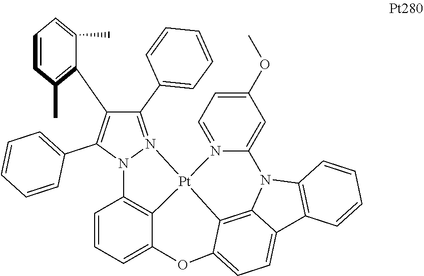

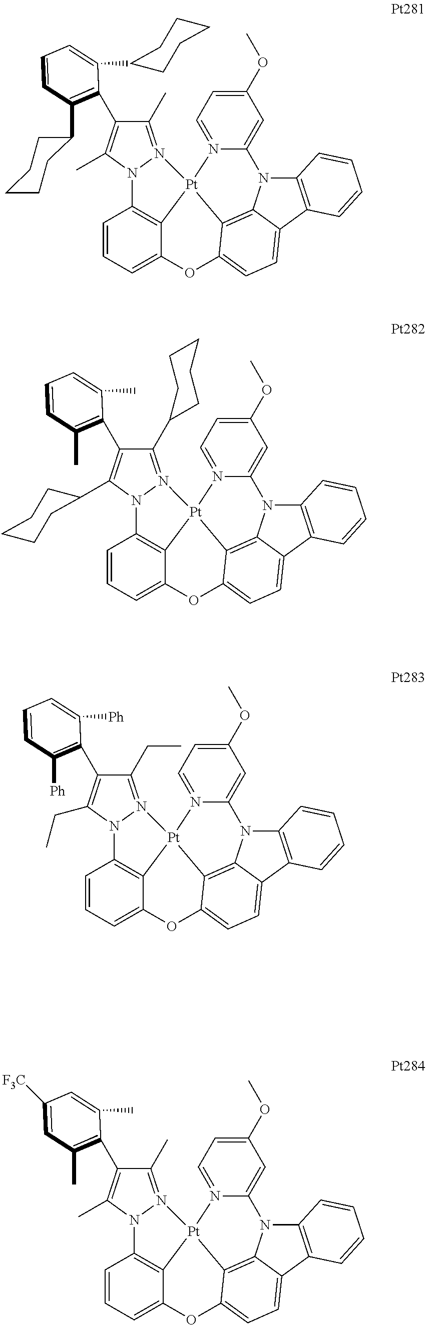

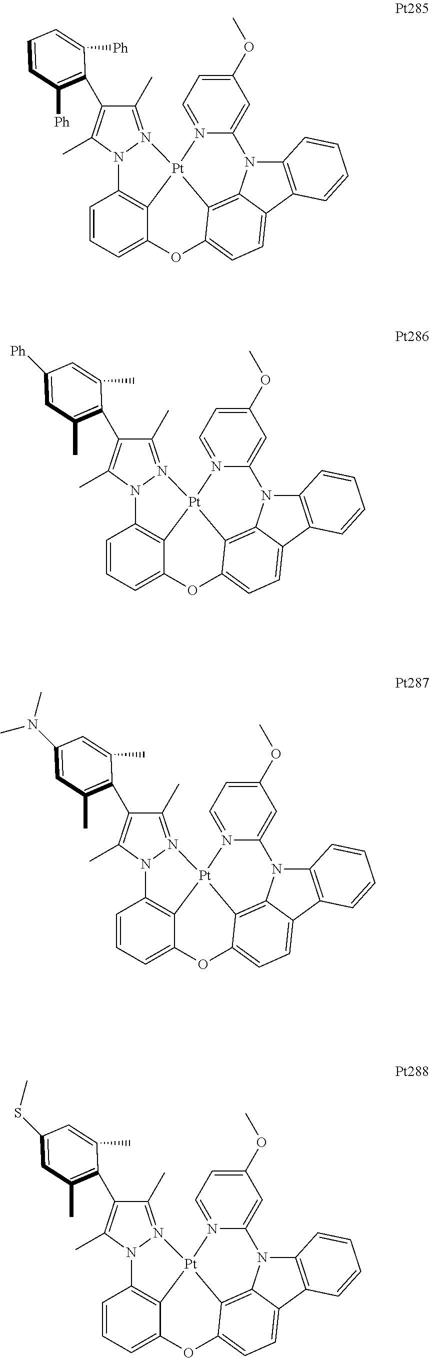

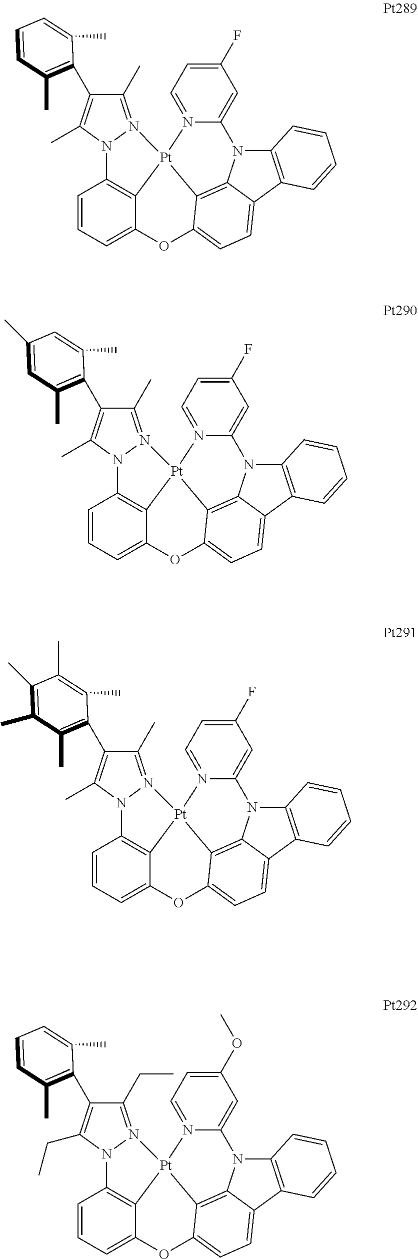

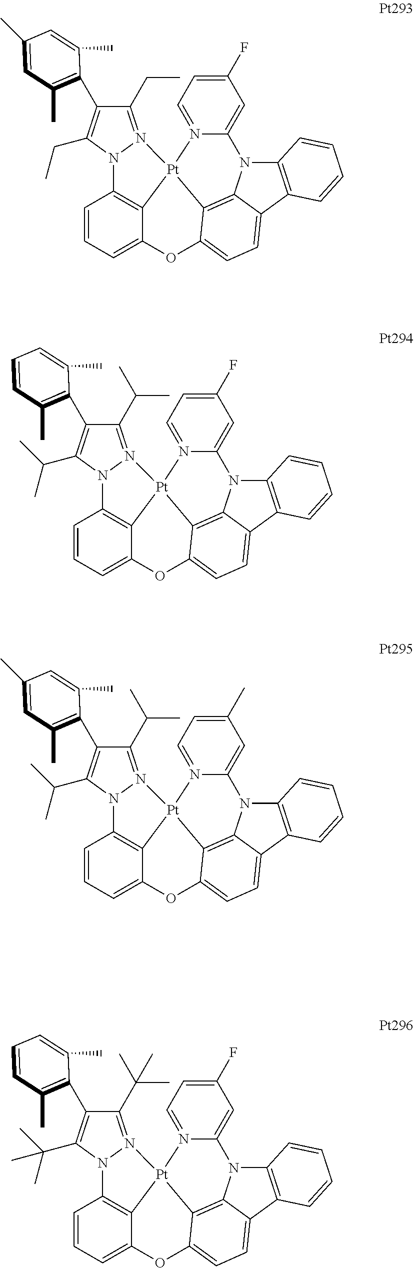

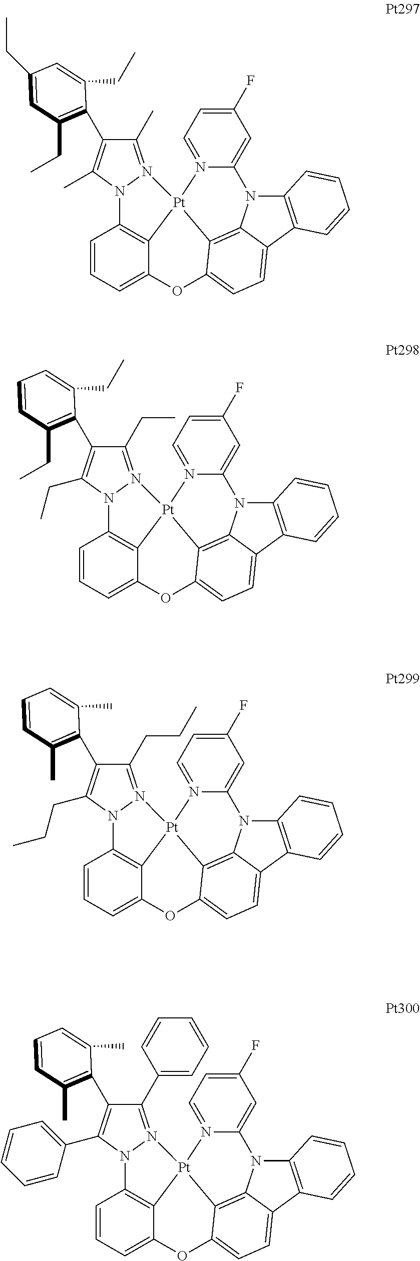

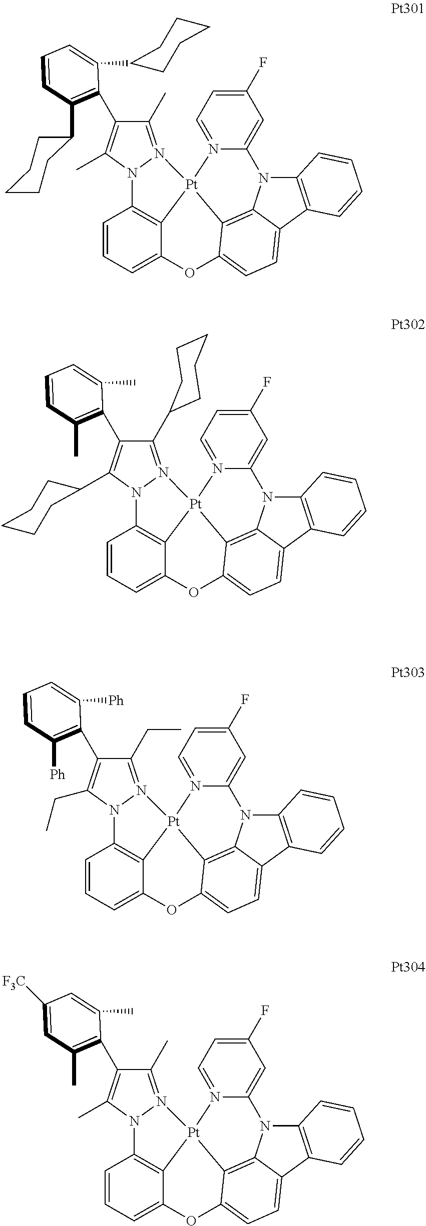

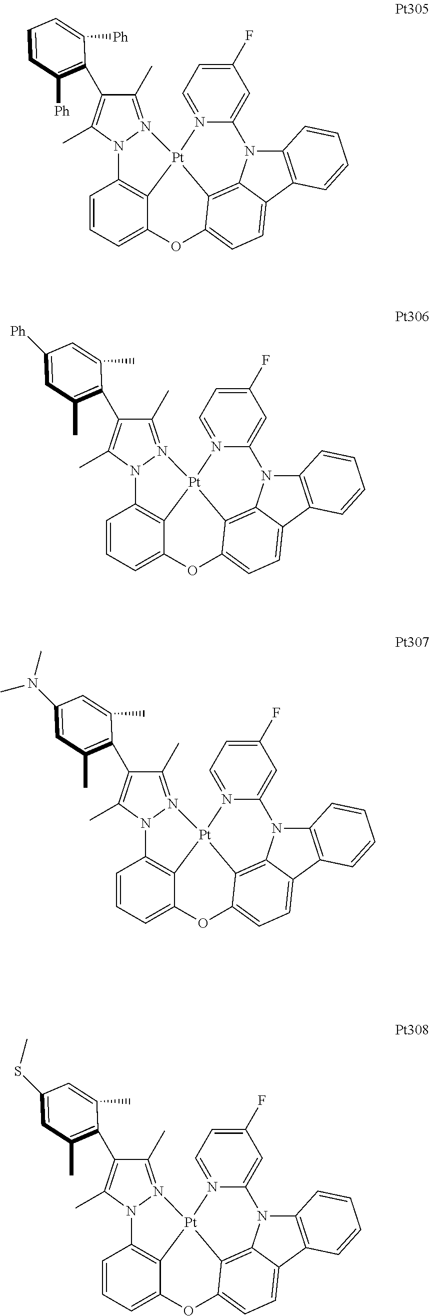

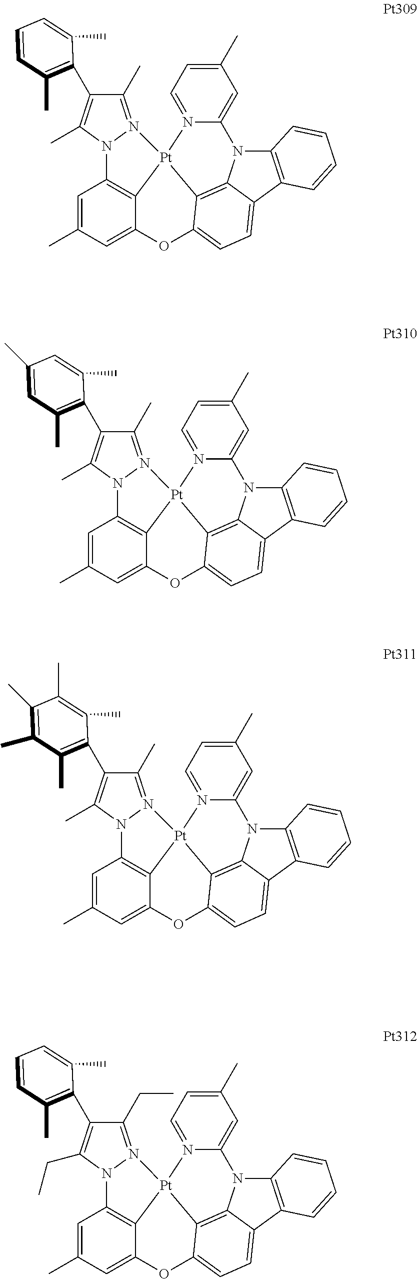

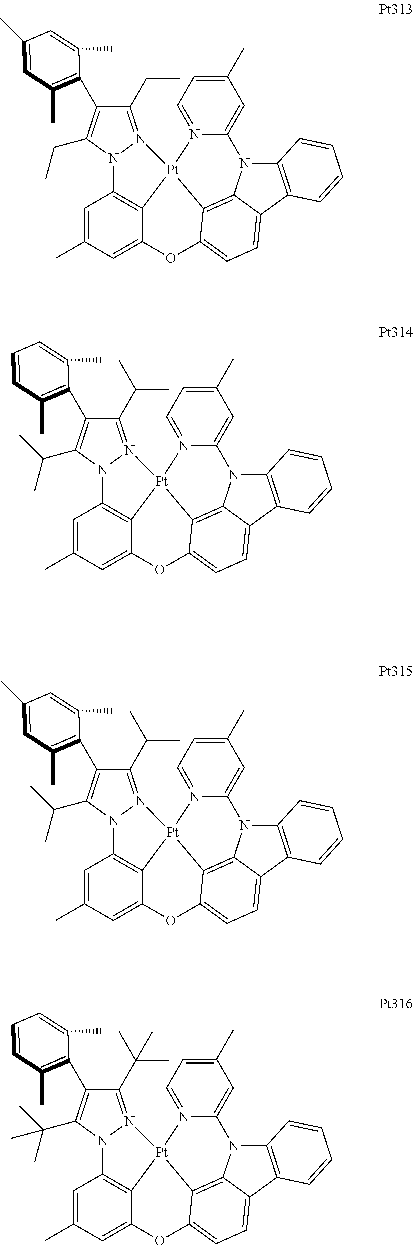

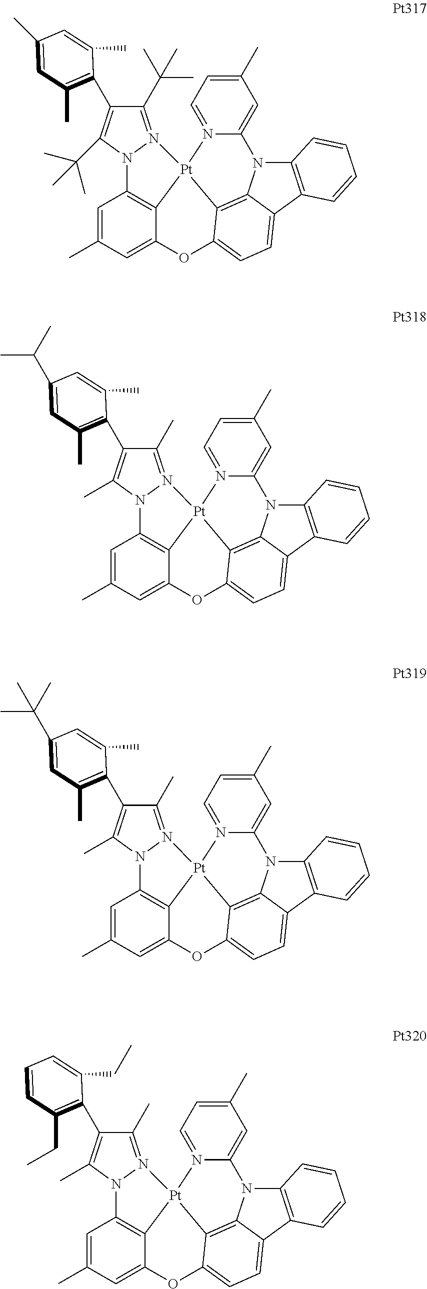

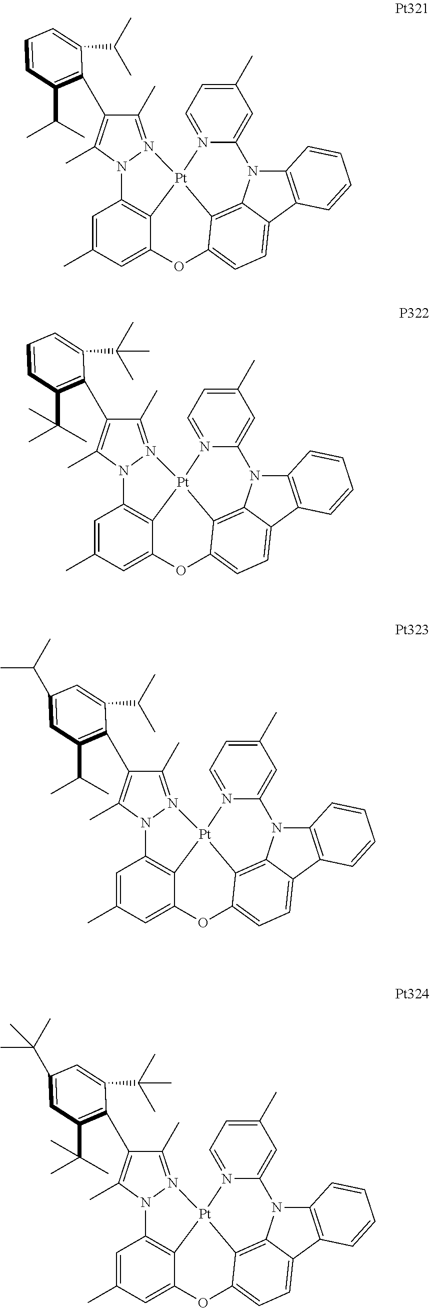

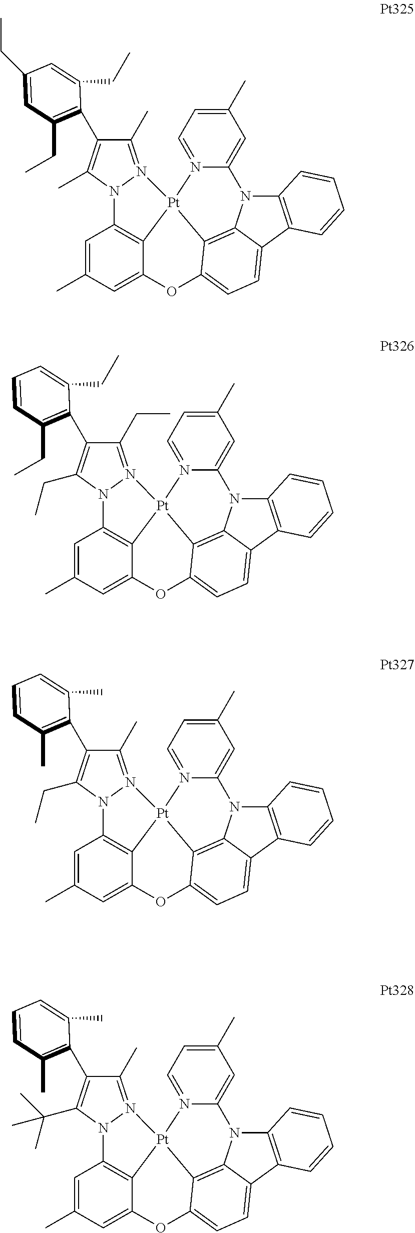

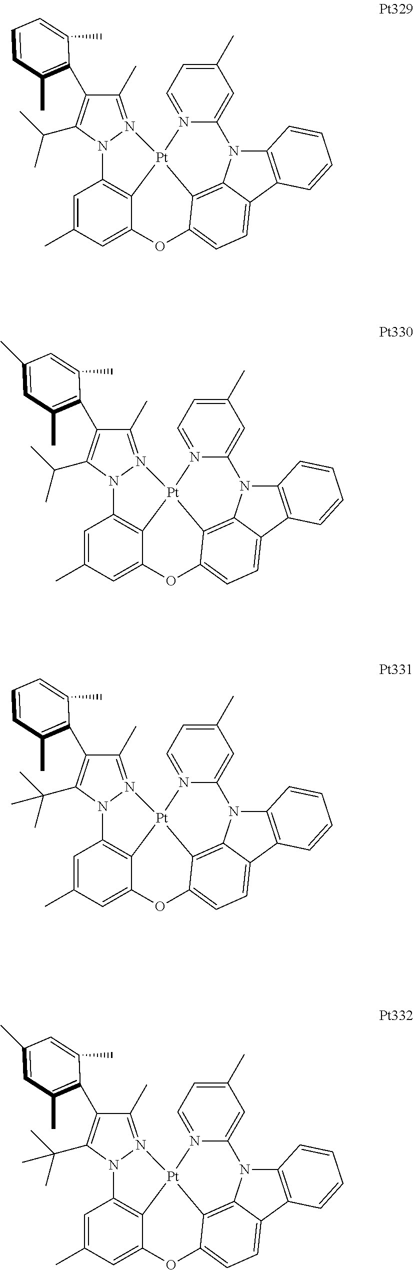

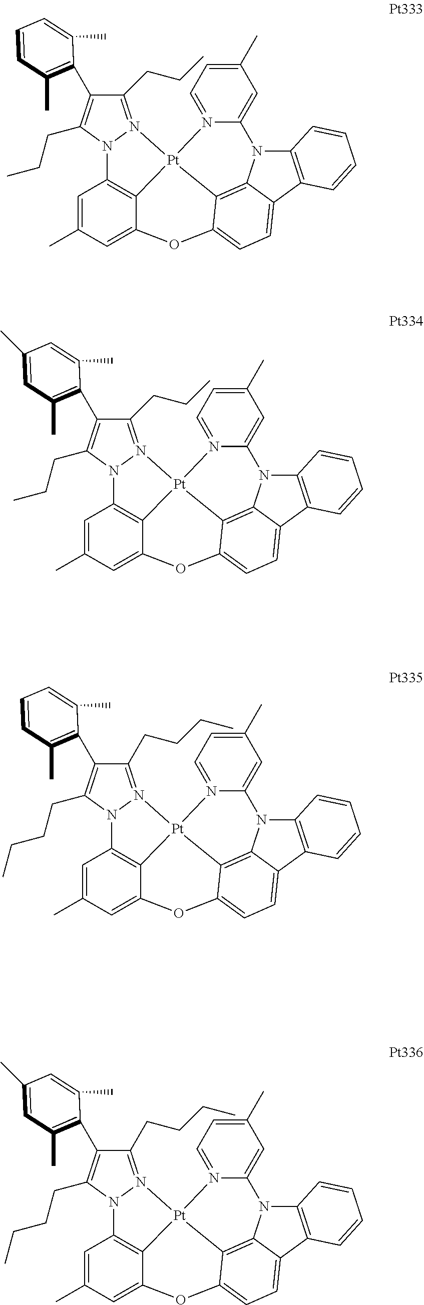

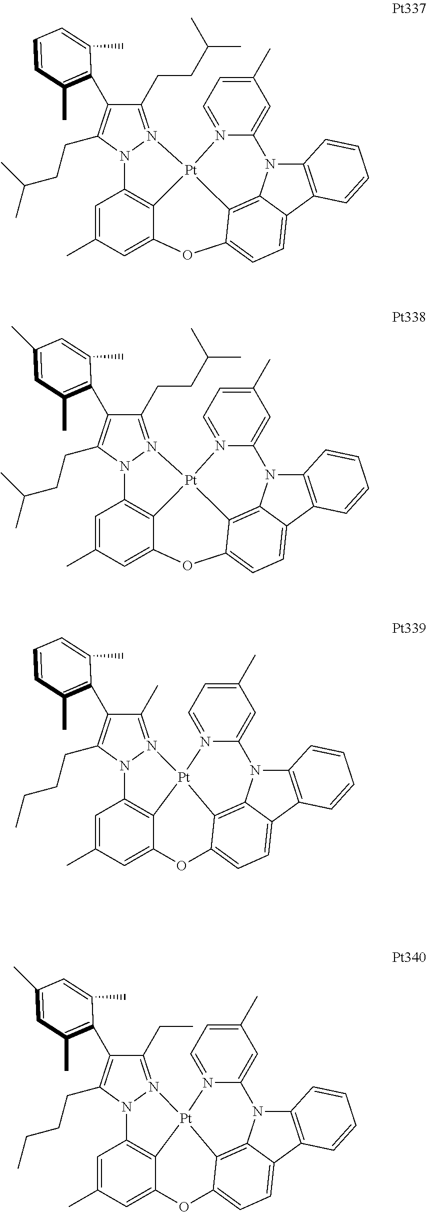

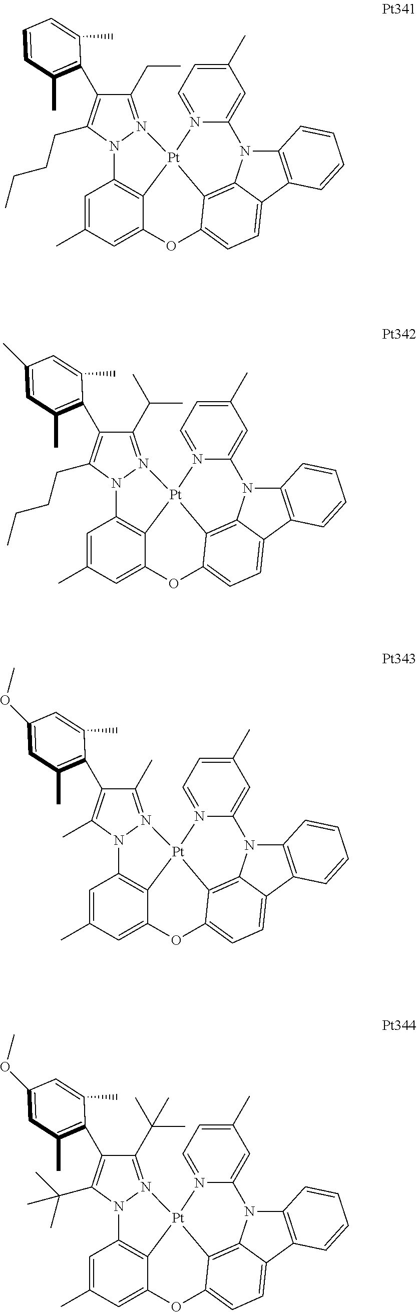

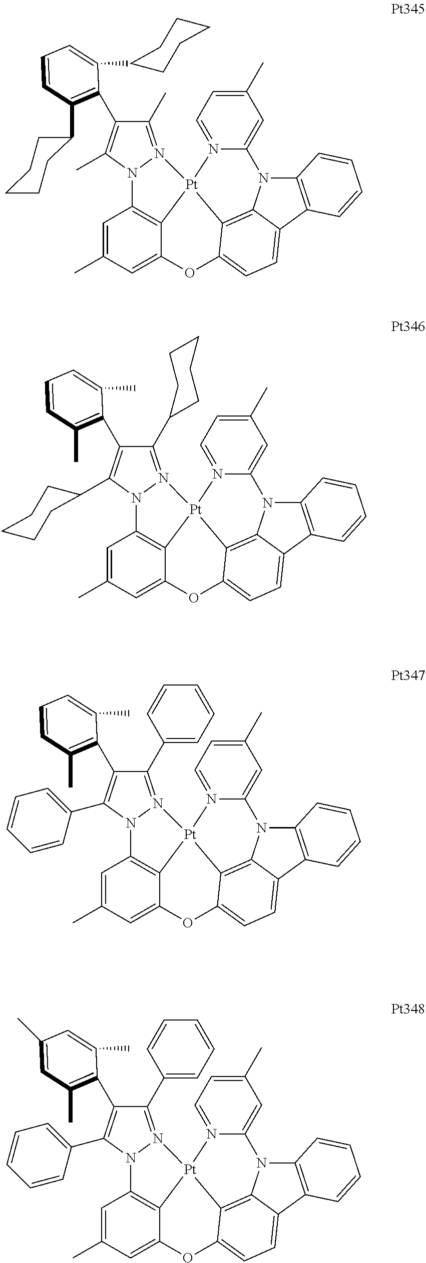

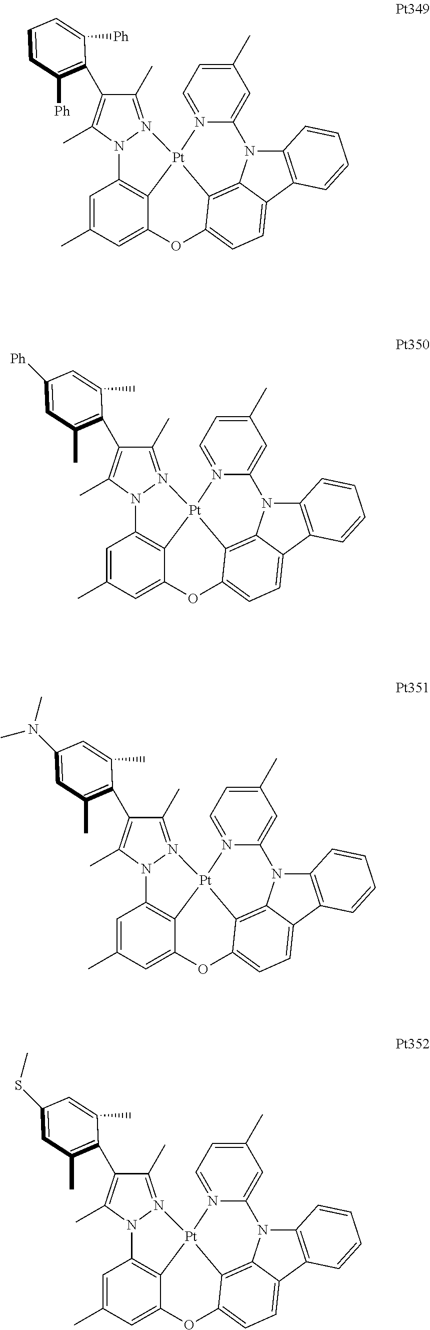

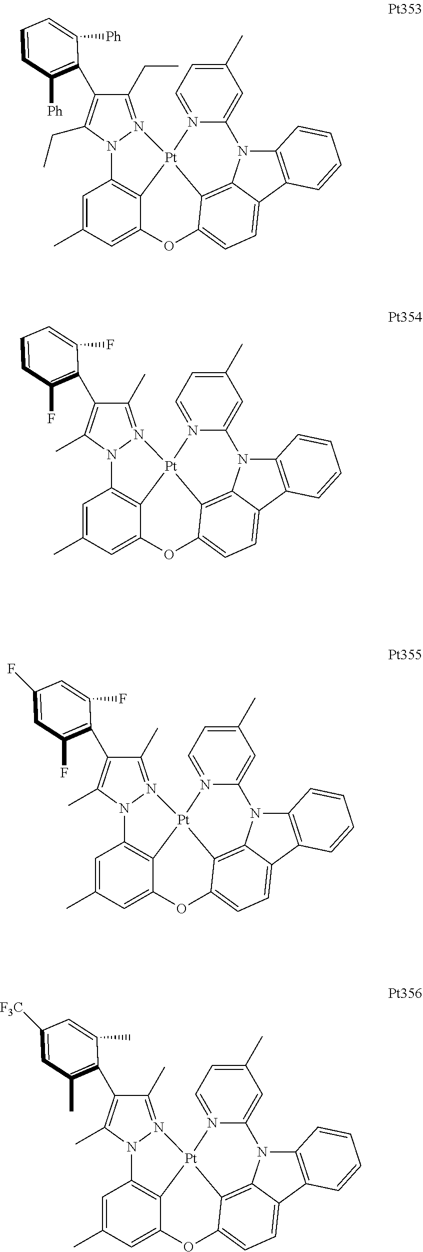

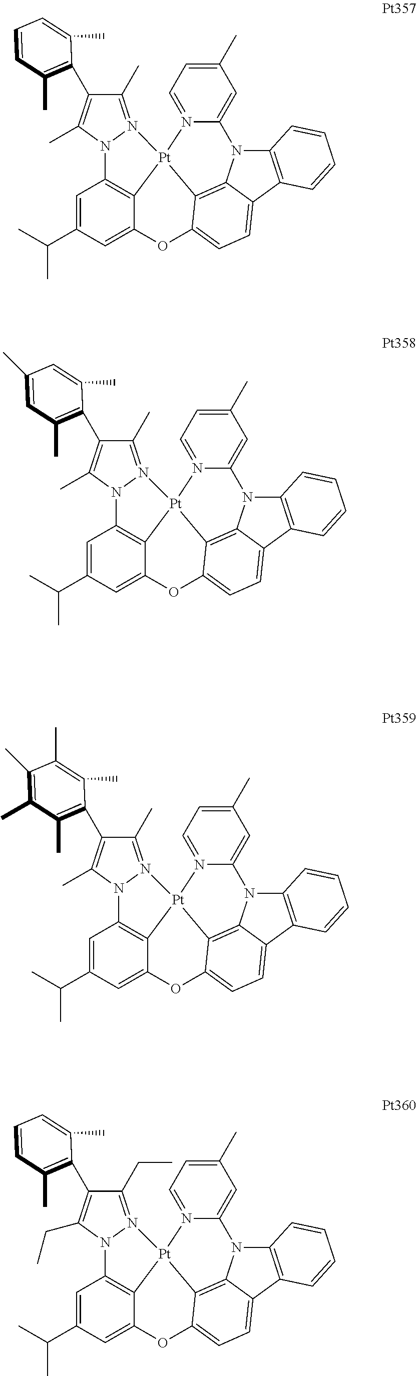

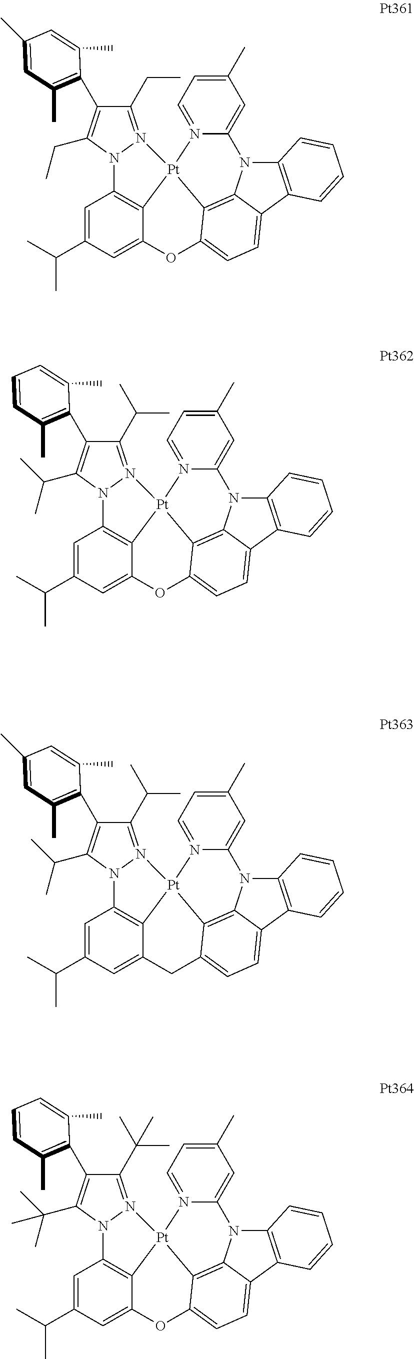

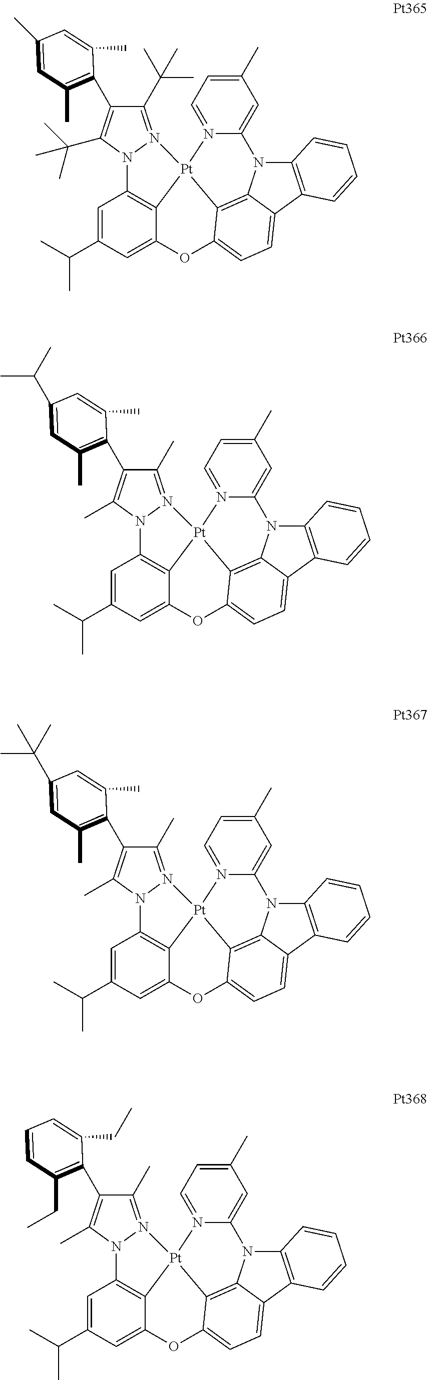

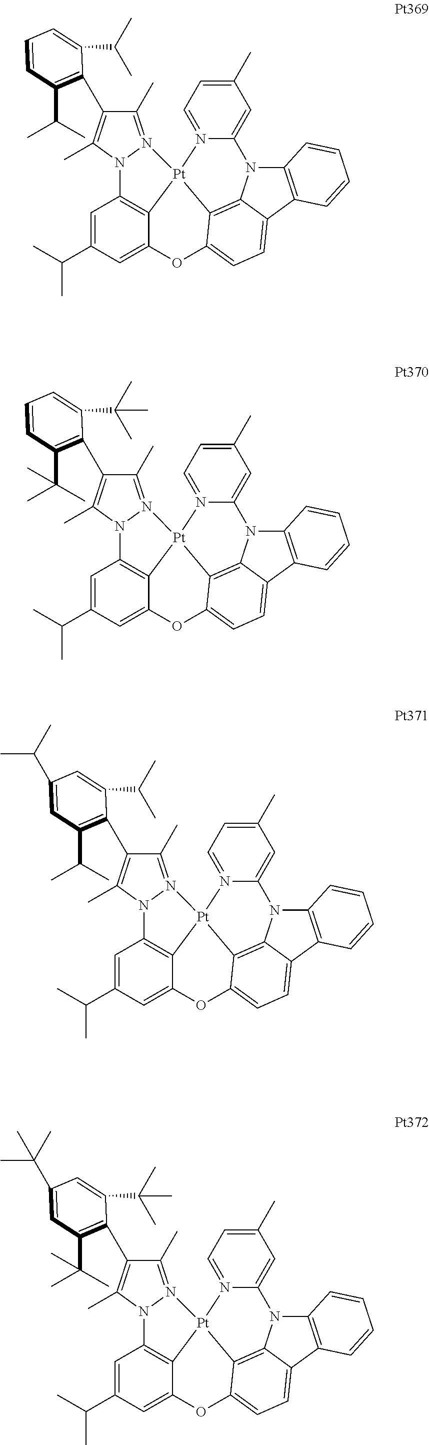

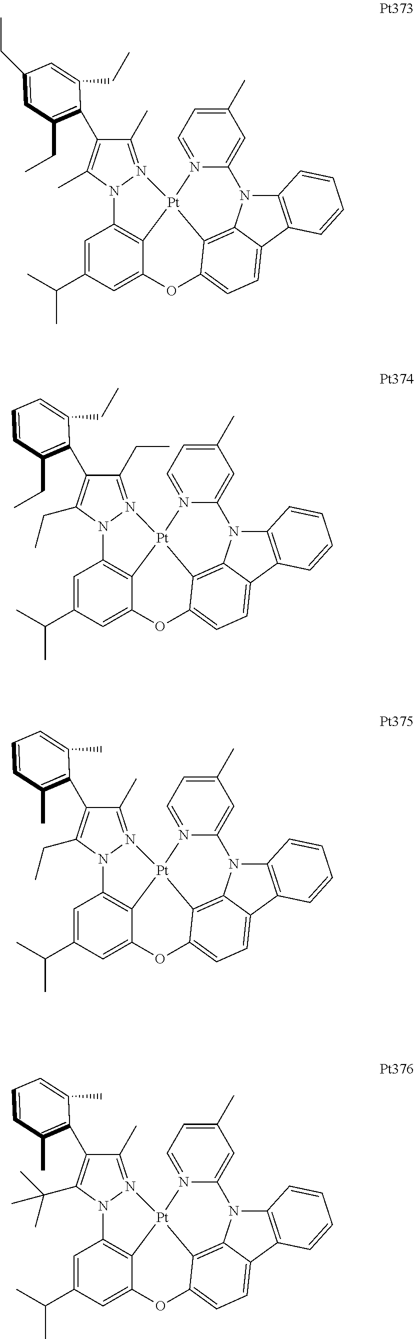

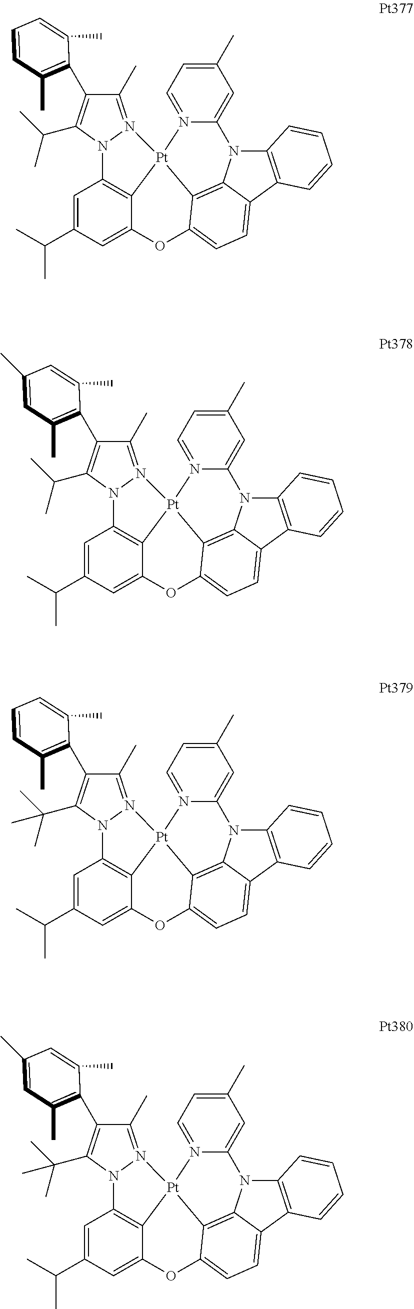

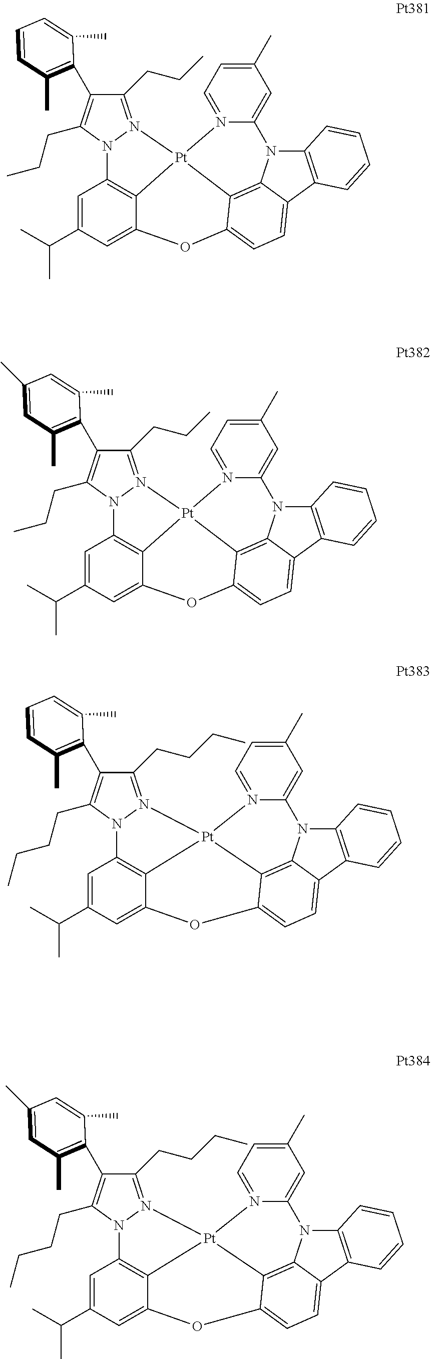

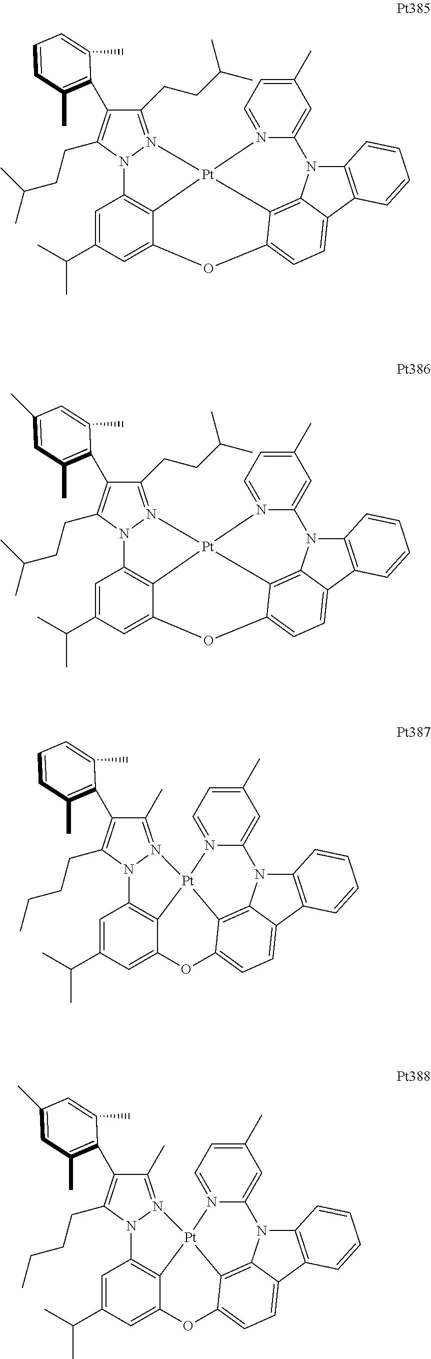

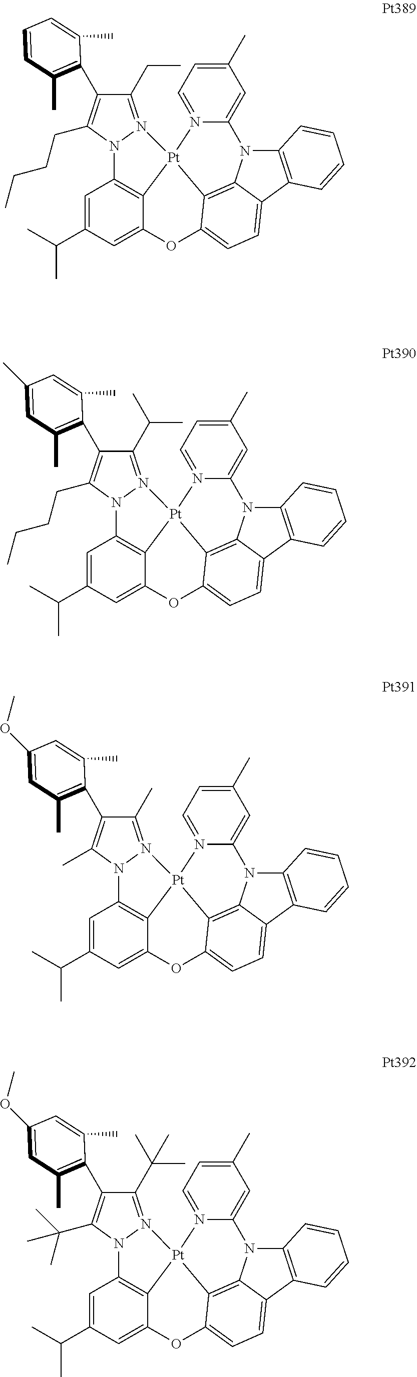

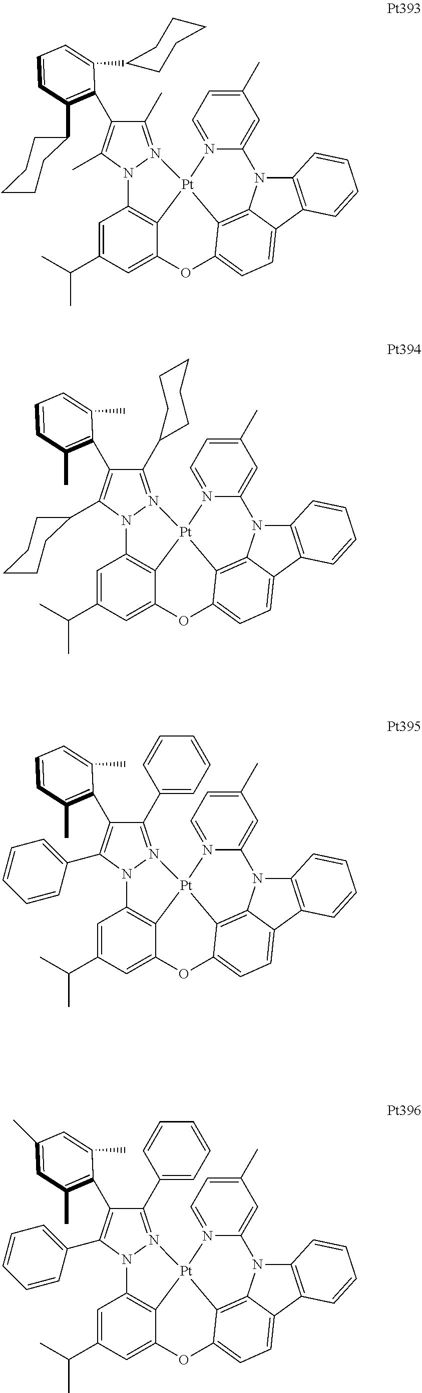

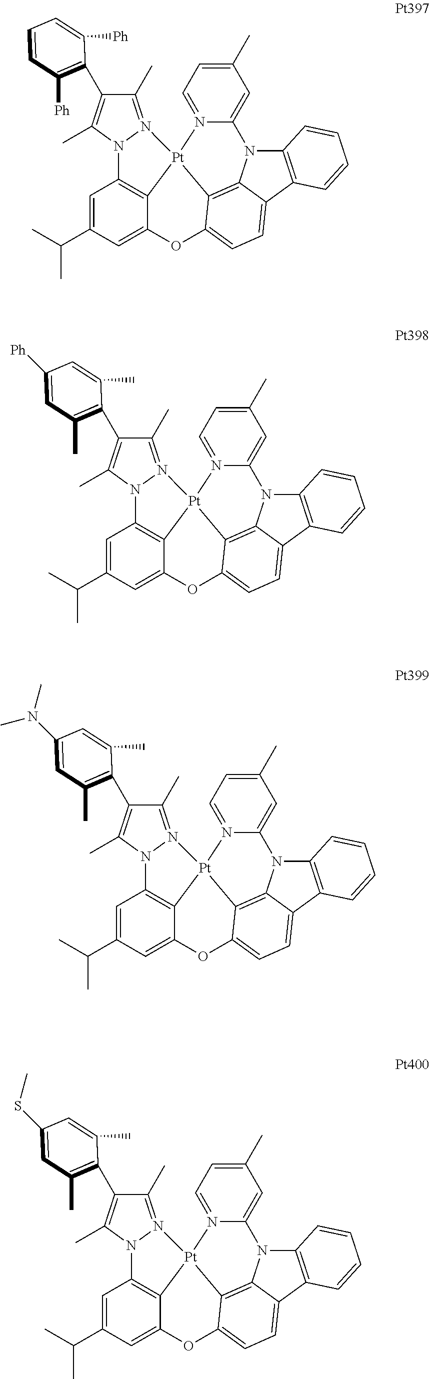

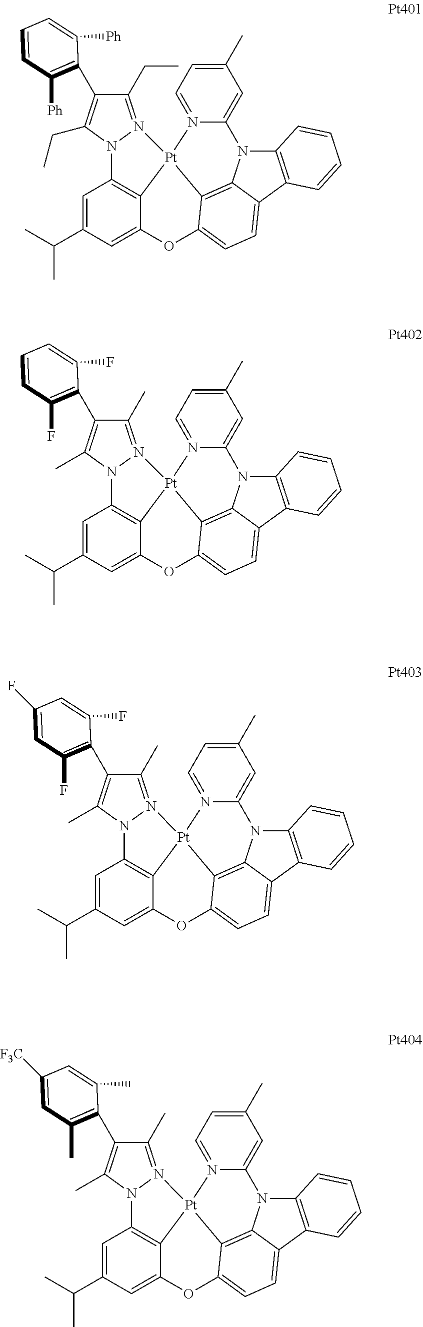

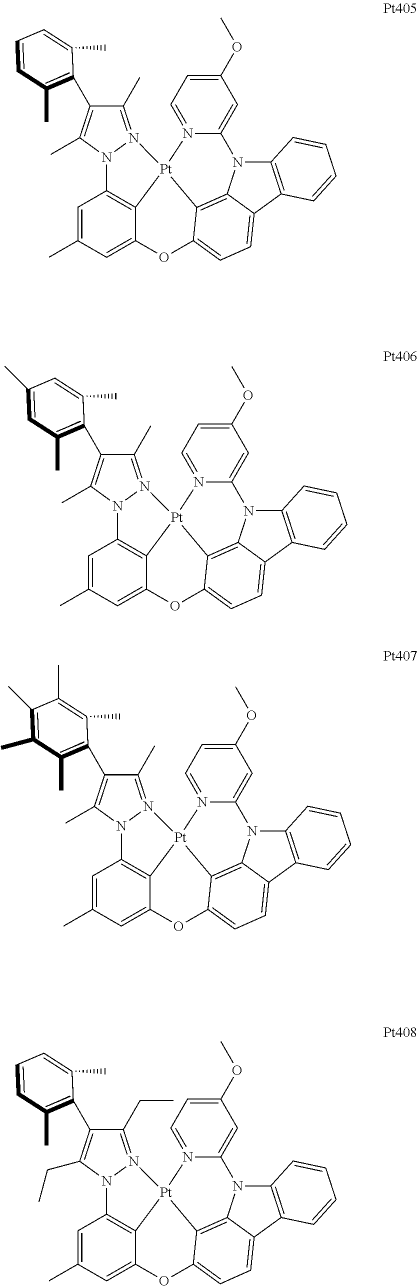

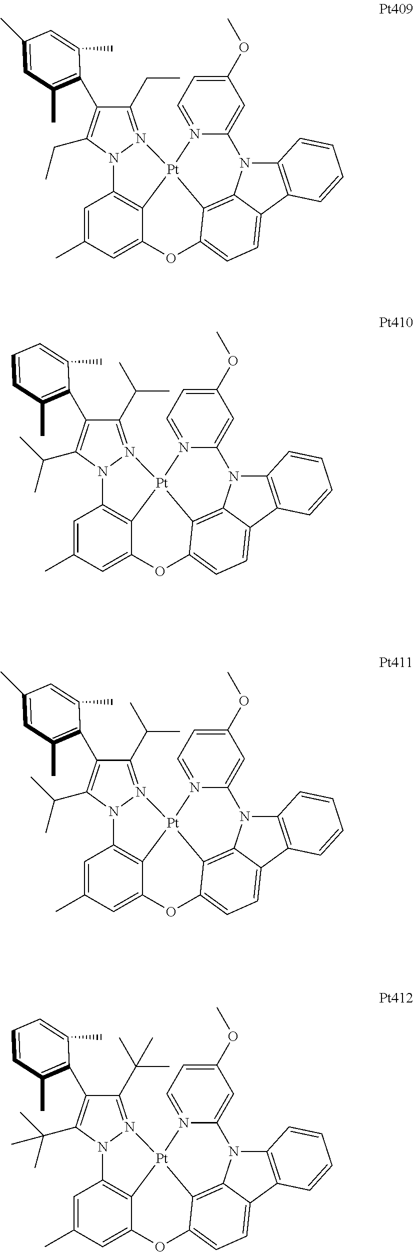

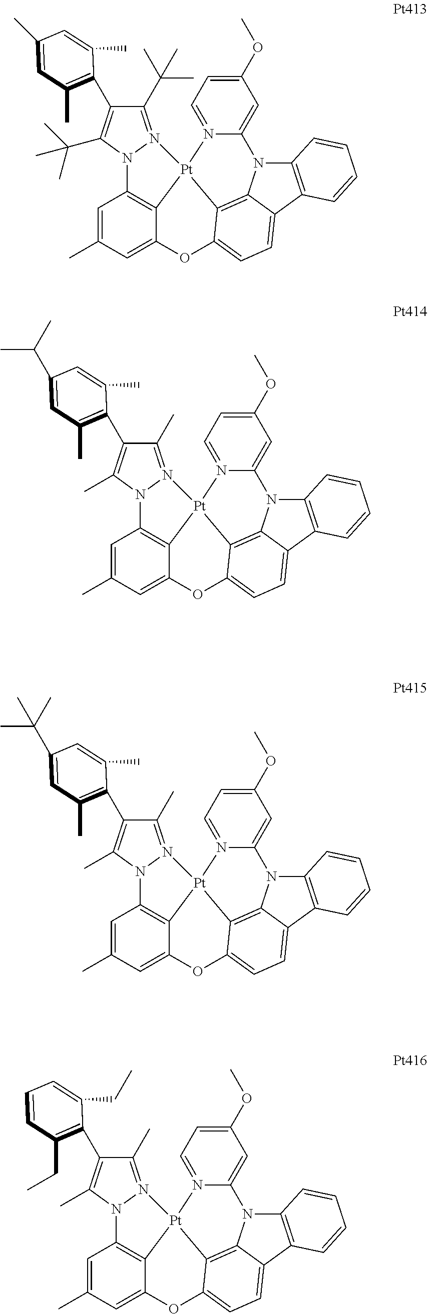

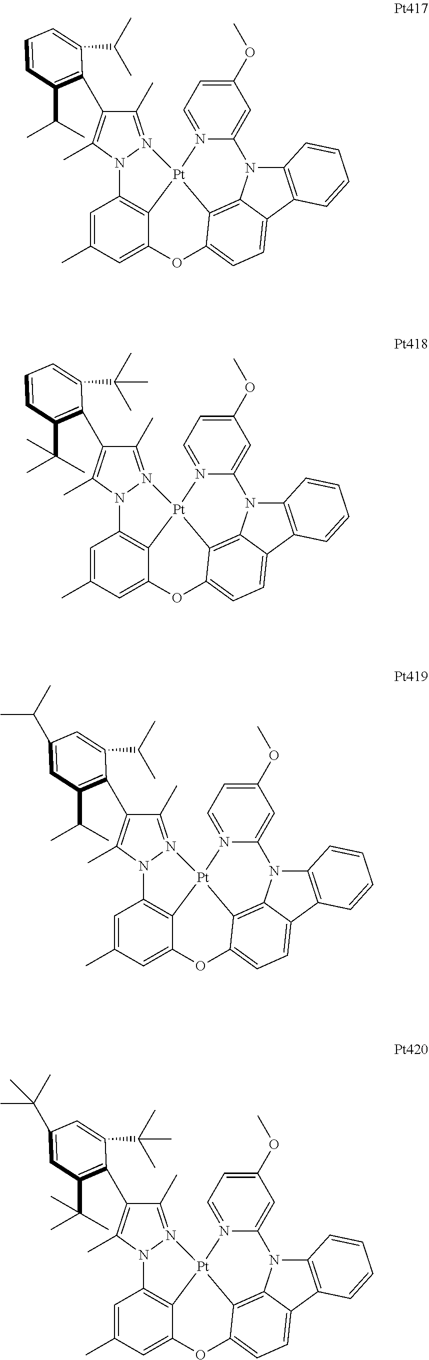

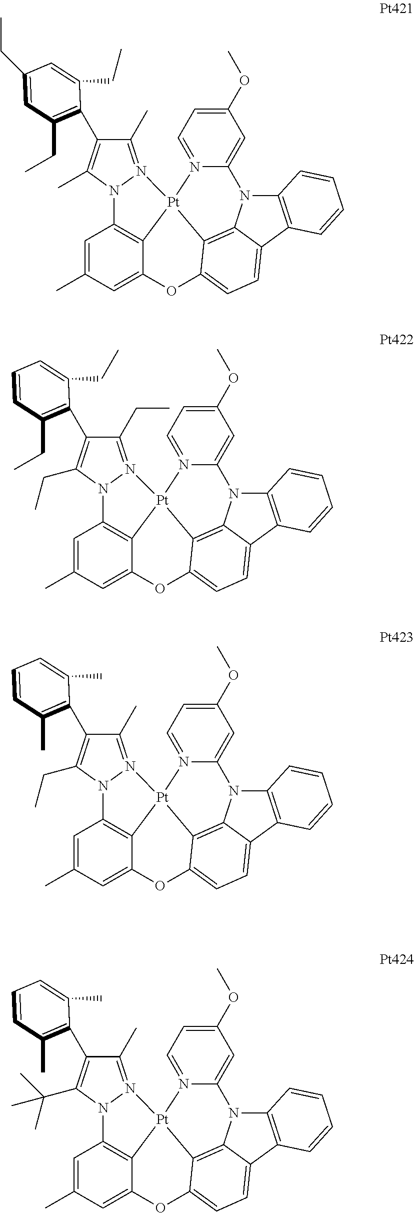

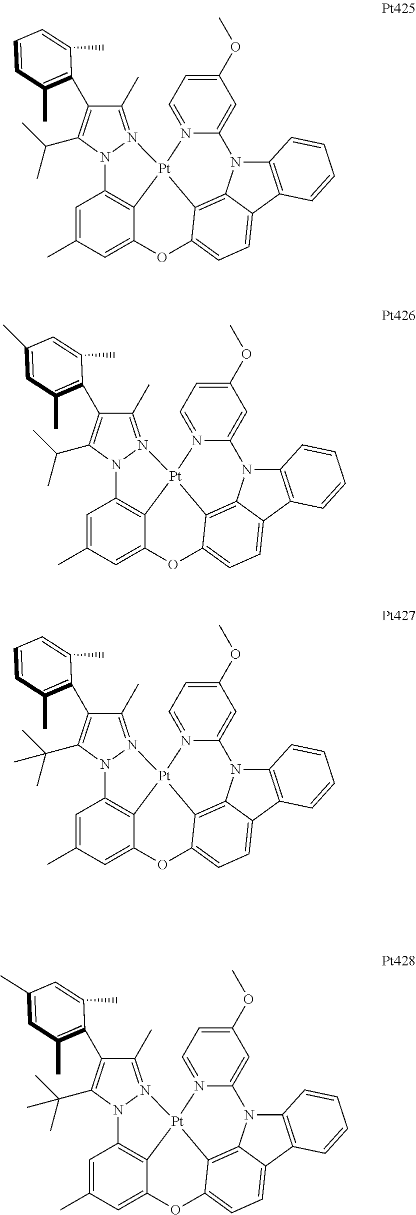

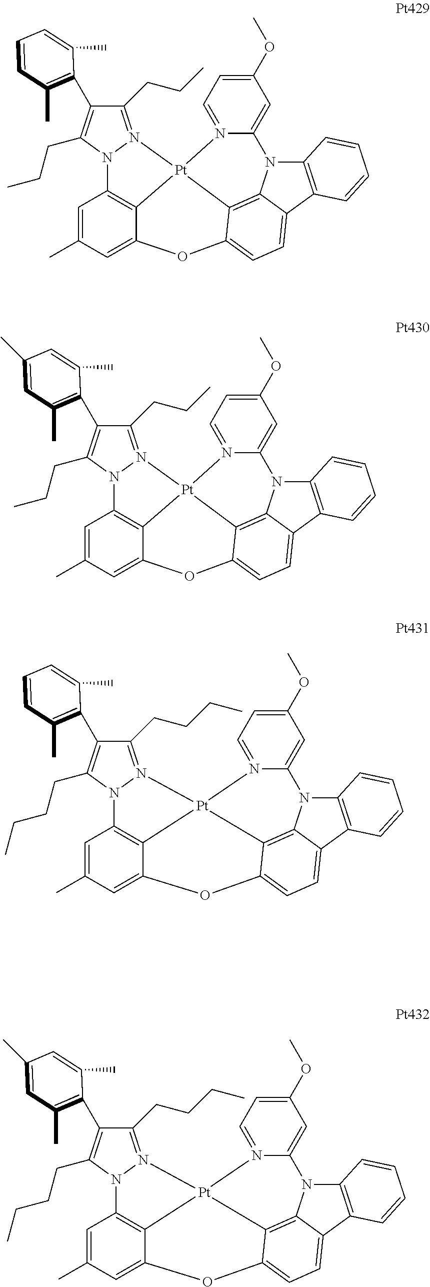

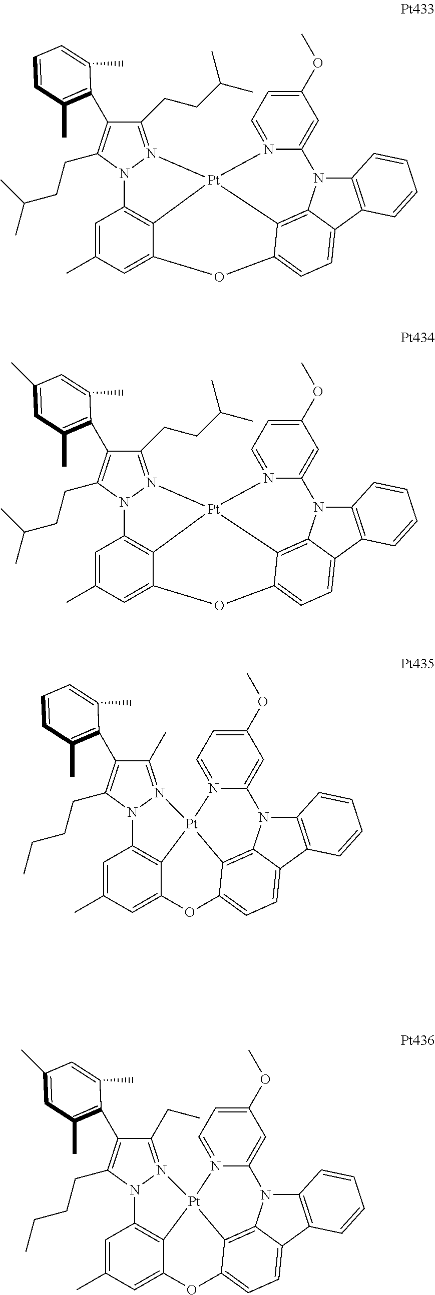

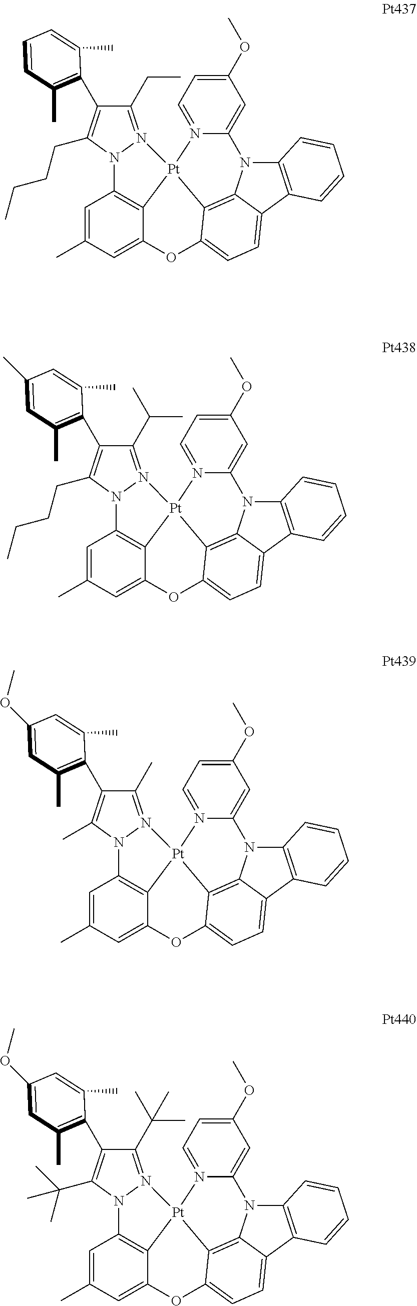

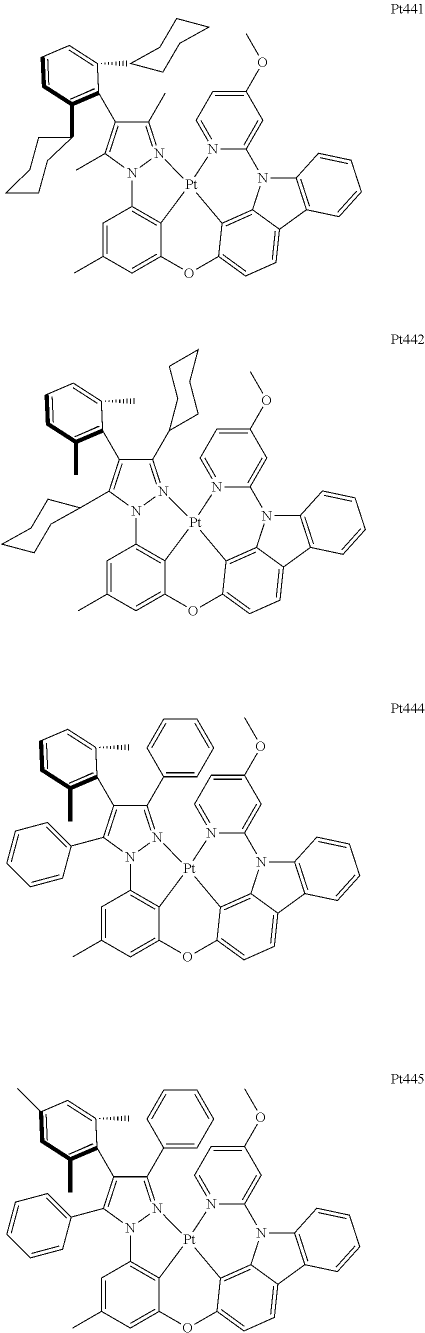

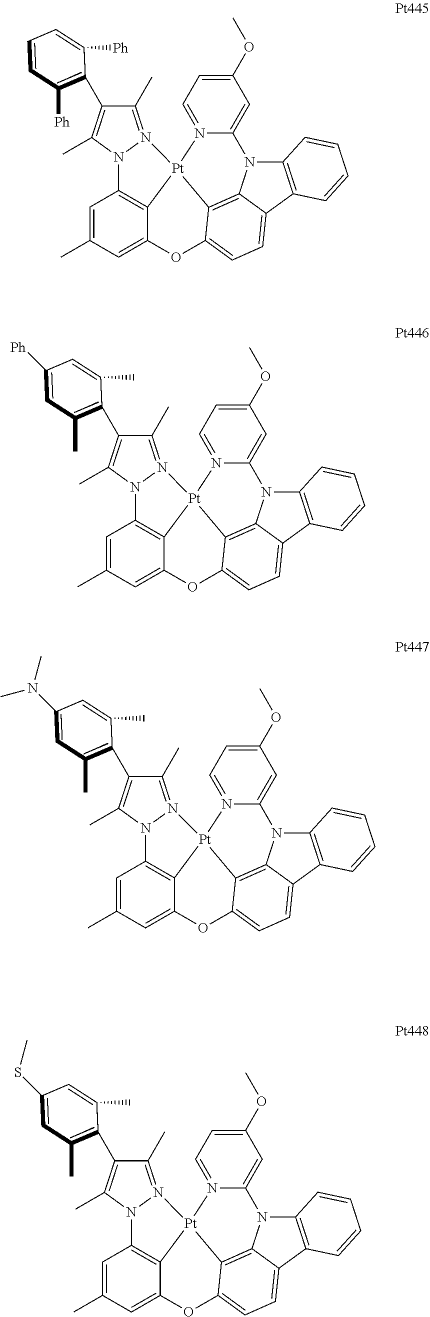

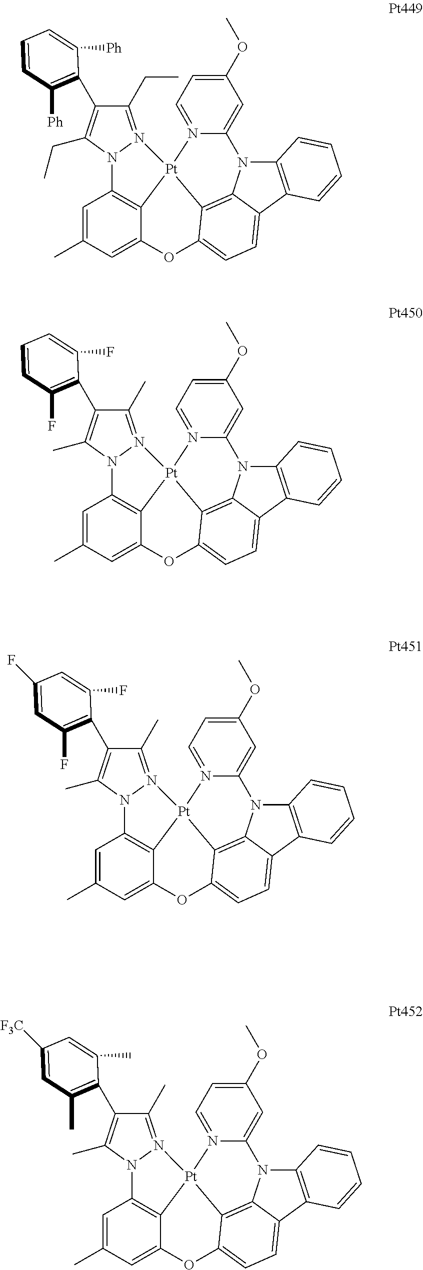

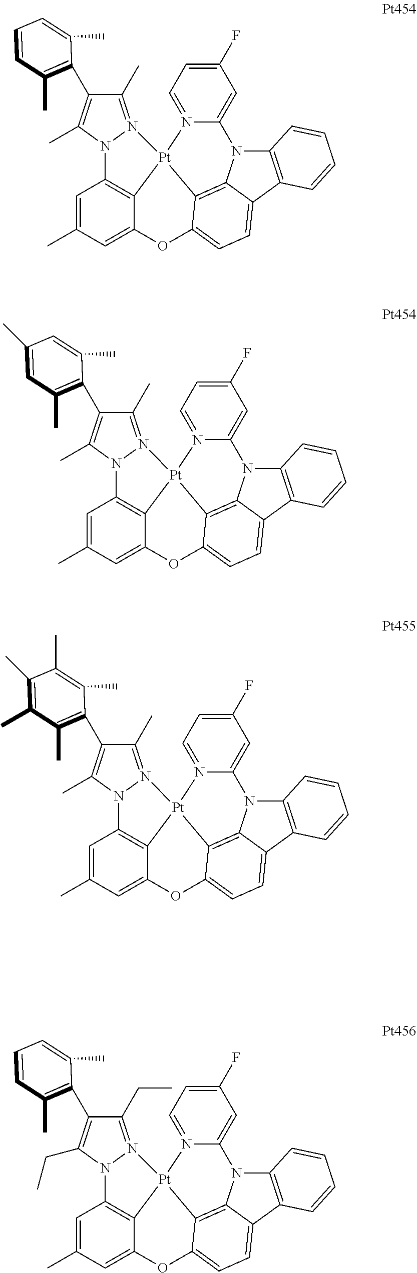

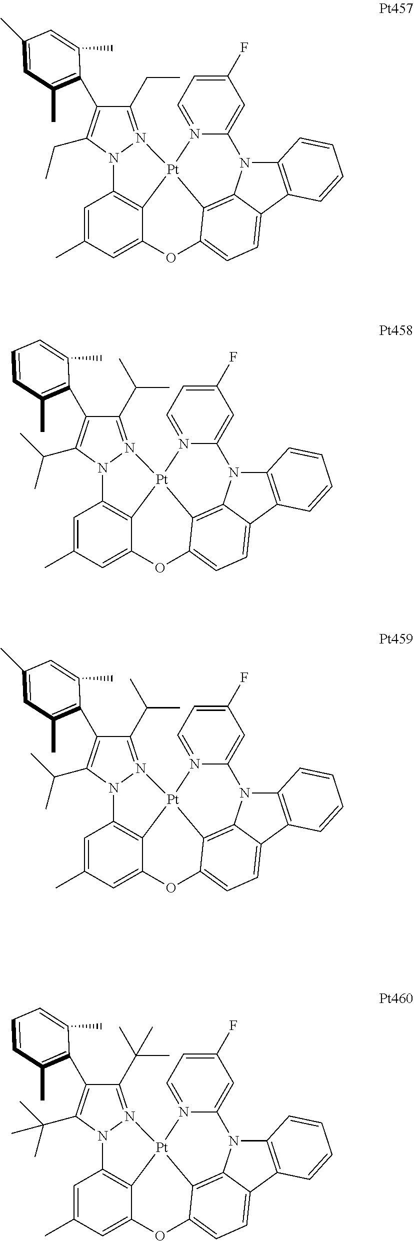

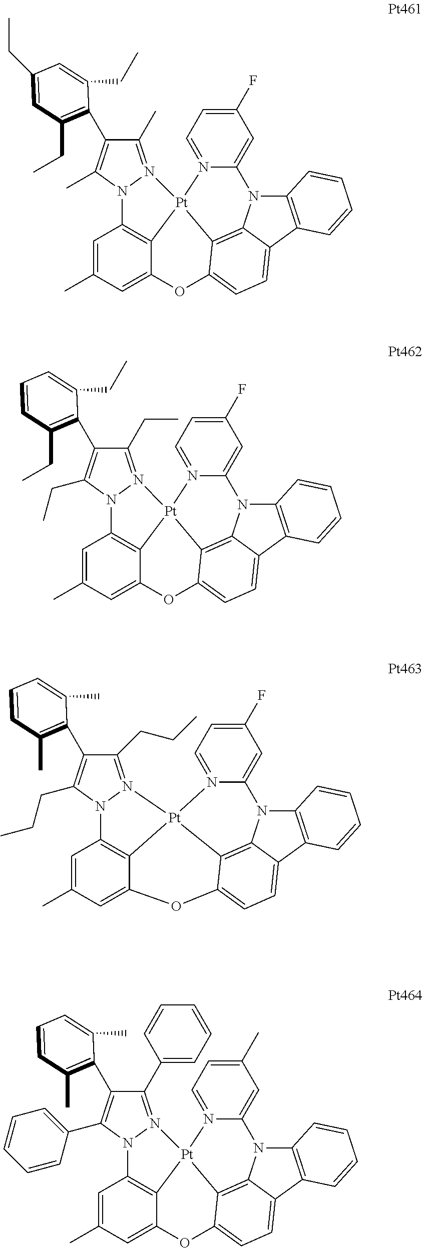

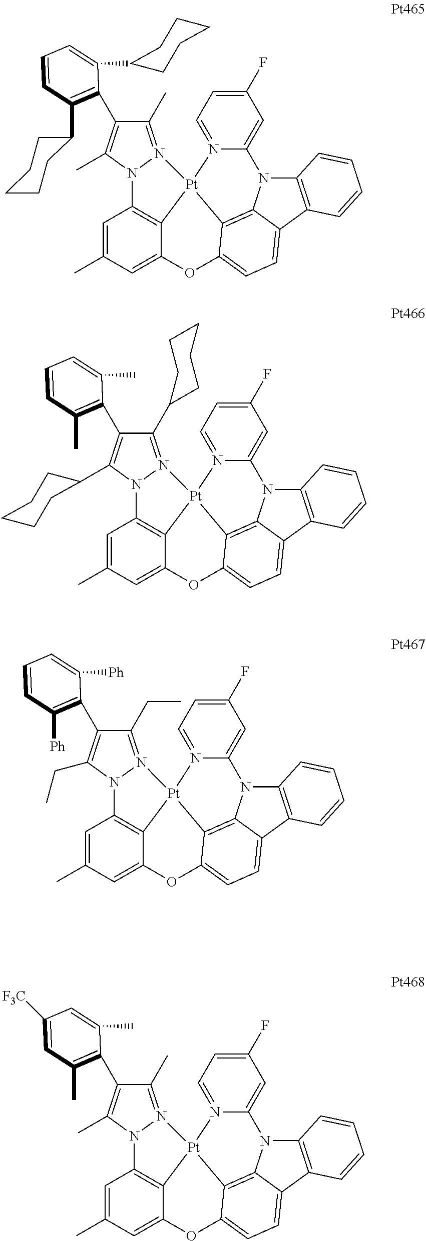

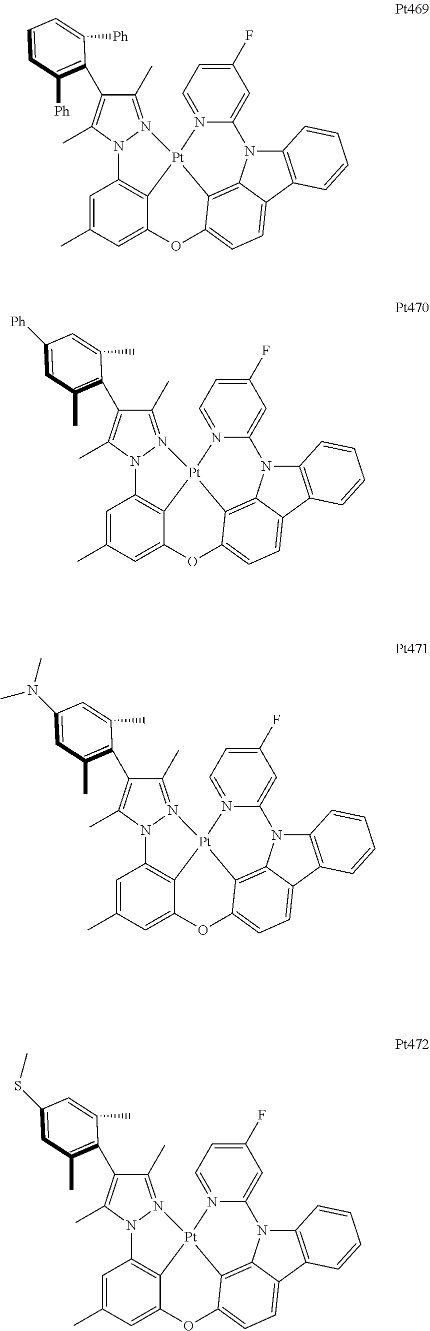

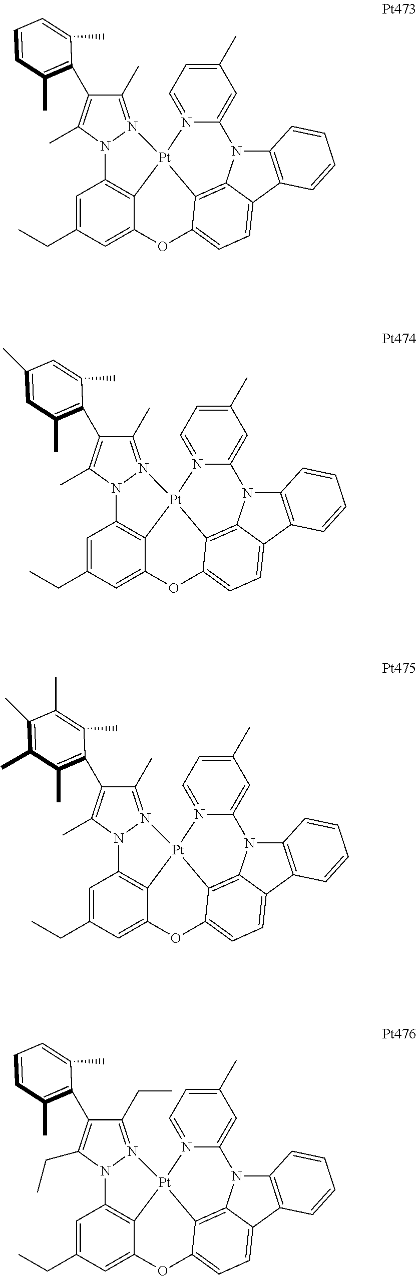

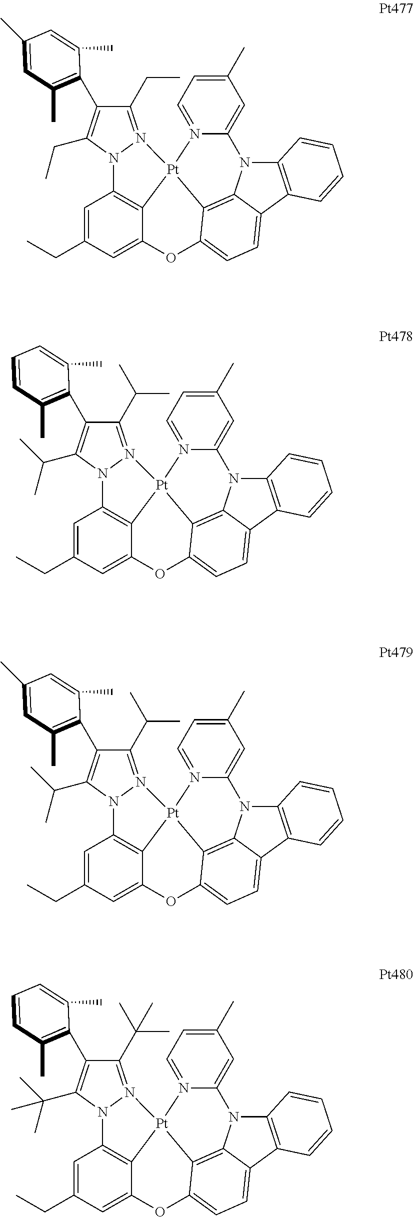

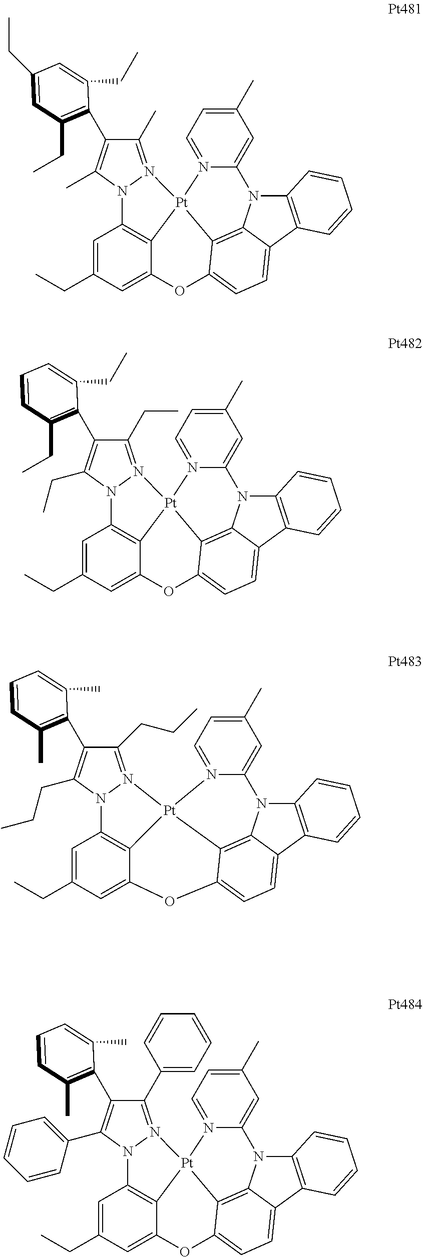

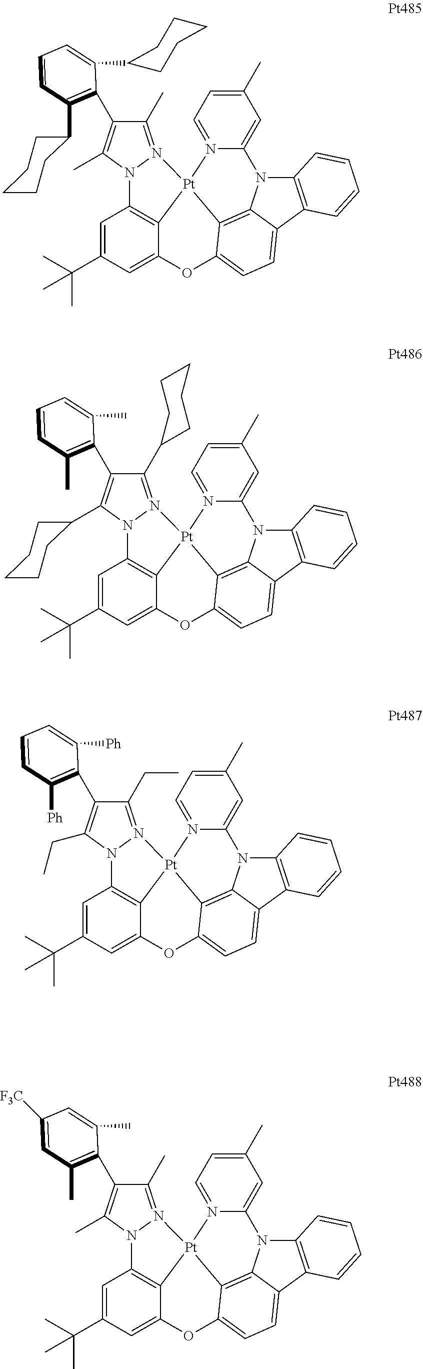

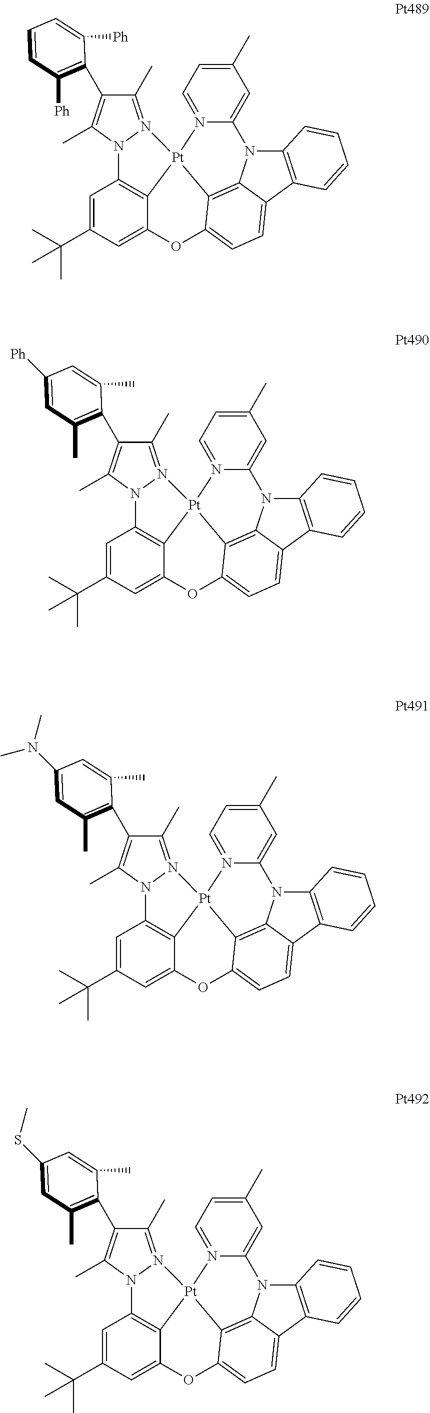

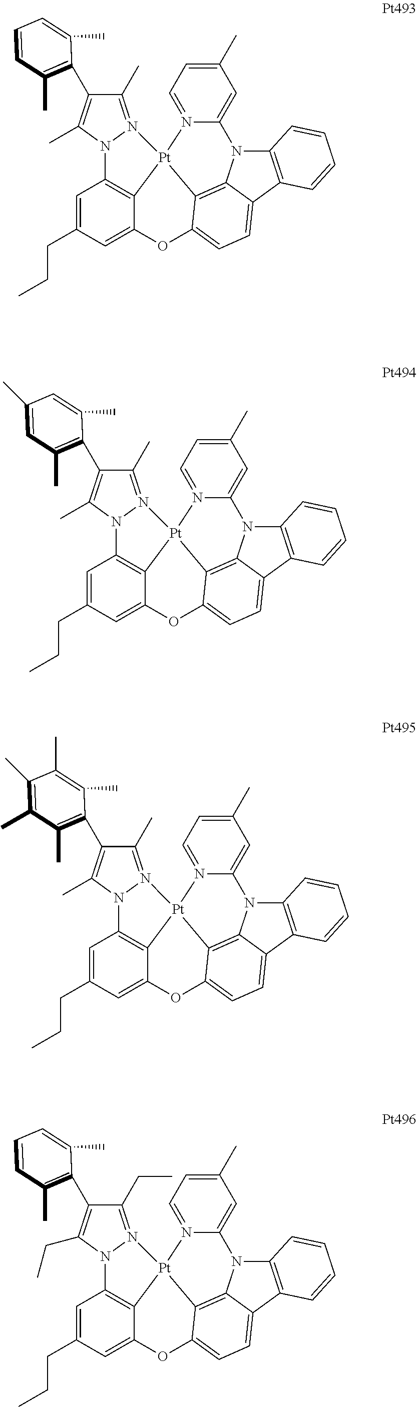

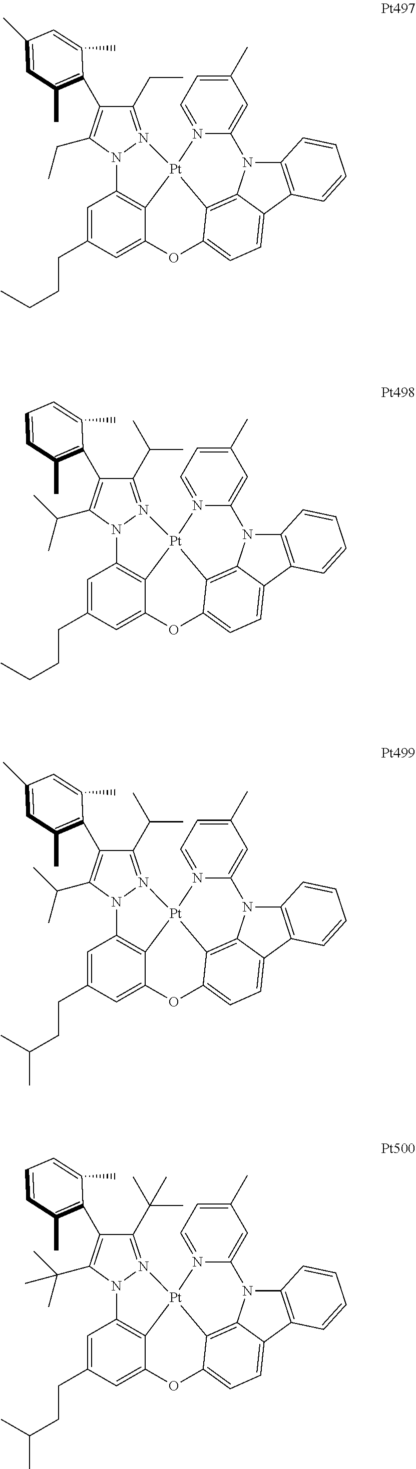

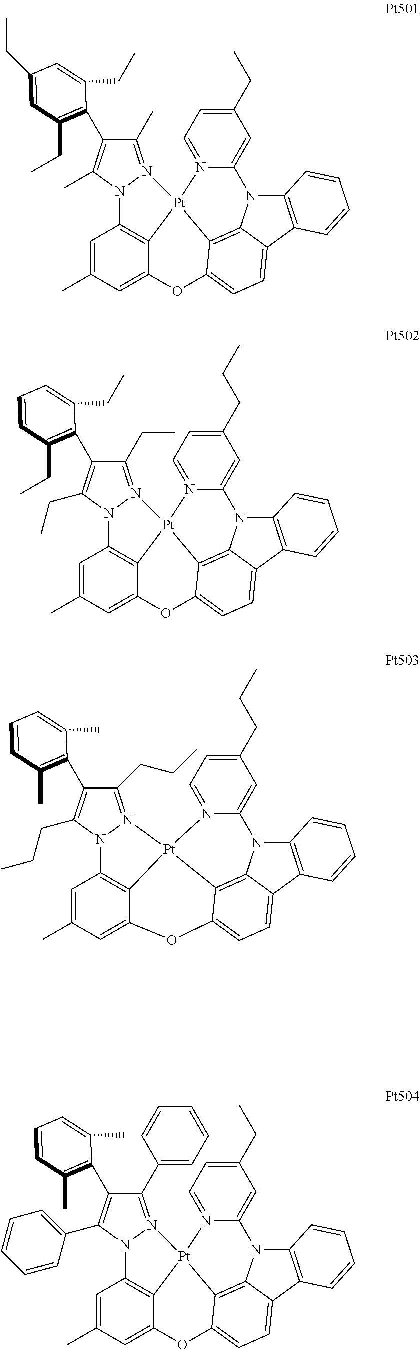

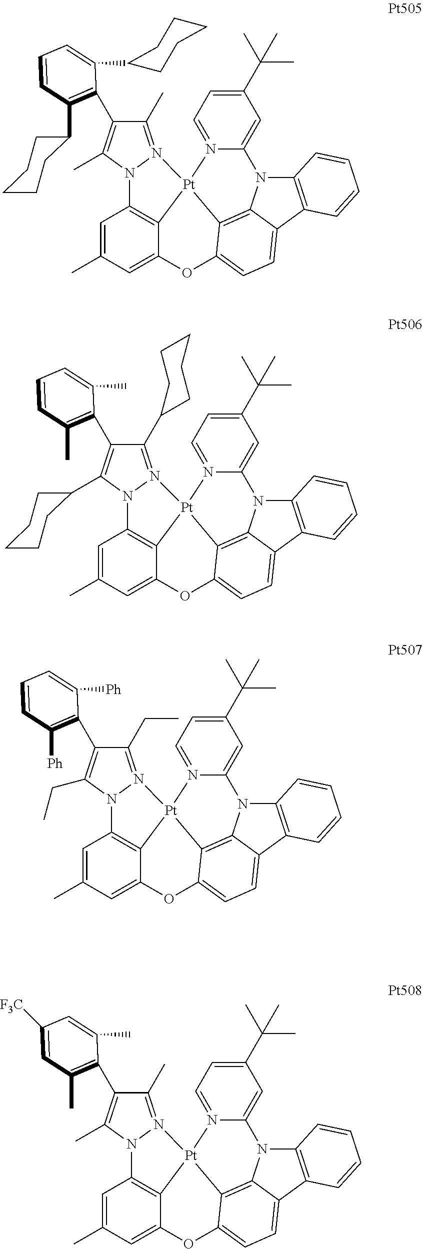

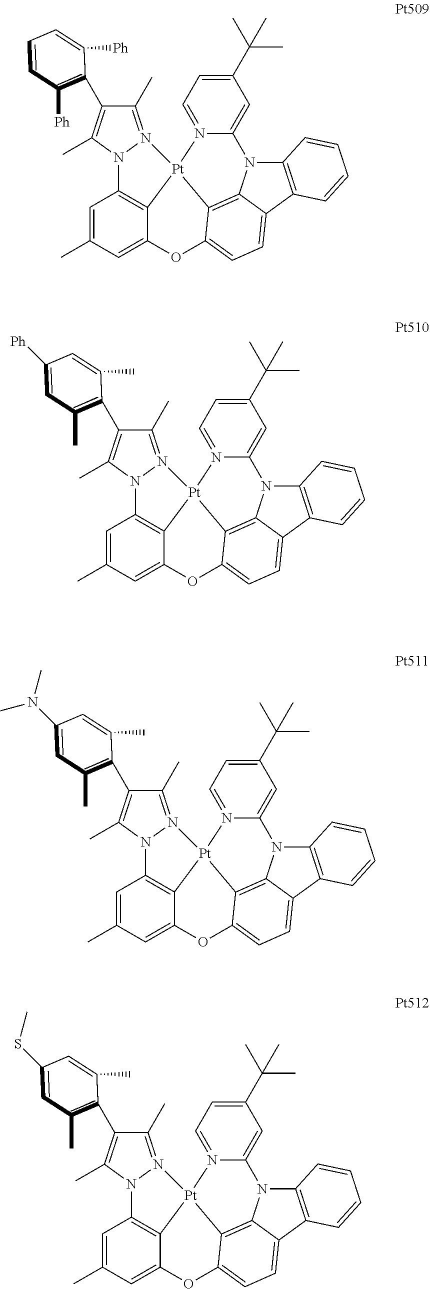

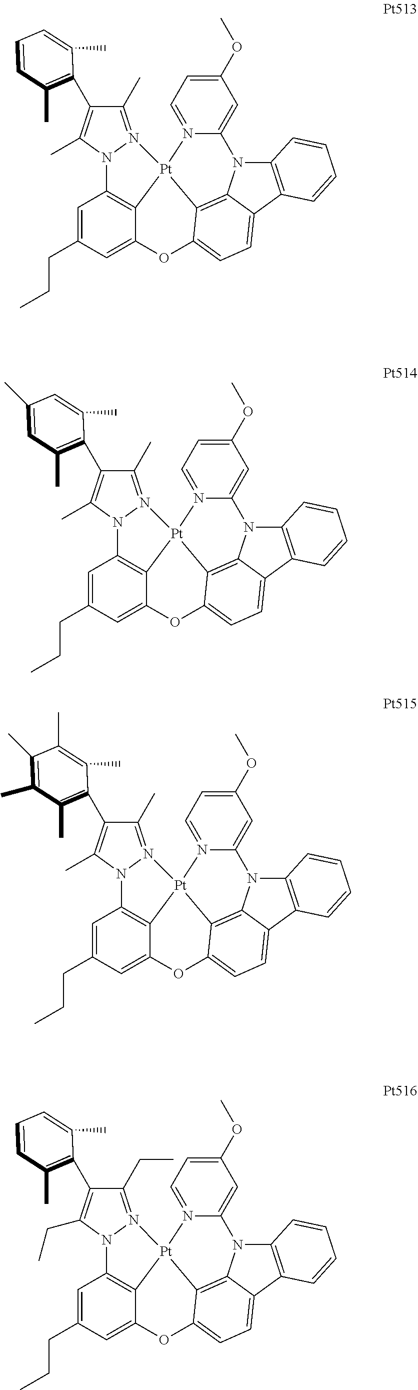

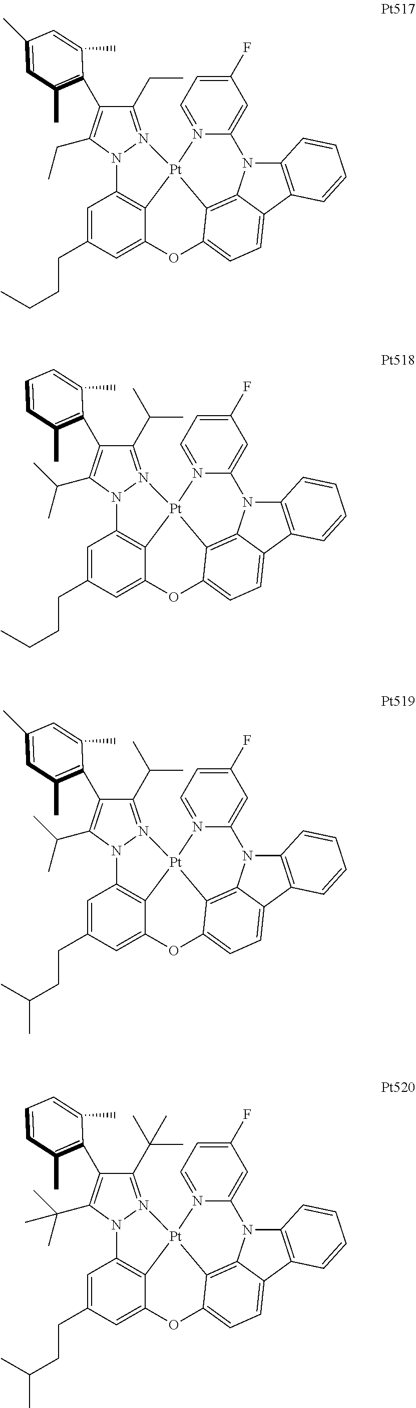

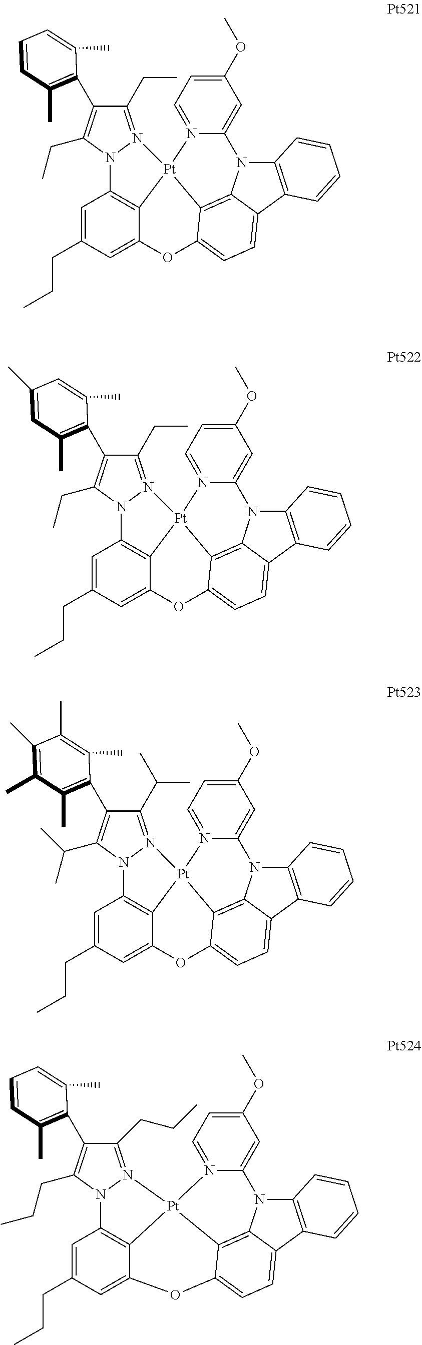

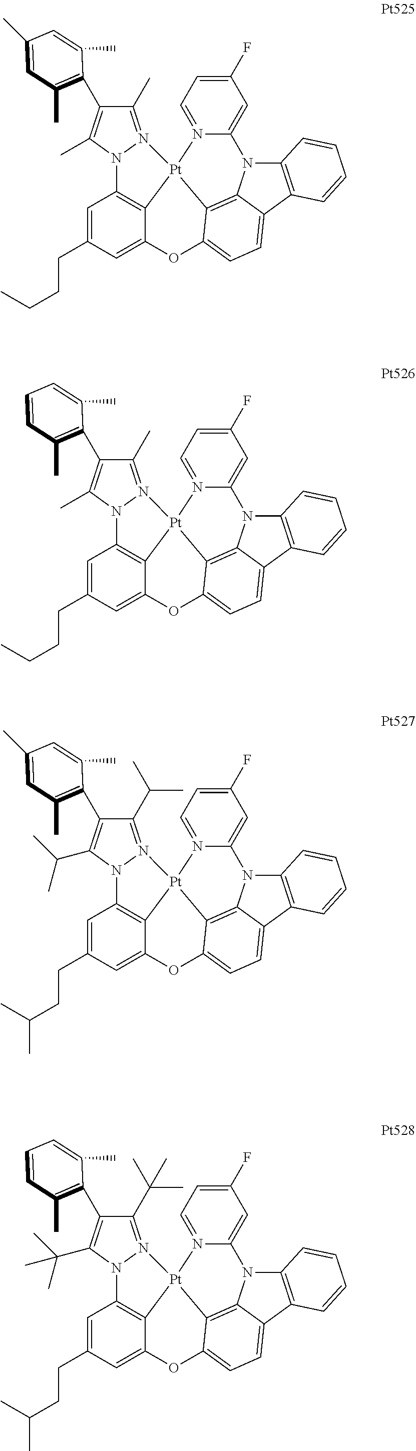

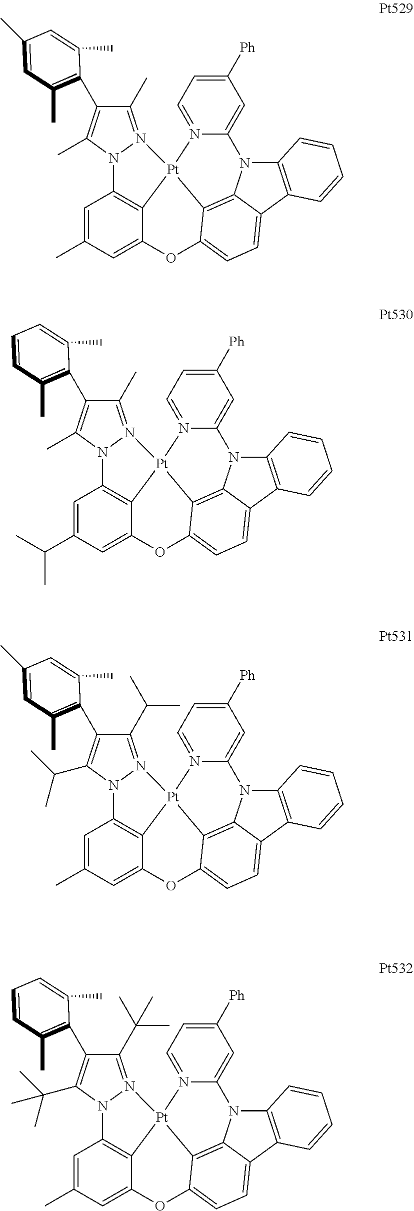

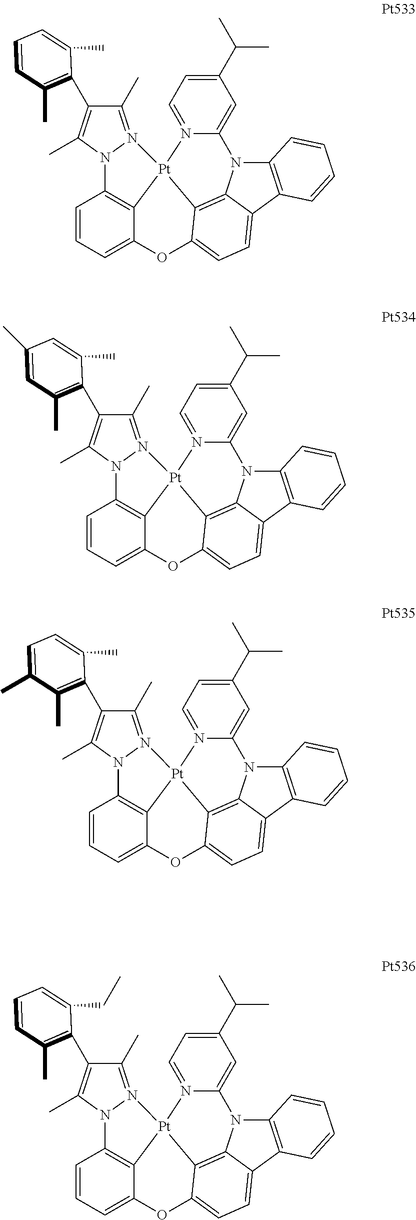

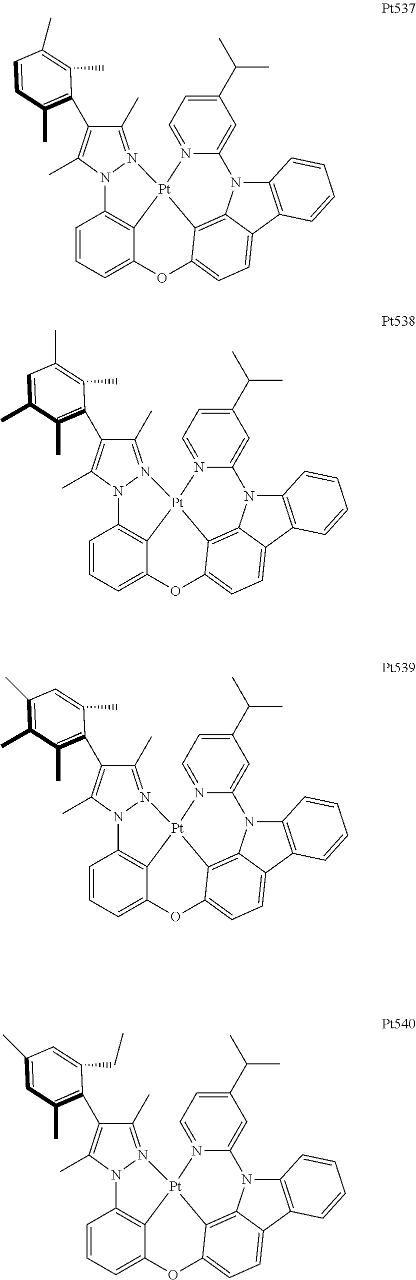

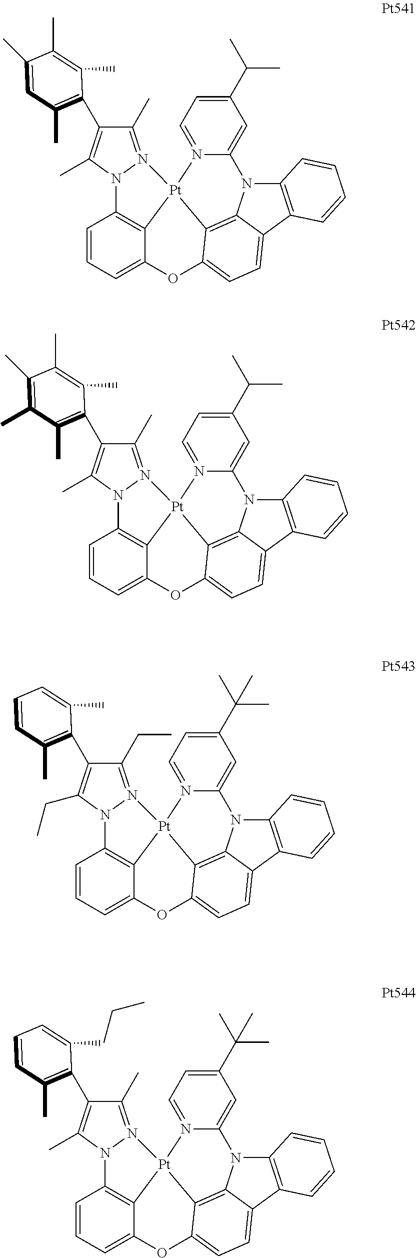

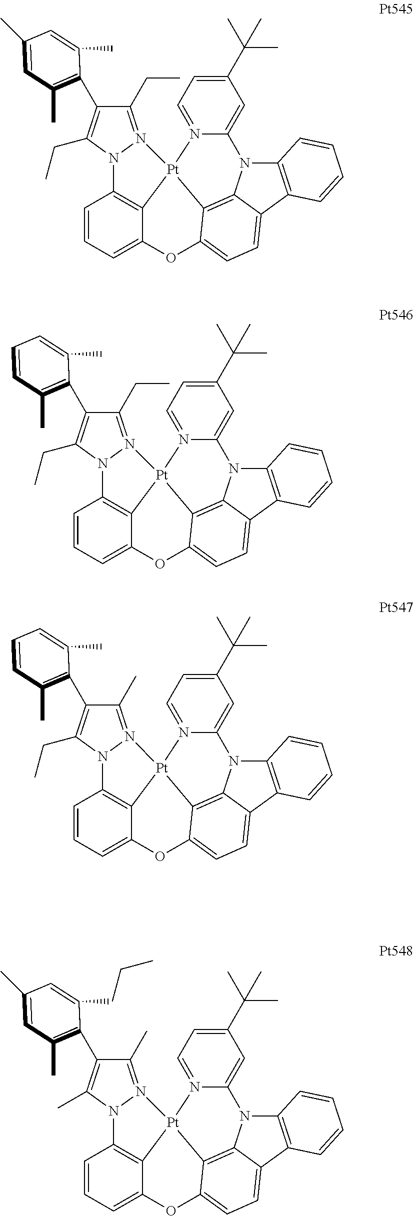

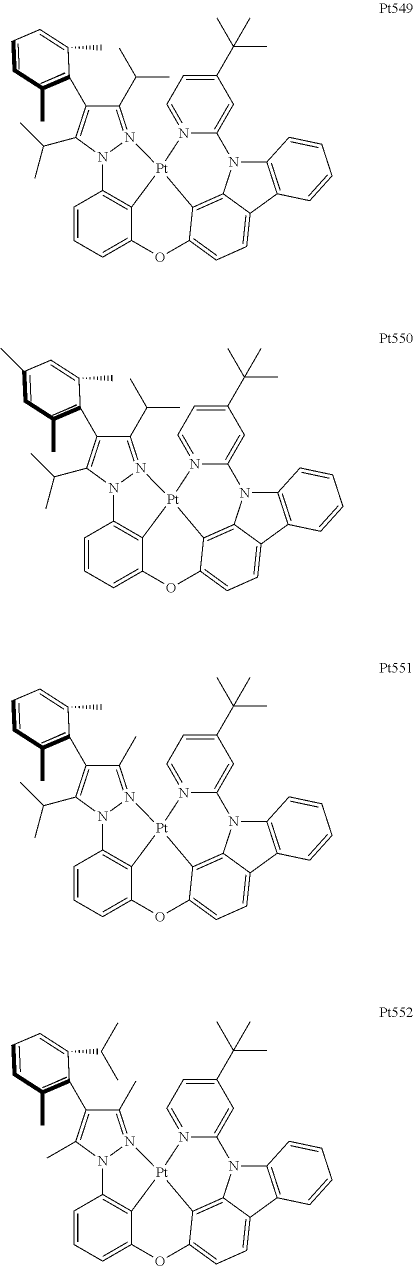

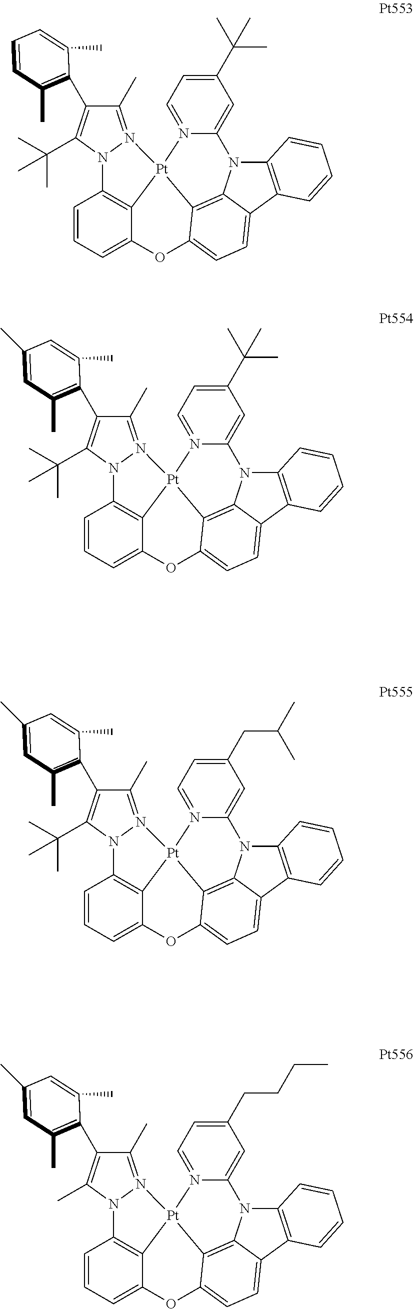

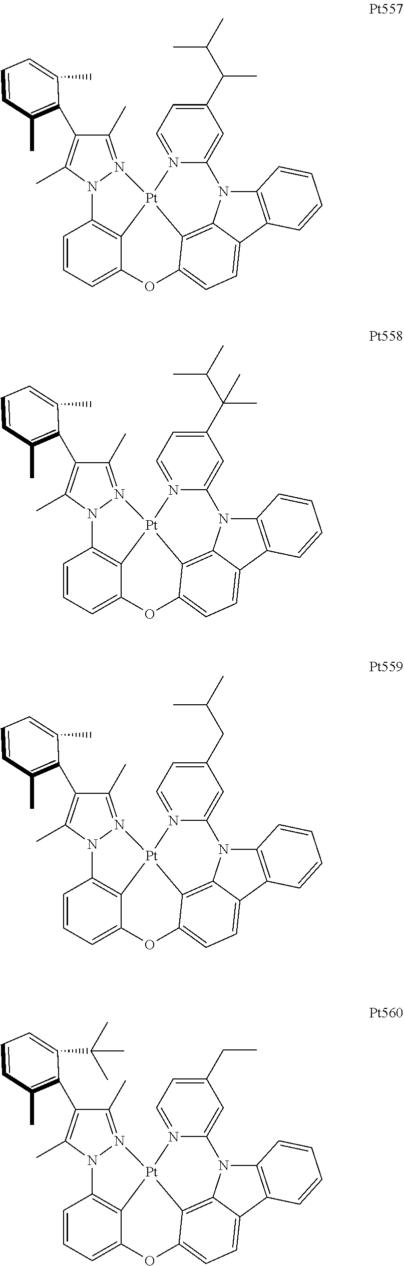

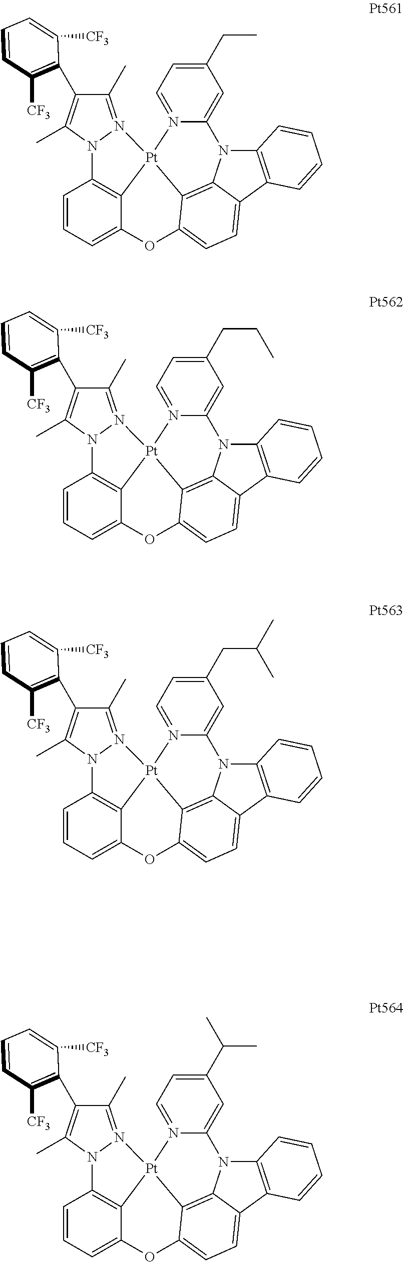

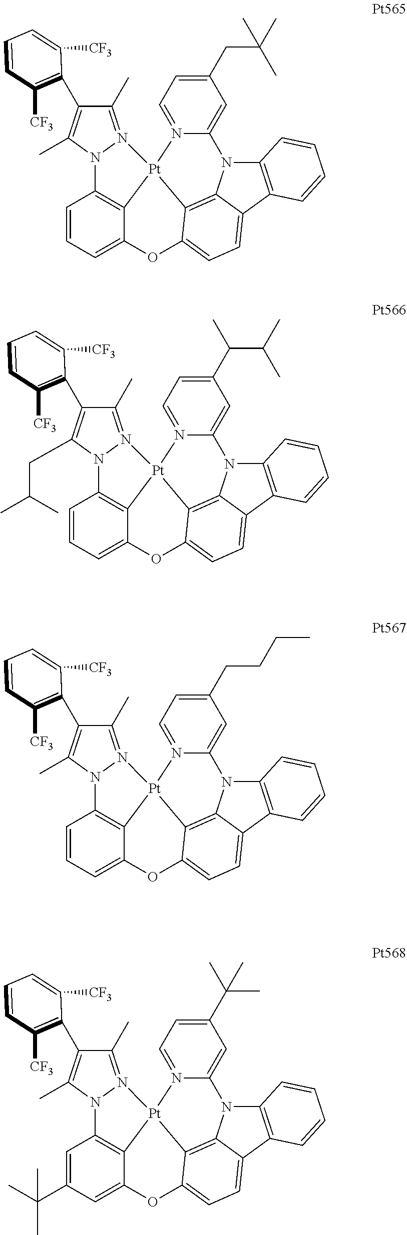

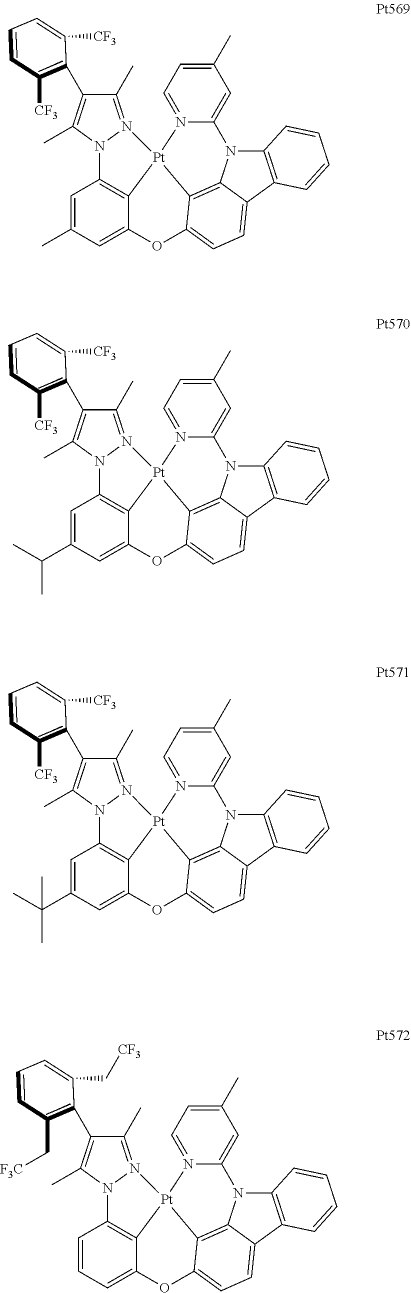

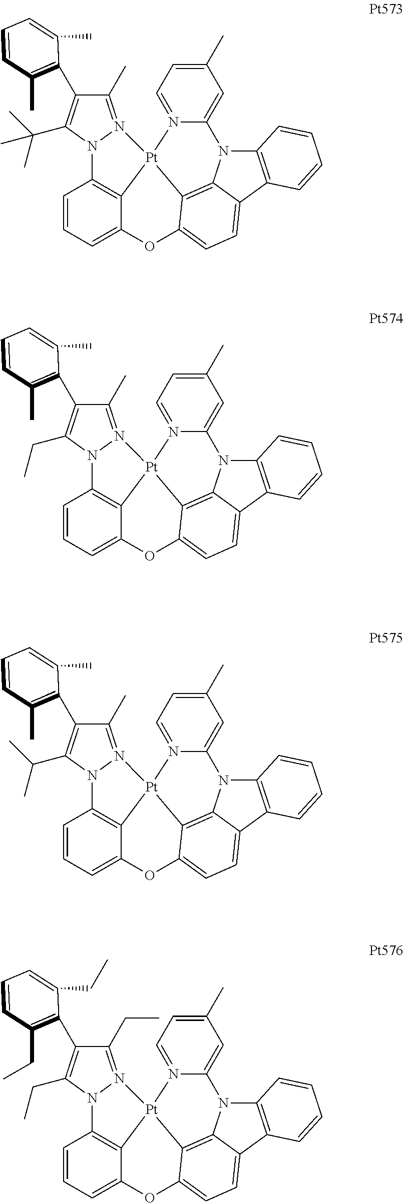

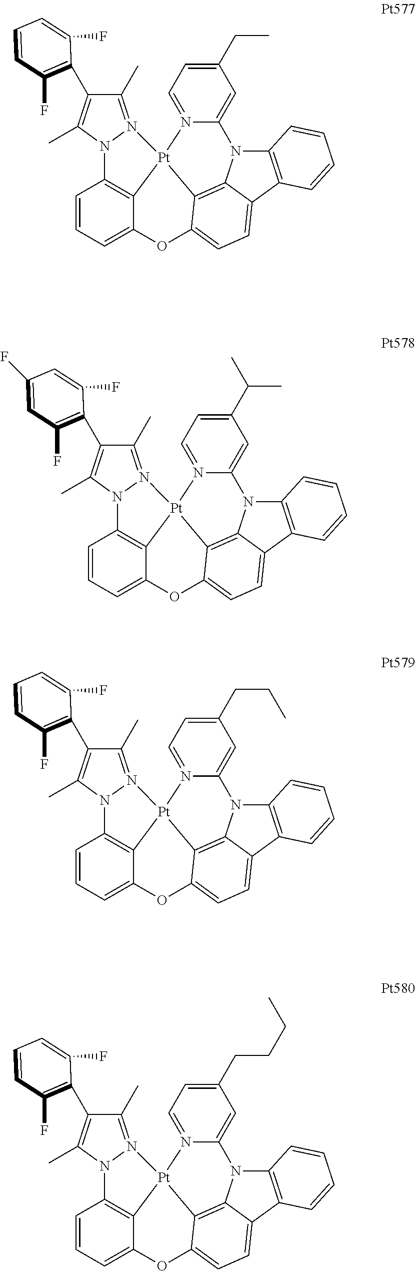

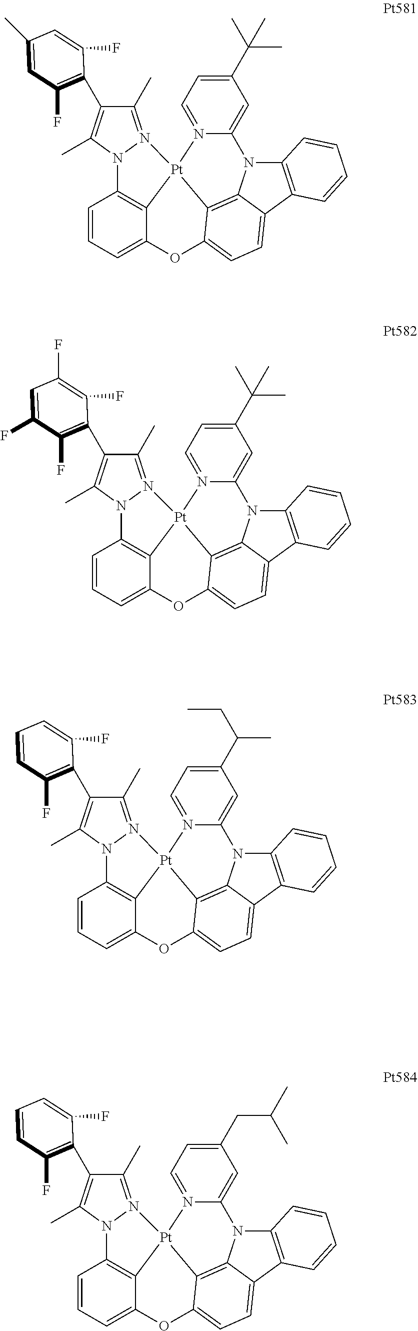

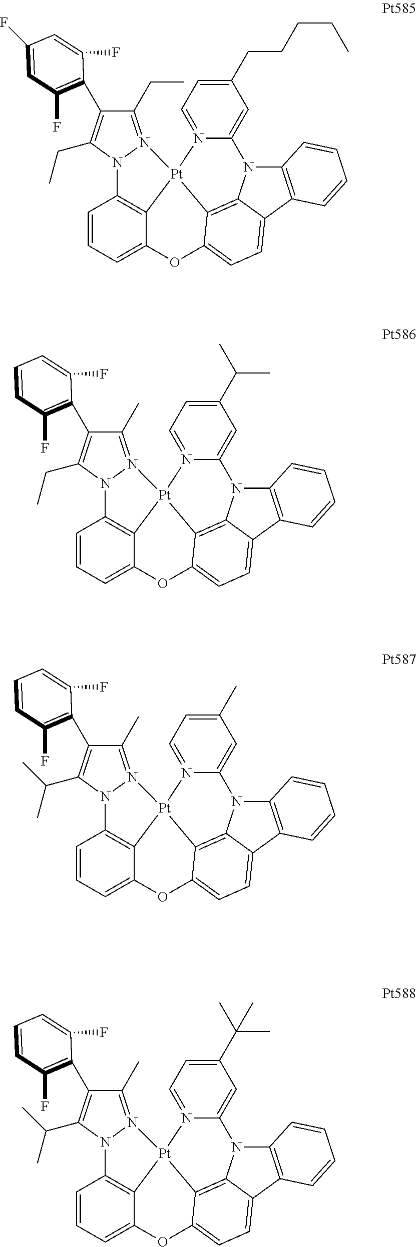

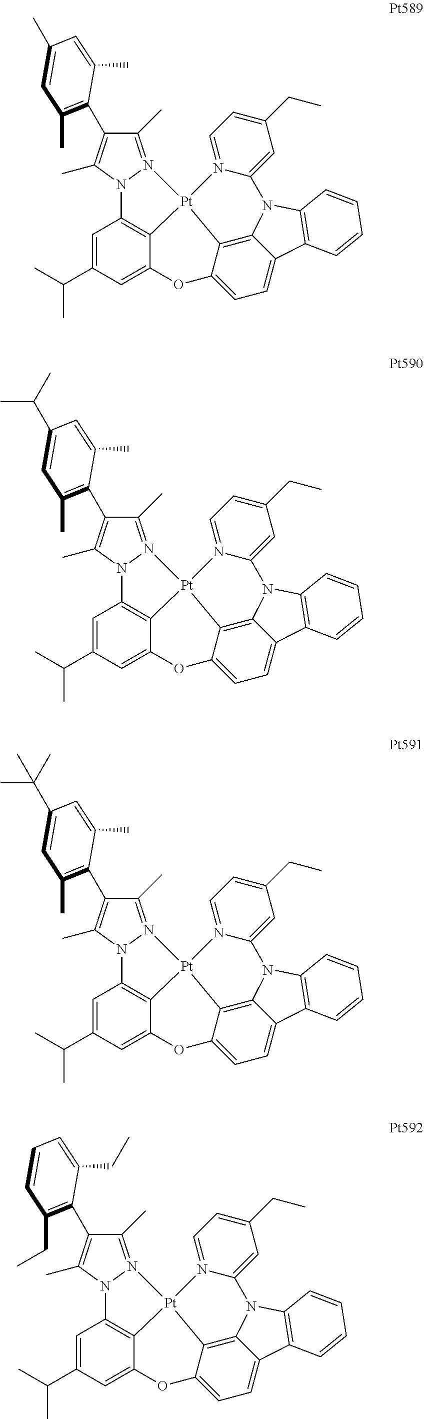

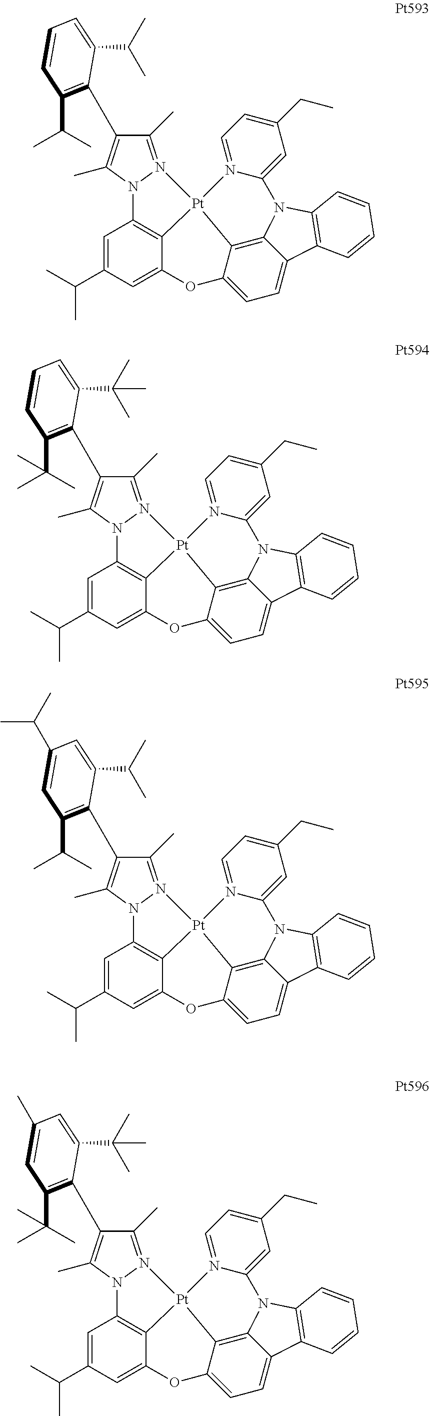

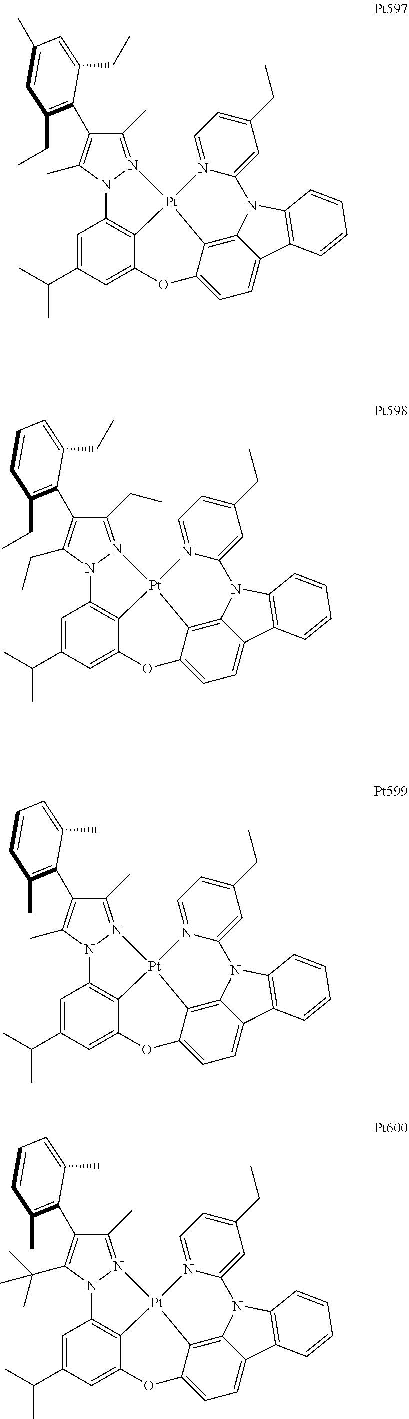

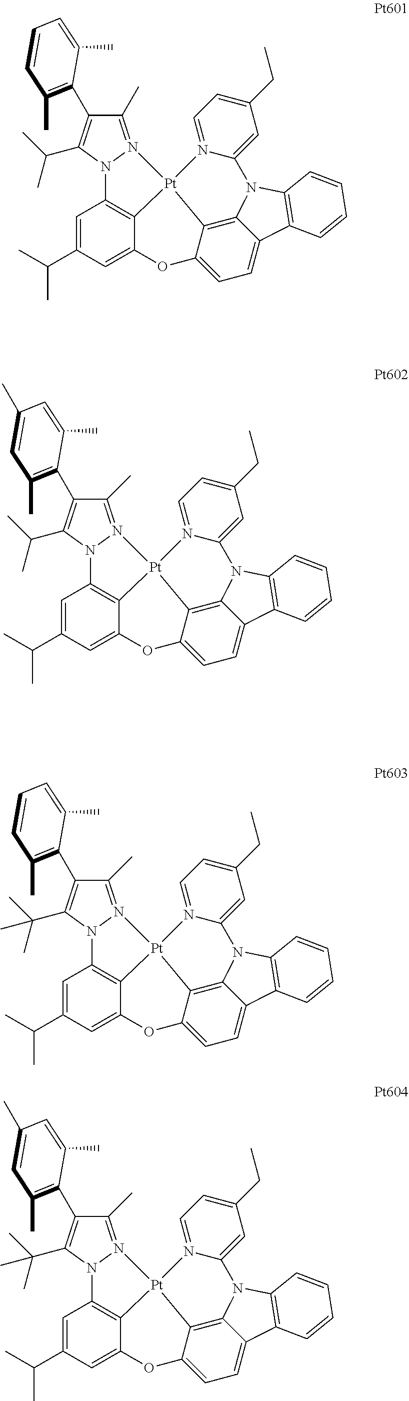

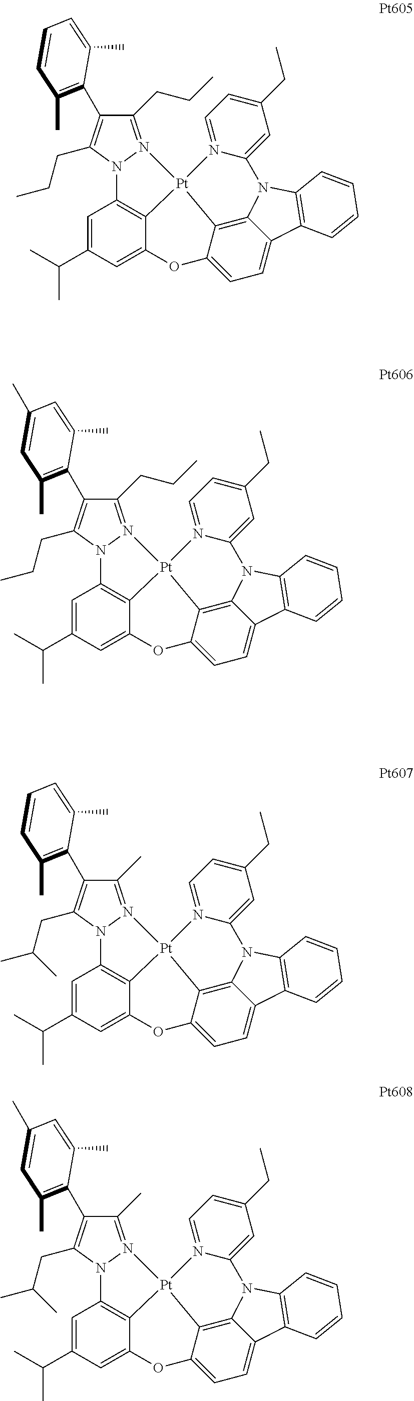

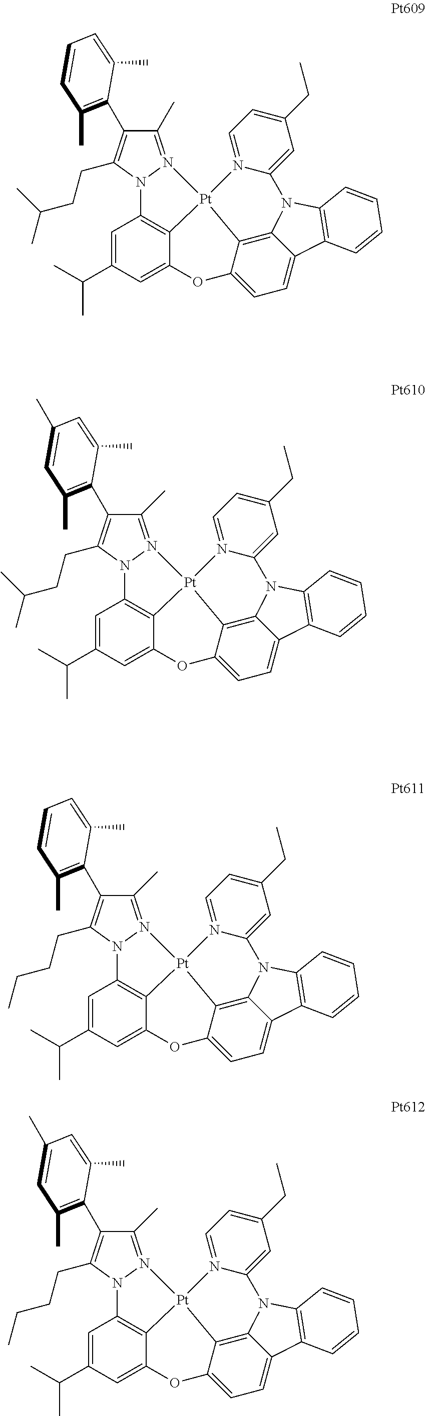

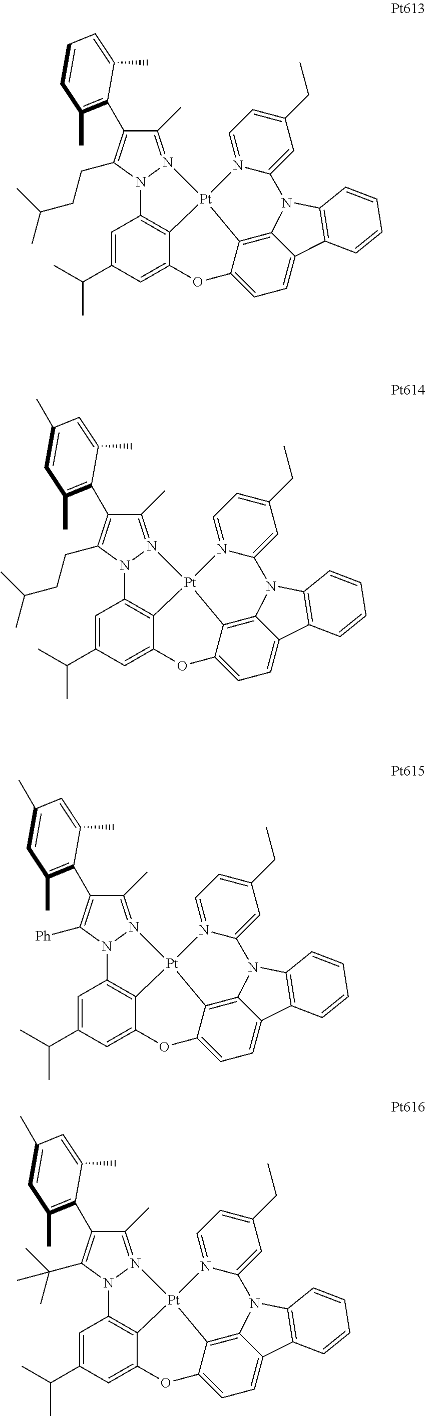

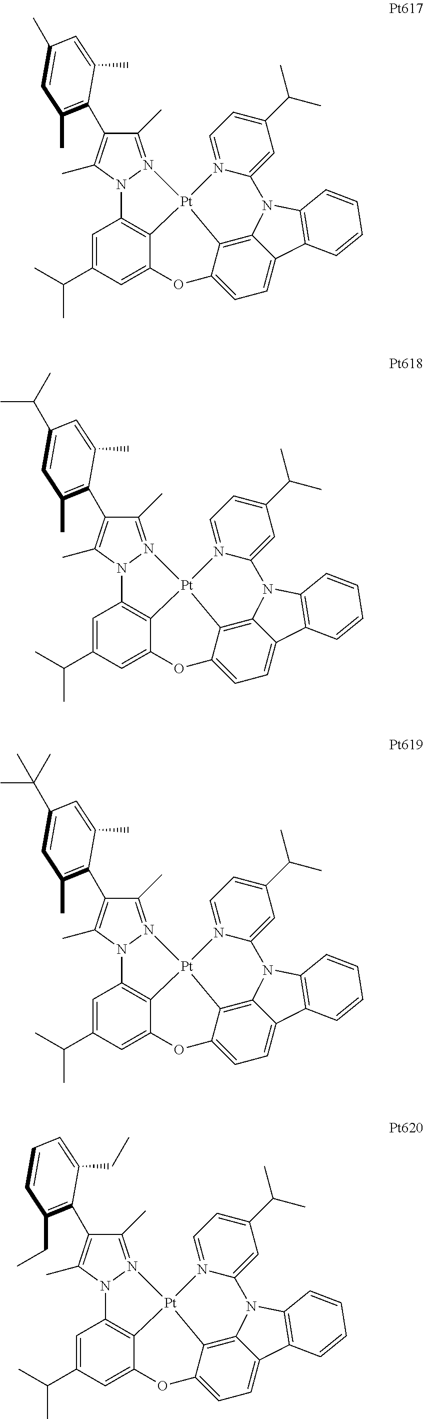

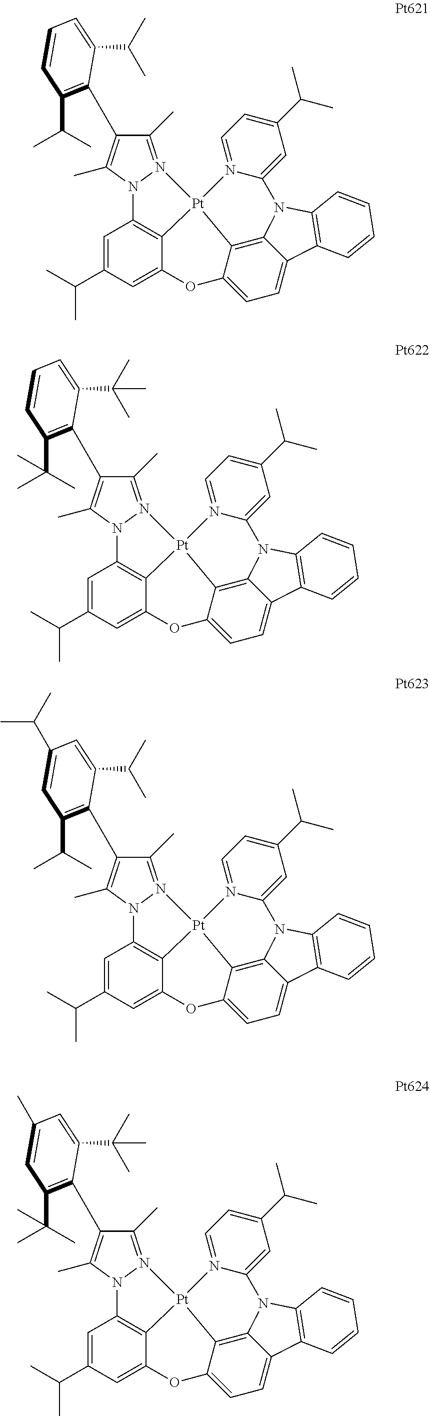

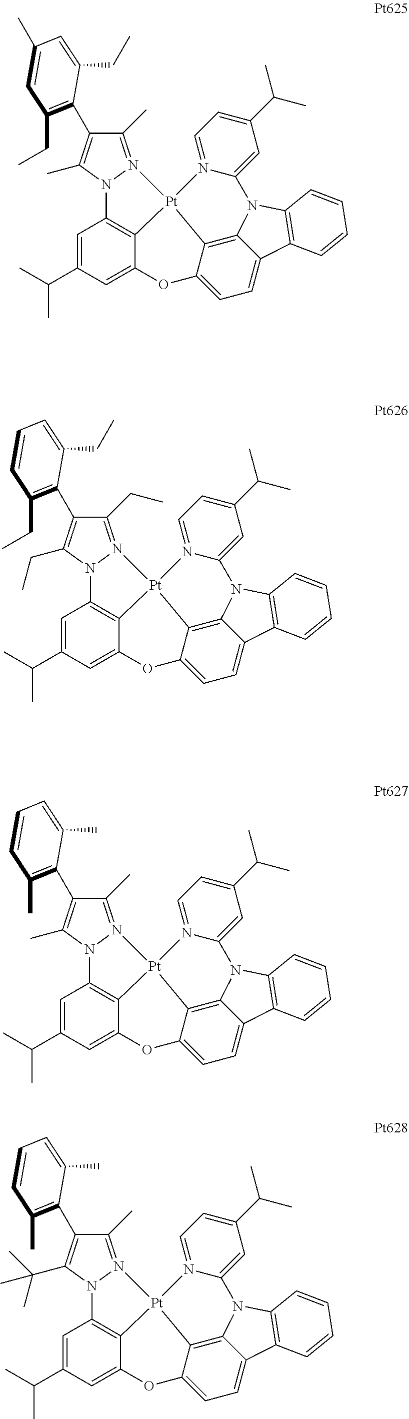

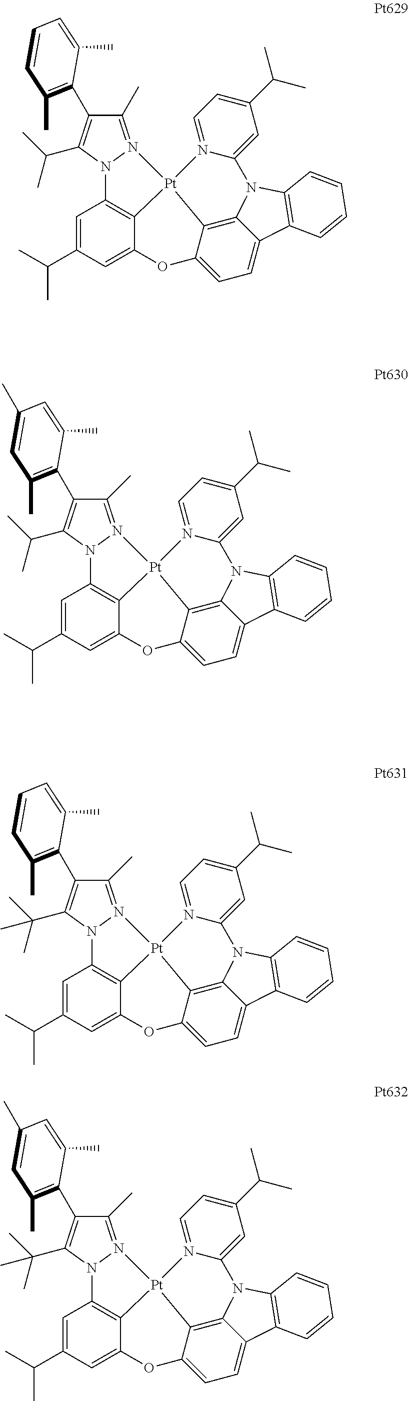

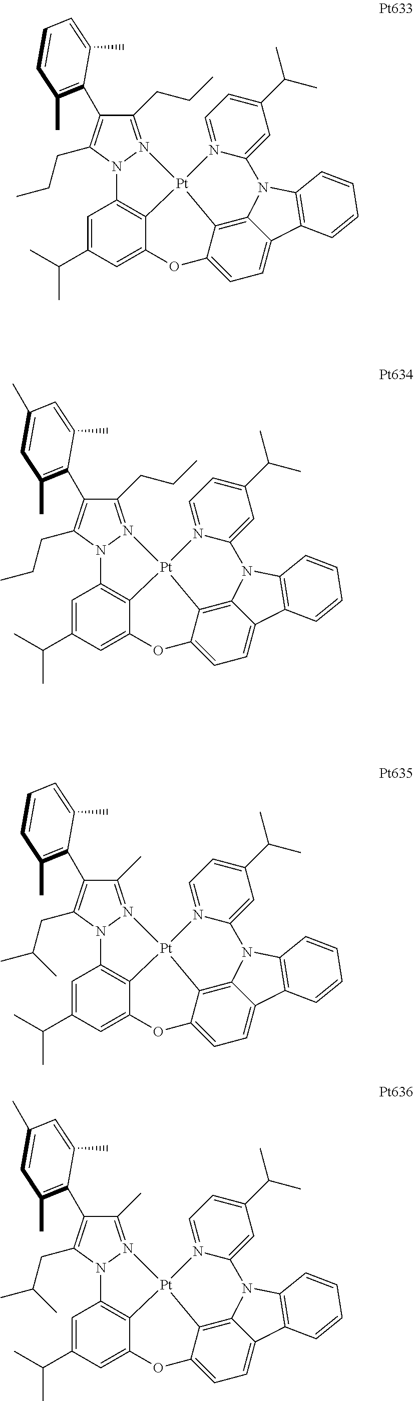

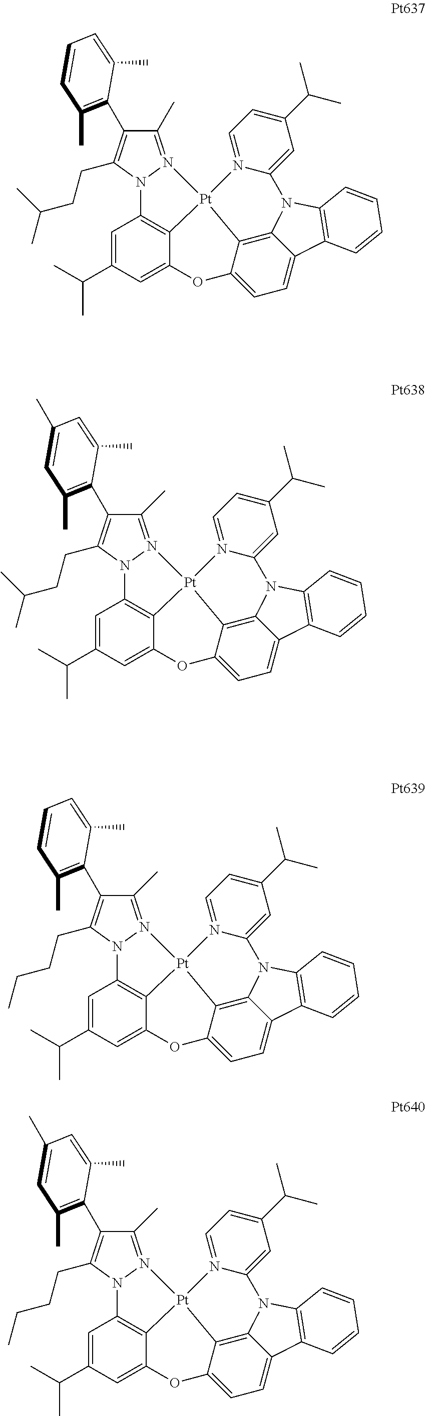

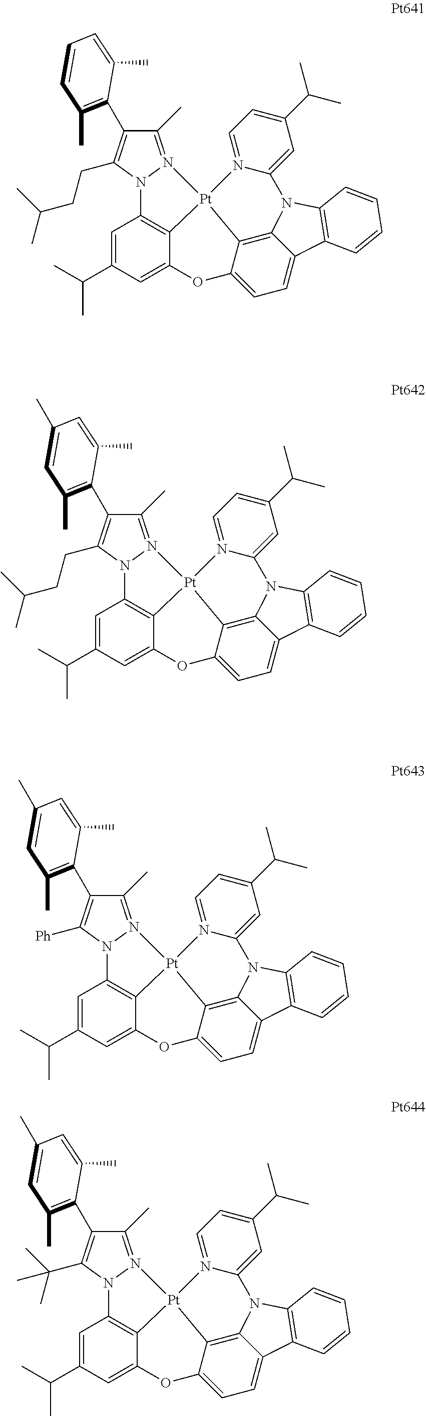

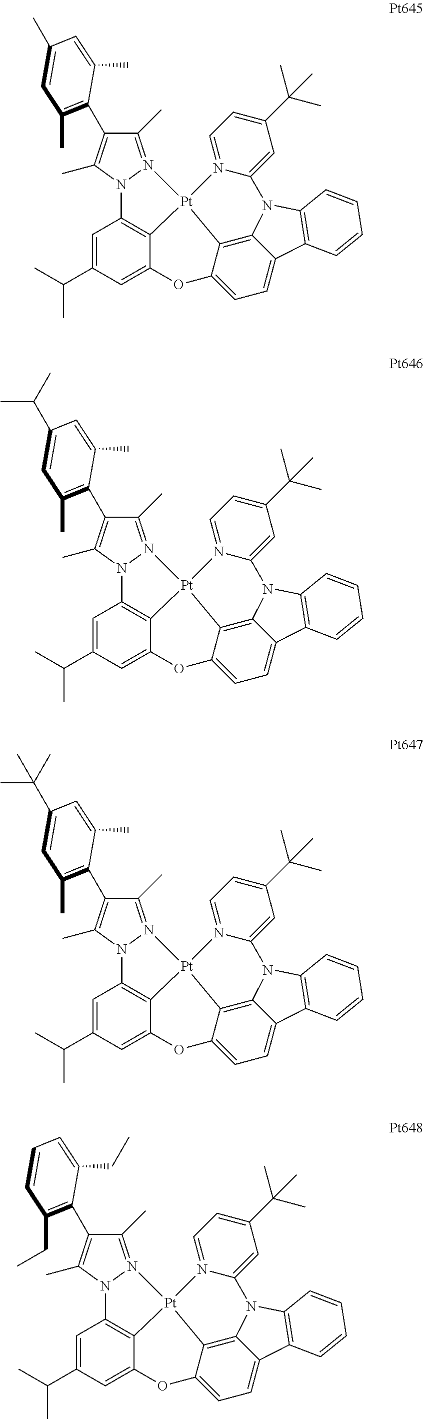

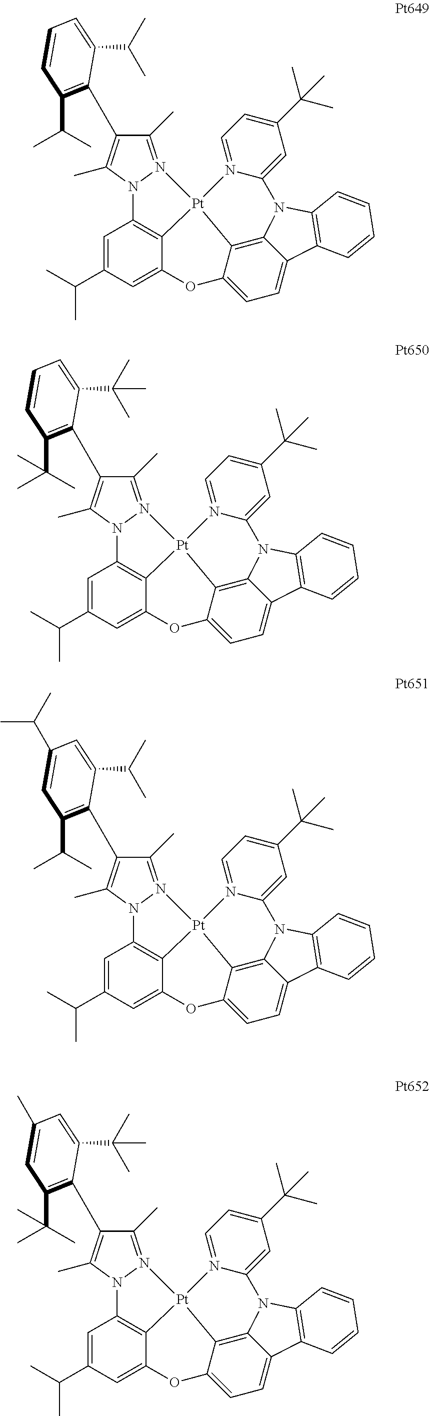

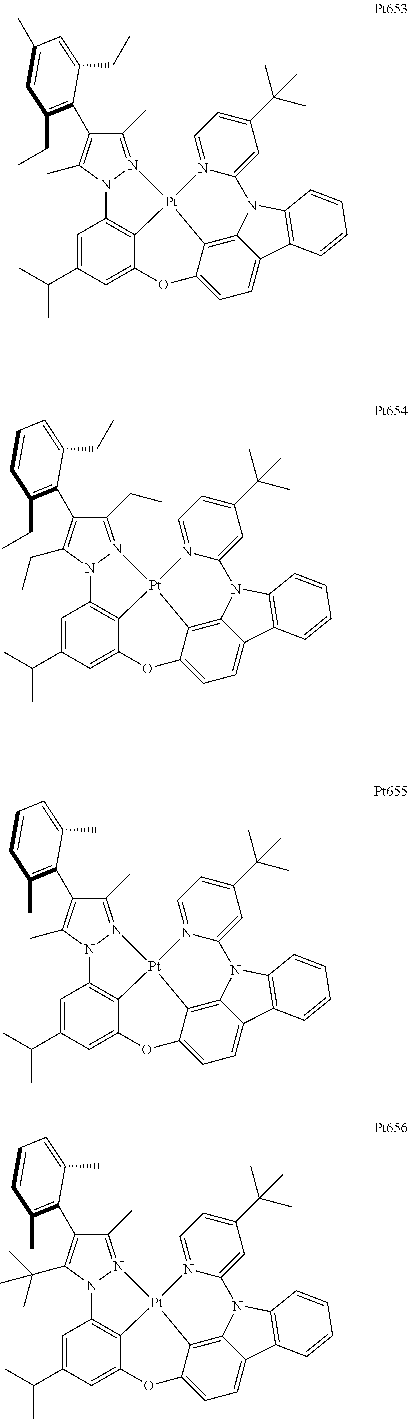

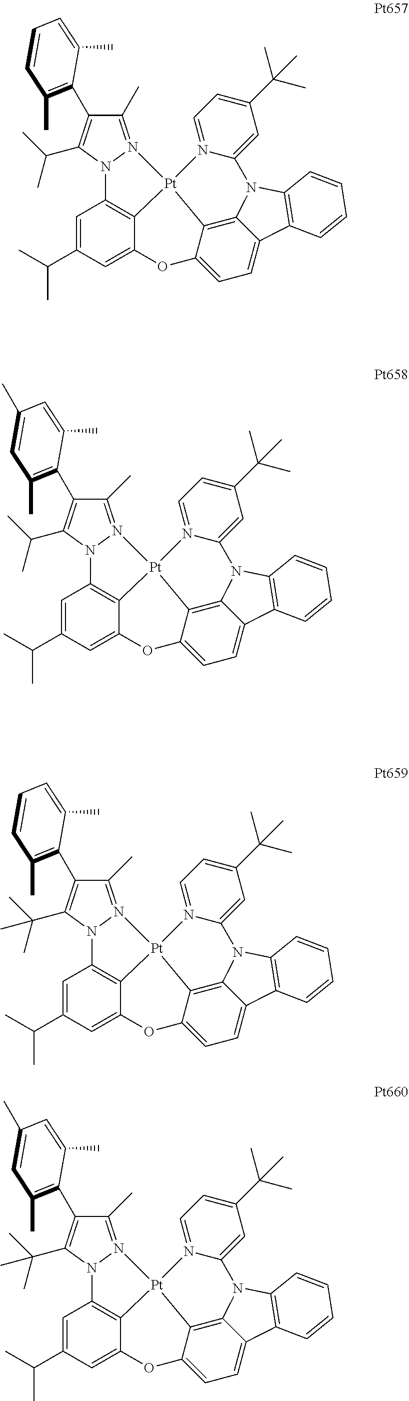

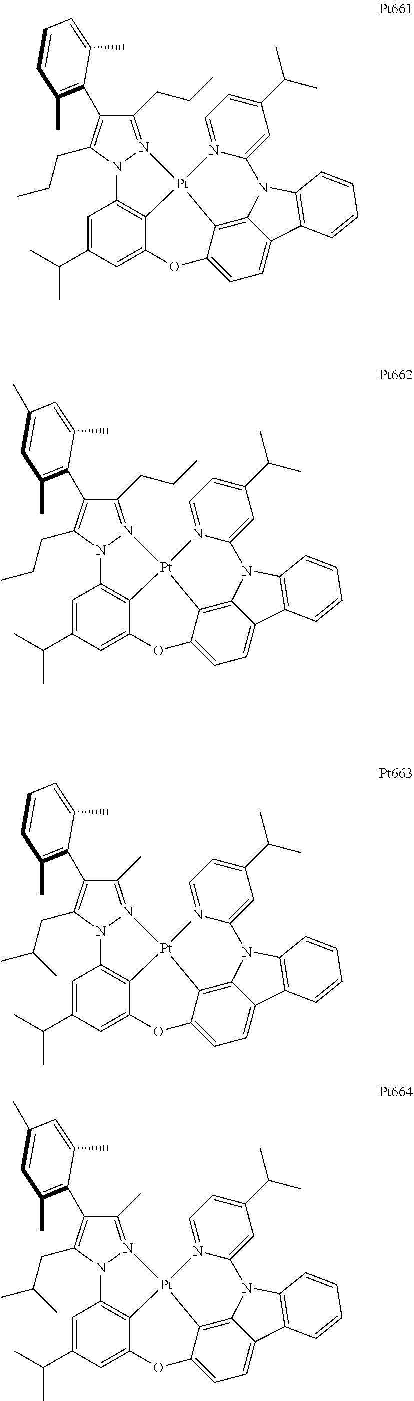

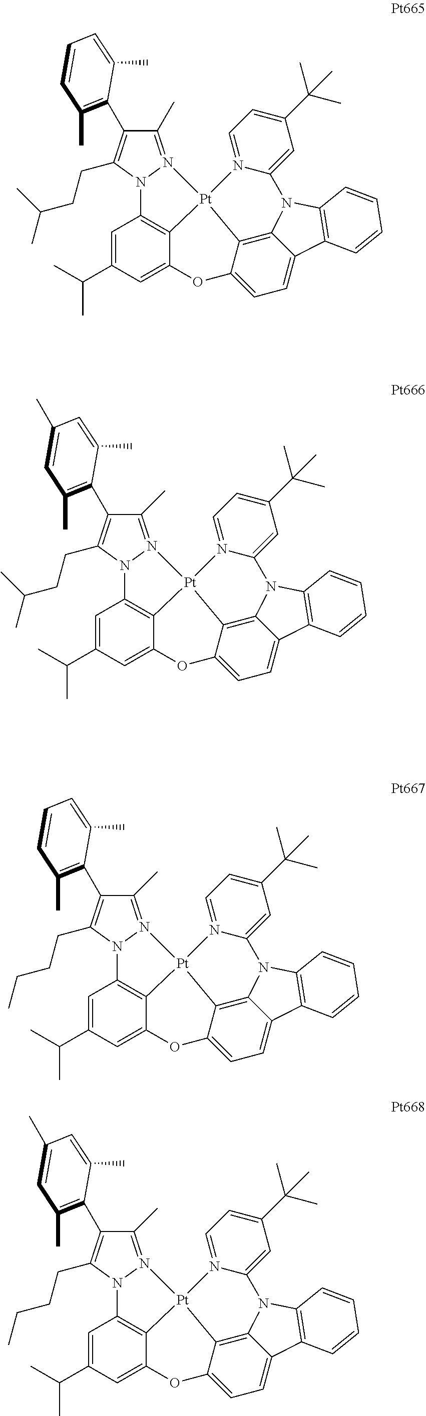

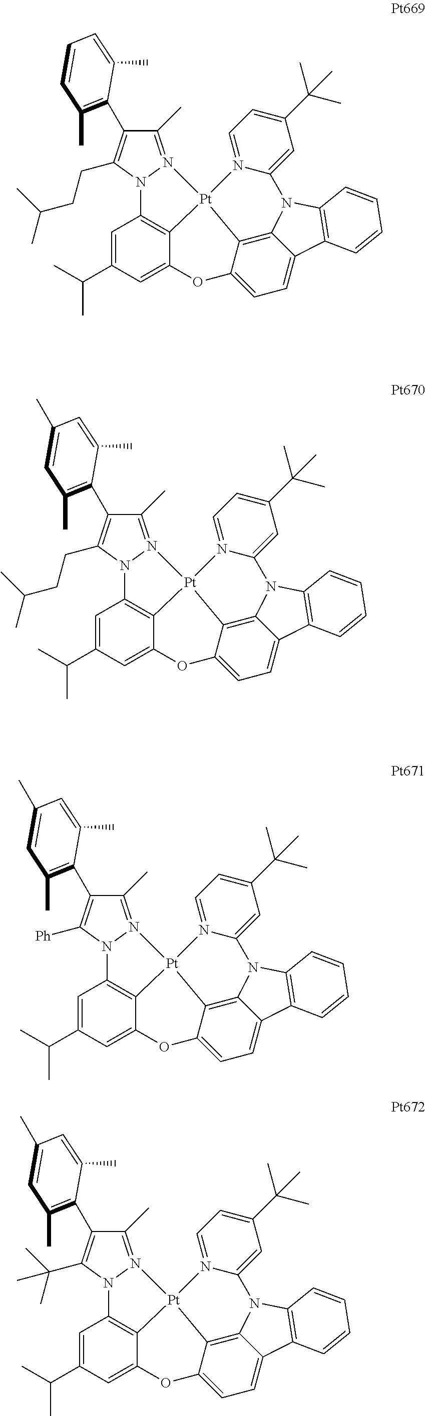

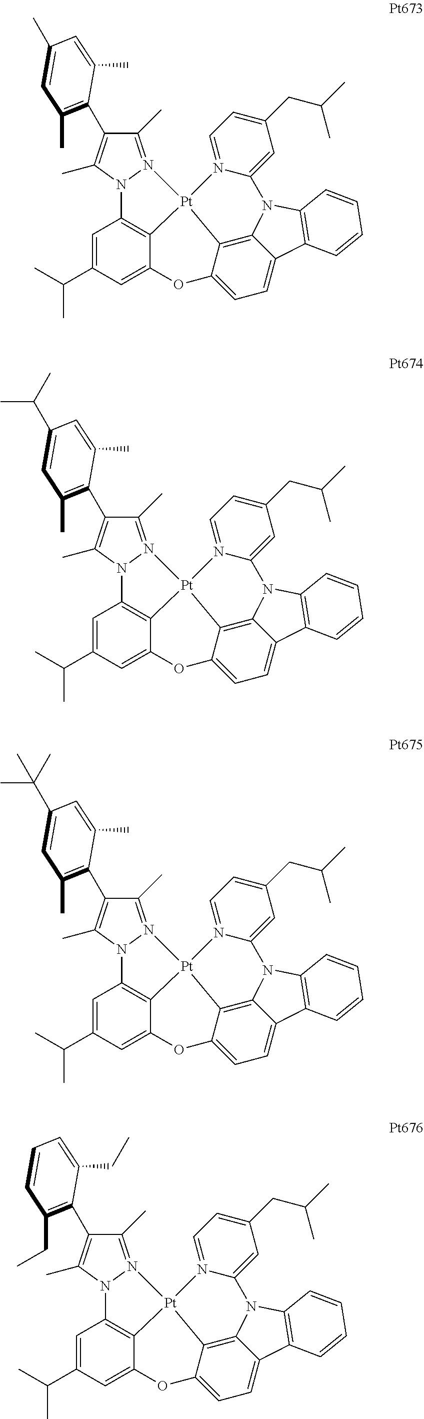

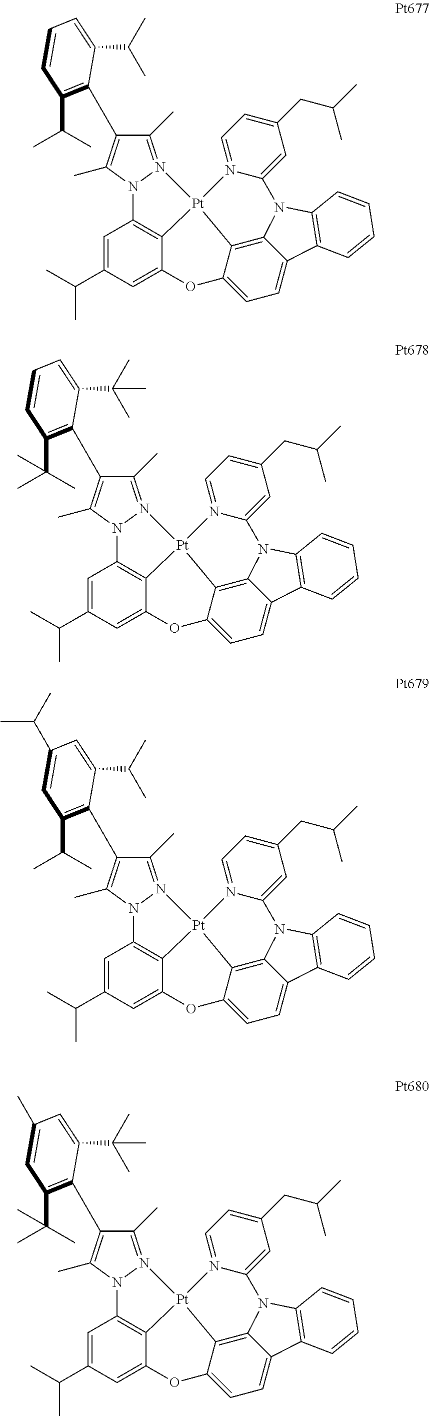

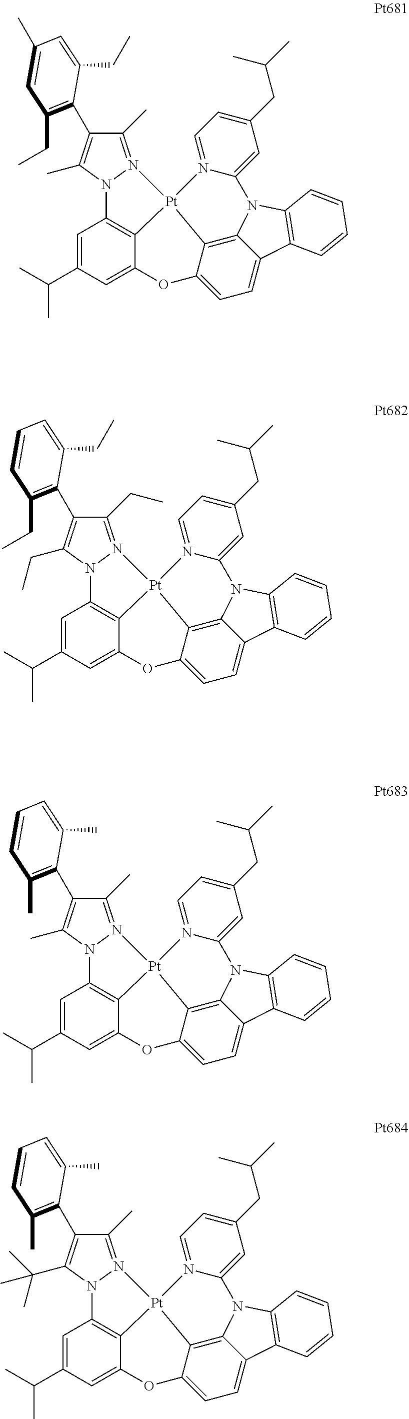

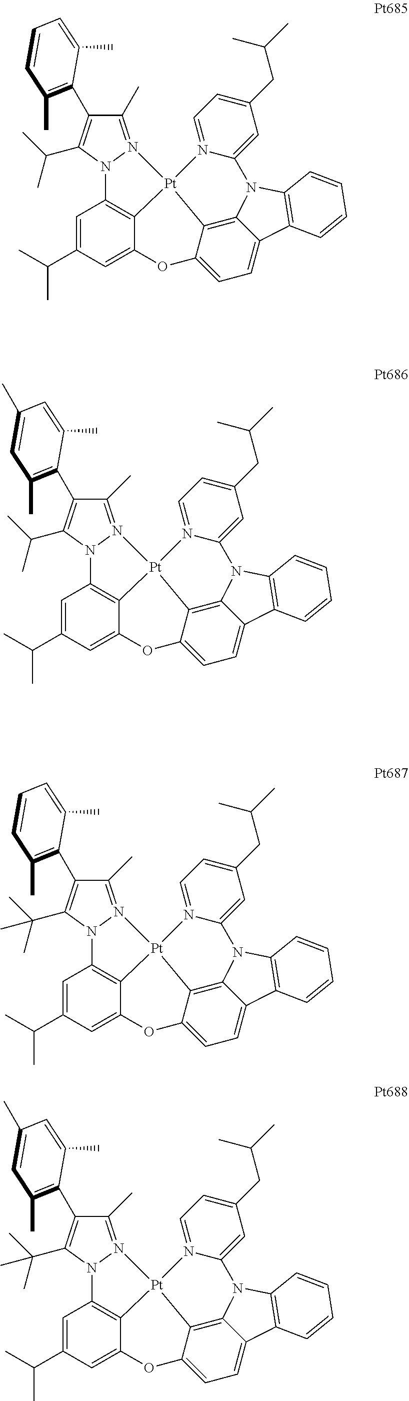

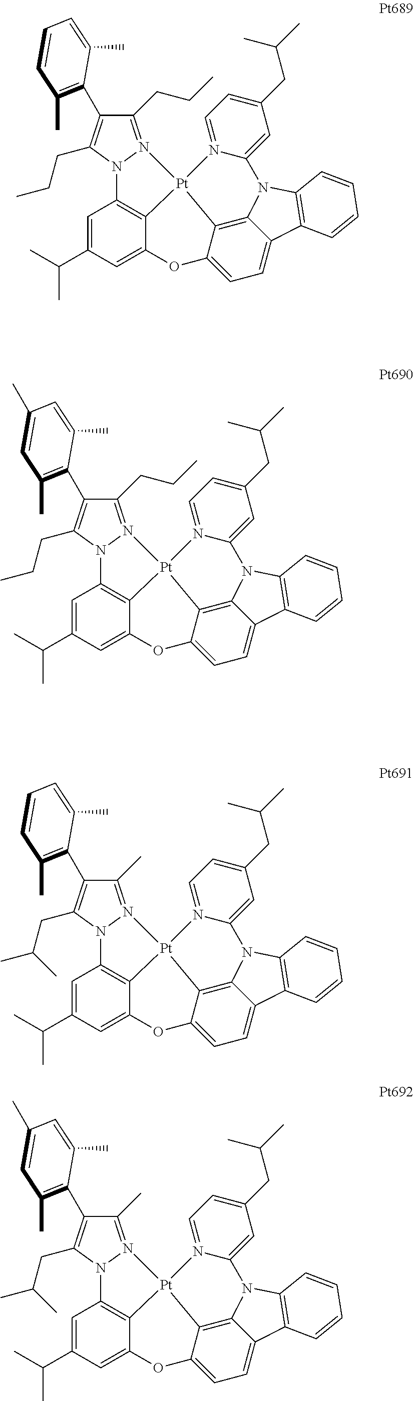

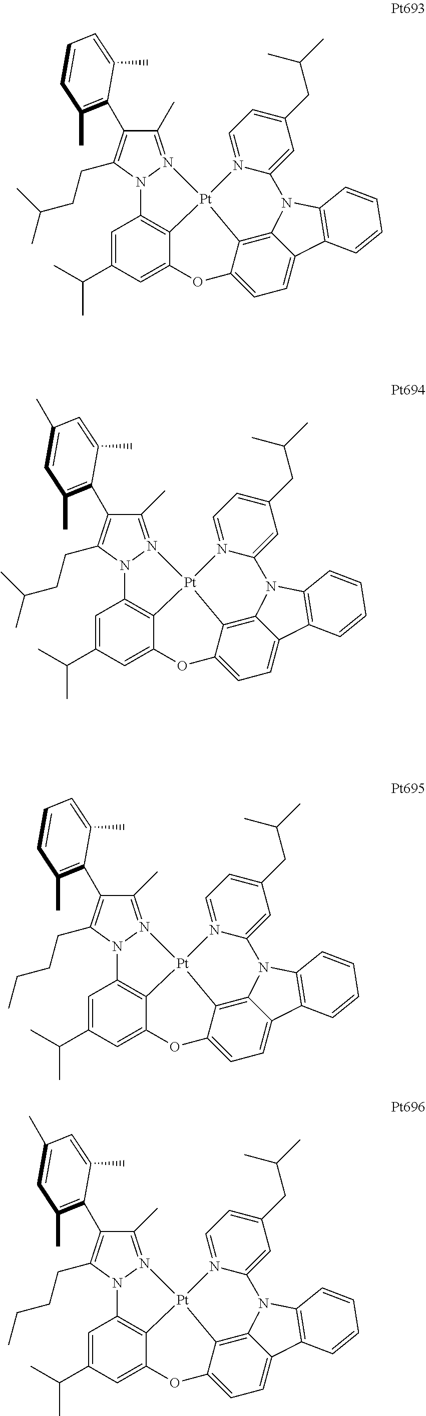

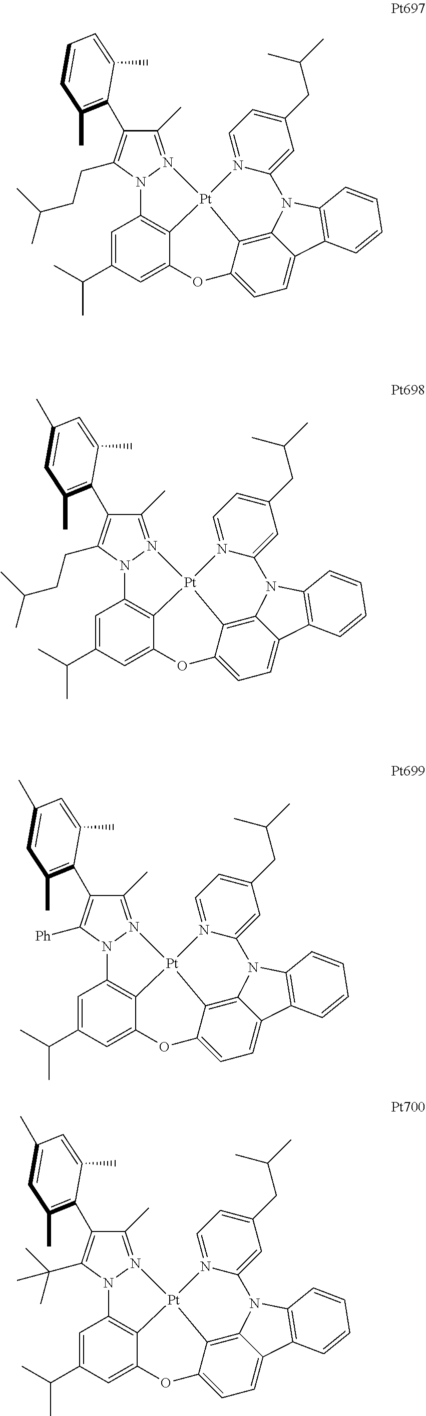

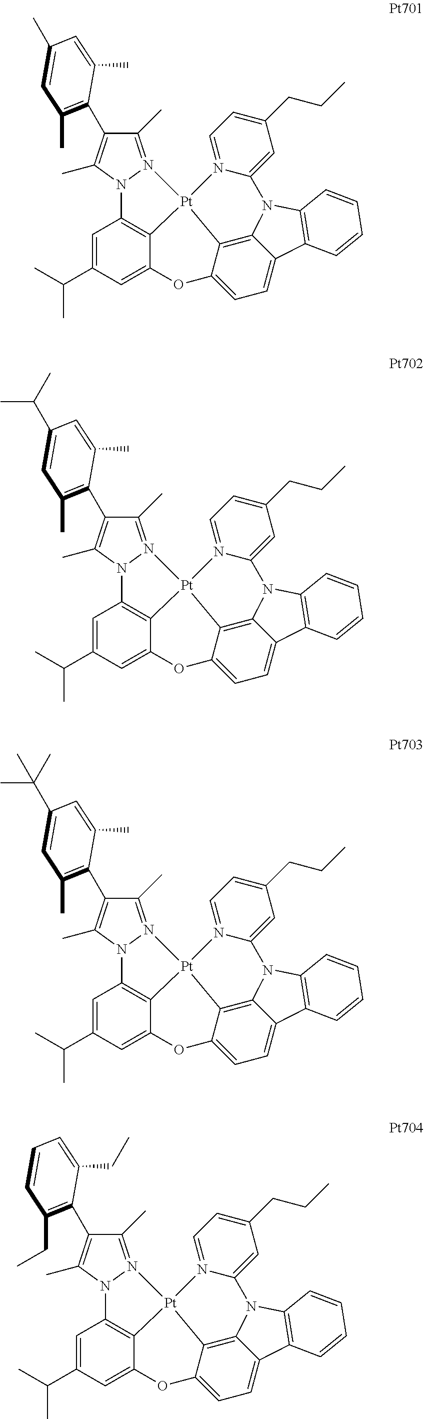

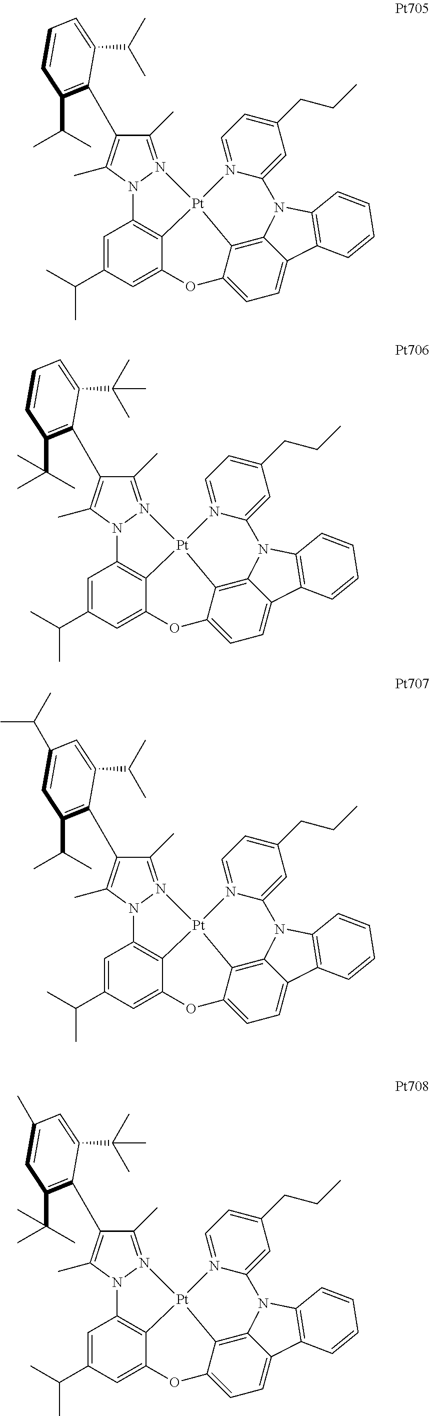

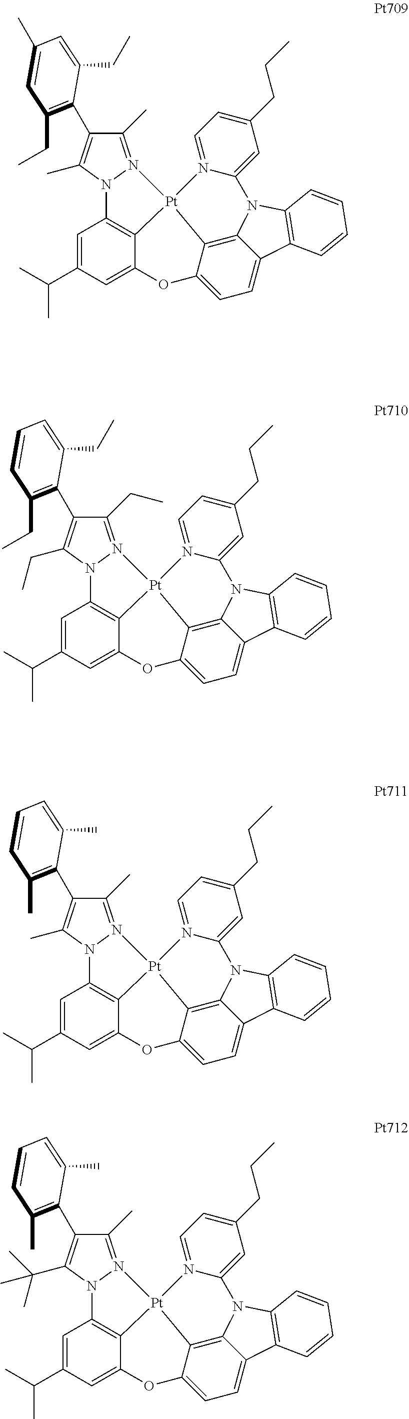

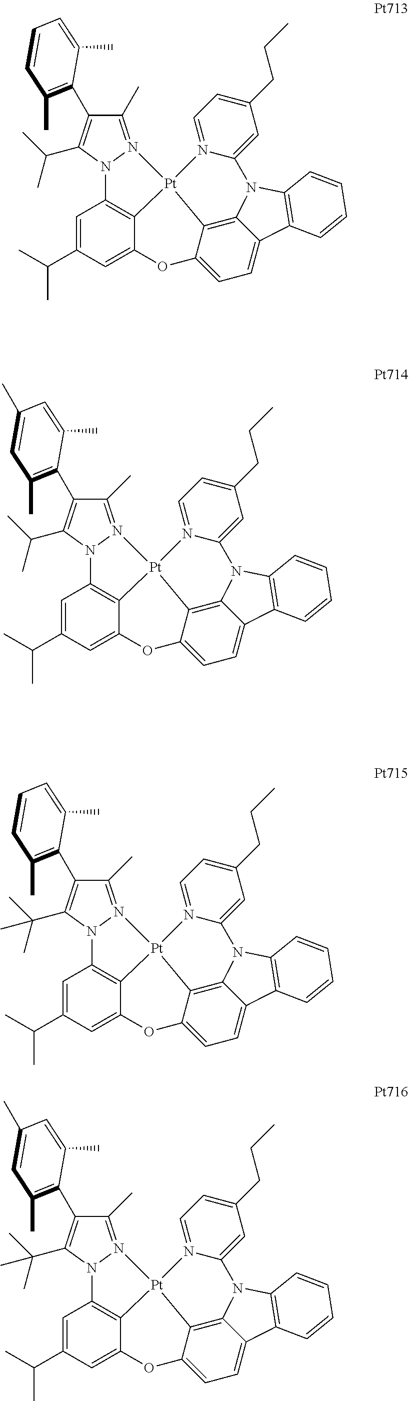

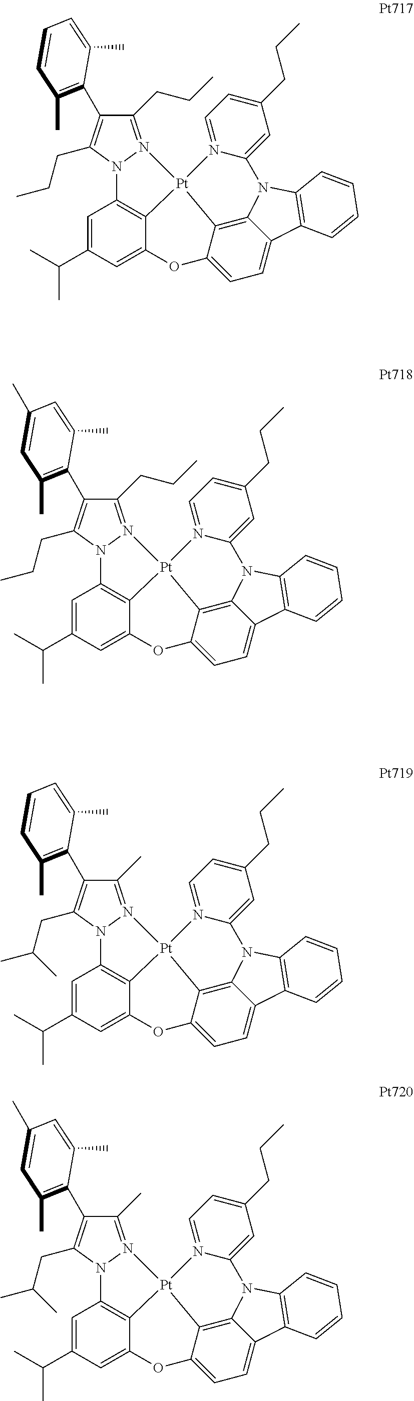

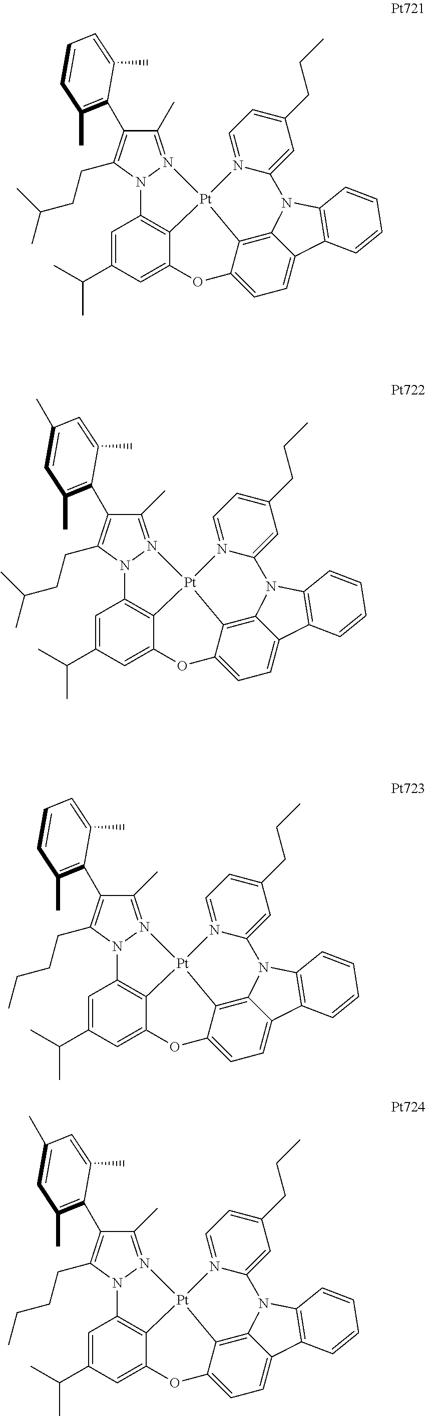

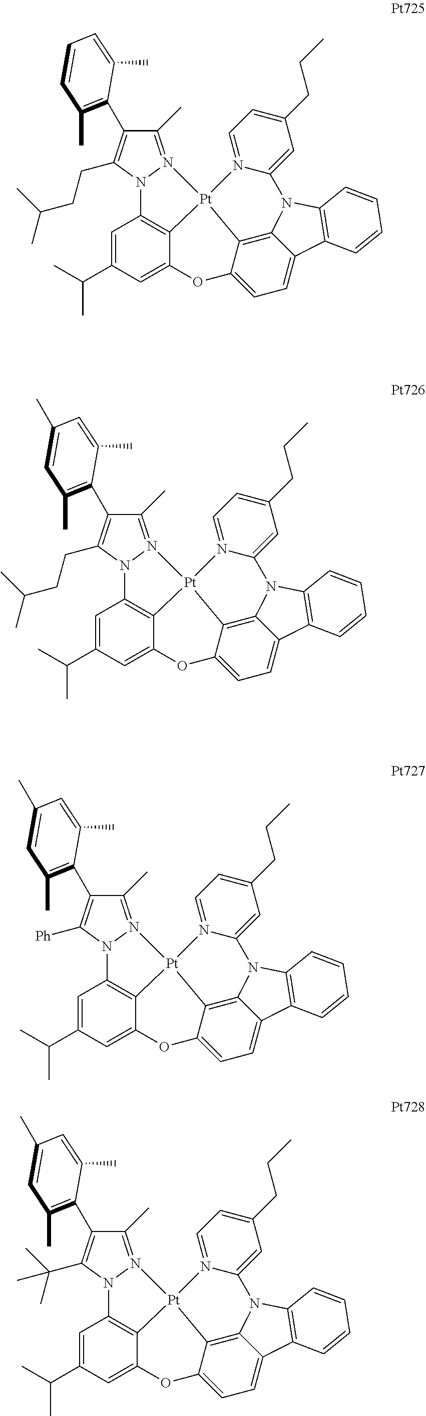

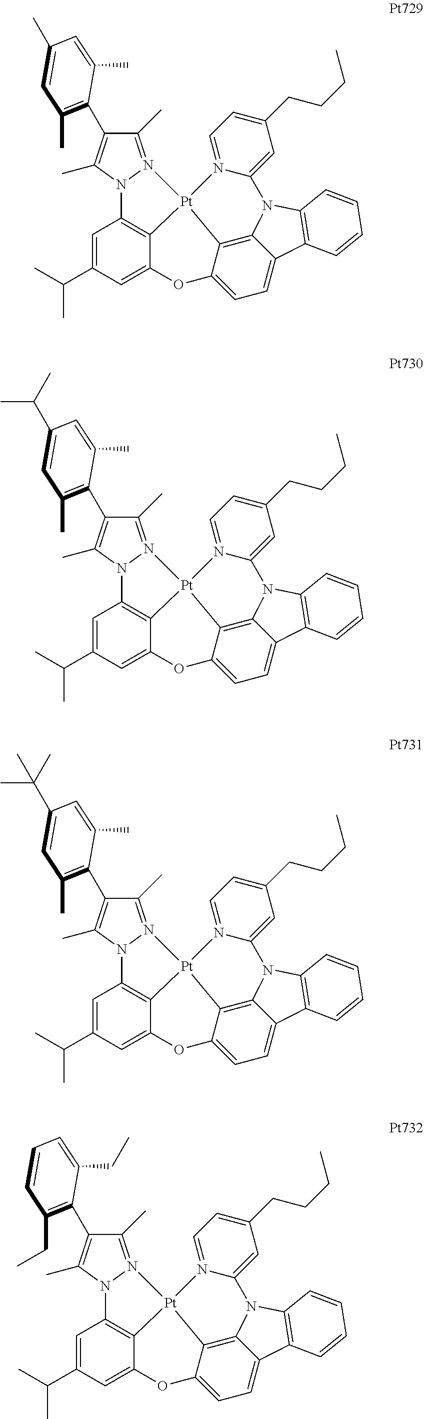

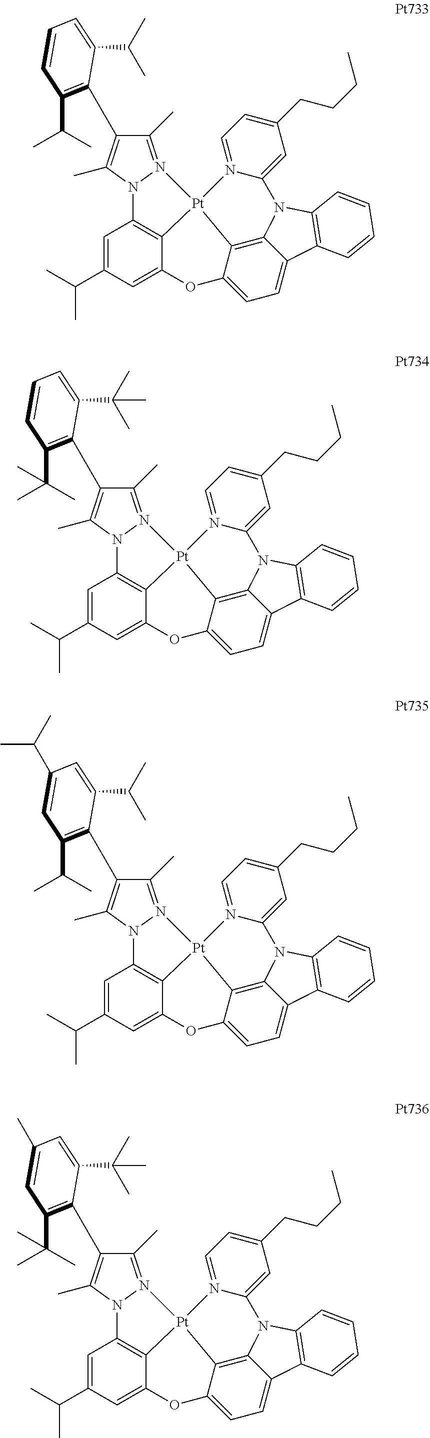

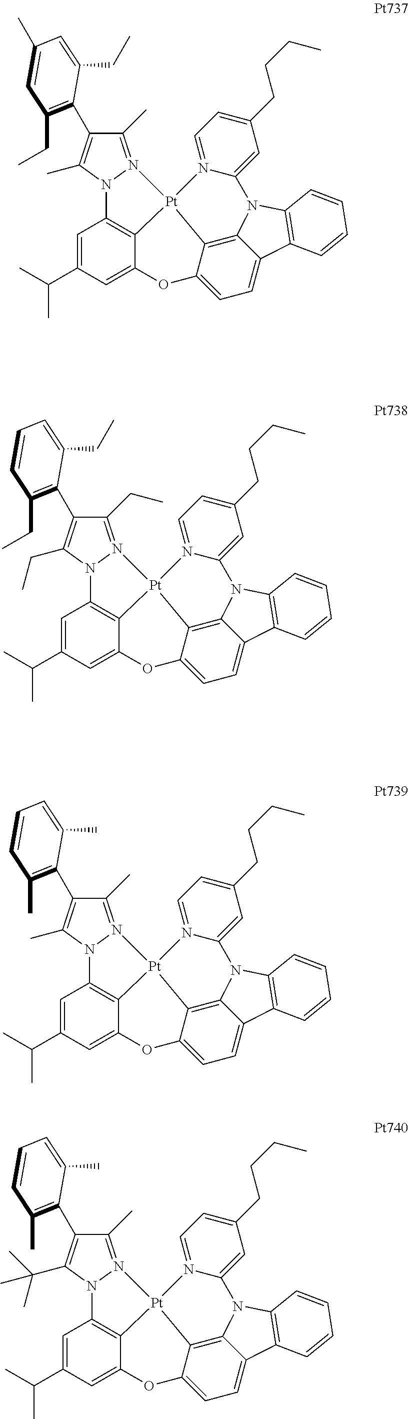

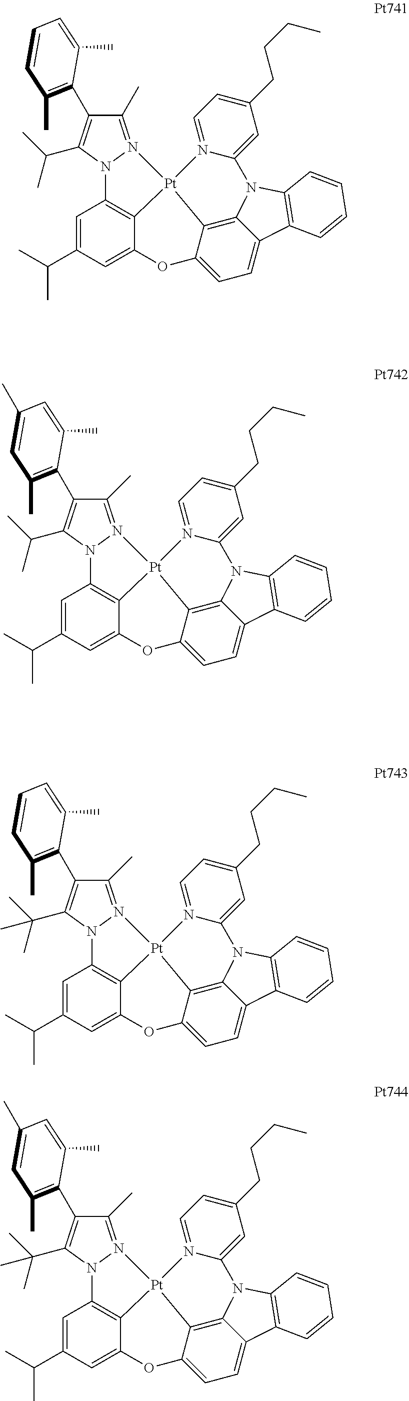

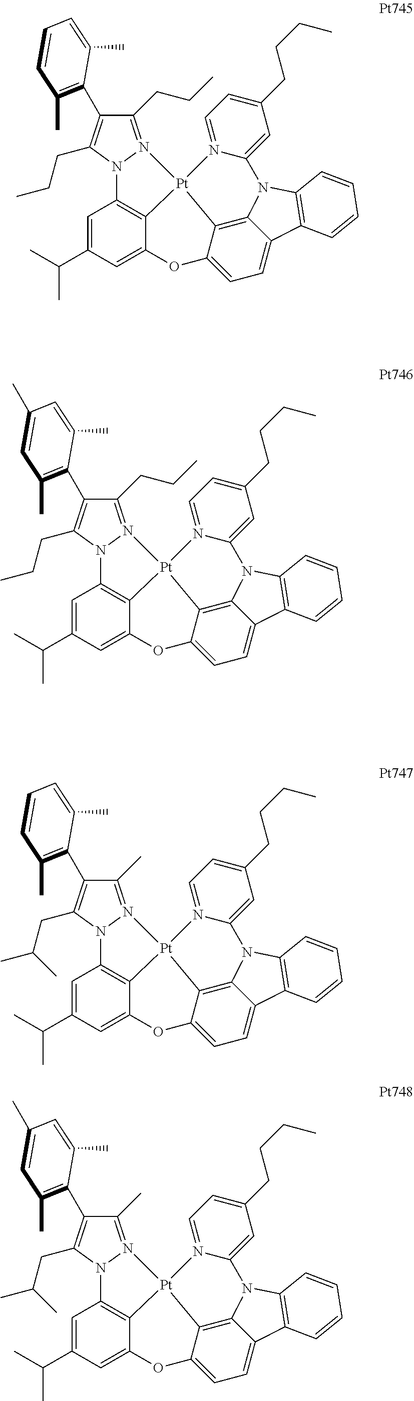

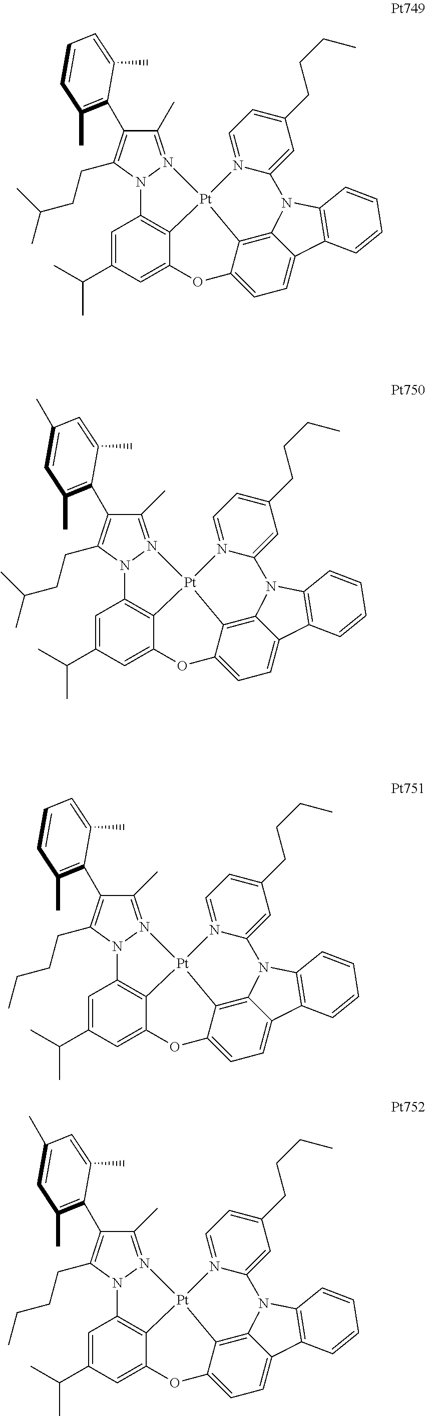

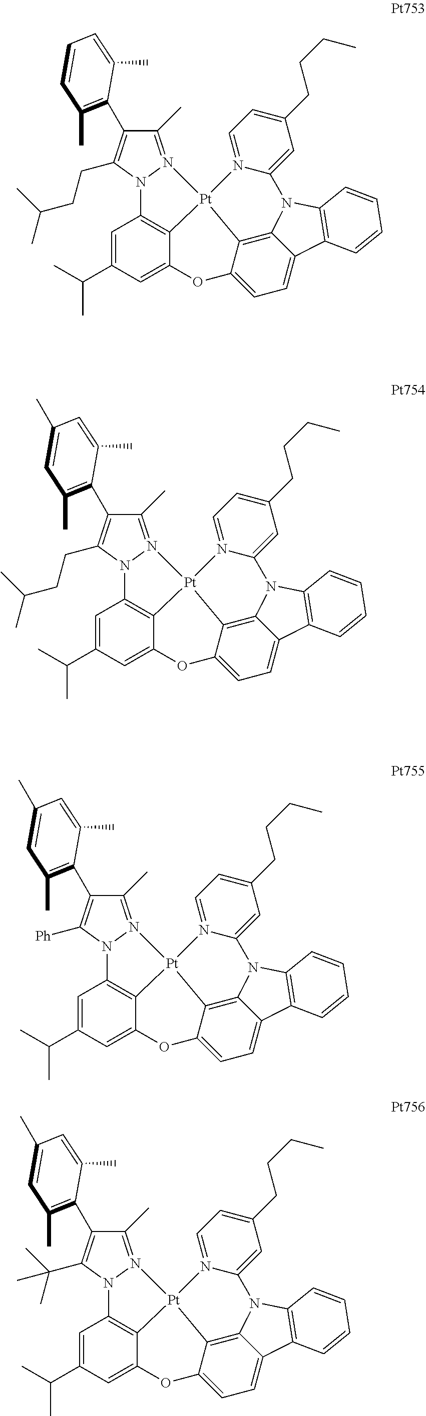

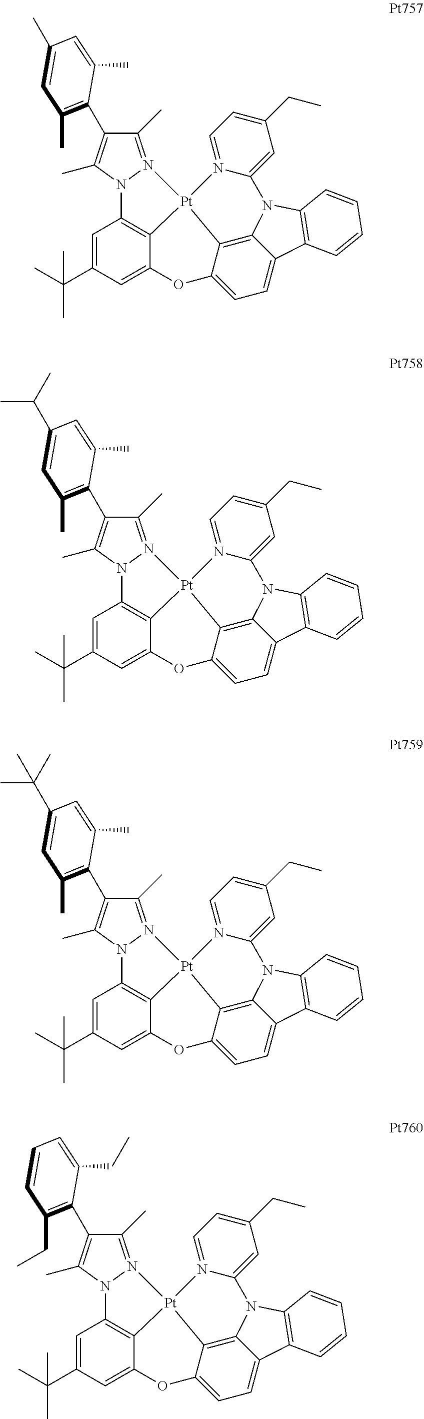

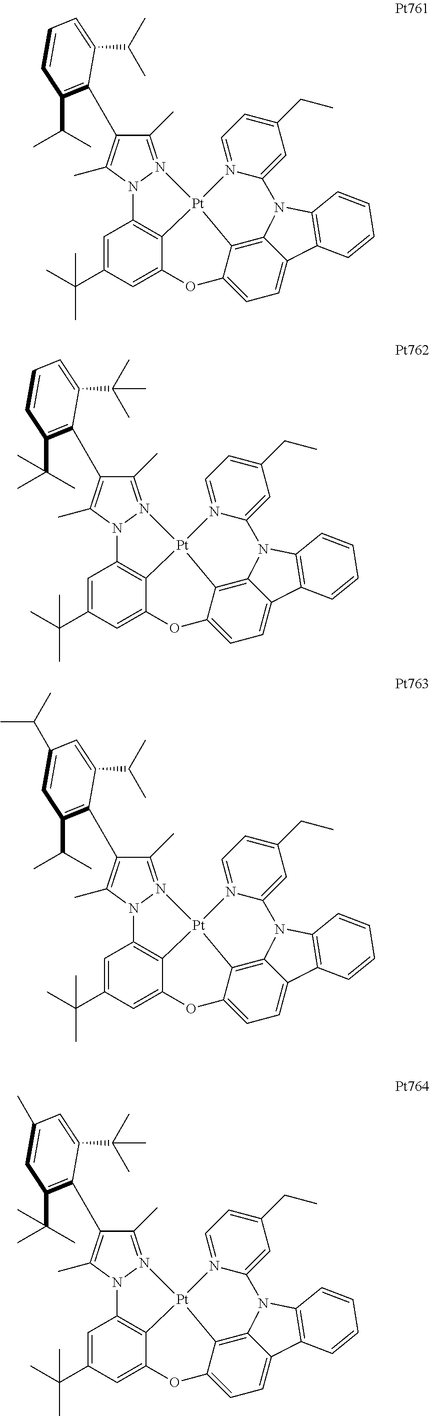

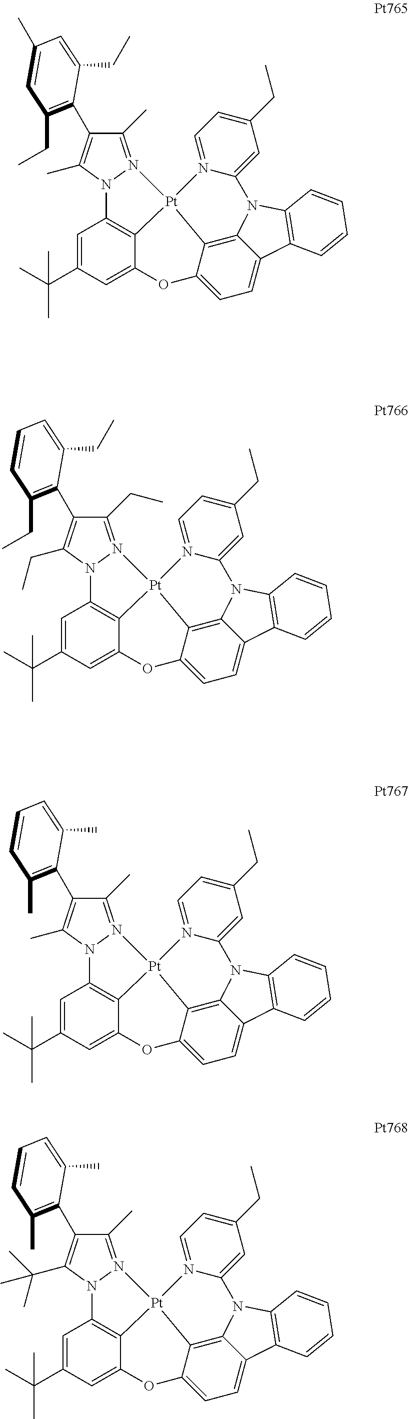

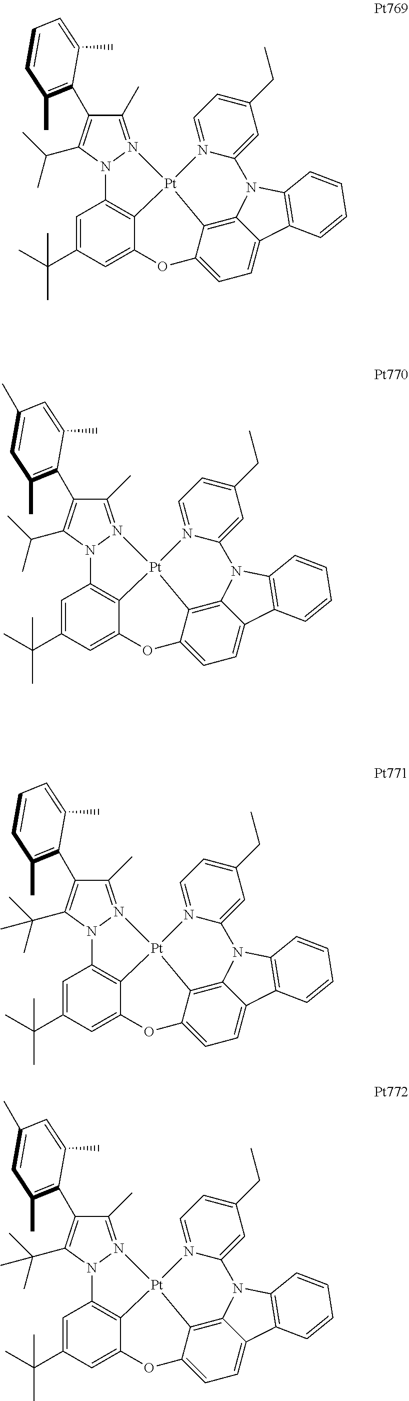

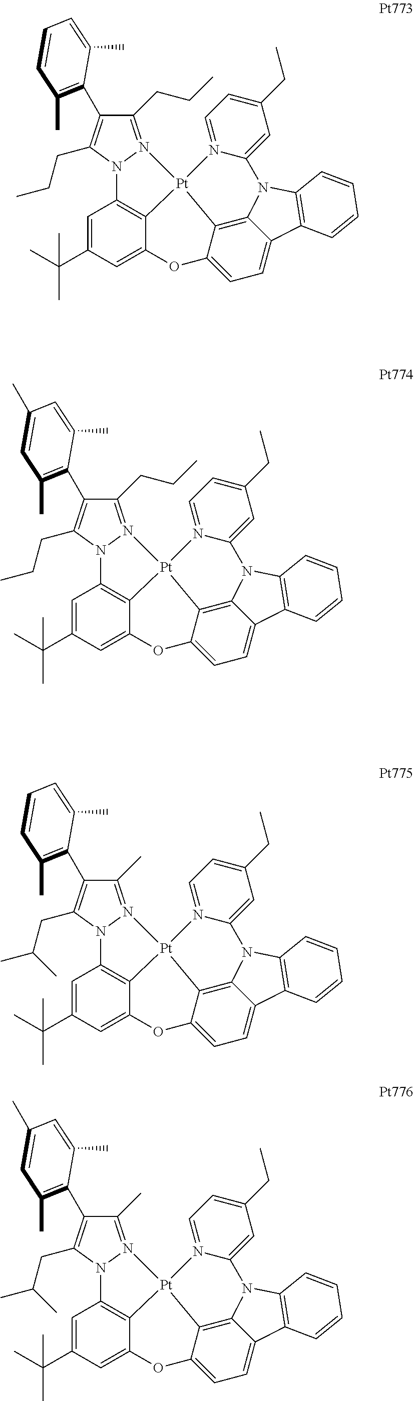

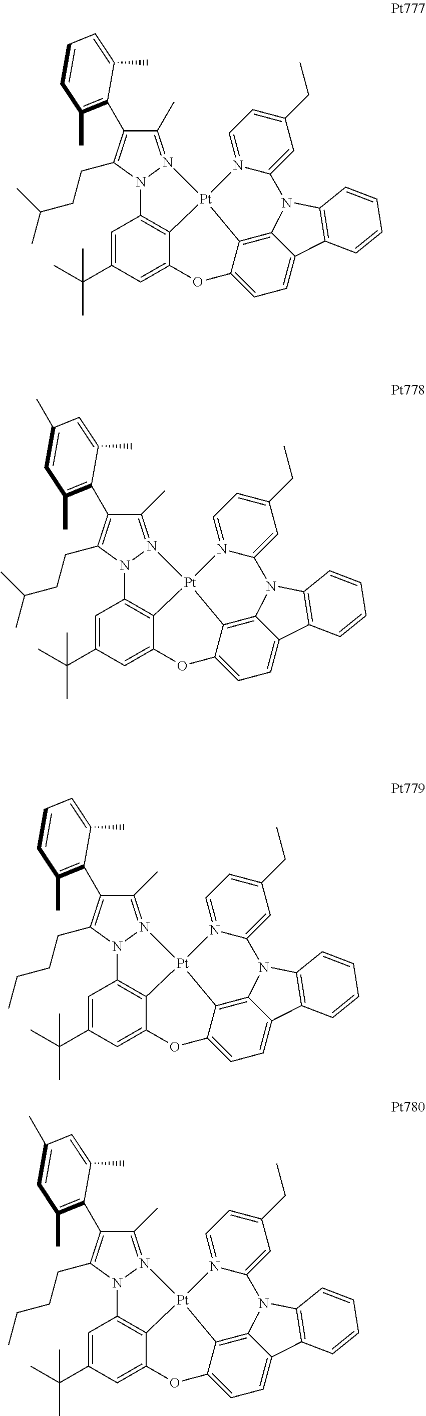

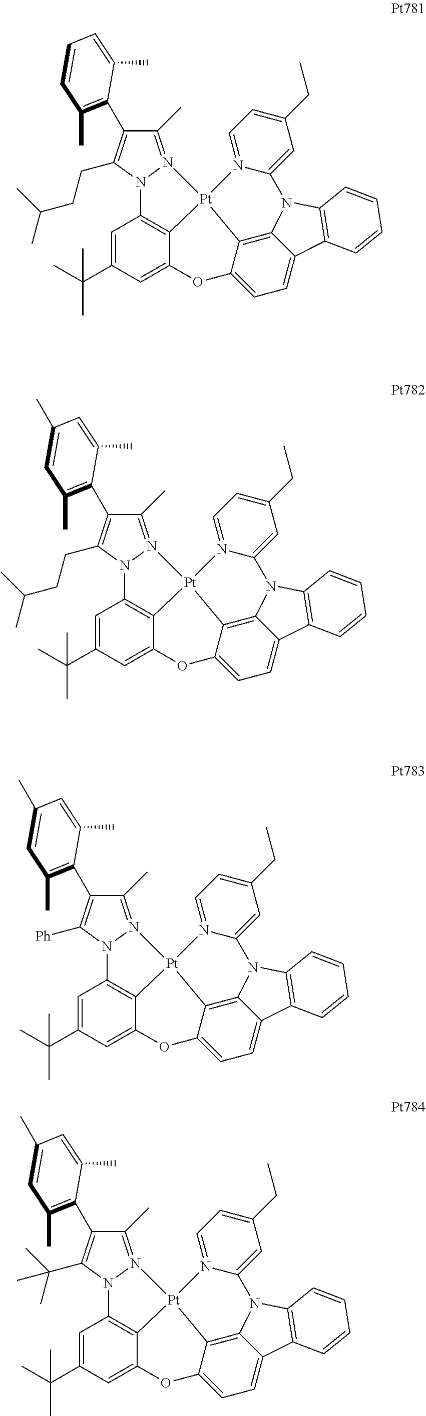

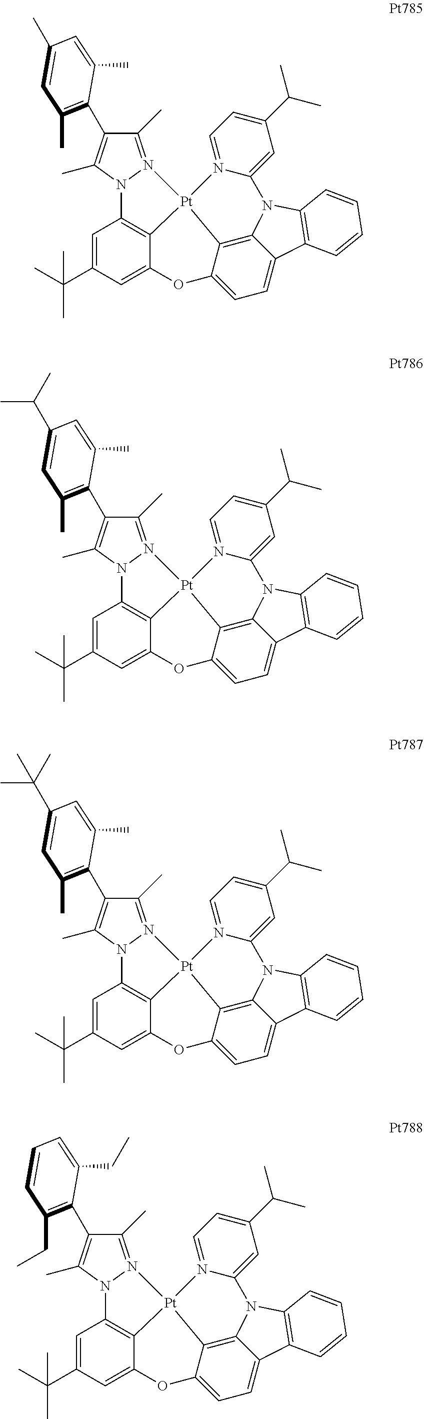

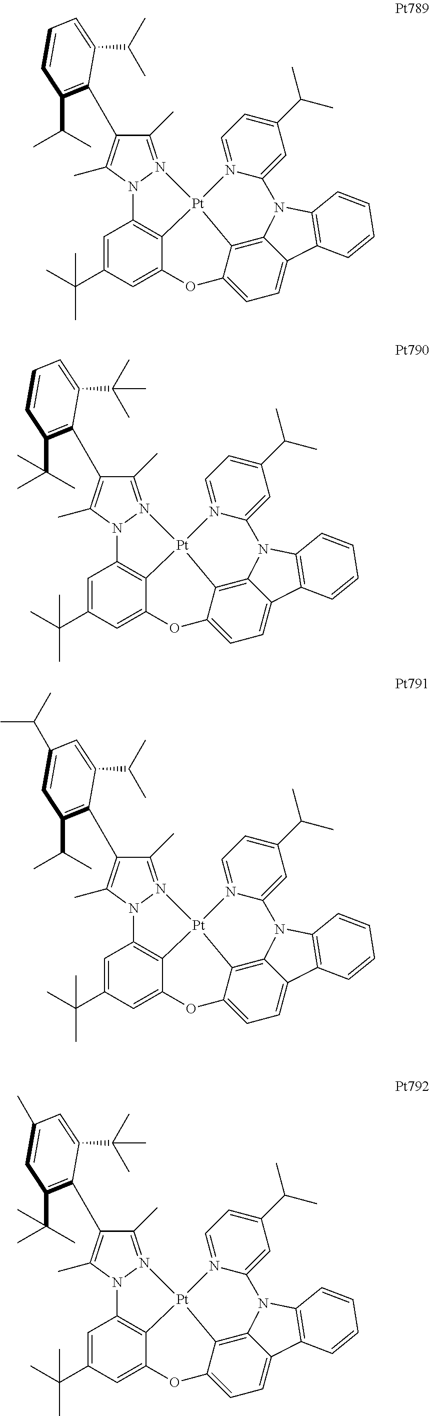

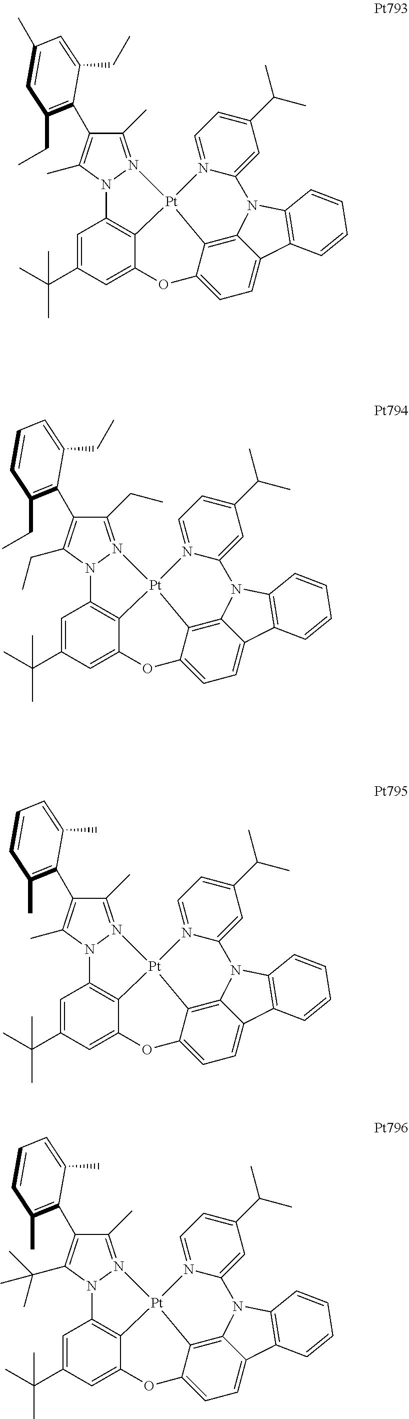

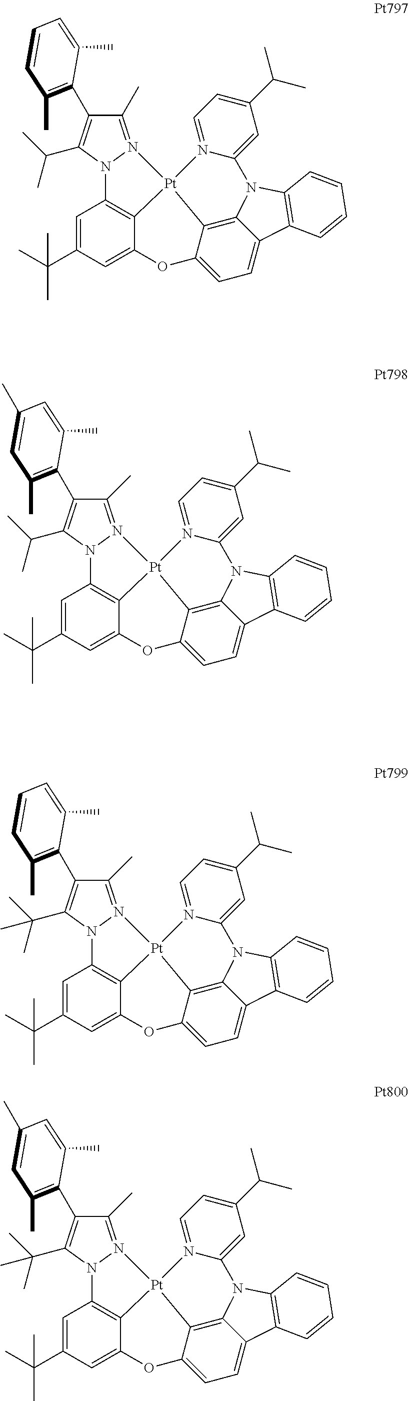

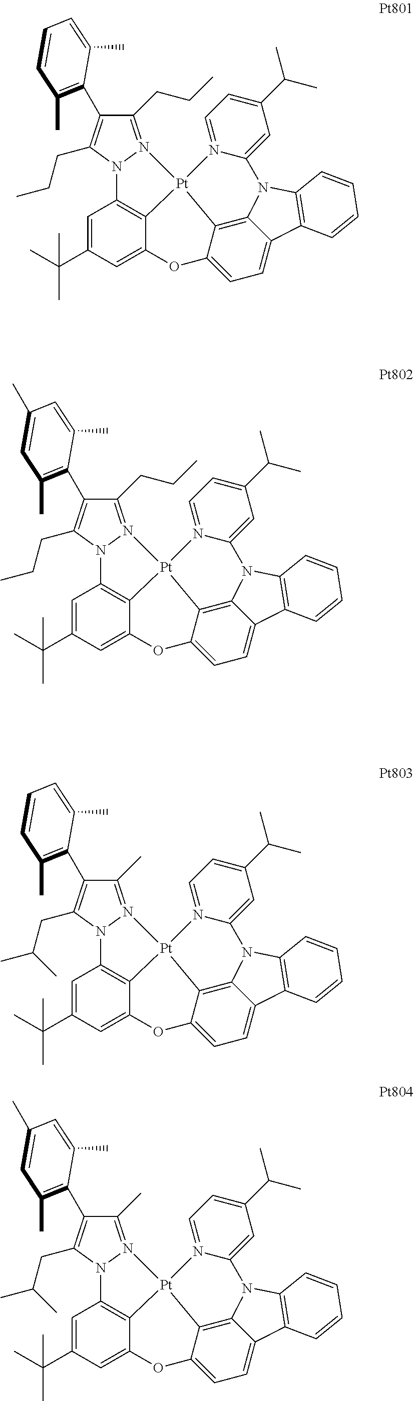

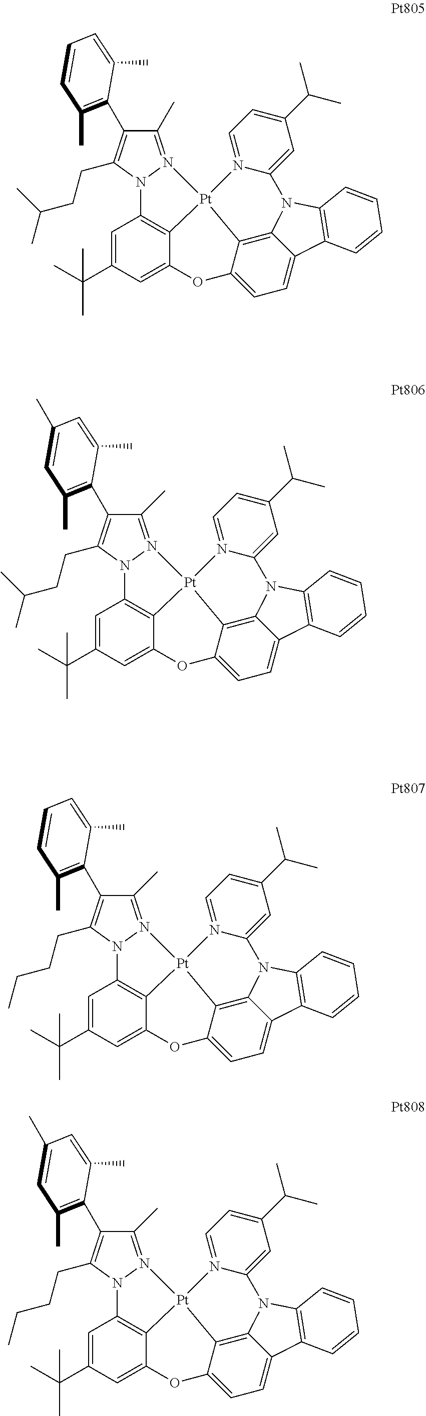

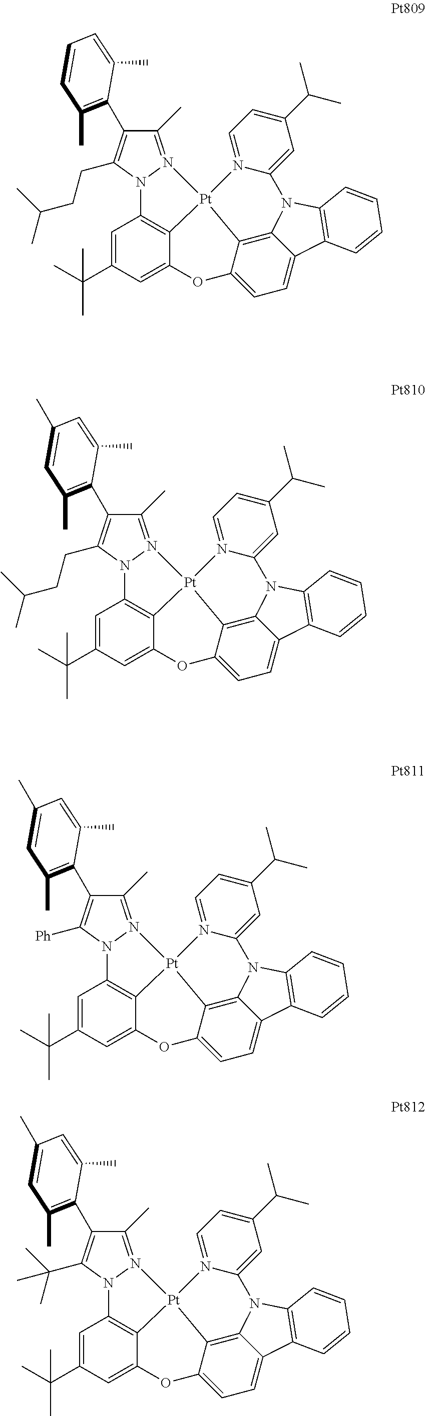

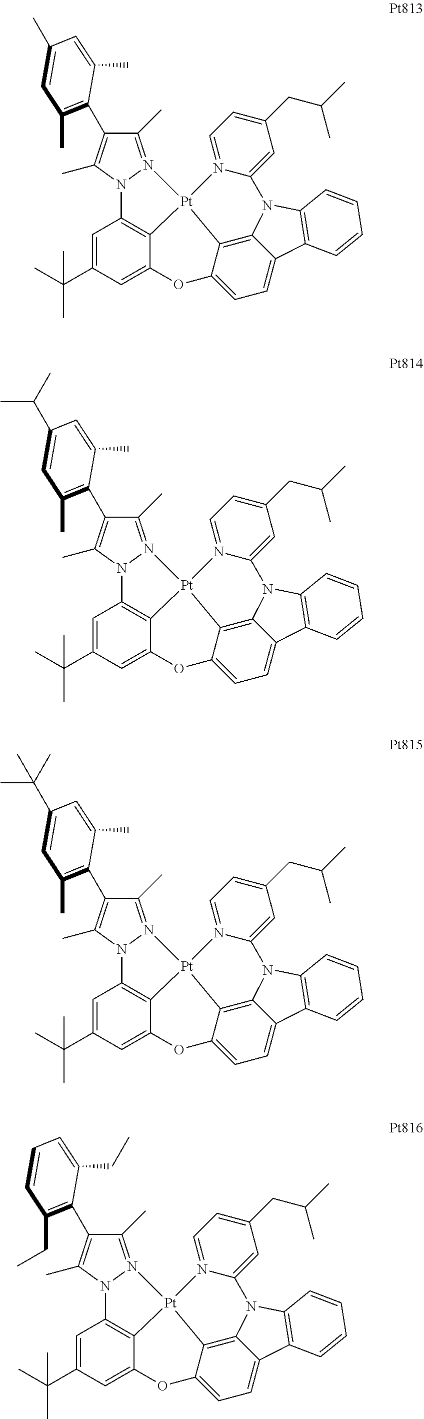

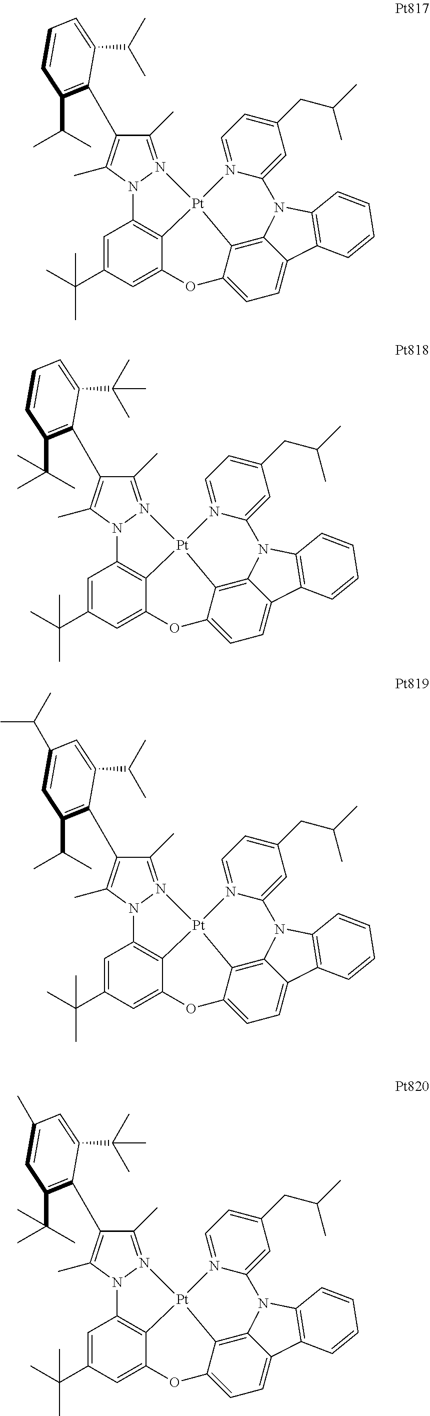

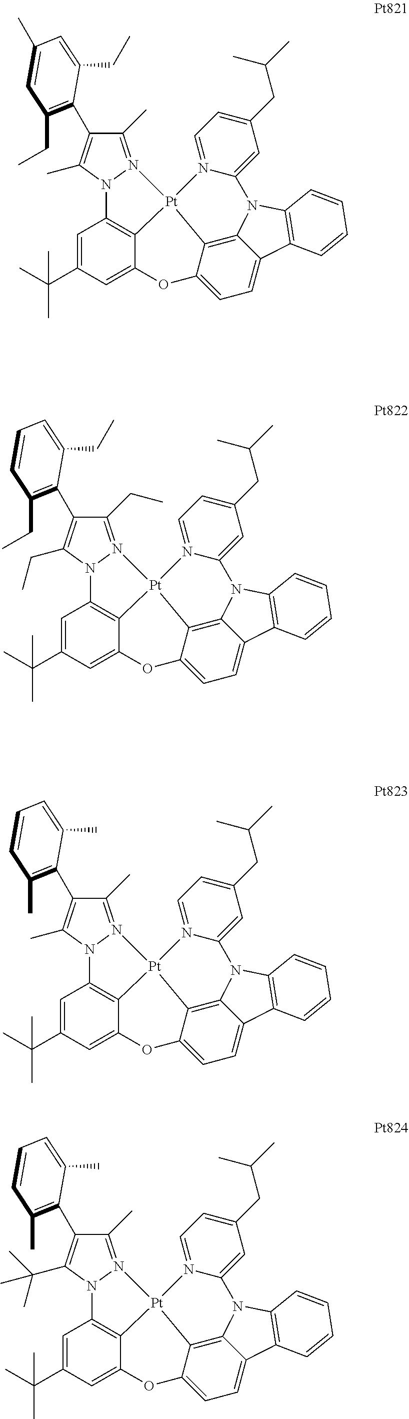

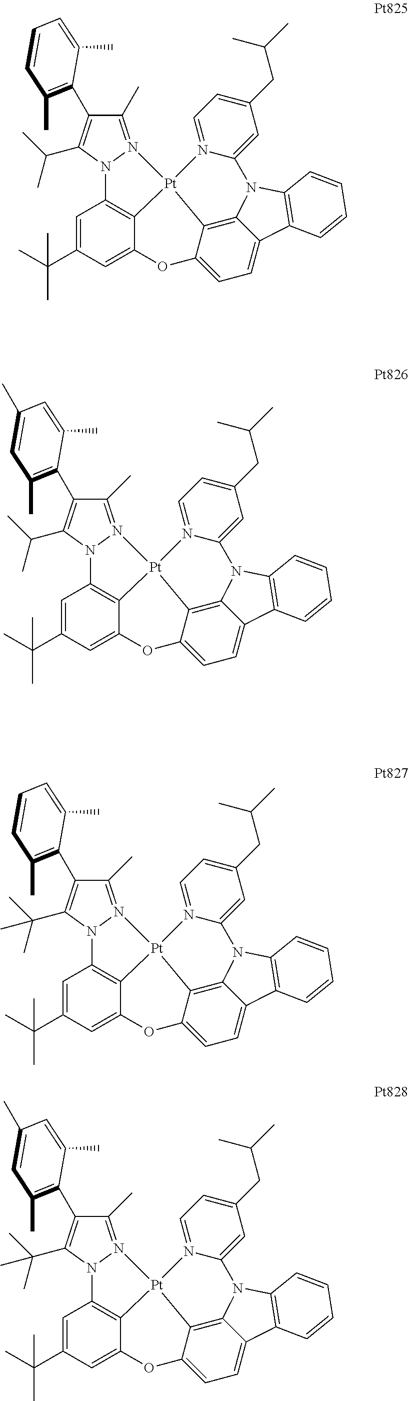

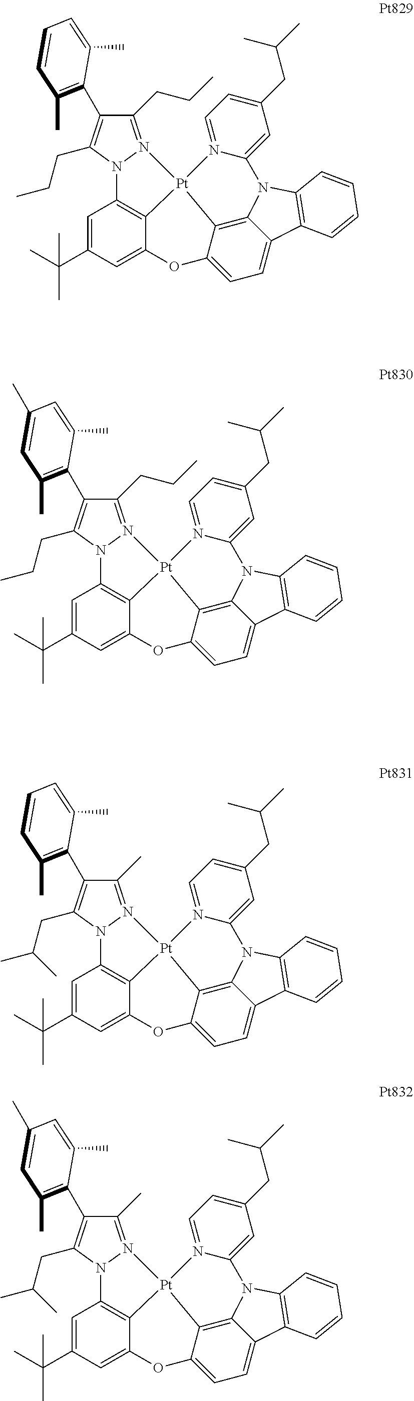

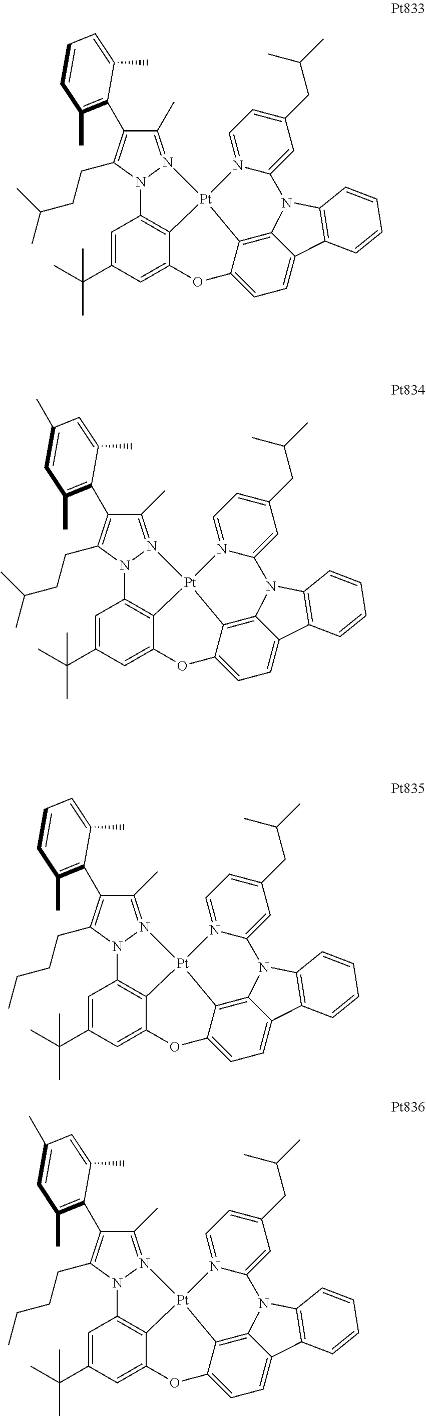

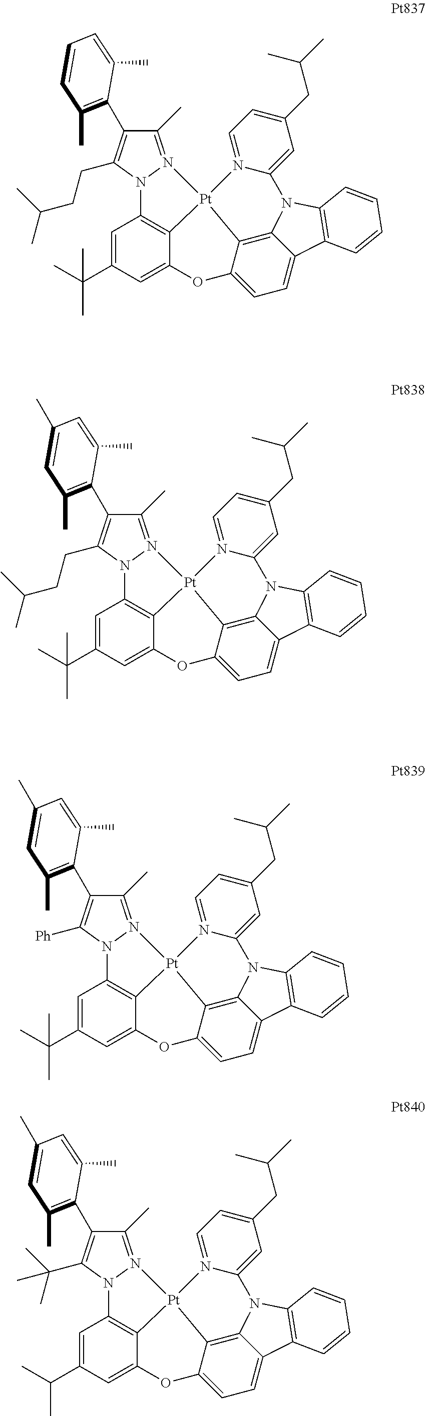

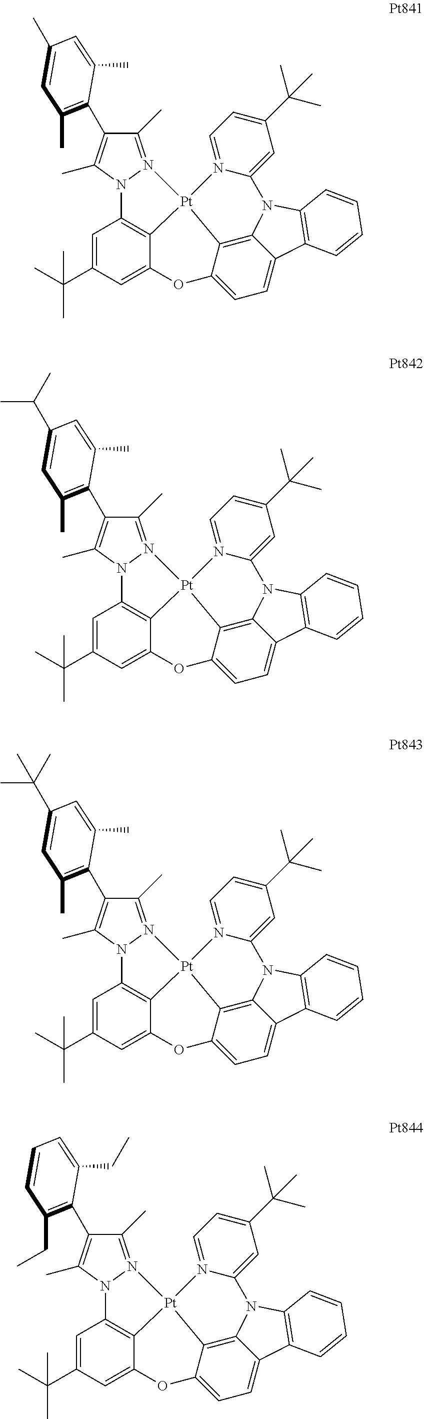

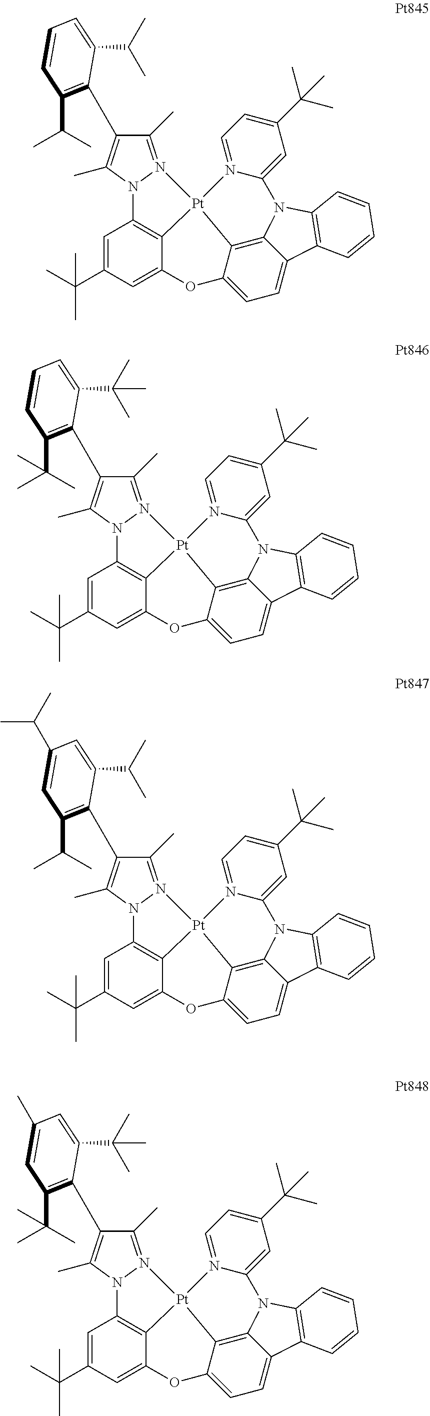

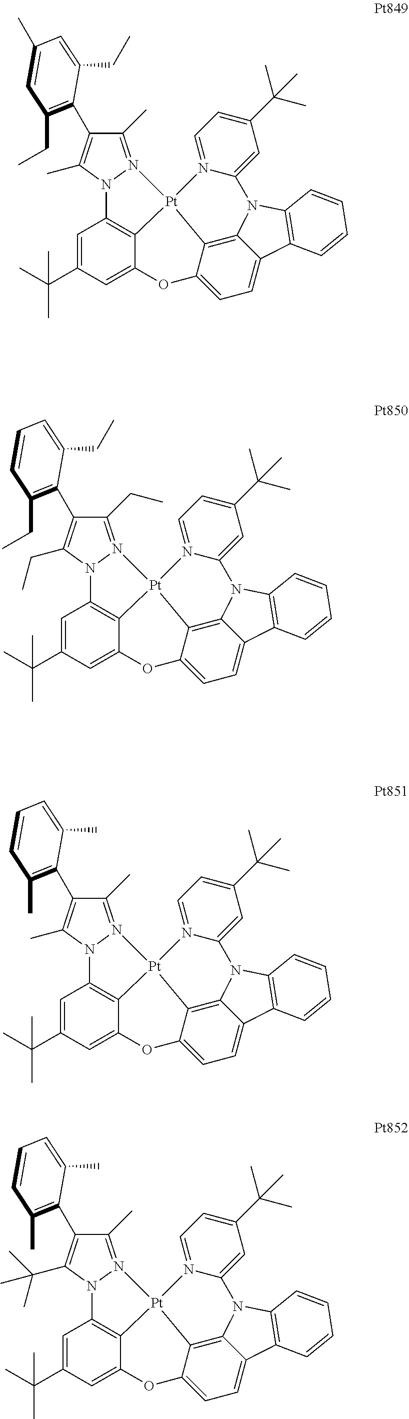

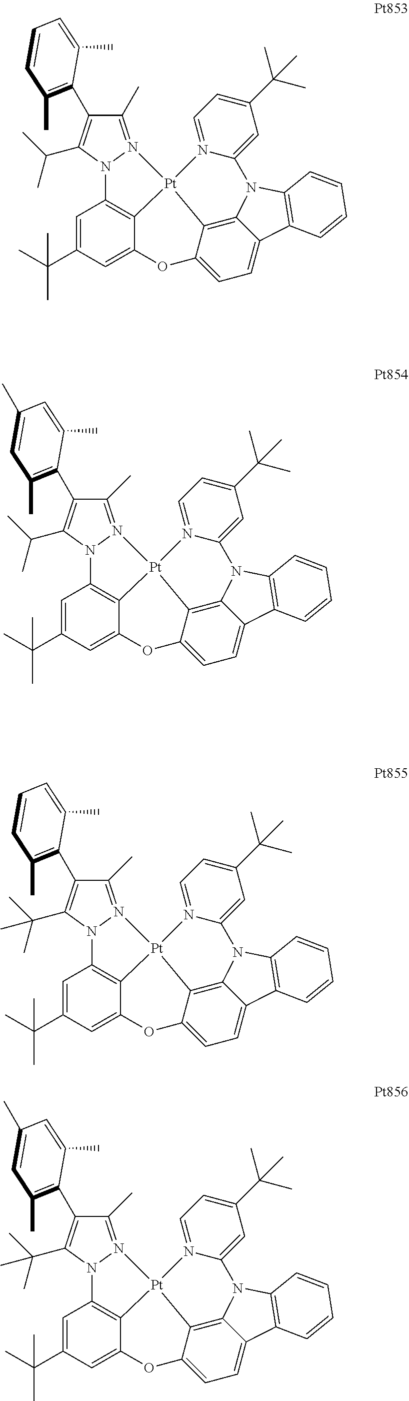

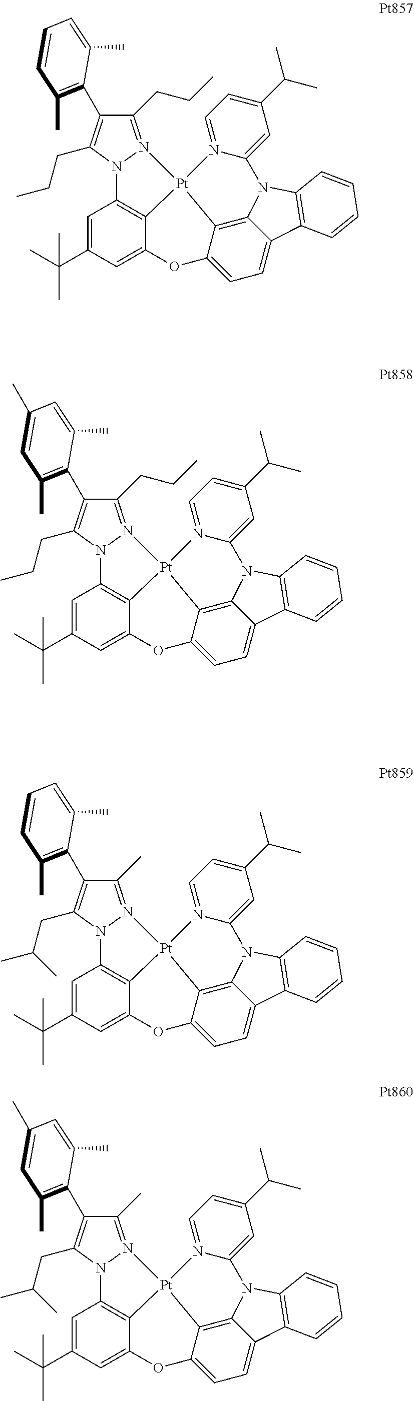

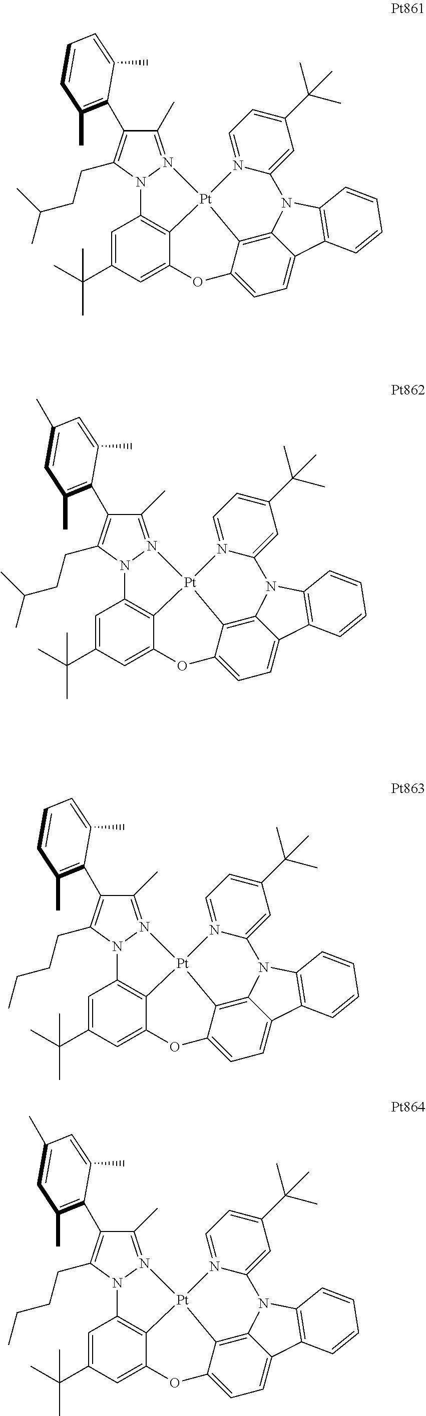

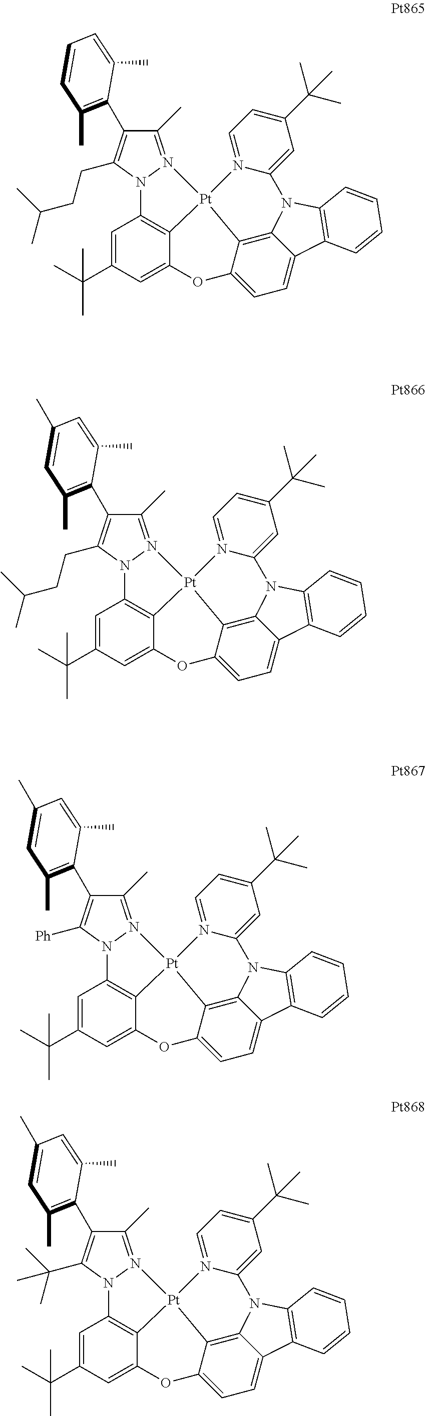

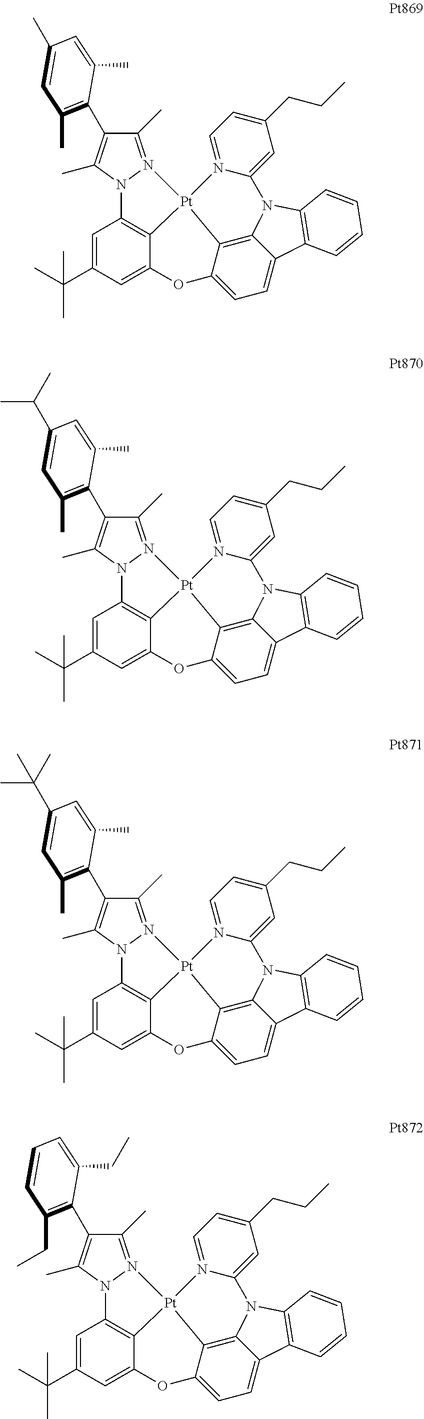

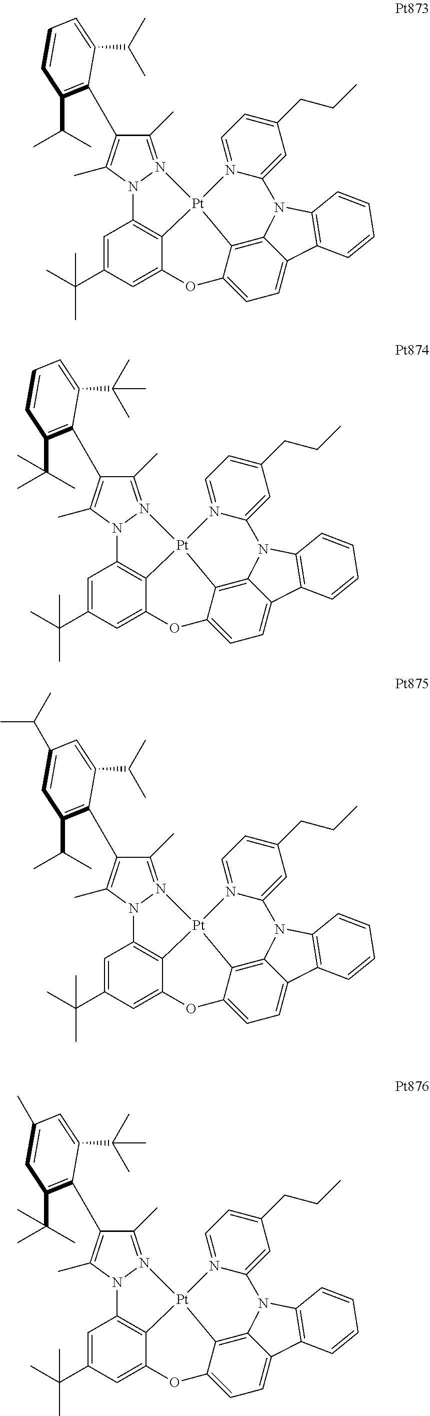

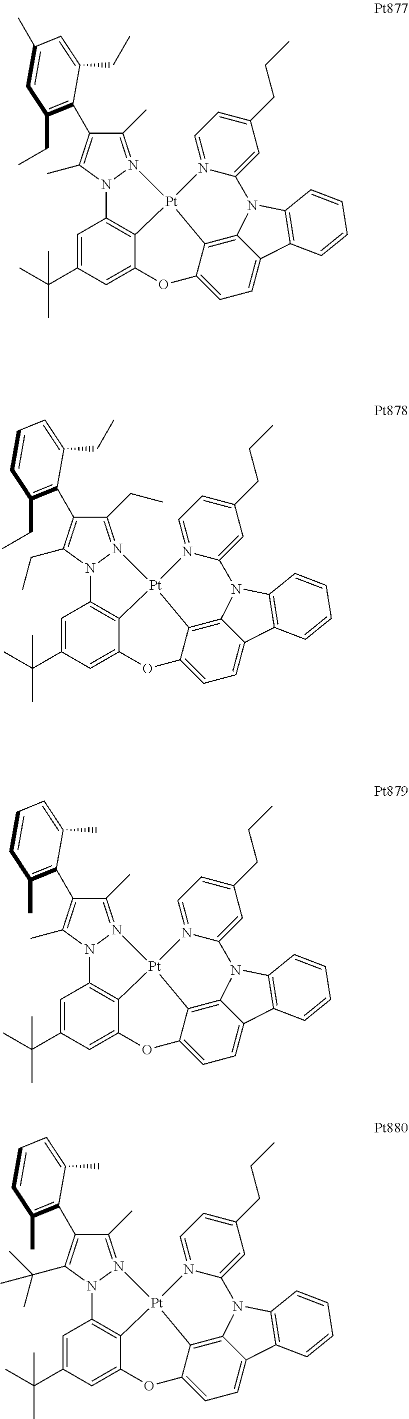

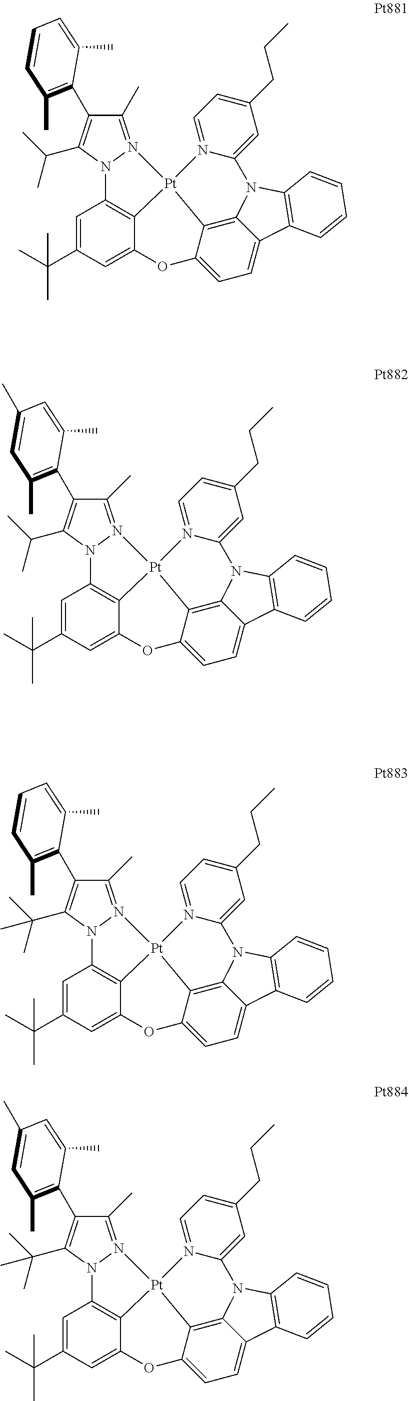

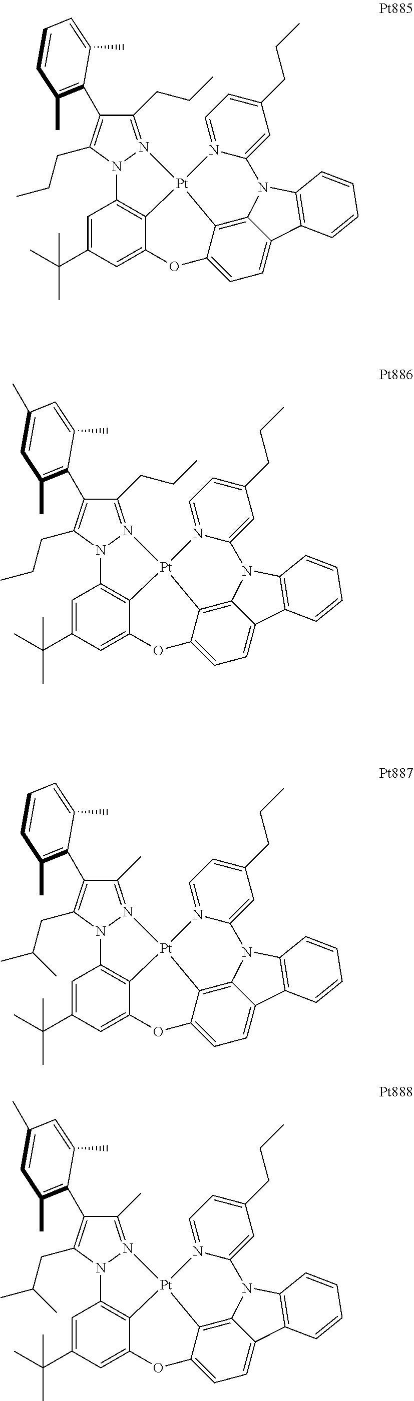

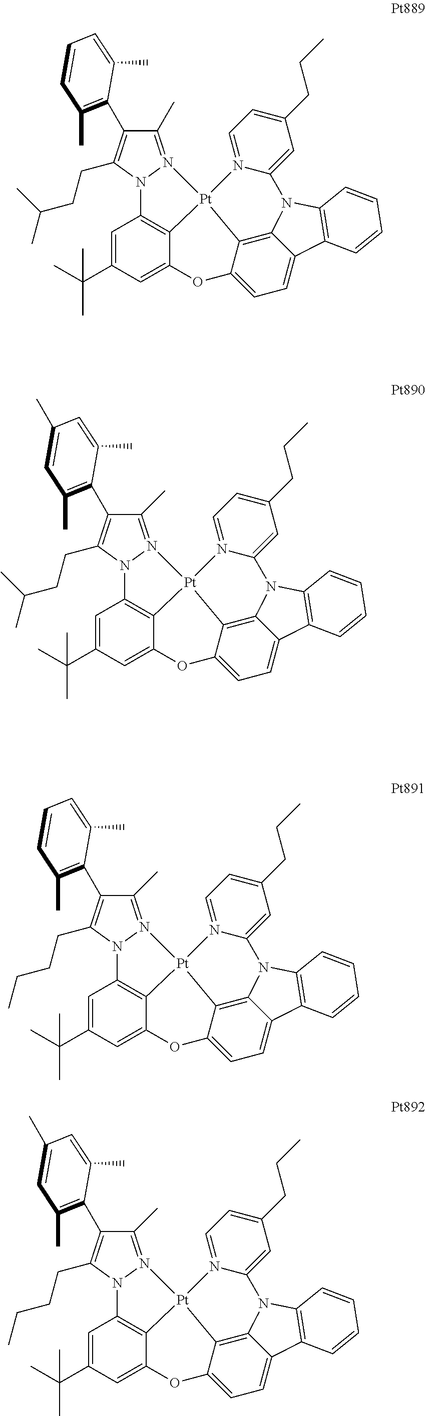

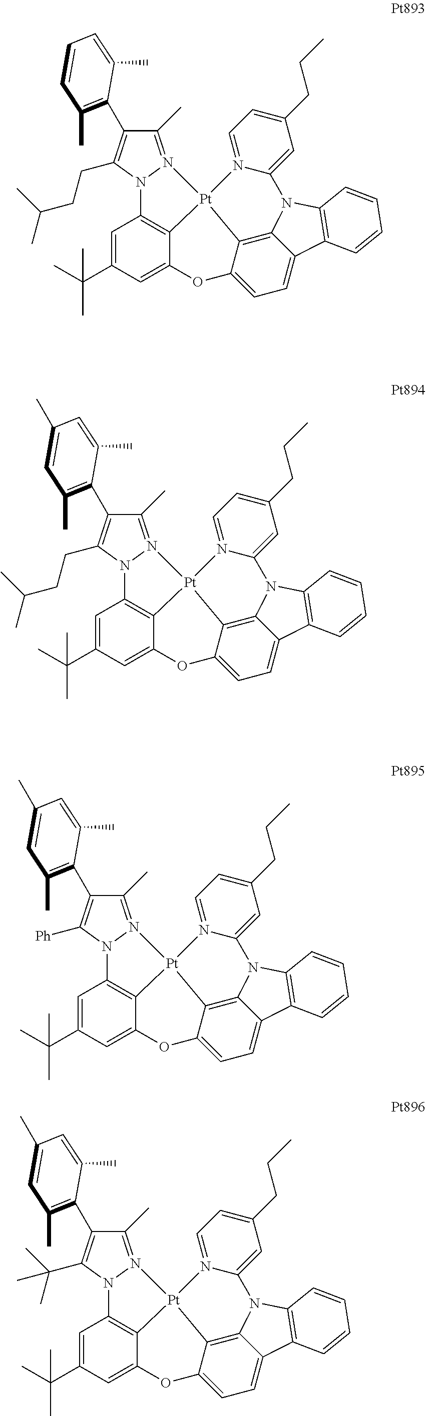

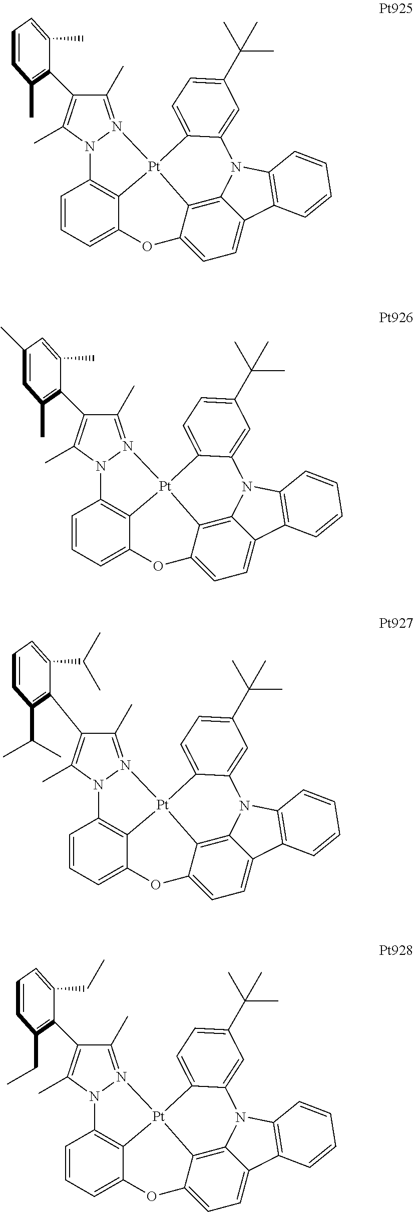

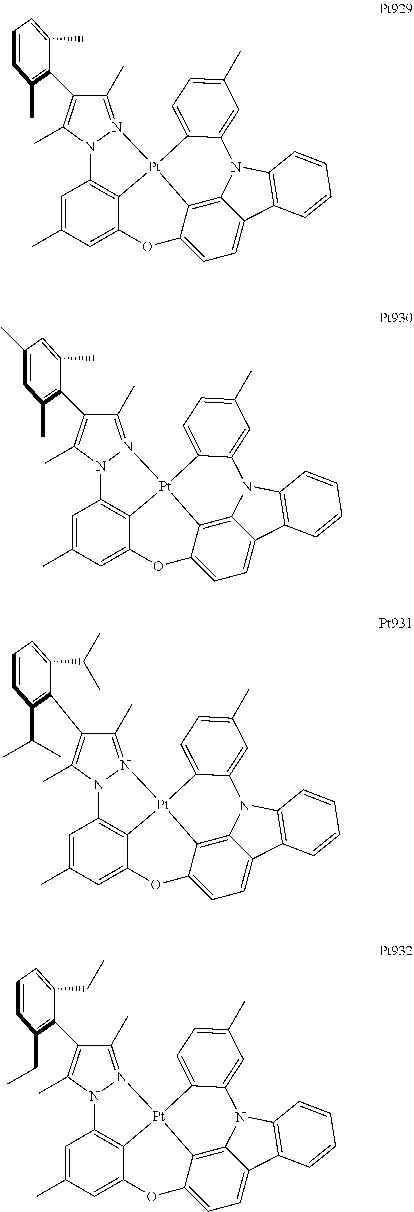

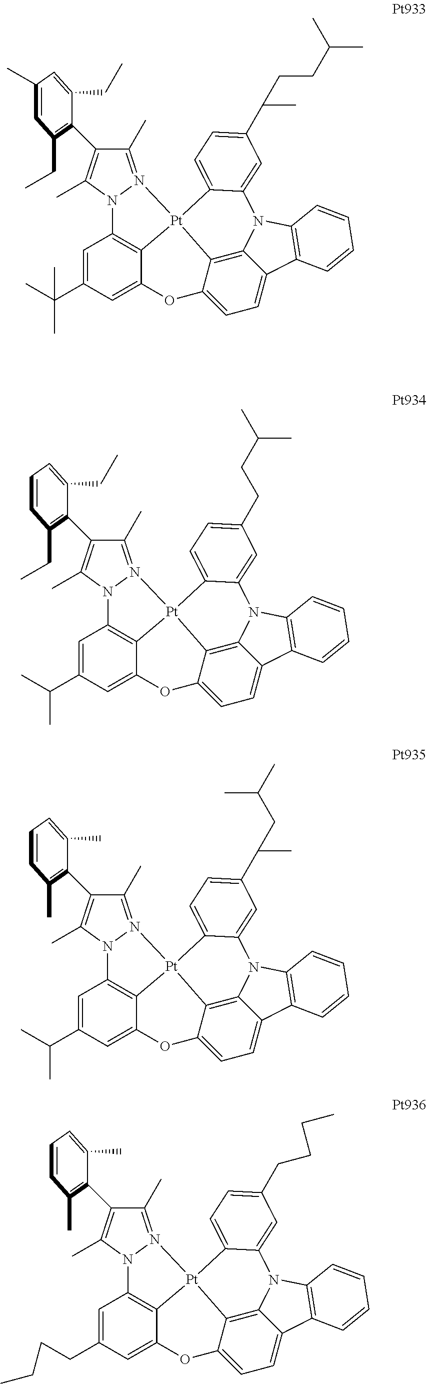

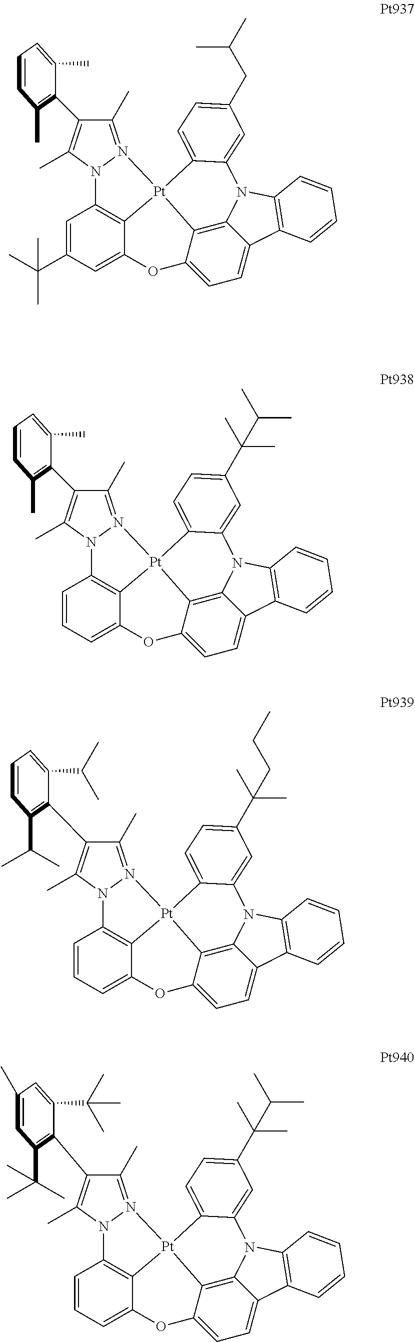

4. The tetradentate ring metal platinum complex containing 4-aryl-3, 5-disubstituted pyrazole as described in claim 1, wherein the mentioned complex is electrically neutral.

5. A preparation method of the tetradentate ring metal platinum complex containing 4-aryl-3, 5-disubstituted pyrazole as described in claim 1, wherein, it contains the following chemical reaction steps:

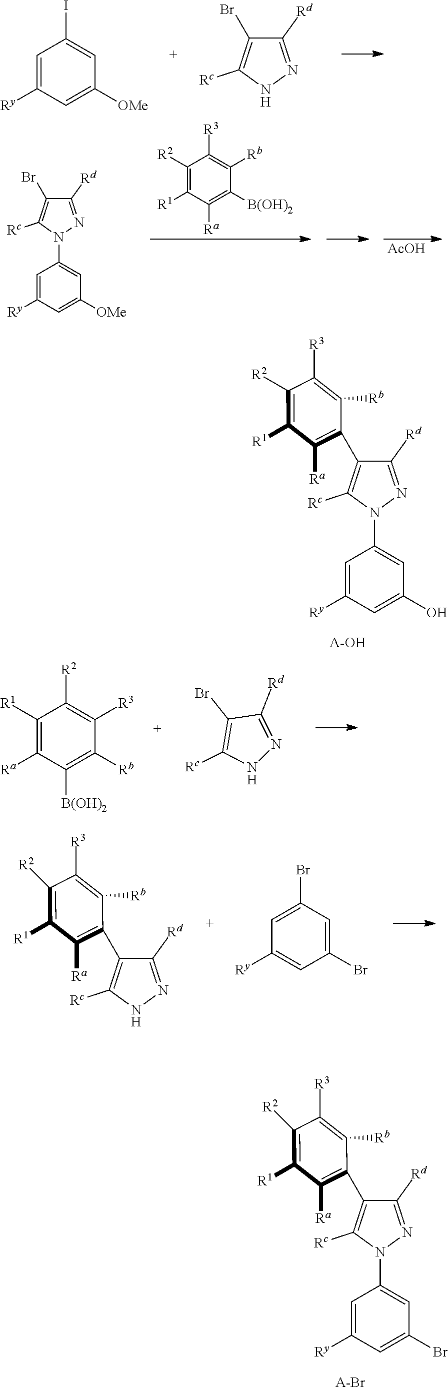

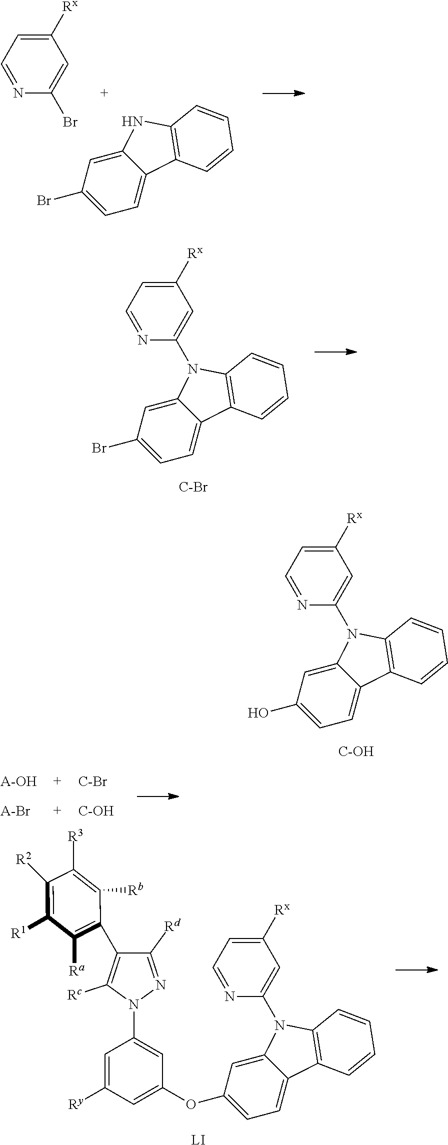

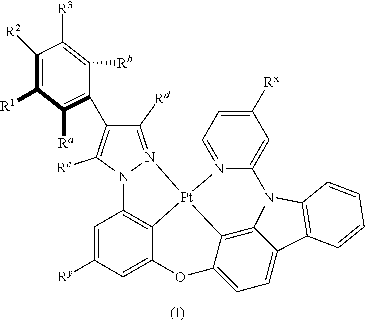

6. An optical or electro-optical device, containing the tetradentate ring metal platinum complex containing 4-aryl-3, 5-disubstituted pyrazole as described in claim 1.

7. The optical or electro-optical device as described in claim 6, wherein the device includes an optical absorption device, organic light-emitting diode (OLED), an optical emitting device or a device capable of being compatible with optical absorption and emission.

8. The optical or electro-optical device as described in claim 6, wherein the complex has an internal quantum efficiency of 100% in the mentioned device.

9. An OLED device, comprising luminescent material or host material of containing the tetradentate ring metal platinum complex containing 4-aryl-3, 5-disubstituted pyrazole described in claim 1.
